(19) United States
(12) Patent Application Publication
(10) Pub. No.: US 2014/0084270 A1
(43) Pub. Date: Mar. 27, 2014

(54) ORGANIC ELECTROLUMINESCENCE DEVICE

(71) Applicant: IDEMITSU KOSAN CO., LTD., Chiyoda-ku (JP)

(72) Inventors: Tomoki KATO, Sodegaura-shi (JP); Takayasu SADO, Sodegaura-shi (JP)

(73) Assignee: IDEMITSU KOSAN CO., LTD., Chiyoda-ku (JP)

(21) Appl. No.: 13/967,651

(22) Filed: Aug. 15, 2013

Related U.S. Application Data
(60) Provisional application No. 61/684,458, filed on Aug. 17, 2012.

(30) Foreign Application Priority Data
Aug. 17, 2012 (JP) 2012-181235

(51) Int. Cl. H01L 51/00

(52) U.S. Cl. CPC H01L 51/0067; H01L 51/0072
USPC 257/40

(57) ABSTRACT

An organic electroluminescence device includes an anode, a cathode, a first organic layer and an emitting layer including a luminescent material, in which the first organic layer and the emitting layer are interposed between the anode and the cathode in this sequence from the anode. The emitting layer contains a first material represented by the following formula (1-1) and a second material. The first organic layer contains a compound represented by the following formula (4).

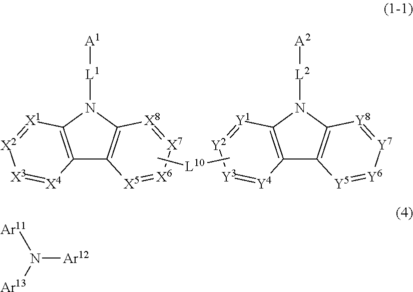

The entire disclosure of Japanese Patent Application No. 2012-181235, filed Aug. 17, 2012, and U.S. Provisional Application No. 61/684,458, filed Aug. 17, 2012, are expressly incorporated by reference herein.

### FIELD

Embodiments described herein relate to an organic electroluminescence device.

### BACKGROUND

When a voltage is applied on an organic electroluminescence device (hereinafter, occasionally referred to as an organic EL device), holes and electrons are respectively injected into an emitting layer from an anode and a cathode. In the emitting layer, the injected holes and electrons are recombined to form excitons. Herein, singlet excitons and triplet excitons are formed at a ratio of 25%:75% according to electron spins statistics. In a classification according to emission principle, in a fluorescent organic EL device which uses emission caused by singlet excitons, the limit value of an internal quantum efficiency is believed to be 25%. On the other hand, in a phosphorescent EL device which uses emission caused by triplet excitons, it has been known that the internal quantum efficiency can be improved up to 100% when intersystem crossing efficiently occurs from the singlet excitons.

In a typical organic EL device, the most suitable device design has been made depending on fluorescent and phosphorescent emission mechanism. Particularly, when a fluorescent device technique is simply used for designing the phosphorescent organic EL device, it has been known that a highly efficient phosphorescent organic EL device cannot be obtained because of a luminescence property of the phosphorescent organic EL device. The reasons are generally considered as follows.

First of all, since the phosphorescent emission is generated using triplet excitons, an energy gap of a compound for the emitting layer must be large. This is because a value of singlet energy (i.e., an energy gap between energy in the lowest singlet state and energy in the ground state) of a compound is typically larger than a value of triplet energy (i.e., an energy gap between energy in the lowest triplet state and energy in the ground state) of the compound.

Accordingly, in order to efficiently trap triplet energy of a phosphorescent dopant material in the device, a host material having larger triplet energy than that of the phosphorescent dopant material needs to be used in the emitting layer. Moreover, when an electron transporting layer and a hole transporting layer need to be provided adjacent to the emitting layer, a compound used as the electron transporting layer and the hole transporting layer need to have a larger triplet energy than that of the phosphorescent dopant material. Thus, according to the typical designing idea of the organic EL device, a compound having a larger energy gap than that of a compound used in a fluorescent organic EL device is used in a phosphorescent organic EL device, thereby increasing drive voltage of the overall organic EL device.

Although a hydrocarbon compound exhibiting a high oxidation resistance and a high reduction resistance is useful for the fluorescent device, the hydrocarbon compound has a broad [symbol] -electron cloud to render the energy gap small. For this reason, such a hydrocarbon compound is unlikely to be selected as the phosphorescent organic EL device but an organic compound containing a hetero atom such as oxygen and nitrogen is selected. However, the phosphorescent organic EL device exhibits a shorter lifetime than that of the fluorescent organic EL device.

Moreover, device performance of the phosphorescent organic EL device is greatly affected by an exciton relaxation rate of triplet excitons much longer than that of singlet excitons in the phosphorescent dopant material. In other words, with respect to emission from the singlet excitons, since a relaxation rate leading to emission is so fast that the singlet excitons are unlikely to diffuse to the neighboring layers of the emitting layer (e.g., the hole transporting layer and the electron transporting layer), efficient emission is expected. On the other hand, with respect to emission from the triplet excitons, since spin is forbidden and a relaxation rate is slow, the triplet excitons are likely to diffuse to the neighboring layers, so that the triplet excitons are thermally energy-deactivated unless the phosphorescent dopant material is a specific phosphorescent compound. In short, in the phosphorescent organic EL device, control of the recombination region of the electrons and the holes is more important as compared with the control of that in the fluorescent organic EL device.

For the above reasons, advancement of performance of the phosphorescent organic EL device requires material selection and device design different from those of the fluorescent organic EL device.

As a material of such a phosphorescent organic EL device, a carbazole derivative that exhibits a high triplet energy and is typically known as a hole transporting material has been used as a useful phosphorescent host material.

For instance, Document 1 discloses a light emitting device in which a compound having a carbazole skeleton is used as a host material of an emitting layer. Example of Document 1 shows the light emitting device including: the emitting layer in which a biscarbazole derivative provided by connecting two carbazole skeletons is used as the host material; and a hole transporting layer adjacent to the emitting layer in which 4,4′-bis(N-(1-naphthyl)-N-phenylamino)biphenyl (hereinafter, this compound is occasionally referred to as α-NPD) is used.

Moreover, Document 2 also discloses an organic EL device using a biscarbazole derivative as a host material. Example of Document 2 shows a light emitting device including: the emitting layer in which a biscarbazole derivative provided by connecting two carbazole skeletons is used as the host material; and a hole transporting layer adjacent to the emitting layer in which a triphenylamine derivative is used.

However, it is technically required to improve luminous efficiency as compared with those of the light emitting device of Document 1 and the organic EL device of Document 2.

### BRIEF SUMMARY OF THE INVENTION

An object of the invention is to provide an organic electroluminescence device having an improved luminous efficiency.

According to an aspect of the invention, an organic electroluminescence device includes: an anode; a cathode; a first organic layer interposed between the anode and the cathode and containing a compound represented by the following formula (4); and an emitting layer interposed between the first organic layer and the cathode and including a first material represented by the following formula (1-1), a second material and a luminescent material.

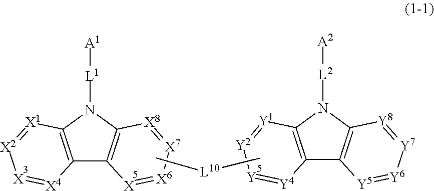

In the formula (1-1), A¹ and A² each independently represent a substituted or unsubstituted aromatic hydrocarbon group having 6 to 30 ring carbon atoms or a substituted or unsubstituted heterocyclic group having 5 to 30 ring atoms.

L¹, L² and L¹⁰ each independently represent a single bond, a substituted or unsubstituted divalent aromatic hydrocarbon group having 6 to 30 ring carbon atoms, or a substituted or unsubstituted divalent heterocyclic group having 5 to 30 ring atoms.

X¹ to X⁸ and Y¹ to Y⁸ each independently represent a nitrogen atom, CR^{a}, or a carbon atom to be bonded to L¹⁰.

R^{a} each independently represents a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms.

When a plurality of R^{a} are present, the plurality of R^{a} are the same or different.

One of X⁵ to X⁸ is bonded to one of Y¹ to Y⁴ through L¹⁰.

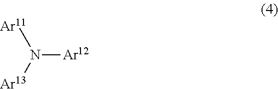

In the formula (4), Ar¹¹ to Ar¹³ represent a group represented by the following formula (4-2) or a substituted or unsubstituted aromatic hydrocarbon group having 6 to 40 carbon atoms. At least one of Ar¹¹ to Ar¹³ is a group represented by the following formula (4-2).

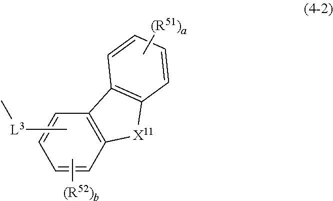

In the formula (4-2), X¹¹ represents CR⁵³R⁵⁴, an oxygen atom, or a sulfur atom.

L³ each independently represents a single bond, or a substituted or unsubstituted arylene group having 6 to 50 ring carbon atoms.

When L³ is a substituted arylene group having 6 to 50 ring carbon atoms, the substituent is a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms.

R⁵¹ and R⁵² each independently represent a halogen atom, a cyano group, a substituted or unsubstituted amino group, a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms.

In adjacent ones of R⁵¹ and adjacent ones of R⁵², a saturated or unsaturated divalent group to be bonded form a ring is formed or not formed.

R⁵³ and R⁵⁴ each independently represent a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, a substituted or unsubstituted alkylarylsilyl group having 8 to 15 carbon atoms, or a substituted or unsubstituted aromatic hydrocarbon group having 6 to 50 ring carbon atoms. In adjacent ones of R⁵³ and adjacent ones of R⁵⁴, a saturated or unsaturated divalent group to be bonded form a ring is formed or not formed.

a represents an integer of 0 to 4; and b represents an integer of 0 to 3.

According to another aspect of the invention, an organic electroluminescence device includes: an anode; a cathode; a first organic layer interposed between the anode and the cathode and containing a compound represented by the following formula (4X); and an emitting layer interposed between the first organic layer and the cathode and including a first material represented by the following formula (1-3X) and a luminescent material.

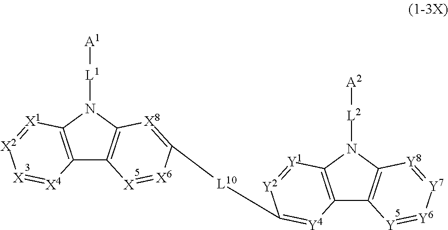

In the formula (1-3X), A¹ and A² each independently represent a substituted or unsubstituted aromatic hydrocarbon group having 6 to 30 ring carbon atoms or a substituted or unsubstituted heterocyclic group having 5 to 30 ring atoms.

L¹, L² and L¹⁰ each independently represent a single bond, a substituted or unsubstituted divalent aromatic hydrocarbon group having 6 to 30 ring carbon atoms, or a substituted or unsubstituted divalent heterocyclic group having 5 to 30 ring atoms.

X¹ to X⁸ and Y¹ to Y⁸ each independently represent a nitrogen atom or CR^{a}.

R^{a} each independently represents a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms.

When a plurality of R^{a} are present, the plurality of R^{a} are the same or different.

One of X⁵ to X⁸ is bonded to one of Y¹ to Y⁴ through L¹⁰.

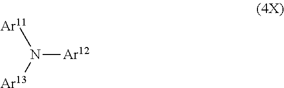

In the formula (4X), at least one of Ar¹¹ to Ar¹³ is a group represented by the following formula (4-2X). The rest of Ar¹¹ to Ar¹³ except for the group represented by the formula (4-2X) is a substituted or unsubstituted aromatic hydrocarbon group having 6 to 40 carbon atoms.

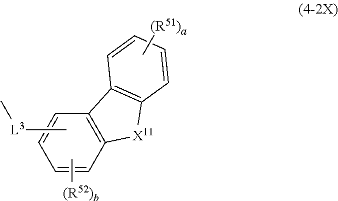

In the formula (4-2X), X¹¹ represents CR⁵³R⁵⁴, an oxygen atom, or a sulfur atom.

L³ each independently represents a single bond, or a substituted or unsubstituted arylene group having 6 to 50 ring carbon atoms.

When L³ is a substituted arylene group having 6 to 50 ring carbon atoms, the substituent is a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms.

R⁵¹ and R⁵² each independently represent a halogen atom, a cyano group, a substituted or unsubstituted amino group, a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms.

In adjacent ones of R⁵¹ and adjacent ones of R⁵², a saturated or unsaturated divalent group to be bonded form a ring is formed or not formed.

R⁵³ and R⁵⁴ each independently represent a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms.

In adjacent ones of R⁵³ and adjacent ones of R⁵⁴, a saturated or unsaturated divalent group to be bonded form a ring is formed or not formed.

a represents an integer of 0 to 4; and b represents an integer of 0 to 3.

According to the above aspects of the invention, a luminous efficiency of an organic electroluminescence device is improvable.

### BRIEF DESCRIPTION OF THE DRAWINGS

FIG. 1 schematically shows an exemplary arrangement of an organic EL device according to a first exemplary embodiment of the invention.

### DETAILED DESCRIPTION OF EMBODIMENTS

An organic EL device according to an exemplary embodiment of the invention will be described below in detail.

### Organic EL Device

An organic EL device according to the exemplary embodiment includes a cathode, an anode, a first organic layer interposed between the cathode and the anode, and an emitting layer. The first organic layer is disposed closer the anode than the emitting layer. In other words, the first organic layer and the emitting layer are disposed in this sequence from the anode. The first organic layer and the emitting layer each independently have a single-layered or multi-layered structure. The first organic layer and the emitting layer may contain an inorganic compound.

### Arrangement of Organic EL Device

Typical device configurations of an organic EL device include, for instance, the following structures (a) to (e) and the like.

(a) anode/emitting layer/cathode;

(b) anode/hole injecting-transporting layer/emitting layer/cathode;

(c) anode/emitting layer/electron injecting-transporting layer/cathode;

(d) anode/hole injecting-transporting layer/emitting layer/electron injecting-transporting layer/cathode; and

(e) anode/hole injecting-transporting layer/emitting layer/blocking layer/electron injecting-transporting layer/cathode.

While the arrangement (d) is preferably used among the above arrangements, the arrangement of the invention is not limited to the above arrangements.

It should be noted that the aforementioned “emitting layer” is an organic layer having an emission function, the organic layer including a host material and a dopant material when employing a doping system. Herein, the host material mainly has a function to promote recombination of electrons and holes and to confine excitons in the emitting layer while the dopant material has a function to efficiently emit the excitons obtained by the recombination. When the organic EL device is a phosphorescent device, the host material mainly has a function to confine excitons generated in the dopant within the emitting layer.

The “hole injecting/transporting layer means “at least one of a hole injecting layer and a hole transporting layer” while the “electron injecting/transporting layer” means “at least one of an electron injecting layer and an electron transporting layer.” Herein, when the hole injecting layer and the hole transporting layer are provided, the hole injecting layer is preferably closer to the anode. When the electron injecting layer and the electron transporting layer are provided, the electron injecting layer is preferably close to the cathode.

In the invention, the electron transporting layer means an organic layer having the highest electron mobility among organic layer(s) providing an electron transporting zone existing between the emitting layer and the cathode. When the electron transporting zone is provided by a single layer, the single layer is the electron transporting layer. Moreover, in the phosphorescent organic EL device, a blocking layer having an electron mobility that is not always high may be provided as shown in the arrangement (e) between the emitting layer and the electron transporting layer in order to prevent diffusion of exciton energy generated in the emitting layer. Thus, the organic layer adjacent to the emitting layer does not always correspond to the electron transporting layer.

The emitting layer of the organic EL device according to the exemplary embodiment contains a first material, a second material and a luminescent material. When the above-described doping system is employed, the luminescent material is used as a dopant material while the first and second materials are occasionally used as the first and second host materials.

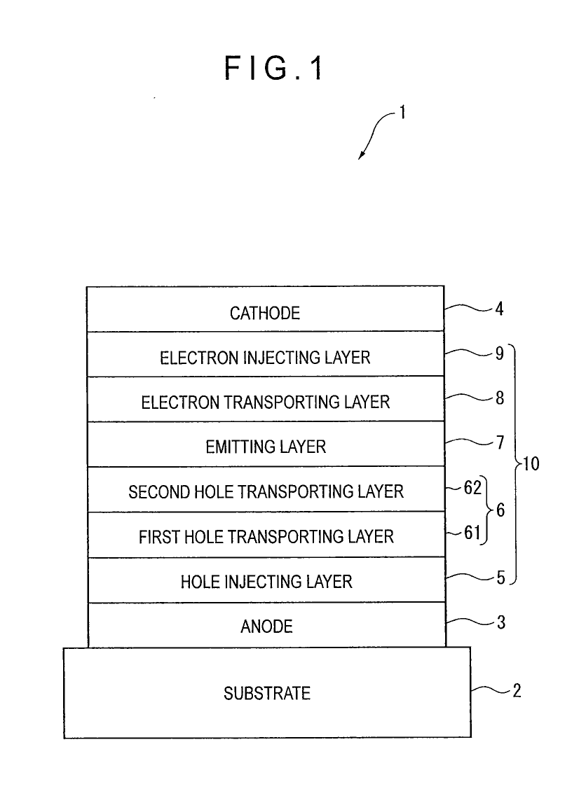

FIG. 1 schematically shows an exemplary arrangement of an organic EL device according to an exemplary embodiment of the invention.

The organic EL device 1 shown in FIG. 1 includes a transparent substrate 2, an anode 3, a cathode 4 and an organic thin-film layer 10 positioned between the anode 3 and the cathode 4.

The organic thin-film layer 10 sequentially includes a hole injecting layer 5, a hole transporting layer 6, an emitting layer 7, an electron transporting layer 8 and an electron injection layer 9 on the anode 3. The hole transporting layer 6 of the organic EL device 1 includes a first hole transporting layer 61 and a second hole transporting layer 62. The first hole transporting layer 61 is closer to the anode 3 than the second hole transporting layer 62. The second hole transporting layer 62 is adjacent to a side near the anode 3 of the emitting layer 7. The hole injecting layer 5 and the hole transporting layer 6 in the exemplary embodiment correspond to the first organic layer.

### Emitting Layer

In the organic EL device according to the exemplary embodiment, the emitting layer includes the first material represented by the following formula (1-1) and the second material. Hereinafter, the first material is occasionally referred to as the first host material and the second material is occasionally referred to as the second host material.

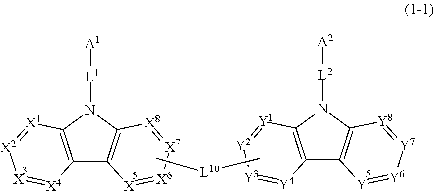

In the formula (1-1), A¹ and A² each independently represent a substituted or unsubstituted aromatic hydrocarbon group having 6 to 30 ring carbon atoms, or a substituted or unsubstituted heterocyclic group having 5 to 30 ring atoms.

In the formula (1-1), L′, L² and L¹⁰ each independently represent a single bond, a substituted or unsubstituted divalent aromatic hydrocarbon group having 6 to 30 ring carbon atoms, or a substituted or unsubstituted divalent heterocyclic group having 5 to 30 ring atoms.

In the formula (1-1), X¹ to X⁸ and Y¹ to Y⁸ each independently represent a nitrogen atom, CR^{a} or a carbon atom to be bonded to L¹⁰. Herein CR^{a} is provided by bonding R^{a} to a carbon atom (C). R^{a} independently represents a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms. When a plurality of R^{a} are present, the plurality of R^{a} are the same or different.

One of X⁵ to X⁸ is bonded to one of Y¹ to Y⁴ through L¹⁰.

Examples of the halogen atom in the formula (1-1) include fluorine, chlorine, bromine and iodine, among which fluorine is preferable.

Examples of the aromatic hydrocarbon group having 6 to 30 ring carbon atoms in the formula (1-1) include a phenyl group, naphthyl group, phenanthryl group, biphenyl group, terphenyl group, quarterphenyl group, fluoranthenyl group, triphenylenyl group, phenanthrenyl group, fluorenyl group, spirofluorenyl group, 9,9-diphenylfluorenyl group, 9,9′-spirobi[9H-fluorene]-2-yl group, 9,9-dimethylfluorenyl group, benzo[c]phenanthrenyl group, benzo[a]triphenylenyl group, naphtho[1,2-c]phenanthrenyl group, naphtho[1,2-a]triphenylenyl group, dibenzo[a,c]triphenylenyl group and benzo[b]fluoranthenyl group.

Preferable examples of the aromatic hydrocarbon group in the formula (1-1) include a phenyl group, naphthyl group, biphenyl group, terphenyl group, phenanthryl group, triphenylenyl group, fluorenyl group, spirobifluorenyl group and fluoranthenyl group.

Examples of the heterocyclic group having 5 to 30 ring atoms in the formula (1-1) include a quinoline ring, isoquinoline ring, quinoxaline ring, phenanthridine ring, phenanthroline ring, pyridine ring, pyrazine ring, pyrimidine ring, pyridazine ring, triazine ring, acridine ring, piperidine ring, morpholine ring, piperazine ring, pyrrole ring, isoindole ring, benzofuran ring, isobenzofuran ring, dibenzothiophen ring, indole ring, pyrrolidine ring, dioxane ring, carbazole ring, furan ring, thiophen ring, oxazole ring, oxadiazole ring, benzooxazole ring, thiazole ring, thiadiazole ring, benzothiazole ring, triazole ring, imidazole ring, benzoimidazole ring, pyrane ring, dibenzofuran ring, benzo[c]dibenzofuran ring and a group formed from derivatives thereof.

The divalent aromatic hydrocarbon group having 6 to 30 ring carbon atoms in the formula (1-1) is exemplified by a divalent group derived from the above examples of the aromatic hydrocarbon group having 6 to 30 ring carbon atoms.

The divalent aromatic hydrocarbon group having 5 to 30 ring atoms in the formula (1-1) is exemplified by a divalent group derived from the above examples of the aromatic hydrocarbon group having 5 to 30 ring carbon atoms.

Examples of the alkyl group having 1 to 30 carbon atoms in the formula (1-1) include a methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neo-pentyl group, and 1-methylpentyl group.

The linear or branched alkyl group in the formula (1-1) preferably has 1 to 10 carbon atoms, more preferably 1 to 6 carbon atoms. Among the alkyl group, a methyl group, ethyl group, propyl group, isopropyl group, n-butyl group, s-butyl group, isobutyl group, t-butyl group, n-pentyl group and n-hexyl group are preferable.

Examples of the cycloalkyl group having 3 to 30 ring carbon atoms in the formula (1-1) are a cyclopropyl group, cyclobutyl group, cyclopentyl group, cyclohexyl group, cyclopentyl group, cyclohexyl group, cyclooctyl group, 4-methylcyclohexyl group, 3,5-tetramethylcyclohexyl group, 1-adamantyl group, 2-adamantyl group, 1-norbornyl group and 2-norbornyl group. The cycloalkyl group preferably has 3 to 10 ring carbon atoms, more preferably 5 to 8 ring carbon atoms. Among the cycloalkyl group, a cyclopentyl group and a cyclohexyl group are preferable.

Examples of the cycloalkyl group in the formula (1-1) further include a halocycloalkyl group, which is provided by substituting at least one hydrogen atom of the above cycloalkyl group with a halogen atom. The substituted halogen atom is preferably fluorine.

The alkoxy group having 1 to 30 carbon atoms in the formula (1-1) is a linear, branched or cyclic alkoxy group and is represented by —OY¹. Y¹ is exemplified by the alkyl group having 1 to 30 carbon atoms or the cycloalkyl group having 3 to 30 ring carbon atoms. Examples of the alkoxy group are a methoxy group, ethoxy group, propoxy group, butoxy group, pentyloxy group and hexyloxy group.

The aryloxy group having 6 to 30 ring carbon atoms in the formula (1-1) is represented by —OR^{Z}. R^{Z} is exemplified by the aromatic hydrocarbon group having 6 to 30 ring carbon atoms. The aryloxy group is exemplified by a phenoxy group.

The haloalkyl group having 1 to 20 carbon atoms in the formula (1-1) is exemplified by a halocalkyl group provided by substituting at least one hydrogen atom of the above alkyl group with a halogen atom. The substituted halogen atom is preferably fluorine. Examples of the haloalkyl group include a trifluoromethyl group and 2,2-trifluoroethyl group.

The haloalkoxy group having 1 to 20 carbon atoms in the formula (1-1) is exemplified by a haloalkoxy group provided by substituting at least one hydrogen atom of the above alkoxy group with a halogen atom.

The alkylsilyl group having 1 to 30 carbon atoms in the formula (1-1) is exemplified by a linear, branched or cyclic alkylsilyl group, examples of which are a trimethylsilyl group, triethylsilyl group, tributylsilyl group, dimethylethylsilyl group, dimethylisopropylsilyl group, dimethylpropylsilyl group, dimethylbutylsilyl group, dimethyl-tert-butylsilyl group, and diethylisopropylsilyl group.

Examples of the arylsilyl group having 6 to 30 carbon atoms in the formula (1-1) are a phenyldimethylsilyl group, diphenylmethylsilyl group, diphenyl-tert-butylsilyl group and triphenylsilyl group.

The aralkyl group having 7 to 30 carbon atoms in the formula (1-1) is represented by —R^{X}—R^{Y}. R^{X} is exemplified by an alkylene group corresponding to the alkyl group having 1 to 30 carbon atoms. R^{Y} is exemplified by the examples of the aromatic hydrocarbon group having 6 to 30 ring carbon atoms. In the aralkyl group, an aromatic hydrocarbon group moiety has 6 to 30 carbon atoms, preferably 6 to 20 carbon atoms, more preferably 6 to 12 carbon atoms. In the aralkyl group, an alkyl group moiety has 1 to 30 carbon atoms, preferably 1 to 20 carbon atoms, more preferably 1 to 10 carbon atoms, further preferably 1 to 6 carbon atoms. Examples of the aralkyl group are a benzyl group, 2-phenylpropane-2-yl group, 1-phenylethyl group, 2-phenylethyl group, 1-phenyl isopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, 2-β-naphthylisopropyl group, 1-pyrorylmethyl group, 2-(1-pyroryl)ethyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group and 1-chloro-2-phenylisopropyl group.

The alkenyl group having 2 to 30 carbon atoms in the formula (1-1) may be linear, branched or cyclic. Examples of the alkenyl group are vinyl, propenyl, butenyl, oleyl, eicosapentaenyl, docosahexaenyl, styryl, 2,2-diphenylvinyl, 1,2,2-triphenylvinyl and 2-phenyl-2-propenyl, among which a vinyl group is preferable.

The alkynyl group having 2 to 30 carbon atoms in the formula (1-1) may be linear, branched or cyclic. Examples of the alkynyl group are ethynyl, propynyl and 2-phenylethynyl, among which an ethynyl group is preferable.

In the formula (1-1), at least one of A¹ and A² is preferably represented by a formula (1-1a) below.

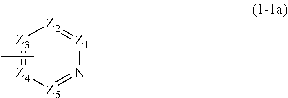

In the formula (1-1a), Z₁ to Z₅ each independently represent CR₇ or a nitrogen atom. Herein CR₇ is provided by bonding R₇ to a carbon atom (C). R₇ independently represents a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms. Adjacent ones of R₇ are bonded to each other to form a cyclic structure, or are not bonded.

In the formula (1-1a), the aromatic hydrocarbon group having 6 to 30 ring carbon atoms, heterocyclic group having 5 to 30 ring atoms, alkyl group having 1 to 30 carbon atoms, cycloalkyl group having 3 to 30 ring carbon atoms, haloalkyl group having 1 to 20 carbon atoms, alkoxy group having 1 to 30 carbon atoms, haloalkoxy group having 1 to 20 carbon atoms, aryloxy group having 6 to 30 ring carbon atoms, alkylsilyl group having 1 to 30 carbon atoms, arylsilyl group having 6 to 30 carbon atoms, aralkyl group having 7 to 30 carbon atoms, alkenyl group having 2 to 30 carbon atoms and alkynyl group having 2 to 30 carbon atoms are respectively exemplified by the examples of those described in relation to the formula (1-1).

Examples of the group in the formula (1-1a) are a monovalent group of each of a pyrimidine ring, triazine ring, pyridine ring, quinazoline ring, isoquinoline ring, quinoxaline ring, phenanthridine ring, phenanthroline ring, pyrazine ring, pyridazine ring, quinoline ring, and acridine ring, among which the monovalent groups of the pyrimidine ring, triazine ring, pyridine ring and quinazoline ring are preferable. These rings may be substituted or unsubstituted.

The first host material is preferably represented by one of the following formulae (1-2) to (1-4).

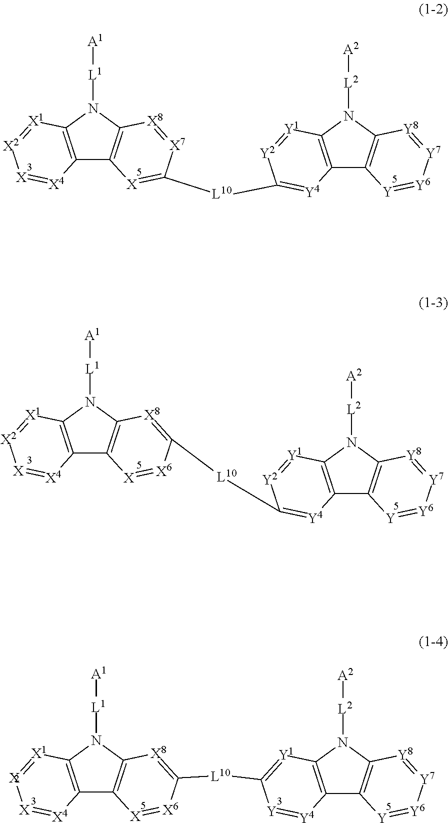

In the formulae (1-2) to (1-4), A¹, A², L¹, L², L¹⁰, X¹ to X⁸ and Y¹ to Y⁸ respectively represent the same as A¹, A², L¹, L², L¹⁰, X¹ to X⁸ and Y¹ to Y⁸ in the formula (1-1).

In the invention, “carbon atoms forming a ring (ring carbon atoms)” mean carbon atoms forming a saturated ring, unsaturated ring, or aromatic ring. “Atoms forming a ring (ring atoms)” mean carbon atoms and hetero atoms forming a hetero ring including a saturated ring, unsaturated ring, or aromatic ring.

In the invention, a “hydrogen atom” means isotopes having different neutron numbers and specifically encompasses protium, deuterium and tritium.

Examples of the substituent meant by “substituted or unsubstituted” are the above-described aromatic hydrocarbon group, aromatic heterocyclic group, alkyl group (linear or branched alkyl group, cycloalkyl group and haloalkyl group), alkoxy group, aryloxy group, aralkyl group, haloalkoxy group, alkylsilyl group, dialkylarylsilyl group, alkyldiarylsilyl group, triarylsilyl group, halogen atom, cyano group, hydroxyl group, nitro group and carboxy group. In addition, the alkenyl group and alkynyl group are also usable.

Examples of the substituent meant by “substituted or unsubstituted” are preferably a halogen atom (fluorine, chlorine, bromine and iodine), cyano group, alkyl group having 1 to 20 carbon atoms (preferably 1 to 6 carbon atoms), cycloalkyl group having 3 to 20 carbon atoms (preferably 5 to 12 carbon atoms), alkoxy group having 1 to 20 carbon atoms (preferably 1 to 5 carbon atoms), haloalkyl group having 1 to 20 carbon atoms (preferably 1 to 5 carbon atoms), haloalkoxy group having 1 to 20 carbon atoms (preferably 1 to 5 carbon atoms), alkylsilyl group having 1 to 10 carbon atoms (preferably 1 to 5 carbon atoms), aryl group 6 to 30 ring carbon atoms (preferably 6 to 18 ring carbon atoms), aryloxy group 6 to 30 carbon atoms (preferably 6 to 18 carbon atoms), arylsilyl group having 6 to 30 carbon atoms (preferably 6 to 18 carbon atoms), aralkyl group having 7 to 30 carbon atoms (preferably 7 to 20 carbon atoms) and heteroaryl group having 5 to 30 ring atoms (preferably 5 to 18 ring atoms).

In the above-described substituents, the aromatic hydrocarbon group, aromatic heterocyclic group, alkyl group, halogen atom, alkylsilyl group, arylsilyl group and cyano group are preferable. Preferable ones of the specific examples of each substituent are further preferable.

“Unsubstituted” in “a substituted or unsubstituted XX group” means that a hydrogen atom of the XX group is not substituted by the above-described substituents.

Herein, “a to b carbon atoms” in the description of “substituted or unsubstituted XX group having a to b carbon atoms” represent carbon atoms of an unsubstituted XX group and does not include carbon atoms of a substituted XX group.

In a later-described compound or a partial structure thereof, the same applies to the description of “substituted or unsubstituted.”

A manufacturing method of the first host material is not particularly limited, but known methods are usable. For instance, the first host material may be manufactured by a coupling reaction using a copper catalyst described in “Tetrahedron, 40th volume (1984), p. 1433-1456” or a paradium catalyst described in “Journal of the American Chemical Society, 123 (2001), p. 7727-7729” to manufacture the biscarbazole derivative.

Examples of specific structures of the compounds usable as the first host material are shown below. However, the invention is not limited to the compounds having these structures. It should be noted that a bond at an end of the following structural formulae, of which chemical formula (e.g., CN or a benzene ring) is not described, represents a methyl group. In the following formulae, a group denoted by —SiMe₃ represents a trimethylsilyl group.

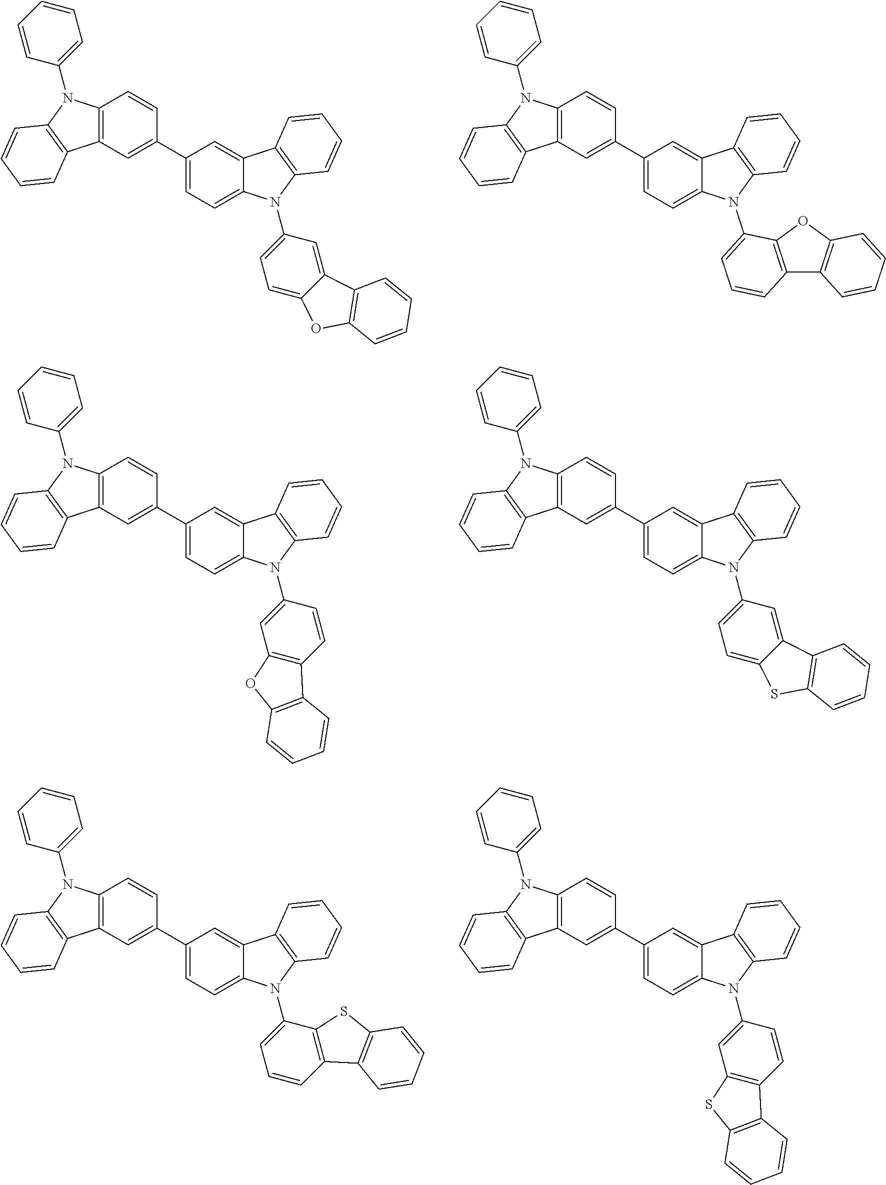 [SMILES: c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5c(c4)sc4ccccc45)ccc32)cc1]

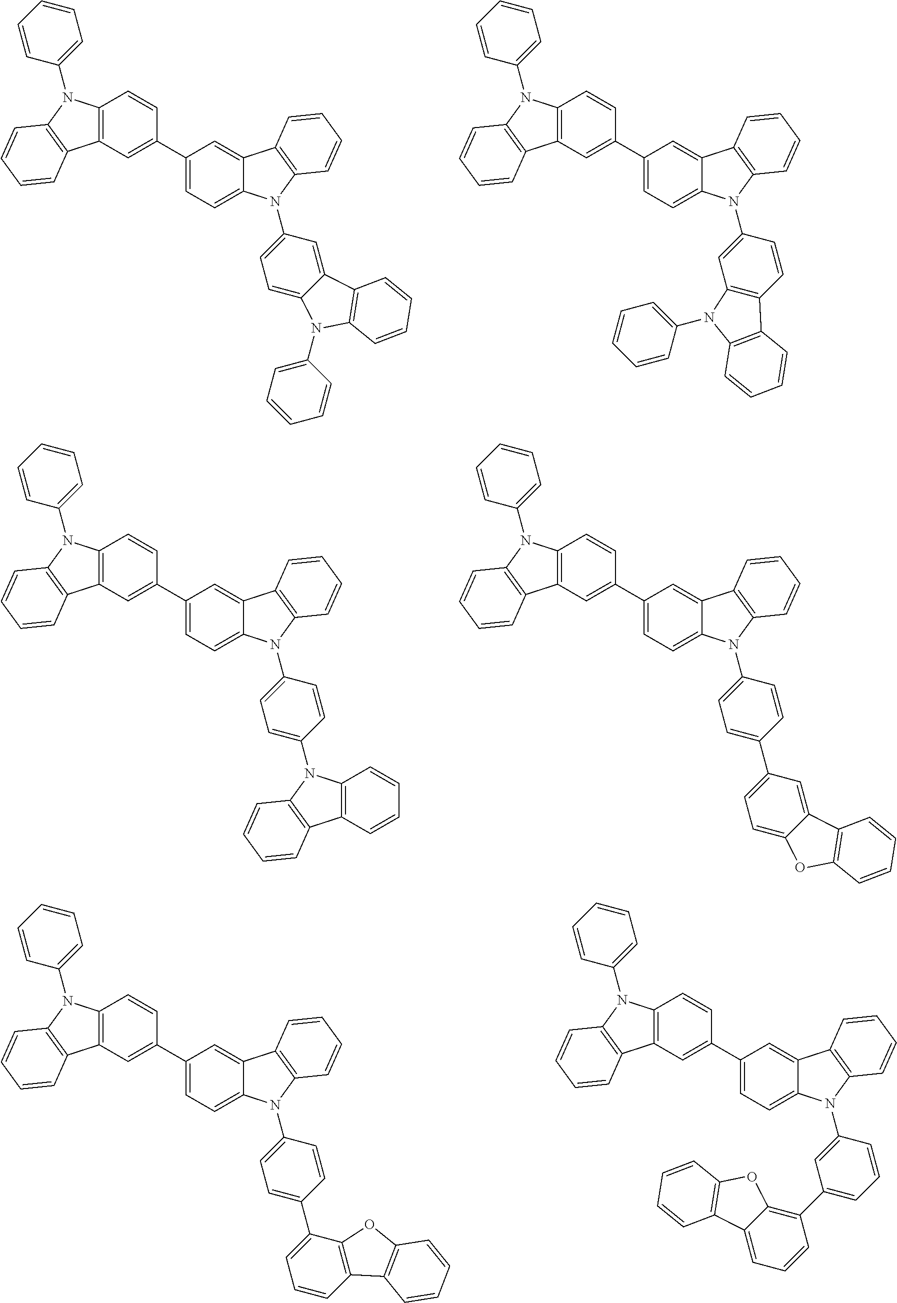

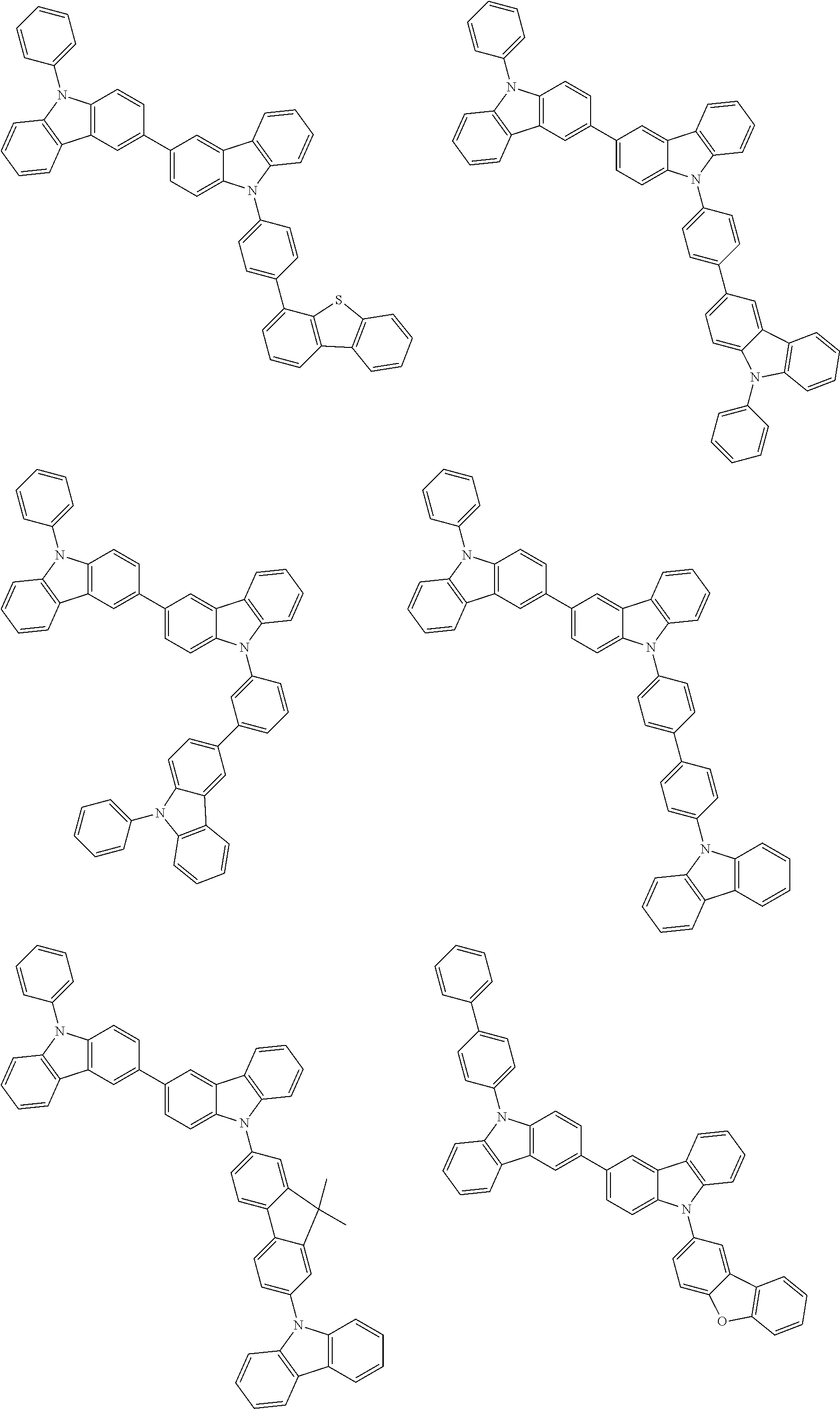

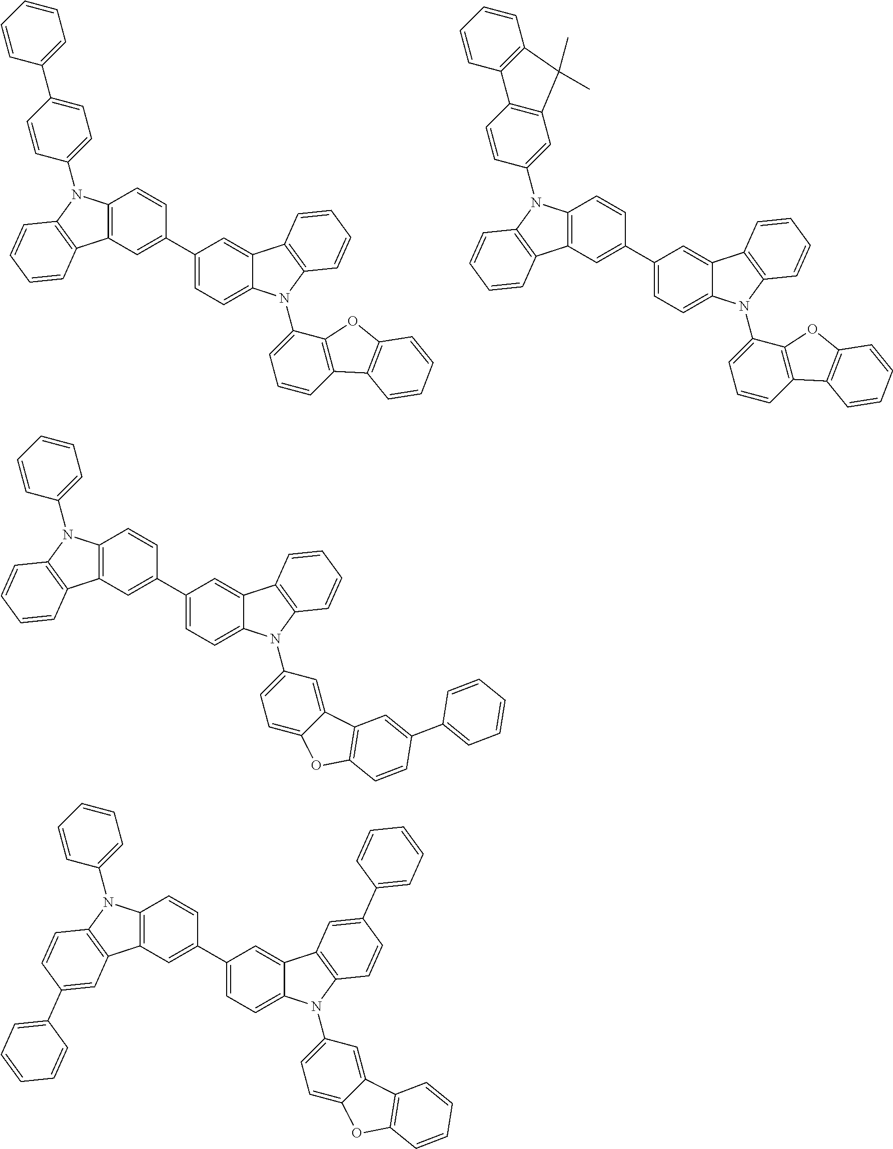 [SMILES: c1ccc(-c2ccc(-n3c4ccccc4c4cc(-c5ccc6c(c5)c5ccccc5n6-c5cccc6c5oc5ccccc56)ccc43)cc2)cc1 ; CC1(C)c2ccccc2-c2ccc(-n3c4ccccc4c4cc(-c5ccc6c(c5)c5ccccc5n6-c5cccc6c5oc5ccccc56)ccc43)cc21 ; c1ccc(-c2ccc3oc4ccc(-n5c6ccccc6c6cc(-c7ccc8c(c7)c7ccccc7n8-c7ccccc7)ccc65)cc4c3c2)cc1 ; c1ccc(-c2ccc3c(c2)c2cc(-c4ccc5c(c4)c4cc(-c6ccccc6)ccc4n5-c4ccc5oc6ccccc6c5c4)ccc2n3-c2ccccc2)cc1]

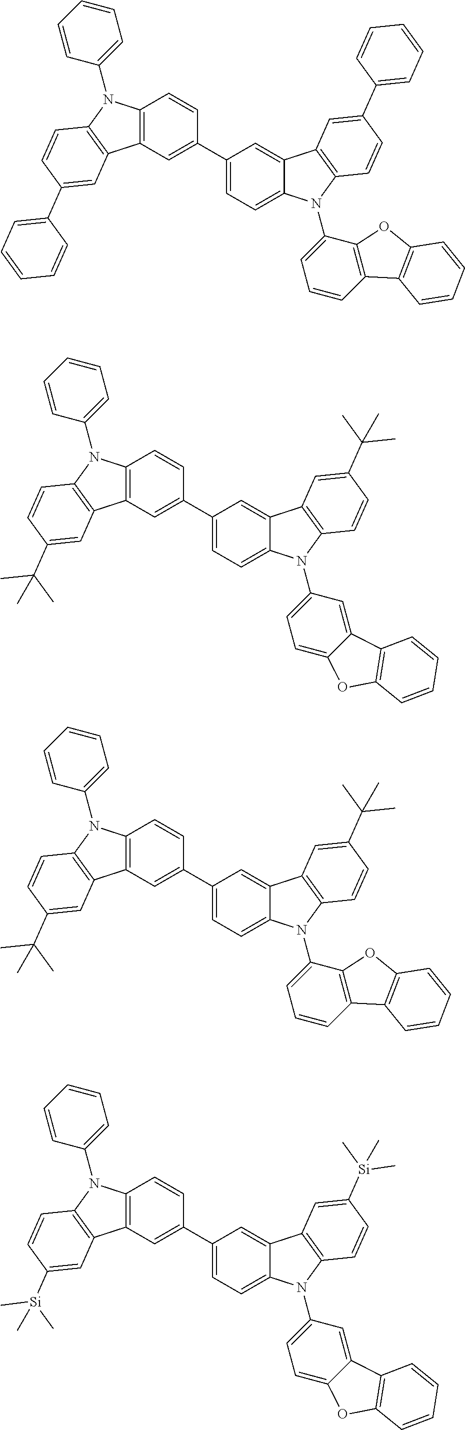 [SMILES: c1ccc(-c2ccc3c(c2)c2cc(-c4ccc5c(c4)c4cc(-c6ccccc6)ccc4n5-c4cccc5c4oc4ccccc45)ccc2n3-c2ccccc2)cc1 ; CC(C)(C)c1ccc2c(c1)c1cc(-c3ccc4c(c3)c3cc(C(C)(C)C)ccc3n4-c3ccc4oc5ccccc5c4c3)ccc1n2-c1ccccc1 ; CC(C)(C)c1ccc2c(c1)c1cc(-c3ccc4c(c3)c3cc(C(C)(C)C)ccc3n4-c3cccc4c3oc3ccccc34)ccc1n2-c1ccccc1 ; C[Si](C)(C)c1ccc2c(c1)c1cc(-c3ccc4c(c3)c3cc([Si](C)(C)C)ccc3n4-c3ccc4oc5ccccc5c4c3)ccc1n2-c1ccccc1]

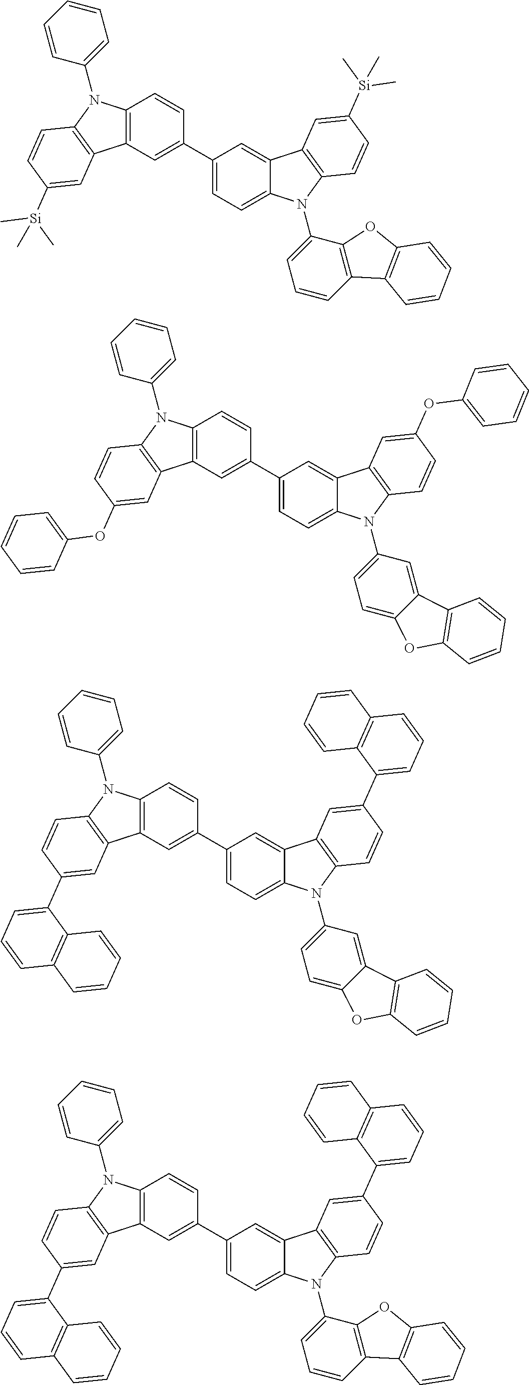 [SMILES: C[Si](C)(C)c1ccc2c(c1)c1cc(-c3ccc4c(c3)c3cc([Si](C)(C)C)ccc3n4-c3cccc4c3oc3ccccc34)ccc1n2-c1ccccc1 ; c1ccc(Oc2ccc3c(c2)c2cc(-c4ccc5c(c4)c4cc(Oc6ccccc6)ccc4n5-c4ccc5oc6ccccc6c5c4)ccc2n3-c2ccccc2)cc1 ; c1ccc(-n2c3ccc(-c4ccc5c(c4)c4cc(-c6cccc7ccccc67)ccc4n5-c4ccc5oc6ccccc6c5c4)cc3c3cc(-c4cccc5ccccc45)ccc32)cc1 ; c1ccc(-n2c3ccc(-c4ccc5c(c4)c4cc(-c6cccc7ccccc67)ccc4n5-c4cccc5c4oc4ccccc45)cc3c3cc(-c4cccc5ccccc45)ccc32)cc1]

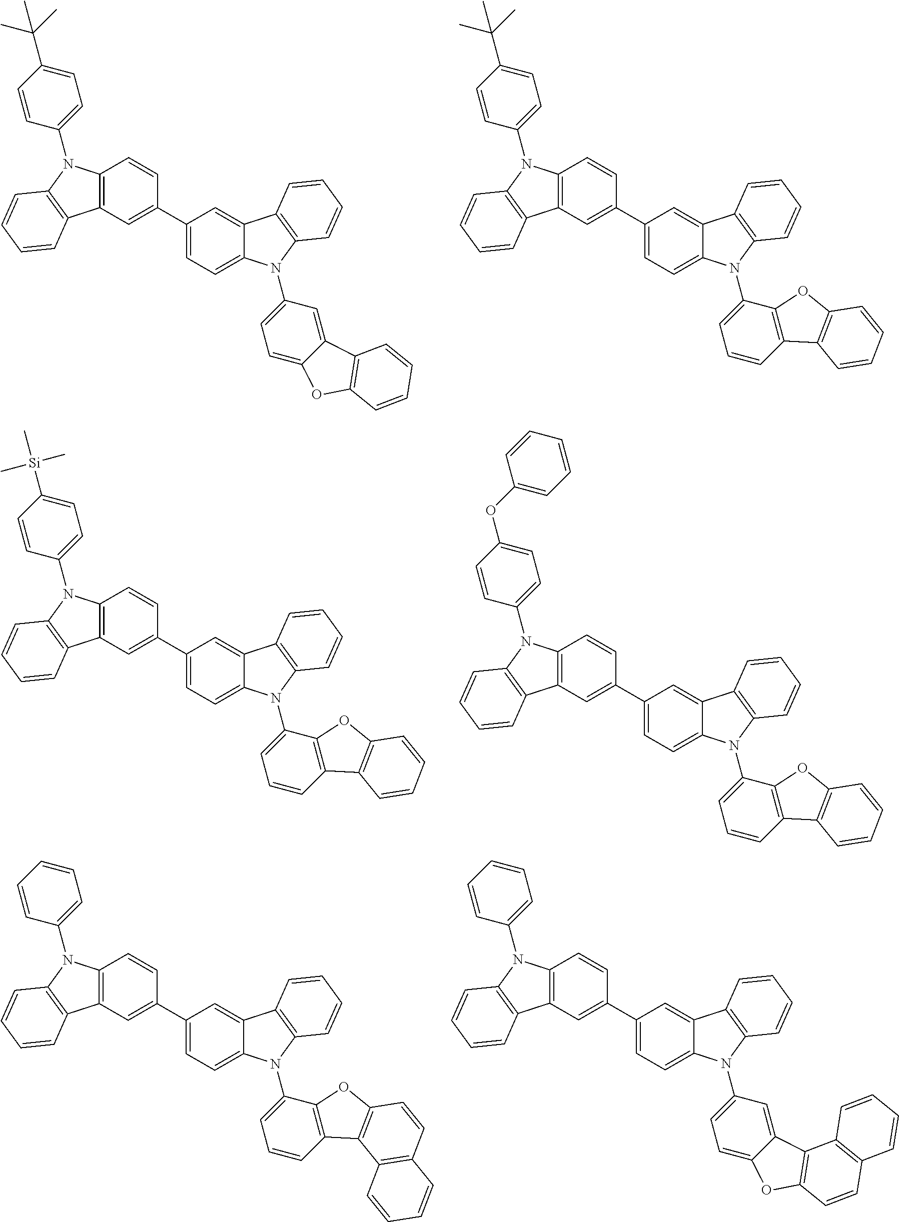

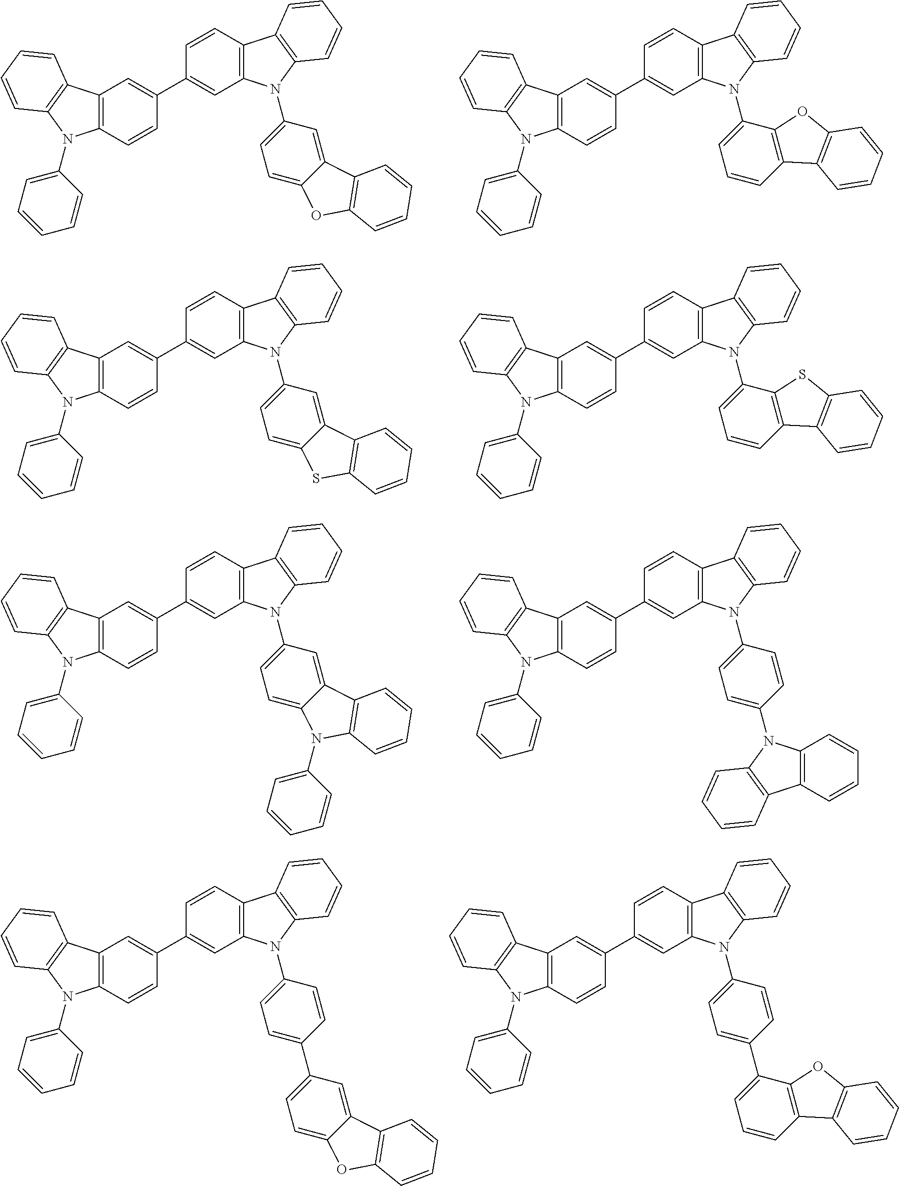

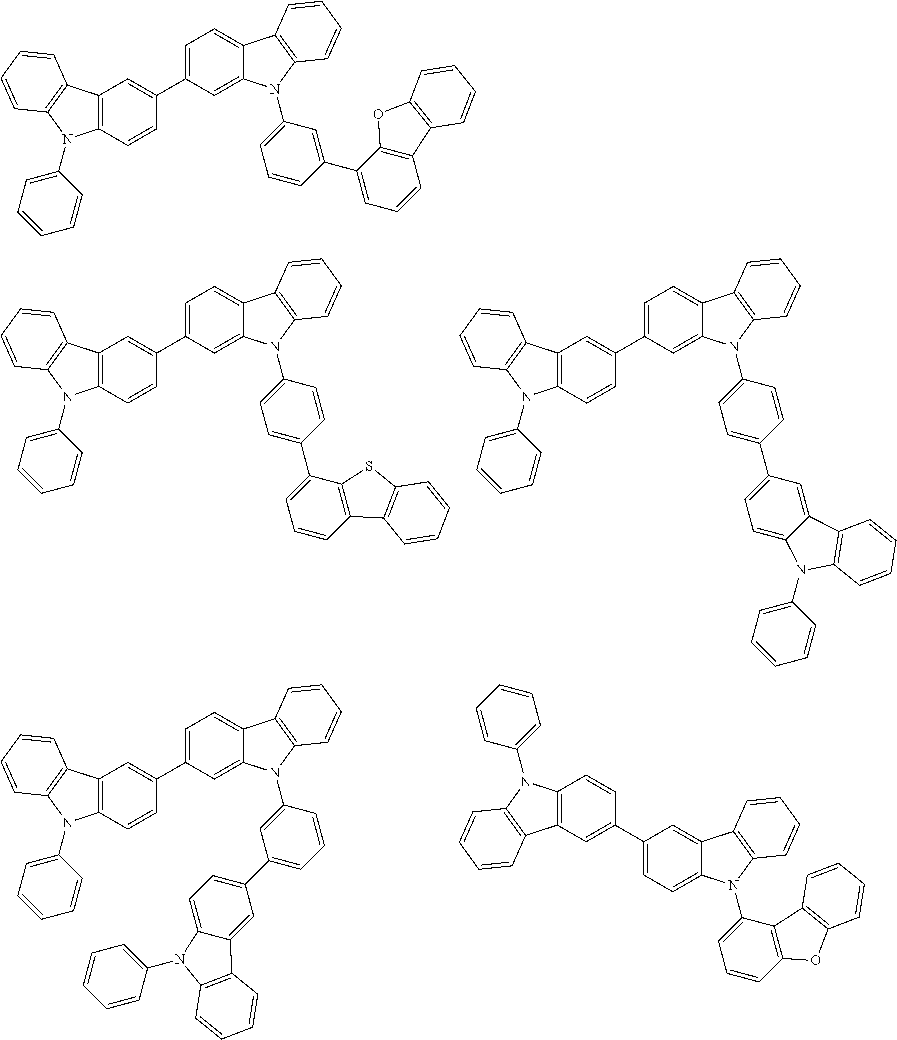 [SMILES: c1ccc(-n2c3ccccc3c3cc(-c4ccc5c6ccccc6n(-c6cccc(-c7cccc8c7oc7ccccc78)c6)c5c4)ccc32)cc1 ; c1ccc(-n2c3ccccc3c3cc(-c4ccc5c6ccccc6n(-c6ccc(-c7cccc8c7sc7ccccc78)cc6)c5c4)ccc32)cc1 ; c1ccc(-n2c3ccccc3c3cc(-c4ccc(-n5c6ccccc6c6ccc(-c7ccc8c(c7)c7ccccc7n8-c7ccccc7)cc65)cc4)ccc32)cc1 ; c1ccc(-n2c3ccccc3c3cc(-c4cccc(-n5c6ccccc6c6ccc(-c7ccc8c(c7)c7ccccc7n8-c7ccccc7)cc65)c4)ccc32)cc1 ; c1ccc(-n2c3ccccc3c3cc(-c4ccc5c(c4)c4ccccc4n5-c4cccc5oc6ccccc6c45)ccc32)cc1]

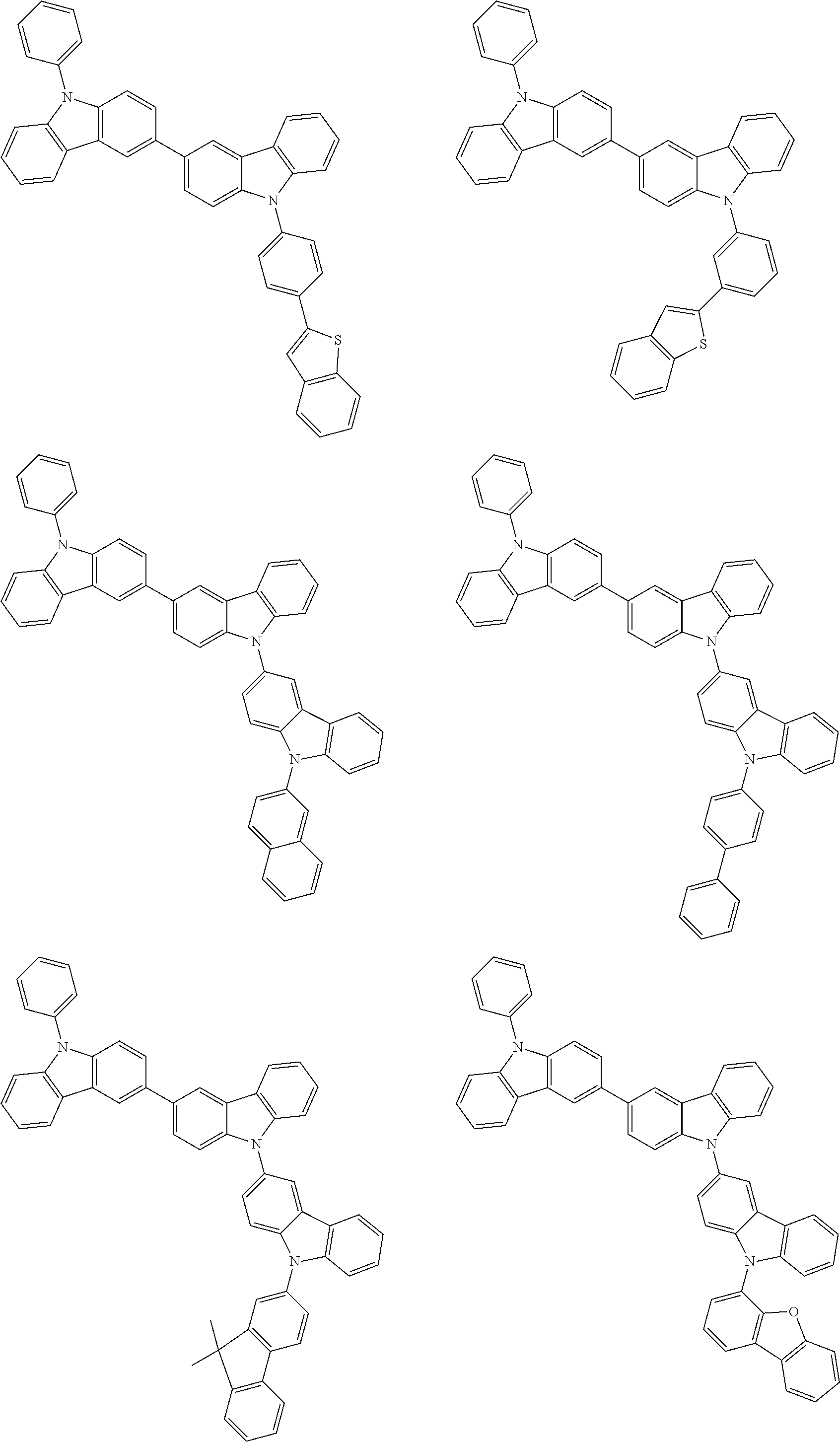

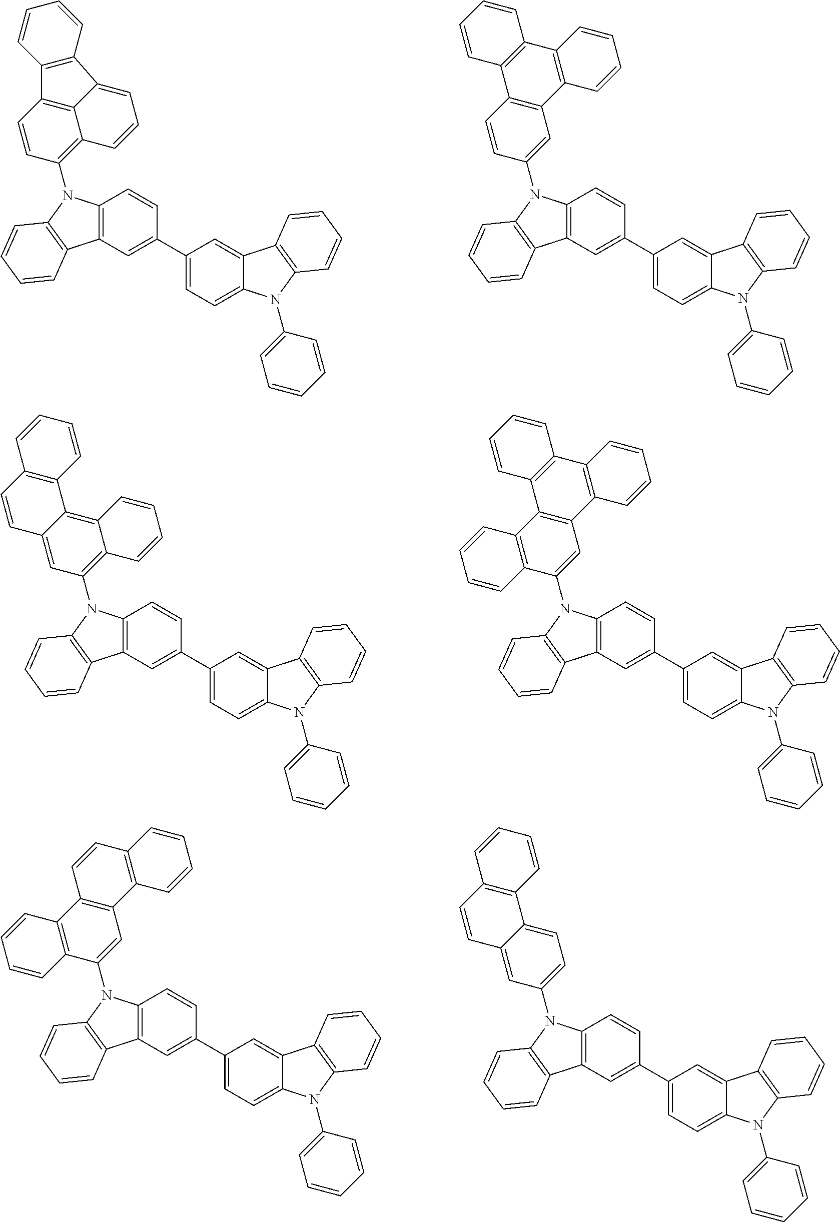

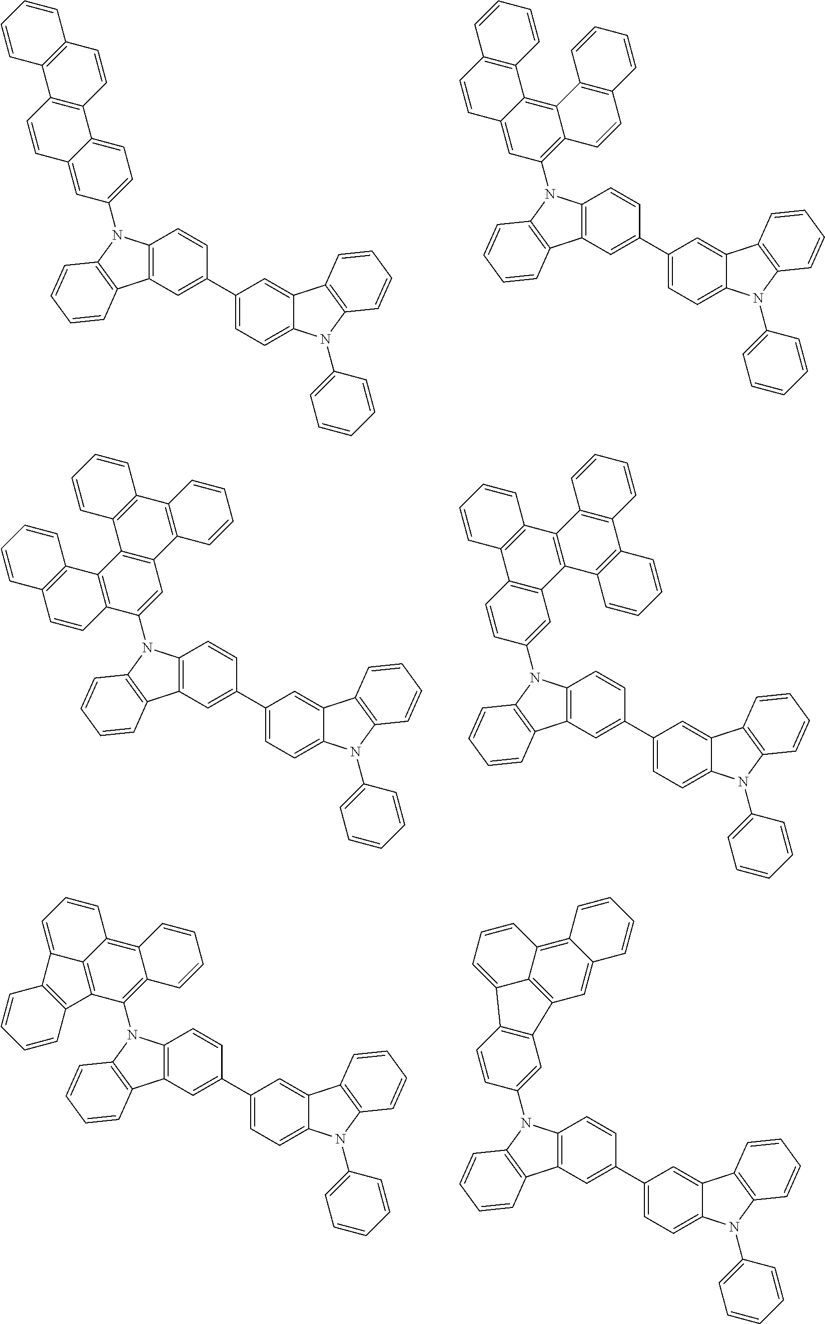

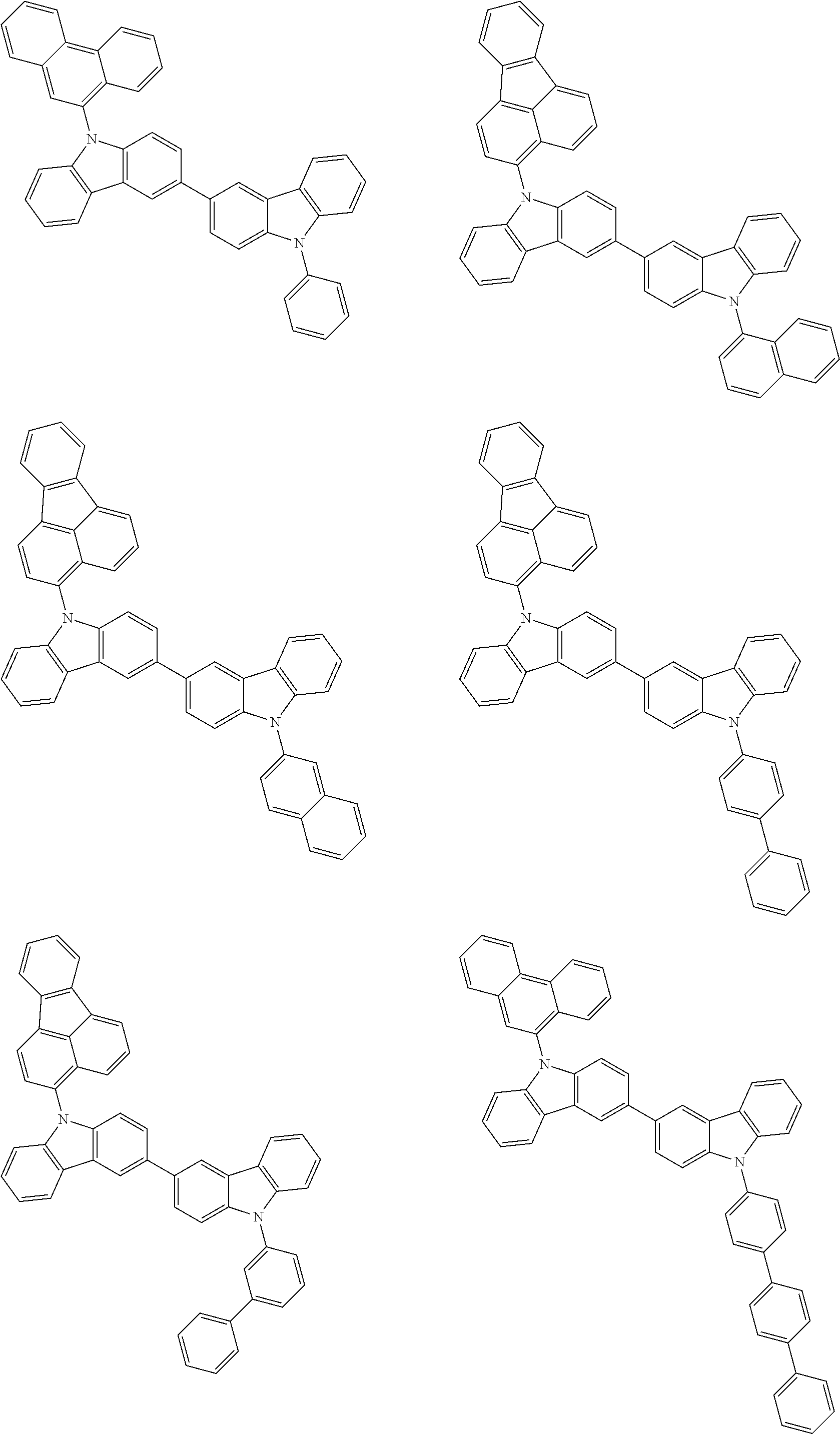

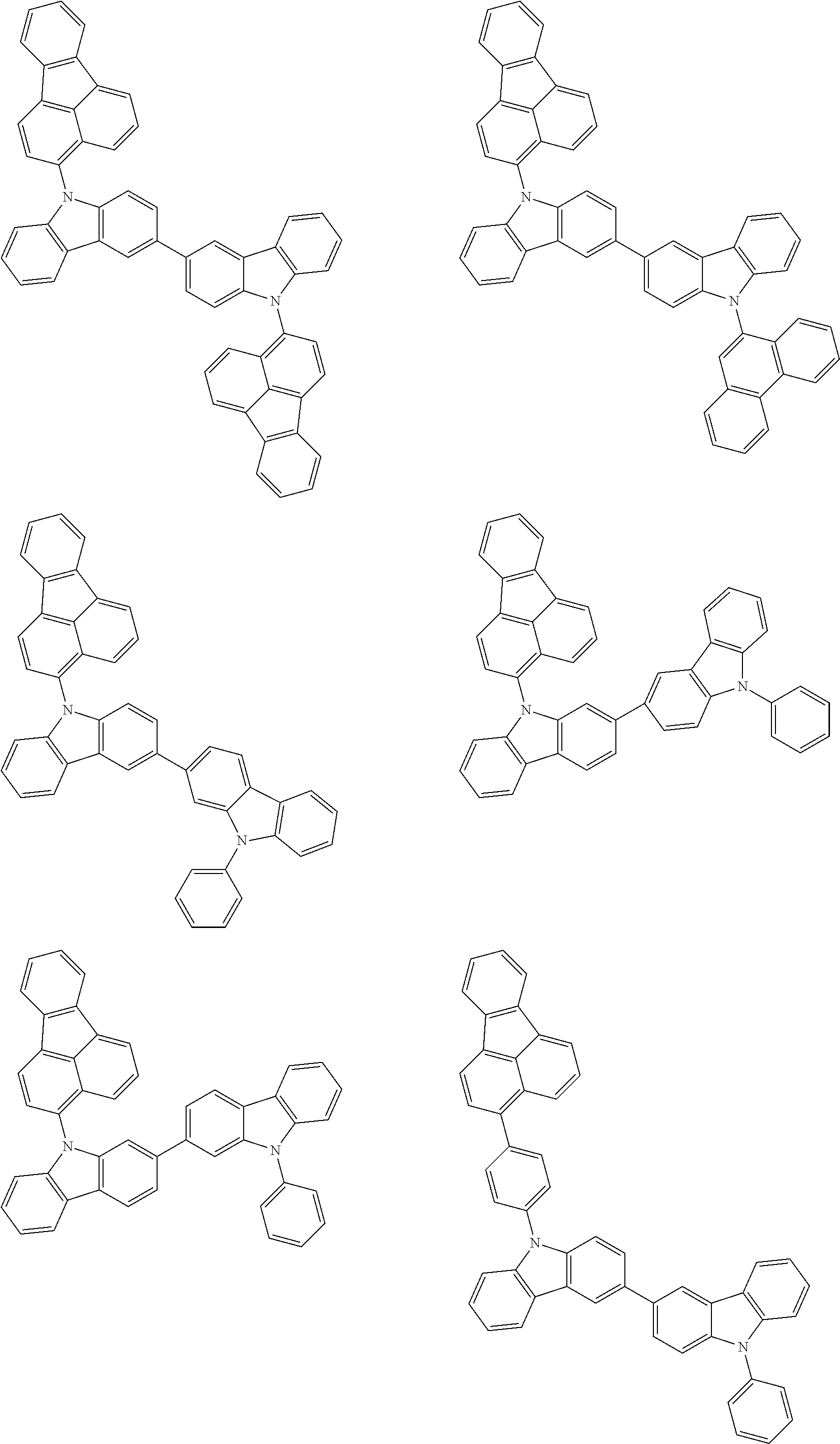

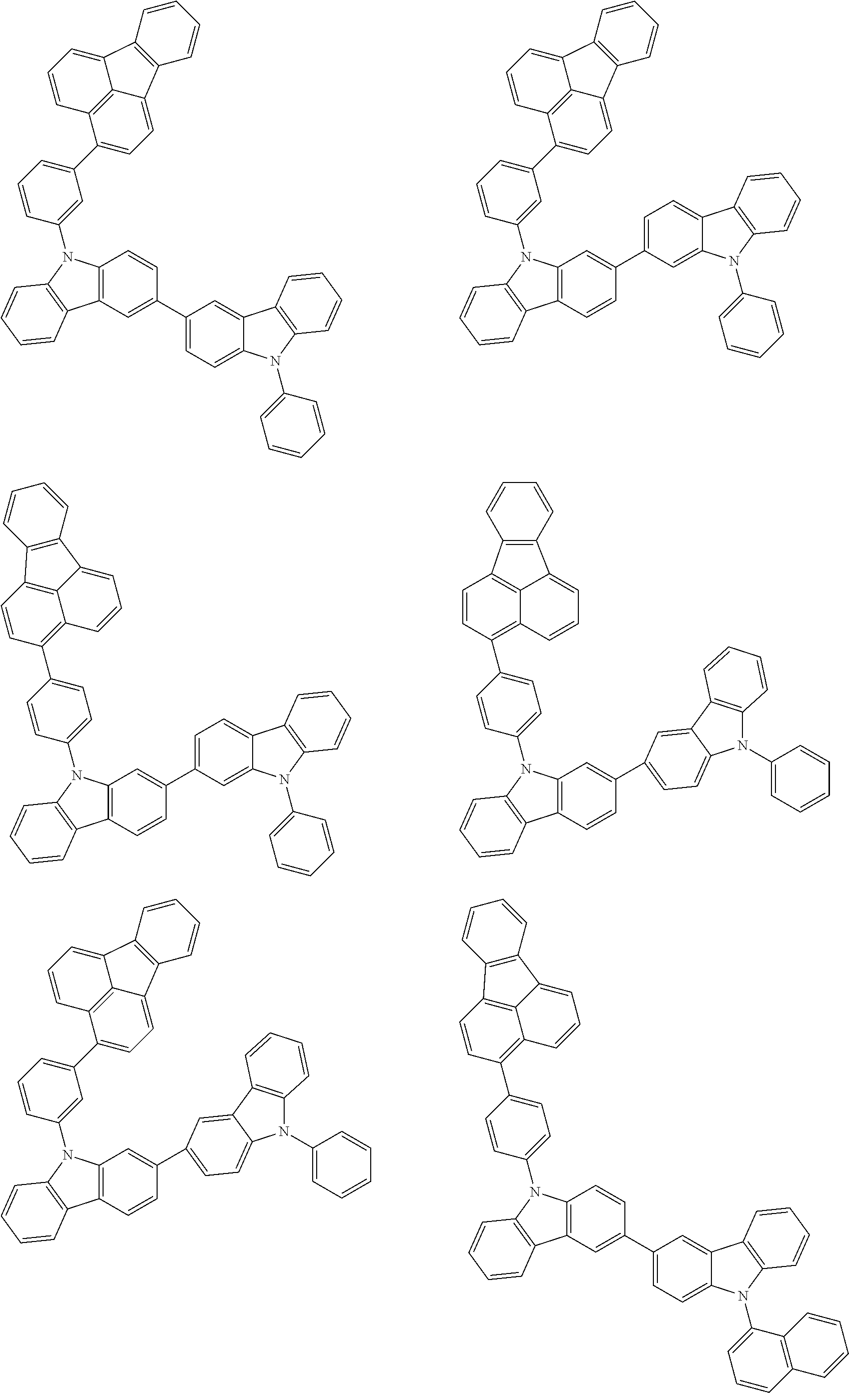

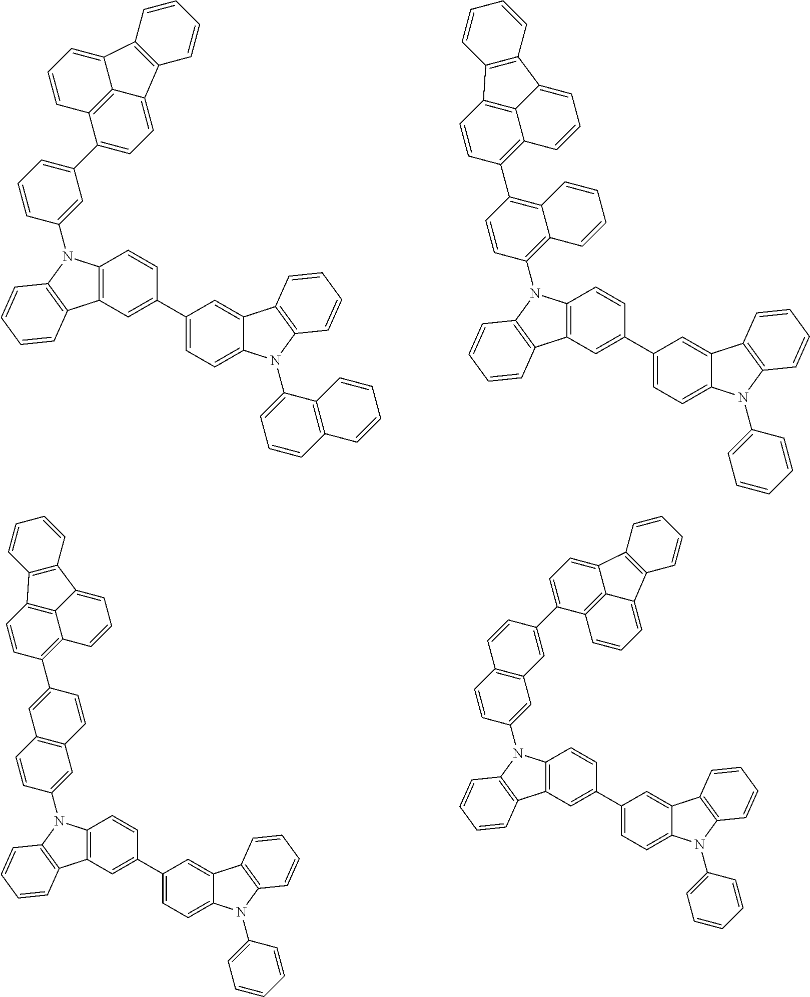 [SMILES: c1cc(-c2ccc3c4c(cccc24)-c2ccccc2-3)cc(-n2c3ccccc3c3cc(-c4ccc5c(c4)c4ccccc4n5-c4cccc5ccccc45)ccc32)c1 ; c1ccc(-n2c3ccccc3c3cc(-c4ccc5c(c4)c4ccccc4n5-c4ccc(-c5ccc6c7c(cccc57)-c5ccccc5-6)c5ccccc45)ccc32)cc1 ; c1ccc(-n2c3ccccc3c3cc(-c4ccc5c(c4)c4ccccc4n5-c4ccc5cc(-c6ccc7c8c(cccc68)-c6ccccc6-7)ccc5c4)ccc32)cc1 ; c1ccc(-n2c3ccccc3c3cc(-c4ccc5c(c4)c4ccccc4n5-c4ccc5ccc(-c6ccc7c8c(cccc68)-c6ccccc6-7)cc5c4)ccc32)cc1]

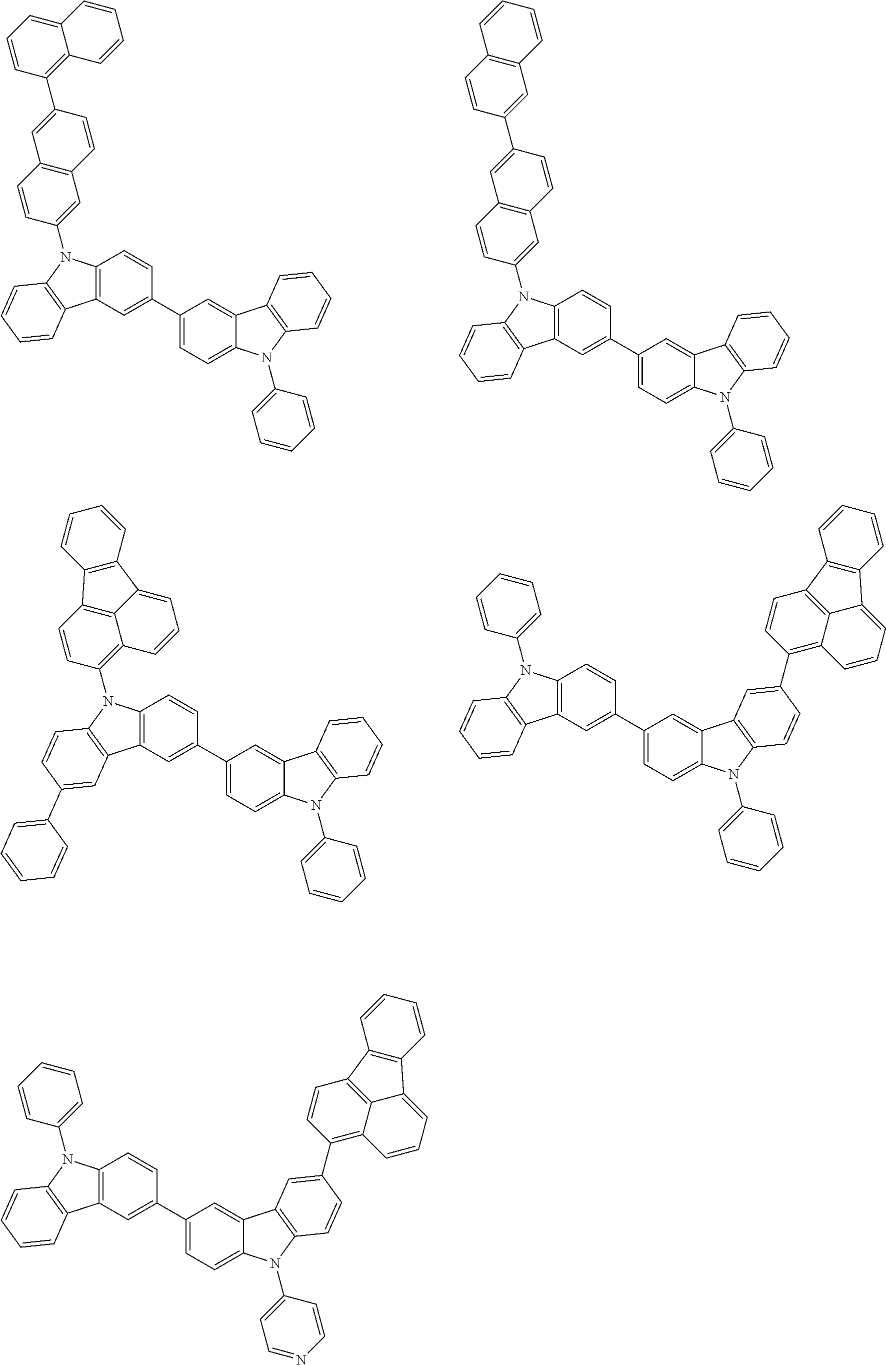 [SMILES: c1ccc(-n2c3ccccc3c3cc(-c4ccc5c(c4)c4ccccc4n5-c4ccc5cc(-c6cccc7ccccc67)ccc5c4)ccc32)cc1 ; c1ccc(-n2c3ccccc3c3cc(-c4ccc5c(c4)c4ccccc4n5-c4ccc5cc(-c6ccc7ccccc7c6)ccc5c4)ccc32)cc1 ; c1ccc(-c2ccc3c(c2)c2cc(-c4ccc5c(c4)c4ccccc4n5-c4ccccc4)ccc2n3-c2ccc3c4c(cccc24)-c2ccccc2-3)cc1 ; c1ccc(-n2c3ccccc3c3cc(-c4ccc5c(c4)c4cc(-c6ccc7c8c(cccc68)-c6ccccc6-7)ccc4n5-c4ccccc4)ccc32)cc1 ; c1ccc(-n2c3ccccc3c3cc(-c4ccc5c(c4)c4cc(-c6ccc7c8c(cccc68)-c6ccccc6-7)ccc4n5-c4ccncc4)ccc32)cc1]

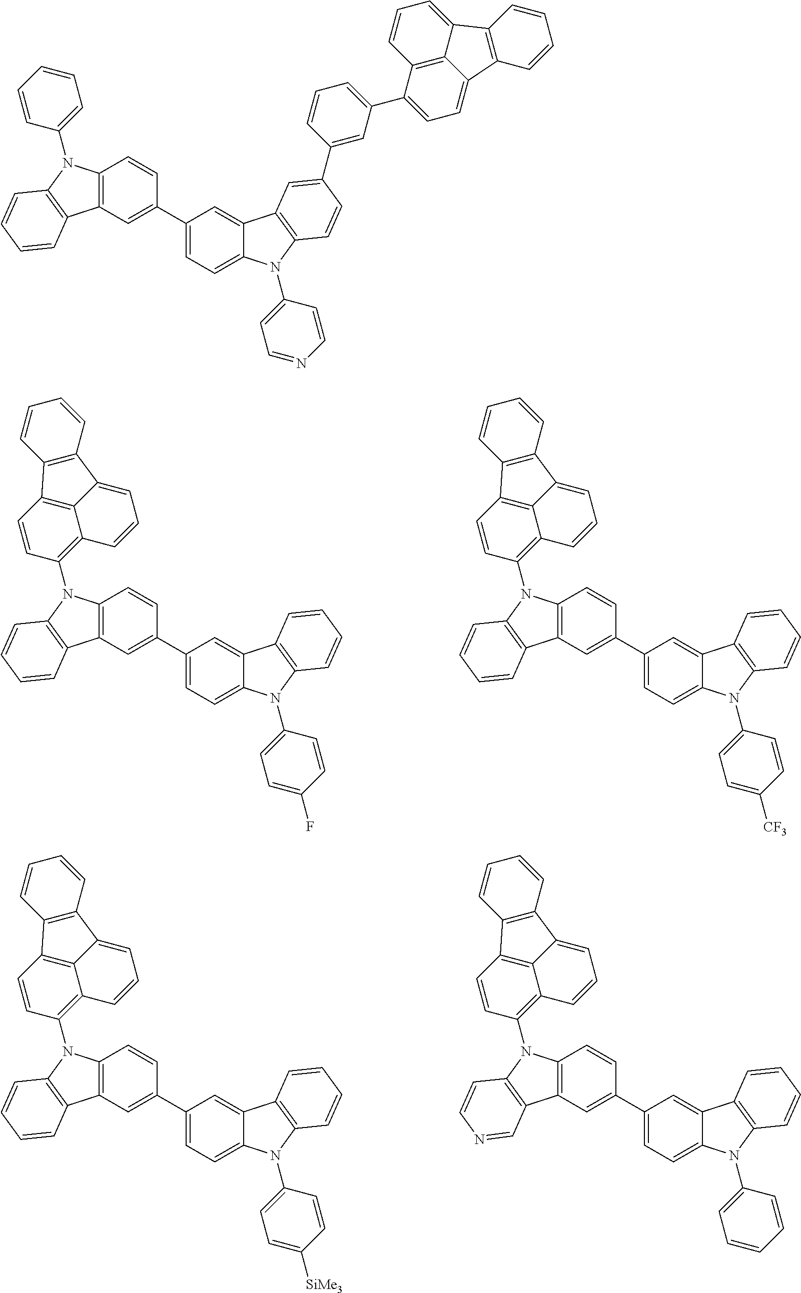 [SMILES: c1ccc(-n2c3ccccc3c3cc(-c4ccc5c(c4)c4cc(-c6cccc(-c7ccc8c9c(cccc79)-c7ccccc7-8)c6)ccc4n5-c4ccncc4)ccc32)cc1 ; Fc1ccc(-n2c3ccccc3c3cc(-c4ccc5c(c4)c4ccccc4n5-c4ccc5c6c(cccc46)-c4ccccc4-5)ccc32)cc1 ; FC(F)(F)c1ccc(-n2c3ccccc3c3cc(-c4ccc5c(c4)c4ccccc4n5-c4ccc5c6c(cccc46)-c4ccccc4-5)ccc32)cc1 ; C[Si](C)(C)c1ccc(-n2c3ccccc3c3cc(-c4ccc5c(c4)c4ccccc4n5-c4ccc5c6c(cccc46)-c4ccccc4-5)ccc32)cc1 ; c1ccc(-n2c3ccccc3c3cc(-c4ccc5c(c4)c4cnccc4n5-c4ccc5c6c(cccc46)-c4ccccc4-5)ccc32)cc1]

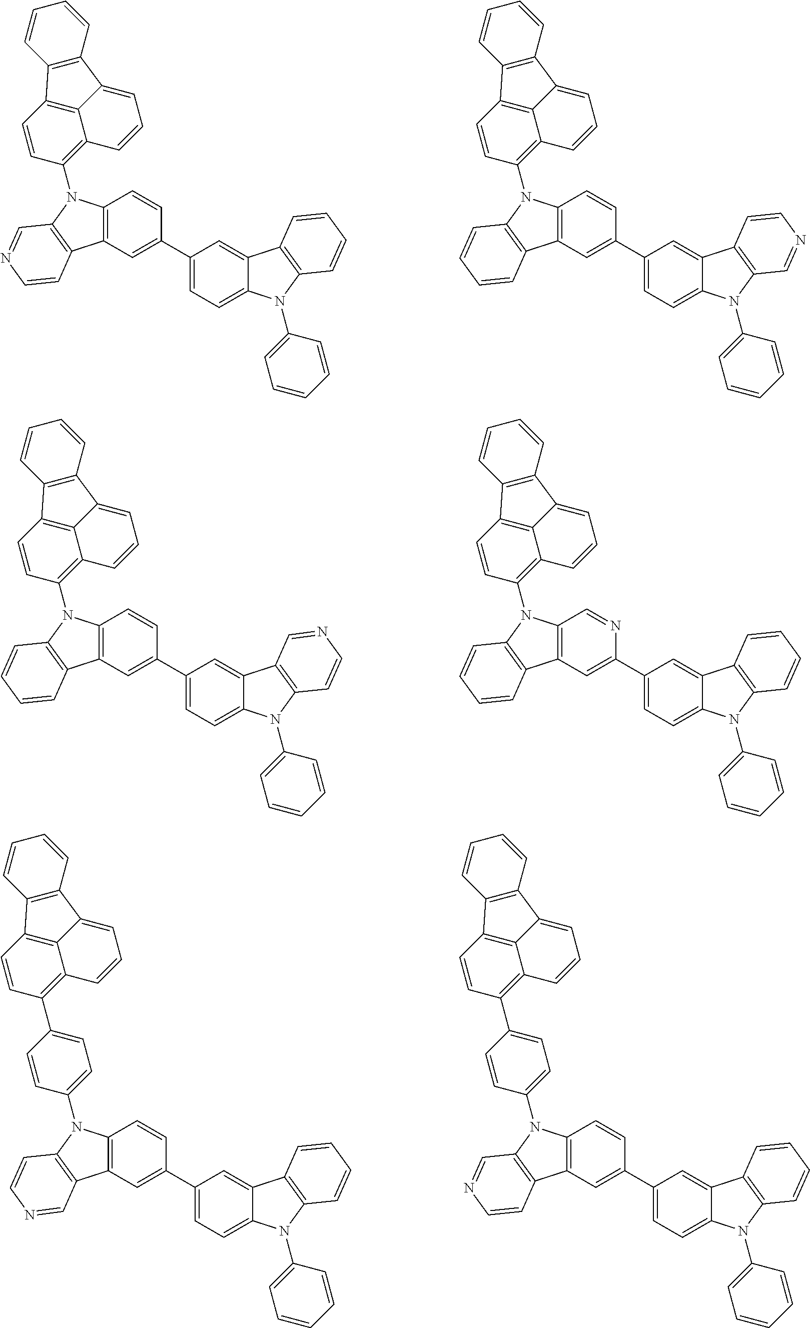

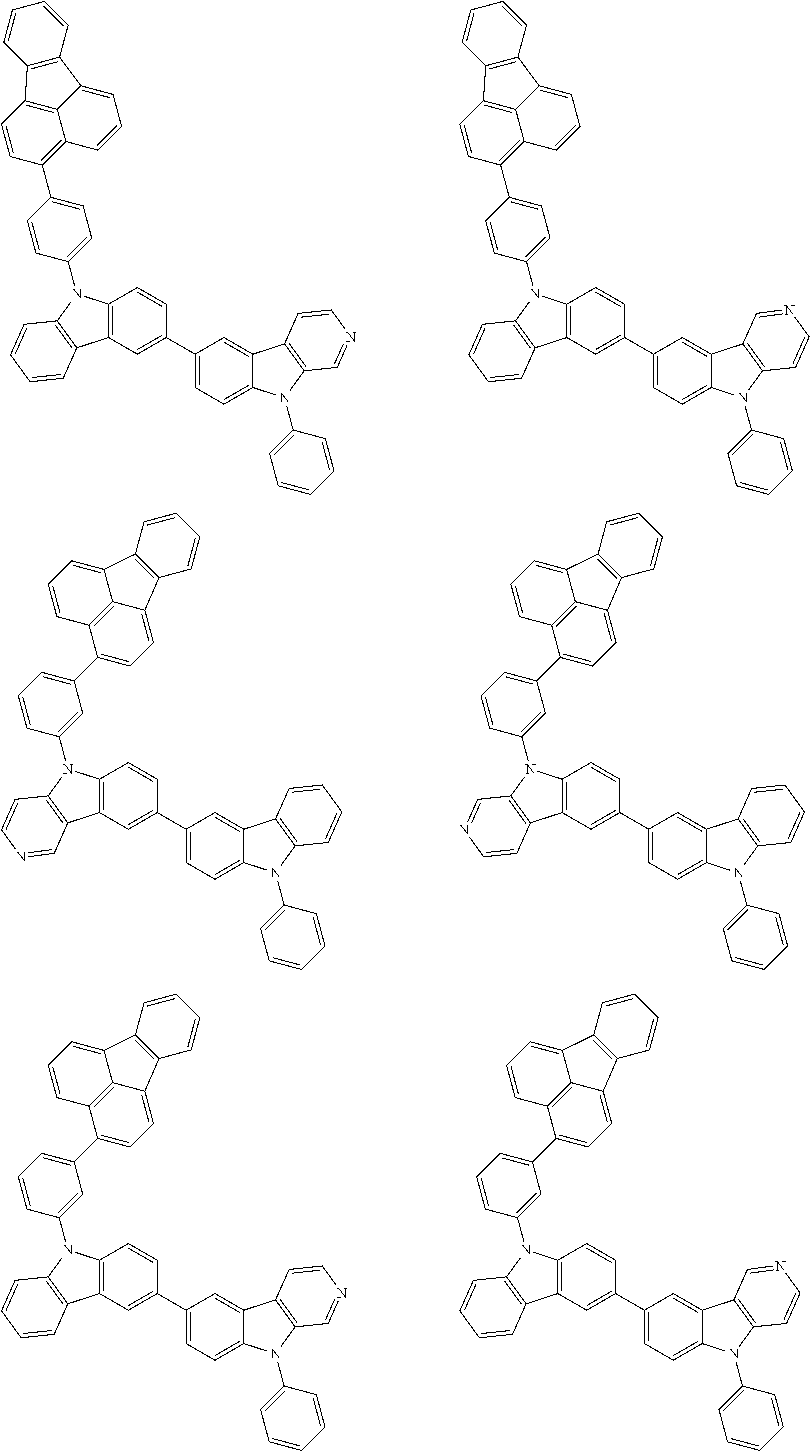

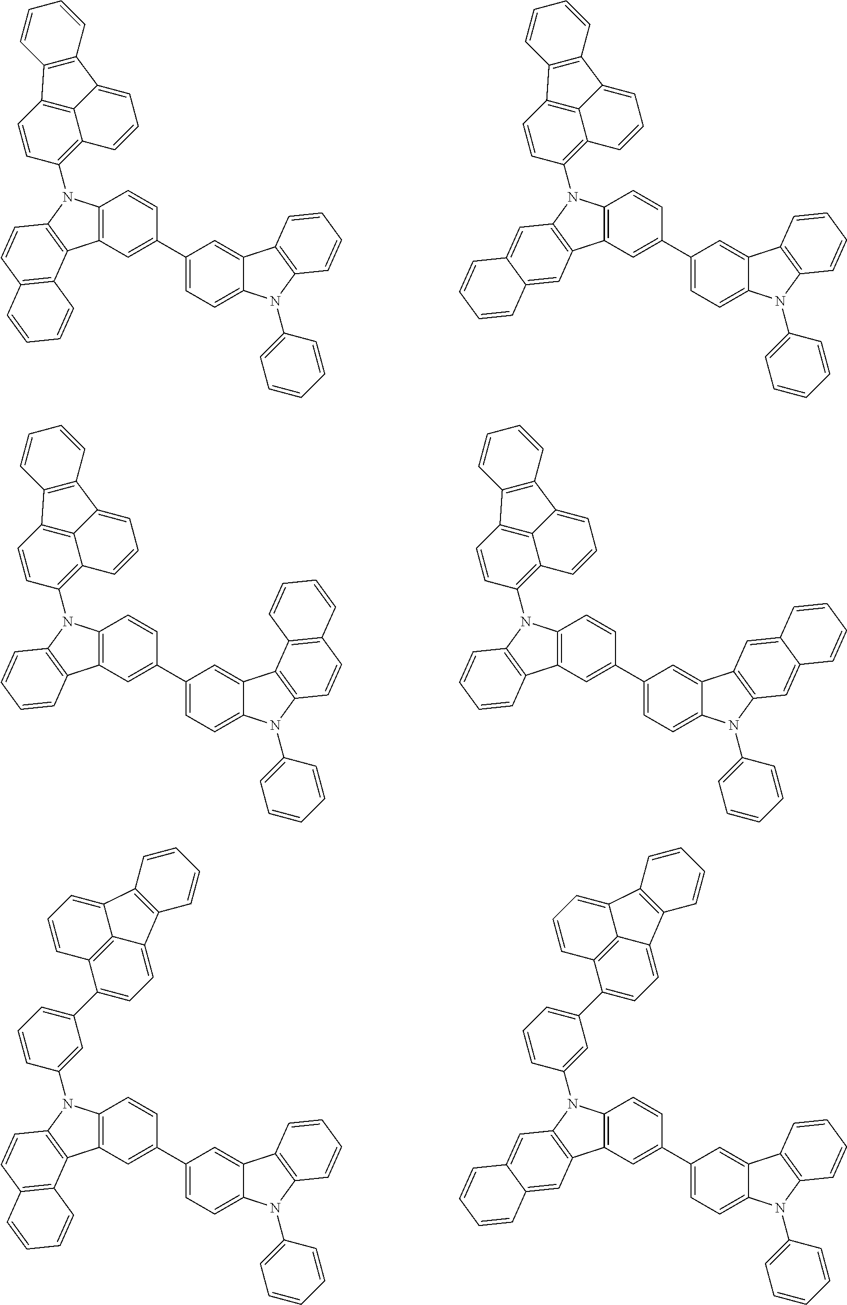

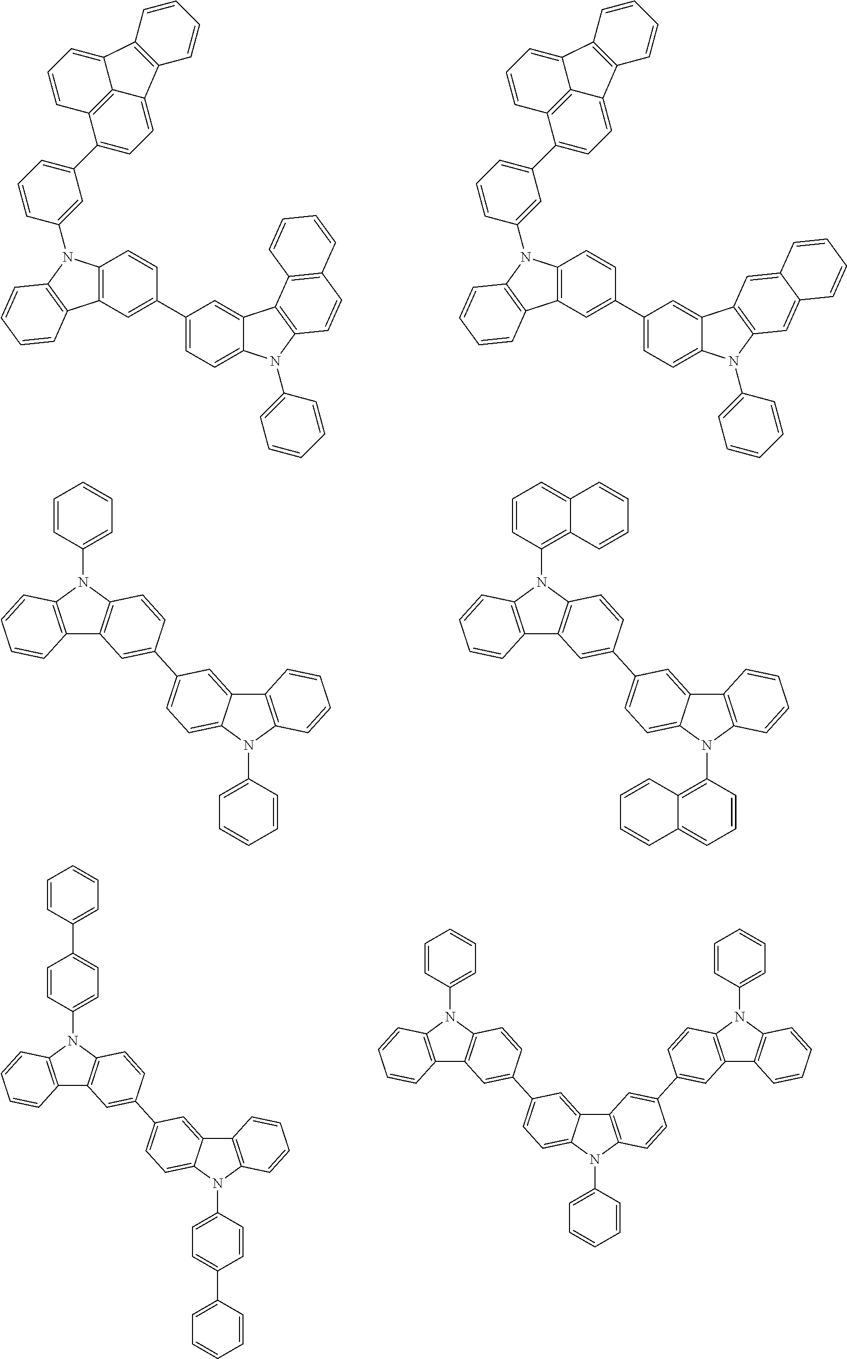

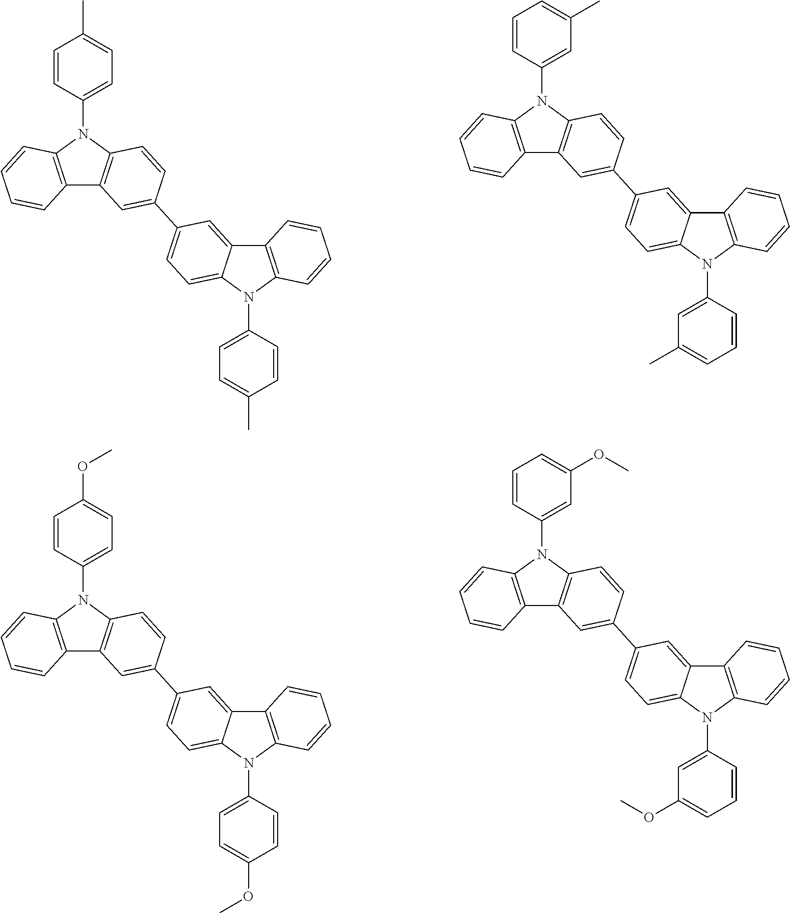 [SMILES: Cc1ccc(-n2c3ccccc3c3cc(-c4ccc5c(c4)c4ccccc4n5-c4ccc(C)cc4)ccc32)cc1 ; Cc1cccc(-n2c3ccccc3c3cc(-c4ccc5c(c4)c4ccccc4n5-c4cccc(C)c4)ccc32)c1 ; COc1ccc(-n2c3ccccc3c3cc(-c4ccc5c(c4)c4ccccc4n5-c4ccc(OC)cc4)ccc32)cc1 ; COc1cccc(-n2c3ccccc3c3cc(-c4ccc5c(c4)c4ccccc4n5-c4cccc(OC)c4)ccc32)c1]

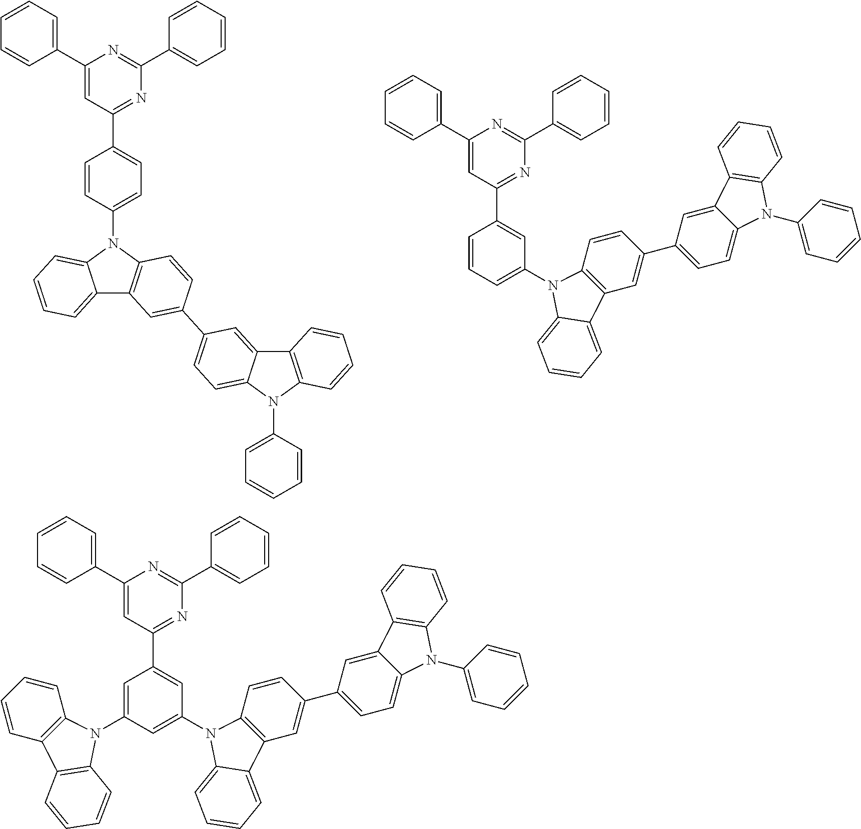

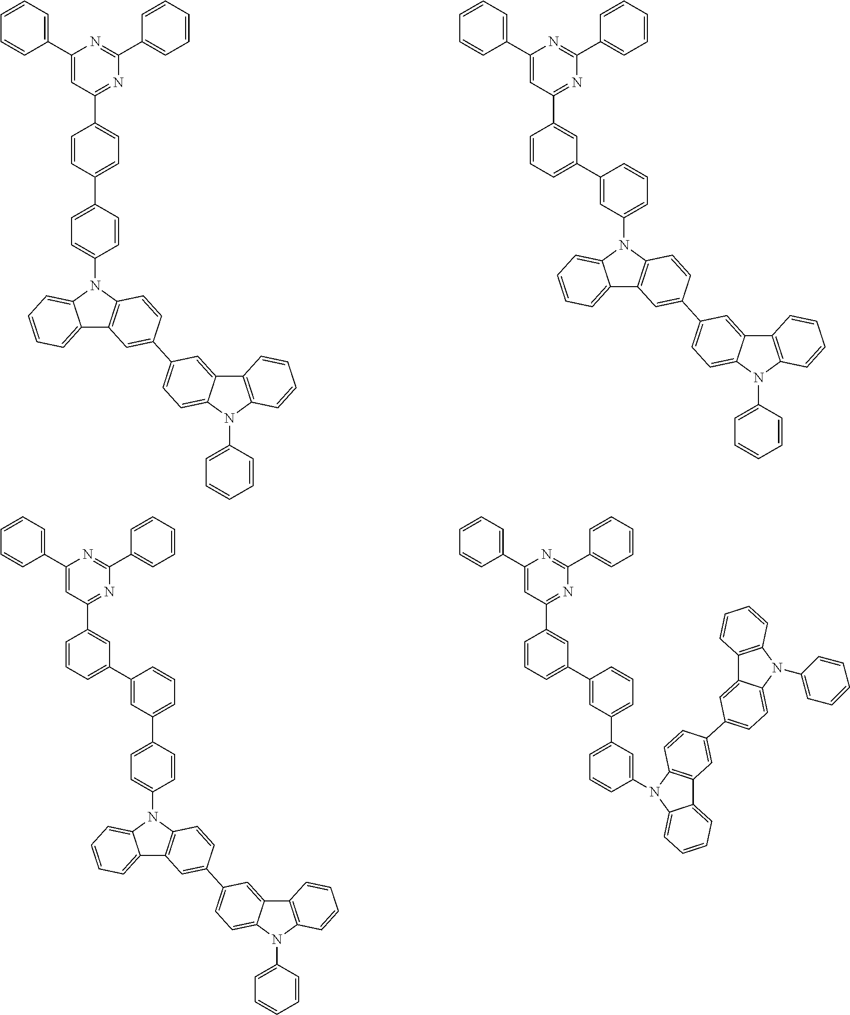 [SMILES: c1ccc(-c2cc(-c3ccc(-c4ccc(-n5c6ccccc6c6cc(-c7ccc8c(c7)c7ccccc7n8-c7ccccc7)ccc65)cc4)cc3)nc(-c3ccccc3)n2)cc1 ; c1ccc(-c2cc(-c3cccc(-c4cccc(-n5c6ccccc6c6cc(-c7ccc8c(c7)c7ccccc7n8-c7ccccc7)ccc65)c4)c3)nc(-c3ccccc3)n2)cc1 ; c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)nc(-c3ccccc3)n2)cc1 ; c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)nc(-c3ccccc3)n2)cc1]

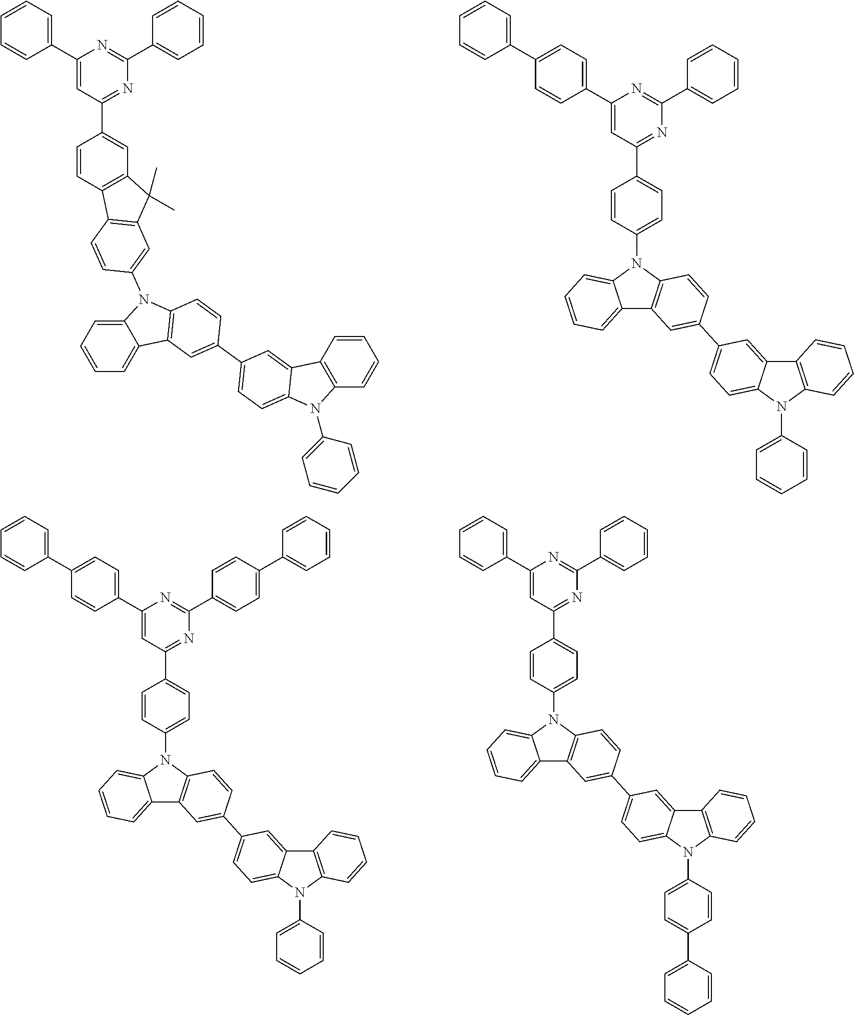

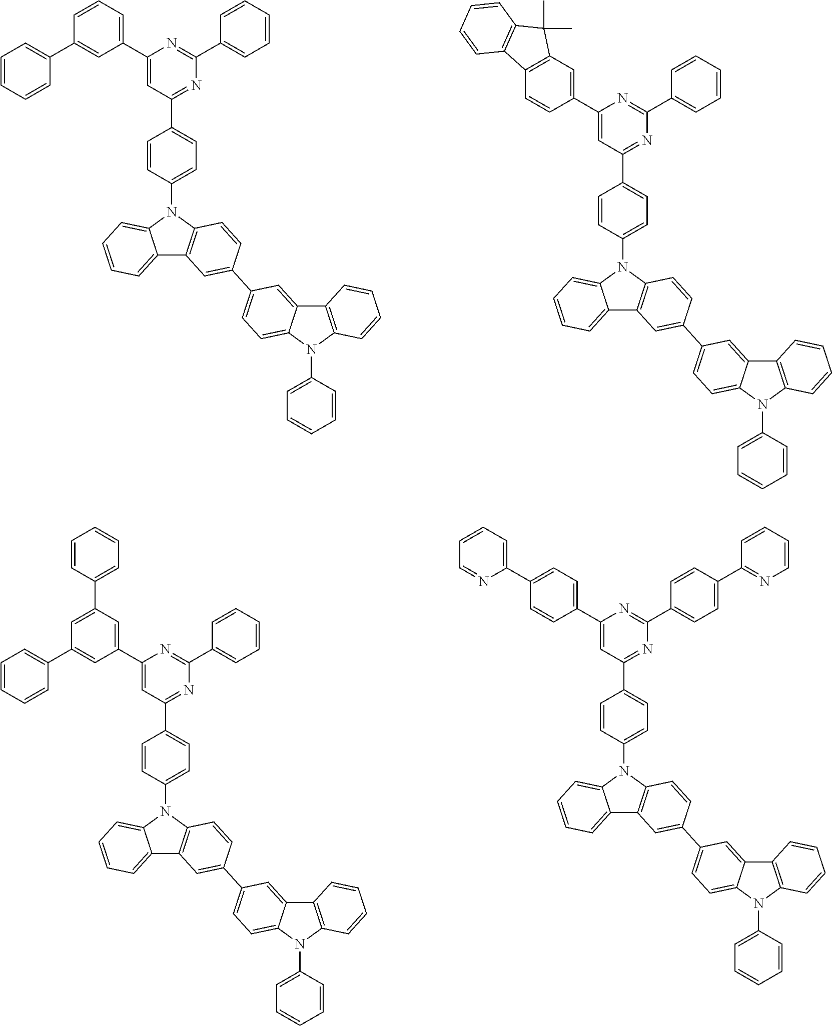 [SMILES: c1ccc(-c2cccc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; CC1(C)c2ccccc2-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc21 ; c1ccc(-c2cc(-c3ccccc3)cc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; c1ccc(-n2c3ccccc3c3cc(-c4ccc5c(c4)c4ccccc4n5-c4ccc(-c5cc(-c6ccc(-c7ccccn7)cc6)nc(-c6ccc(-c7ccccn7)cc6)n5)cc4)ccc32)cc1]

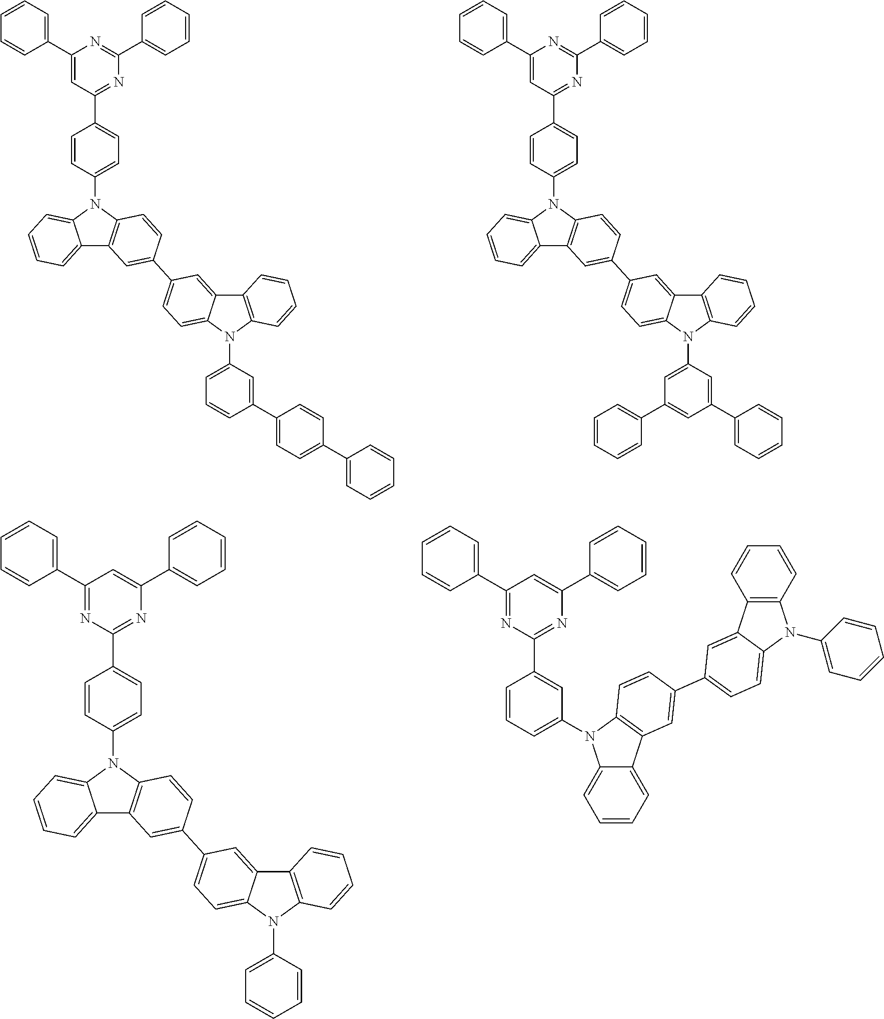 [SMILES: c1ccc(-c2ccc(-c3cccc(-n4c5ccccc5c5cc(-c6ccc7c(c6)c6ccccc6n7-c6ccc(-c7cc(-c8ccccc8)nc(-c8ccccc8)n7)cc6)ccc54)c3)cc2)cc1 ; c1ccc(-c2cc(-c3ccccc3)cc(-n3c4ccccc4c4cc(-c5ccc6c(c5)c5ccccc5n6-c5ccc(-c6cc(-c7ccccc7)nc(-c7ccccc7)n6)cc5)ccc43)c2)cc1 ; c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1]

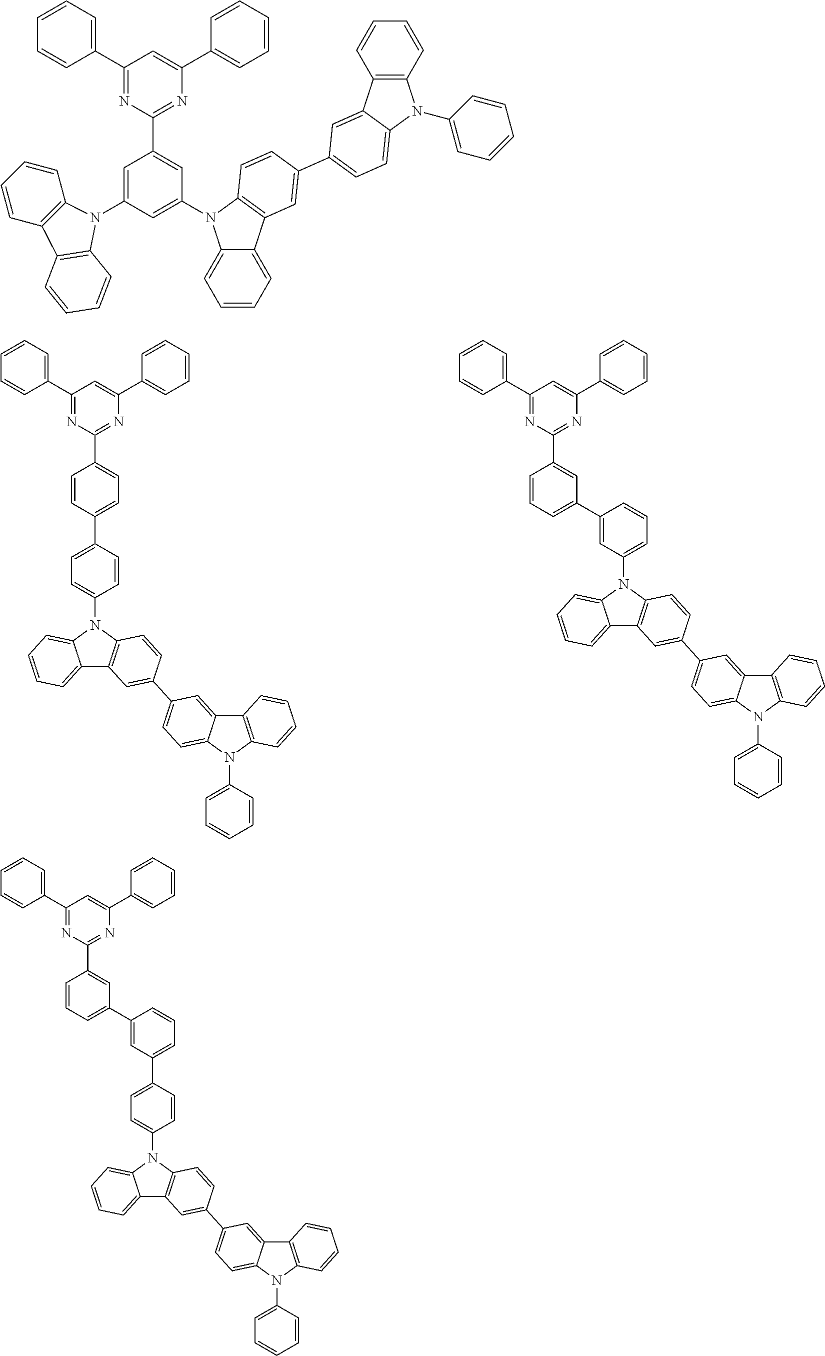 [SMILES: c1ccc(-c2cc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1]

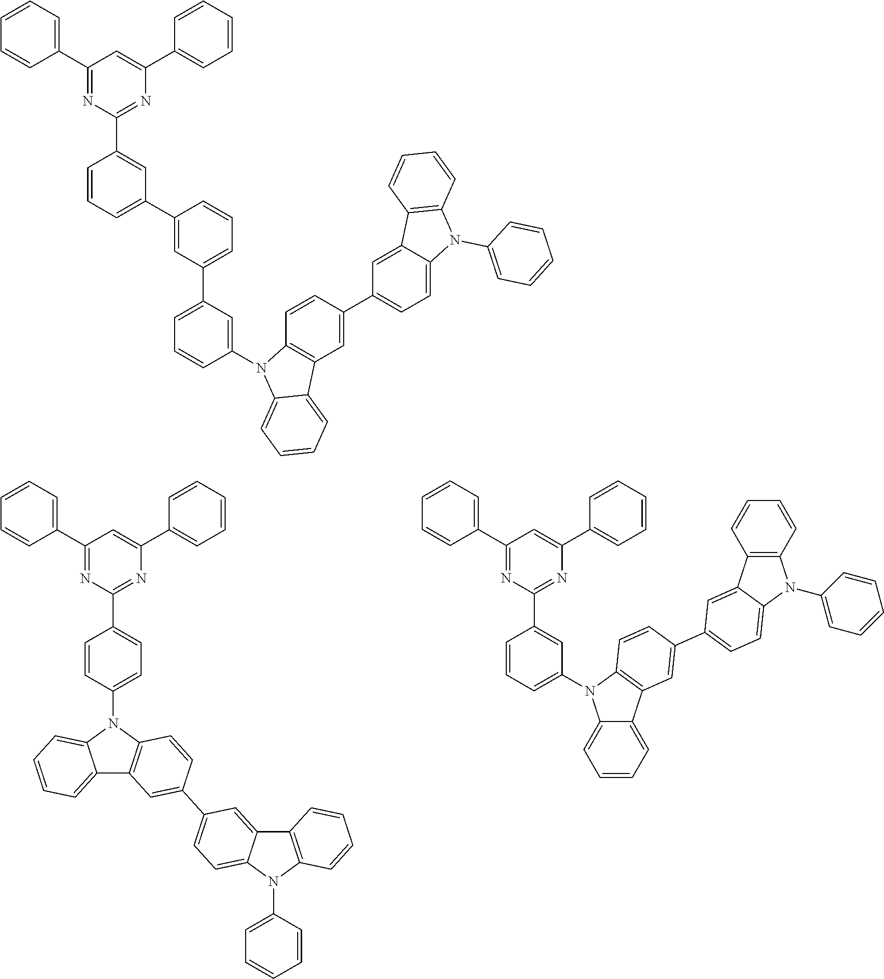 [SMILES: c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1 ; c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1]

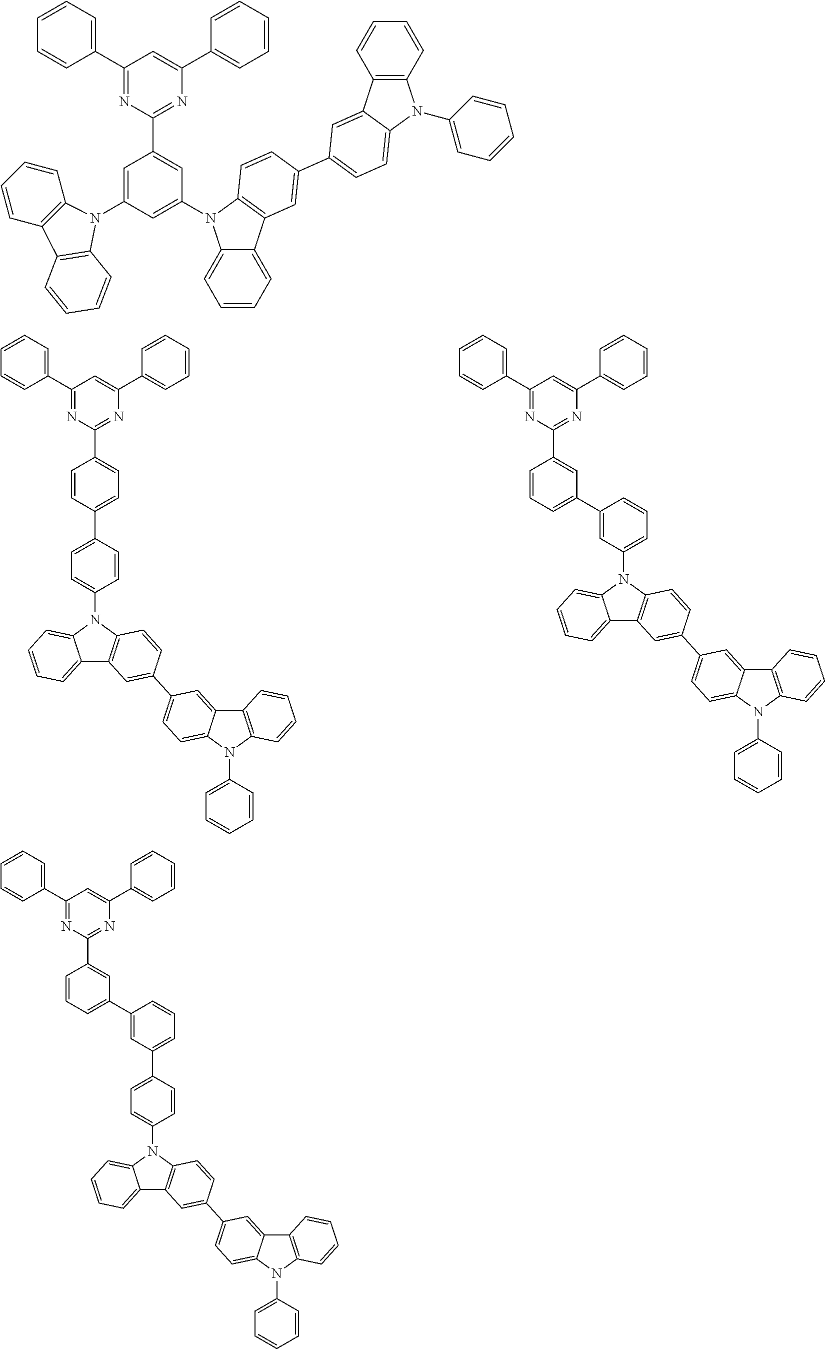 [SMILES: c1ccc(-c2cc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1]

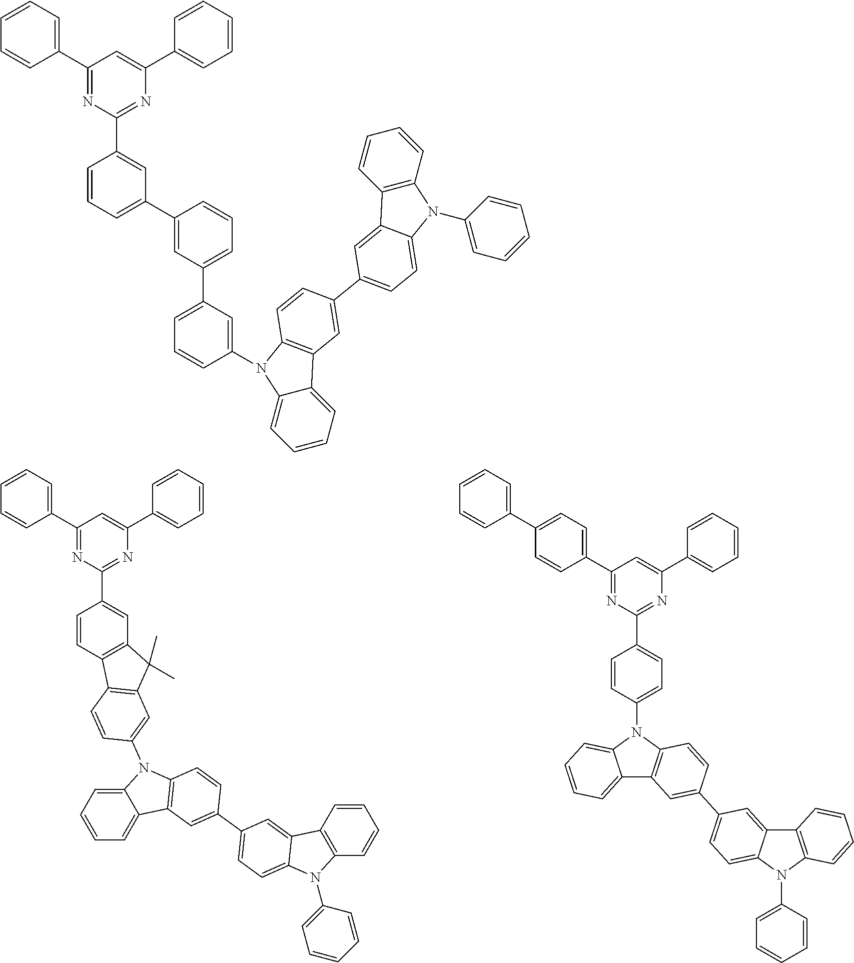 [SMILES: c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1 ; CC1(C)c2cc(-c3nc(-c4ccccc4)cc(-c4ccccc4)n3)ccc2-c2ccc(-n3c4ccccc4c4cc(-c5ccc6c(c5)c5ccccc5n6-c5ccccc5)ccc43)cc21 ; c1ccc(-c2ccc(-c3cc(-c4ccccc4)nc(-c4ccc(-n5c6ccccc6c6cc(-c7ccc8c(c7)c7ccccc7n8-c7ccccc7)ccc65)cc4)n3)cc2)cc1]

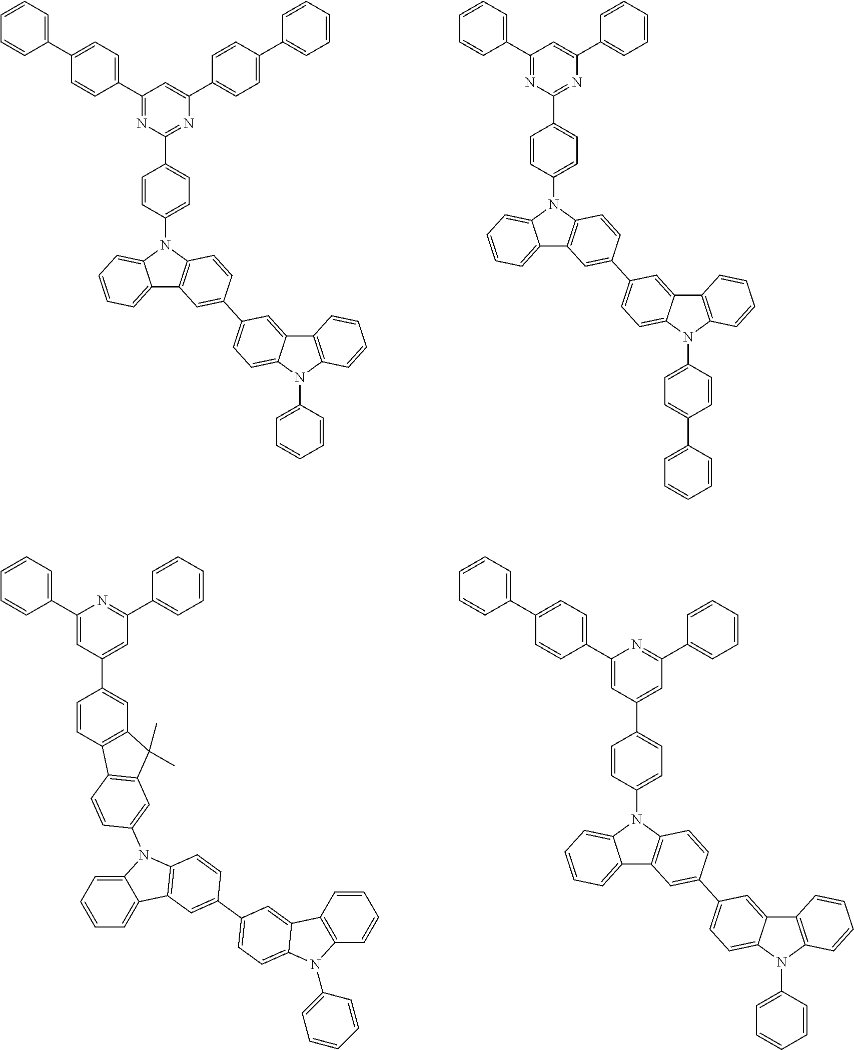 [SMILES: c1ccc(-c2ccc(-c3cc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-n3c4ccccc4c4cc(-c5ccc6c(c5)c5ccccc5n6-c5ccc(-c6nc(-c7ccccc7)cc(-c7ccccc7)n6)cc5)ccc43)cc2)cc1 ; CC1(C)c2cc(-c3cc(-c4ccccc4)nc(-c4ccccc4)c3)ccc2-c2ccc(-n3c4ccccc4c4cc(-c5ccc6c(c5)c5ccccc5n6-c5ccccc5)ccc43)cc21 ; c1ccc(-c2ccc(-c3cc(-c4ccc(-n5c6ccccc6c6cc(-c7ccc8c(c7)c7ccccc7n8-c7ccccc7)ccc65)cc4)cc(-c4ccccc4)n3)cc2)cc1]

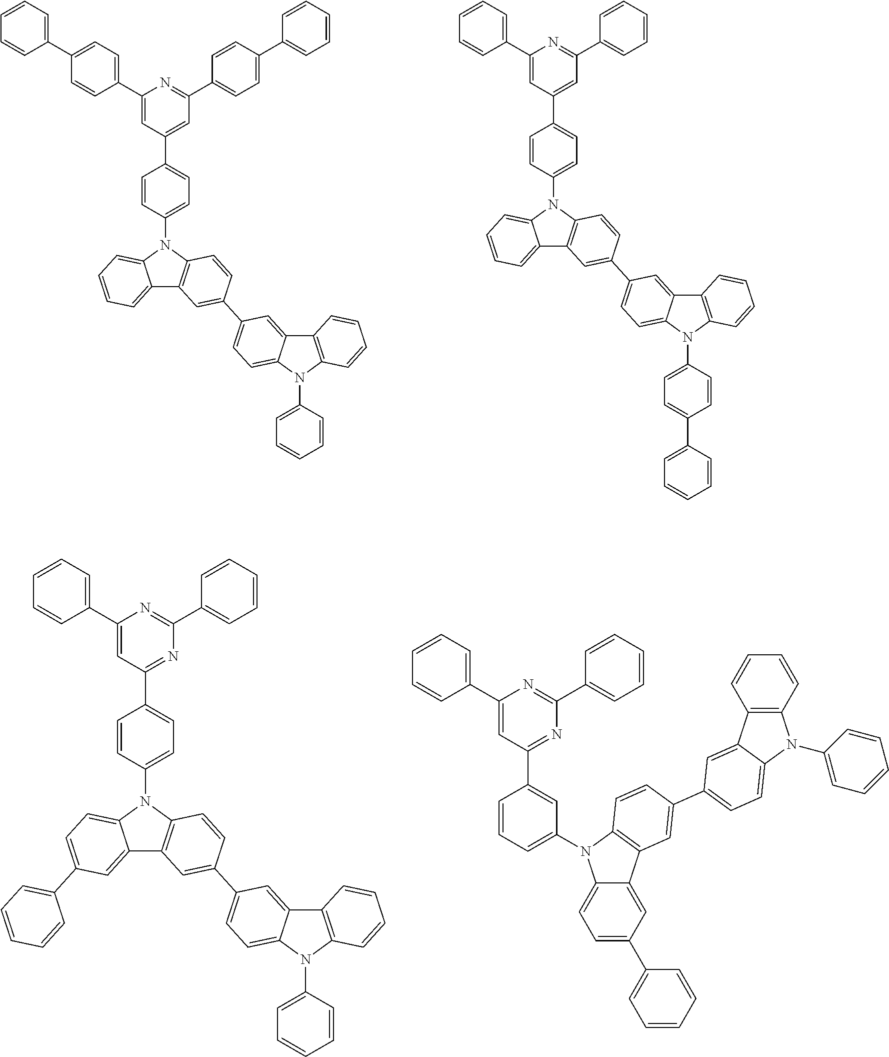 [SMILES: c1ccc(-c2ccc(-c3cc(-c4ccc(-n5c6ccccc6c6cc(-c7ccc8c(c7)c7ccccc7n8-c7ccccc7)ccc65)cc4)cc(-c4ccc(-c5ccccc5)cc4)n3)cc2)cc1 ; c1ccc(-c2ccc(-n3c4ccccc4c4cc(-c5ccc6c(c5)c5ccccc5n6-c5ccc(-c6cc(-c7ccccc7)nc(-c7ccccc7)c6)cc5)ccc43)cc2)cc1 ; c1ccc(-c2ccc3c(c2)c2cc(-c4ccc5c(c4)c4ccccc4n5-c4ccccc4)ccc2n3-c2ccc(-c3cc(-c4ccccc4)nc(-c4ccccc4)n3)cc2)cc1 ; c1ccc(-c2ccc3c(c2)c2cc(-c4ccc5c(c4)c4ccccc4n5-c4ccccc4)ccc2n3-c2cccc(-c3cc(-c4ccccc4)nc(-c4ccccc4)n3)c2)cc1]

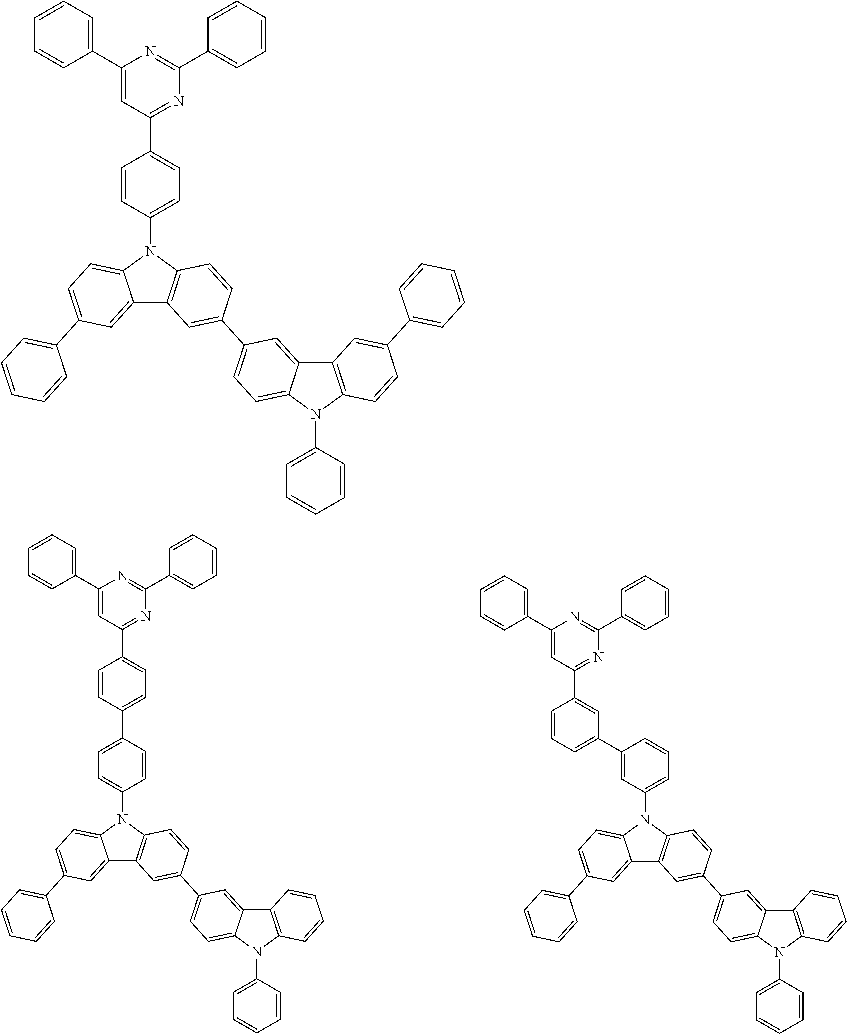 [SMILES: c1ccc(-c2ccc3c(c2)c2cc(-c4ccc5c(c4)c4cc(-c6ccccc6)ccc4n5-c4ccc(-c5cc(-c6ccccc6)nc(-c6ccccc6)n5)cc4)ccc2n3-c2ccccc2)cc1 ; c1ccc(-c2ccc3c(c2)c2cc(-c4ccc5c(c4)c4ccccc4n5-c4ccccc4)ccc2n3-c2ccc(-c3ccc(-c4cc(-c5ccccc5)nc(-c5ccccc5)n4)cc3)cc2)cc1 ; c1ccc(-c2ccc3c(c2)c2cc(-c4ccc5c(c4)c4ccccc4n5-c4ccccc4)ccc2n3-c2cccc(-c3cccc(-c4cc(-c5ccccc5)nc(-c5ccccc5)n4)c3)c2)cc1]

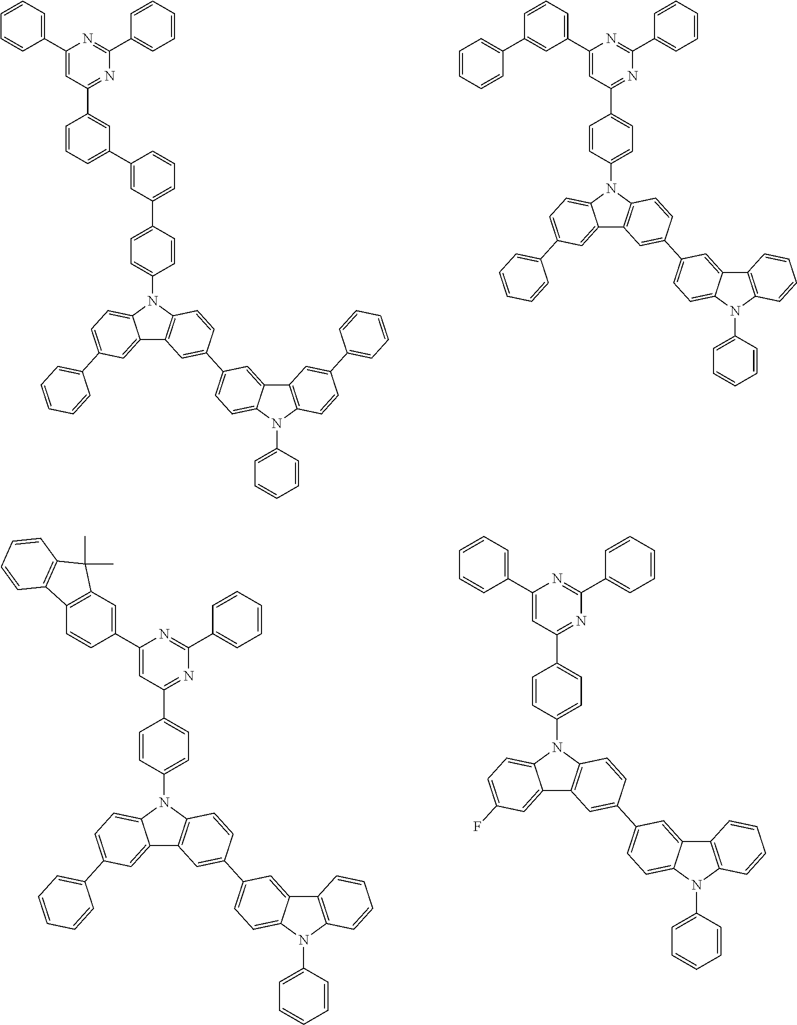 [SMILES: c1ccc(-c2ccc3c(c2)c2cc(-c4ccc5c(c4)c4cc(-c6ccccc6)ccc4n5-c4ccc(-c5cccc(-c6cccc(-c7cc(-c8ccccc8)nc(-c8ccccc8)n7)c6)c5)cc4)ccc2n3-c2ccccc2)cc1 ; c1ccc(-c2cccc(-c3cc(-c4ccc(-n5c6ccc(-c7ccccc7)cc6c6cc(-c7ccc8c(c7)c7ccccc7n8-c7ccccc7)ccc65)cc4)nc(-c4ccccc4)n3)c2)cc1 ; CC1(C)c2ccccc2-c2ccc(-c3cc(-c4ccc(-n5c6ccc(-c7ccccc7)cc6c6cc(-c7ccc8c(c7)c7ccccc7n8-c7ccccc7)ccc65)cc4)nc(-c4ccccc4)n3)cc21 ; Fc1ccc2c(c1)c1cc(-c3ccc4c(c3)c3ccccc3n4-c3ccccc3)ccc1n2-c1ccc(-c2cc(-c3ccccc3)nc(-c3ccccc3)n2)cc1]

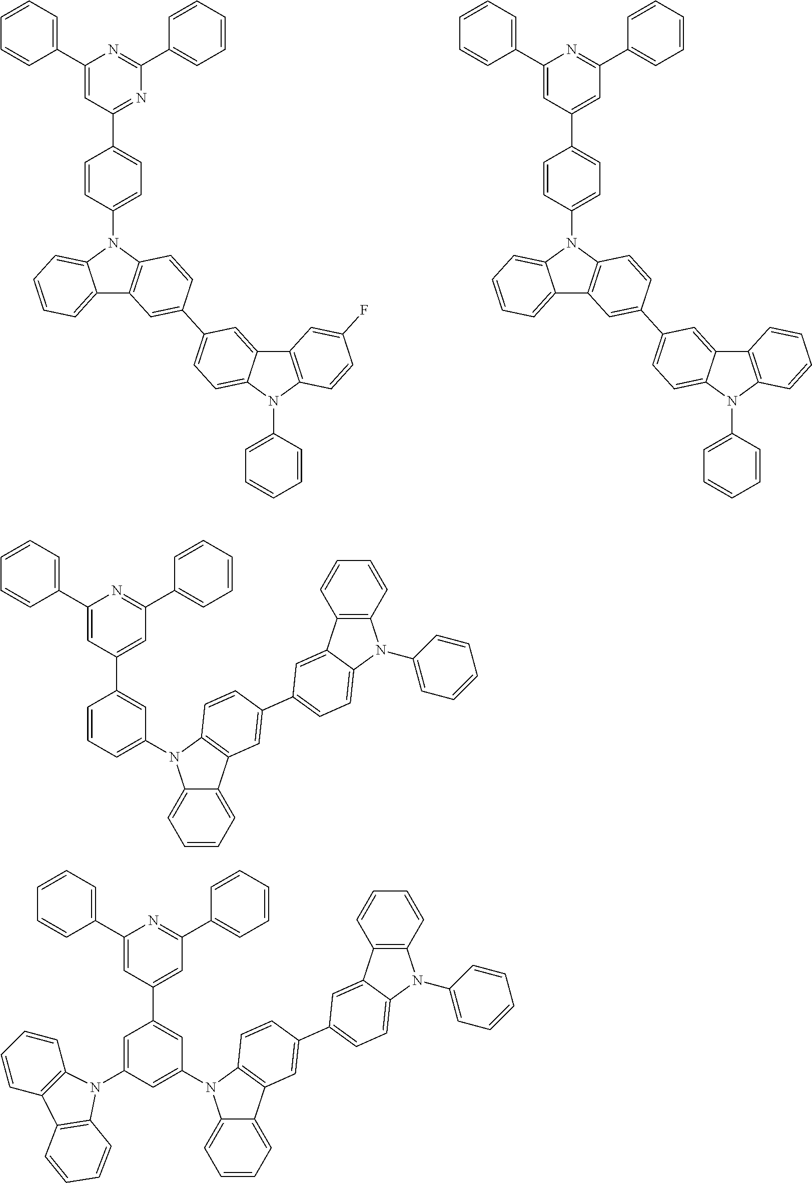

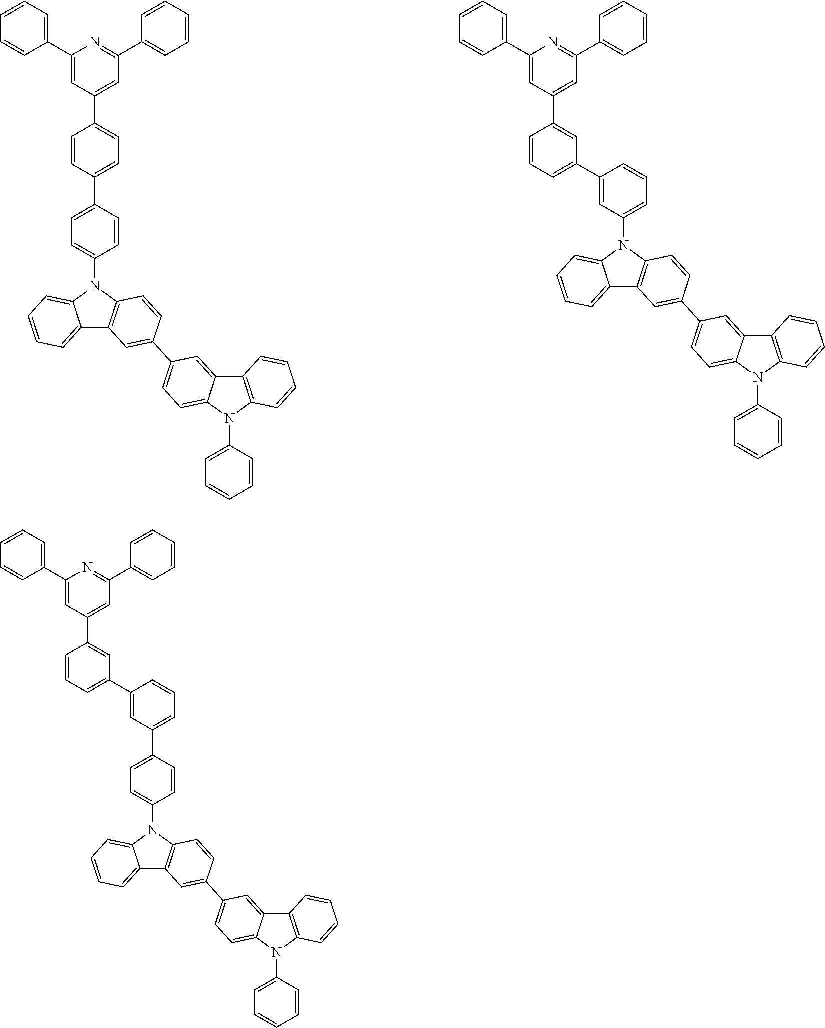 [SMILES: c1ccc(-c2cc(-c3ccc(-c4ccc(-n5c6ccccc6c6cc(-c7ccc8c(c7)c7ccccc7n8-c7ccccc7)ccc65)cc4)cc3)cc(-c3ccccc3)n2)cc1 ; c1ccc(-c2cc(-c3cccc(-c4cccc(-n5c6ccccc6c6cc(-c7ccc8c(c7)c7ccccc7n8-c7ccccc7)ccc65)c4)c3)cc(-c3ccccc3)n2)cc1 ; c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)cc(-c3ccccc3)n2)cc1]

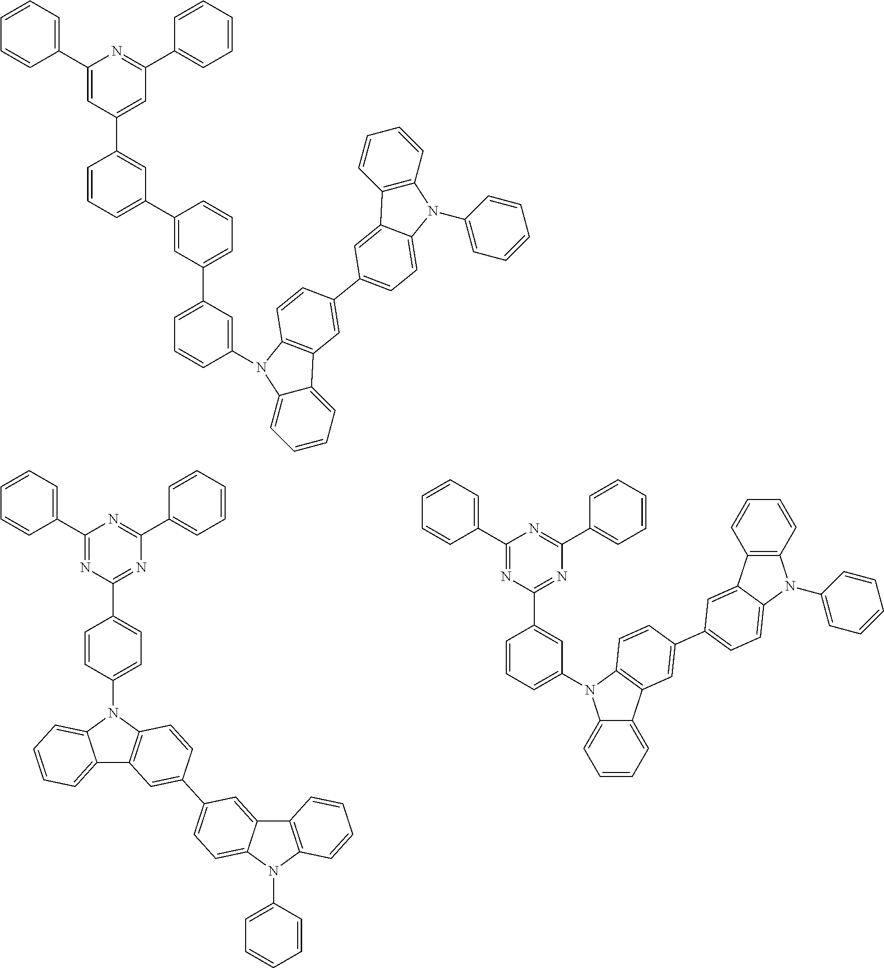 [SMILES: c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)cc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

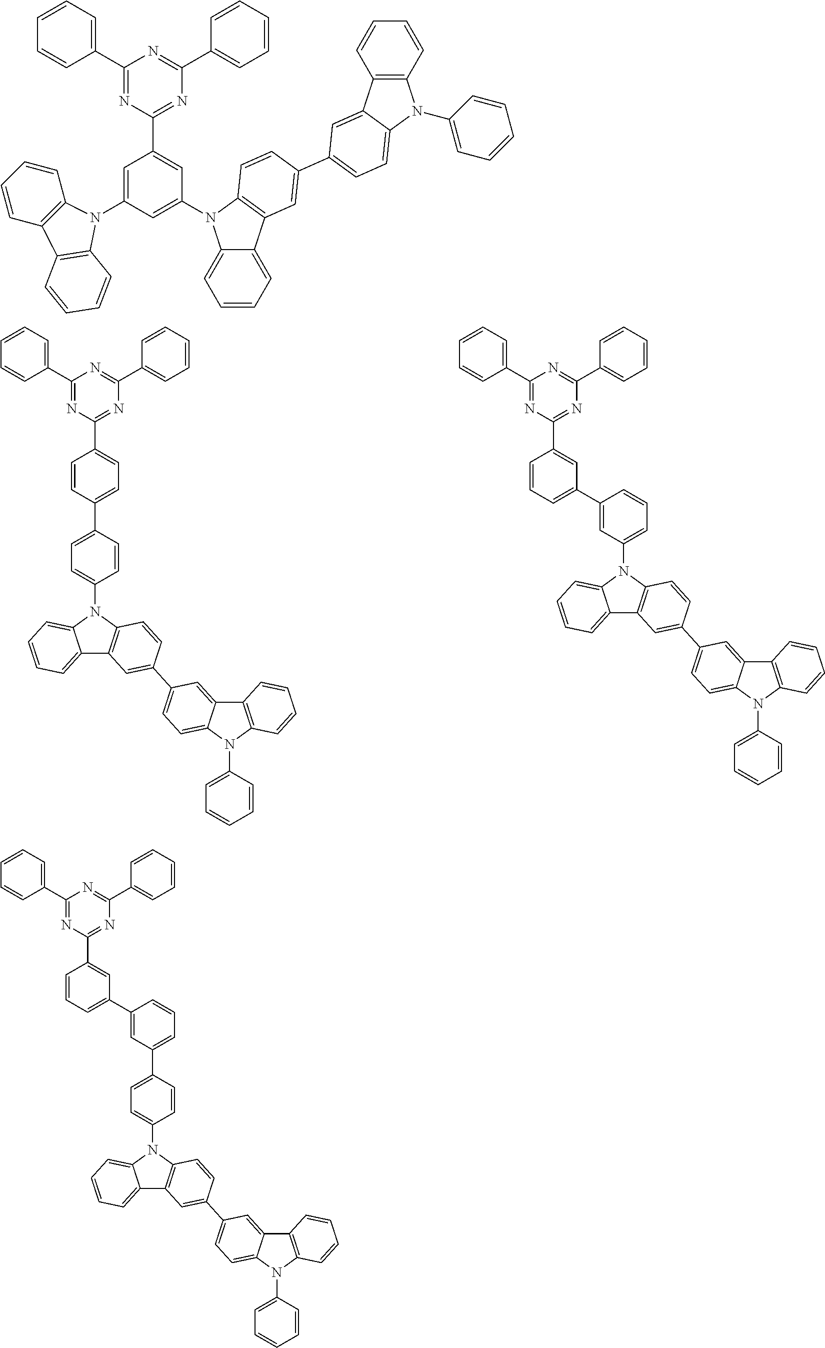

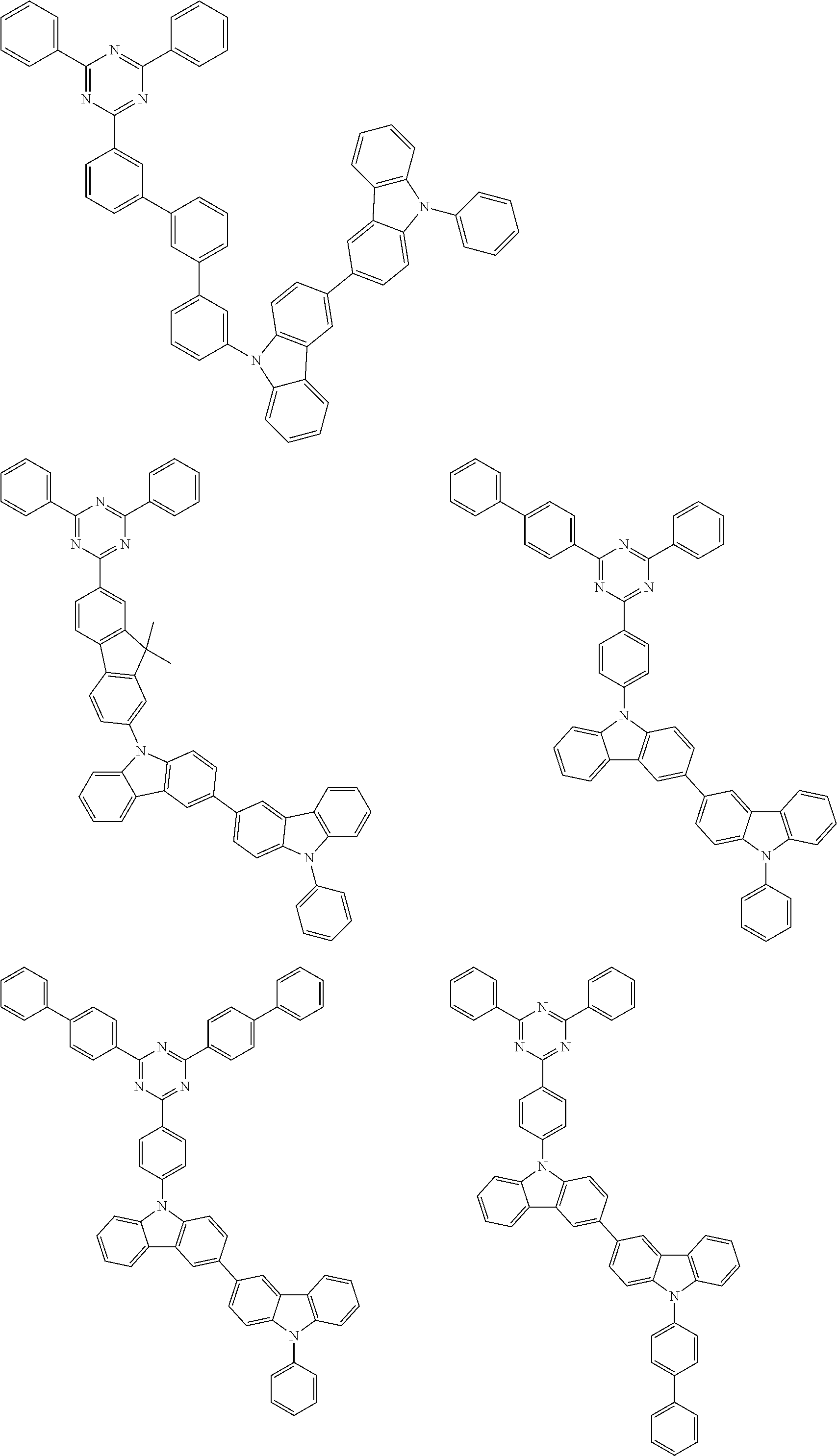

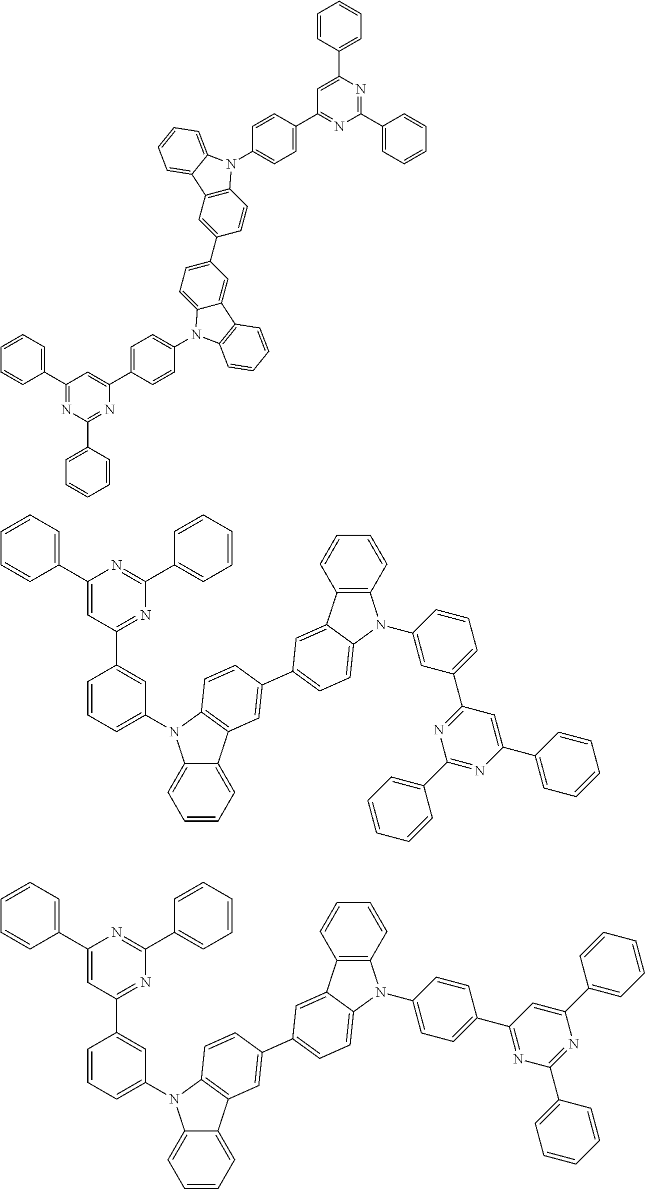

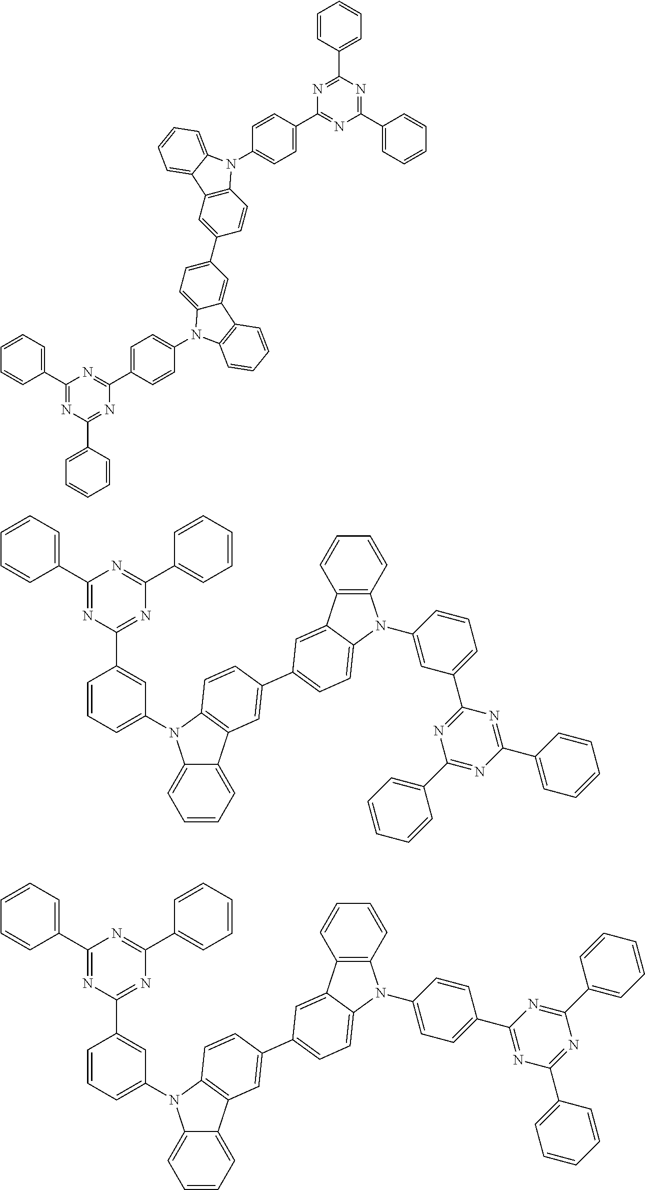

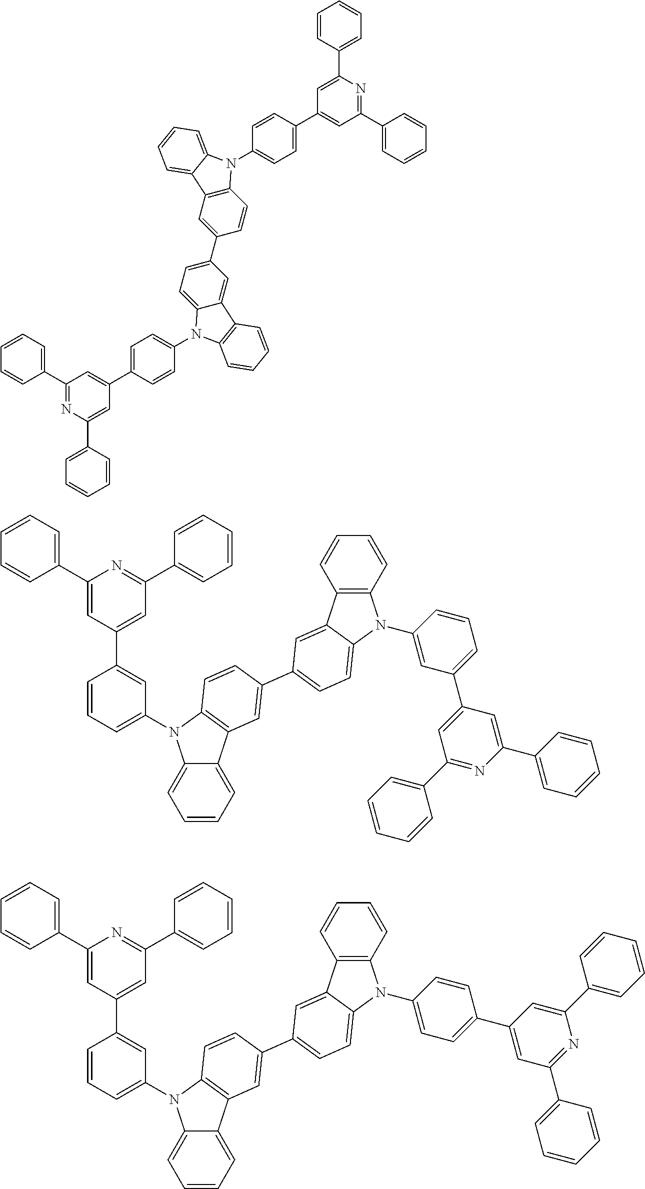

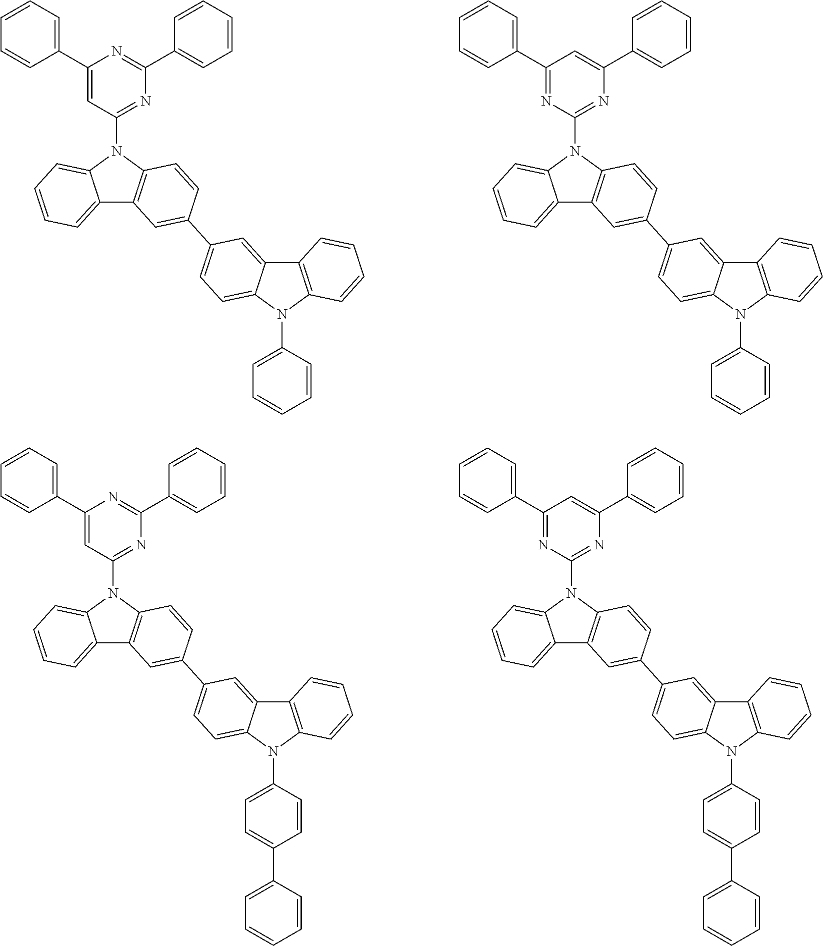 [SMILES: c1ccc(-c2cc(-n3c4ccccc4c4cc(-c5ccc6c(c5)c5ccccc5n6-c5ccccc5)ccc43)nc(-c3ccccc3)n2)cc1 ; c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2ccc(-n3c4ccccc4c4cc(-c5ccc6c(c5)c5ccccc5n6-c5cc(-c6ccccc6)nc(-c6ccccc6)n5)ccc43)cc2)cc1 ; c1ccc(-c2ccc(-n3c4ccccc4c4cc(-c5ccc6c(c5)c5ccccc5n6-c5nc(-c6ccccc6)cc(-c6ccccc6)n5)ccc43)cc2)cc1]

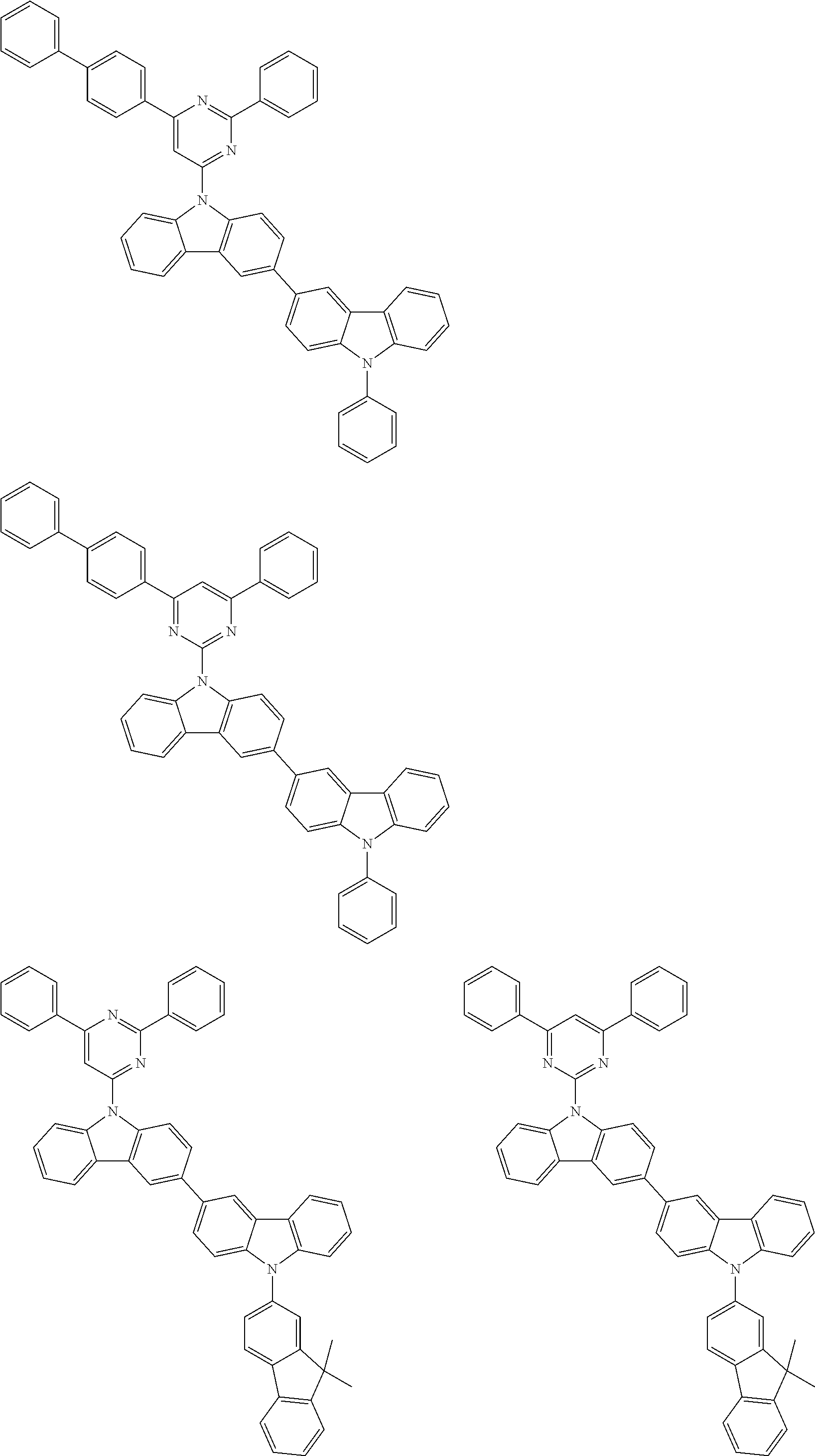 [SMILES: c1ccc(-c2ccc(-c3cc(-n4c5ccccc5c5cc(-c6ccc7c(c6)c6ccccc6n7-c6ccccc6)ccc54)nc(-c4ccccc4)n3)cc2)cc1 ; c1ccc(-c2ccc(-c3cc(-c4ccccc4)nc(-n4c5ccccc5c5cc(-c6ccc7c(c6)c6ccccc6n7-c6ccccc6)ccc54)n3)cc2)cc1 ; CC1(C)c2ccccc2-c2ccc(-n3c4ccccc4c4cc(-c5ccc6c(c5)c5ccccc5n6-c5cc(-c6ccccc6)nc(-c6ccccc6)n5)ccc43)cc21 ; CC1(C)c2ccccc2-c2ccc(-n3c4ccccc4c4cc(-c5ccc6c(c5)c5ccccc5n6-c5nc(-c6ccccc6)cc(-c6ccccc6)n5)ccc43)cc21]

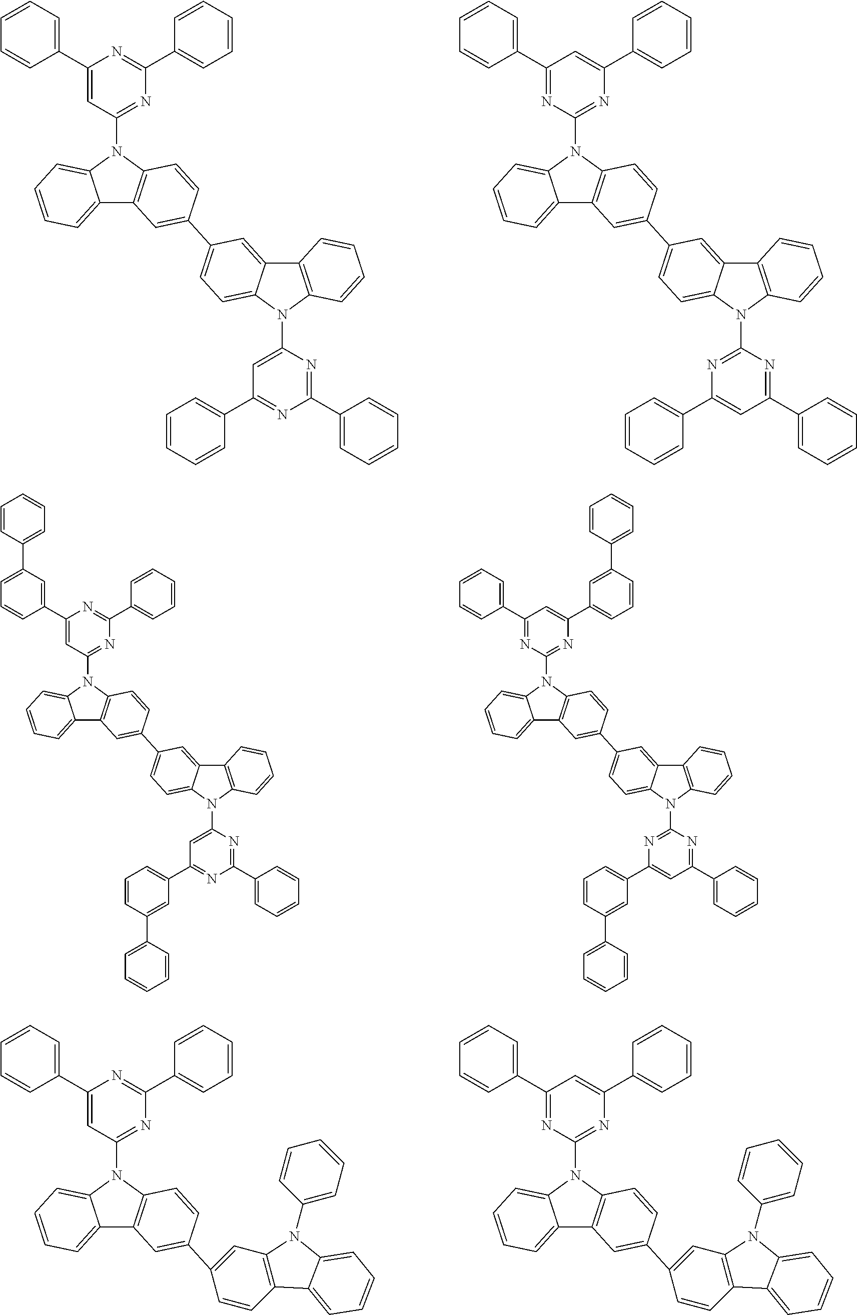

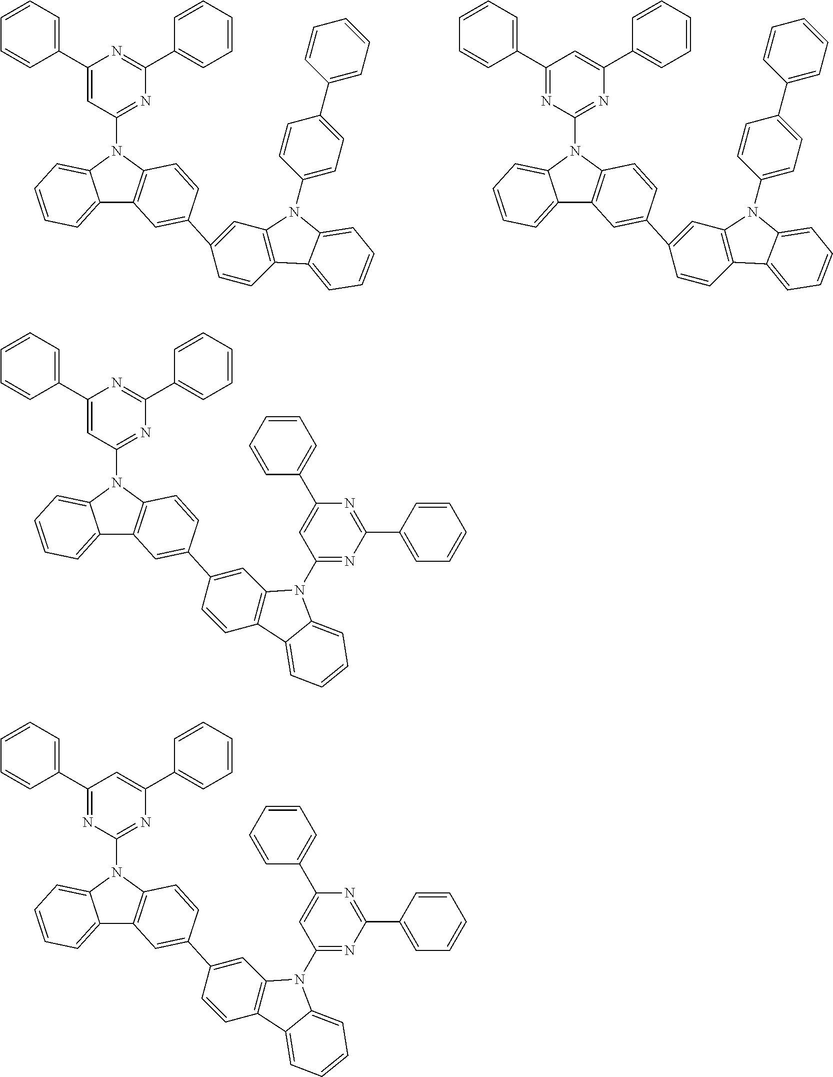 [SMILES: c1ccc(-c2ccc(-n3c4ccccc4c4ccc(-c5ccc6c(c5)c5ccccc5n6-c5cc(-c6ccccc6)nc(-c6ccccc6)n5)cc43)cc2)cc1 ; c1ccc(-c2ccc(-n3c4ccccc4c4ccc(-c5ccc6c(c5)c5ccccc5n6-c5nc(-c6ccccc6)cc(-c6ccccc6)n5)cc43)cc2)cc1 ; c1ccc(-c2cc(-n3c4ccccc4c4cc(-c5ccc6c7ccccc7n(-c7cc(-c8ccccc8)nc(-c8ccccc8)n7)c6c5)ccc43)nc(-c3ccccc3)n2)cc1 ; c1ccc(-c2cc(-n3c4ccccc4c4ccc(-c5ccc6c(c5)c5ccccc5n6-c5nc(-c6ccccc6)cc(-c6ccccc6)n5)cc43)nc(-c3ccccc3)n2)cc1]

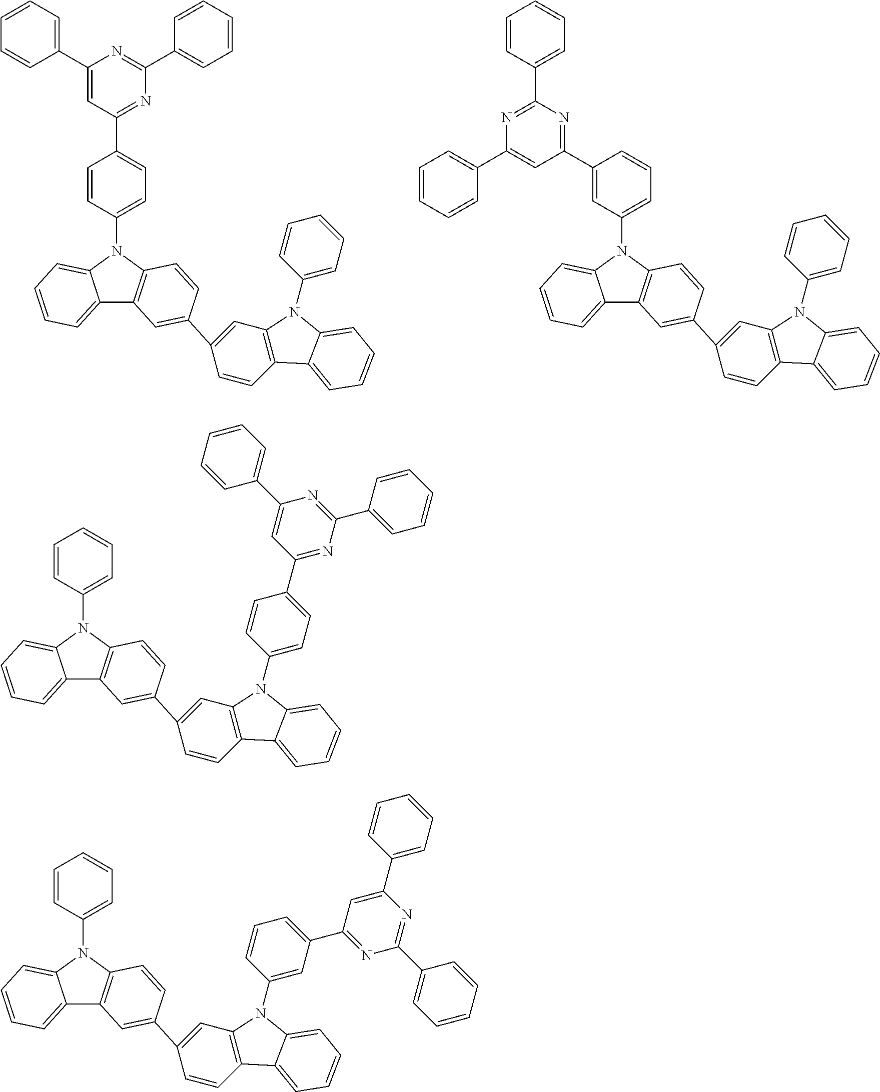

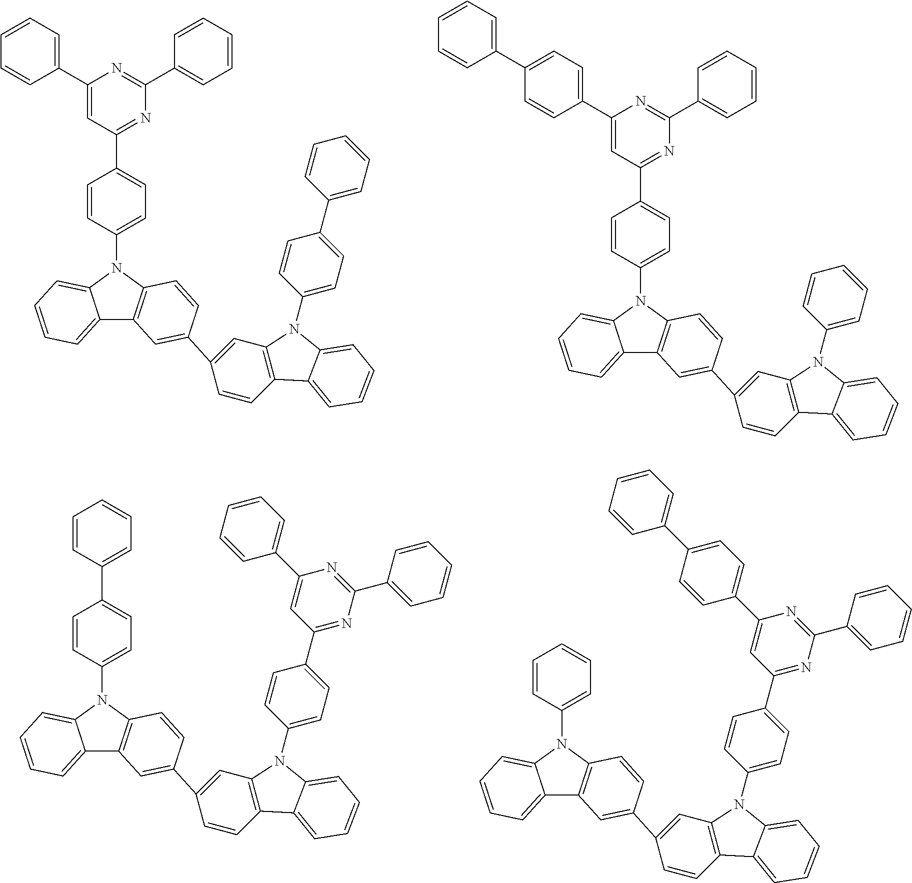 [SMILES: c1ccc(-c2ccc(-n3c4ccccc4c4ccc(-c5ccc6c(c5)c5ccccc5n6-c5ccc(-c6cc(-c7ccccc7)nc(-c7ccccc7)n6)cc5)cc43)cc2)cc1 ; c1ccc(-c2ccc(-c3cc(-c4ccc(-n5c6ccccc6c6cc(-c7ccc8c9ccccc9n(-c9ccccc9)c8c7)ccc65)cc4)nc(-c4ccccc4)n3)cc2)cc1 ; c1ccc(-c2ccc(-n3c4ccccc4c4cc(-c5ccc6c7ccccc7n(-c7ccc(-c8cc(-c9ccccc9)nc(-c9ccccc9)n8)cc7)c6c5)ccc43)cc2)cc1 ; c1ccc(-c2ccc(-c3cc(-c4ccc(-n5c6ccccc6c6ccc(-c7ccc8c(c7)c7ccccc7n8-c7ccccc7)cc65)cc4)nc(-c4ccccc4)n3)cc2)cc1]

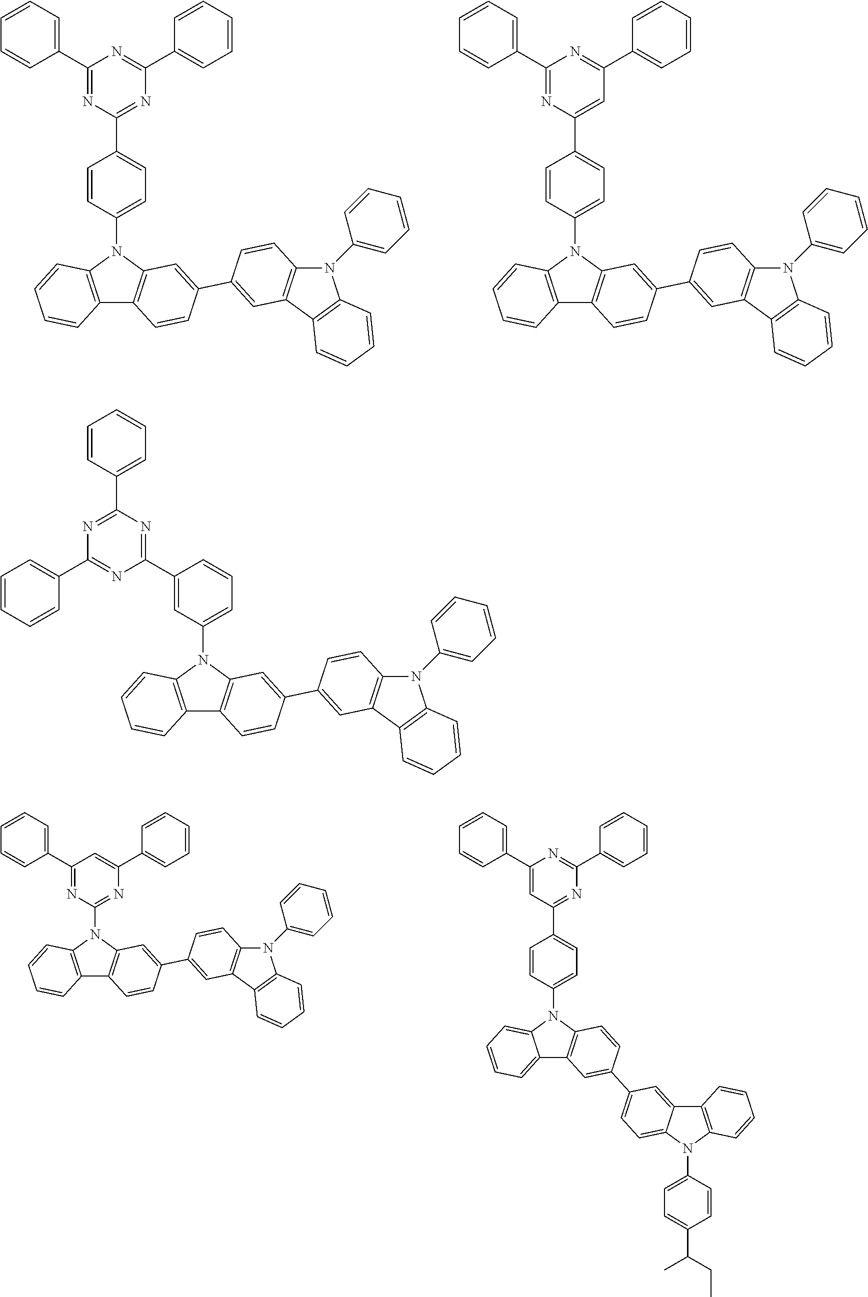 [SMILES: c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1 ; CCC(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1]

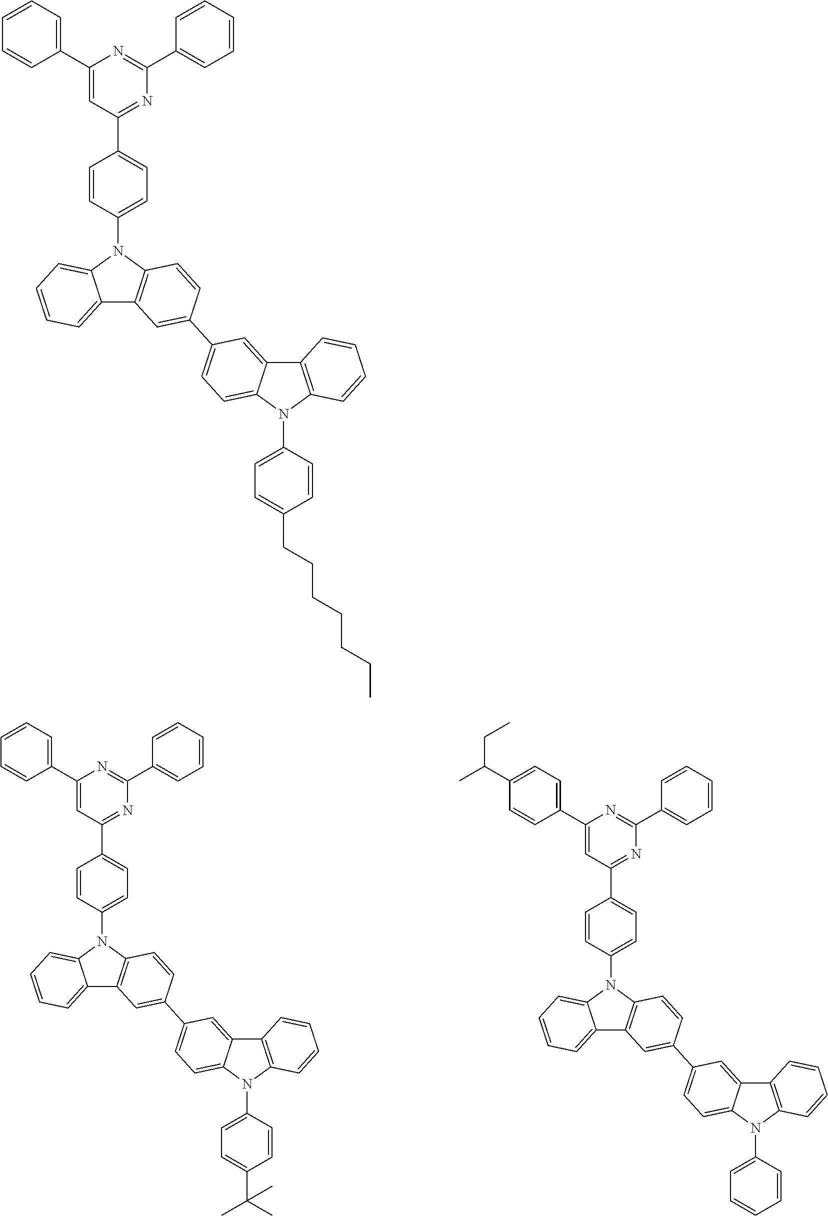 [SMILES: CCCCCCCc1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CC(C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CCC(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1]

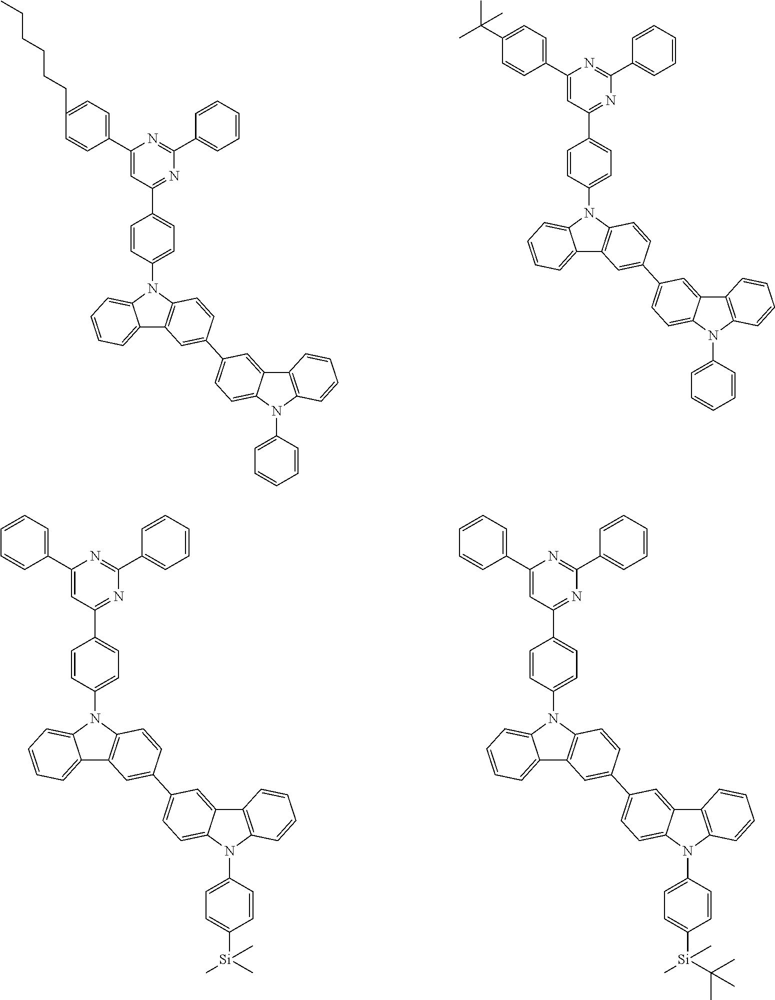 [SMILES: CCCCCCc1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; CC(C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; C[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CC(C)(C)[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1]

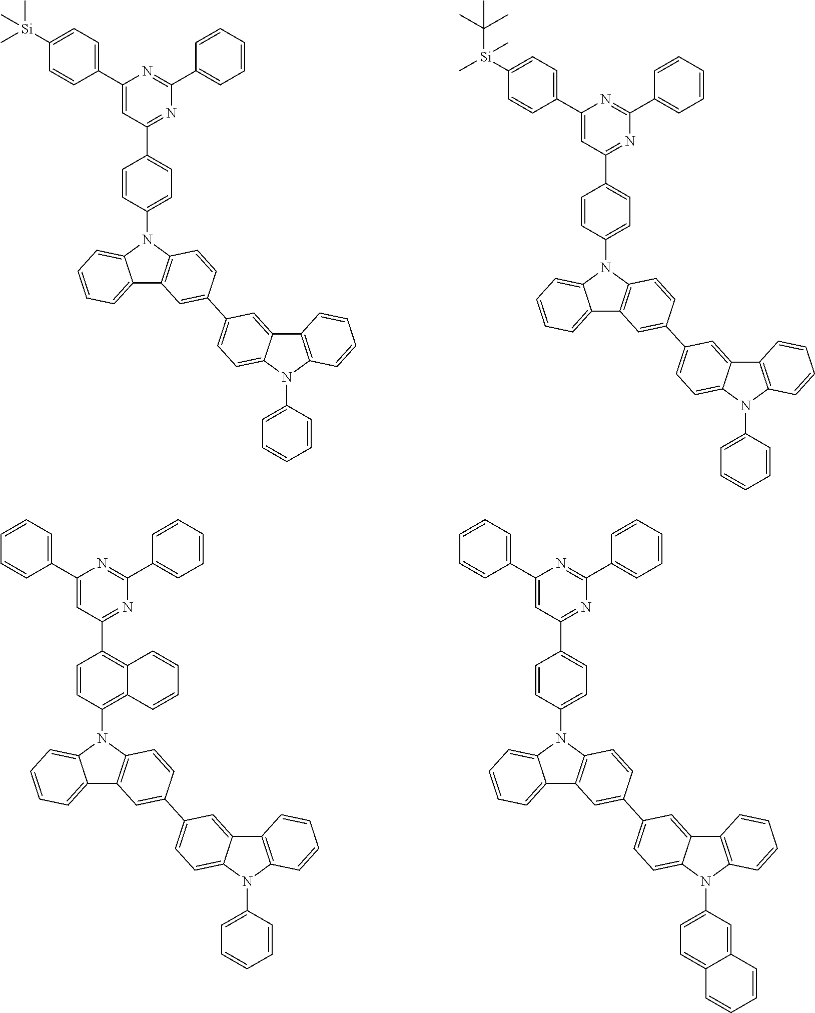 [SMILES: C[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; CC(C)(C)[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3ccc(-n4c5ccccc5c5cc(-c6ccc7c(c6)c6ccccc6n7-c6ccccc6)ccc54)c4ccccc34)nc(-c3ccccc3)n2)cc1 ; c1ccc(-c2cc(-c3ccc(-n4c5ccccc5c5cc(-c6ccc7c(c6)c6ccccc6n7-c6ccc7ccccc7c6)ccc54)cc3)nc(-c3ccccc3)n2)cc1]

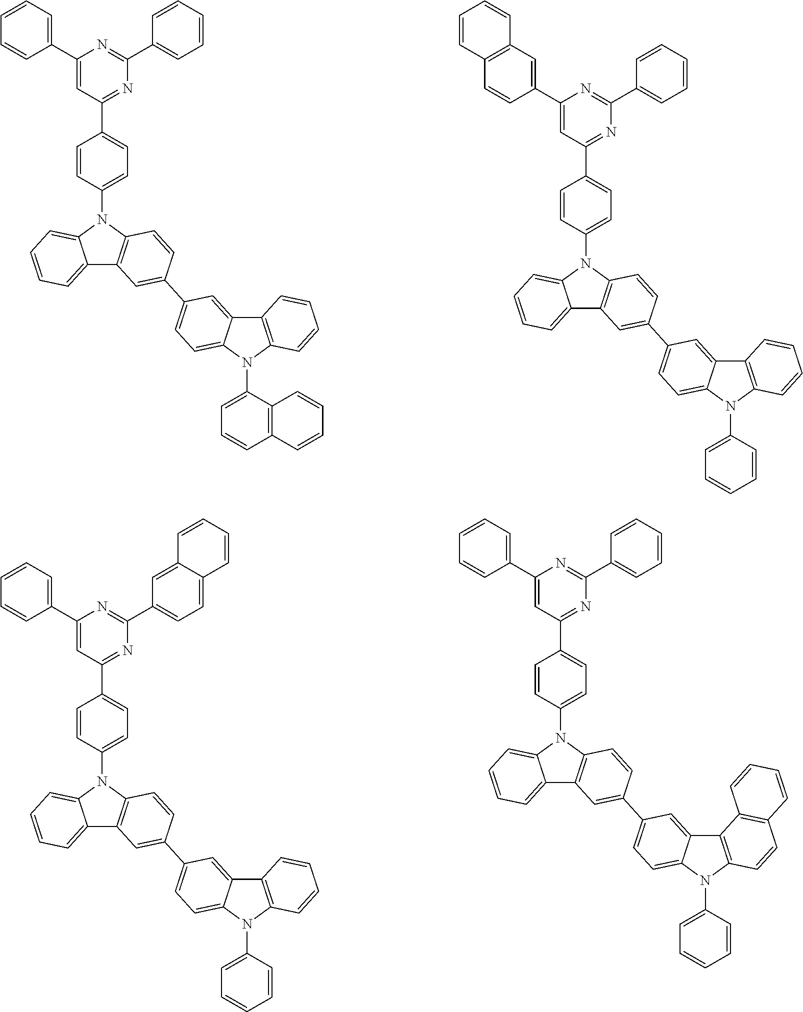 [SMILES: c1ccc(-c2cc(-c3ccc(-n4c5ccccc5c5cc(-c6ccc7c(c6)c6ccccc6n7-c6cccc7ccccc67)ccc54)cc3)nc(-c3ccccc3)n2)cc1 ; c1ccc(-c2nc(-c3ccc(-n4c5ccccc5c5cc(-c6ccc7c(c6)c6ccccc6n7-c6ccccc6)ccc54)cc3)cc(-c3ccc4ccccc4c3)n2)cc1 ; c1ccc(-c2cc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2cc(-c3ccc(-n4c5ccccc5c5cc(-c6ccc7c(c6)c6c8ccccc8ccc6n7-c6ccccc6)ccc54)cc3)nc(-c3ccccc3)n2)cc1]

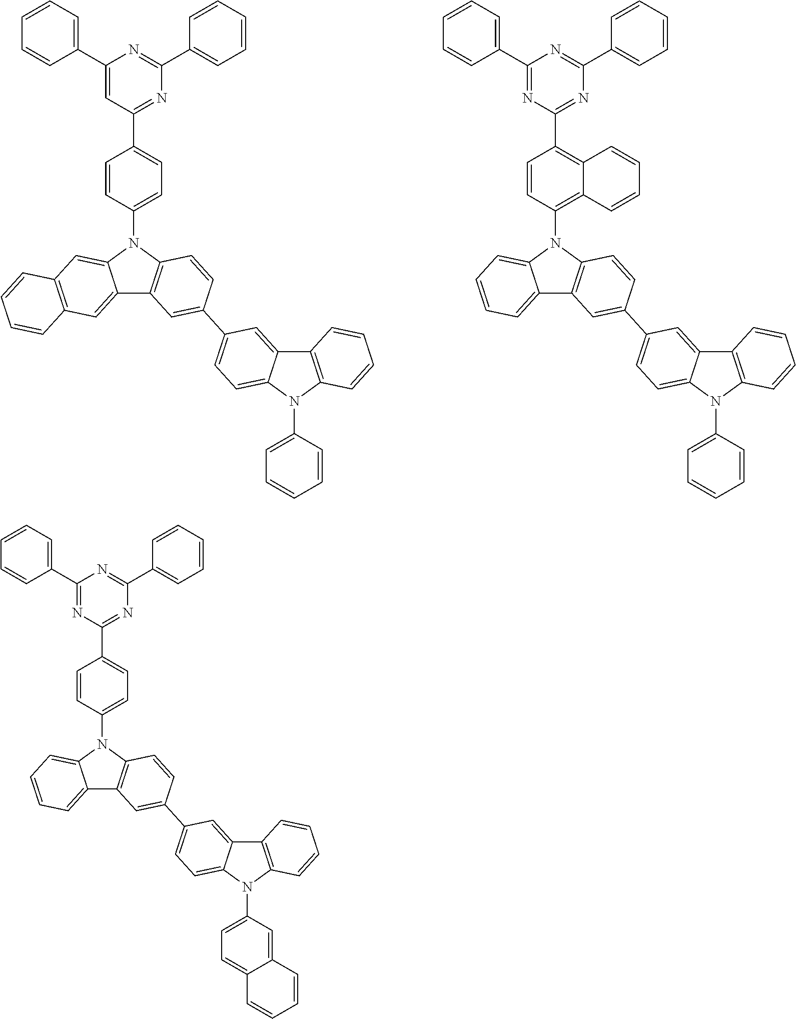 [SMILES: c1ccc(-c2cc(-c3ccc(-n4c5ccc(-c6ccc7c(c6)c6ccccc6n7-c6ccccc6)cc5c5cc6ccccc6cc54)cc3)nc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)c4ccccc34)n2)cc1 ; c1ccc(-c2nc(-c3ccccc3)nc(-c3ccc(-n4c5ccccc5c5cc(-c6ccc7c(c6)c6ccccc6n7-c6ccc7ccccc7c6)ccc54)cc3)n2)cc1]

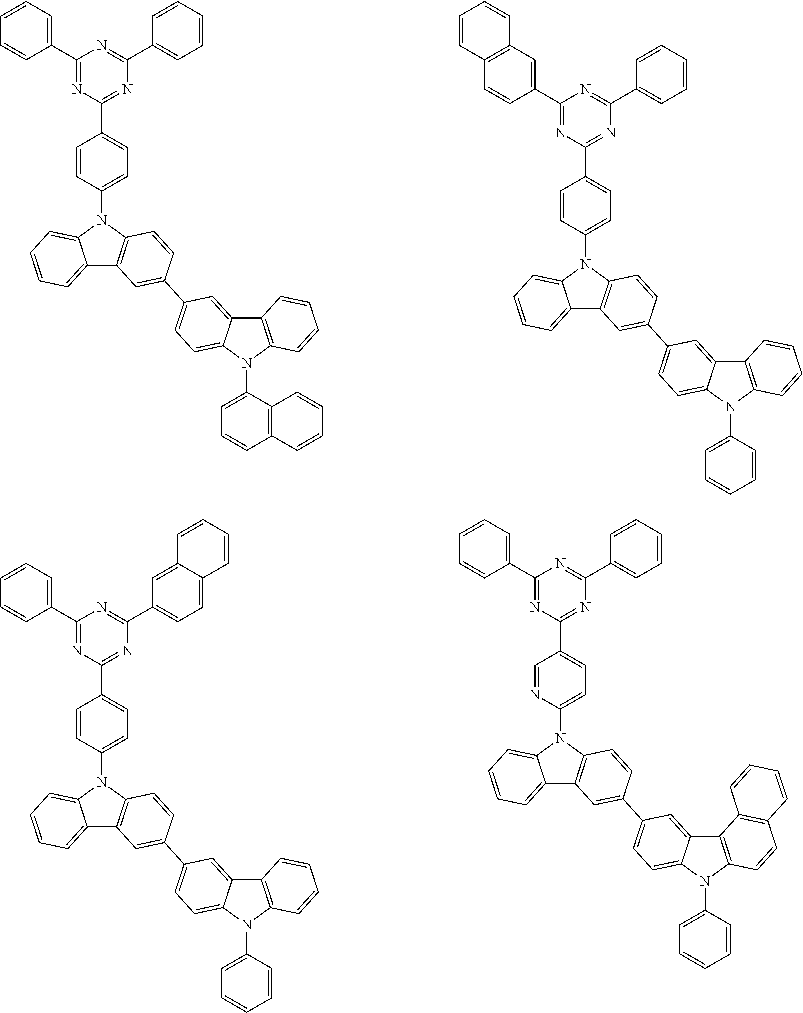 [SMILES: c1ccc(-c2nc(-c3ccccc3)nc(-c3ccc(-n4c5ccccc5c5cc(-c6ccc7c(c6)c6ccccc6n7-c6cccc7ccccc67)ccc54)cc3)n2)cc1 ; c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2nc(-c3ccccc3)nc(-c3ccc(-n4c5ccccc5c5cc(-c6ccc7c(c6)c6c8ccccc8ccc6n7-c6ccccc6)ccc54)nc3)n2)cc1]

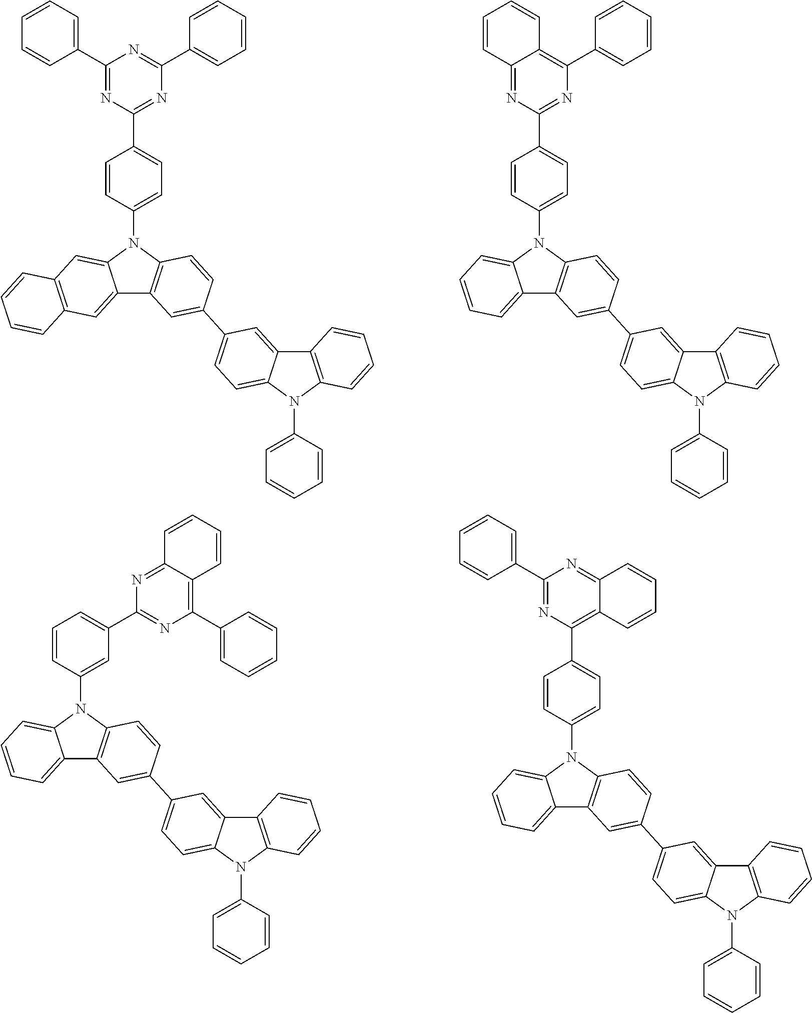 [SMILES: c1ccc(-c2nc(-c3ccccc3)nc(-c3ccc(-n4c5ccc(-c6ccc7c(c6)c6ccccc6n7-c6ccccc6)cc5c5cc6ccccc6cc54)cc3)n2)cc1 ; c1ccc(-c2nc(-c3ccc(-n4c5ccccc5c5cc(-c6ccc7c(c6)c6ccccc6n7-c6ccccc6)ccc54)cc3)nc3ccccc23)cc1 ; c1ccc(-c2nc(-c3cccc(-n4c5ccccc5c5cc(-c6ccc7c(c6)c6ccccc6n7-c6ccccc6)ccc54)c3)nc3ccccc23)cc1 ; c1ccc(-c2nc(-c3ccc(-n4c5ccccc5c5cc(-c6ccc7c(c6)c6ccccc6n7-c6ccccc6)ccc54)cc3)c3ccccc3n2)cc1]

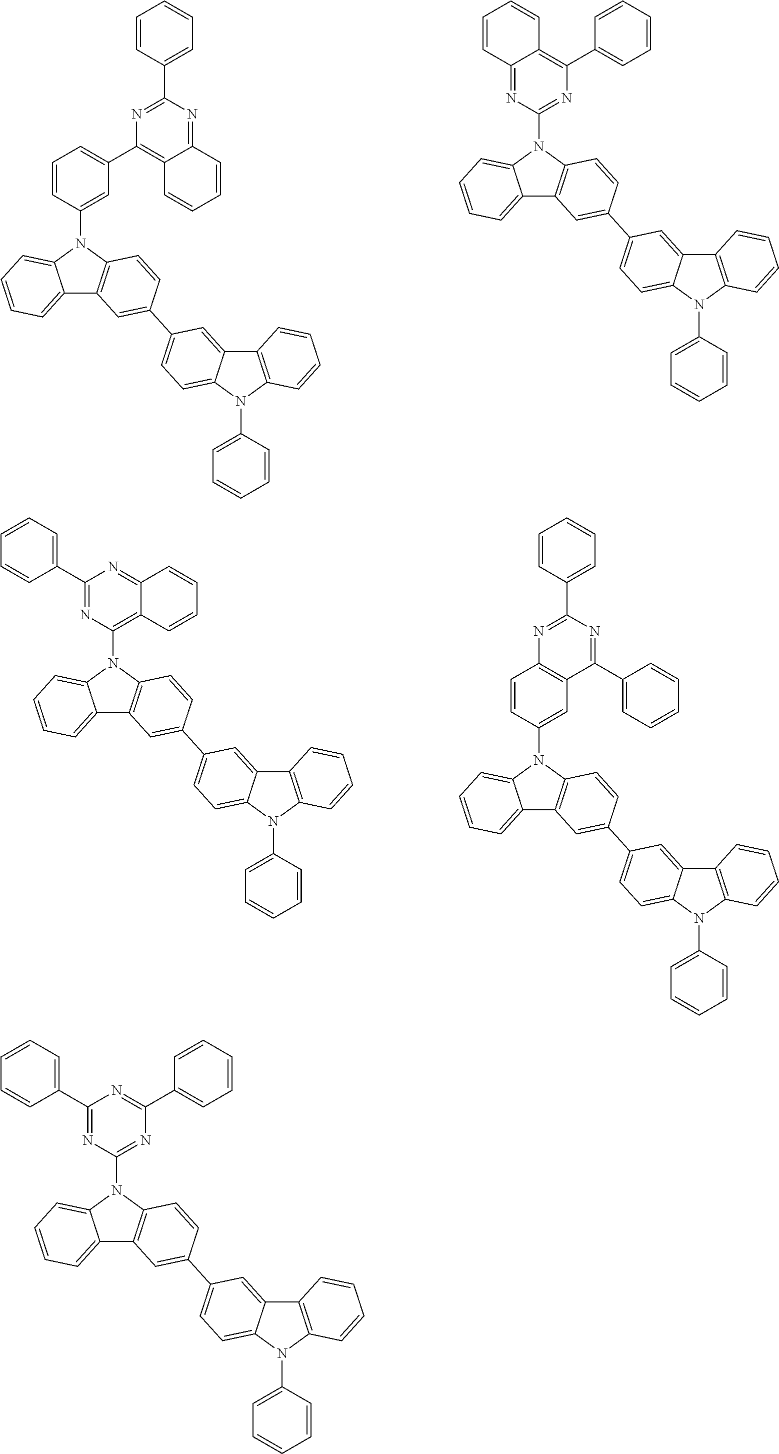 [SMILES: c1ccc(-c2nc(-c3cccc(-n4c5ccccc5c5cc(-c6ccc7c(c6)c6ccccc6n7-c6ccccc6)ccc54)c3)c3ccccc3n2)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccccc4c4cc(-c5ccc6c(c5)c5ccccc5n6-c5ccccc5)ccc43)c3ccccc3n2)cc1 ; c1ccc(-c2nc(-c3ccccc3)c3cc(-n4c5ccccc5c5cc(-c6ccc7c(c6)c6ccccc6n7-c6ccccc6)ccc54)ccc3n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

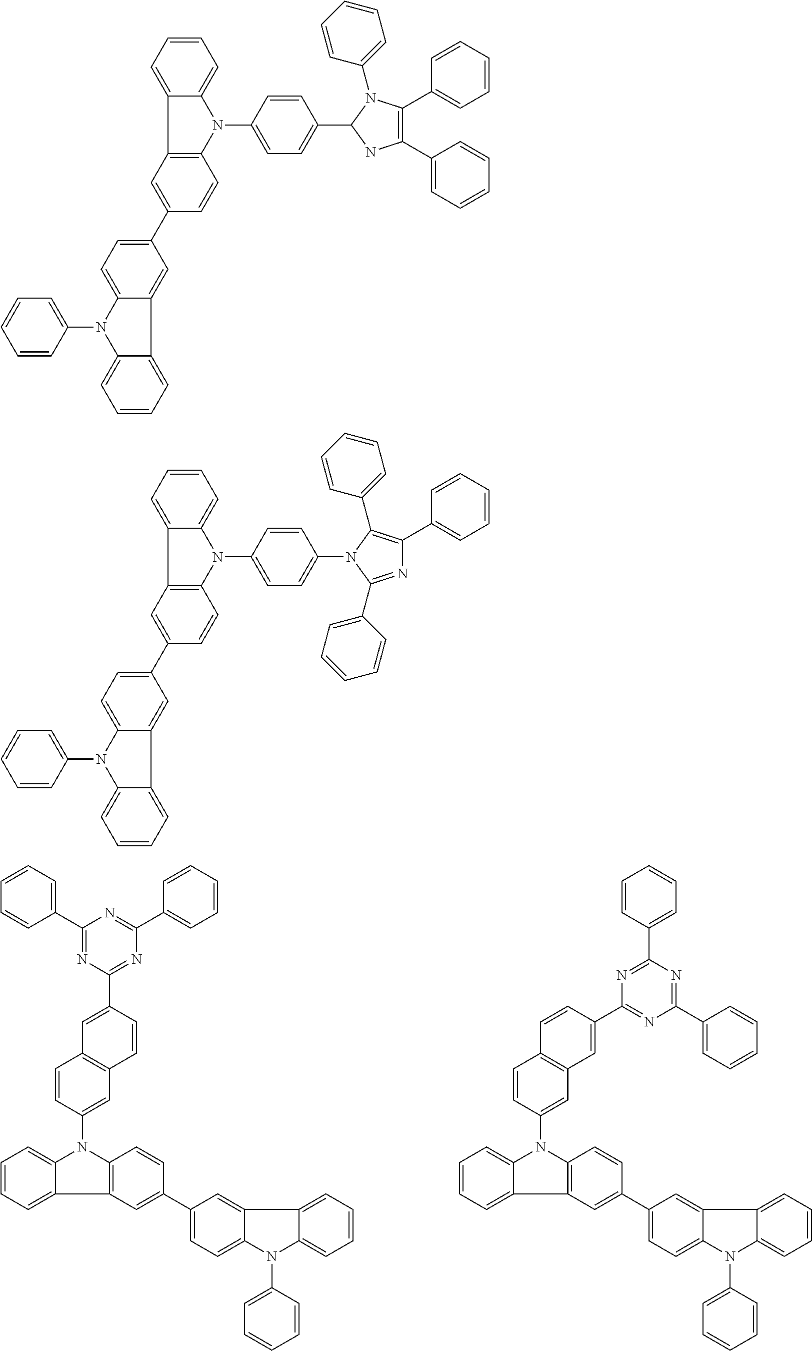

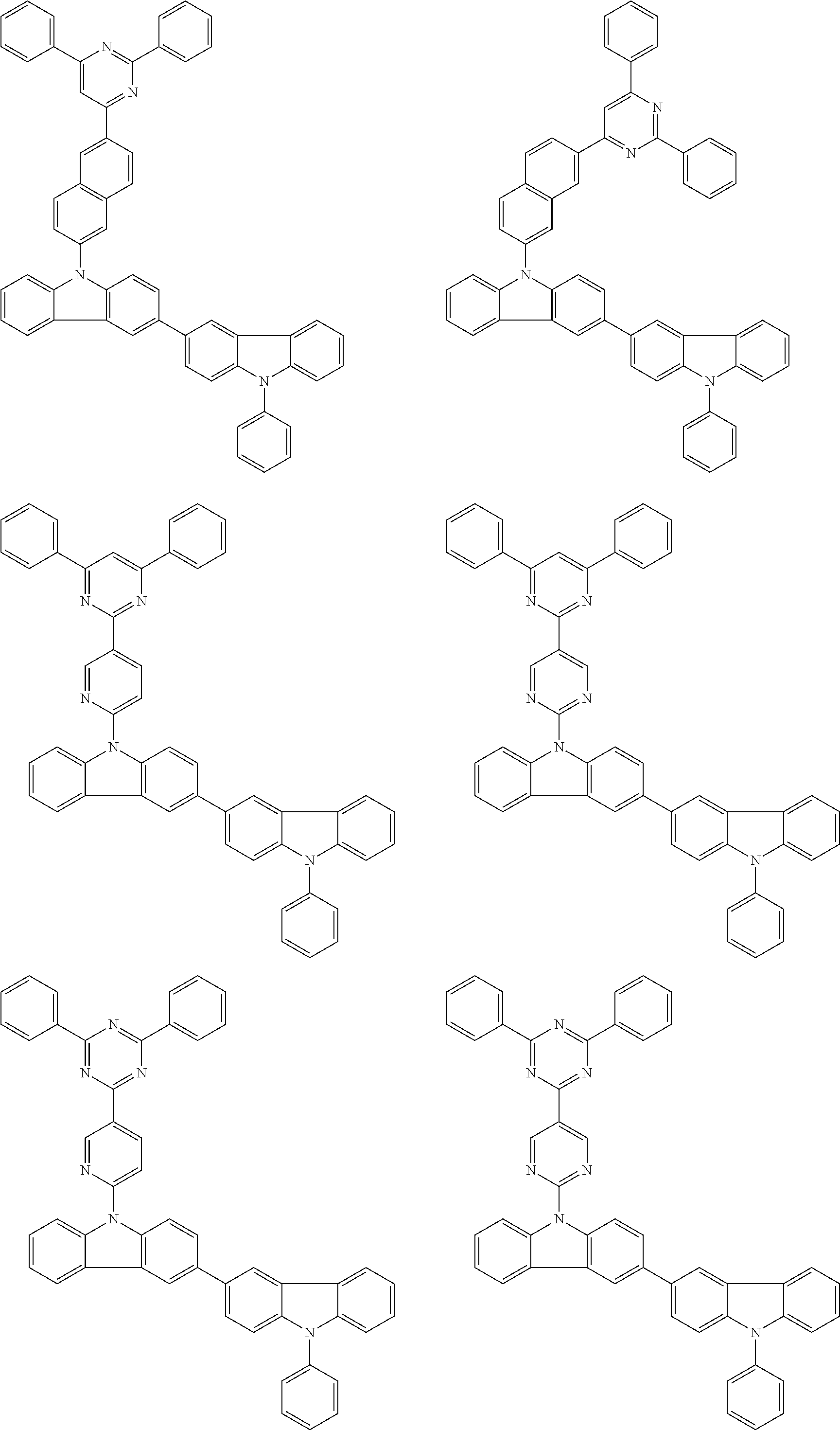

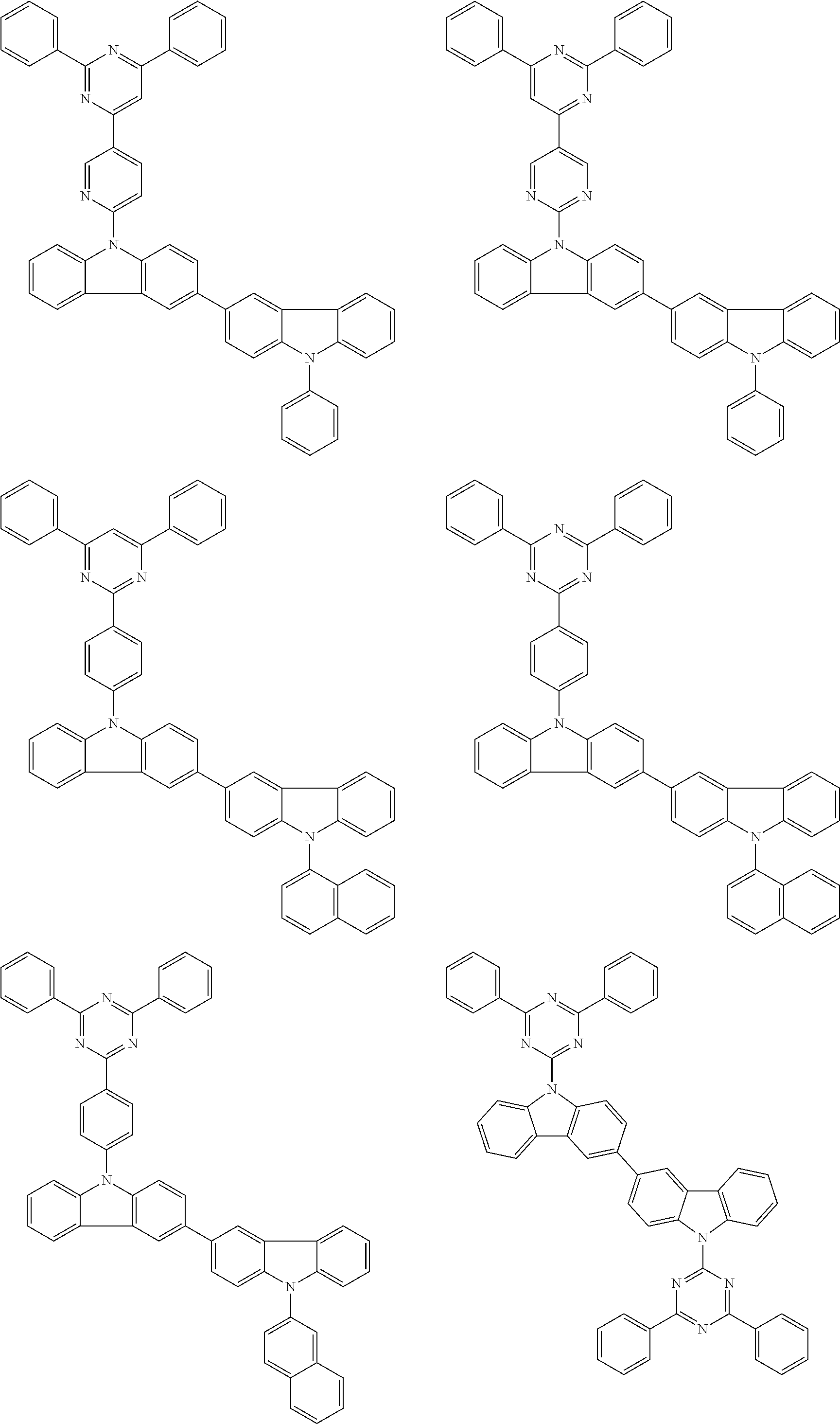

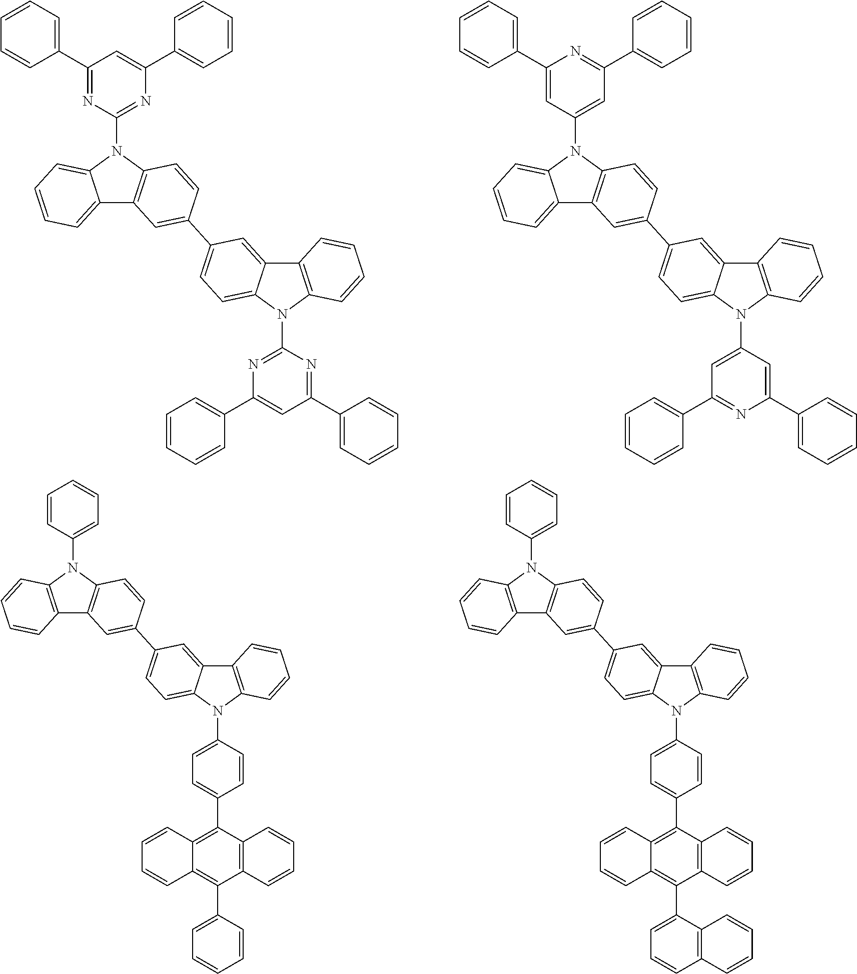 [SMILES: c1ccc(-c2cc(-c3ccccc3)nc(-n3c4ccccc4c4cc(-c5ccc6c(c5)c5ccccc5n6-c5nc(-c6ccccc6)cc(-c6ccccc6)n5)ccc43)n2)cc1 ; c1ccc(-c2cc(-n3c4ccccc4c4cc(-c5ccc6c(c5)c5ccccc5n6-c5cc(-c6ccccc6)nc(-c6ccccc6)c5)ccc43)cc(-c3ccccc3)n2)cc1 ; c1ccc(-c2c3ccccc3c(-c3ccc(-n4c5ccccc5c5cc(-c6ccc7c(c6)c6ccccc6n7-c6ccccc6)ccc54)cc3)c3ccccc23)cc1 ; c1ccc(-n2c3ccccc3c3cc(-c4ccc5c(c4)c4ccccc4n5-c4ccc(-c5c6ccccc6c(-c6cccc7ccccc67)c6ccccc56)cc4)ccc32)cc1]

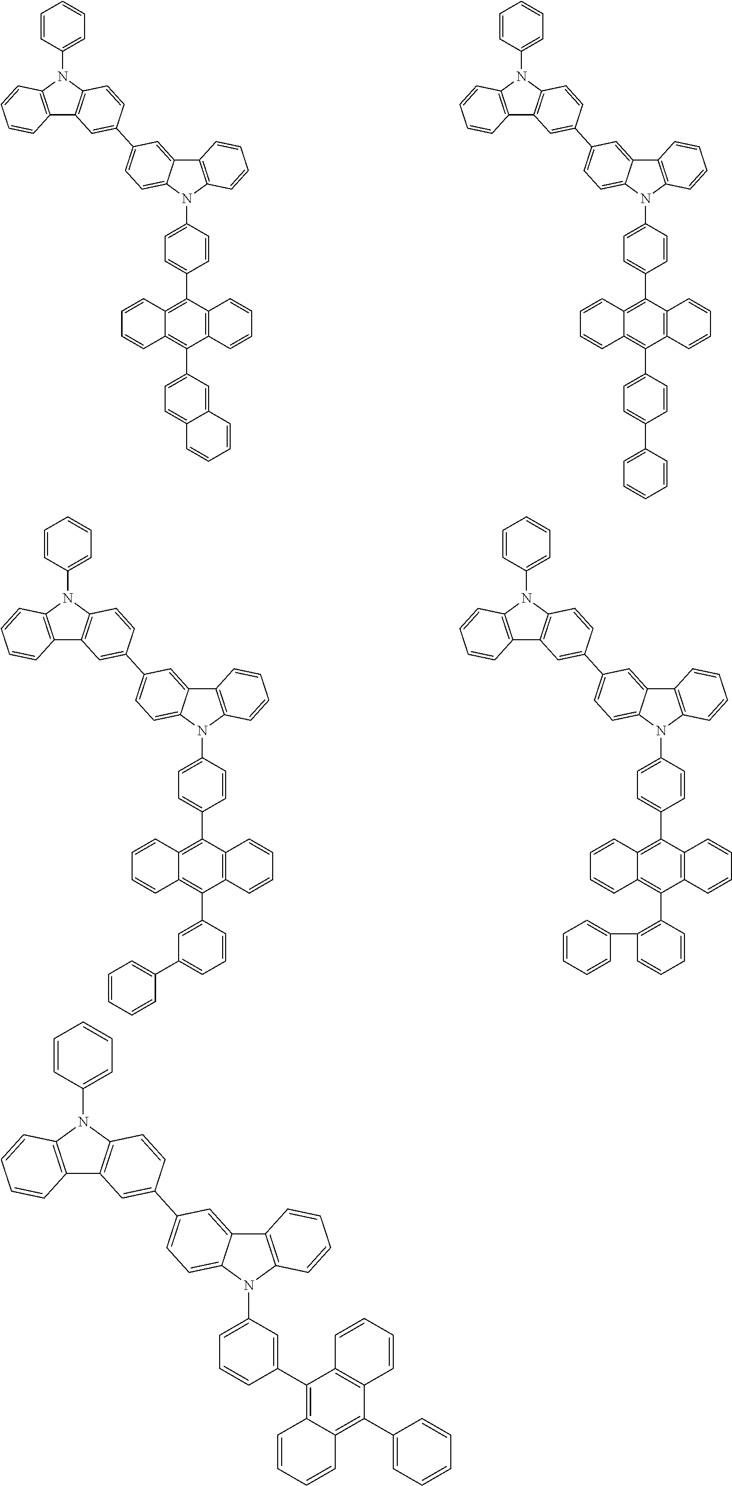

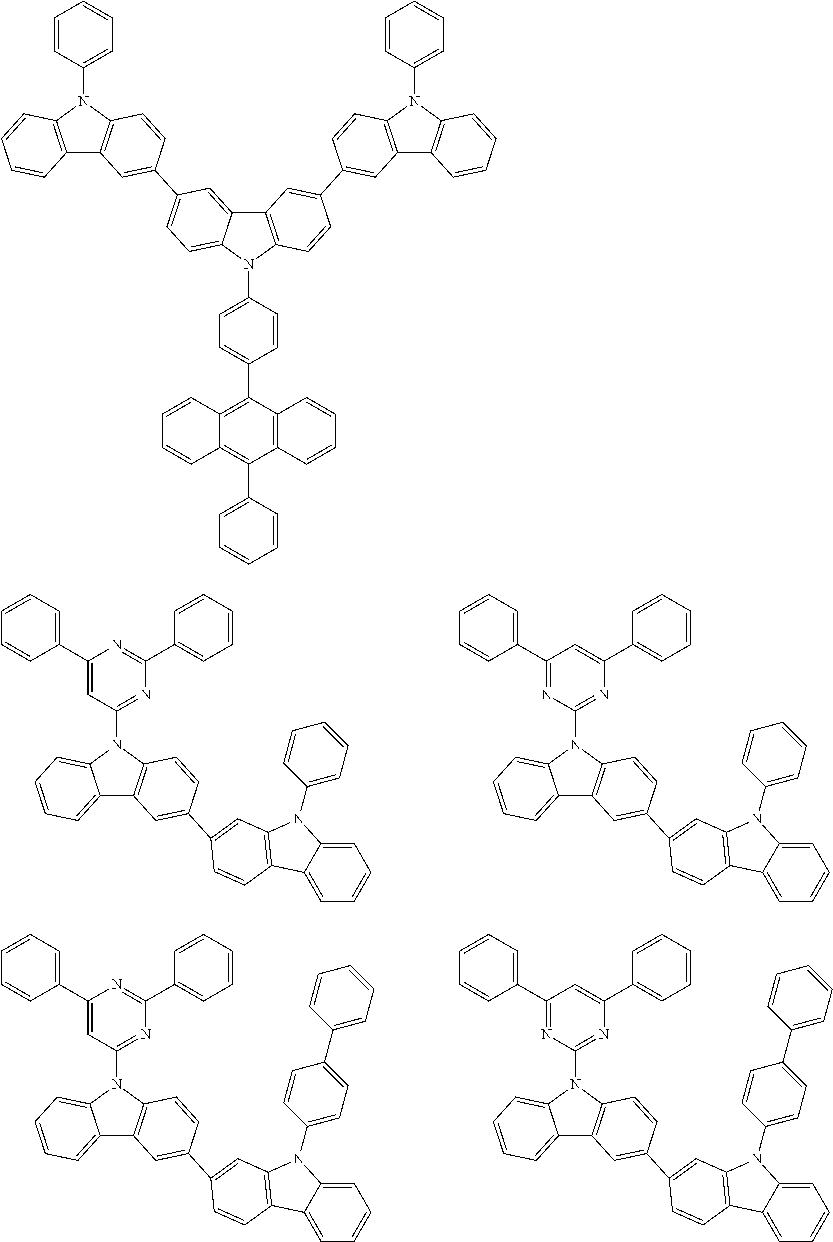

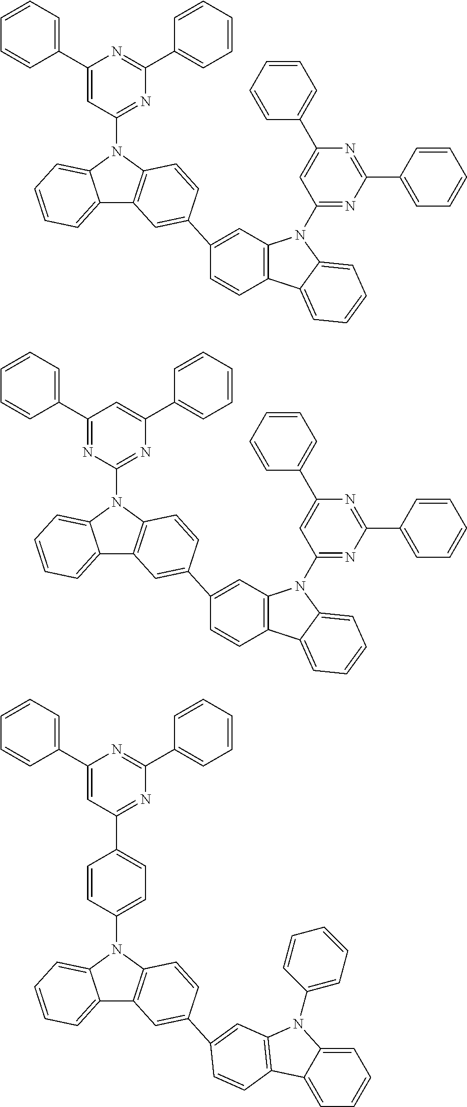 [SMILES: c1ccc(-c2cc(-n3c4ccccc4c4cc(-c5ccc6c7ccccc7n(-c7cc(-c8ccccc8)nc(-c8ccccc8)n7)c6c5)ccc43)nc(-c3ccccc3)n2)cc1 ; c1ccc(-c2cc(-n3c4ccccc4c4ccc(-c5ccc6c(c5)c5ccccc5n6-c5nc(-c6ccccc6)cc(-c6ccccc6)n5)cc43)nc(-c3ccccc3)n2)cc1 ; c1ccc(-c2cc(-c3ccc(-n4c5ccccc5c5cc(-c6ccc7c8ccccc8n(-c8ccccc8)c7c6)ccc54)cc3)nc(-c3ccccc3)n2)cc1]

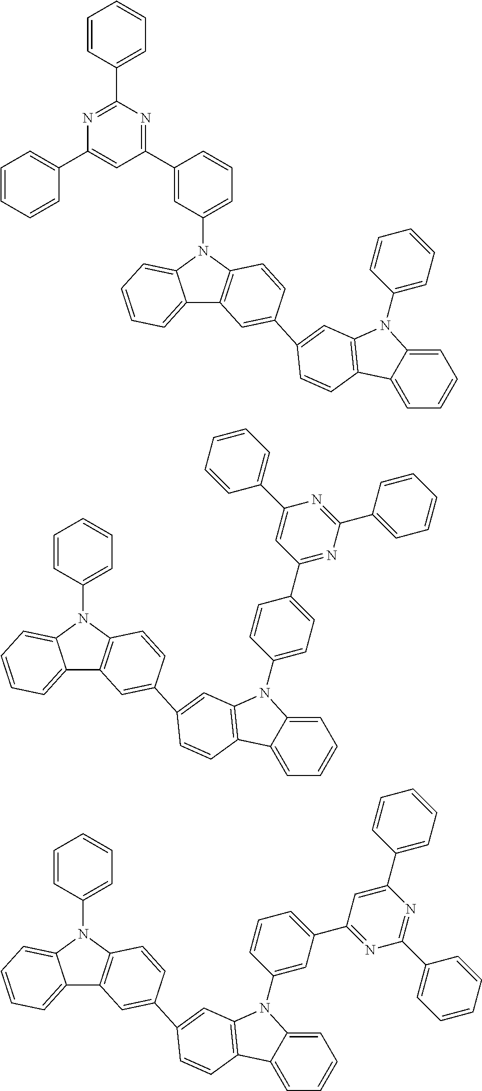 [SMILES: c1ccc(-c2cc(-c3cccc(-n4c5ccccc5c5cc(-c6ccc7c8ccccc8n(-c8ccccc8)c7c6)ccc54)c3)nc(-c3ccccc3)n2)cc1 ; c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1]

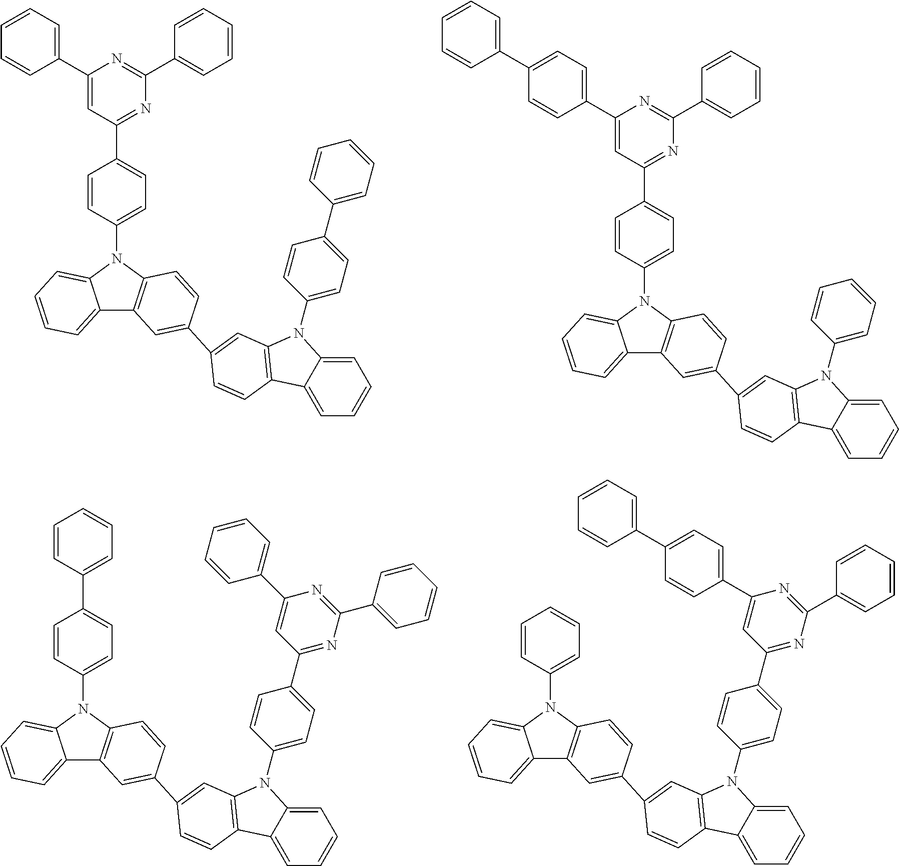 [SMILES: c1ccc(-c2ccc(-n3c4ccccc4c4ccc(-c5ccc6c(c5)c5ccccc5n6-c5ccc(-c6cc(-c7ccccc7)nc(-c7ccccc7)n6)cc5)cc43)cc2)cc1 ; c1ccc(-c2ccc(-c3cc(-c4ccc(-n5c6ccccc6c6cc(-c7ccc8c9ccccc9n(-c9ccccc9)c8c7)ccc65)cc4)nc(-c4ccccc4)n3)cc2)cc1 ; c1ccc(-c2ccc(-n3c4ccccc4c4cc(-c5ccc6c7ccccc7n(-c7ccc(-c8cc(-c9ccccc9)nc(-c9ccccc9)n8)cc7)c6c5)ccc43)cc2)cc1 ; c1ccc(-c2ccc(-c3cc(-c4ccc(-n5c6ccccc6c6ccc(-c7ccc8c(c7)c7ccccc7n8-c7ccccc7)cc65)cc4)nc(-c4ccccc4)n3)cc2)cc1]

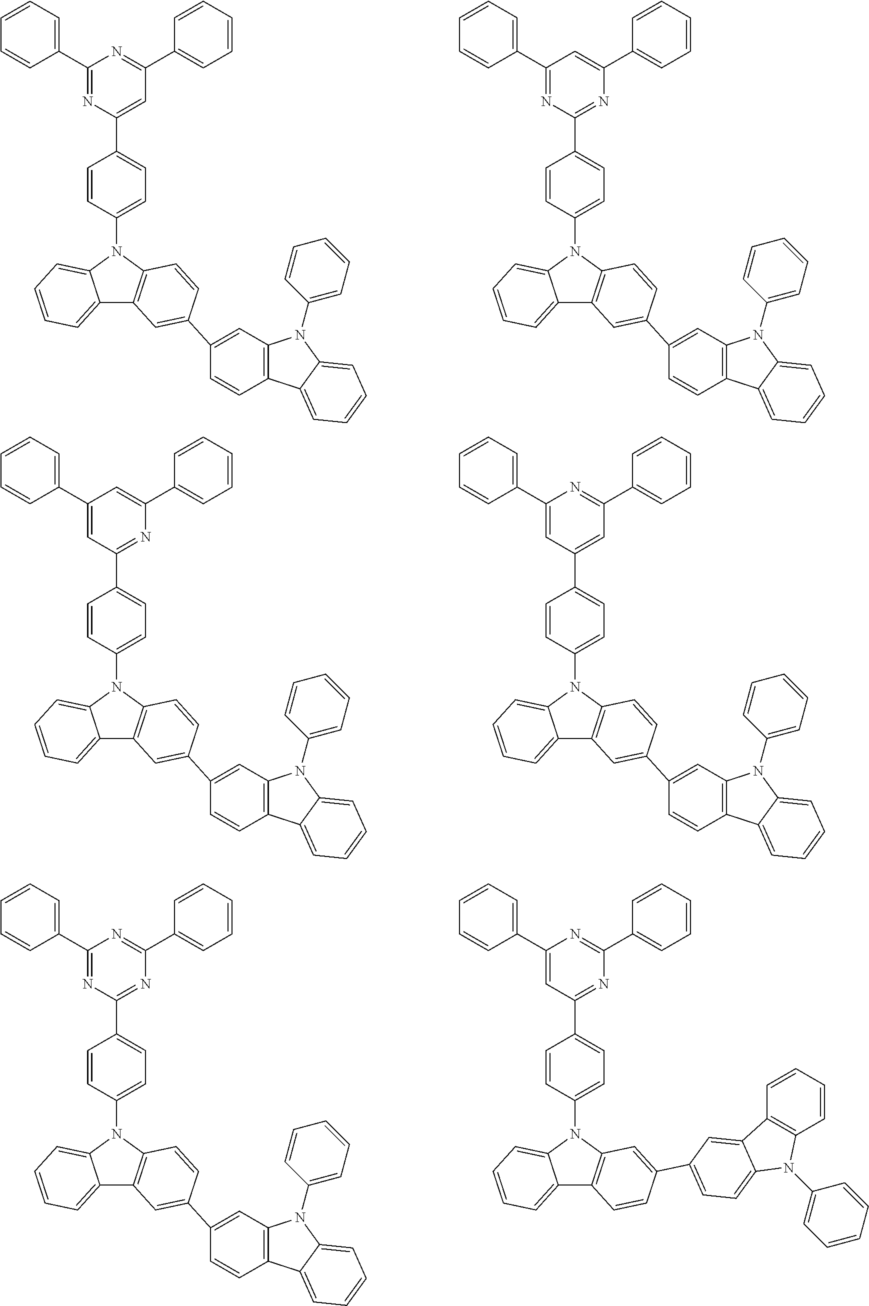

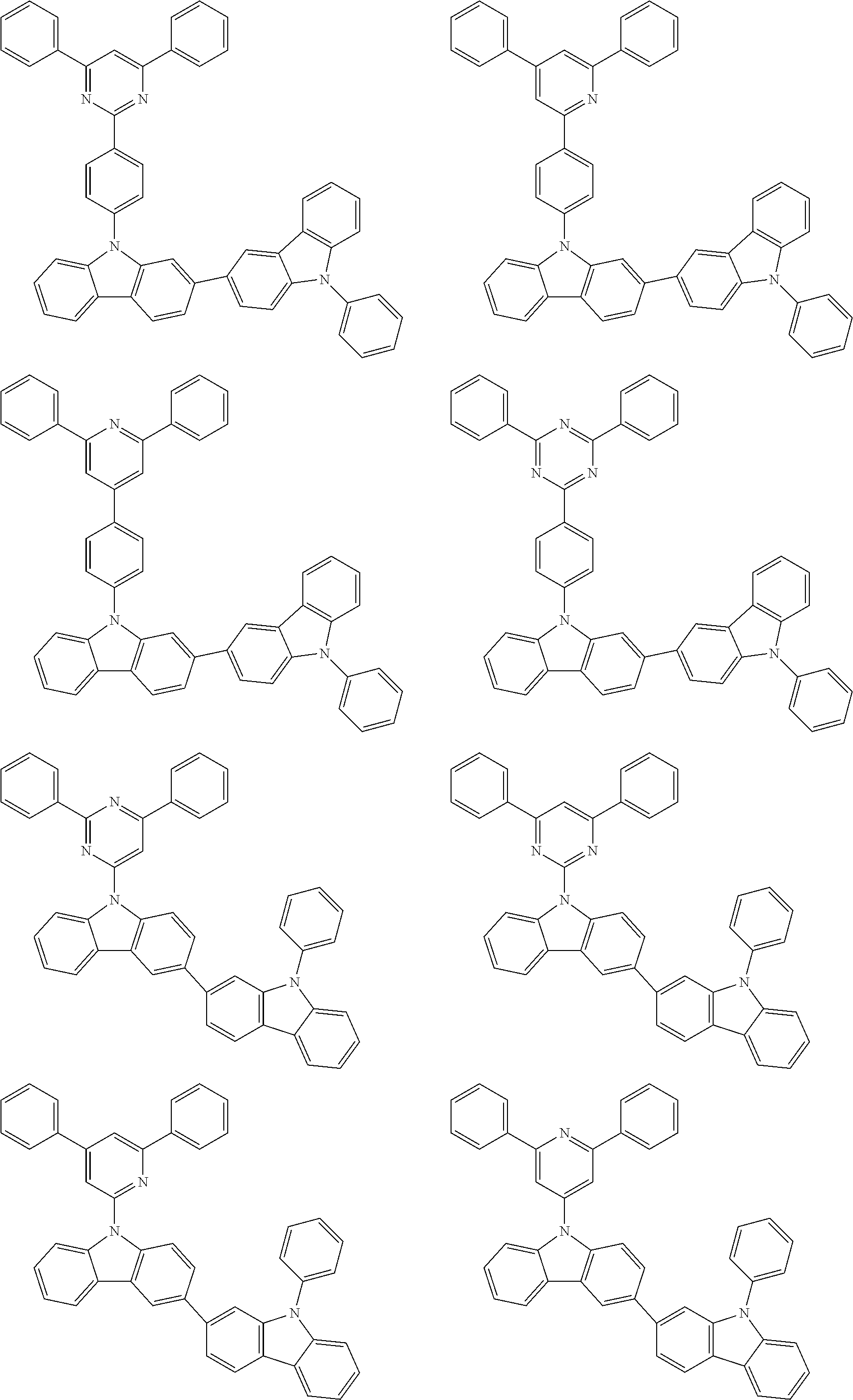

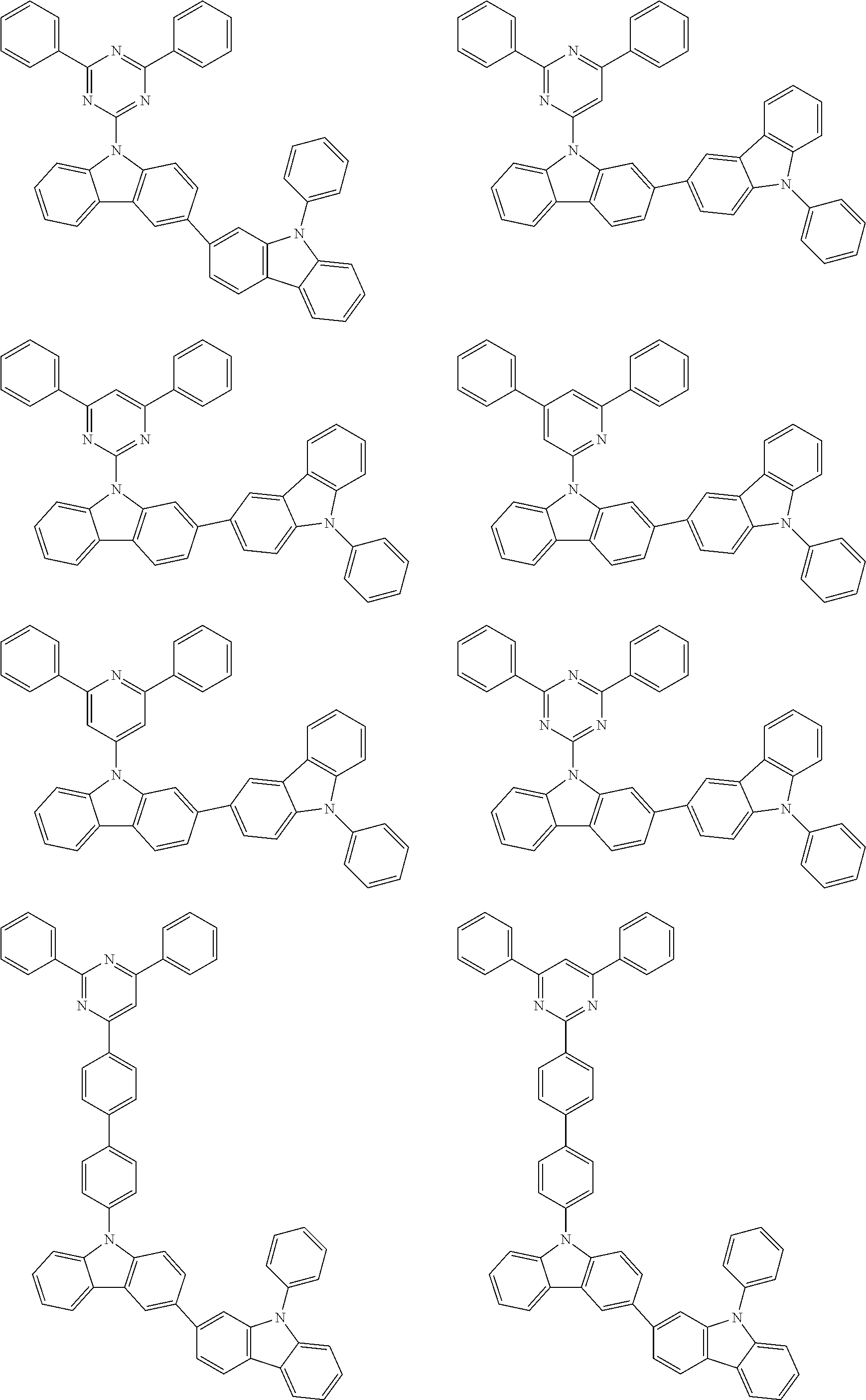

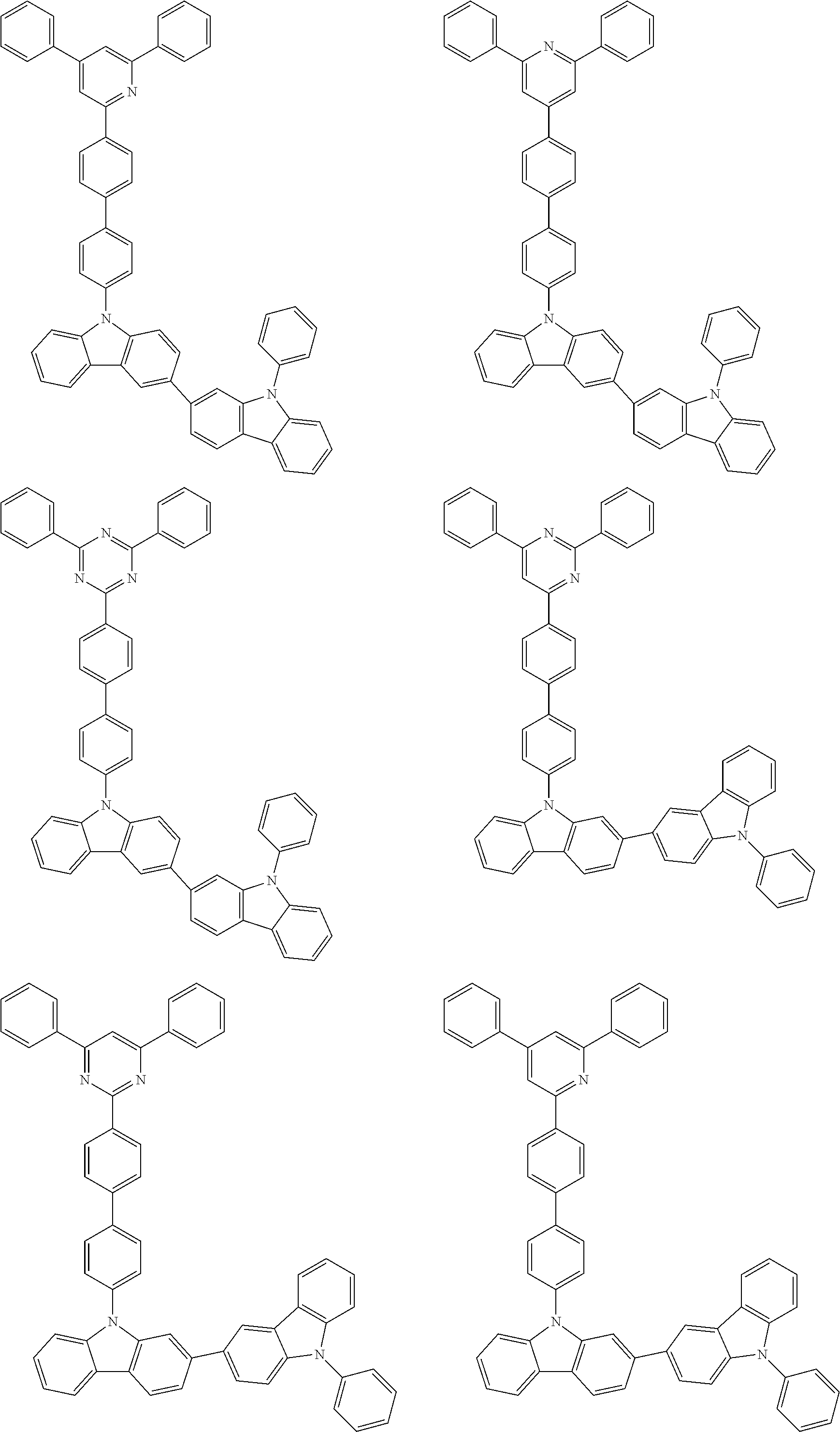

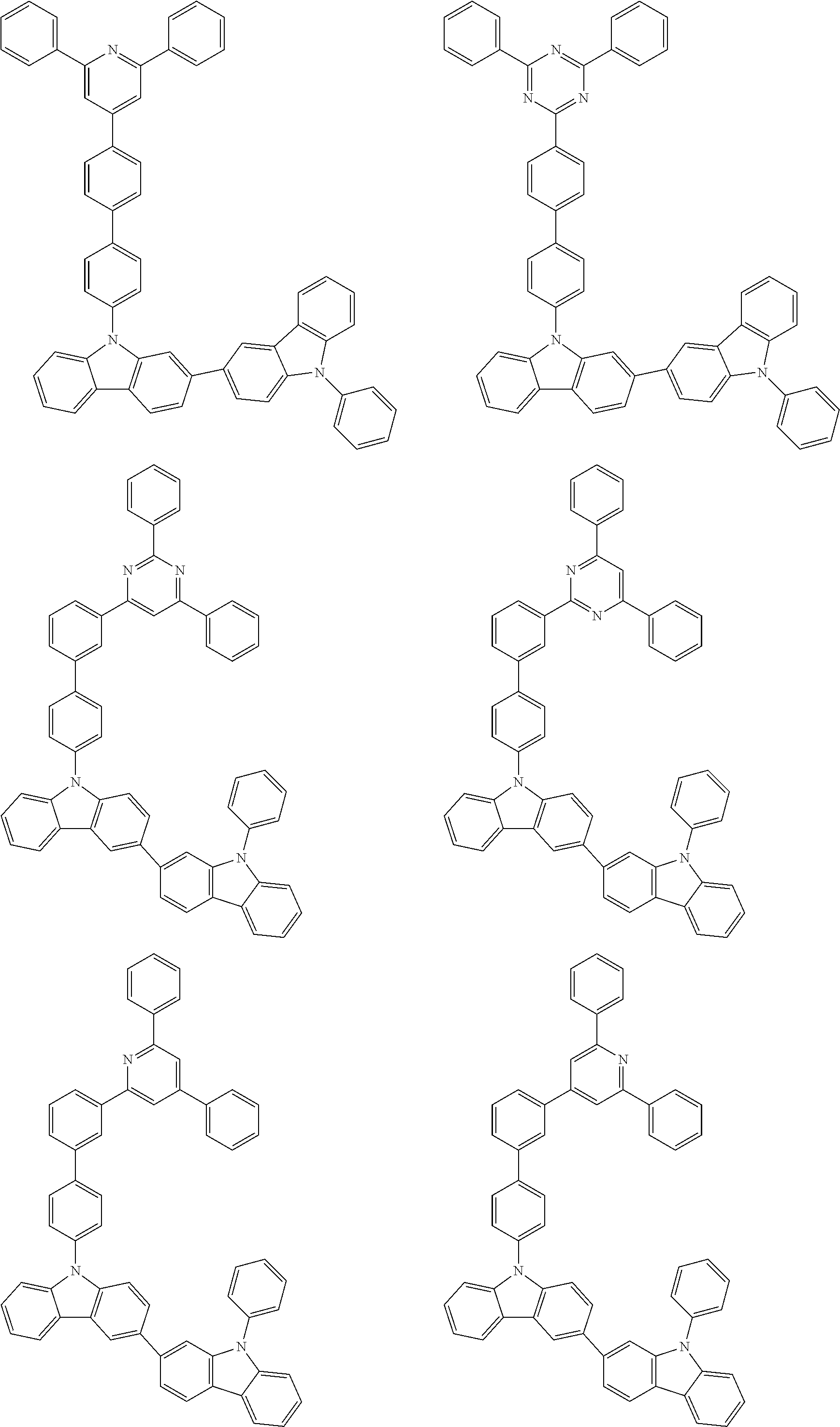

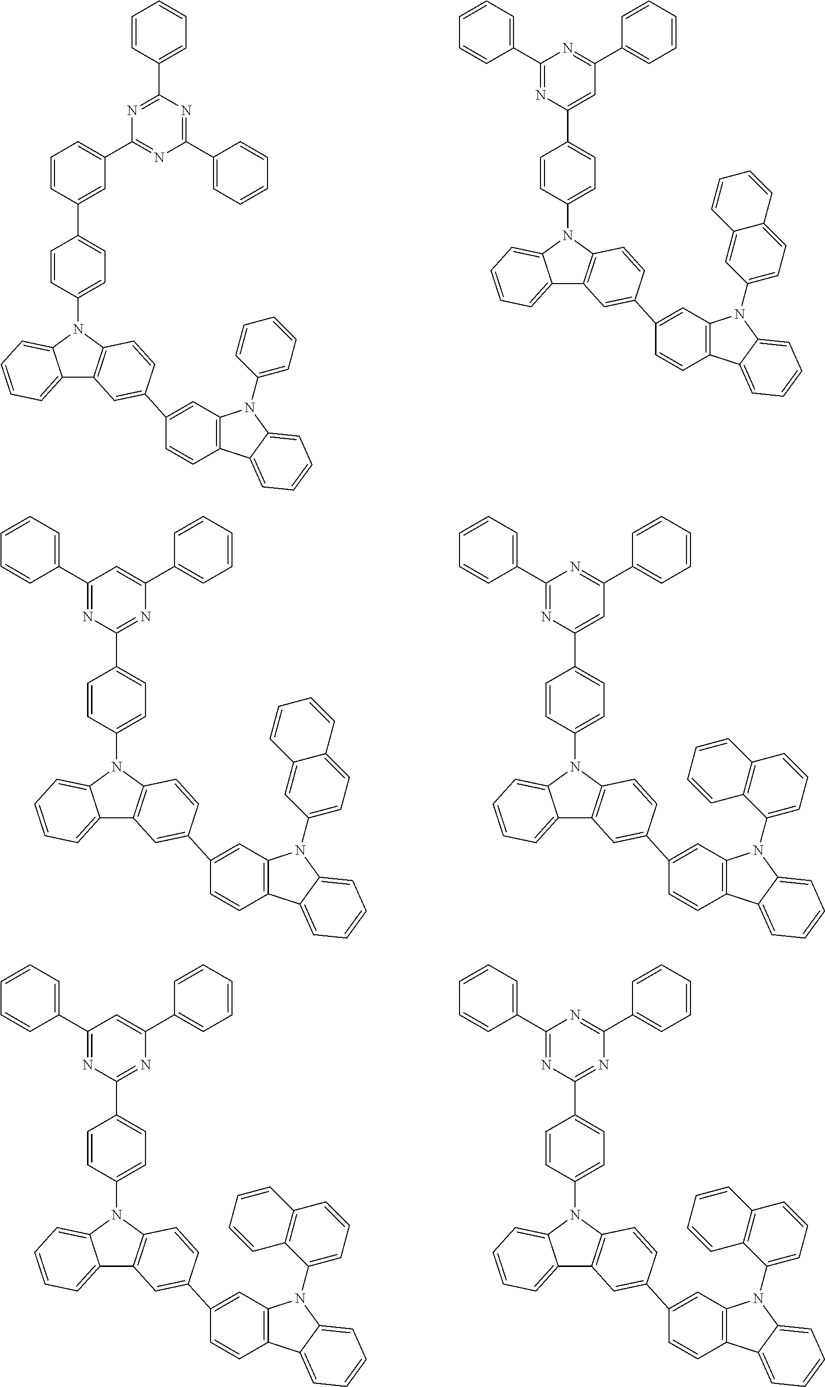

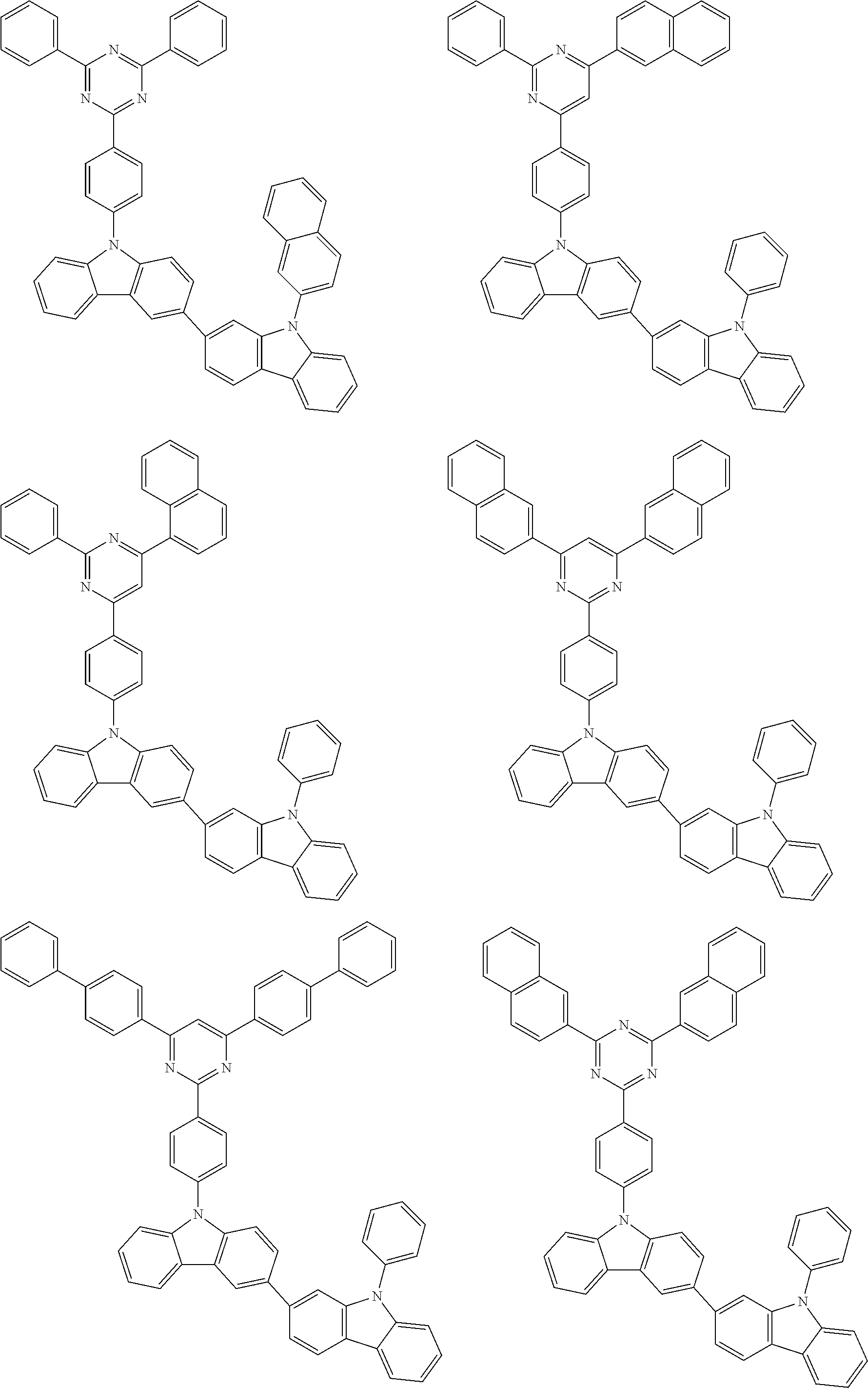

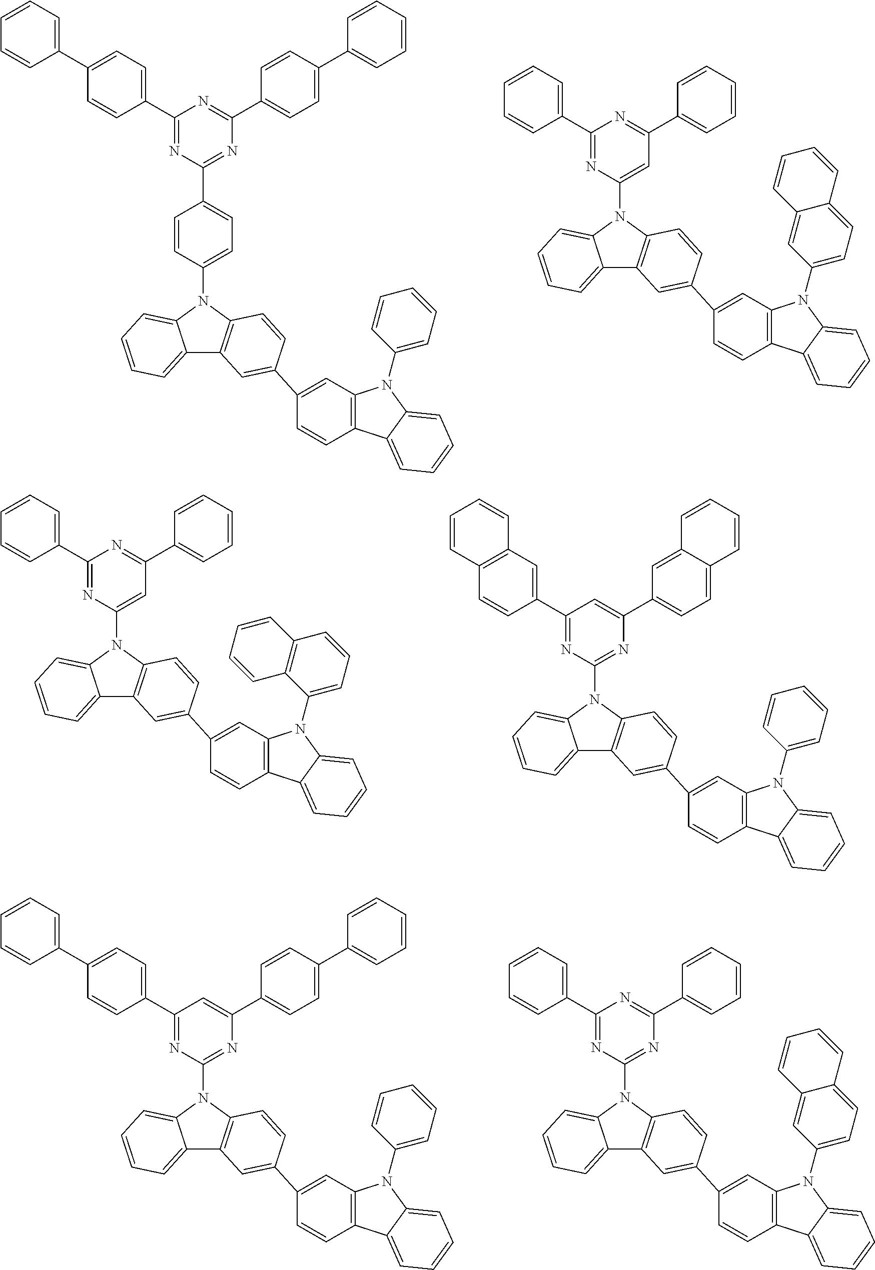

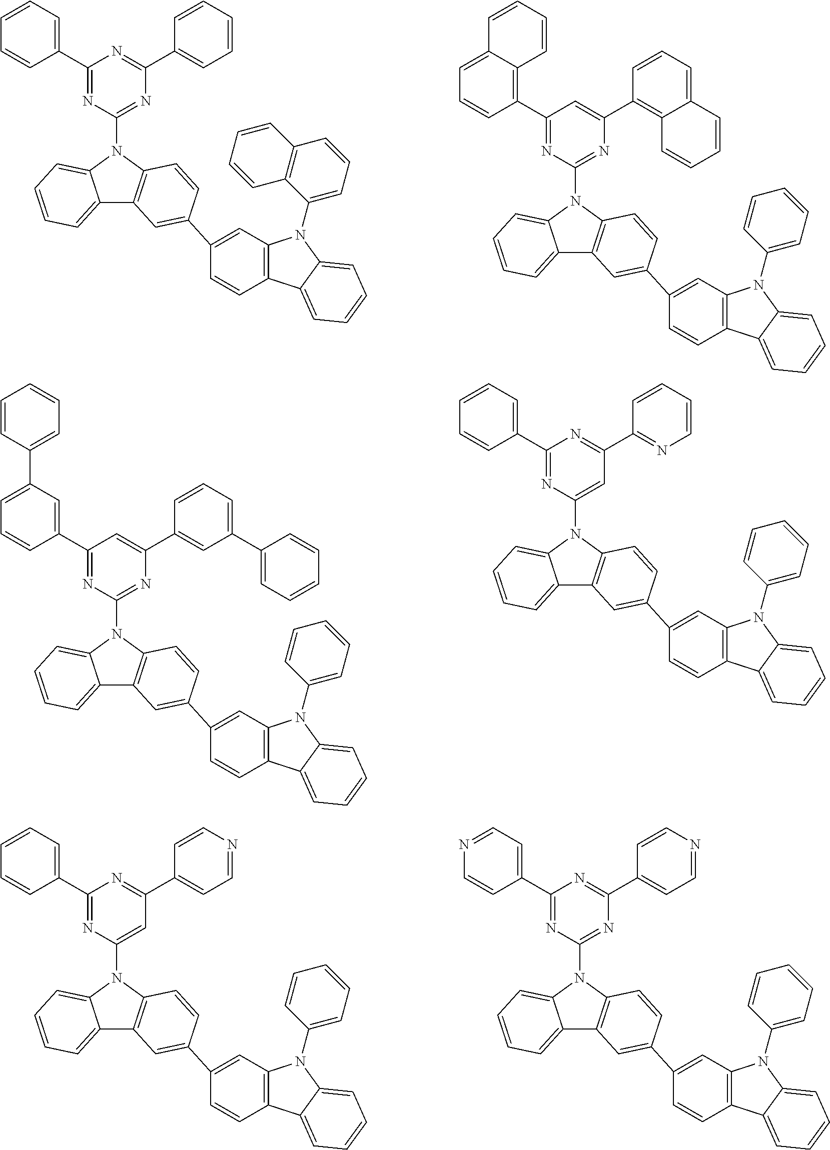

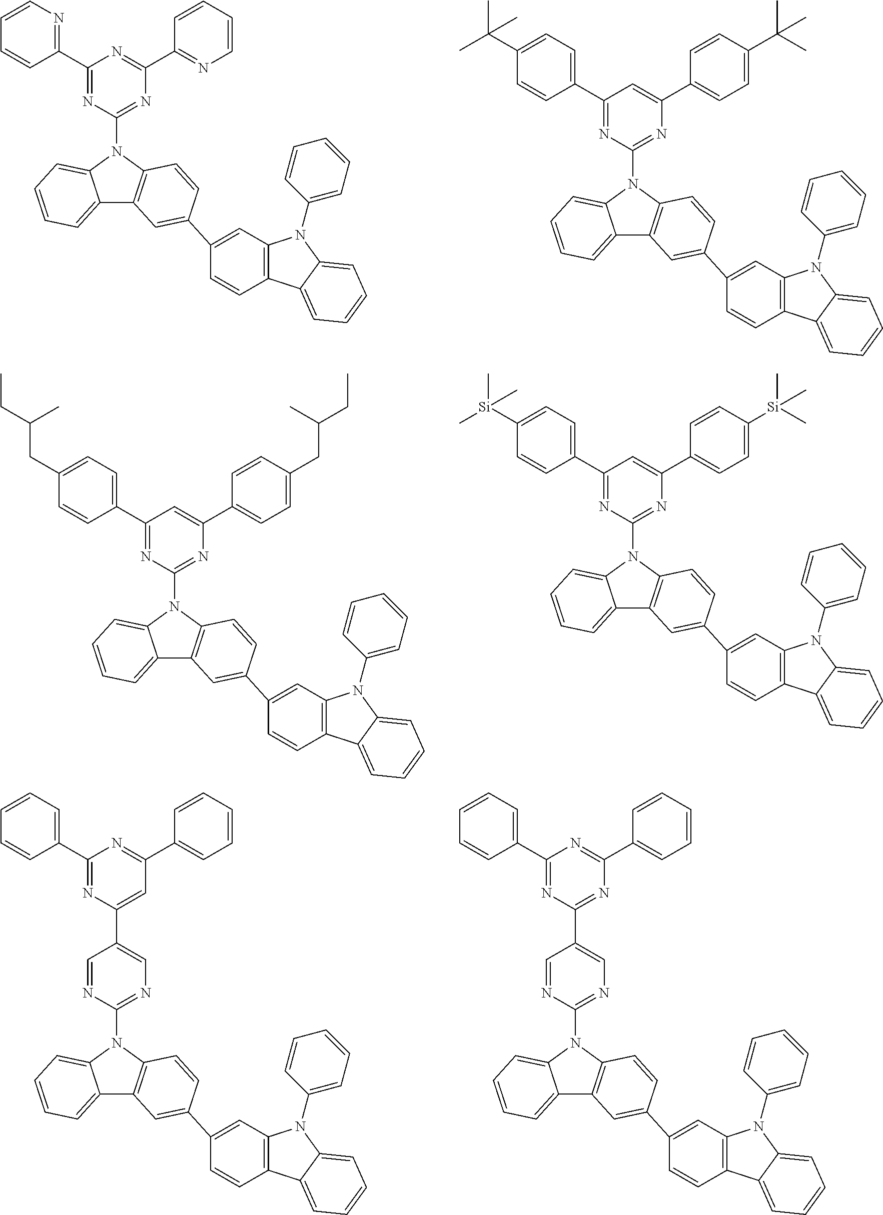

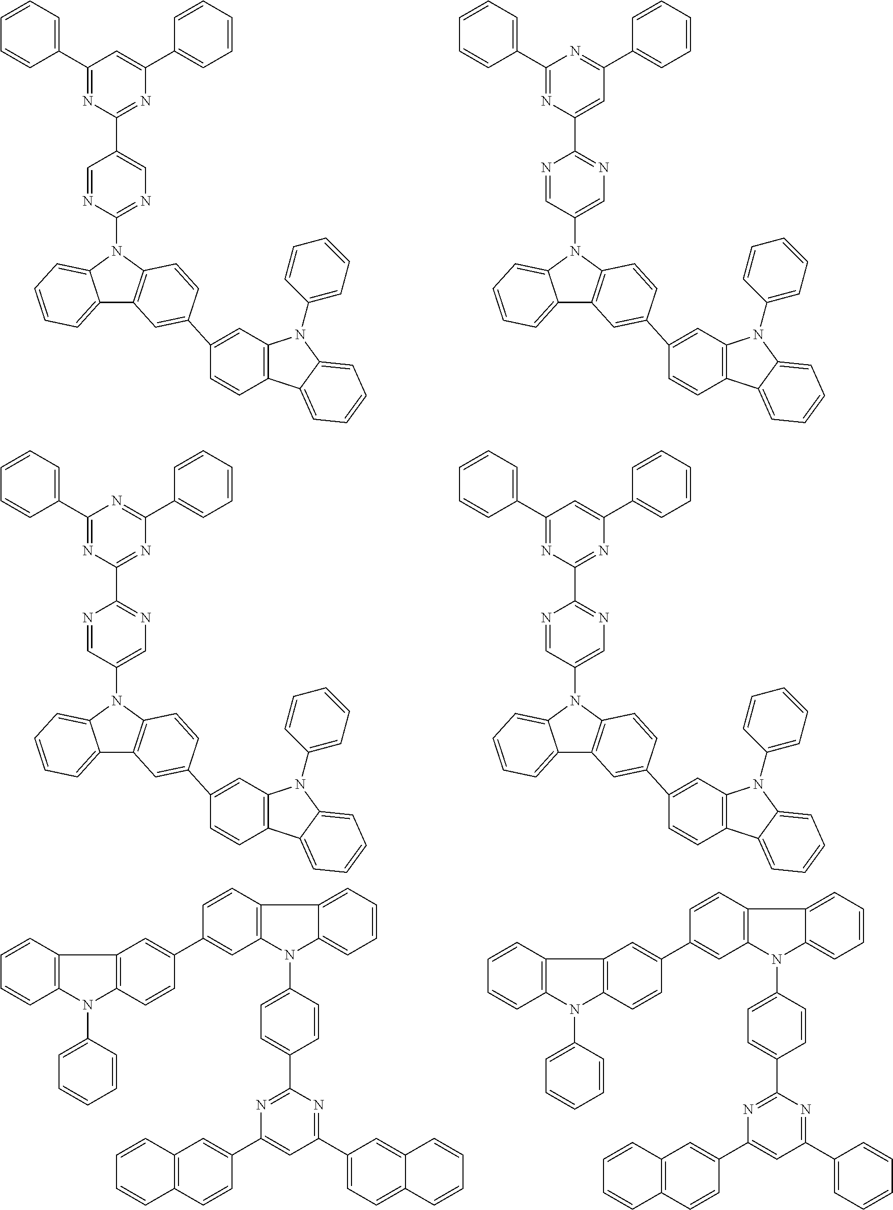

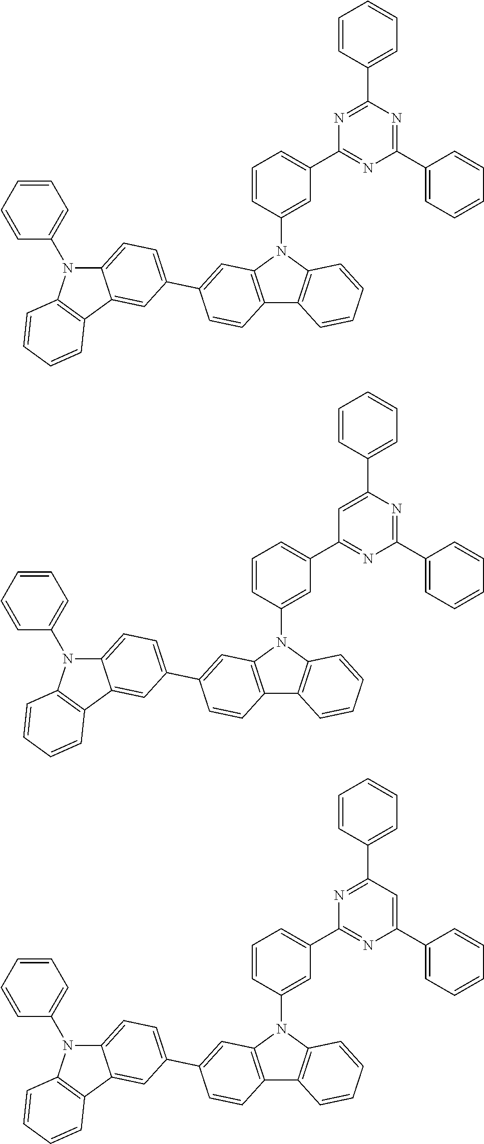 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1 ; c1ccc(-c2cc(-c3ccccc3)nc(-c3cccc(-n4c5ccccc5c5ccc(-c6ccc7c(c6)c6ccccc6n7-c6ccccc6)cc54)c3)n2)cc1]

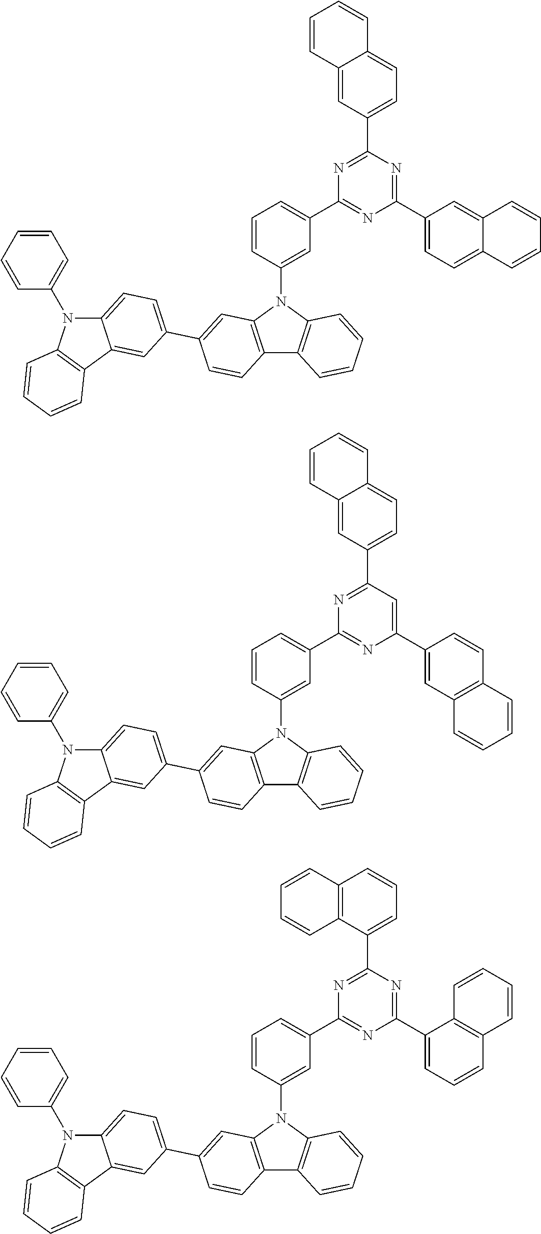 [SMILES: c1ccc(-n2c3ccccc3c3cc(-c4ccc5c6ccccc6n(-c6cccc(-c7nc(-c8ccc9ccccc9c8)nc(-c8ccc9ccccc9c8)n7)c6)c5c4)ccc32)cc1 ; c1ccc(-n2c3ccccc3c3cc(-c4ccc5c6ccccc6n(-c6cccc(-c7nc(-c8ccc9ccccc9c8)cc(-c8ccc9ccccc9c8)n7)c6)c5c4)ccc32)cc1 ; c1ccc(-n2c3ccccc3c3cc(-c4ccc5c6ccccc6n(-c6cccc(-c7nc(-c8cccc9ccccc89)nc(-c8cccc9ccccc89)n7)c6)c5c4)ccc32)cc1]

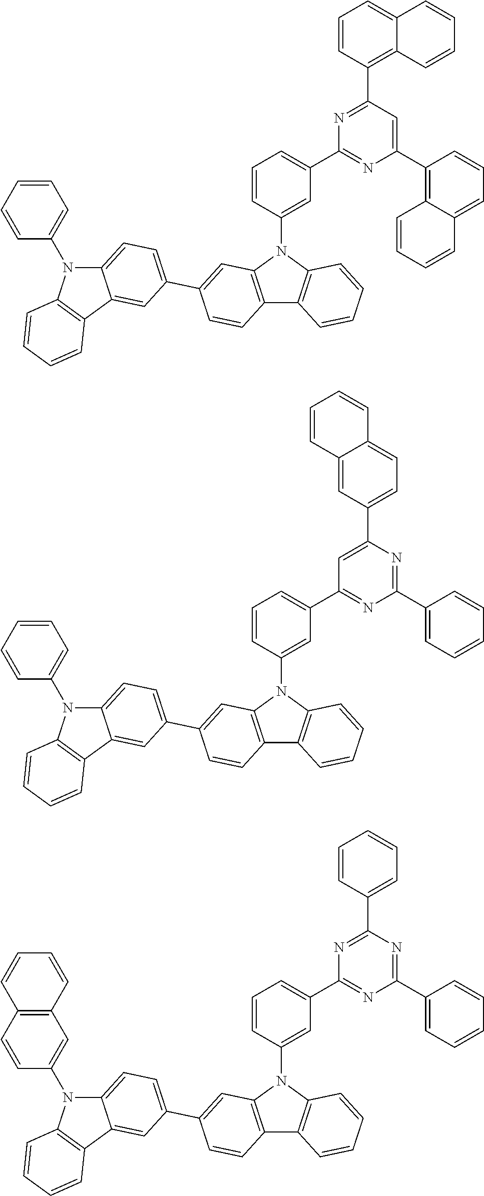 [SMILES: c1ccc(-n2c3ccccc3c3cc(-c4ccc5c6ccccc6n(-c6cccc(-c7nc(-c8cccc9ccccc89)cc(-c8cccc9ccccc89)n7)c6)c5c4)ccc32)cc1 ; c1ccc(-c2nc(-c3cccc(-n4c5ccccc5c5ccc(-c6ccc7c(c6)c6ccccc6n7-c6ccccc6)cc54)c3)cc(-c3ccc4ccccc4c3)n2)cc1 ; c1ccc(-c2nc(-c3ccccc3)nc(-c3cccc(-n4c5ccccc5c5ccc(-c6ccc7c(c6)c6ccccc6n7-c6ccc7ccccc7c6)cc54)c3)n2)cc1]

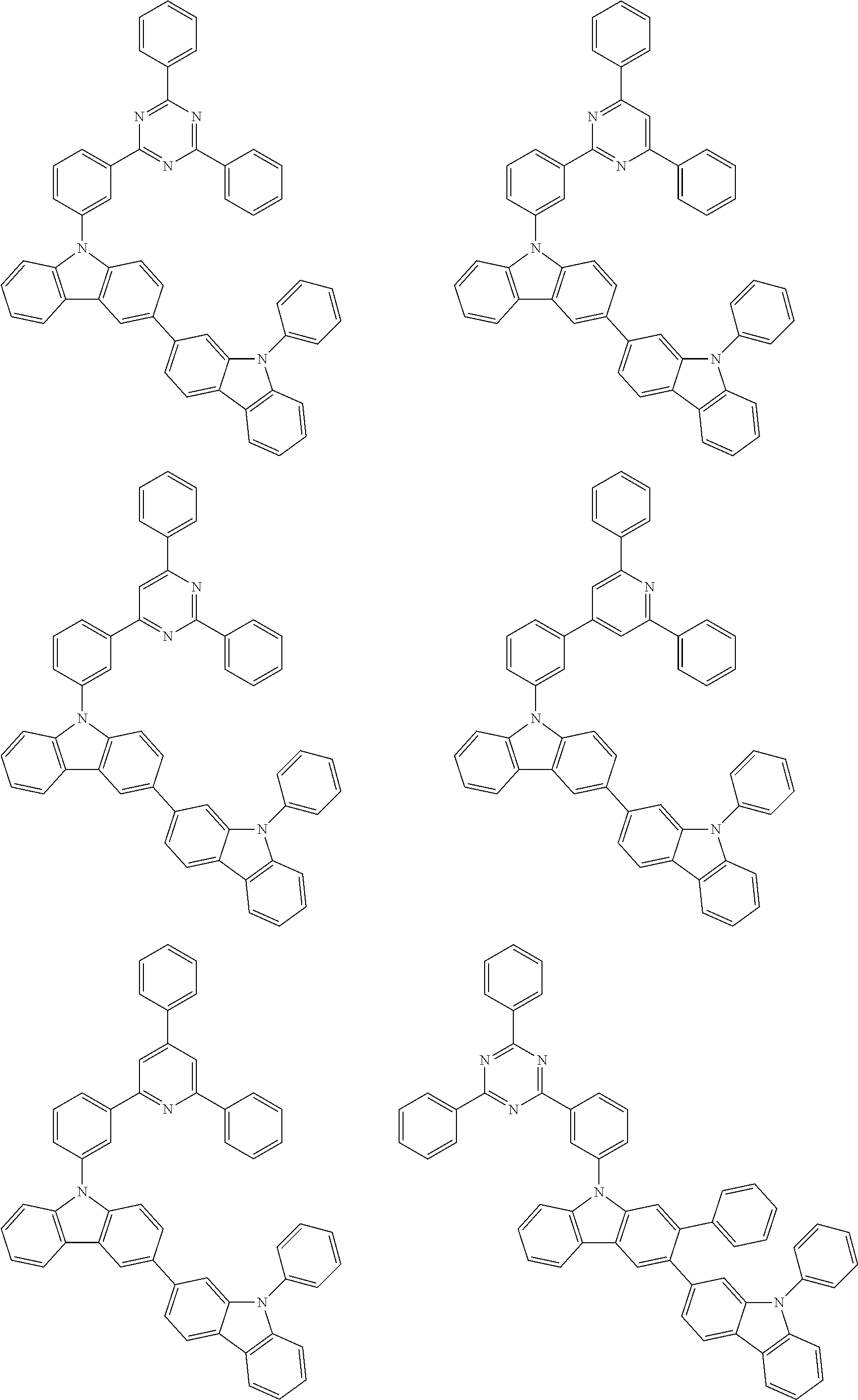

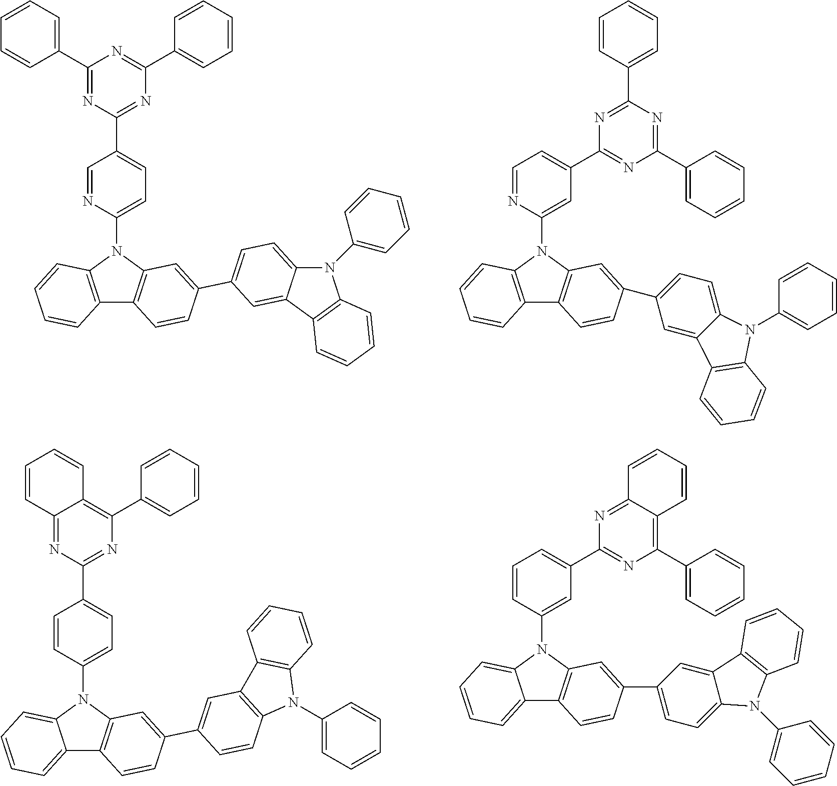 [SMILES: c1ccc(-c2nc(-c3ccccc3)nc(-c3ccc(-n4c5ccccc5c5ccc(-c6ccc7c(c6)c6ccccc6n7-c6ccccc6)cc54)nc3)n2)cc1 ; c1ccc(-c2nc(-c3ccccc3)nc(-c3ccnc(-n4c5ccccc5c5ccc(-c6ccc7c(c6)c6ccccc6n7-c6ccccc6)cc54)c3)n2)cc1 ; c1ccc(-c2nc(-c3ccc(-n4c5ccccc5c5ccc(-c6ccc7c(c6)c6ccccc6n7-c6ccccc6)cc54)cc3)nc3ccccc23)cc1 ; c1ccc(-c2nc(-c3cccc(-n4c5ccccc5c5ccc(-c6ccc7c(c6)c6ccccc6n7-c6ccccc6)cc54)c3)nc3ccccc23)cc1]

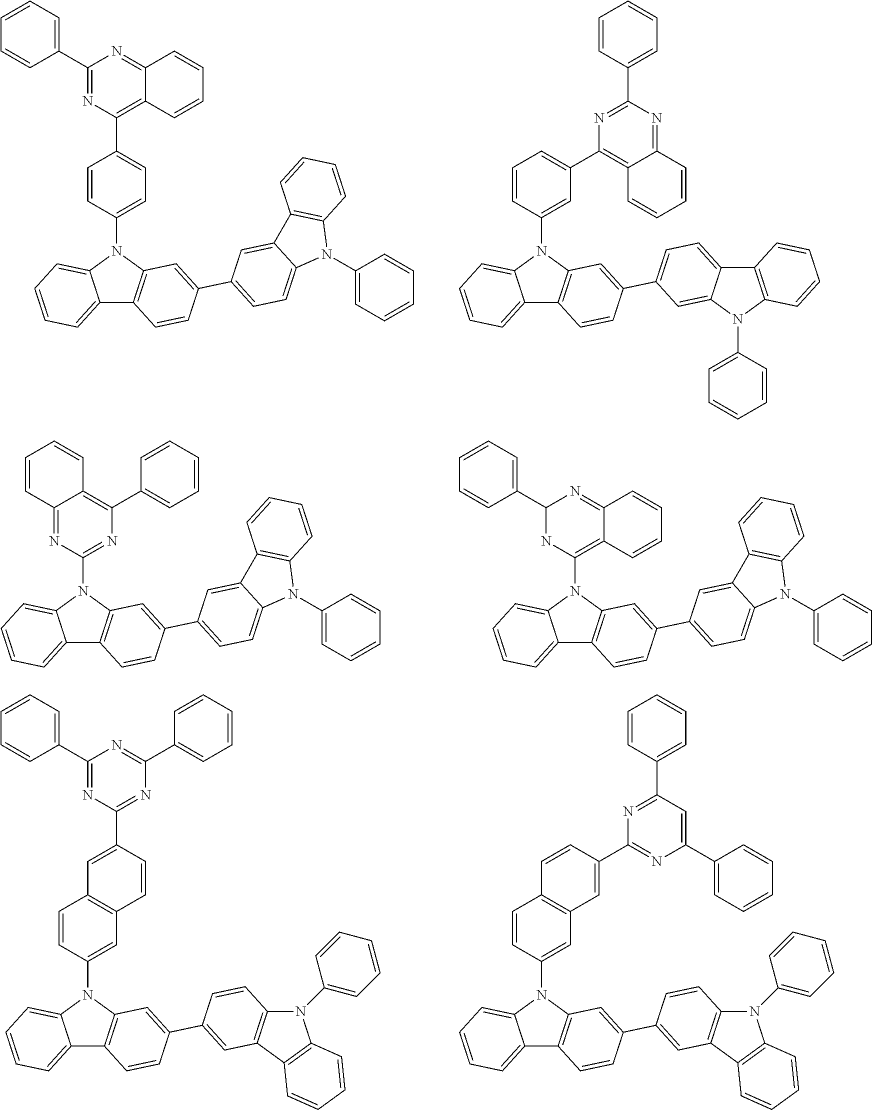

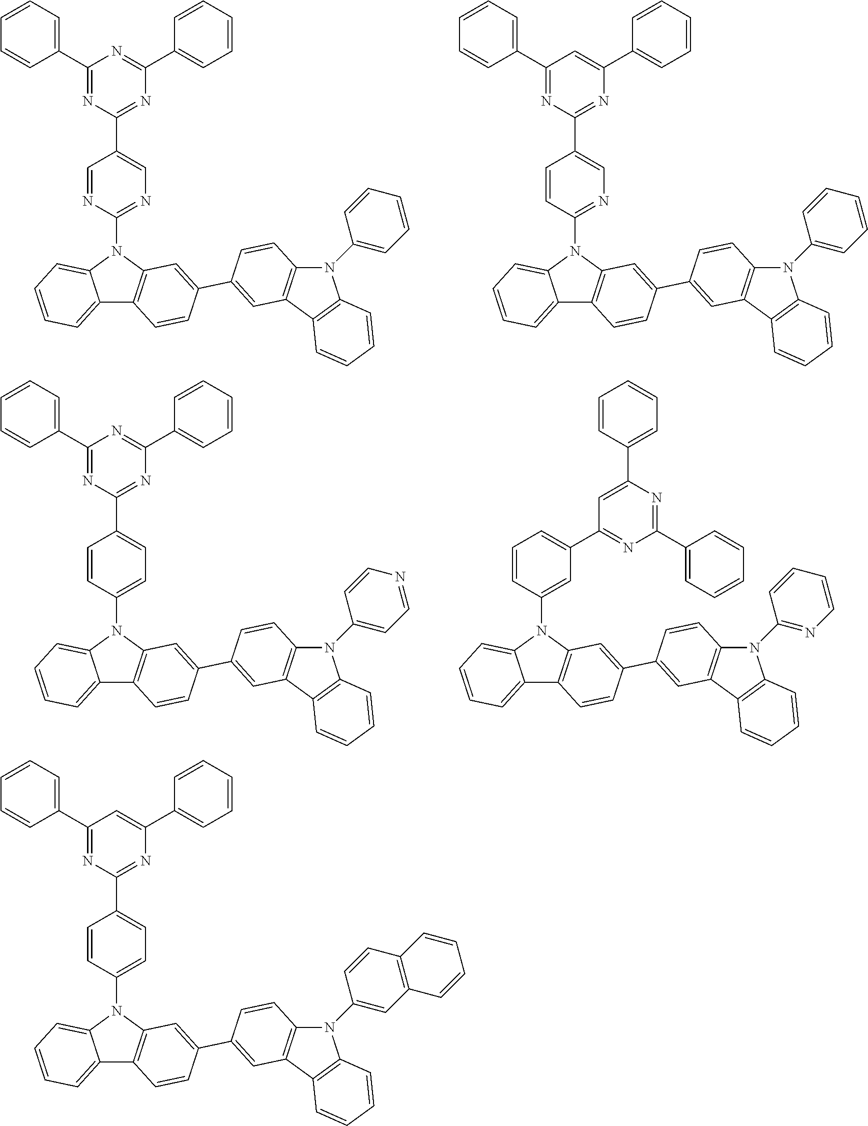 [SMILES: c1ccc(-c2nc(-c3ccccc3)nc(-c3cnc(-n4c5ccccc5c5ccc(-c6ccc7c(c6)c6ccccc6n7-c6ccccc6)cc54)nc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)nc3)n2)cc1 ; c1ccc(-c2nc(-c3ccccc3)nc(-c3ccc(-n4c5ccccc5c5ccc(-c6ccc7c(c6)c6ccccc6n7-c6ccncc6)cc54)cc3)n2)cc1 ; c1ccc(-c2cc(-c3cccc(-n4c5ccccc5c5ccc(-c6ccc7c(c6)c6ccccc6n7-c6ccccn6)cc54)c3)nc(-c3ccccc3)n2)cc1 ; c1ccc(-c2cc(-c3ccccc3)nc(-c3ccc(-n4c5ccccc5c5ccc(-c6ccc7c(c6)c6ccccc6n7-c6ccc7ccccc7c6)cc54)cc3)n2)cc1]

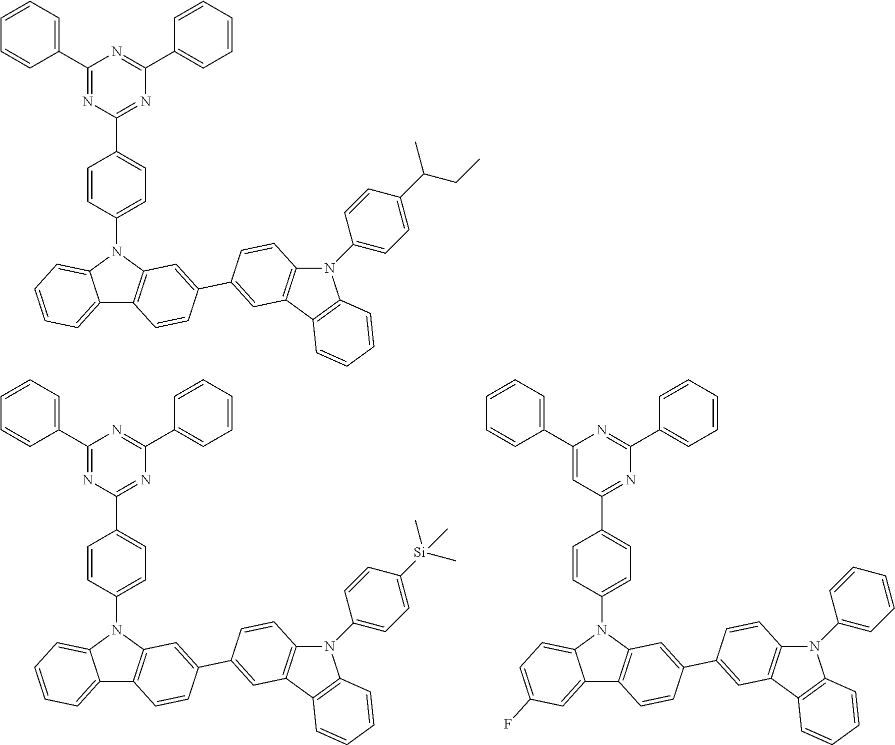 [SMILES: CCC(C)c1ccc(-n2c3ccccc3c3cc(-c4ccc5c6ccccc6n(-c6ccc(-c7nc(-c8ccccc8)nc(-c8ccccc8)n7)cc6)c5c4)ccc32)cc1 ; C[Si](C)(C)c1ccc(-n2c3ccccc3c3cc(-c4ccc5c6ccccc6n(-c6ccc(-c7nc(-c8ccccc8)nc(-c8ccccc8)n7)cc6)c5c4)ccc32)cc1 ; Fc1ccc2c(c1)c1ccc(-c3ccc4c(c3)c3ccccc3n4-c3ccccc3)cc1n2-c1ccc(-c2cc(-c3ccccc3)nc(-c3ccccc3)n2)cc1]

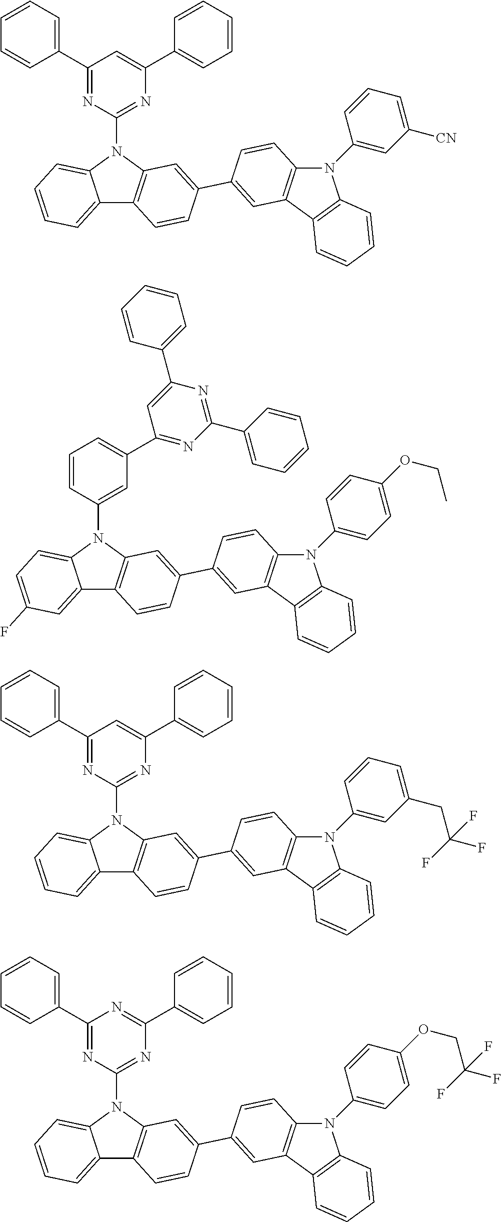

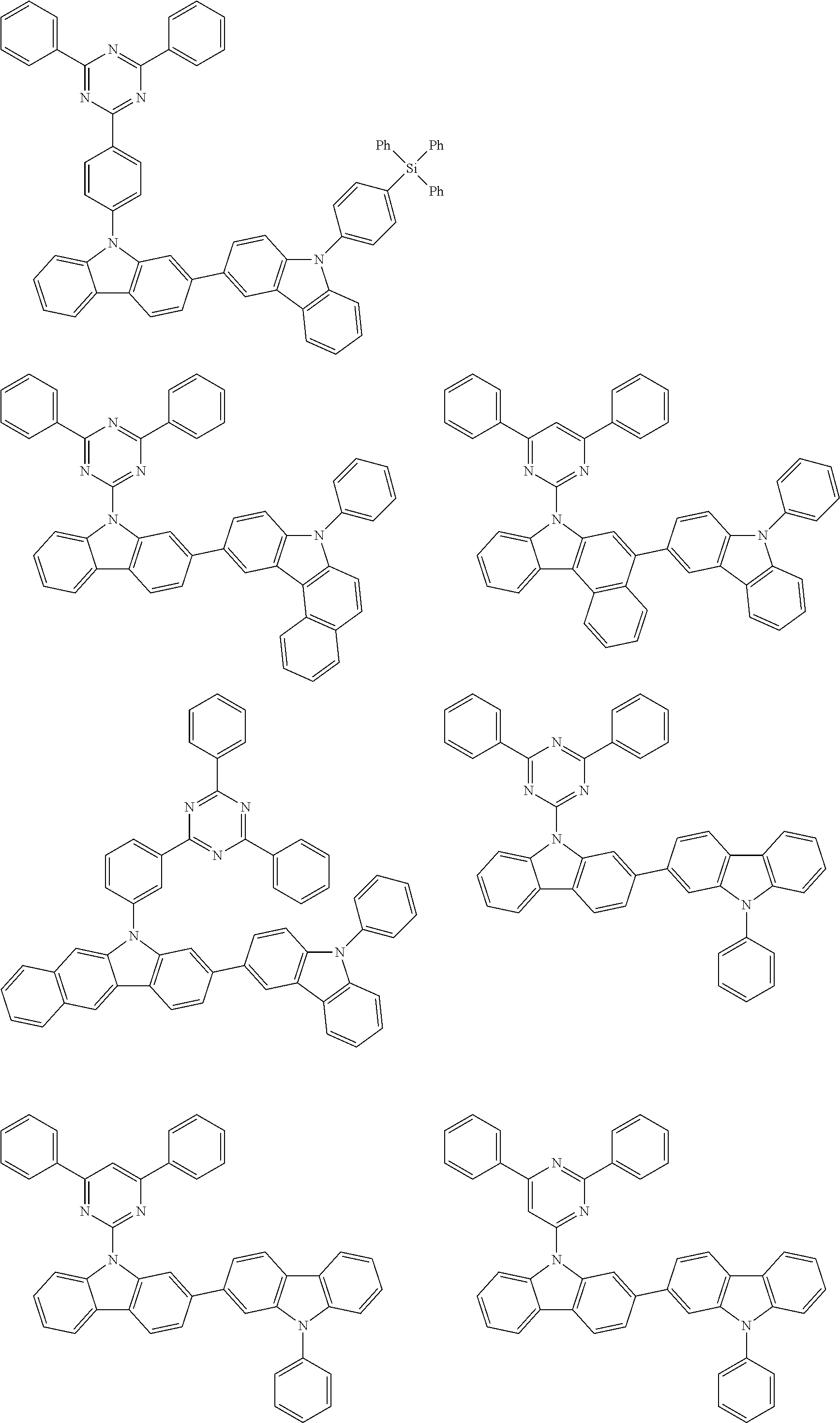

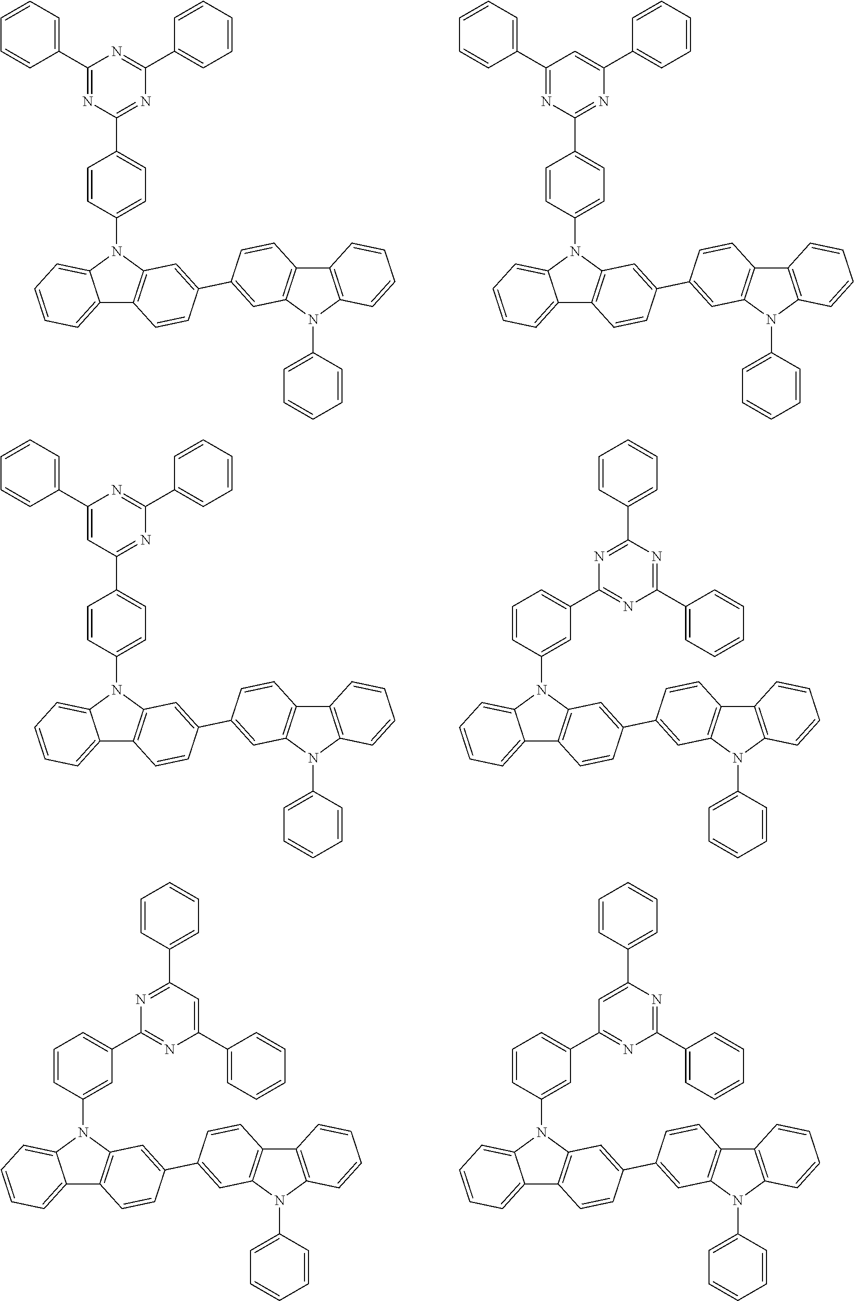

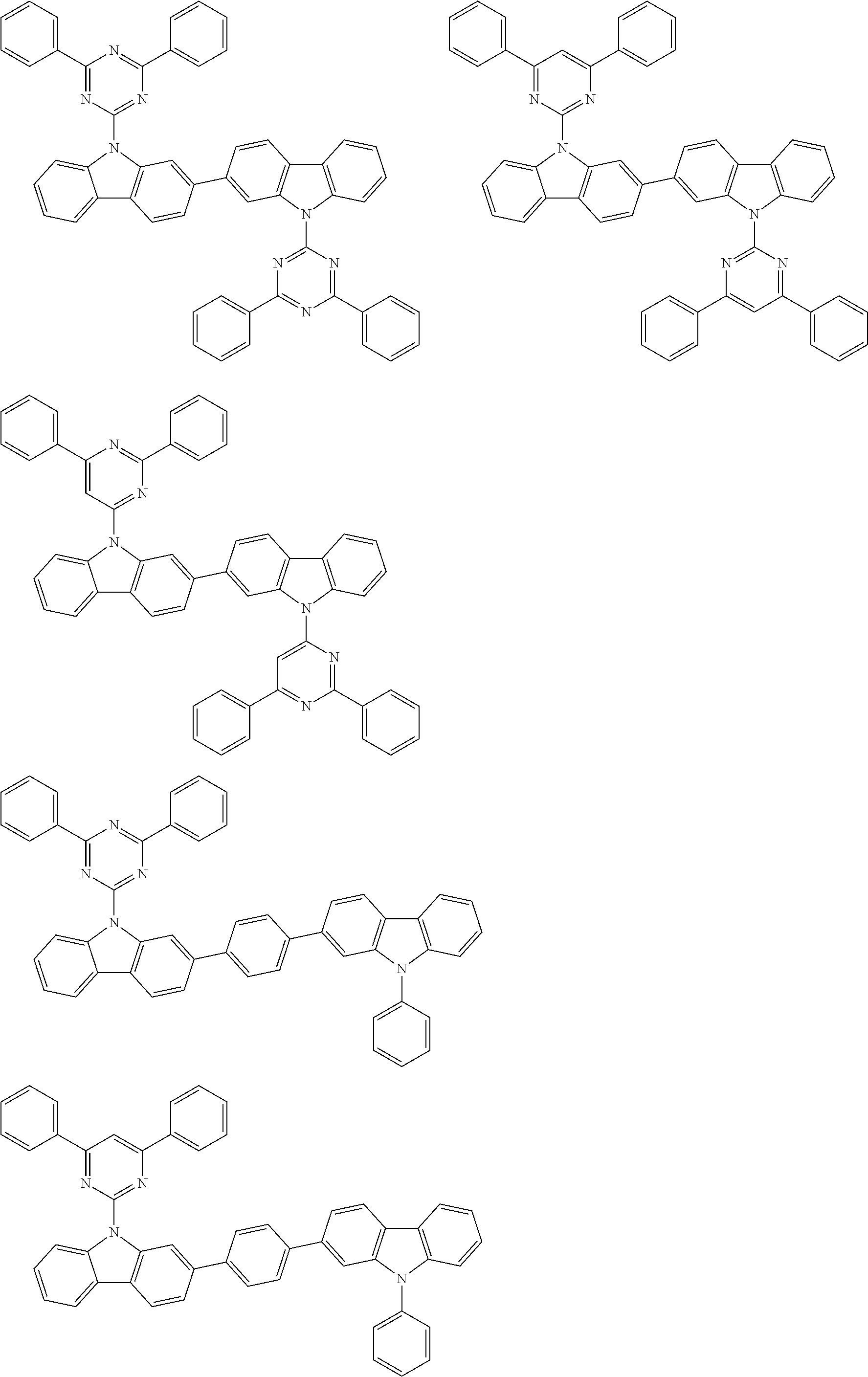

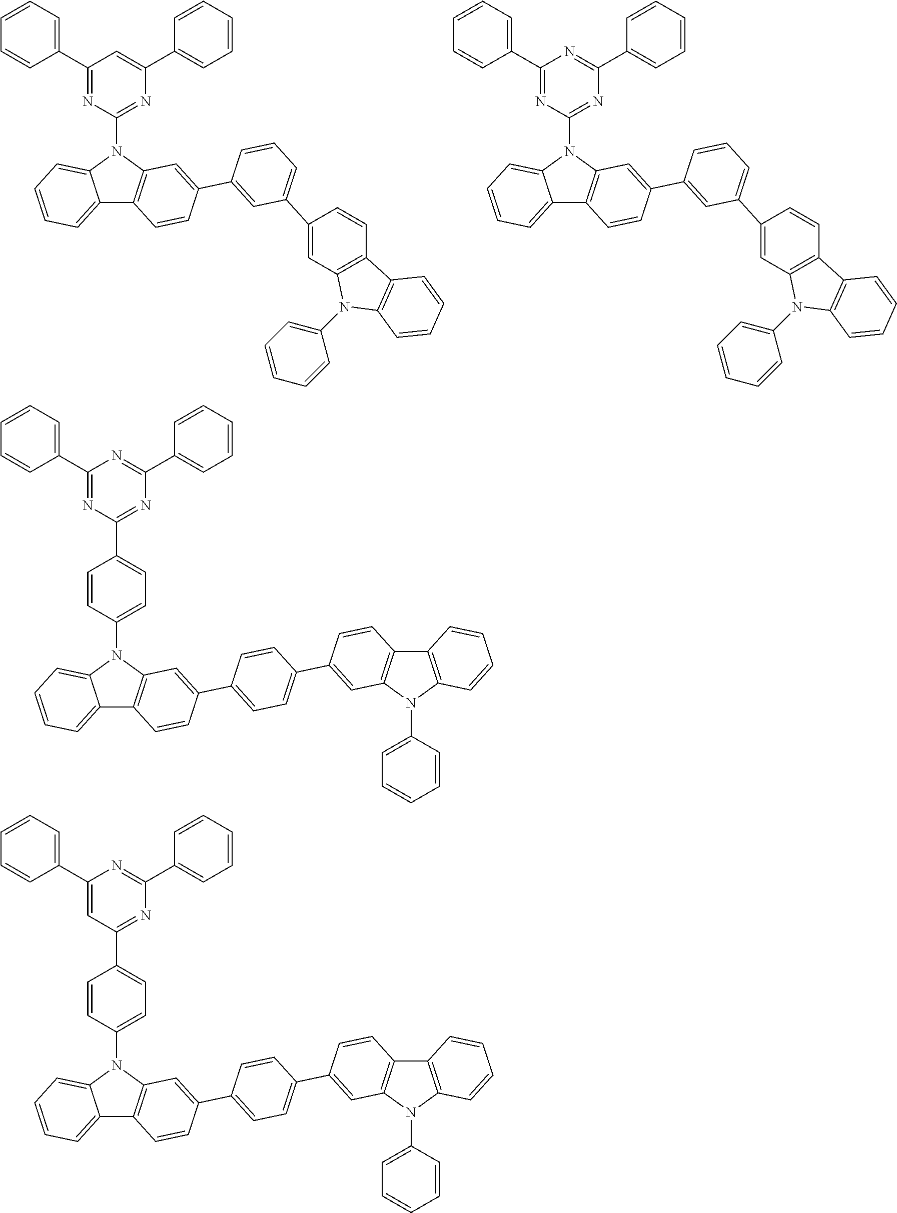 [SMILES: c1ccc(-c2cc(-c3ccccc3)nc(-n3c4ccccc4c4ccc(-c5cccc(-c6ccc7c8ccccc8n(-c8ccccc8)c7c6)c5)cc43)n2)cc1 ; c1ccc(-c2nc(-c3ccccc3)nc(-n3c4ccccc4c4ccc(-c5cccc(-c6ccc7c8ccccc8n(-c8ccccc8)c7c6)c5)cc43)n2)cc1 ; c1ccc(-c2nc(-c3ccccc3)nc(-c3ccc(-n4c5ccccc5c5ccc(-c6ccc(-c7ccc8c9ccccc9n(-c9ccccc9)c8c7)cc6)cc54)cc3)n2)cc1 ; c1ccc(-c2cc(-c3ccc(-n4c5ccccc5c5ccc(-c6ccc(-c7ccc8c9ccccc9n(-c9ccccc9)c8c7)cc6)cc54)cc3)nc(-c3ccccc3)n2)cc1]

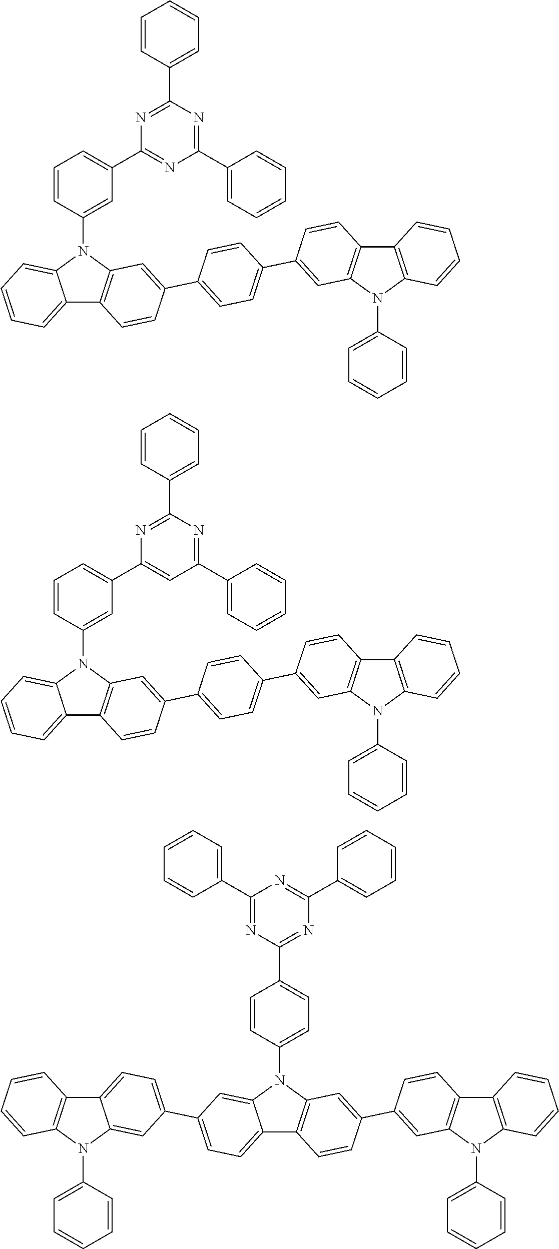

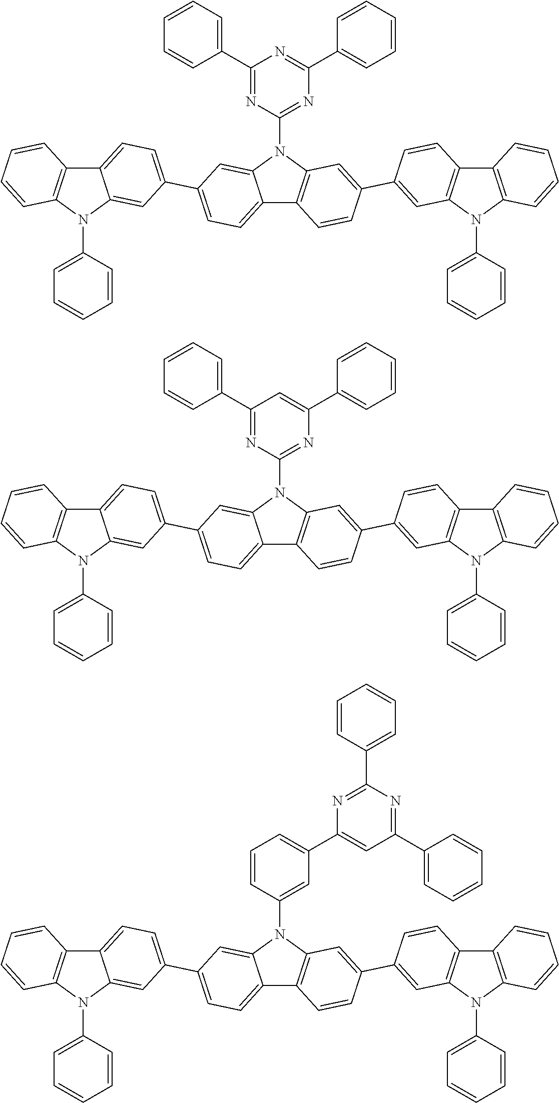 [SMILES: c1ccc(-c2nc(-c3ccccc3)nc(-n3c4cc(-c5ccc6c7ccccc7n(-c7ccccc7)c6c5)ccc4c4ccc(-c5ccc6c7ccccc7n(-c7ccccc7)c6c5)cc43)n2)cc1 ; c1ccc(-c2cc(-c3ccccc3)nc(-n3c4cc(-c5ccc6c7ccccc7n(-c7ccccc7)c6c5)ccc4c4ccc(-c5ccc6c7ccccc7n(-c7ccccc7)c6c5)cc43)n2)cc1 ; c1ccc(-c2cc(-c3cccc(-n4c5cc(-c6ccc7c8ccccc8n(-c8ccccc8)c7c6)ccc5c5ccc(-c6ccc7c8ccccc8n(-c8ccccc8)c7c6)cc54)c3)nc(-c3ccccc3)n2)cc1]

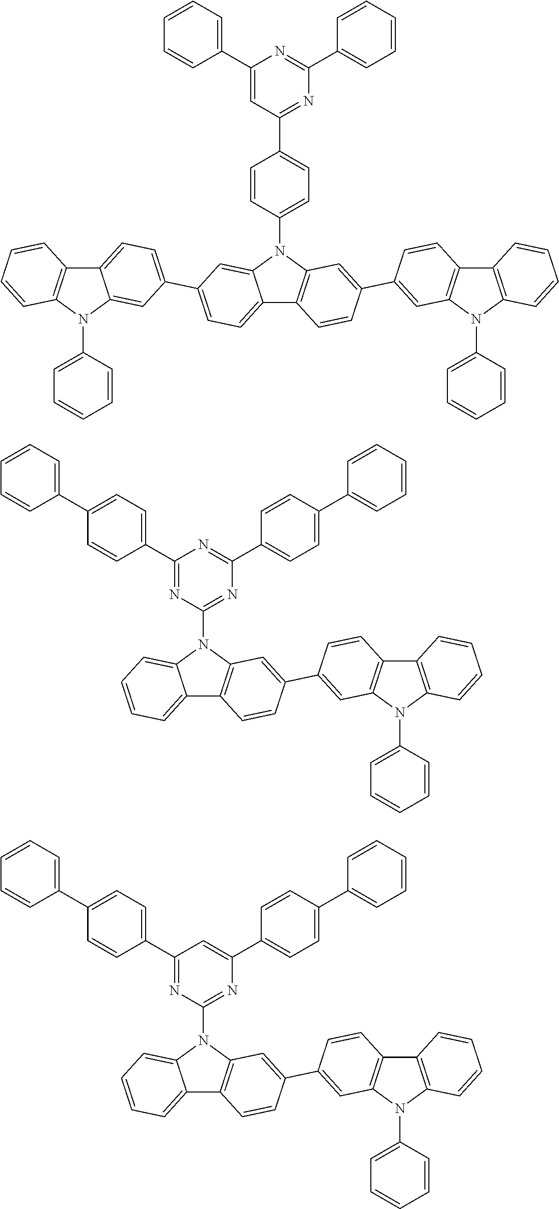

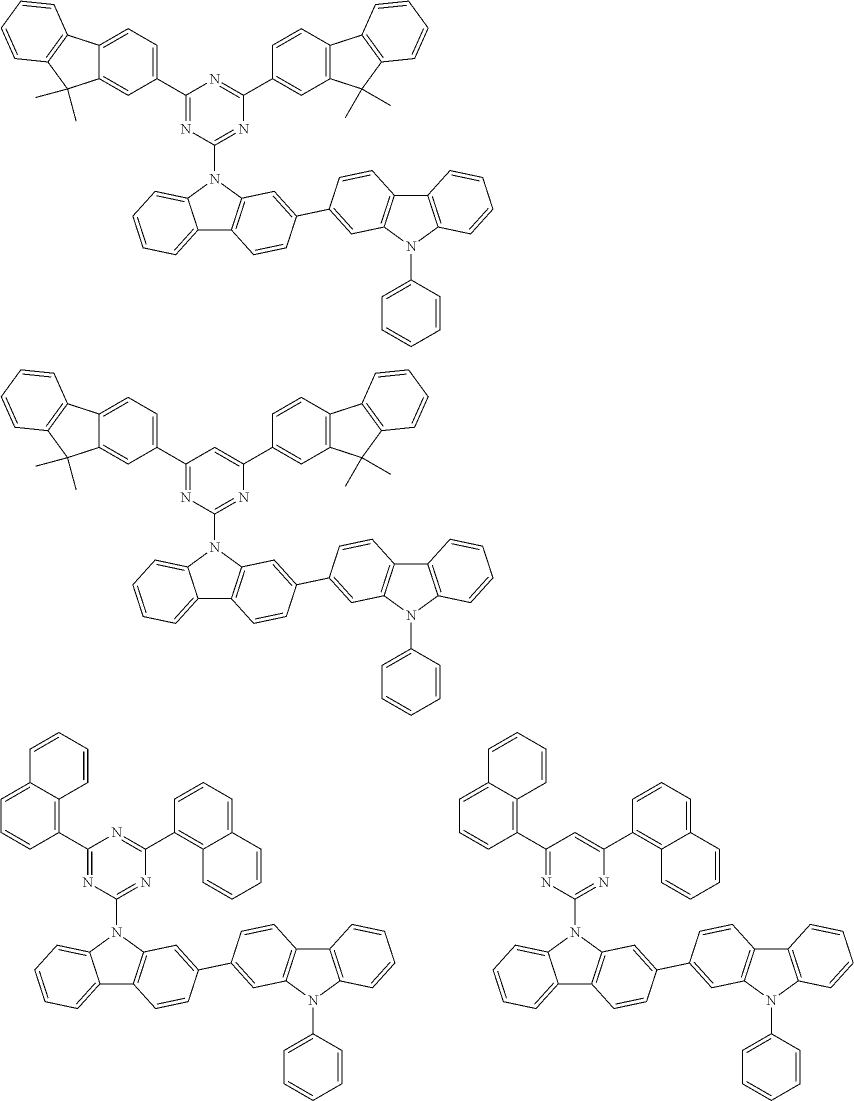

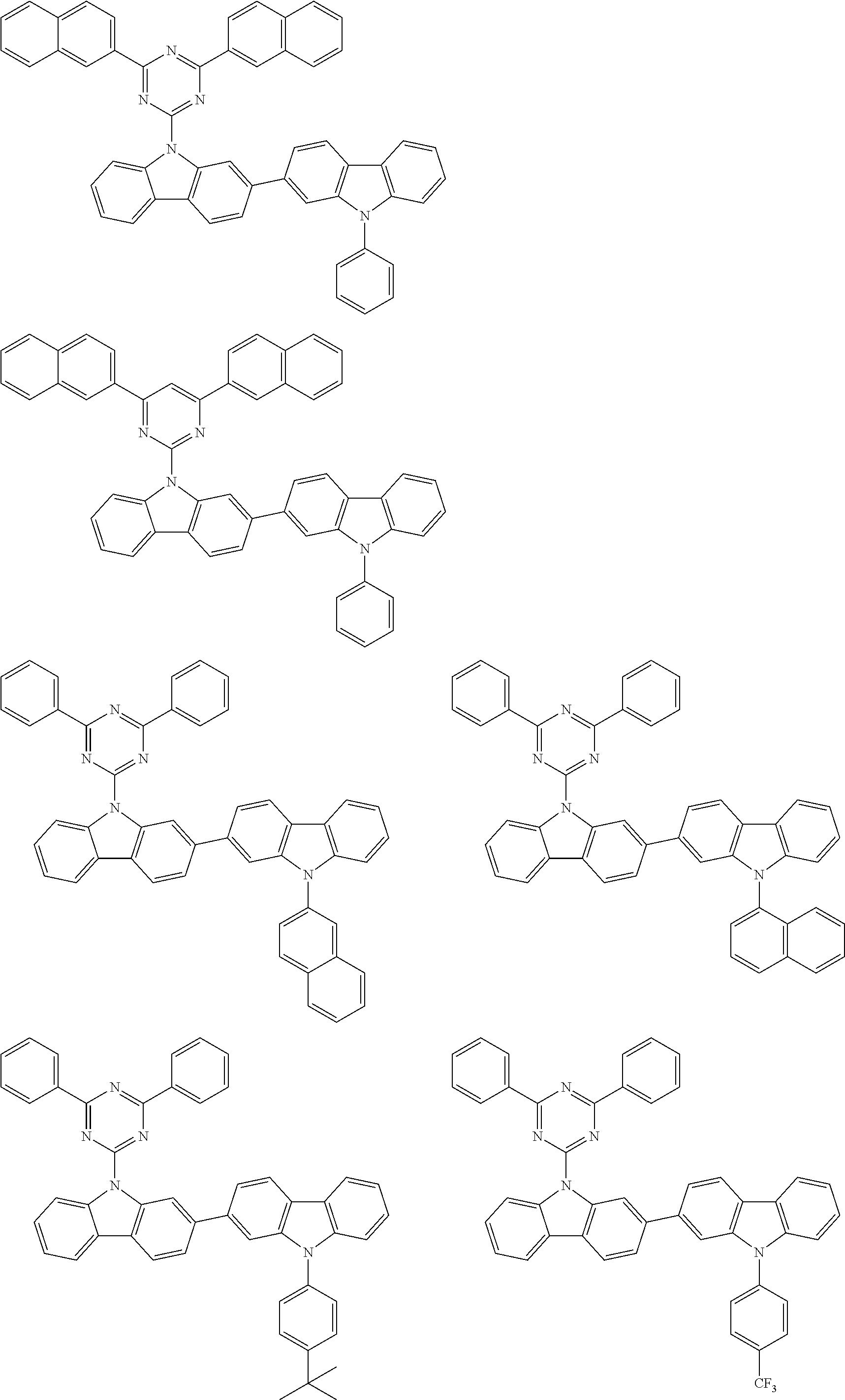

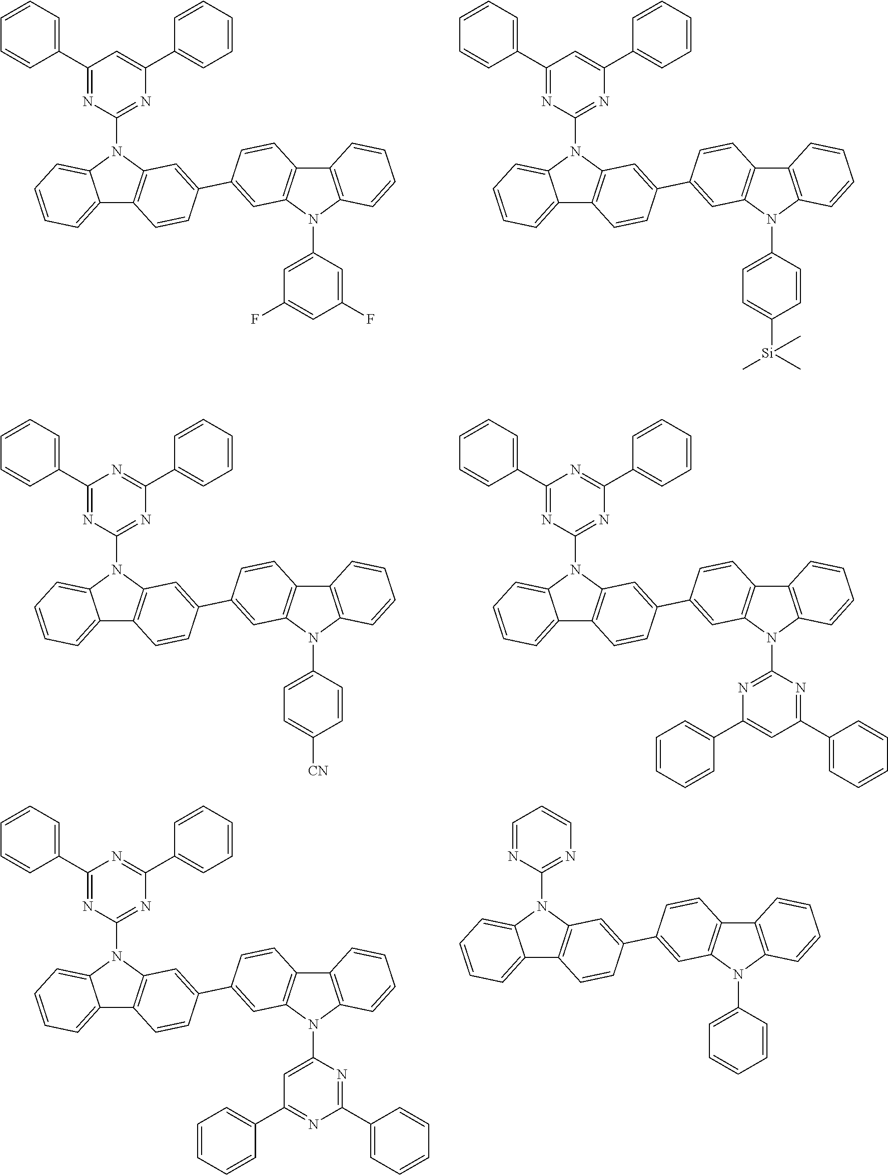

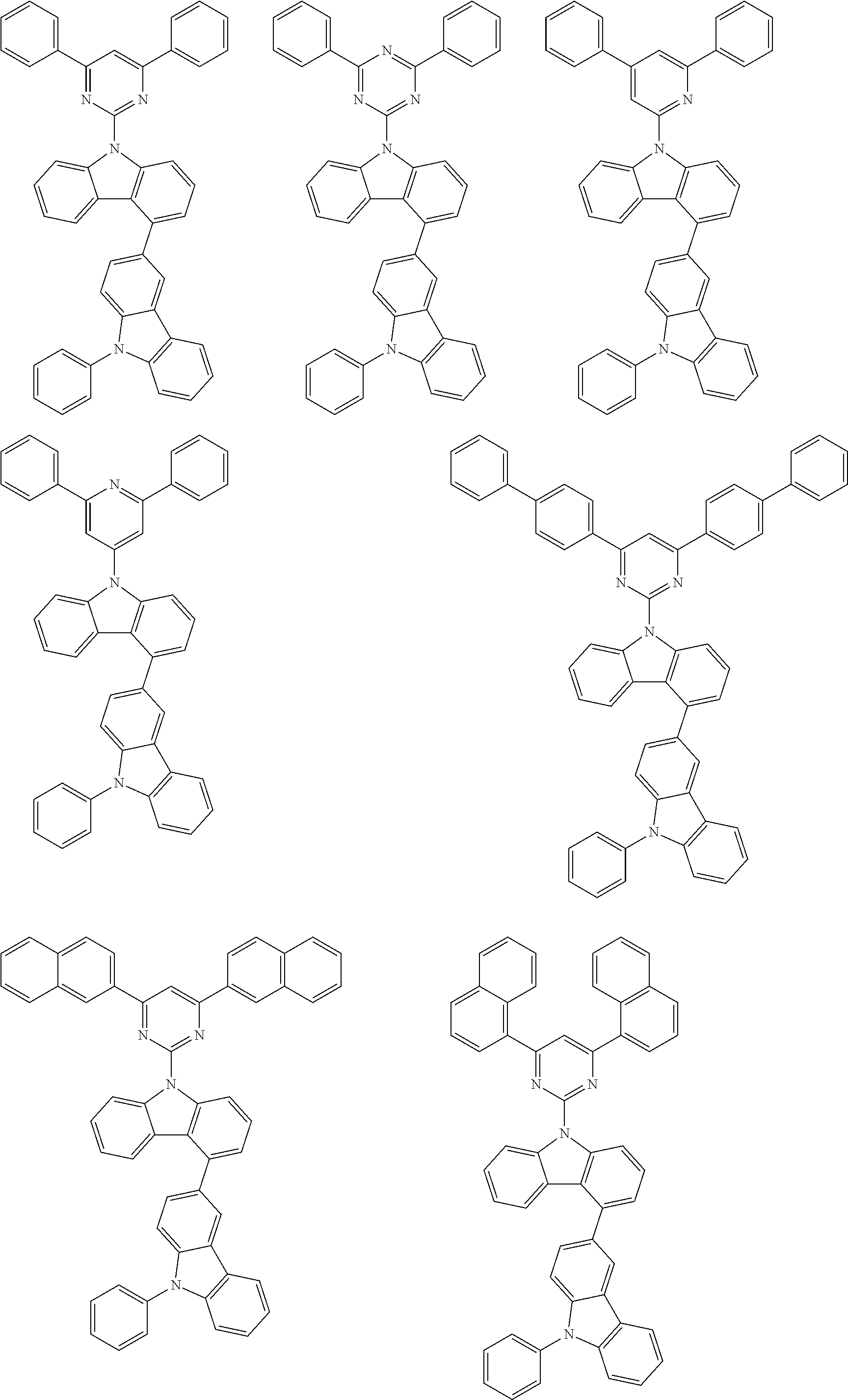

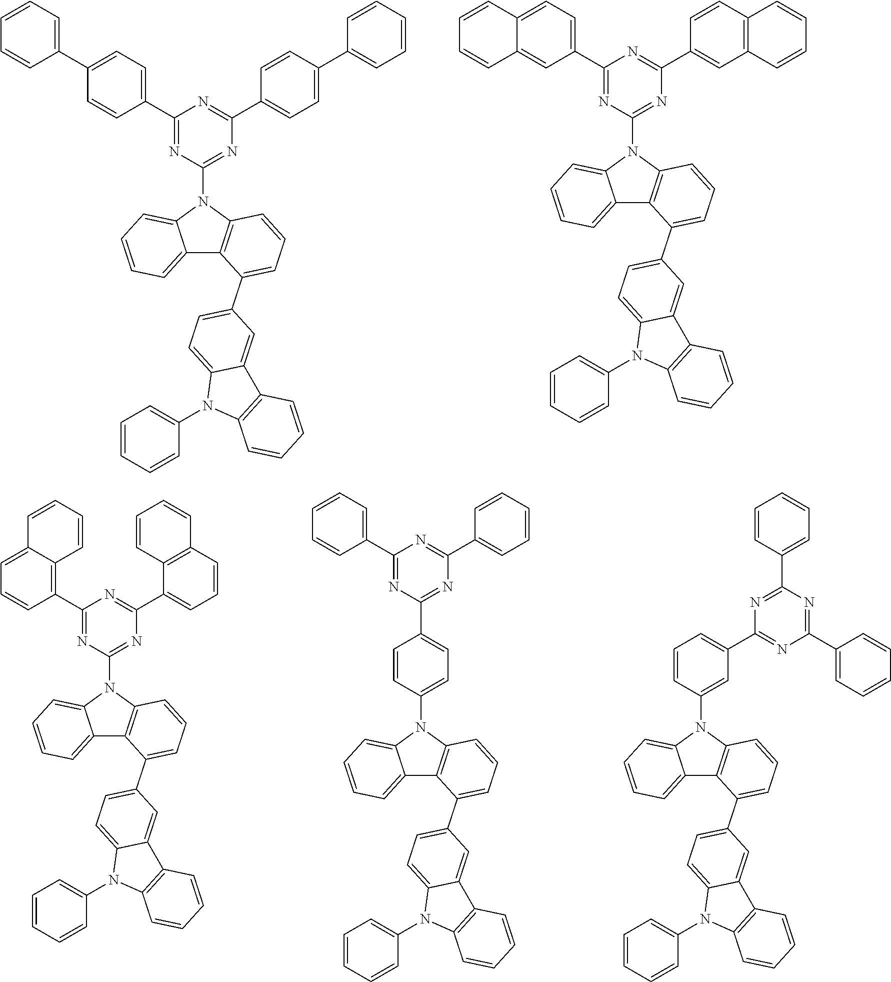

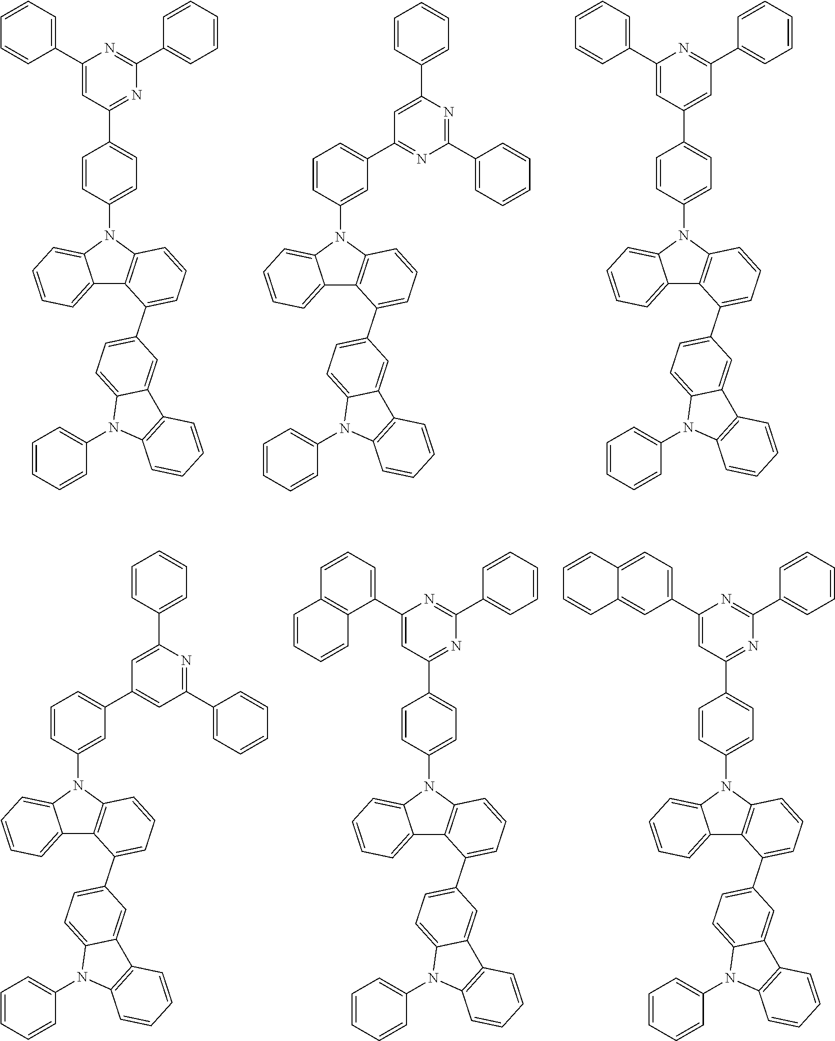

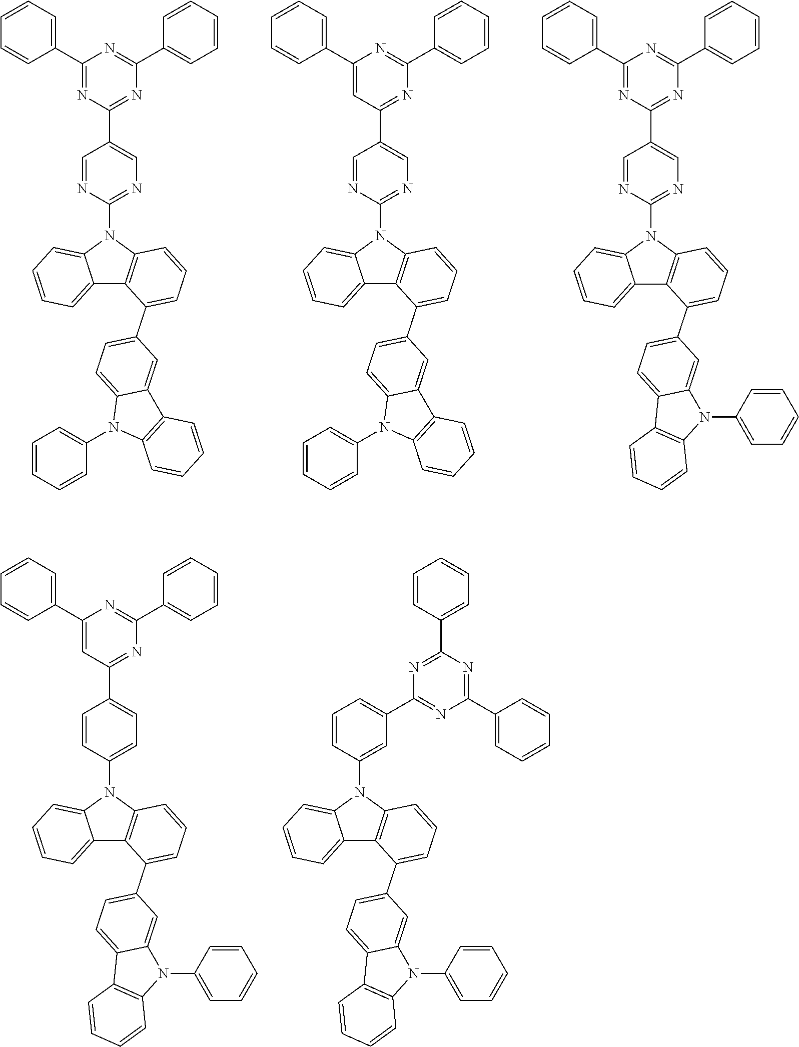 [SMILES: c1ccc(-c2nc(-c3ccccc3)nc(-c3cnc(-n4c5ccccc5c5c(-c6ccc7c(c6)c6ccccc6n7-c6ccccc6)cccc54)nc3)n2)cc1 ; c1ccc(-c2cc(-c3cnc(-n4c5ccccc5c5c(-c6ccc7c(c6)c6ccccc6n7-c6ccccc6)cccc54)nc3)nc(-c3ccccc3)n2)cc1 ; c1ccc(-c2nc(-c3ccccc3)nc(-c3cnc(-n4c5ccccc5c5c(-c6ccc7c8ccccc8n(-c8ccccc8)c7c6)cccc54)nc3)n2)cc1 ; c1ccc(-c2cc(-c3ccc(-n4c5ccccc5c5c(-c6ccc7c8ccccc8n(-c8ccccc8)c7c6)cccc54)cc3)nc(-c3ccccc3)n2)cc1 ; c1ccc(-c2nc(-c3ccccc3)nc(-c3cccc(-n4c5ccccc5c5c(-c6ccc7c8ccccc8n(-c8ccccc8)c7c6)cccc54)c3)n2)cc1]

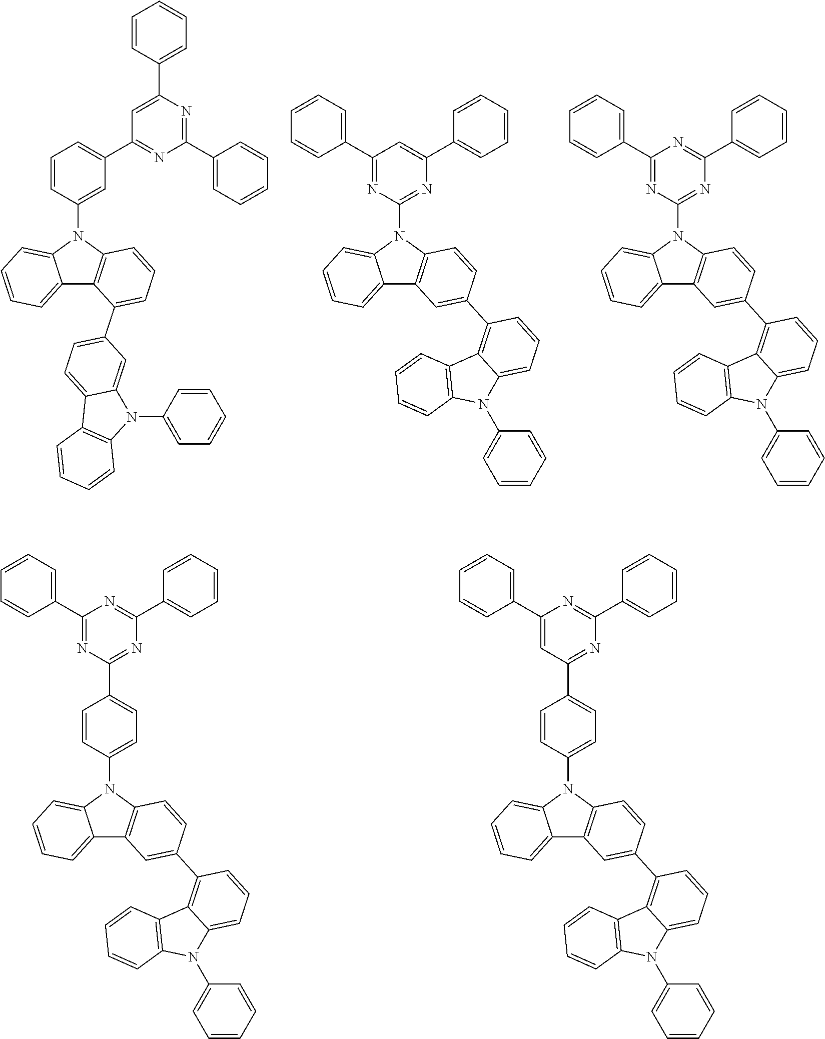

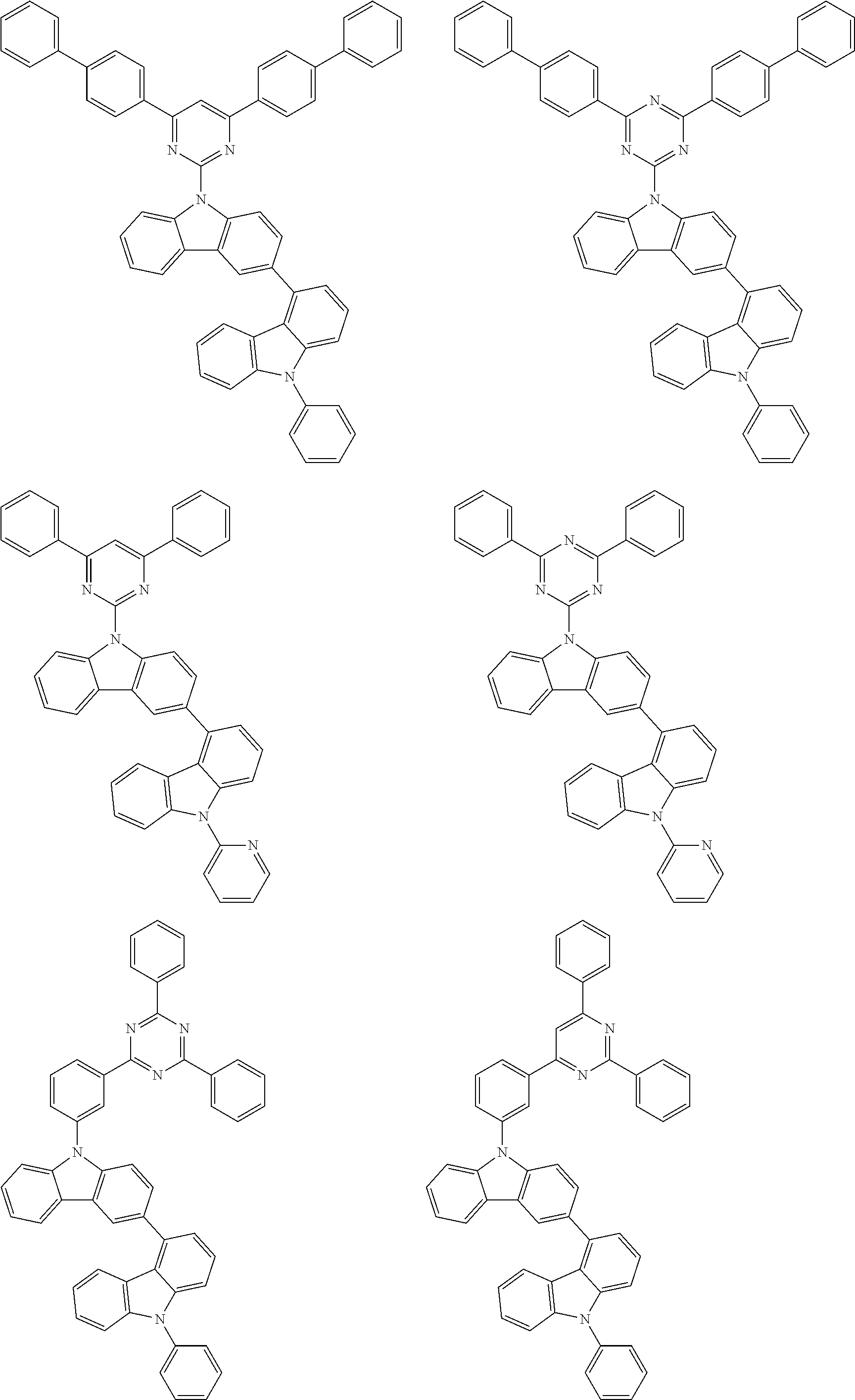

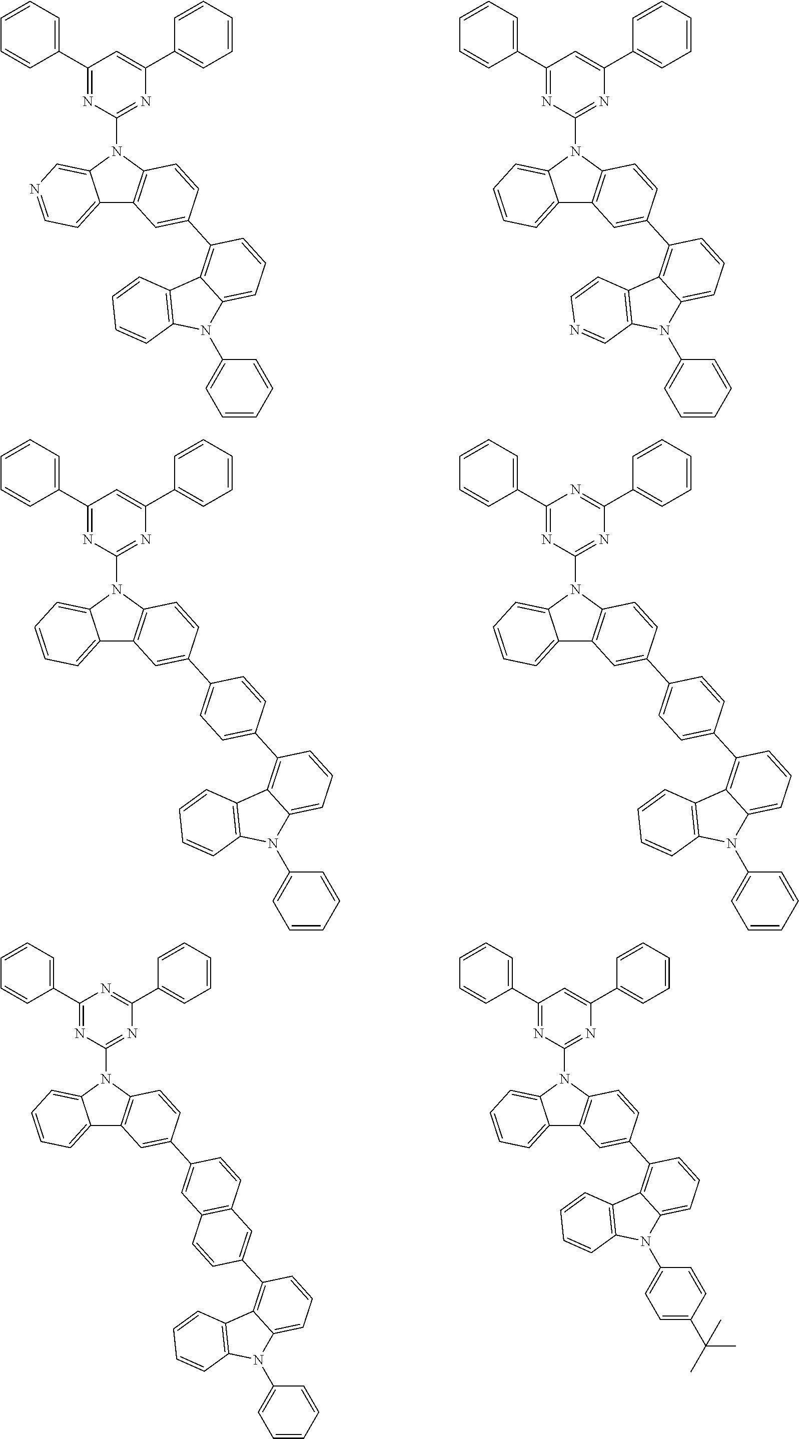

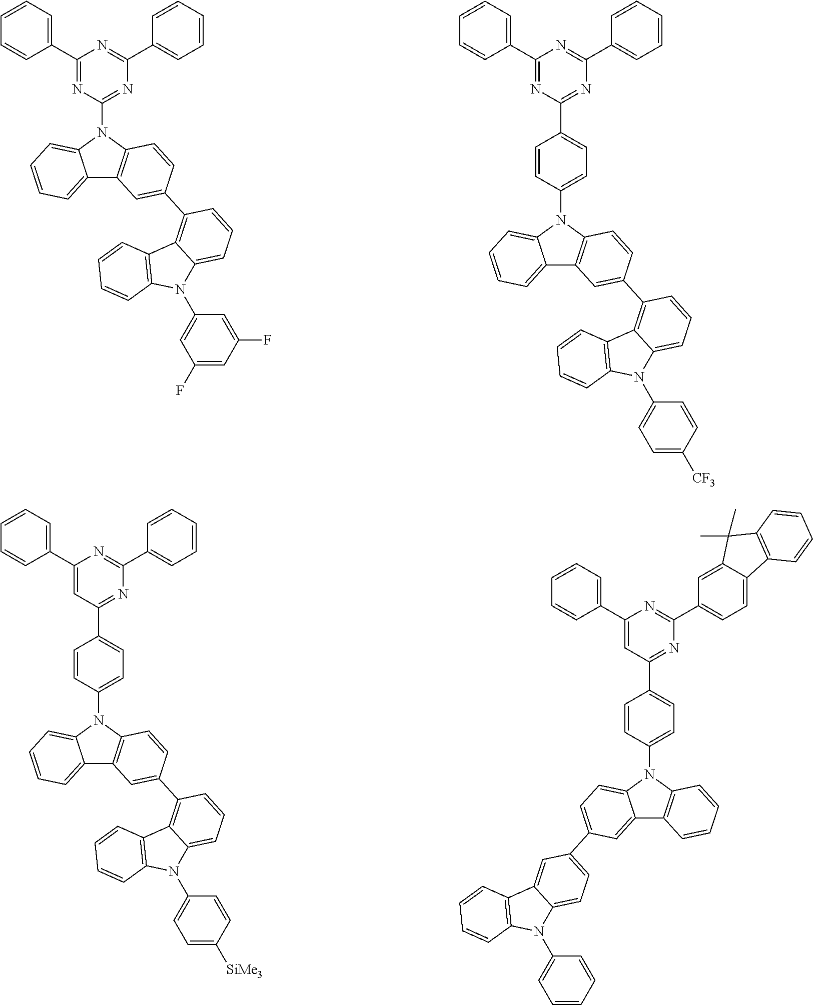 [SMILES: Fc1cc(F)cc(-n2c3ccccc3c3c(-c4ccc5c(c4)c4ccccc4n5-c4nc(-c5ccccc5)nc(-c5ccccc5)n4)cccc32)c1 ; FC(F)(F)c1ccc(-n2c3ccccc3c3c(-c4ccc5c(c4)c4ccccc4n5-c4ccc(-c5nc(-c6ccccc6)nc(-c6ccccc6)n5)cc4)cccc32)cc1 ; C[Si](C)(C)c1ccc(-n2c3ccccc3c3c(-c4ccc5c(c4)c4ccccc4n5-c4ccc(-c5cc(-c6ccccc6)nc(-c6ccccc6)n5)cc4)cccc32)cc1 ; CC1(C)c2ccccc2-c2ccc(-c3nc(-c4ccccc4)cc(-c4ccc(-n5c6ccccc6c6cc(-c7ccc8c(c7)c7ccccc7n8-c7ccccc7)ccc65)cc4)n3)cc21]

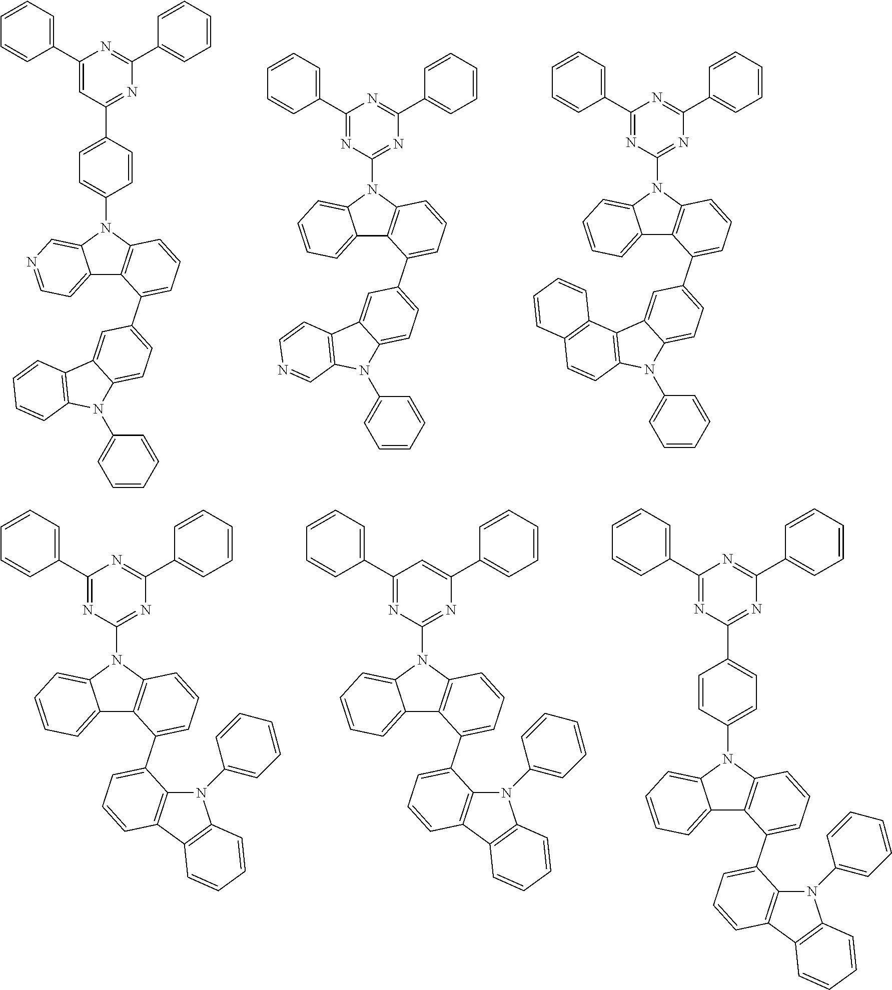

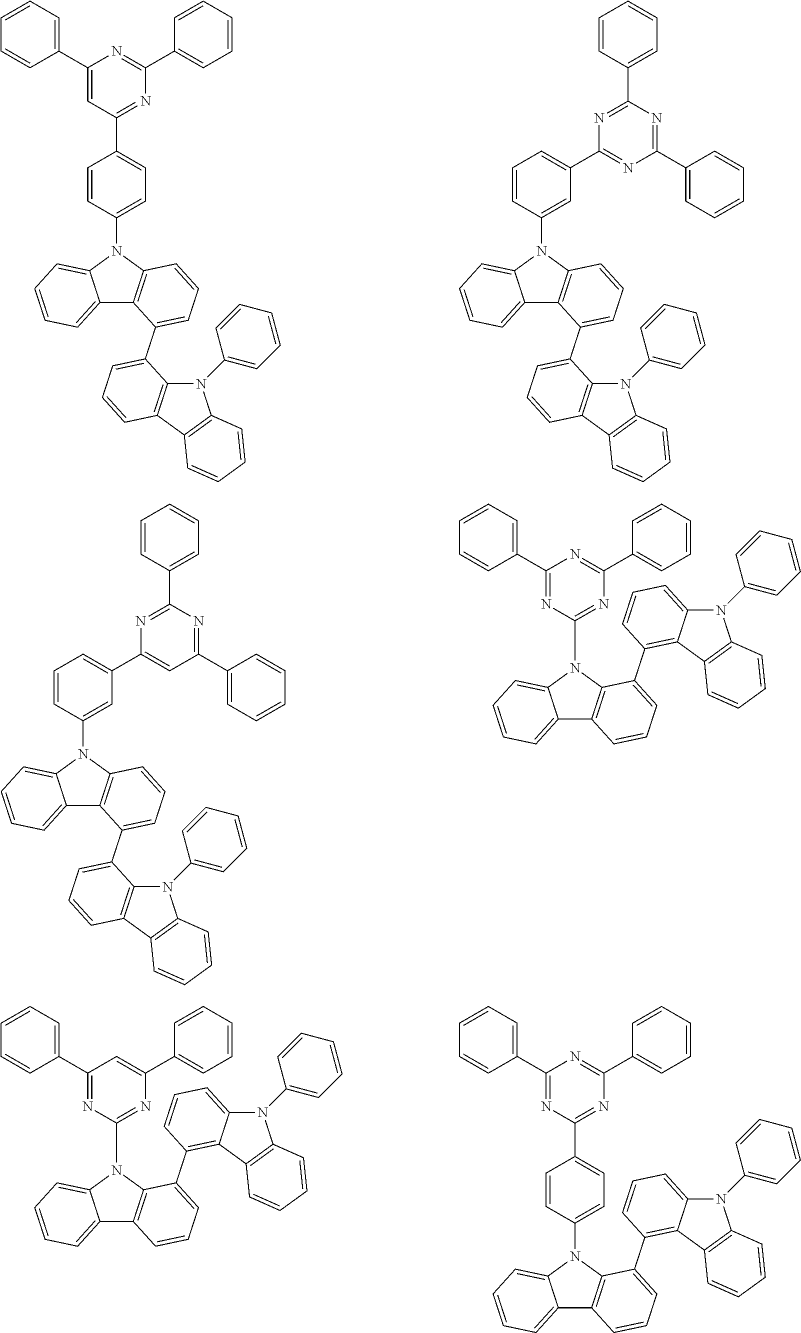

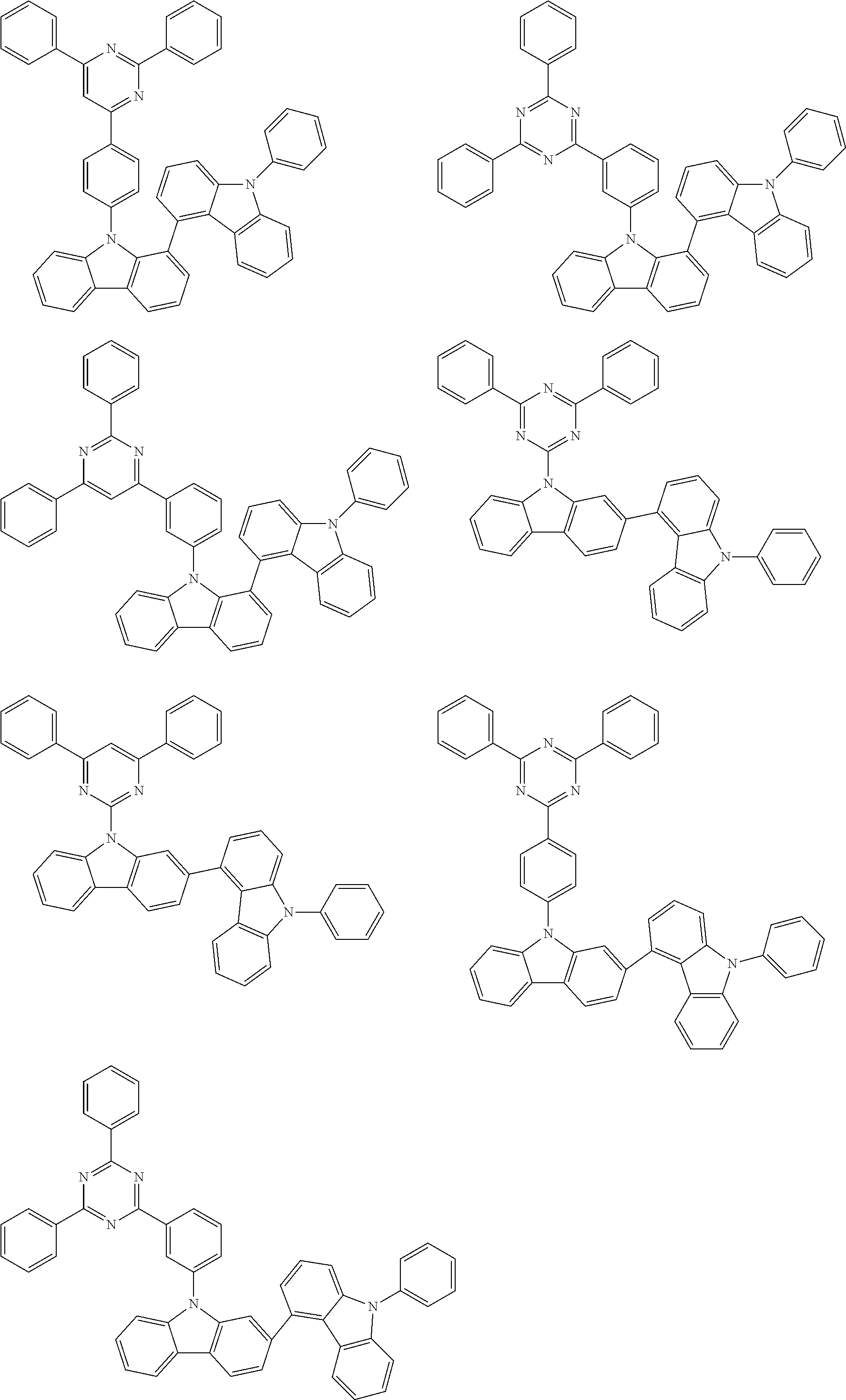

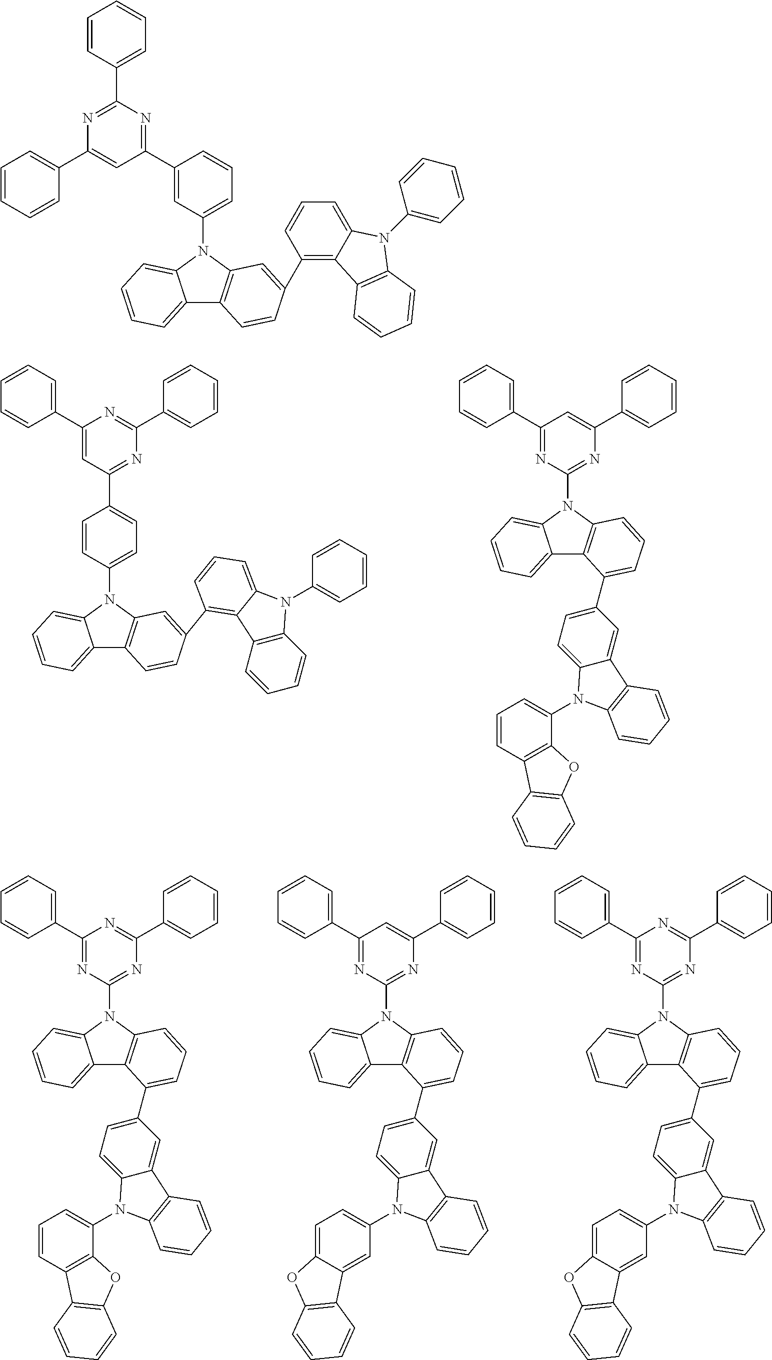

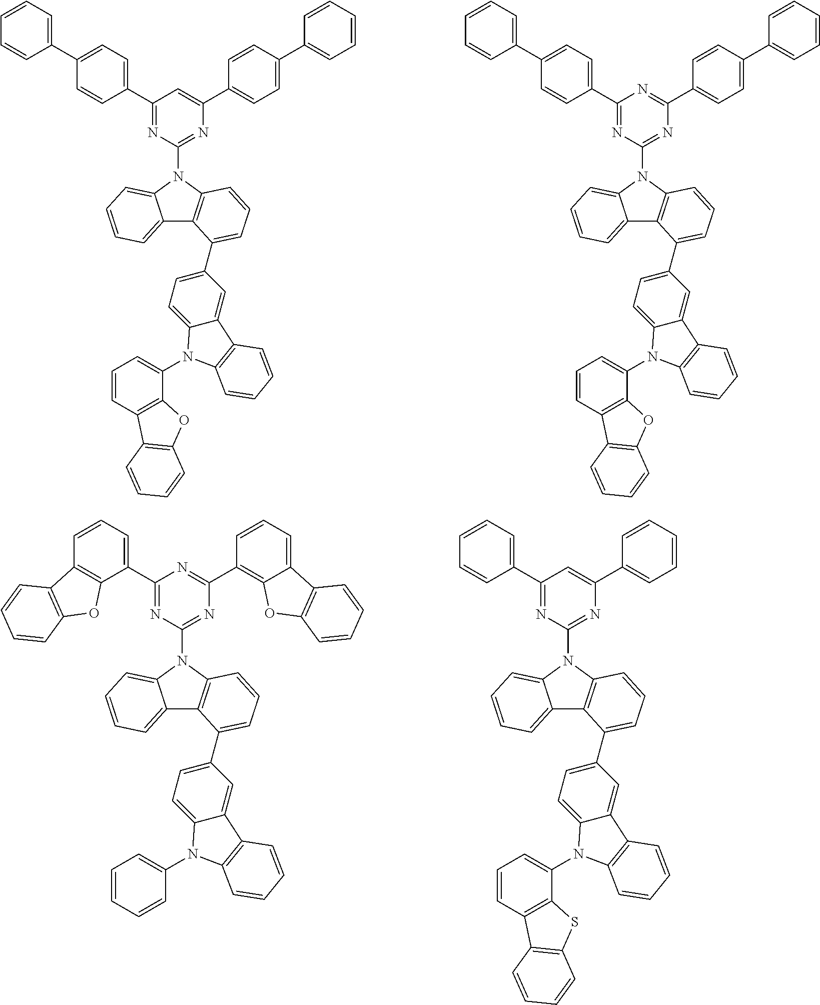

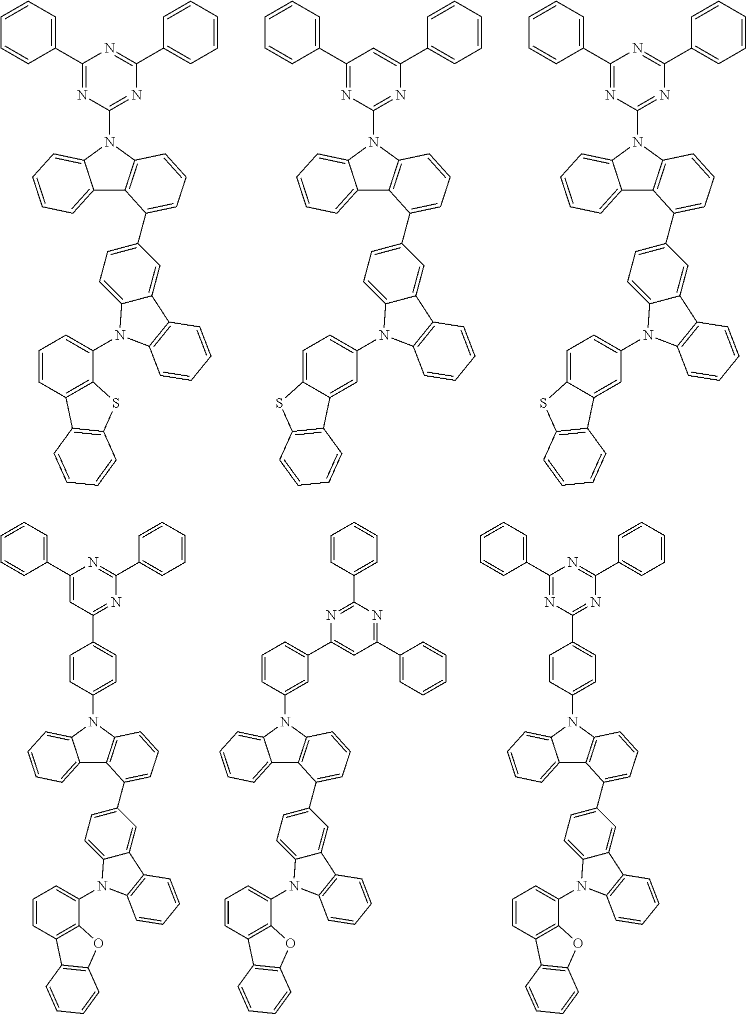

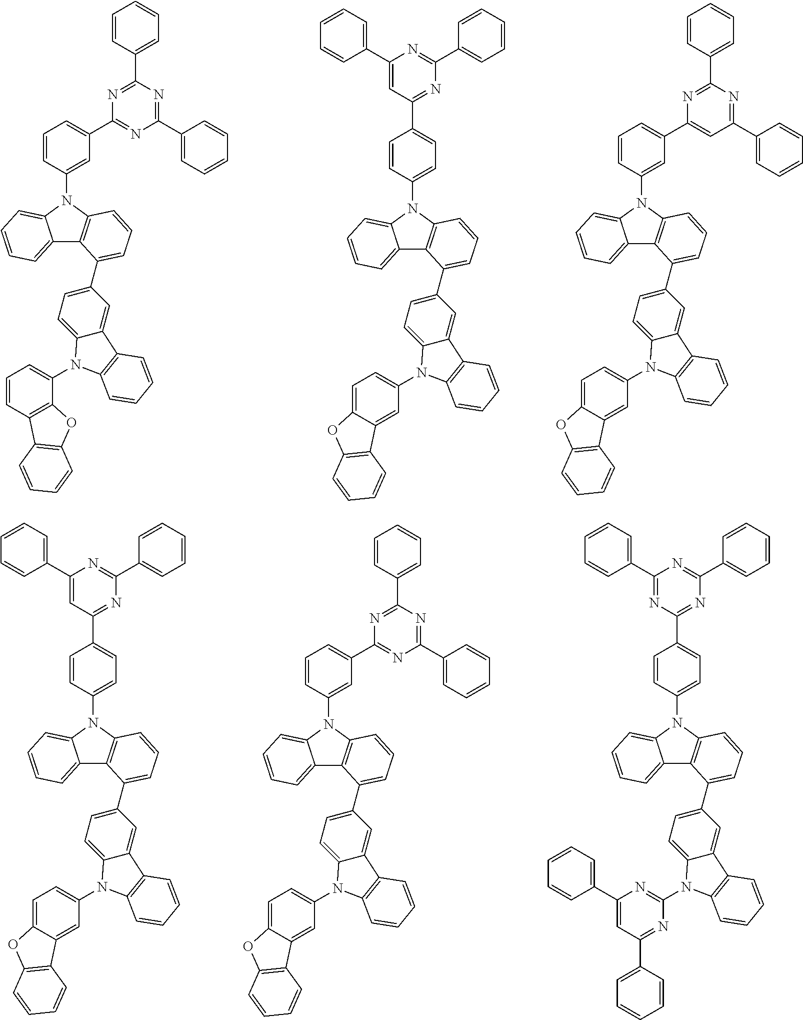

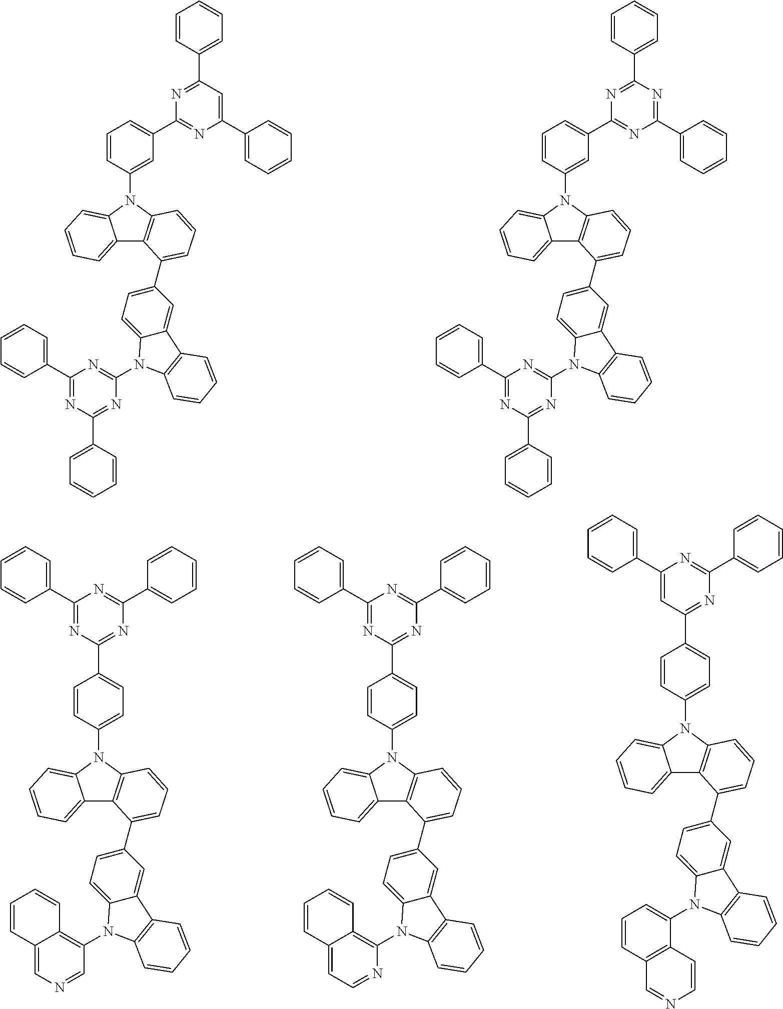

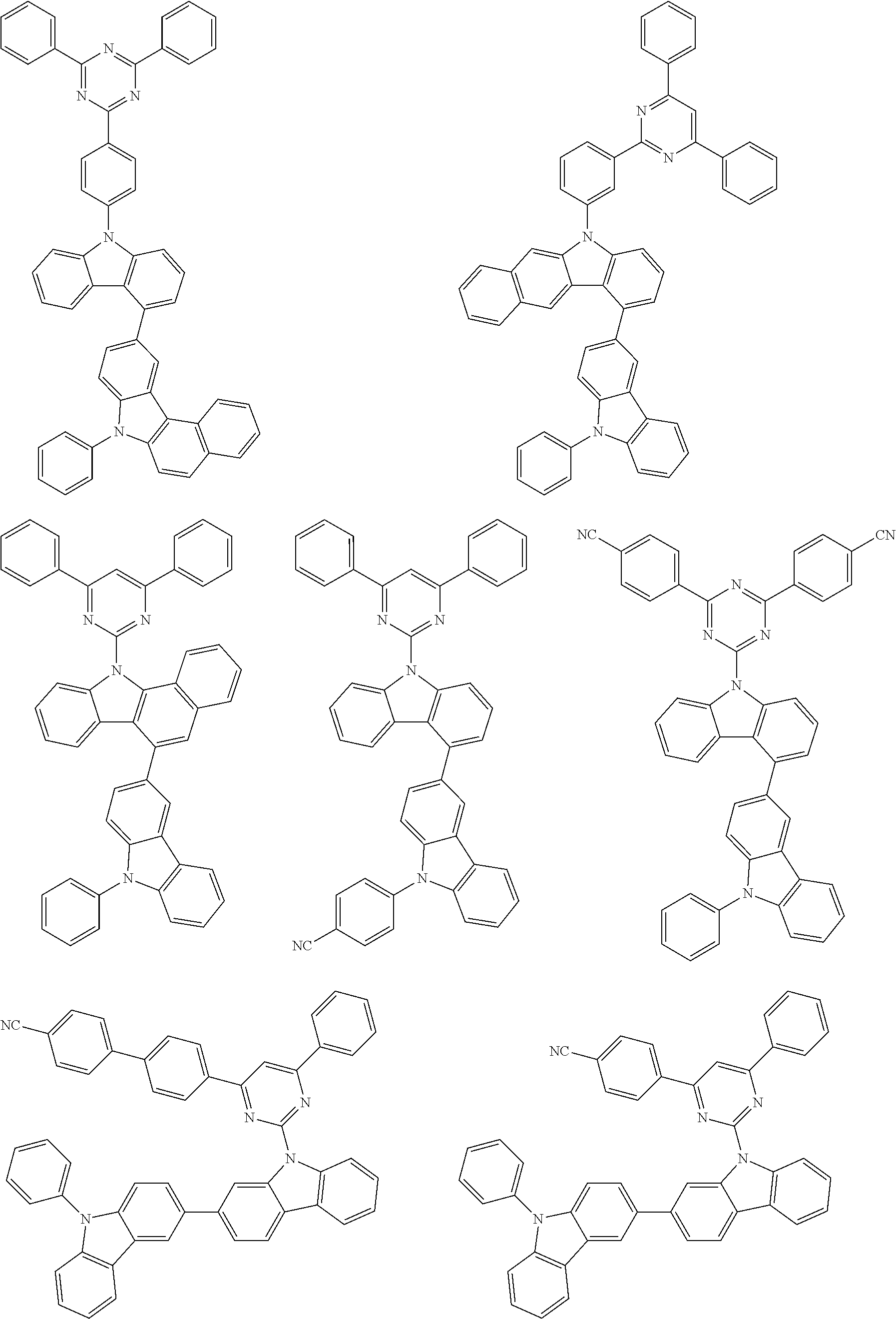

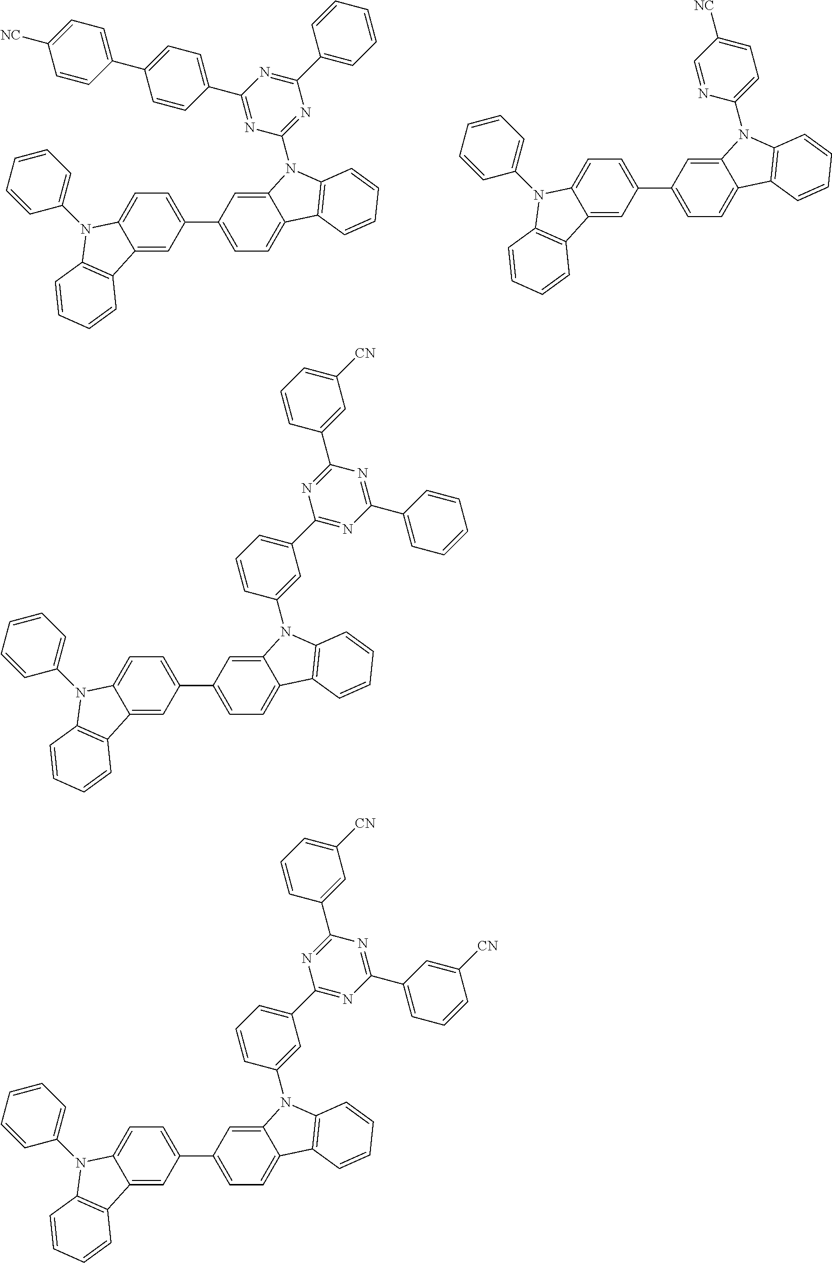 [SMILES: N#Cc1ccc(-c2ccc(-c3nc(-c4ccccc4)nc(-n4c5ccccc5c5ccc(-c6ccc7c(c6)c6ccccc6n7-c6ccccc6)cc54)n3)cc2)cc1 ; N#Cc1ccc(-n2c3ccccc3c3ccc(-c4ccc5c(c4)c4ccccc4n5-c4ccccc4)cc32)nc1 ; N#Cc1cccc(-c2nc(-c3ccccc3)nc(-c3cccc(-n4c5ccccc5c5ccc(-c6ccc7c(c6)c6ccccc6n7-c6ccccc6)cc54)c3)n2)c1 ; N#Cc1cccc(-c2nc(-c3cccc(C#N)c3)nc(-c3cccc(-n4c5ccccc5c5ccc(-c6ccc7c(c6)c6ccccc6n7-c6ccccc6)cc54)c3)n2)c1]

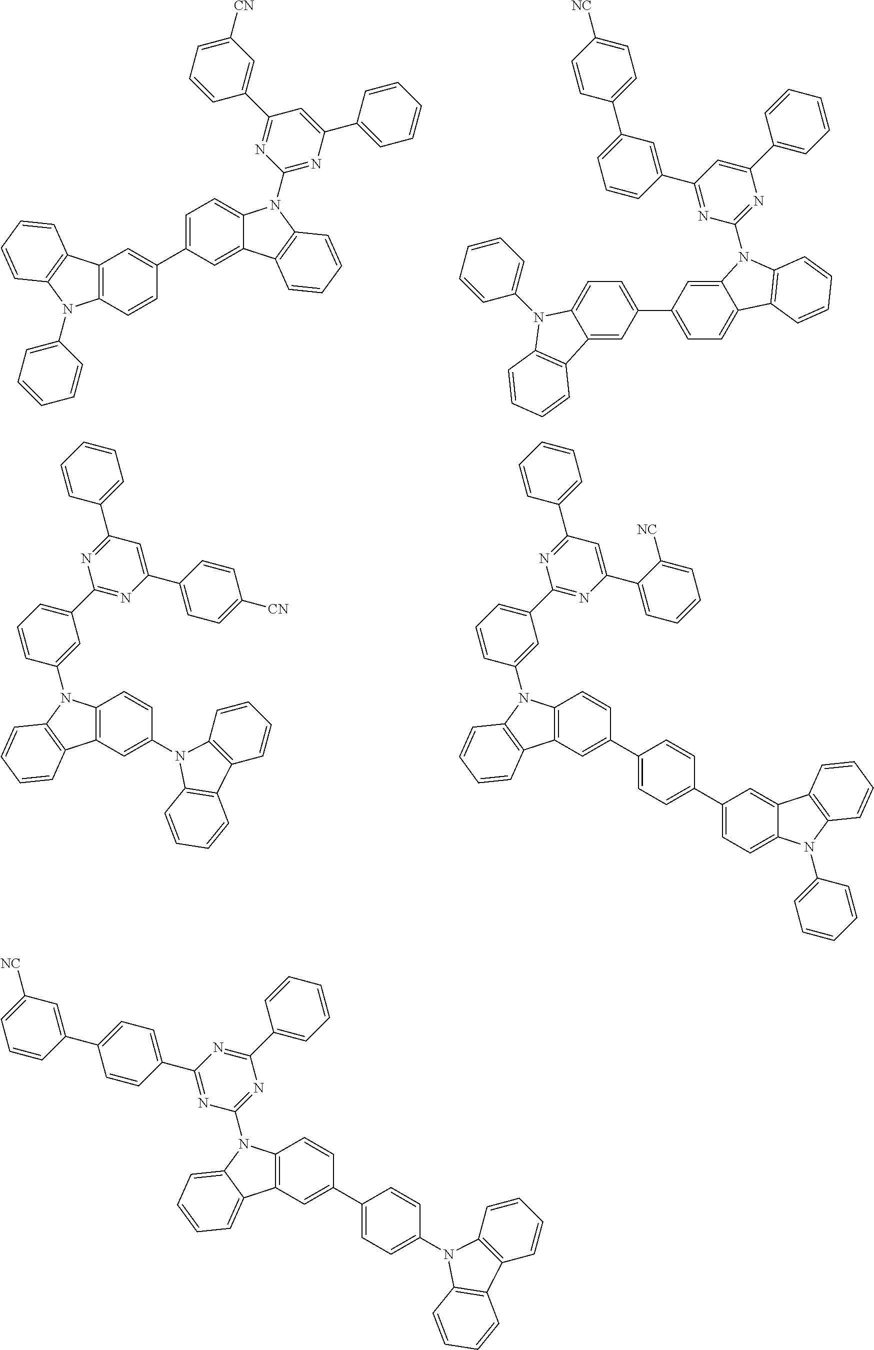

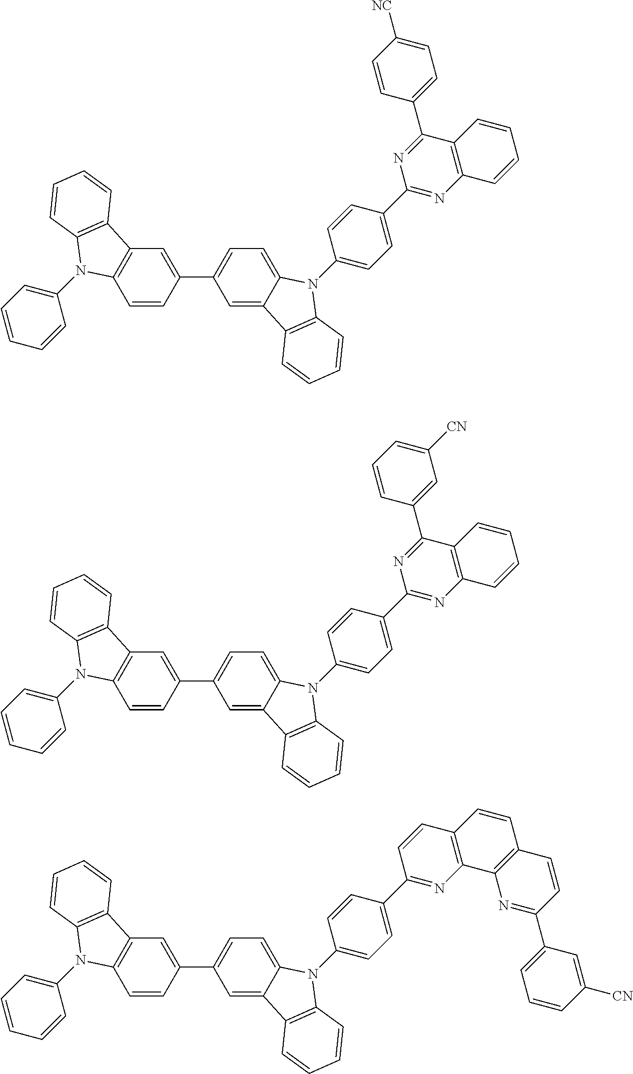 [SMILES: N#Cc1ccc(-c2nc(-c3ccc(-n4c5ccccc5c5cc(-c6ccc7c(c6)c6ccccc6n7-c6ccccc6)ccc54)cc3)nc3ccccc23)cc1 ; N#Cc1cccc(-c2nc(-c3ccc(-n4c5ccccc5c5cc(-c6ccc7c(c6)c6ccccc6n7-c6ccccc6)ccc54)cc3)nc3ccccc23)c1 ; N#Cc1cccc(-c2ccc3ccc4ccc(-c5ccc(-n6c7ccccc7c7cc(-c8ccc9c(c8)c8ccccc8n9-c8ccccc8)ccc76)cc5)nc4c3n2)c1]

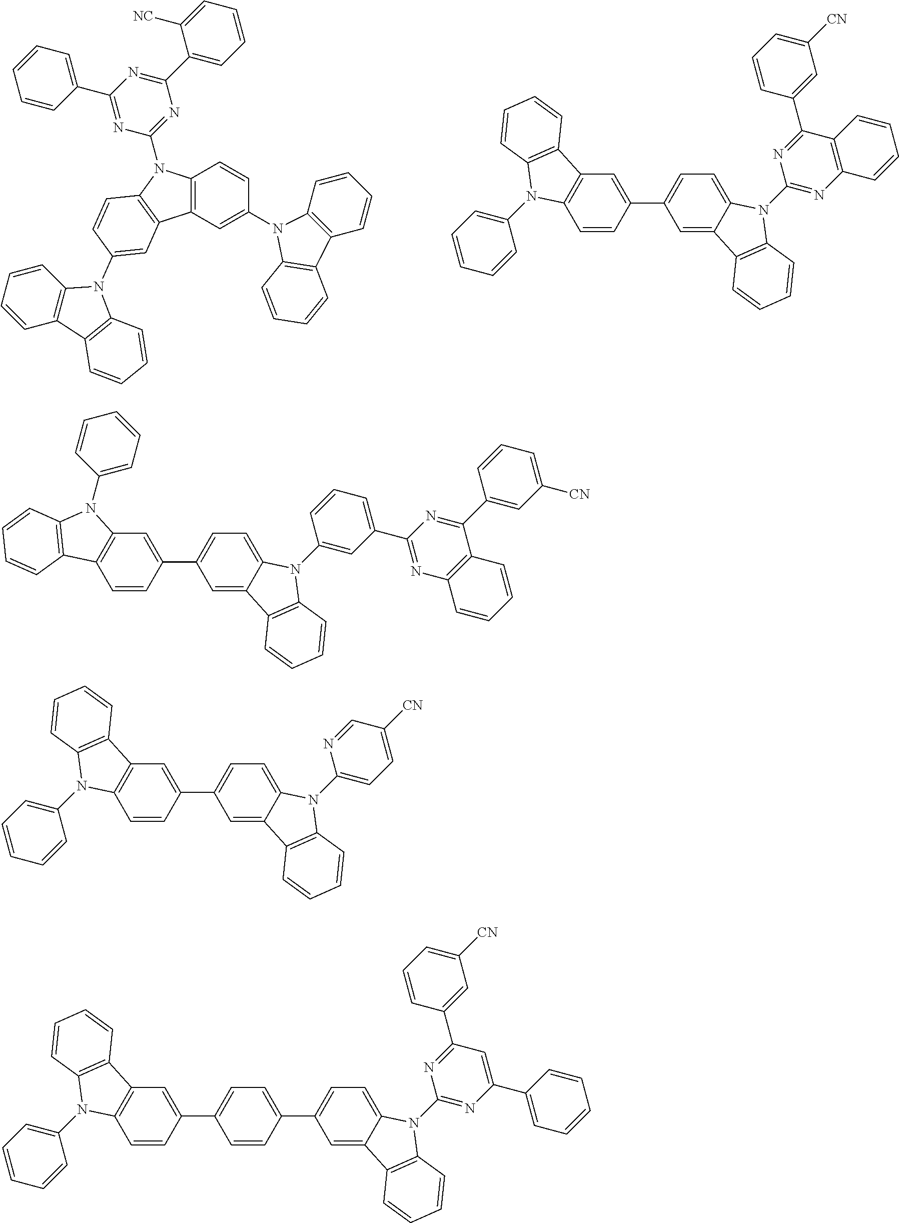

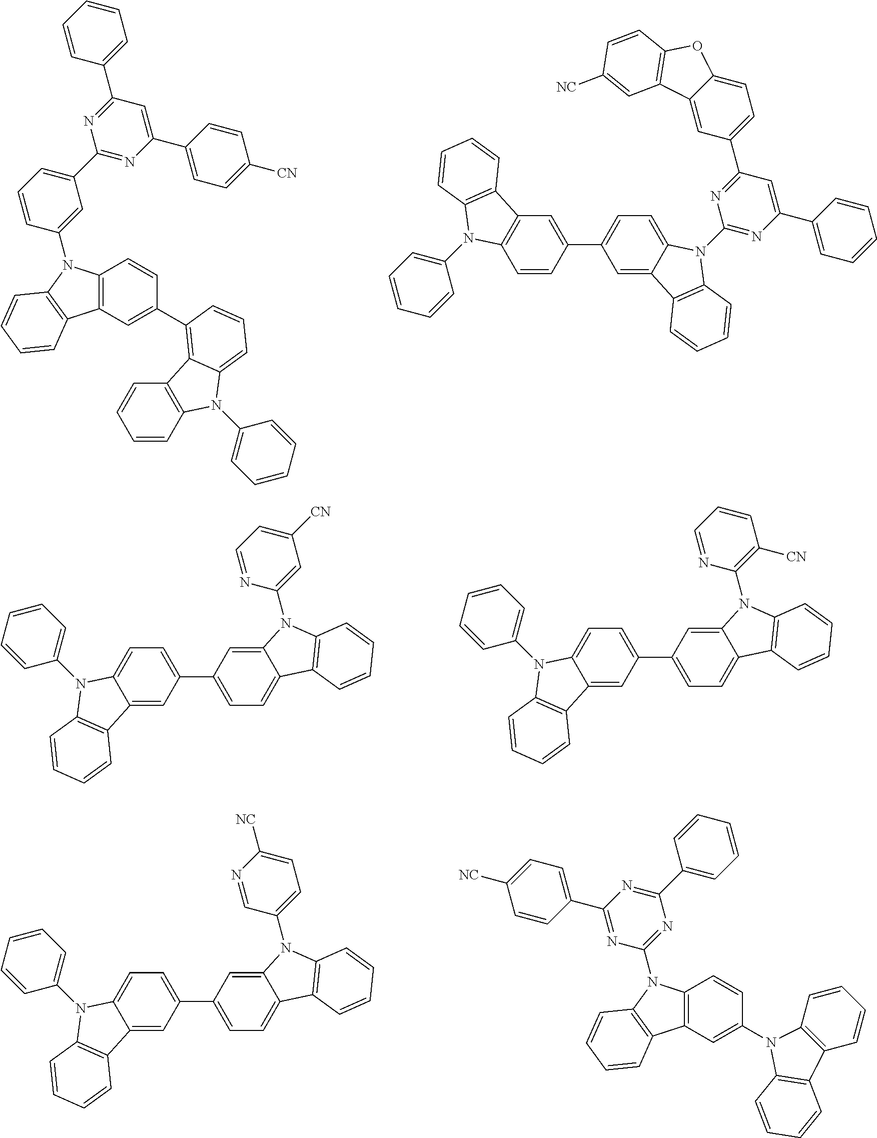

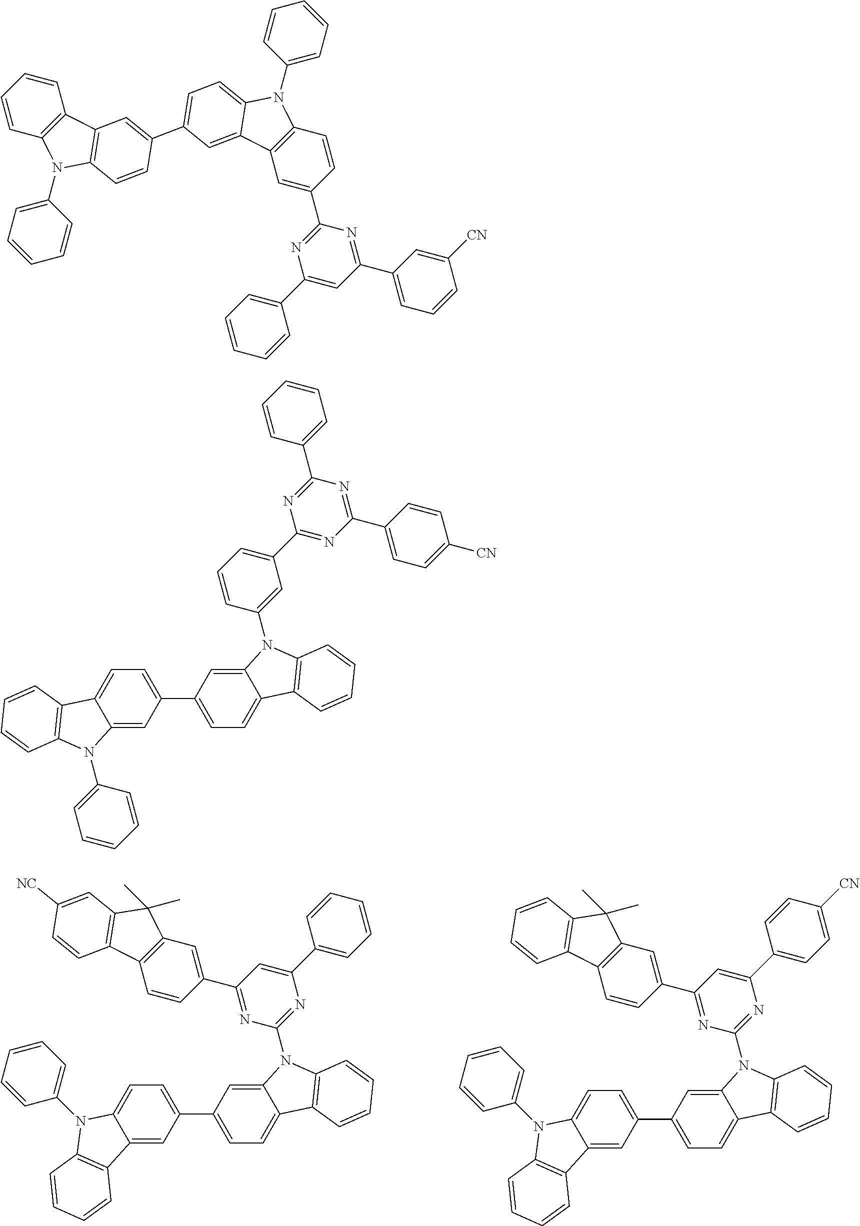

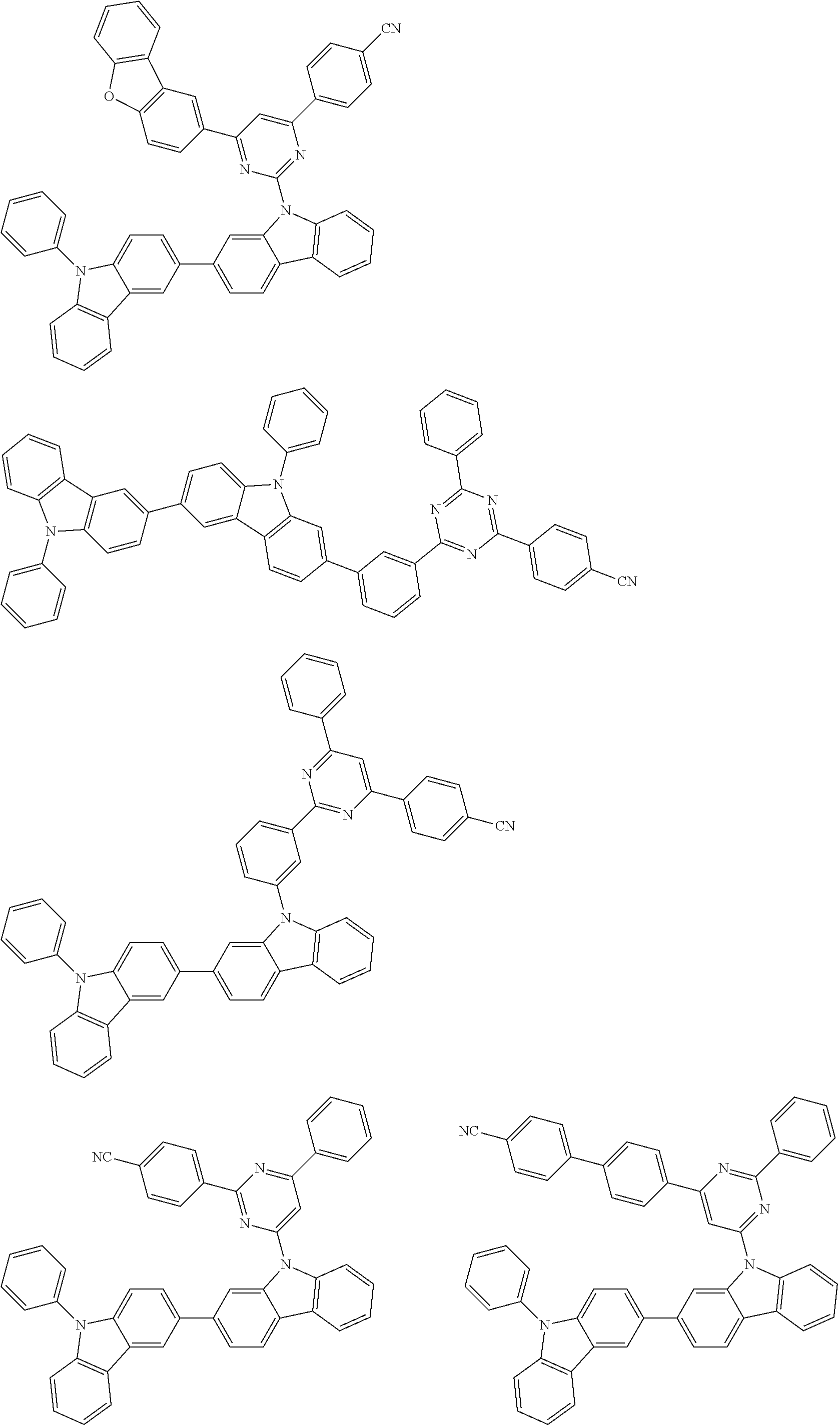

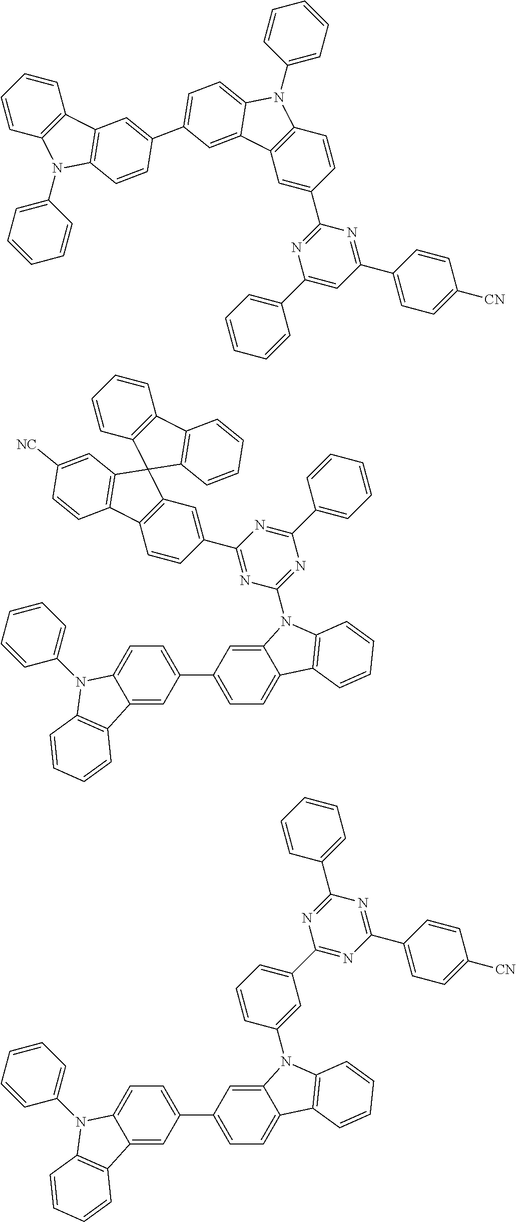 [SMILES: N#Cc1ccc(-c2cc(-c3ccccc3)nc(-c3ccc4c(c3)c3cc(-c5ccc6c(c5)c5ccccc5n6-c5ccccc5)ccc3n4-c3ccccc3)n2)cc1 ; N#Cc1ccc2c(c1)C1(c3ccccc3-c3ccccc31)c1cc(-c3nc(-c4ccccc4)nc(-n4c5ccccc5c5ccc(-c6ccc7c(c6)c6ccccc6n7-c6ccccc6)cc54)n3)ccc1-2 ; N#Cc1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

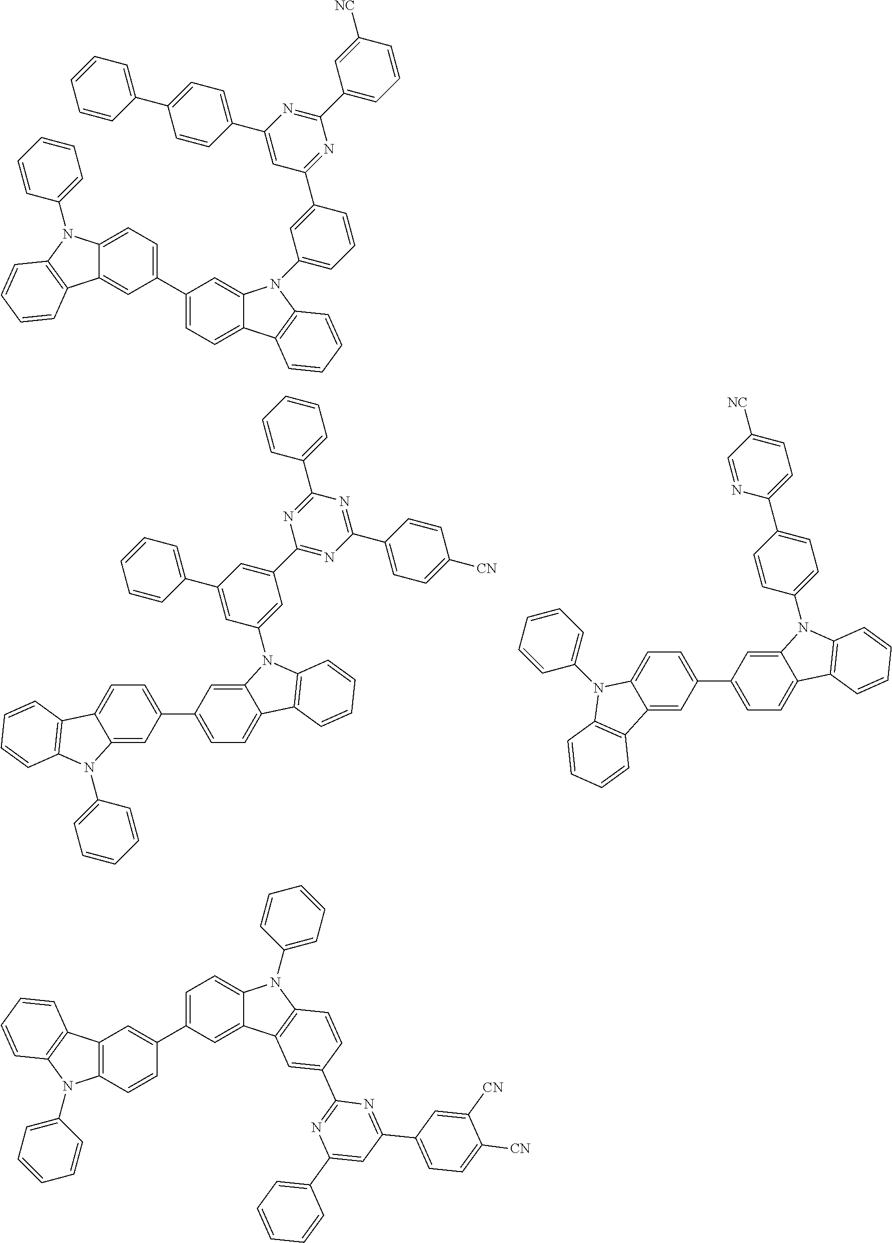

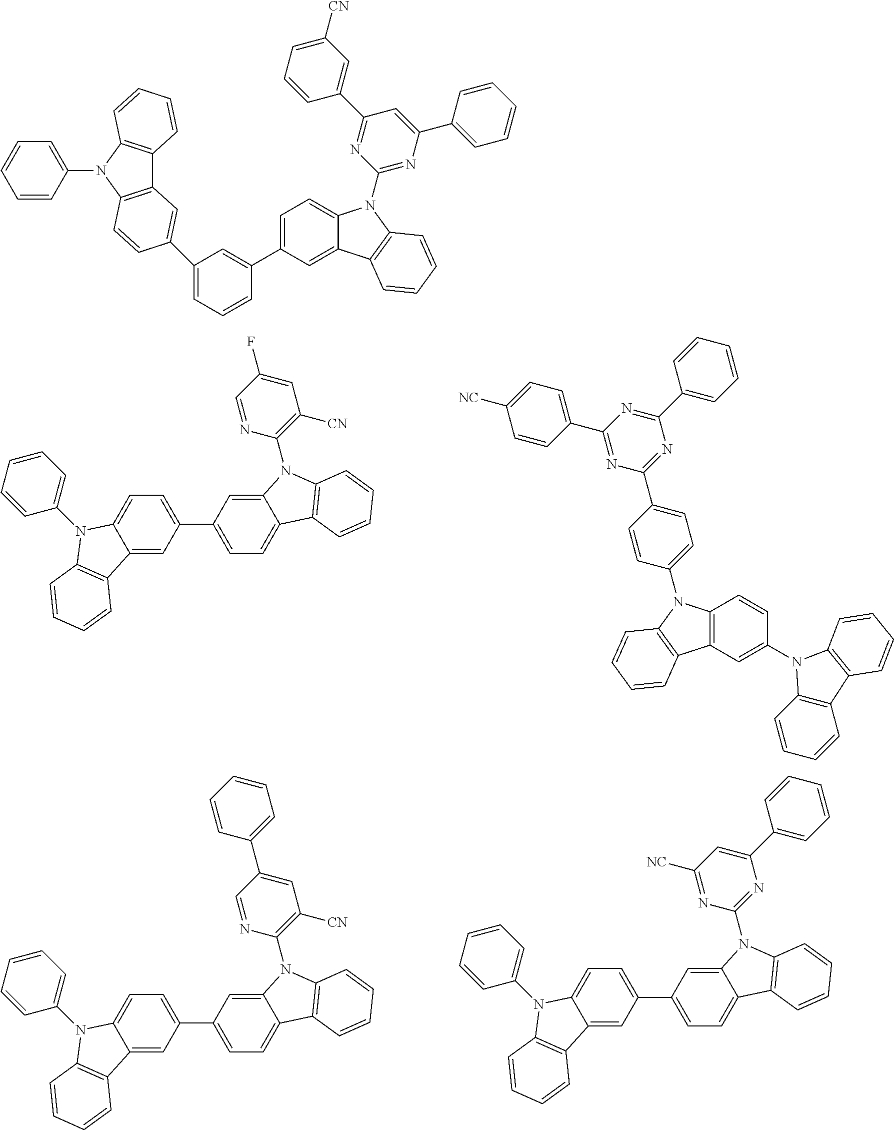

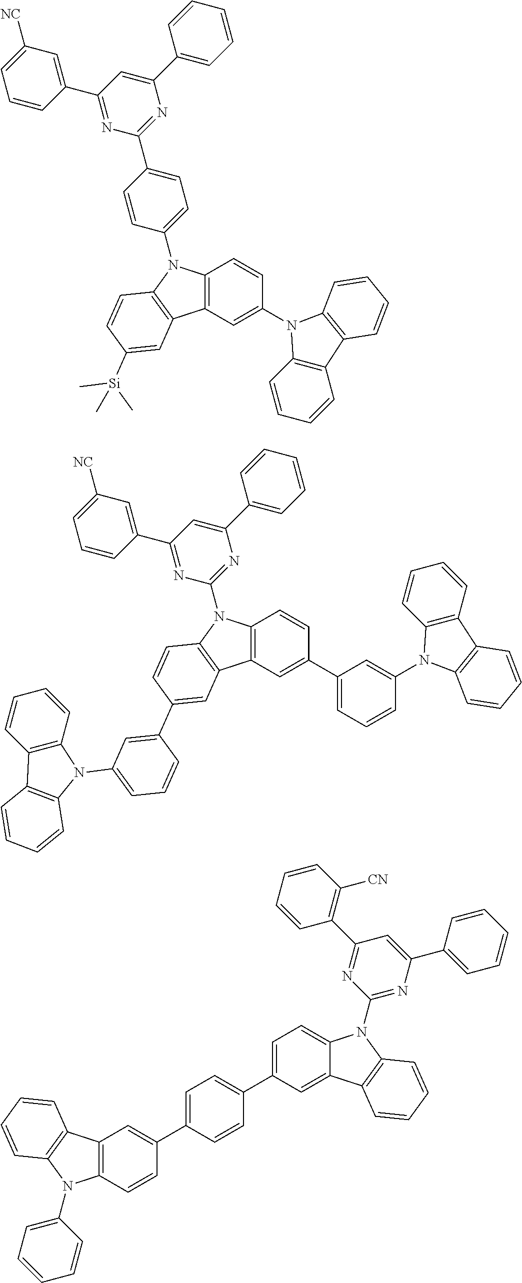

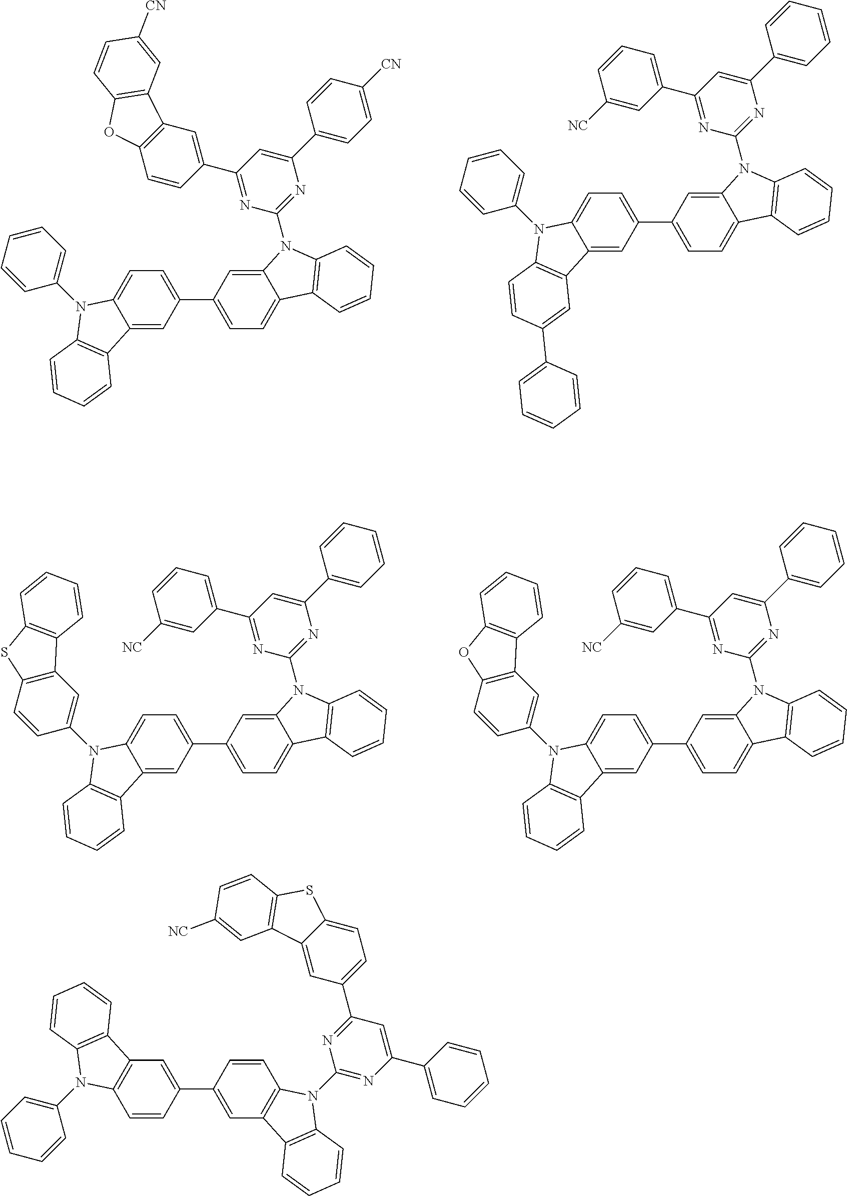

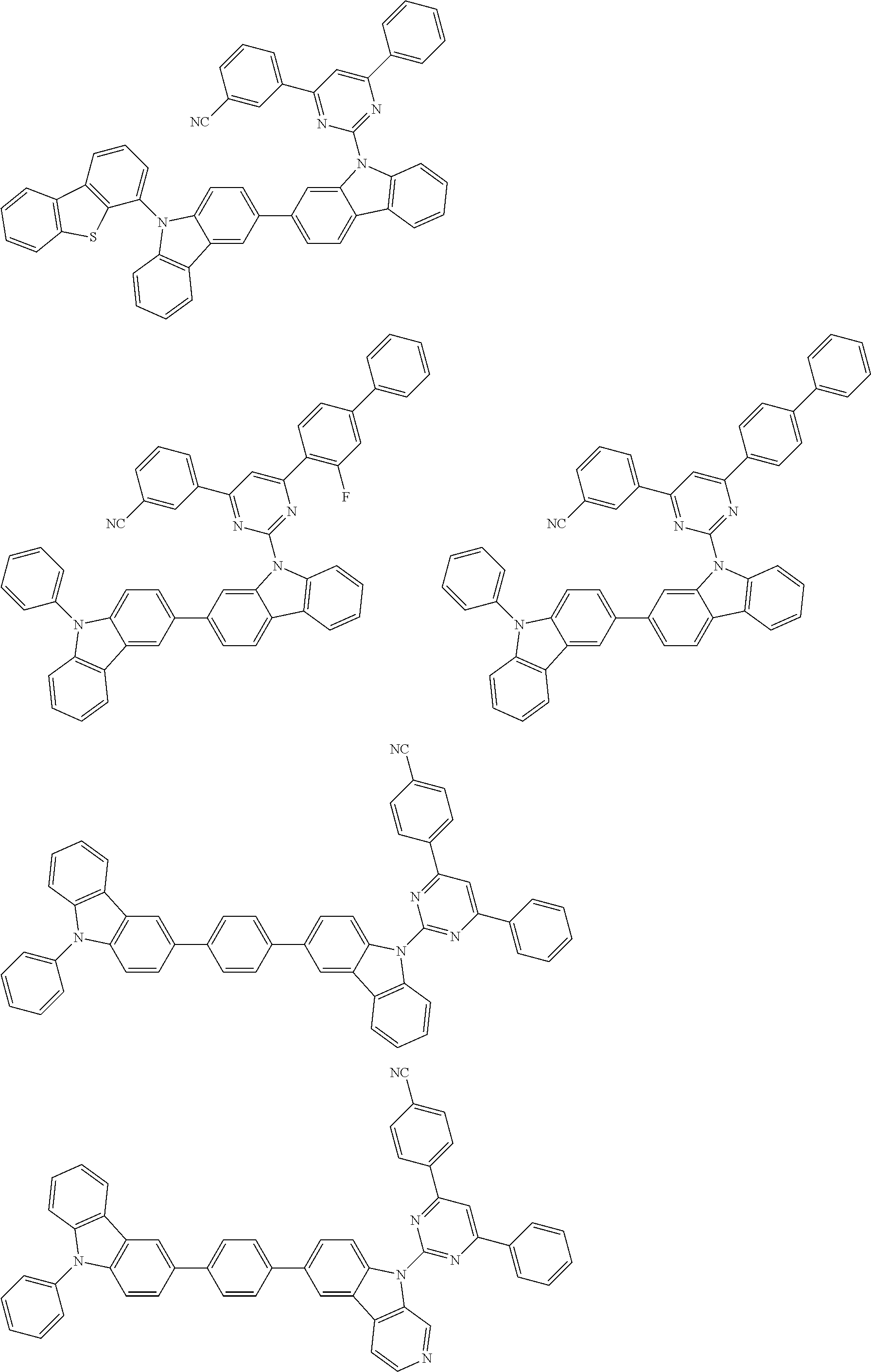

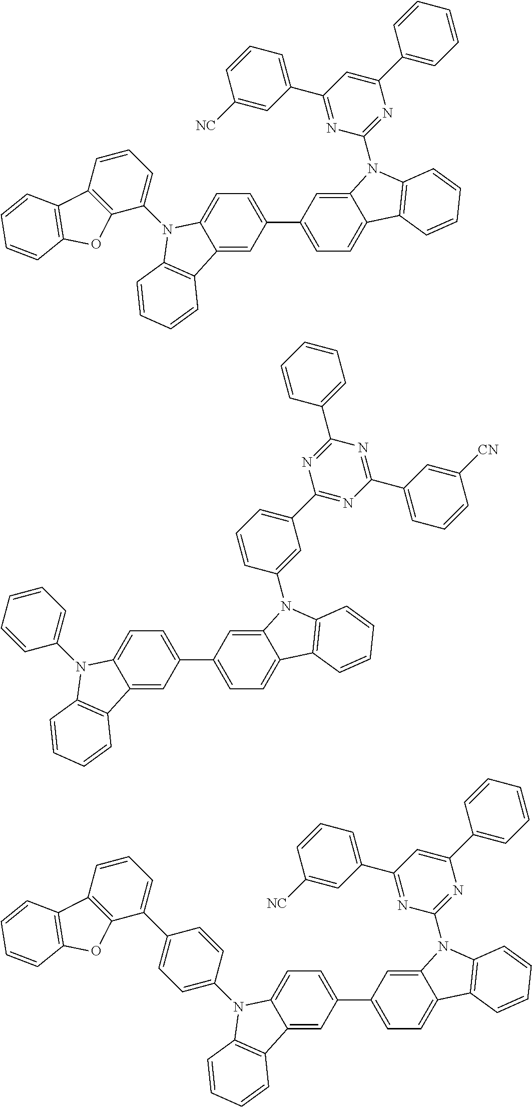 [SMILES: N#Cc1cccc(-c2cc(-c3ccccc3)nc(-n3c4ccccc4c4ccc(-c5ccc6c(c5)c5ccccc5n6-c5cccc6c5oc5ccccc56)cc43)n2)c1 ; N#Cc1cccc(-c2nc(-c3ccccc3)nc(-c3cccc(-n4c5ccccc5c5ccc(-c6ccc7c(c6)c6ccccc6n7-c6ccccc6)cc54)c3)n2)c1 ; N#Cc1cccc(-c2cc(-c3ccccc3)nc(-n3c4ccccc4c4ccc(-c5ccc6c(c5)c5ccccc5n6-c5ccc(-c6cccc7c6oc6ccccc67)cc5)cc43)n2)c1]

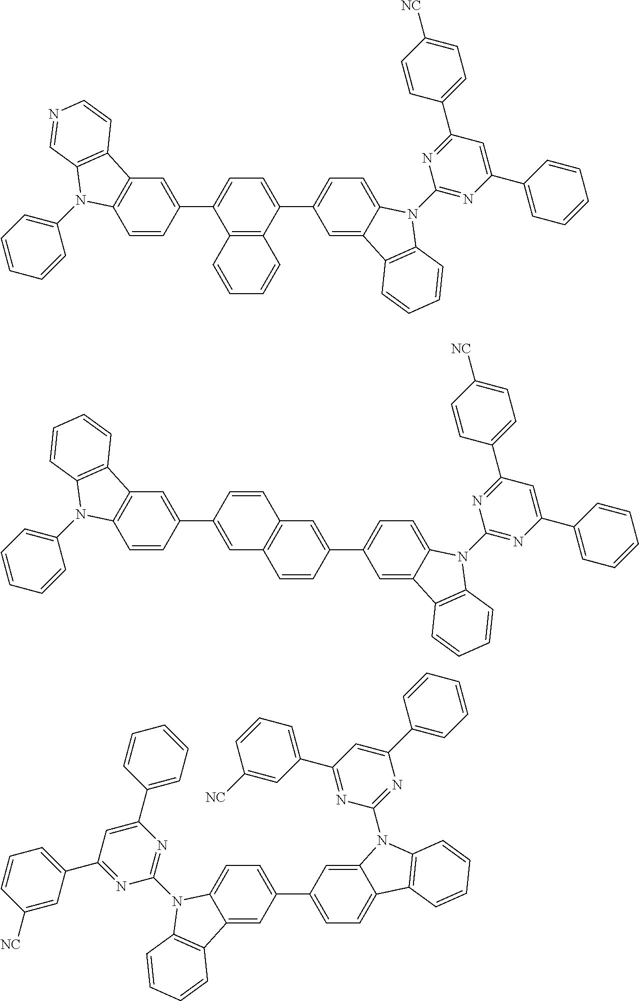

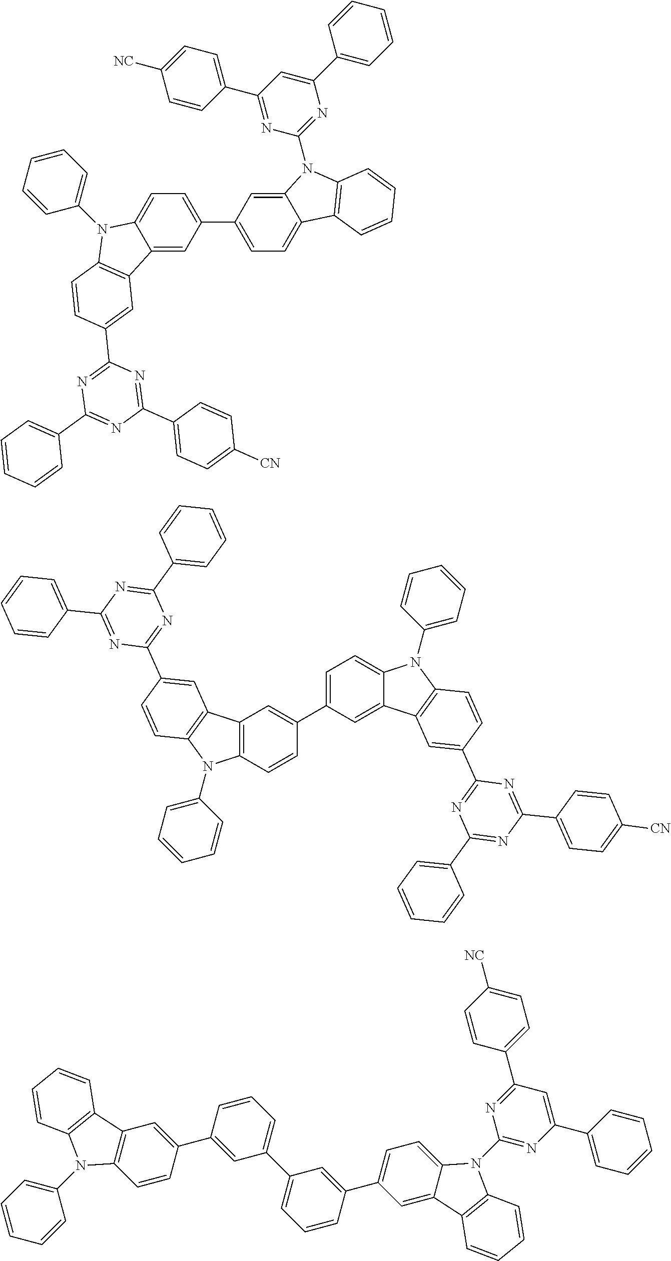

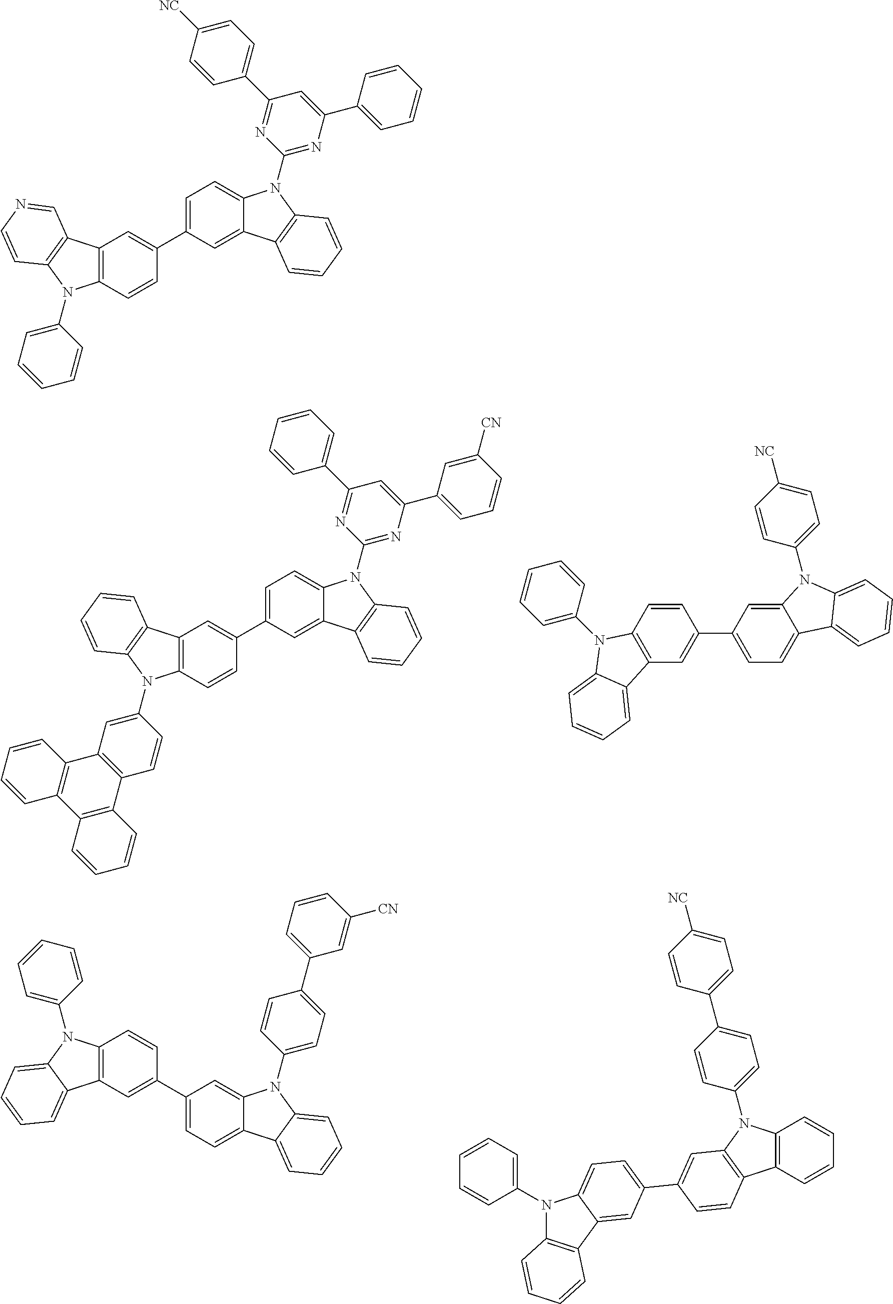 [SMILES: N#Cc1ccc(-c2cc(-c3ccccc3)nc(-n3c4ccccc4c4cc(-c5ccc6c(c5)c5cnccc5n6-c5ccccc5)ccc43)n2)cc1 ; N#Cc1cccc(-c2cc(-c3ccccc3)nc(-n3c4ccccc4c4cc(-c5ccc6c(c5)c5ccccc5n6-c5ccc6c7ccccc7c7ccccc7c6c5)ccc43)n2)c1 ; N#Cc1ccc(-n2c3ccccc3c3ccc(-c4ccc5c(c4)c4ccccc4n5-c4ccccc4)cc32)cc1 ; N#Cc1cccc(-c2ccc(-n3c4ccccc4c4ccc(-c5ccc6c(c5)c5ccccc5n6-c5ccccc5)cc43)cc2)c1 ; N#Cc1ccc(-c2ccc(-n3c4ccccc4c4ccc(-c5ccc6c(c5)c5ccccc5n6-c5ccccc5)cc43)cc2)cc1]

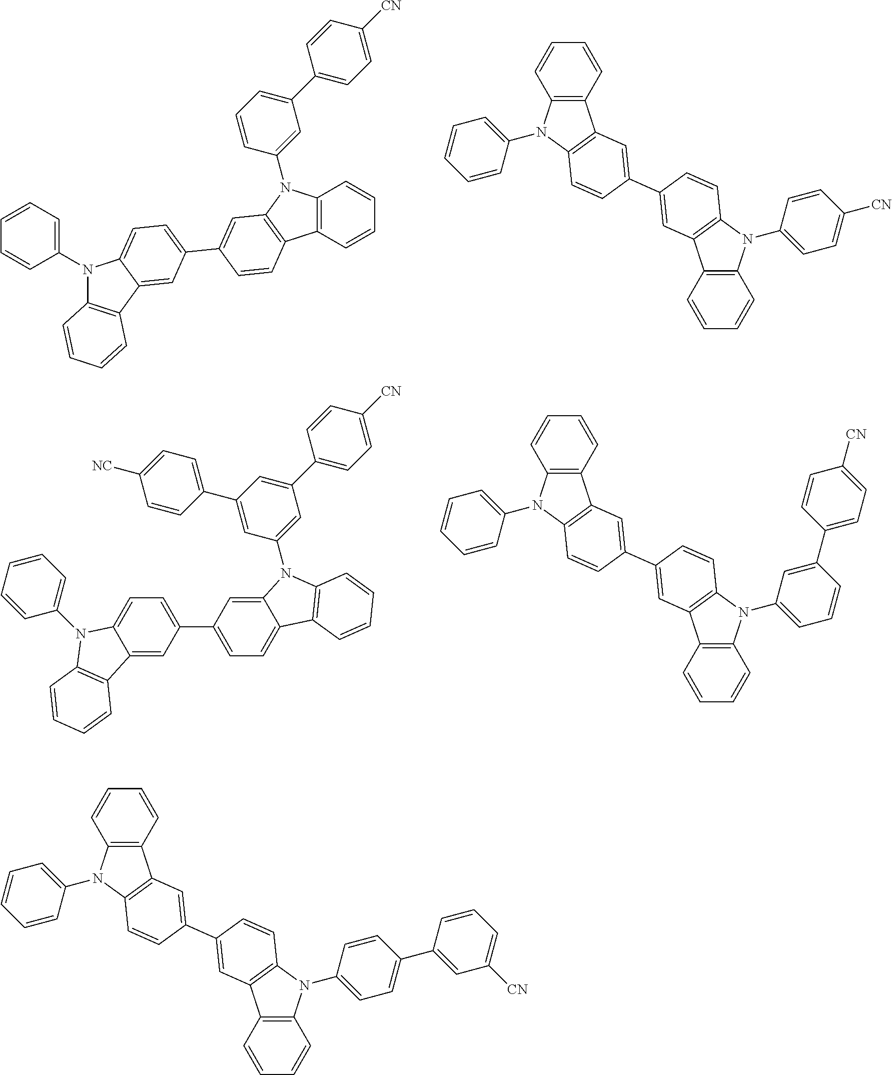 [SMILES: N#Cc1ccc(-c2cccc(-n3c4ccccc4c4ccc(-c5ccc6c(c5)c5ccccc5n6-c5ccccc5)cc43)c2)cc1 ; N#Cc1ccc(-n2c3ccccc3c3cc(-c4ccc5c(c4)c4ccccc4n5-c4ccccc4)ccc32)cc1 ; N#Cc1ccc(-c2cc(-c3ccc(C#N)cc3)cc(-n3c4ccccc4c4ccc(-c5ccc6c(c5)c5ccccc5n6-c5ccccc5)cc43)c2)cc1 ; N#Cc1ccc(-c2cccc(-n3c4ccccc4c4cc(-c5ccc6c(c5)c5ccccc5n6-c5ccccc5)ccc43)c2)cc1 ; N#Cc1cccc(-c2ccc(-n3c4ccccc4c4cc(-c5ccc6c(c5)c5ccccc5n6-c5ccccc5)ccc43)cc2)c1]

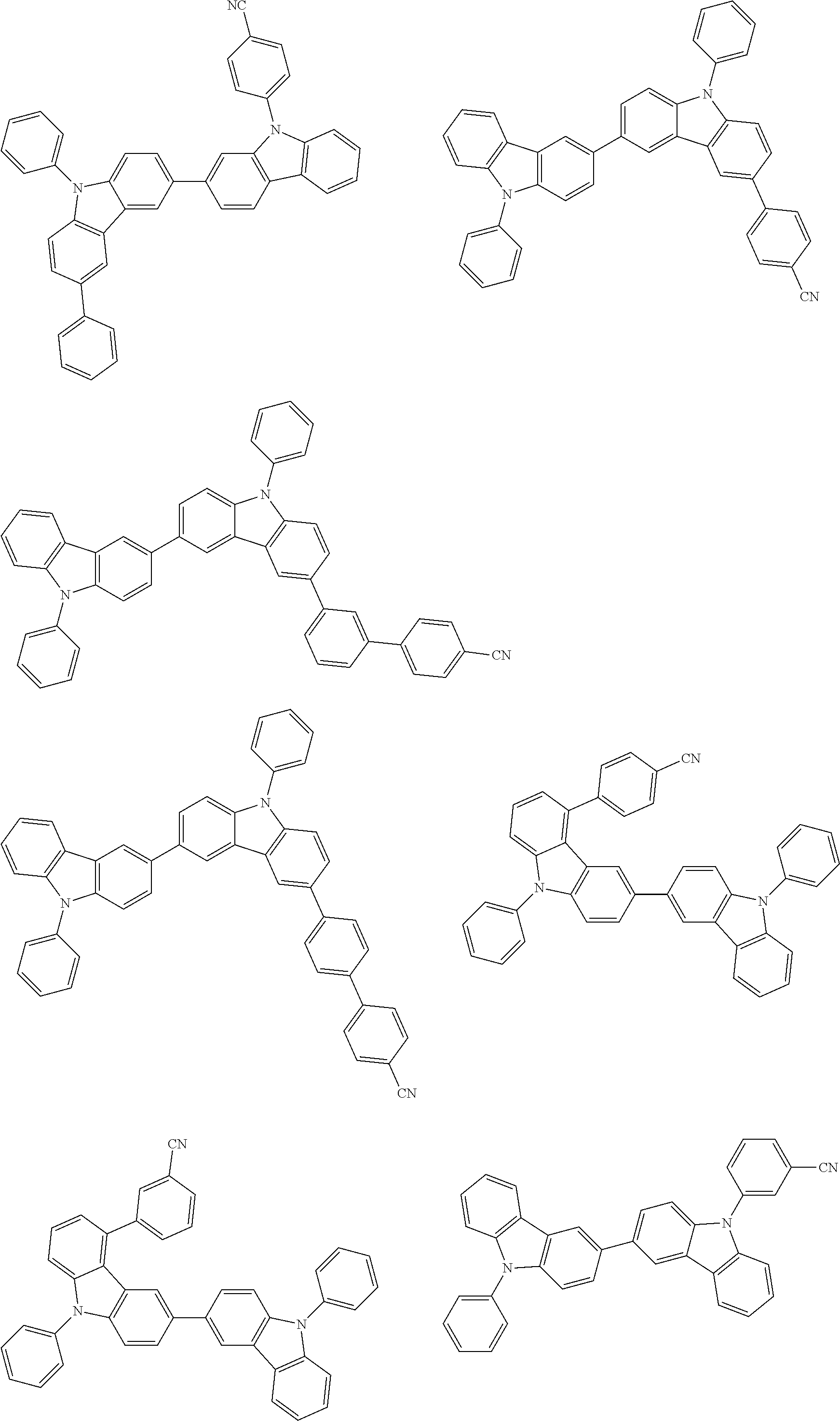

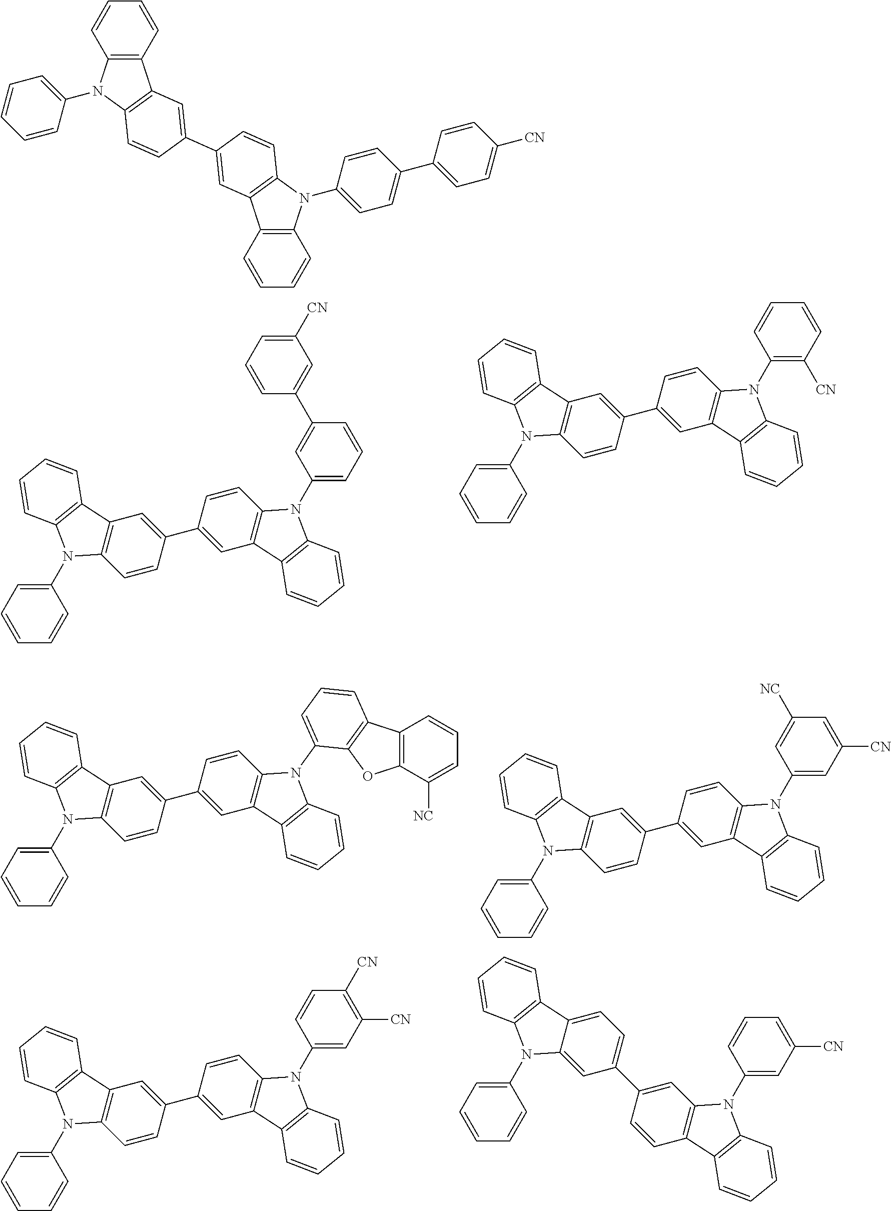

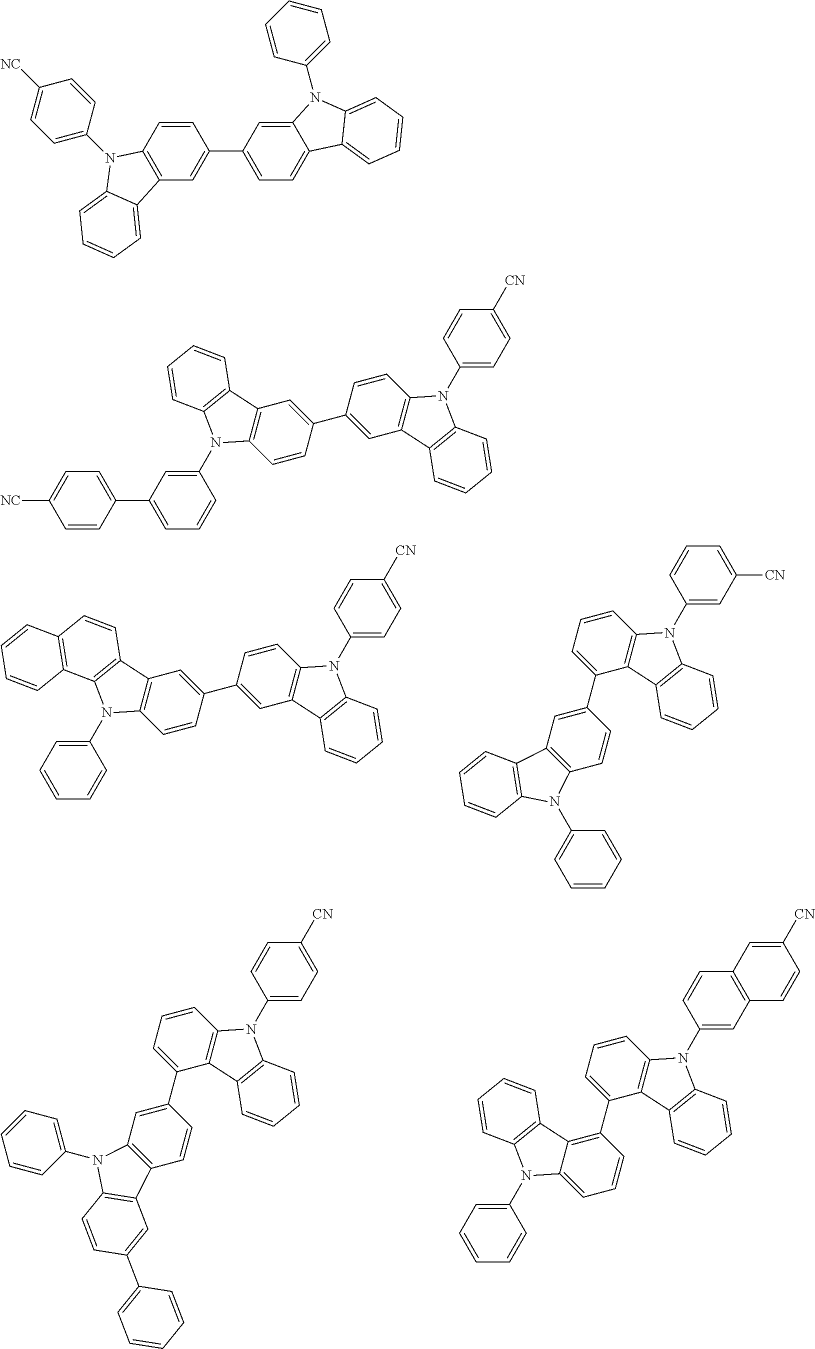 [SMILES: N#Cc1ccc(-n2c3ccccc3c3cc(-c4ccc5c6ccccc6n(-c6ccccc6)c5c4)ccc32)cc1 ; N#Cc1ccc(-c2cccc(-n3c4ccccc4c4cc(-c5ccc6c(c5)c5ccccc5n6-c5ccc(C#N)cc5)ccc43)c2)cc1 ; N#Cc1ccc(-n2c3ccccc3c3cc(-c4ccc5c(c4)c4ccc6ccccc6c4n5-c4ccccc4)ccc32)cc1 ; N#Cc1cccc(-n2c3ccccc3c3c(-c4ccc5c(c4)c4ccccc4n5-c4ccccc4)cccc32)c1 ; N#Cc1ccc(-n2c3ccccc3c3c(-c4ccc5c6cc(-c7ccccc7)ccc6n(-c6ccccc6)c5c4)cccc32)cc1 ; N#Cc1ccc2cc(-n3c4ccccc4c4c(-c5cccc6c5c5ccccc5n6-c5ccccc5)cccc43)ccc2c1]

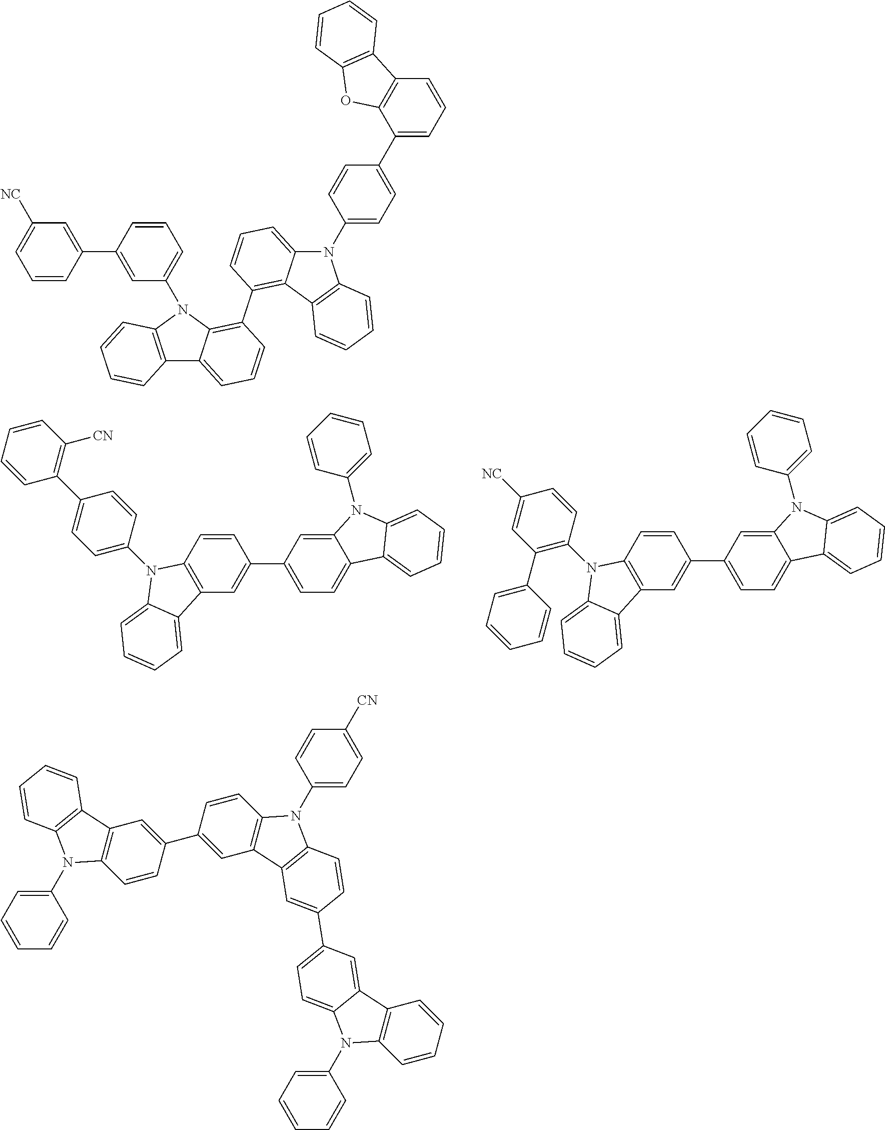 [SMILES: N#Cc1cccc(-c2cccc(-n3c4ccccc4c4cccc(-c5cccc6c5c5ccccc5n6-c5ccc(-c6cccc7c6oc6ccccc67)cc5)c43)c2)c1 ; N#Cc1ccccc1-c1ccc(-n2c3ccccc3c3cc(-c4ccc5c6ccccc6n(-c6ccccc6)c5c4)ccc32)cc1 ; N#Cc1ccc(-n2c3ccccc3c3cc(-c4ccc5c6ccccc6n(-c6ccccc6)c5c4)ccc32)c(-c2ccccc2)c1 ; N#Cc1ccc(-n2c3ccc(-c4ccc5c(c4)c4ccccc4n5-c4ccccc4)cc3c3cc(-c4ccc5c(c4)c4ccccc4n5-c4ccccc4)ccc32)cc1]

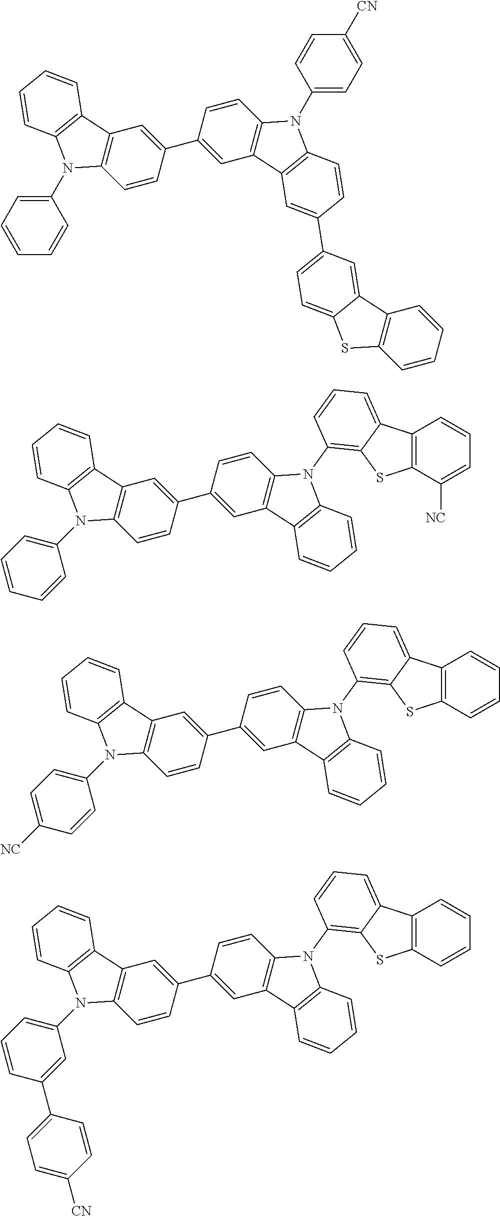

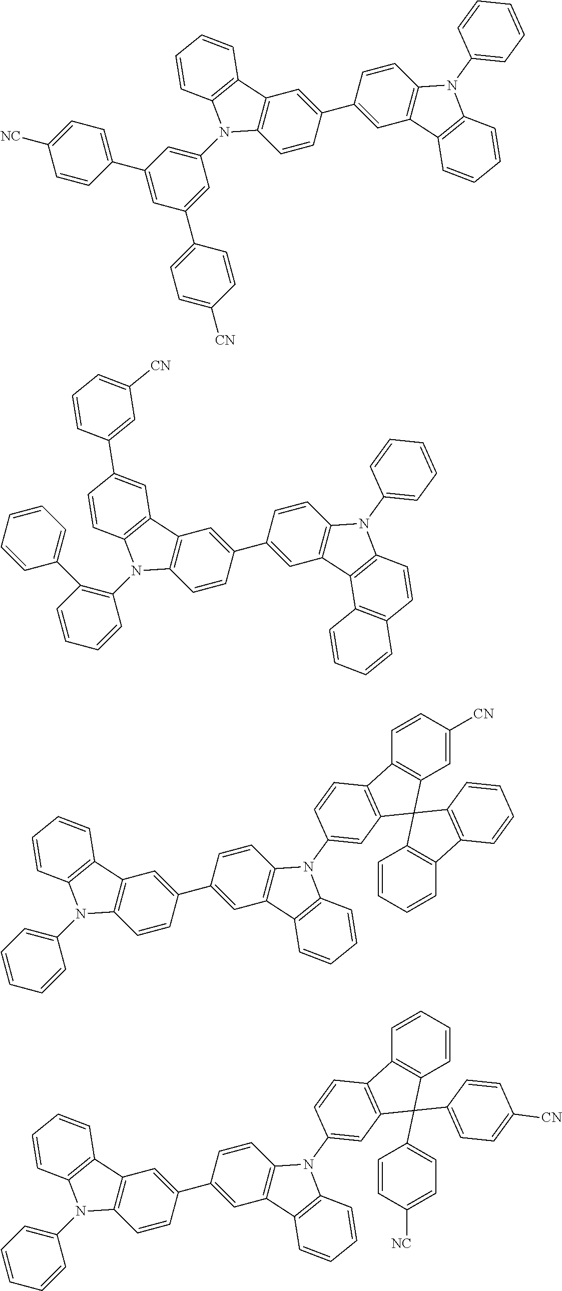 [SMILES: N#Cc1ccc(-c2cc(-c3ccc(C#N)cc3)cc(-n3c4ccccc4c4cc(-c5ccc6c(c5)c5ccccc5n6-c5ccccc5)ccc43)c2)cc1 ; N#Cc1cccc(-c2ccc3c(c2)c2cc(-c4ccc5c(c4)c4c6ccccc6ccc4n5-c4ccccc4)ccc2n3-c2ccccc2-c2ccccc2)c1 ; N#Cc1ccc2c(c1)C1(c3ccccc3-c3ccccc31)c1cc(-n3c4ccccc4c4cc(-c5ccc6c(c5)c5ccccc5n6-c5ccccc5)ccc43)ccc1-2 ; N#Cc1ccc(C2(c3ccc(C#N)cc3)c3ccccc3-c3ccc(-n4c5ccccc5c5cc(-c6ccc7c(c6)c6ccccc6n7-c6ccccc6)ccc54)cc32)cc1]

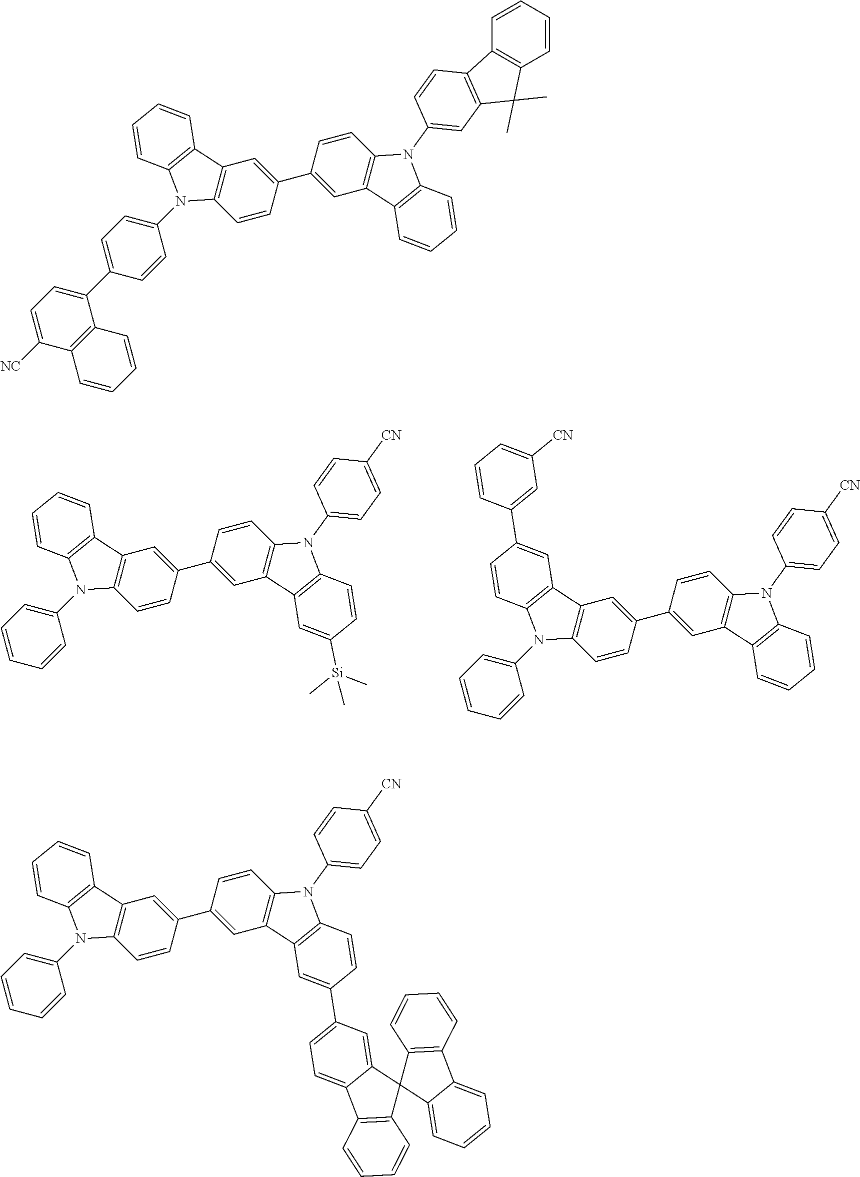 [SMILES: CC1(C)c2ccccc2-c2ccc(-n3c4ccccc4c4cc(-c5ccc6c(c5)c5ccccc5n6-c5ccc(-c6ccc(C#N)c7ccccc67)cc5)ccc43)cc21 ; C[Si](C)(C)c1ccc2c(c1)c1cc(-c3ccc4c(c3)c3ccccc3n4-c3ccccc3)ccc1n2-c1ccc(C#N)cc1 ; N#Cc1ccc(-n2c3ccccc3c3cc(-c4ccc5c(c4)c4cc(-c6cccc(C#N)c6)ccc4n5-c4ccccc4)ccc32)cc1 ; N#Cc1ccc(-n2c3ccc(-c4ccc5c(c4)C4(c6ccccc6-c6ccccc64)c4ccccc4-5)cc3c3cc(-c4ccc5c(c4)c4ccccc4n5-c4ccccc4)ccc32)cc1]

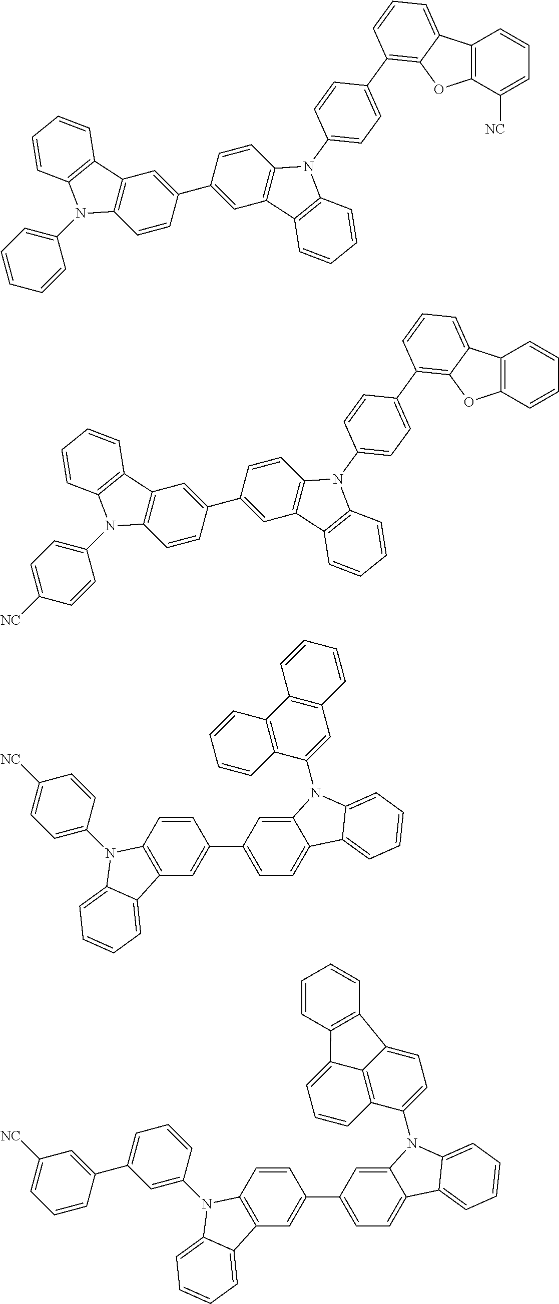 [SMILES: N#Cc1cccc2c1oc1c(-c3ccc(-n4c5ccccc5c5cc(-c6ccc7c(c6)c6ccccc6n7-c6ccccc6)ccc54)cc3)cccc12 ; N#Cc1ccc(-n2c3ccccc3c3cc(-c4ccc5c(c4)c4ccccc4n5-c4ccc(-c5cccc6c5oc5ccccc56)cc4)ccc32)cc1 ; N#Cc1ccc(-n2c3ccccc3c3cc(-c4ccc5c6ccccc6n(-c6cc7ccccc7c7ccccc67)c5c4)ccc32)cc1 ; N#Cc1cccc(-c2cccc(-n3c4ccccc4c4cc(-c5ccc6c7ccccc7n(-c7ccc8c9c(cccc79)-c7ccccc7-8)c6c5)ccc43)c2)c1]

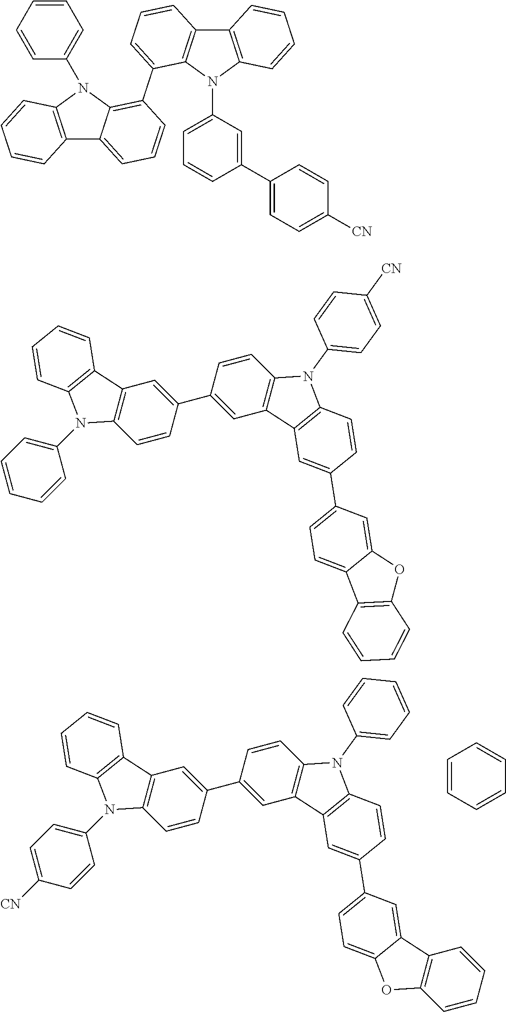

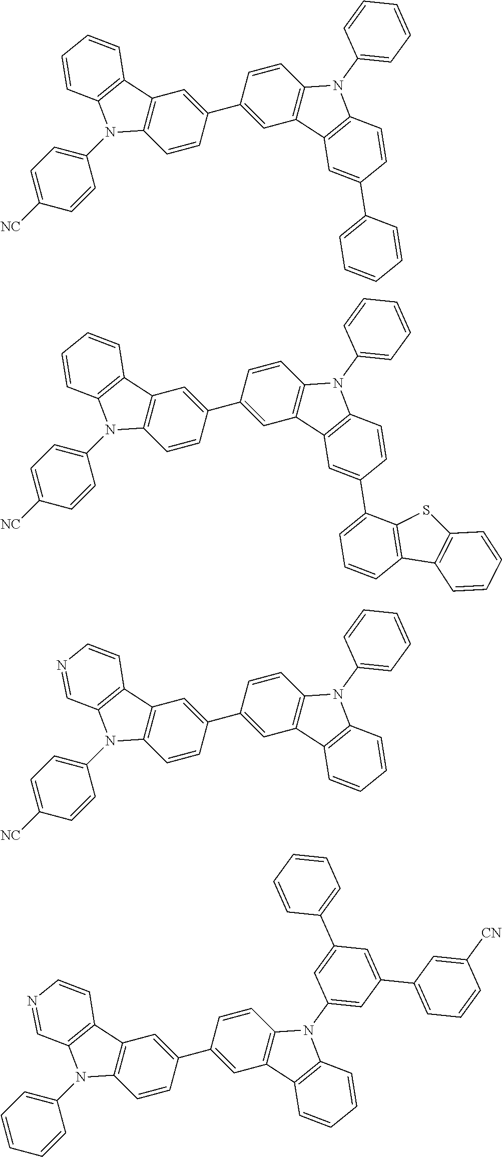

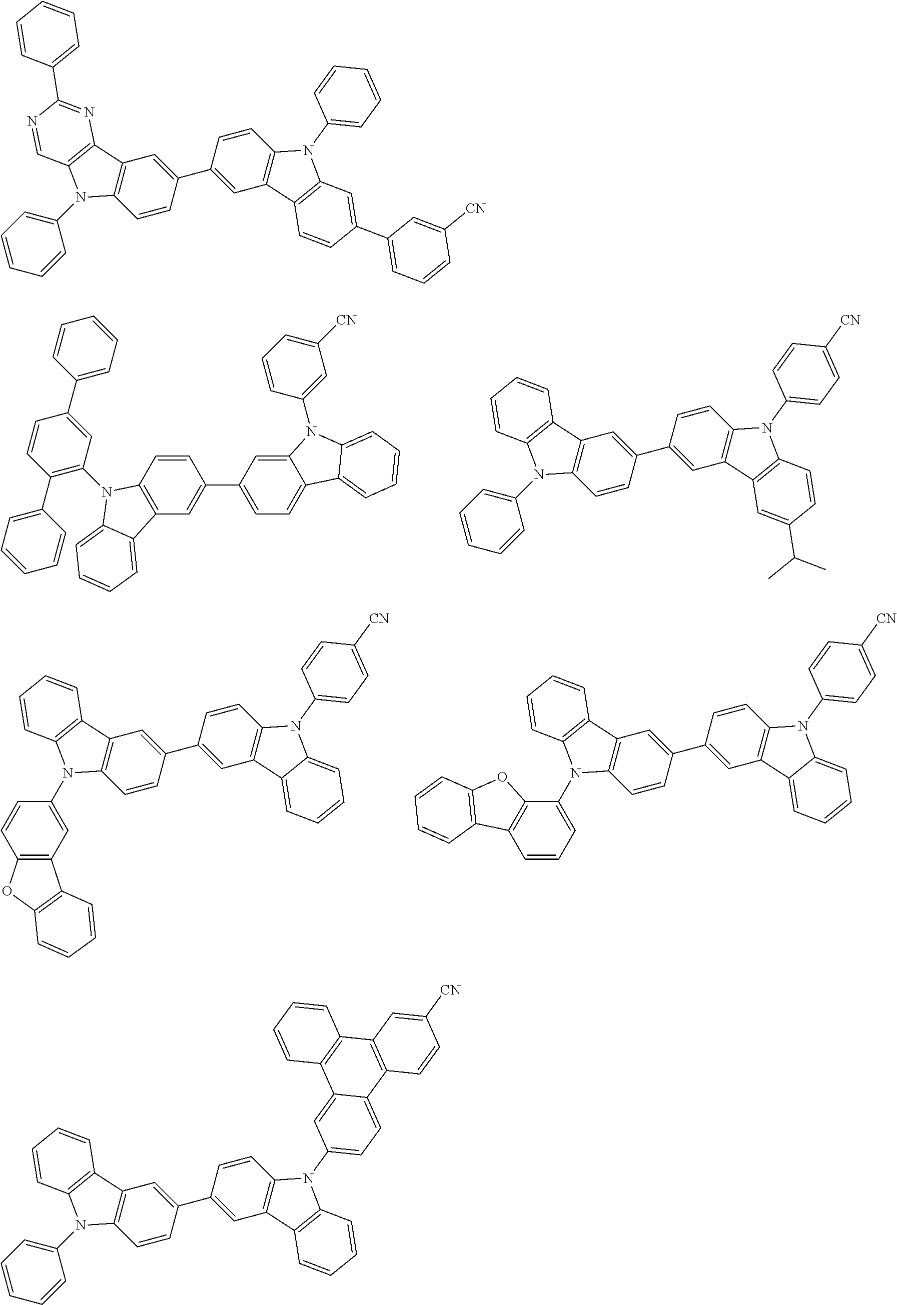 [SMILES: N#Cc1cccc(-c2ccc3c4cc(-c5ccc6c(c5)c5nc(-c7ccccc7)ncc5n6-c5ccccc5)ccc4n(-c4ccccc4)c3c2)c1 ; N#Cc1cccc(-n2c3ccccc3c3ccc(-c4ccc5c(c4)c4ccccc4n5-c4cc(-c5ccccc5)ccc4-c4ccccc4)cc32)c1 ; CC(C)c1ccc2c(c1)c1cc(-c3ccc4c(c3)c3ccccc3n4-c3ccccc3)ccc1n2-c1ccc(C#N)cc1 ; N#Cc1ccc(-n2c3ccccc3c3cc(-c4ccc5c(c4)c4ccccc4n5-c4ccc5oc6ccccc6c5c4)ccc32)cc1 ; N#Cc1ccc(-n2c3ccccc3c3cc(-c4ccc5c(c4)c4ccccc4n5-c4cccc5c4oc4ccccc45)ccc32)cc1 ; N#Cc1ccc2c3ccc(-n4c5ccccc5c5cc(-c6ccc7c(c6)c6ccccc6n7-c6ccccc6)ccc54)cc3c3ccccc3c2c1]

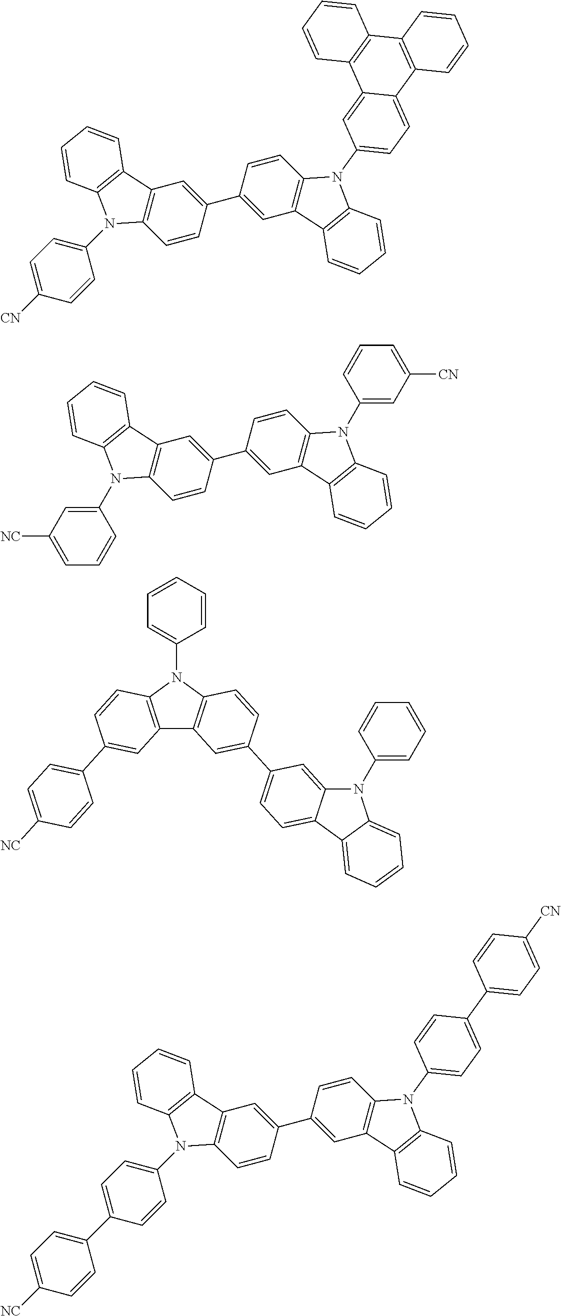

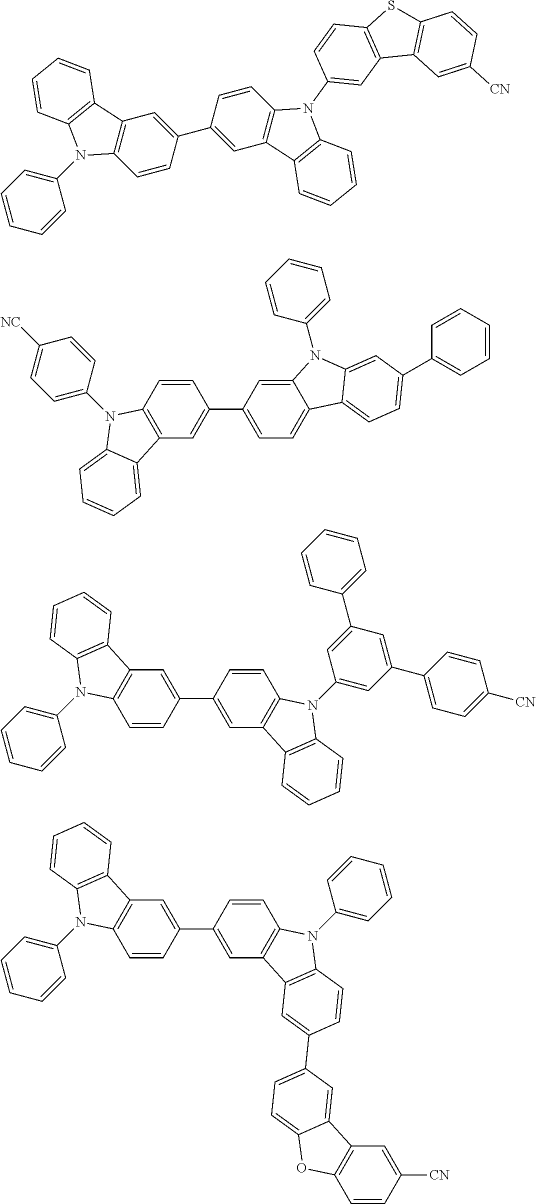 [SMILES: N#Cc1ccc2sc3ccc(-n4c5ccccc5c5cc(-c6ccc7c(c6)c6ccccc6n7-c6ccccc6)ccc54)cc3c2c1 ; N#Cc1ccc(-n2c3ccccc3c3cc(-c4ccc5c6ccc(-c7ccccc7)cc6n(-c6ccccc6)c5c4)ccc32)cc1 ; N#Cc1ccc(-c2cc(-c3ccccc3)cc(-n3c4ccccc4c4cc(-c5ccc6c(c5)c5ccccc5n6-c5ccccc5)ccc43)c2)cc1 ; N#Cc1ccc2oc3ccc(-c4ccc5c(c4)c4cc(-c6ccc7c(c6)c6ccccc6n7-c6ccccc6)ccc4n5-c4ccccc4)cc3c2c1]

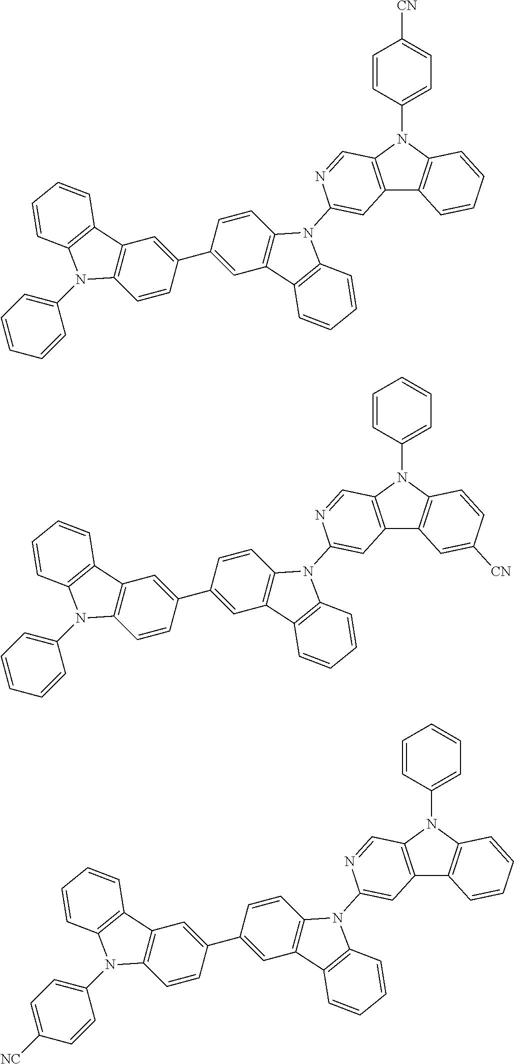 [SMILES: N#Cc1ccc(-n2c3ccccc3c3cc(-n4c5ccccc5c5cc(-c6ccc7c(c6)c6ccccc6n7-c6ccccc6)ccc54)ncc32)cc1 ; N#Cc1ccc2c(c1)c1cc(-n3c4ccccc4c4cc(-c5ccc6c(c5)c5ccccc5n6-c5ccccc5)ccc43)ncc1n2-c1ccccc1 ; N#Cc1ccc(-n2c3ccccc3c3cc(-c4ccc5c(c4)c4ccccc4n5-c4cc5c6ccccc6n(-c6ccccc6)c5cn4)ccc32)cc1]

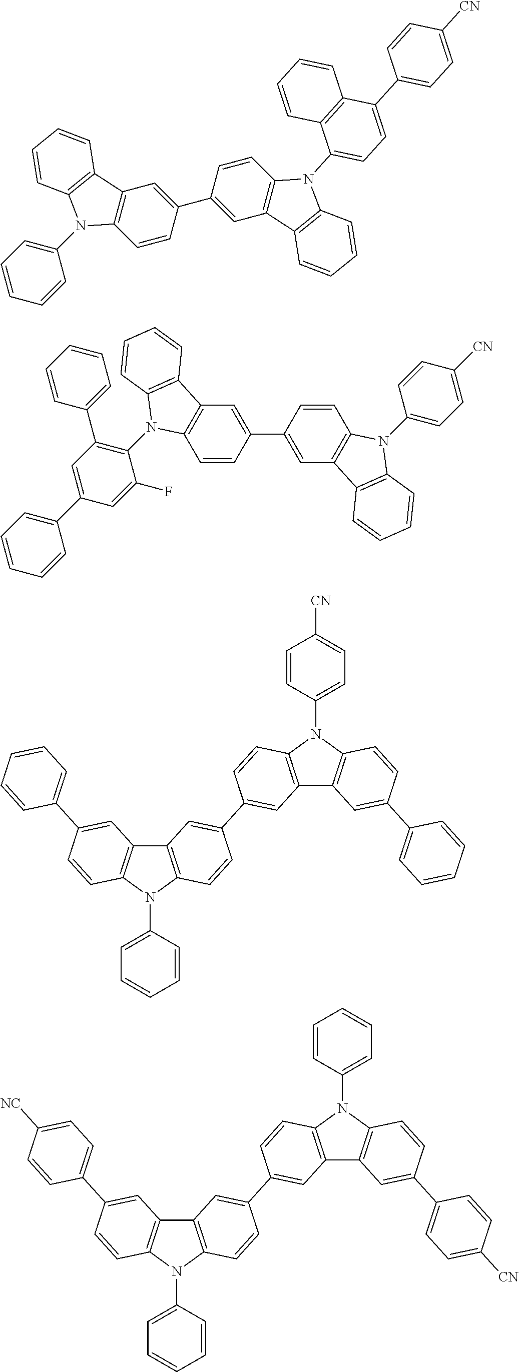 [SMILES: N#Cc1ccc(-c2ccc(-n3c4ccccc4c4cc(-c5ccc6c(c5)c5ccccc5n6-c5ccccc5)ccc43)c3ccccc23)cc1 ; N#Cc1ccc(-n2c3ccccc3c3cc(-c4ccc5c(c4)c4ccccc4n5-c4c(F)cc(-c5ccccc5)cc4-c4ccccc4)ccc32)cc1 ; N#Cc1ccc(-n2c3ccc(-c4ccccc4)cc3c3cc(-c4ccc5c(c4)c4cc(-c6ccccc6)ccc4n5-c4ccccc4)ccc32)cc1 ; N#Cc1ccc(-c2ccc3c(c2)c2cc(-c4ccc5c(c4)c4cc(-c6ccc(C#N)cc6)ccc4n5-c4ccccc4)ccc2n3-c2ccccc2)cc1]

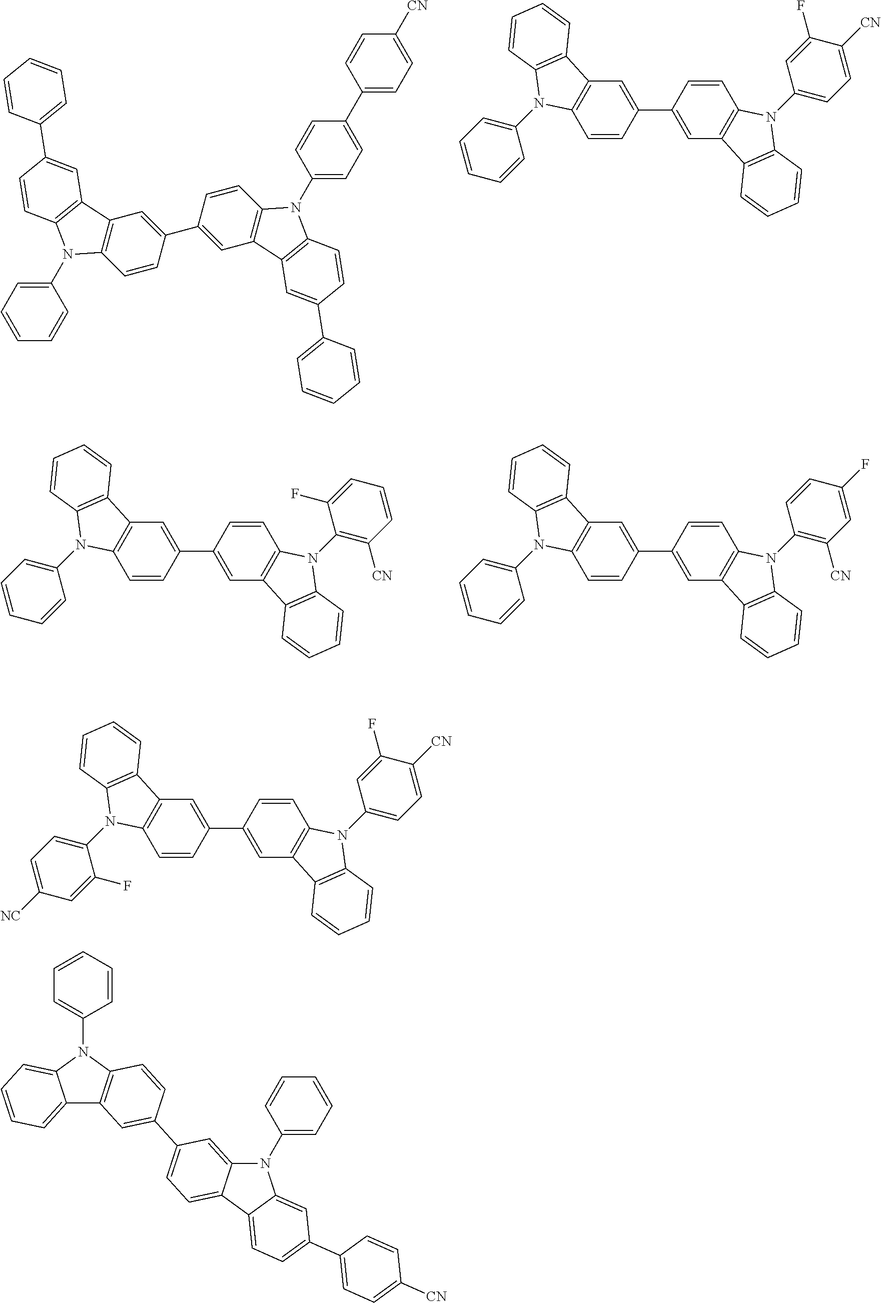 [SMILES: N#Cc1ccc(-c2ccc(-n3c4ccc(-c5ccccc5)cc4c4cc(-c5ccc6c(c5)c5cc(-c7ccccc7)ccc5n6-c5ccccc5)ccc43)cc2)cc1 ; N#Cc1ccc(-n2c3ccccc3c3cc(-c4ccc5c(c4)c4ccccc4n5-c4ccccc4)ccc32)cc1F ; N#Cc1cccc(F)c1-n1c2ccccc2c2cc(-c3ccc4c(c3)c3ccccc3n4-c3ccccc3)ccc21 ; N#Cc1cc(F)ccc1-n1c2ccccc2c2cc(-c3ccc4c(c3)c3ccccc3n4-c3ccccc3)ccc21 ; N#Cc1ccc(-n2c3ccccc3c3cc(-c4ccc5c(c4)c4ccccc4n5-c4ccc(C#N)c(F)c4)ccc32)c(F)c1 ; N#Cc1ccc(-c2ccc3c4ccc(-c5ccc6c(c5)c5ccccc5n6-c5ccccc5)cc4n(-c4ccccc4)c3c2)cc1]

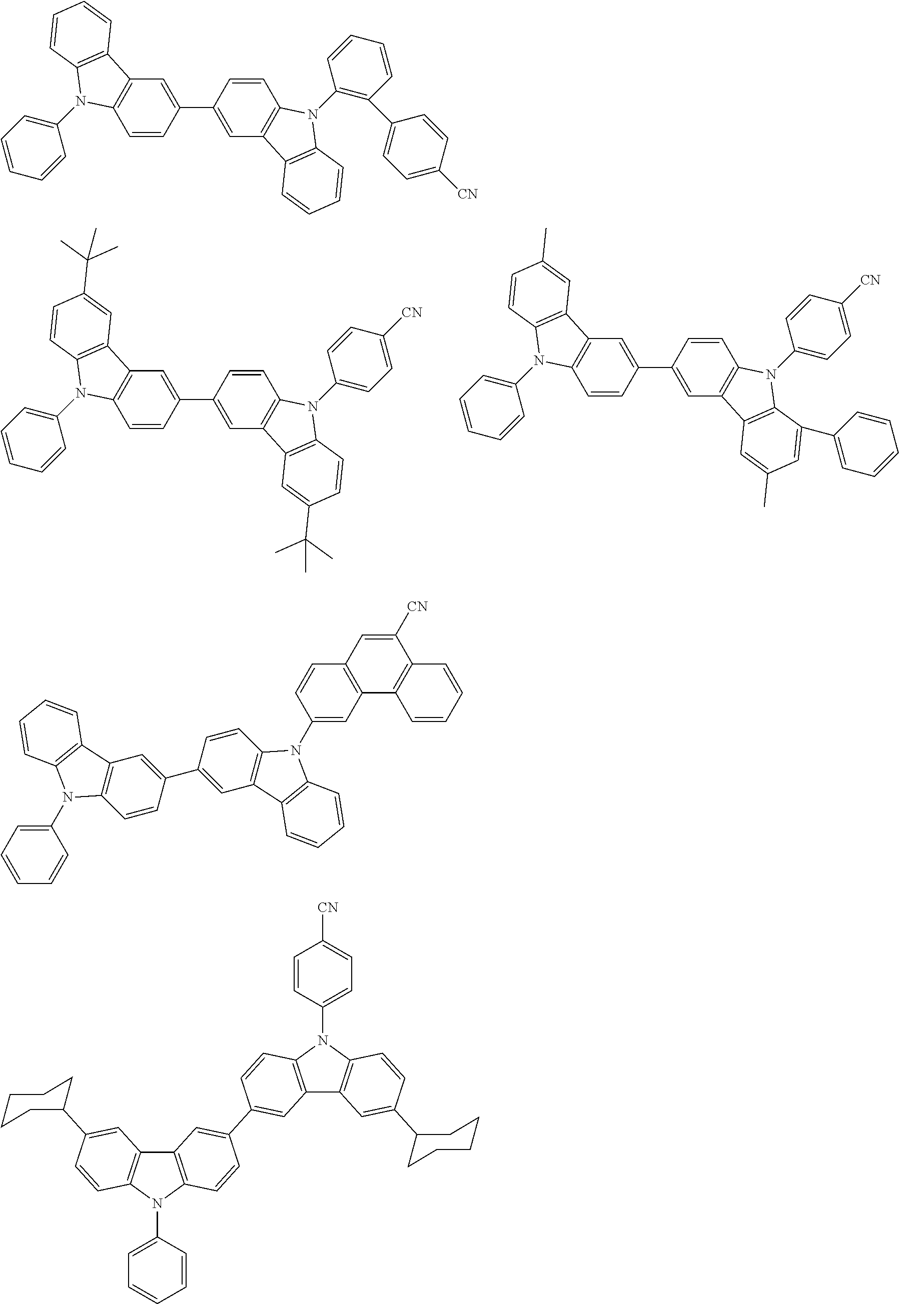 [SMILES: N#Cc1ccc(-c2ccccc2-n2c3ccccc3c3cc(-c4ccc5c(c4)c4ccccc4n5-c4ccccc4)ccc32)cc1 ; CC(C)(C)c1ccc2c(c1)c1cc(-c3ccc4c(c3)c3cc(C(C)(C)C)ccc3n4-c3ccc(C#N)cc3)ccc1n2-c1ccccc1 ; Cc1ccc2c(c1)c1cc(-c3ccc4c(c3)c3cc(C)cc(-c5ccccc5)c3n4-c3ccc(C#N)cc3)ccc1n2-c1ccccc1 ; N#Cc1cc2ccc(-n3c4ccccc4c4cc(-c5ccc6c(c5)c5ccccc5n6-c5ccccc5)ccc43)cc2c2ccccc12 ; N#Cc1ccc(-n2c3ccc(-c4ccc5c(c4)c4cc(C6CCCCC6)ccc4n5-c4ccccc4)cc3c3cc(C4CCCCC4)ccc32)cc1]

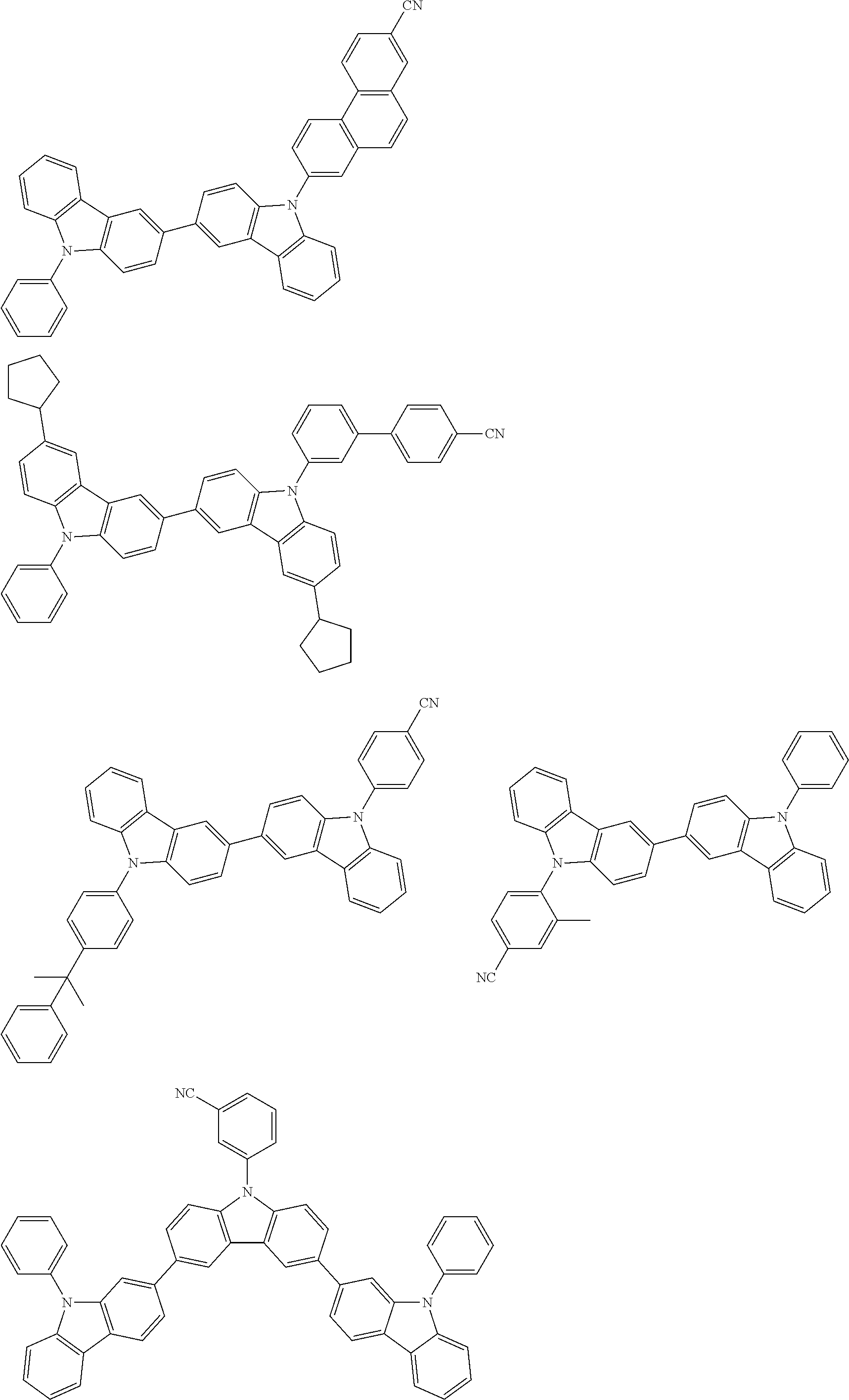

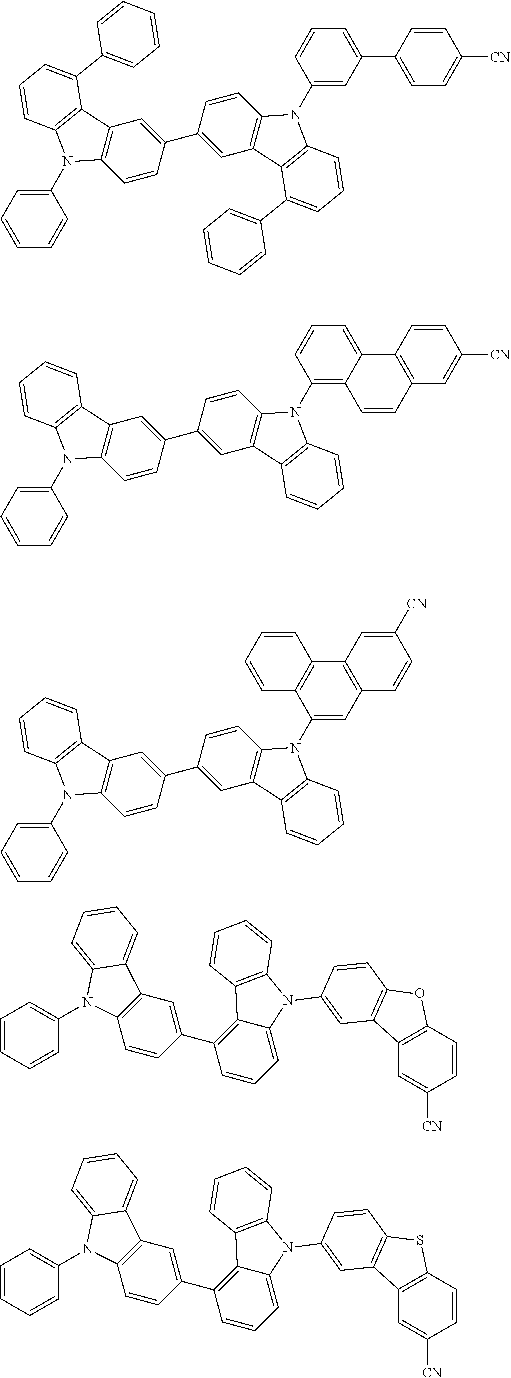

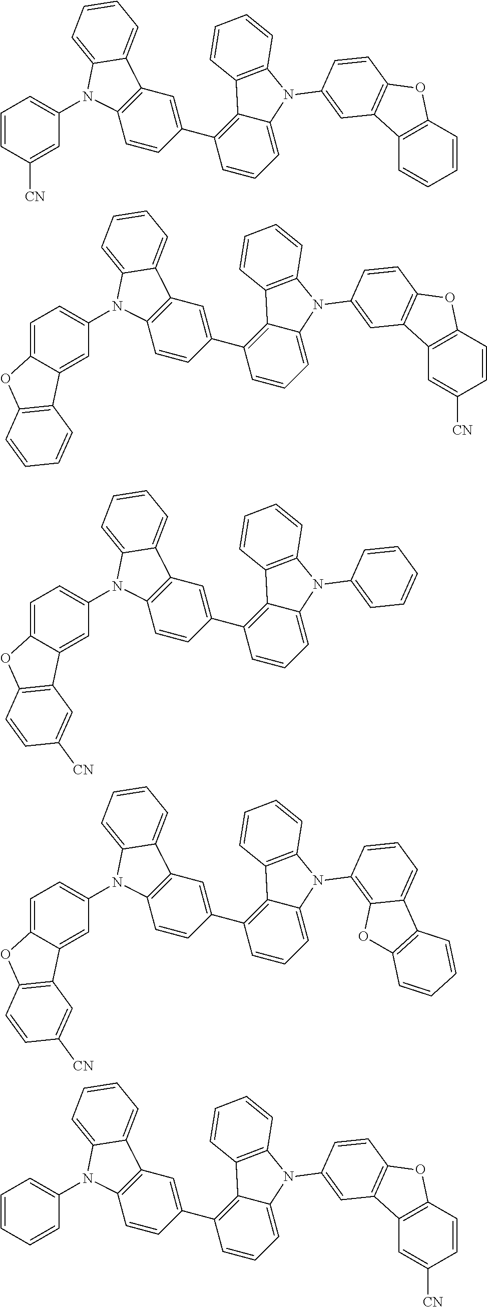

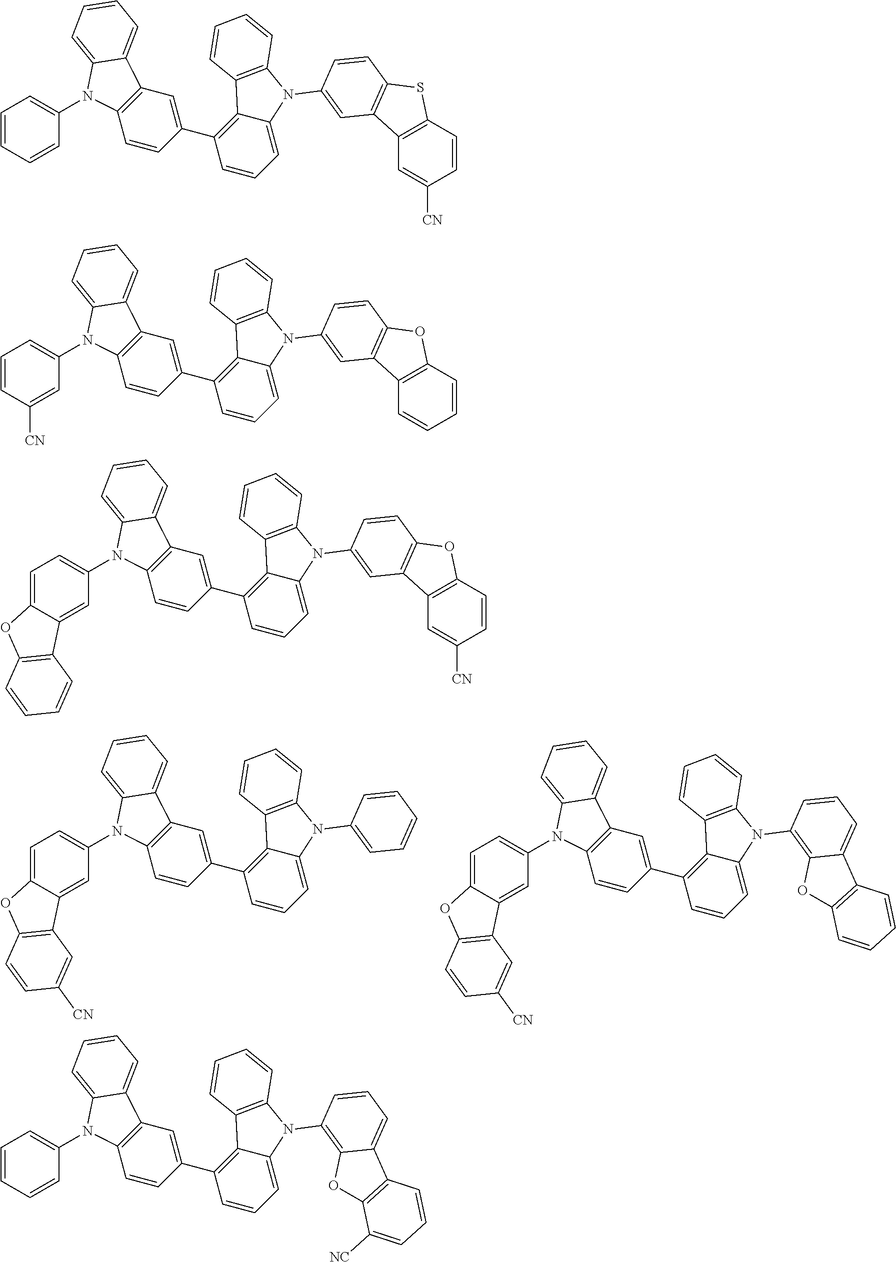

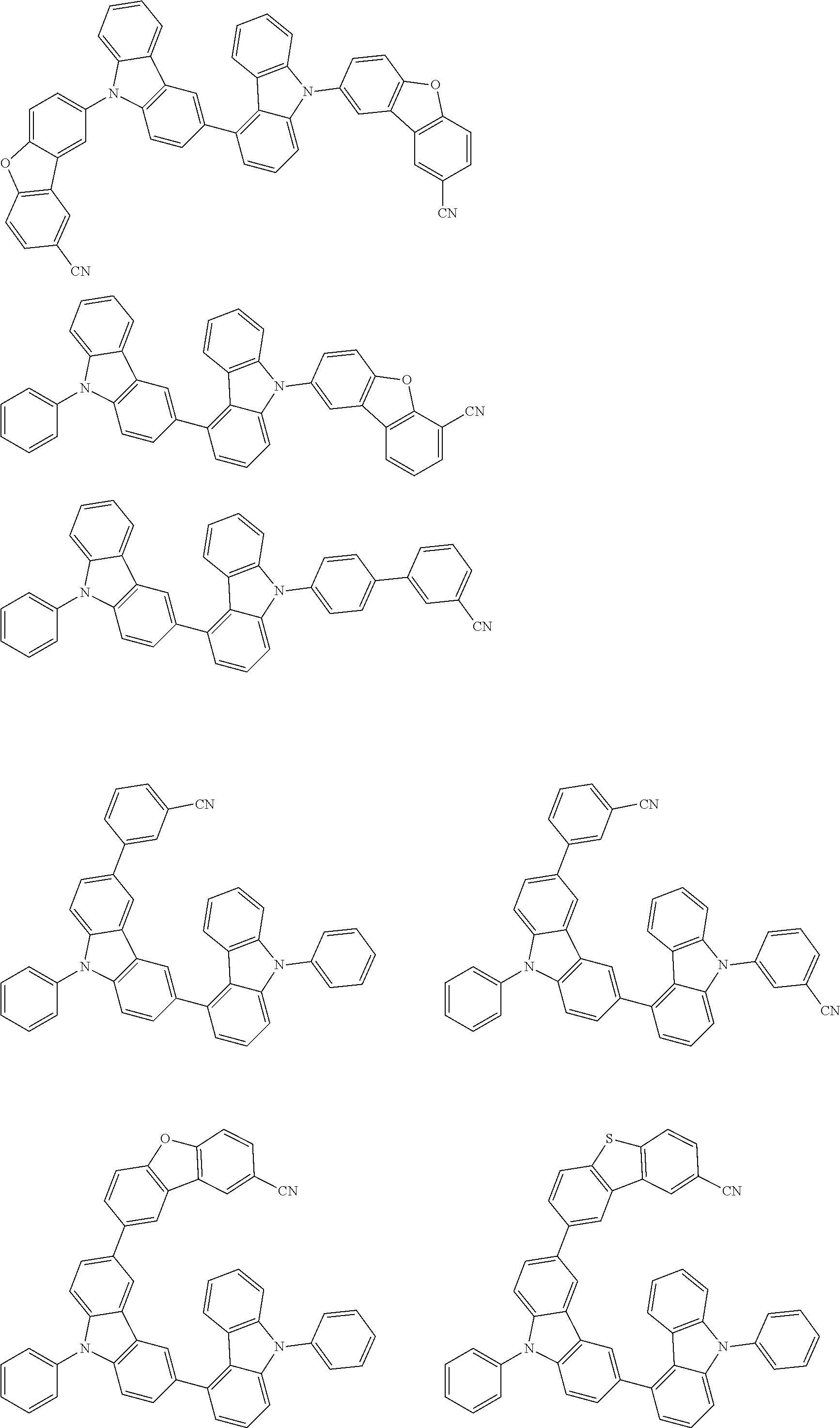

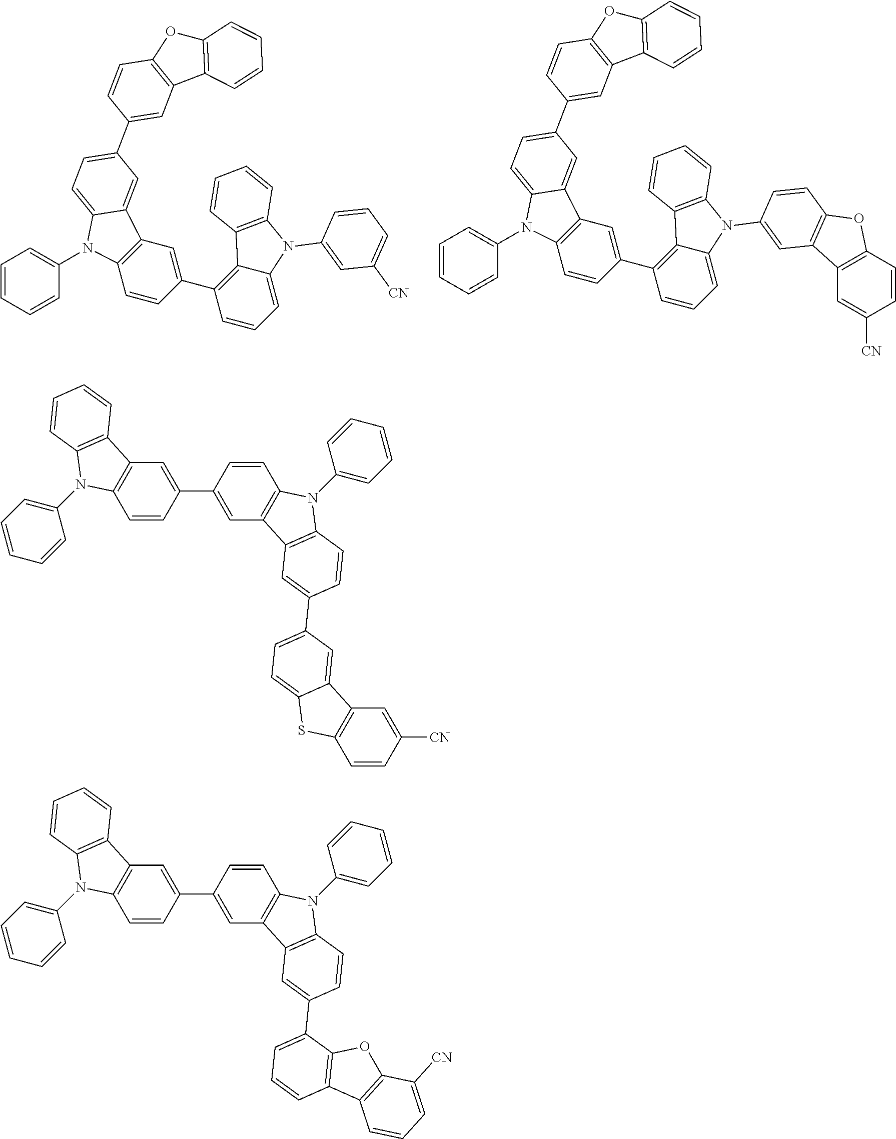 [SMILES: N#Cc1cccc(-n2c3ccccc3c3c(-c4ccc5c(c4)c4cc(-c6ccc7oc8ccccc8c7c6)ccc4n5-c4ccccc4)cccc32)c1 ; N#Cc1ccc2oc3ccc(-n4c5ccccc5c5c(-c6ccc7c(c6)c6cc(-c8ccc9oc%10ccccc%10c9c8)ccc6n7-c6ccccc6)cccc54)cc3c2c1 ; N#Cc1ccc2sc3ccc(-c4ccc5c(c4)c4cc(-c6ccc7c(c6)c6ccccc6n7-c6ccccc6)ccc4n5-c4ccccc4)cc3c2c1 ; N#Cc1cccc2c1oc1c(-c3ccc4c(c3)c3cc(-c5ccc6c(c5)c5ccccc5n6-c5ccccc5)ccc3n4-c3ccccc3)cccc12]

In addition to the above-described first host material, the second host material is contained in the emitting layer of the organic EL device according to the exemplary embodiment. The second host material is preferably represented by the following formula (2).

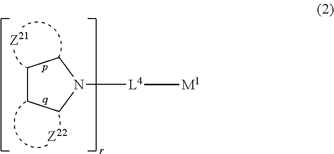

In the formula (2), Z²¹ to be fused at p represents a cyclic structure represented by the following formula (2-1) or (2-2).

In the formula (2), Z²² to be fused at q represents a cyclic structure represented by the following formula (2-1) or (2-2). However, at least one of Z²¹ and Z²² is represented by the formula (2-1).

In the formula (2), M¹ represents a substituted or unsubstituted aromatic hydrocarbon group having 6 to 30 ring carbon atoms, or substituted or unsubstituted heterocyclic group having 5 to 30 ring atoms.

The aromatic hydrocarbon group having 6 to 30 ring carbon atoms in the formula (2) is exemplified by the examples of the aromatic hydrocarbon group described in relation to the formula (1-1).

The heterocyclic group having 5 to 30 ring atoms in the formula (2) is exemplified by the examples of the aromatic hydrocarbon group described in relation to the formula (1-1).

In the formula (2), L⁴ represents a single bond, a substituted or unsubstituted divalent aromatic hydrocarbon group having 6 to 30 ring carbon atoms, a substituted or unsubstituted divalent heterocyclic group having 5 to 30 ring atoms, a substituted or unsubstituted cycloalkylene group having 5 to 30 ring carbon atoms, or a group provided by linking the divalent aromatic hydrocarbon group, the divalent heterocyclic group and the cycloalkylene group.

The divalent aromatic hydrocarbon group having 6 to 30 ring carbon atoms in the formula (2) is exemplified by the examples of the divalent aromatic hydrocarbon group having 6 to 30 ring carbon atoms described in relation to the formula (1-1).

The divalent heterocyclic group having 5 to 30 ring atoms in the formula (2) is exemplified by the examples of the divalent heterocyclic group having 5 to 30 ring atoms described in relation to the formula (1-1).

The cycloalkylene group having 5 to 30 ring carbon atoms in the formula (2) is exemplified by divalent groups of the examples of the cycloalkyl group having 3 to 30 ring carbon atoms described in relation to the formula (1-1).

In the formula (2), r is 1 or 2.

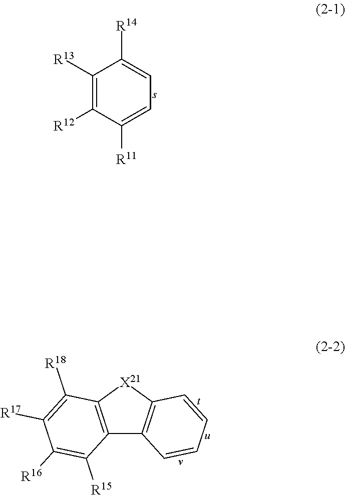

In the formula (2-1), s represents fusion at p or q in the formula (2).

One of t, u and v in the formula (2-2) is fused to p or q in the formula (2).

X²¹ in the formula (2-2) represents a sulfur atom, an oxygen atom, N—R¹⁹, or C(R²⁰)(R²¹). Herein, C(R²⁰)(R²¹) represents R²⁰ and R²¹ bonded to a carbon atom (C).

In the formulae (2-1) and (2-2), R¹¹ to R²¹ each independently represent a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms.

Adjacent ones of R¹¹ to R¹⁸ are bonded to each other to form a ring, or are not bonded.

For R¹¹ to R²¹ in the formulae (2-1) and (2-2), the aromatic hydrocarbon group having 6 to 30 ring carbon atoms, heterocyclic group having 5 to 30 ring atoms, alkyl group having 1 to 30 carbon atoms, cycloalkyl group having 3 to 30 ring carbon atoms, haloalkyl group having 1 to 20 carbon atoms, alkoxy group having 1 to 30 carbon atoms, haloalkoxy group having 1 to 20 carbon atoms, aryloxy group having 6 to 30 ring carbon atoms, alkylsilyl group having 1 to 30 carbon atoms, arylsilyl group having 6 to 30 carbon atoms, aralkyl group having 7 to 30 carbon atoms, alkenyl group having 2 to 30 carbon atoms and alkynyl group having 2 to 30 carbon atoms are respectively exemplified by the examples of those described in relation to the formula (1-1).

The second host material is preferably represented by the following formula (2-3).

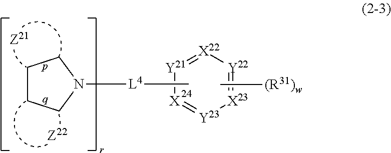

In the formula (2-3), Z²¹ to be fused at p represents a cyclic structure represented by the formula (2-1) or (2-2).

In the formula (2-3), Z²² to be fused at q represents a cyclic structure represented by the formula (2-1) or (2-2).

At least one of Z²¹ and Z²² in the formula (2-3) is represented by the formula (2-1).

In the formula (2-3), L⁴ represents the same as L⁴ in the formula (2).

In the formula (2-3), X²² to X²⁴ each independently represent a nitrogen atom, CH or a carbon atom to be bonded to R³¹ or L⁴.

In the formula (2-3), Y²¹ to Y²³ each independently represent CH or a carbon atom to be bonded to R³¹ or L⁴.

In the formulae (2-1) and (2-2), R¹¹ to R²¹ each independently represent a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms.

In the formula (2-3), when a plurality of R³¹ are present, the plurality of R³¹ may be mutually the same or different and adjacent one of those may be bonded to each other to form a ring.

For R³¹ in the formula (2-3), the aromatic hydrocarbon group having 6 to 30 ring carbon atoms, heterocyclic group having 5 to 30 ring atoms, alkyl group having 1 to 30 carbon atoms, cycloalkyl group having 3 to 30 ring carbon atoms, haloalkyl group having 1 to 20 carbon atoms, alkoxy group having 1 to 30 carbon atoms, haloalkoxy group having 1 to 20 carbon atoms, aryloxy group having 6 to 30 ring carbon atoms, alkylsilyl group having 1 to 30 carbon atoms, arylsilyl group having 6 to 30 carbon atoms, aralkyl group having 7 to 30 carbon atoms, alkenyl group having 2 to 30 carbon atoms and alkynyl group having 2 to 30 carbon atoms are respectively exemplified by the examples of those described in relation to the formula (1-1).

In the formula (2-3), r is 1 or 2 and w is an integer of 0 to 4.

s in the formula (2-1) is fused to p or q in the formula (2). One of t, u and v in the formula (2-2) is fused to p or q in the formula (2).

The second host material is preferably represented by the following formula (2-4).

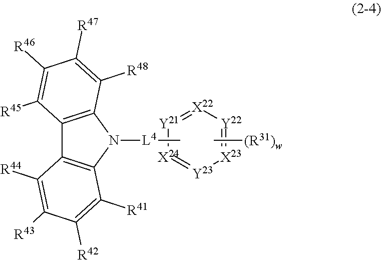

In the formula (2-4), L⁴ represents the same as L⁴ in the formula (2).

In the formula (2-4), X²² to X²⁴ each independently represent a nitrogen atom, CH or a carbon atom to be bonded to R³¹ or L⁴.

In the formula (2-4), Y²¹ to Y²³ each independently represent CH or a carbon atom to be bonded to R³¹ or L⁴. In the formula (2-4), R³¹ represents the same as R³¹ in the formula (2-3).

In the formula (2-4), when a plurality of R³¹ are present, the plurality of R³¹ may be mutually the same or different and adjacent one of those may be bonded to each other to form a ring.

In the formula (2-4), w is an integer of 0 to 4.

In the formula (2-4), R⁴¹ to R⁴⁸ each independently represent the same as R¹¹ to R²¹ in the formulae (2-1) and (2-2). Adjacent ones of R⁴¹ to R⁴⁸ are bonded to each other to form a ring, or are not bonded.

The second host material is preferably represented by the following formula (2-5).

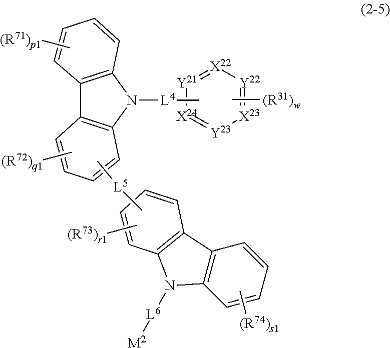

In the formula (2-5), L⁴ represents the same as L⁴ in the formula (2).

In the formula (2-5), X²² to X²⁴ each independently represent a nitrogen atom, CH or a carbon atom to be bonded to R³¹ or L⁴. At least one of X²² to X²⁴ is a nitrogen atom.

In the formula (2-5), Y²¹ to Y²³ each independently represent CH or a carbon atom to be bonded to R³¹ or L⁴. In the formula (2-5), R³¹ represents the same as R³¹ in the formula (2-3).

In the formula (2-5), when a plurality of R³¹ are present, the plurality of R³¹ may be mutually the same or different and adjacent one of those may be bonded to each other to form a ring.

In the formula (2-5), w is an integer of 0 to 4.

In the formula (2-5), L⁵ and L⁶ represent a single bond, a substituted or unsubstituted divalent aromatic hydrocarbon group having 6 to 30 ring carbon atoms, a substituted or unsubstituted divalent heterocyclic group having 5 to 30 ring atoms, a substituted or unsubstituted cycloalkylene group having 5 to 30 ring carbon atoms, or a group provided by linking the divalent aromatic hydrocarbon group, the divalent heterocyclic group and the cycloalkylene group.

In the formula (2-5), R⁷¹ to R⁷⁴ each independently represent the same as R¹¹ to R²¹ in the formula (2). In at least one of adjacent ones of R⁷¹, adjacent ones of R⁷², adjacent ones of R⁷³, and adjacent ones of R⁷⁴, the adjacent ones are bonded to each other to form a ring, or are not bonded;

In the formula (2-5), M² represents a substituted or unsubstituted aromatic hydrocarbon group having 6 to 30 ring carbon atoms, or substituted or unsubstituted heterocyclic group having 5 to 30 ring atoms.

In the formula (2-5), p1 and s1 each independently represent an integer of 0 to 4 and q1 and r1 each independently represent an integer of 0 to 3.

The divalent aromatic hydrocarbon group having 6 to 30 ring carbon atoms in the formula (2-5) is exemplified by the examples of the divalent aromatic hydrocarbon group having 6 to 30 ring carbon atoms described in relation to the formula (1-1).

The divalent heterocyclic group having 5 to 30 ring atoms in the formula (2-5) is exemplified by the examples of the divalent heterocyclic group having 5 to 30 ring atoms described in relation to the formula (1-1).

The cycloalkylene group having 5 to 30 ring carbon atoms in the formula (2-5) is exemplified by divalent groups of the examples of the cycloalkyl group having 3 to 30 ring carbon atoms described in relation to the formula (1-1).

A manufacturing method of the second host material is not particularly limited, but known methods are usable. For instance, the first host material may be manufactured by a coupling reaction using a copper catalyst described in “Tetrahedron, 40th volume (1984), p. 1433-1456” or a paradium catalyst described in “Journal of the American Chemical Society, 123 (2001), p. 7727-7729” to manufacture the biscarbazole derivative.

A specific structure of the compound used as the second host material is exemplified by structures of the compound satisfying at least one of the formulae (2) and (2-3) to (2-5), and the following compounds. However, the invention is not limited to the compounds having these structures. It should be noted that a bond at an end of the following structural formulae, of which chemical formula (e.g., CN or a benzene ring) is not described, represents a methyl group.

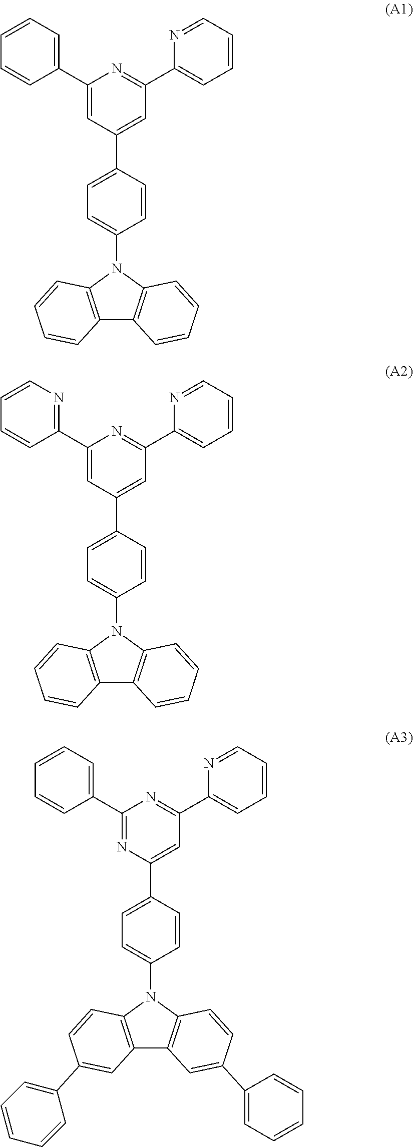

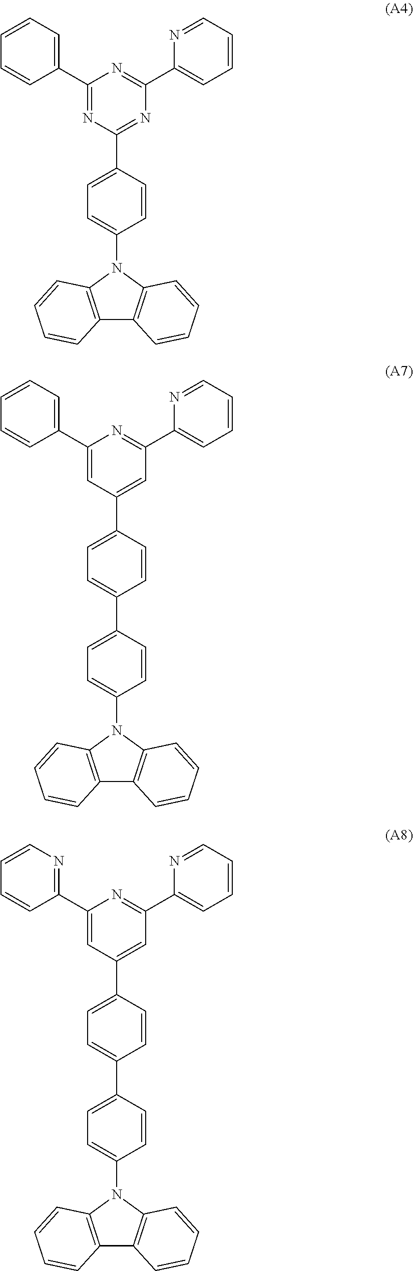

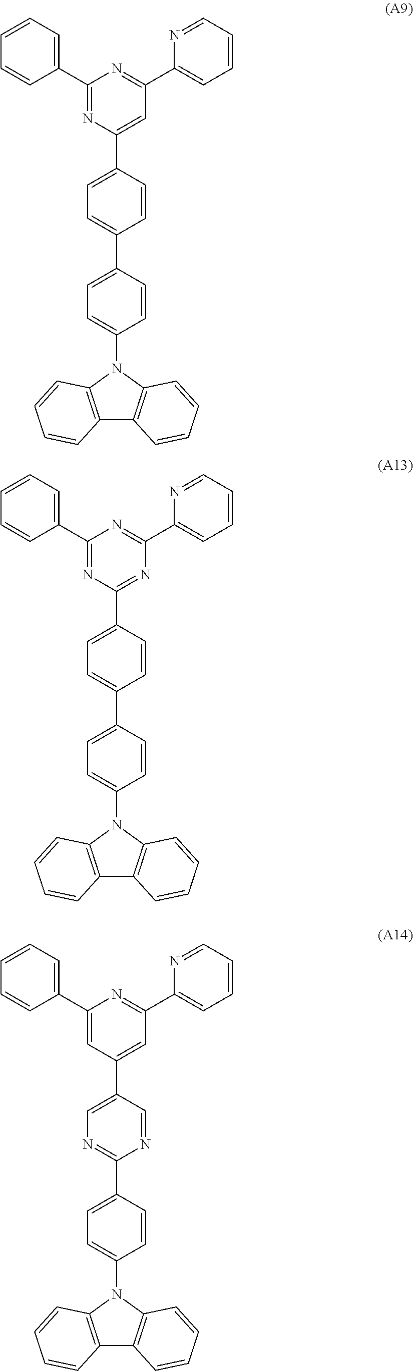

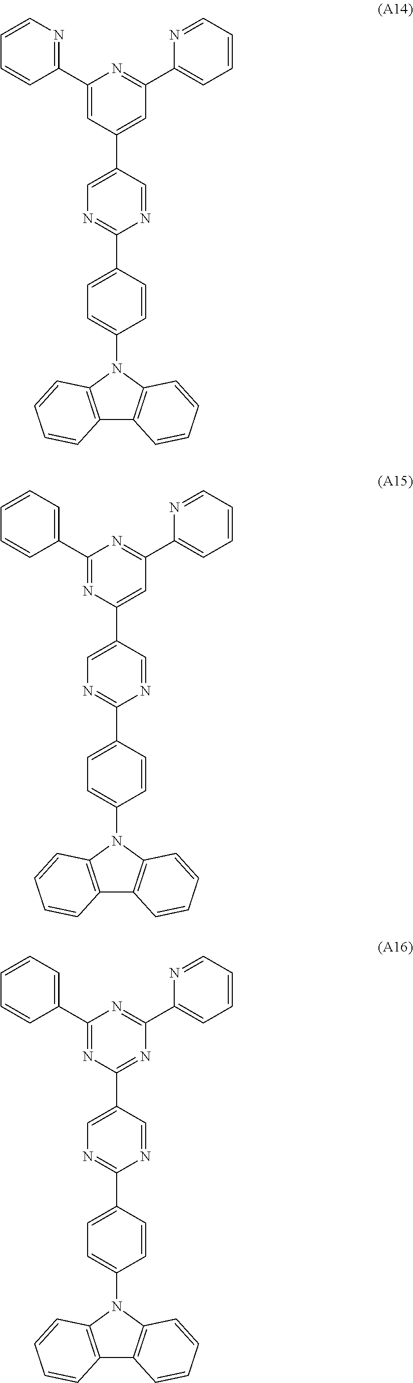 [SMILES: c1ccc(-c2cc(-c3cnc(-c4ccc(-n5c6ccccc6c6ccccc65)cc4)nc3)cc(-c3ccccn3)n2)nc1 ; c1ccc(-c2nc(-c3cnc(-c4ccc(-n5c6ccccc6c6ccccc65)cc4)nc3)cc(-c3ccccn3)n2)cc1 ; c1ccc(-c2nc(-c3cnc(-c4ccc(-n5c6ccccc6c6ccccc65)cc4)nc3)nc(-c3ccccn3)n2)cc1]

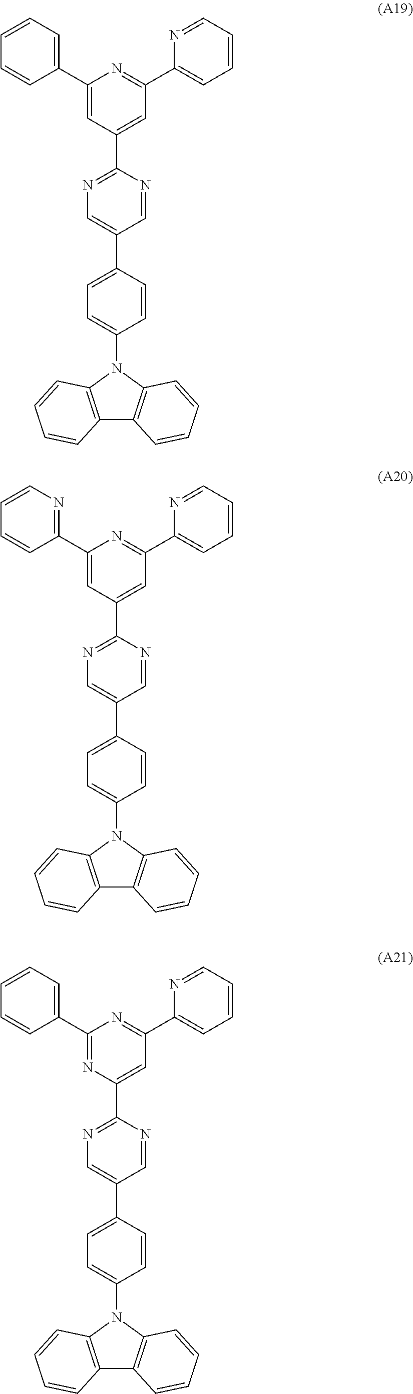 [SMILES: c1ccc(-c2cc(-c3ncc(-c4ccc(-n5c6ccccc6c6ccccc65)cc4)cn3)cc(-c3ccccn3)n2)cc1 ; c1ccc(-c2cc(-c3ncc(-c4ccc(-n5c6ccccc6c6ccccc65)cc4)cn3)cc(-c3ccccn3)n2)nc1 ; c1ccc(-c2nc(-c3ccccn3)cc(-c3ncc(-c4ccc(-n5c6ccccc6c6ccccc65)cc4)cn3)n2)cc1]

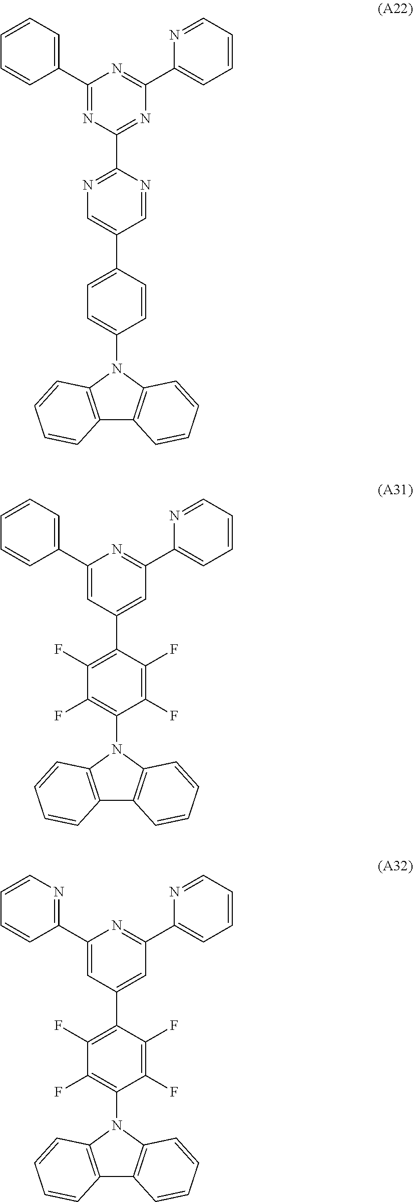 [SMILES: c1ccc(-c2nc(-c3ccccn3)nc(-c3ncc(-c4ccc(-n5c6ccccc6c6ccccc65)cc4)cn3)n2)cc1 ; Fc1c(F)c(-n2c3ccccc3c3ccccc32)c(F)c(F)c1-c1cc(-c2ccccc2)nc(-c2ccccn2)c1 ; Fc1c(F)c(-n2c3ccccc3c3ccccc32)c(F)c(F)c1-c1cc(-c2ccccn2)nc(-c2ccccn2)c1]

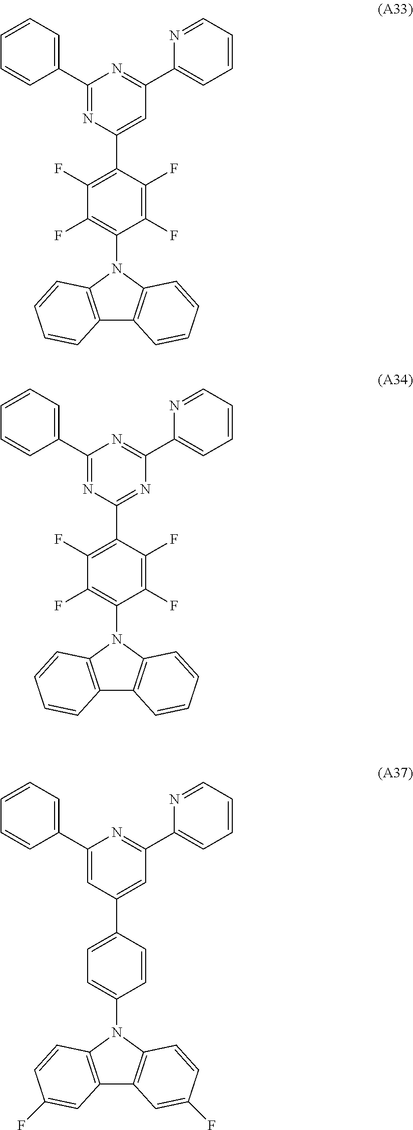 [SMILES: Fc1c(F)c(-n2c3ccccc3c3ccccc32)c(F)c(F)c1-c1cc(-c2ccccn2)nc(-c2ccccc2)n1 ; Fc1c(F)c(-n2c3ccccc3c3ccccc32)c(F)c(F)c1-c1nc(-c2ccccc2)nc(-c2ccccn2)n1 ; Fc1ccc2c(c1)c1cc(F)ccc1n2-c1ccc(-c2cc(-c3ccccc3)nc(-c3ccccn3)c2)cc1]

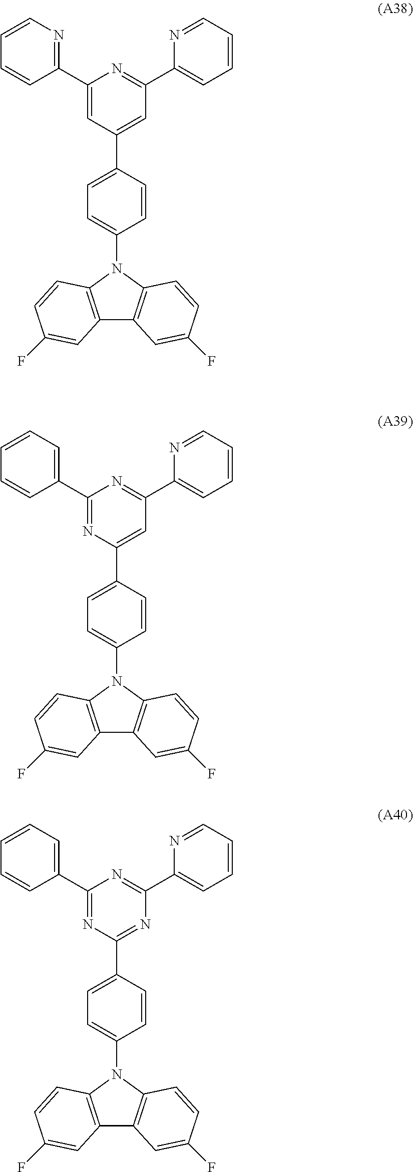 [SMILES: Fc1ccc2c(c1)c1cc(F)ccc1n2-c1ccc(-c2cc(-c3ccccn3)nc(-c3ccccn3)c2)cc1 ; Fc1ccc2c(c1)c1cc(F)ccc1n2-c1ccc(-c2cc(-c3ccccn3)nc(-c3ccccc3)n2)cc1 ; Fc1ccc2c(c1)c1cc(F)ccc1n2-c1ccc(-c2nc(-c3ccccc3)nc(-c3ccccn3)n2)cc1]

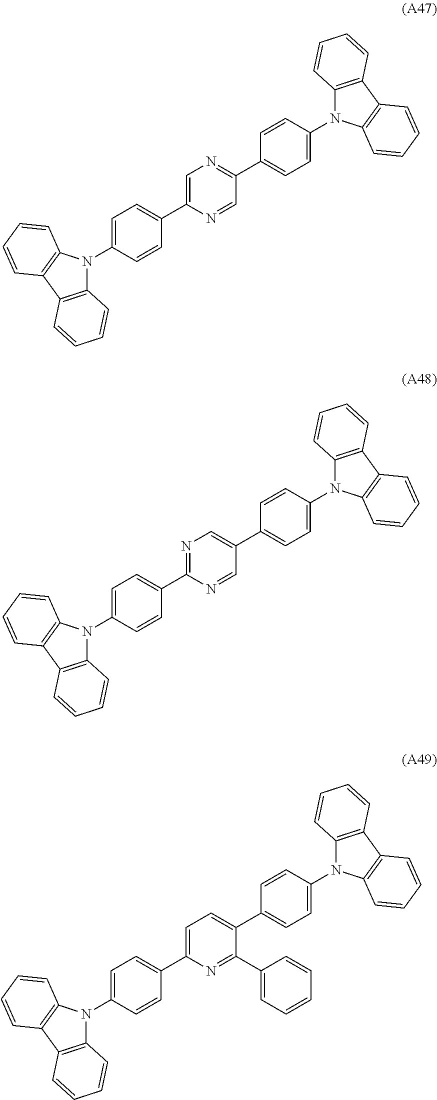 [SMILES: c1ccc2c(c1)c1ccccc1n2-c1ccc(-c2cnc(-c3ccc(-n4c5ccccc5c5ccccc54)cc3)cn2)cc1 ; c1ccc2c(c1)c1ccccc1n2-c1ccc(-c2cnc(-c3ccc(-n4c5ccccc5c5ccccc54)cc3)nc2)cc1 ; c1ccc(-c2nc(-c3ccc(-n4c5ccccc5c5ccccc54)cc3)ccc2-c2ccc(-n3c4ccccc4c4ccccc43)cc2)cc1]

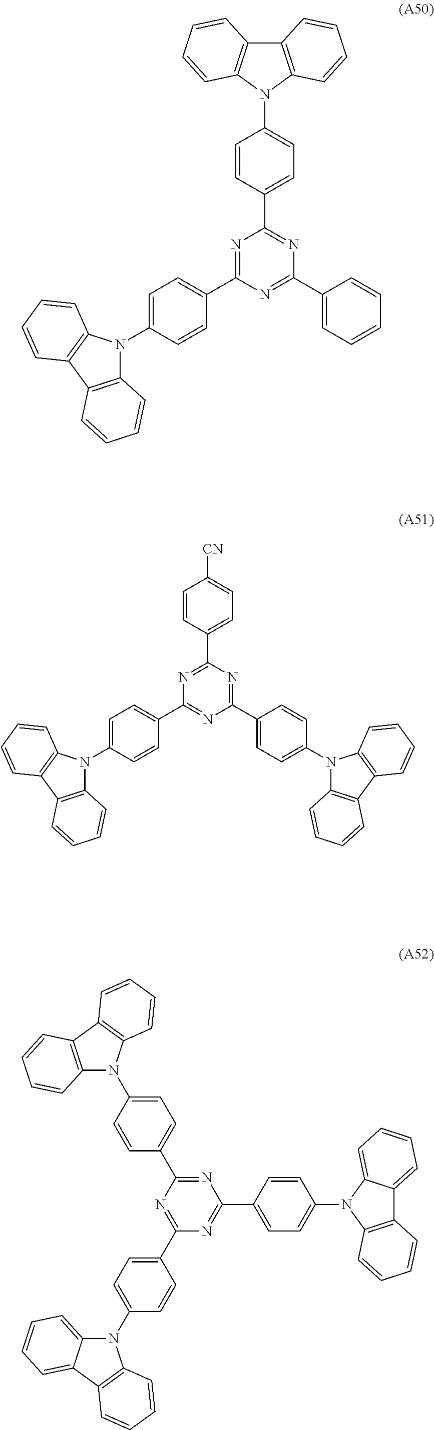 [SMILES: c1ccc(-c2nc(-c3ccc(-n4c5ccccc5c5ccccc54)cc3)nc(-c3ccc(-n4c5ccccc5c5ccccc54)cc3)n2)cc1 ; N#Cc1ccc(-c2nc(-c3ccc(-n4c5ccccc5c5ccccc54)cc3)nc(-c3ccc(-n4c5ccccc5c5ccccc54)cc3)n2)cc1 ; c1ccc2c(c1)c1ccccc1n2-c1ccc(-c2nc(-c3ccc(-n4c5ccccc5c5ccccc54)cc3)nc(-c3ccc(-n4c5ccccc5c5ccccc54)cc3)n2)cc1]

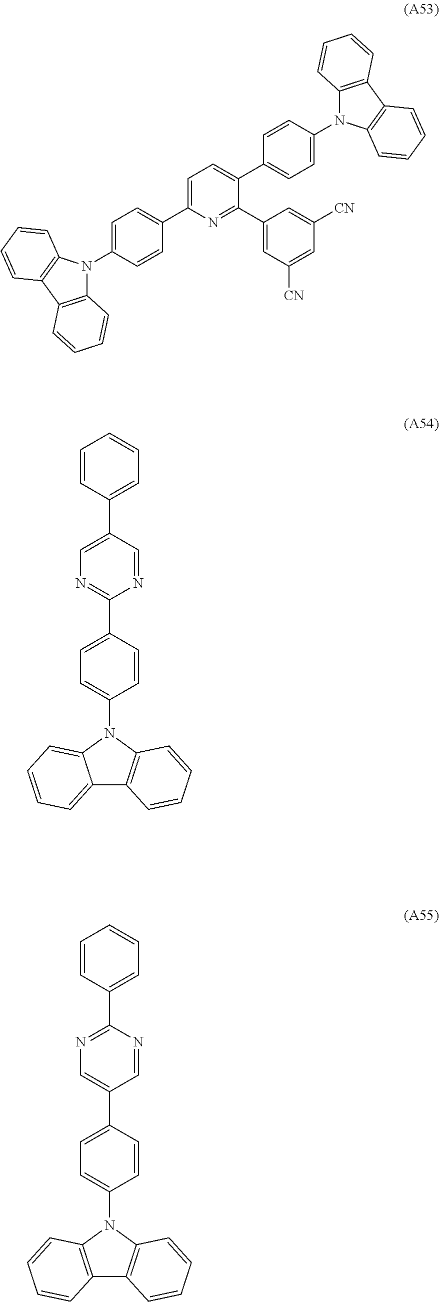 [SMILES: N#Cc1cc(C#N)cc(-c2nc(-c3ccc(-n4c5ccccc5c5ccccc54)cc3)ccc2-c2ccc(-n3c4ccccc4c4ccccc43)cc2)c1 ; c1ccc(-c2cnc(-c3ccc(-n4c5ccccc5c5ccccc54)cc3)nc2)cc1 ; c1ccc(-c2ncc(-c3ccc(-n4c5ccccc5c5ccccc54)cc3)cn2)cc1]

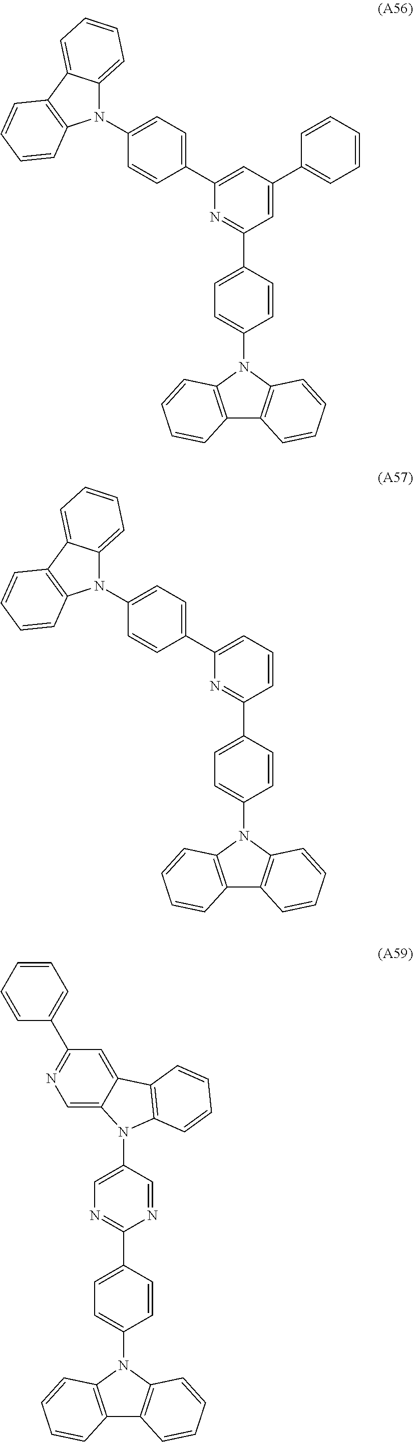 [SMILES: c1ccc(-c2cc(-c3ccc(-n4c5ccccc5c5ccccc54)cc3)nc(-c3ccc(-n4c5ccccc5c5ccccc54)cc3)c2)cc1 ; c1cc(-c2ccc(-n3c4ccccc4c4ccccc43)cc2)nc(-c2ccc(-n3c4ccccc4c4ccccc43)cc2)c1 ; c1ccc(-c2cc3c4ccccc4n(-c4cnc(-c5ccc(-n6c7ccccc7c7ccccc76)cc5)nc4)c3cn2)cc1]

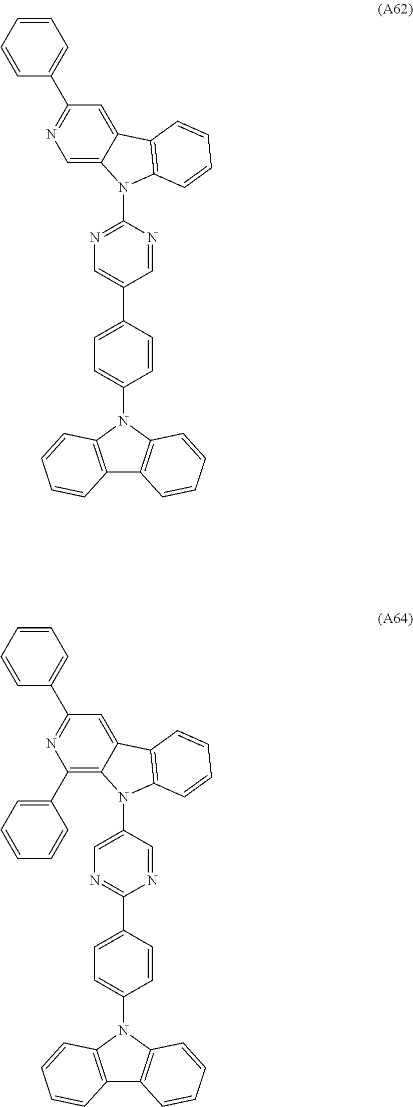 [SMILES: c1ccc(-c2cc3c4ccccc4n(-c4ncc(-c5ccc(-n6c7ccccc7c7ccccc76)cc5)cn4)c3cn2)cc1 ; c1ccc(-c2cc3c4ccccc4n(-c4cnc(-c5ccc(-n6c7ccccc7c7ccccc76)cc5)nc4)c3c(-c3ccccc3)n2)cc1]

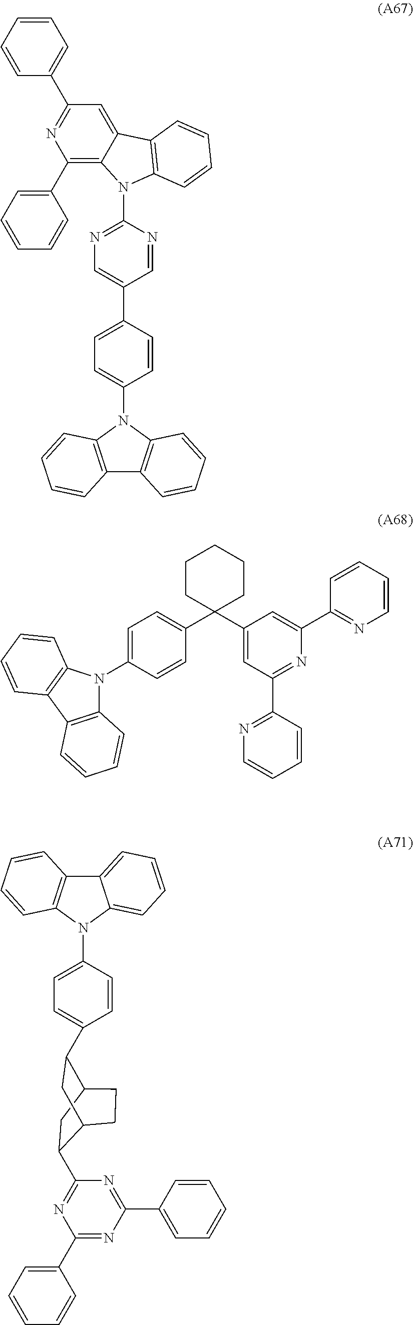 [SMILES: c1ccc(-c2cc3c4ccccc4n(-c4ncc(-c5ccc(-n6c7ccccc7c7ccccc76)cc5)cn4)c3c(-c3ccccc3)n2)cc1 ; c1ccc(-c2cc(C3(c4ccc(-n5c6ccccc6c6ccccc65)cc4)CCCCC3)cc(-c3ccccn3)n2)nc1 ; c1ccc(-c2nc(-c3ccccc3)nc(C3CC4CCC3CC4c3ccc(-n4c5ccccc5c5ccccc54)cc3)n2)cc1]

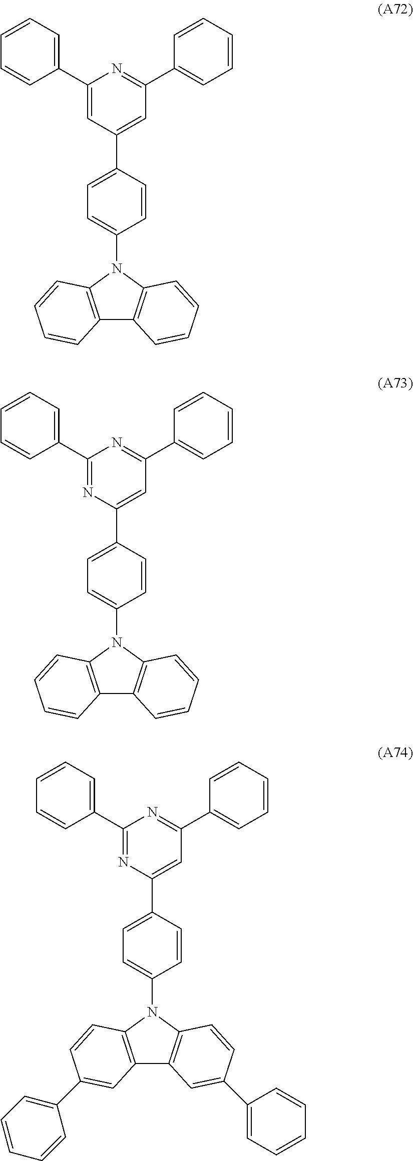

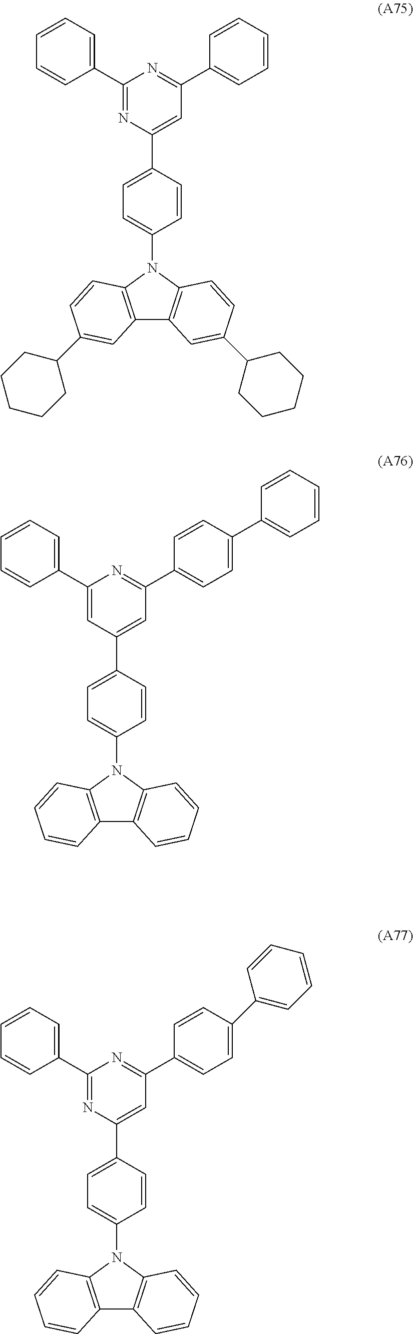 [SMILES: c1ccc(-c2cc(-c3ccc(-n4c5ccc(C6CCCCC6)cc5c5cc(C6CCCCC6)ccc54)cc3)nc(-c3ccccc3)n2)cc1 ; c1ccc(-c2ccc(-c3cc(-c4ccc(-n5c6ccccc6c6ccccc65)cc4)cc(-c4ccccc4)n3)cc2)cc1 ; c1ccc(-c2ccc(-c3cc(-c4ccc(-n5c6ccccc6c6ccccc65)cc4)nc(-c4ccccc4)n3)cc2)cc1]

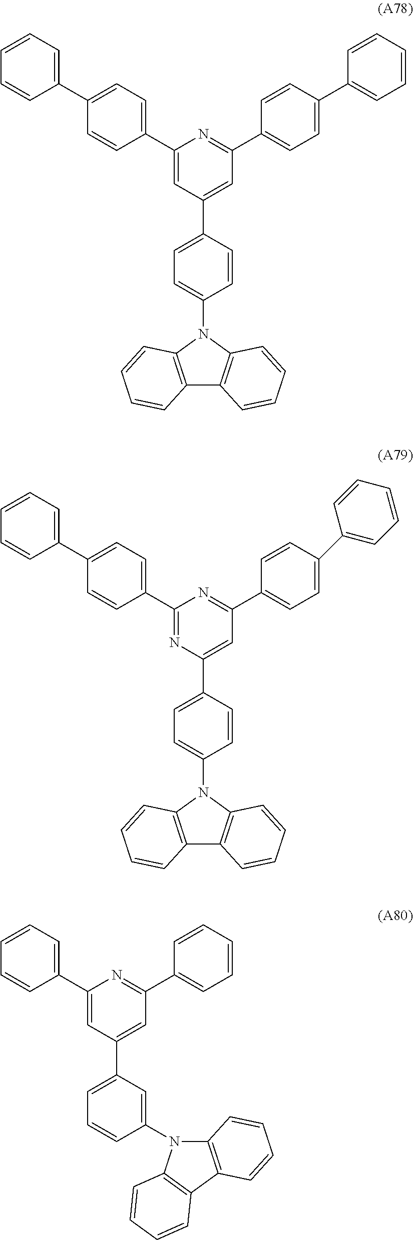 [SMILES: c1ccc(-c2ccc(-c3cc(-c4ccc(-n5c6ccccc6c6ccccc65)cc4)cc(-c4ccc(-c5ccccc5)cc4)n3)cc2)cc1 ; c1ccc(-c2ccc(-c3cc(-c4ccc(-n5c6ccccc6c6ccccc65)cc4)nc(-c4ccc(-c5ccccc5)cc4)n3)cc2)cc1 ; c1ccc(-c2cc(-c3cccc(-n4c5ccccc5c5ccccc54)c3)cc(-c3ccccc3)n2)cc1]

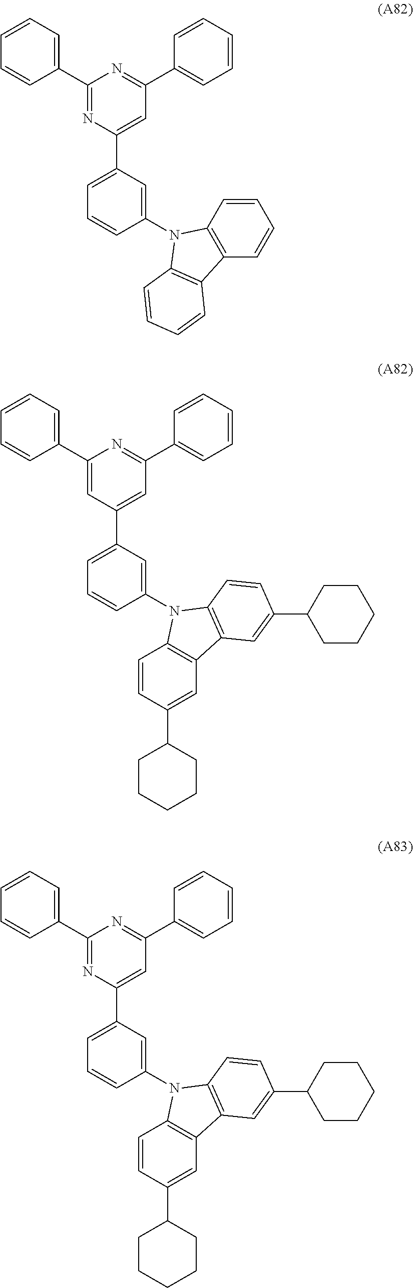 [SMILES: c1ccc(-c2cc(-c3cccc(-n4c5ccccc5c5ccccc54)c3)nc(-c3ccccc3)n2)cc1 ; c1ccc(-c2cc(-c3cccc(-n4c5ccc(C6CCCCC6)cc5c5cc(C6CCCCC6)ccc54)c3)cc(-c3ccccc3)n2)cc1 ; c1ccc(-c2cc(-c3cccc(-n4c5ccc(C6CCCCC6)cc5c5cc(C6CCCCC6)ccc54)c3)nc(-c3ccccc3)n2)cc1]

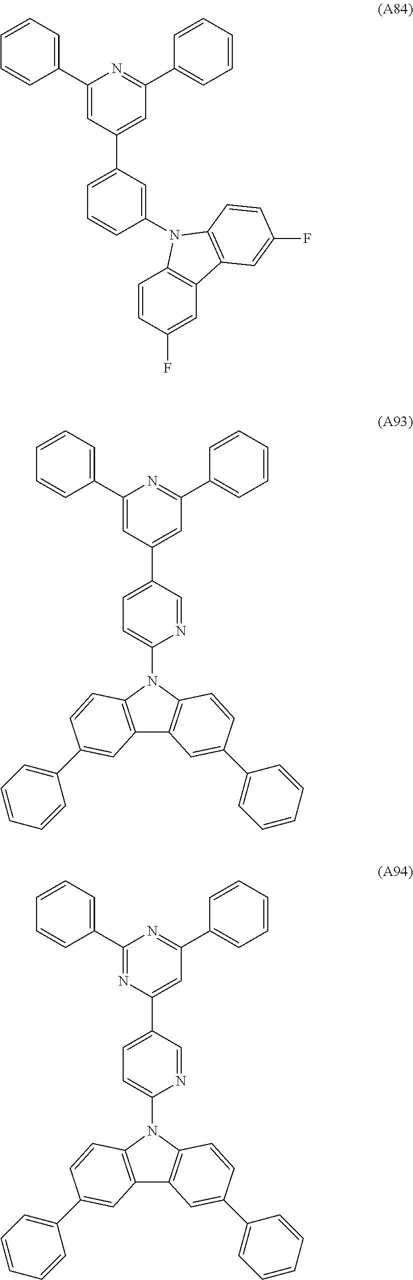 [SMILES: Fc1ccc2c(c1)c1cc(F)ccc1n2-c1cccc(-c2cc(-c3ccccc3)nc(-c3ccccc3)c2)c1 ; c1ccc(-c2ccc3c(c2)c2cc(-c4ccccc4)ccc2n3-c2ccc(-c3cc(-c4ccccc4)nc(-c4ccccc4)c3)cn2)cc1 ; c1ccc(-c2ccc3c(c2)c2cc(-c4ccccc4)ccc2n3-c2ccc(-c3cc(-c4ccccc4)nc(-c4ccccc4)n3)cn2)cc1]

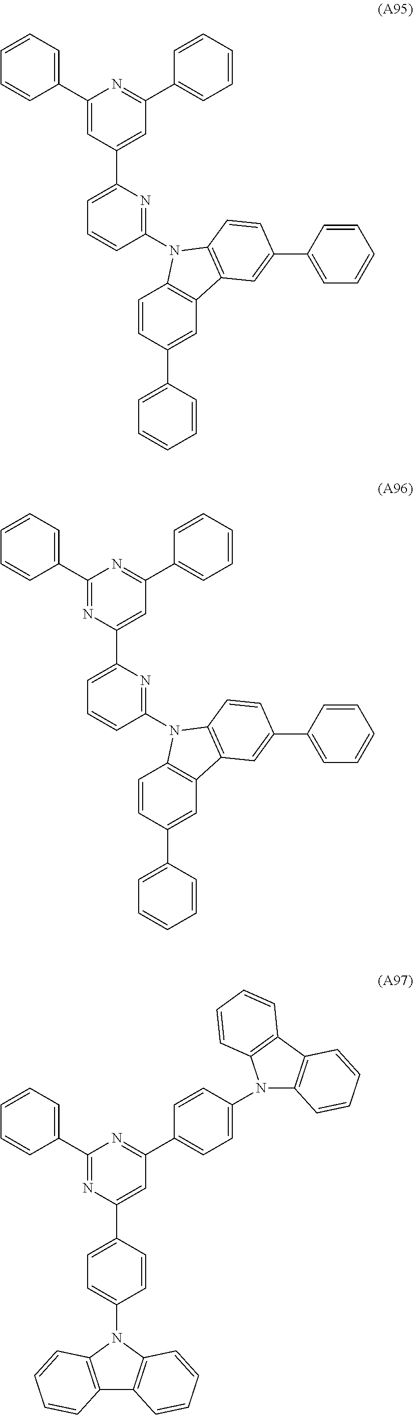 [SMILES: c1ccc(-c2ccc3c(c2)c2cc(-c4ccccc4)ccc2n3-c2cccc(-c3cc(-c4ccccc4)nc(-c4ccccc4)c3)n2)cc1 ; c1ccc(-c2ccc3c(c2)c2cc(-c4ccccc4)ccc2n3-c2cccc(-c3cc(-c4ccccc4)nc(-c4ccccc4)n3)n2)cc1 ; c1ccc(-c2nc(-c3ccc(-n4c5ccccc5c5ccccc54)cc3)cc(-c3ccc(-n4c5ccccc5c5ccccc54)cc3)n2)cc1]

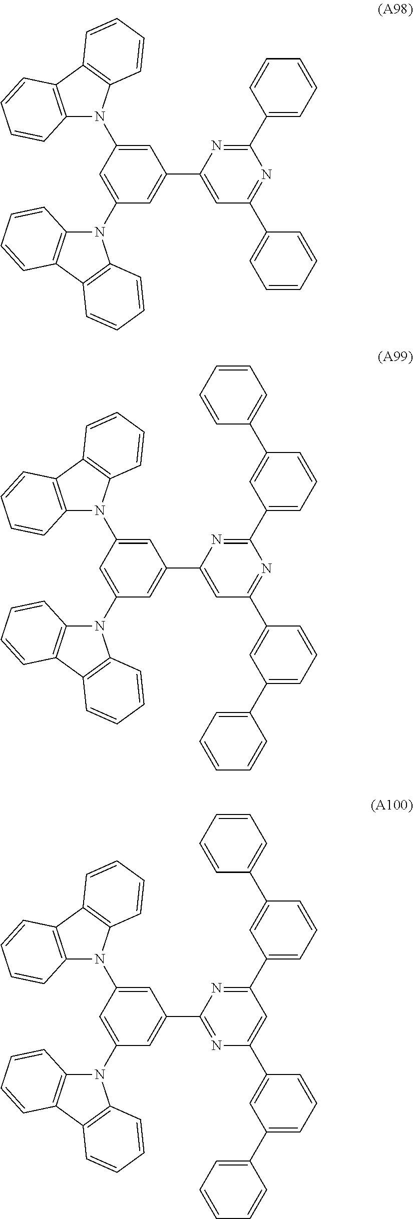

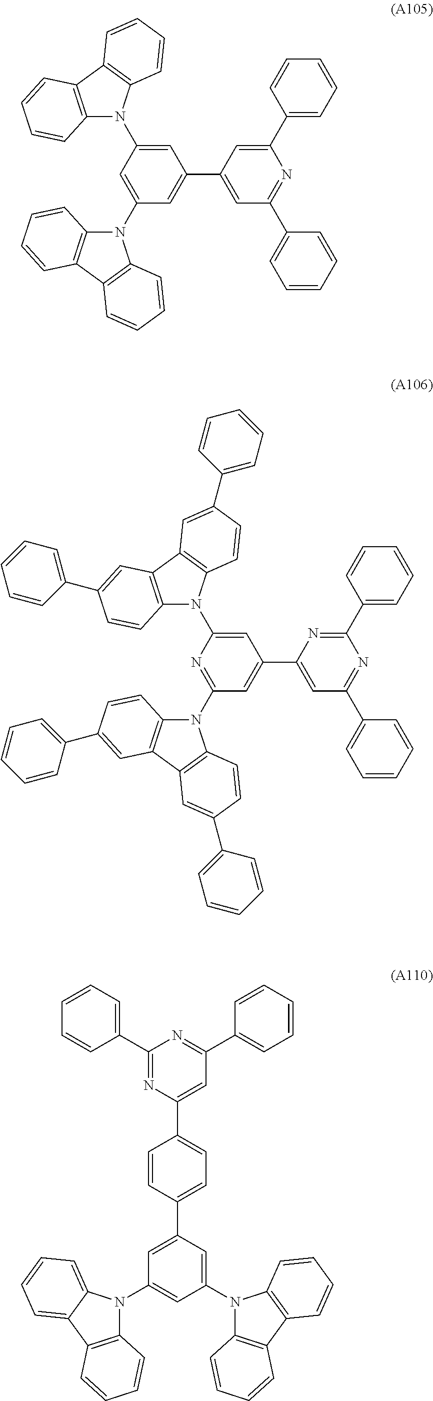 [SMILES: c1ccc(-c2cc(-c3cc(-n4c5ccccc5c5ccccc54)cc(-n4c5ccccc5c5ccccc54)c3)cc(-c3ccccc3)n2)cc1 ; c1ccc(-c2ccc3c(c2)c2cc(-c4ccccc4)ccc2n3-c2cc(-c3cc(-c4ccccc4)nc(-c4ccccc4)n3)cc(-n3c4ccc(-c5ccccc5)cc4c4cc(-c5ccccc5)ccc43)n2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1]

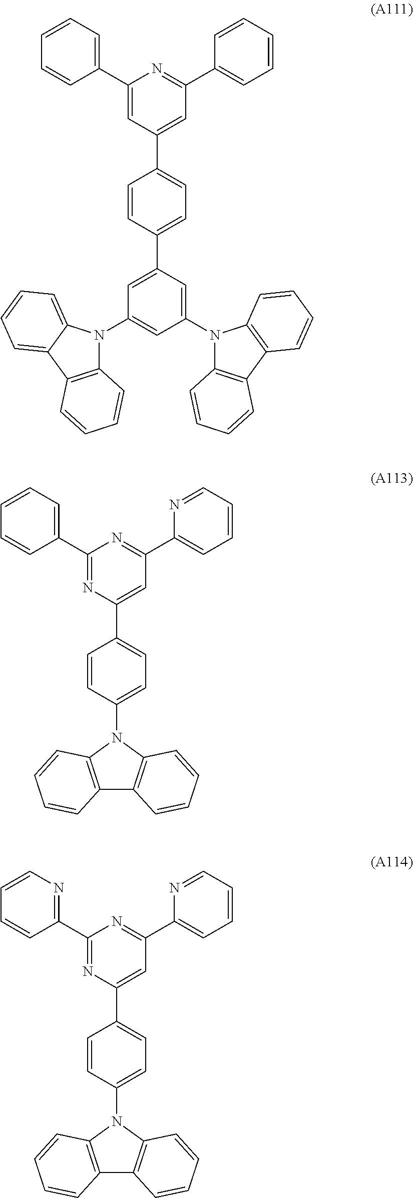 [SMILES: c1ccc(-c2cc(-c3ccc(-c4cc(-n5c6ccccc6c6ccccc65)cc(-n5c6ccccc6c6ccccc65)c4)cc3)cc(-c3ccccc3)n2)cc1 ; c1ccc(-c2nc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)nc(-c3ccccn3)n2)nc1]

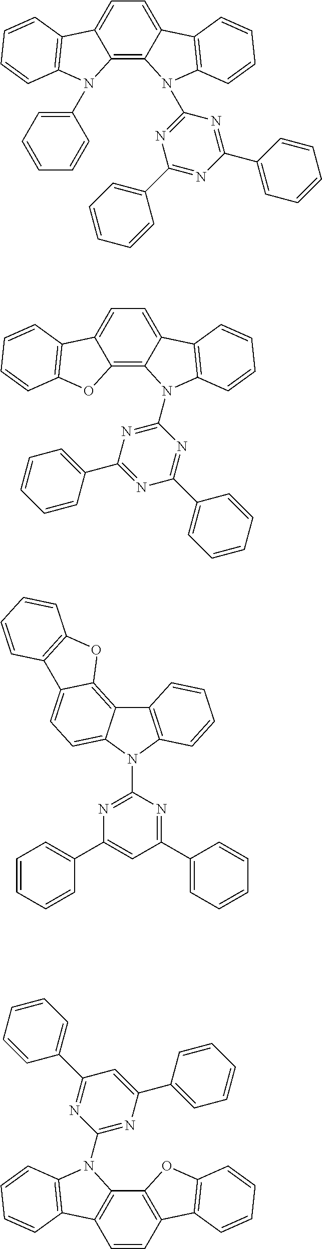 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6oc5c43)n2)cc1 ; c1ccc(-c2cc(-c3ccccc3)nc(-n3c4ccccc4c4c5oc6ccccc6c5ccc43)n2)cc1 ; c1ccc(-c2cc(-c3ccccc3)nc(-n3c4ccccc4c4ccc5c6ccccc6oc5c43)n2)cc1]

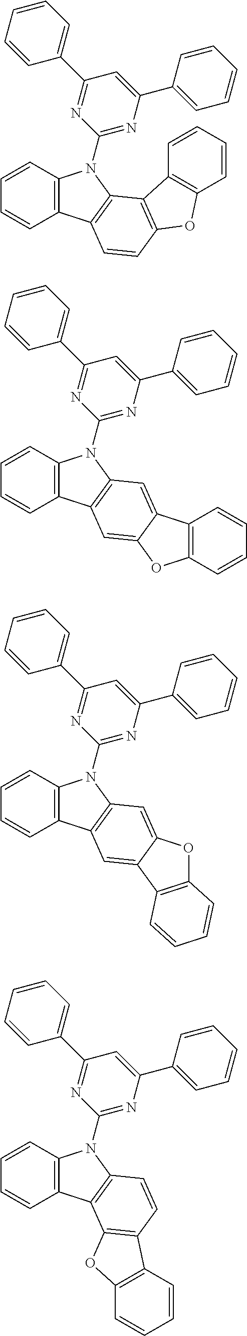 [SMILES: c1ccc(-c2cc(-c3ccccc3)nc(-n3c4ccccc4c4ccc5oc6ccccc6c5c43)n2)cc1 ; c1ccc(-c2cc(-c3ccccc3)nc(-n3c4ccccc4c4cc5oc6ccccc6c5cc43)n2)cc1 ; c1ccc(-c2cc(-c3ccccc3)nc(-n3c4ccccc4c4cc5c(cc43)oc3ccccc35)n2)cc1 ; c1ccc(-c2cc(-c3ccccc3)nc(-n3c4ccccc4c4c5oc6ccccc6c5ccc43)n2)cc1]

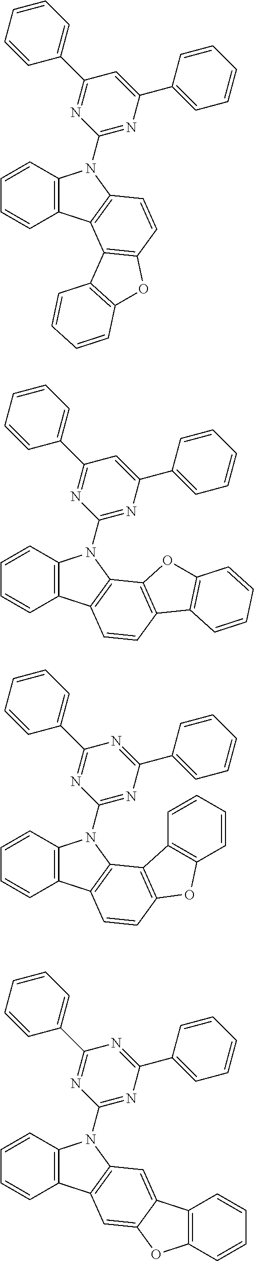 [SMILES: c1ccc(-c2cc(-c3ccccc3)nc(-n3c4ccccc4c4c5c(ccc43)oc3ccccc35)n2)cc1 ; c1ccc(-c2cc(-c3ccccc3)nc(-n3c4ccccc4c4ccc5c6ccccc6oc5c43)n2)cc1 ; c1ccc(-c2nc(-c3ccccc3)nc(-n3c4ccccc4c4ccc5oc6ccccc6c5c43)n2)cc1 ; c1ccc(-c2nc(-c3ccccc3)nc(-n3c4ccccc4c4cc5oc6ccccc6c5cc43)n2)cc1]

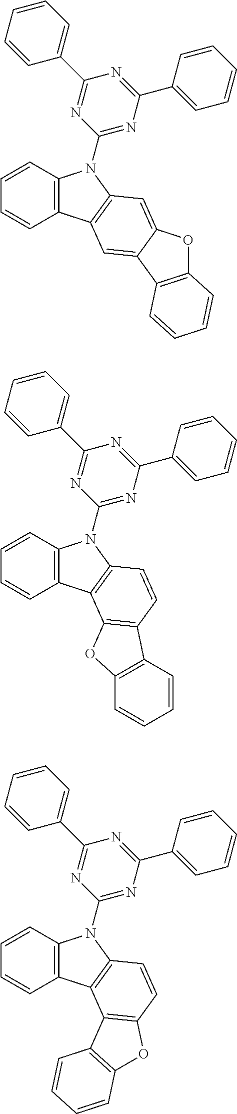 [SMILES: c1ccc(-c2nc(-c3ccccc3)nc(-n3c4ccccc4c4cc5c(cc43)oc3ccccc35)n2)cc1 ; c1ccc(-c2nc(-c3ccccc3)nc(-n3c4ccccc4c4c5oc6ccccc6c5ccc43)n2)cc1 ; c1ccc(-c2nc(-c3ccccc3)nc(-n3c4ccccc4c4c5c(ccc43)oc3ccccc35)n2)cc1]

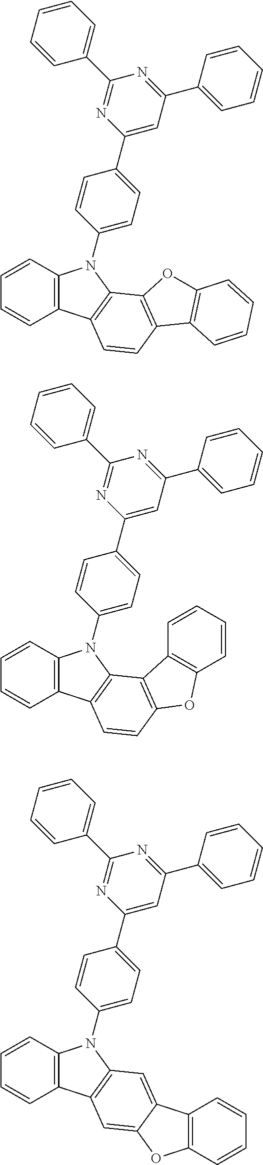 [SMILES: c1ccc(-c2cc(-c3ccc(-n4c5ccccc5c5ccc6c7ccccc7oc6c54)cc3)nc(-c3ccccc3)n2)cc1 ; c1ccc(-c2cc(-c3ccc(-n4c5ccccc5c5ccc6oc7ccccc7c6c54)cc3)nc(-c3ccccc3)n2)cc1 ; c1ccc(-c2cc(-c3ccc(-n4c5ccccc5c5cc6oc7ccccc7c6cc54)cc3)nc(-c3ccccc3)n2)cc1]

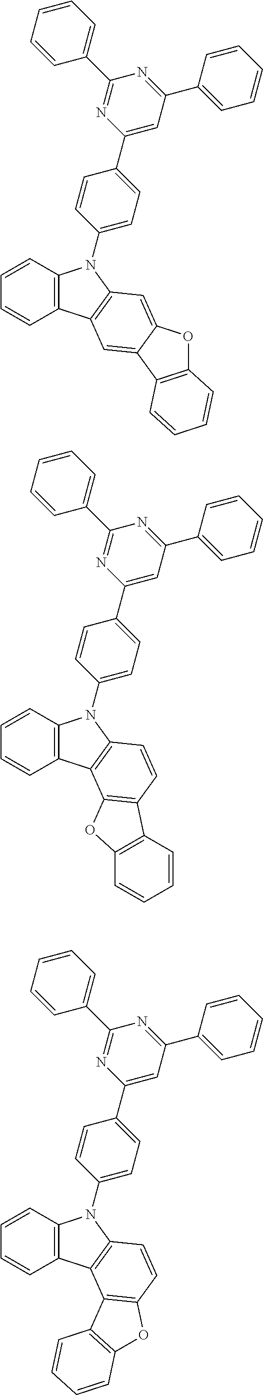 [SMILES: c1ccc(-c2cc(-c3ccc(-n4c5ccccc5c5cc6c(cc54)oc4ccccc46)cc3)nc(-c3ccccc3)n2)cc1 ; c1ccc(-c2cc(-c3ccc(-n4c5ccccc5c5c6oc7ccccc7c6ccc54)cc3)nc(-c3ccccc3)n2)cc1 ; c1ccc(-c2cc(-c3ccc(-n4c5ccccc5c5c6c(ccc54)oc4ccccc46)cc3)nc(-c3ccccc3)n2)cc1]

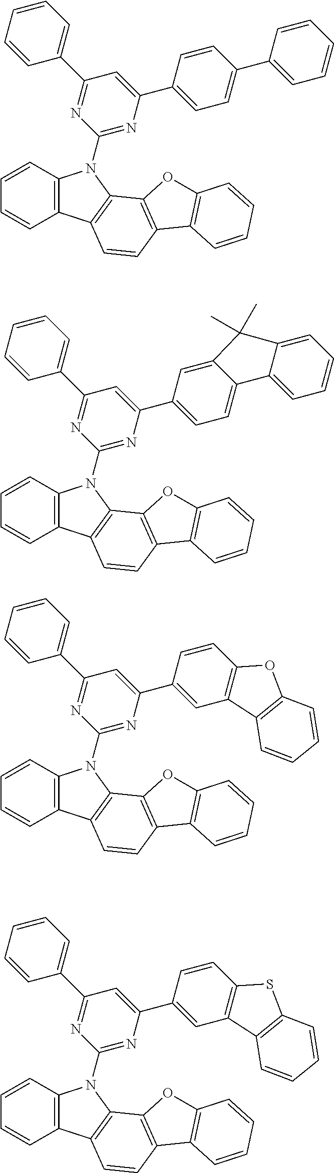 [SMILES: c1ccc(-c2ccc(-c3cc(-c4ccccc4)nc(-n4c5ccccc5c5ccc6c7ccccc7oc6c54)n3)cc2)cc1 ; CC1(C)c2ccccc2-c2ccc(-c3cc(-c4ccccc4)nc(-n4c5ccccc5c5ccc6c7ccccc7oc6c54)n3)cc21 ; c1ccc(-c2cc(-c3ccc4oc5ccccc5c4c3)nc(-n3c4ccccc4c4ccc5c6ccccc6oc5c43)n2)cc1 ; c1ccc(-c2cc(-c3ccc4sc5ccccc5c4c3)nc(-n3c4ccccc4c4ccc5c6ccccc6oc5c43)n2)cc1]

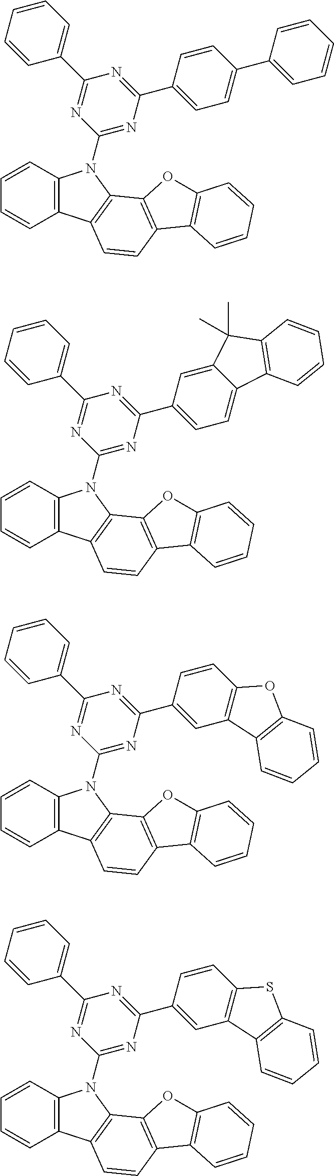 [SMILES: c1ccc(-c2ccc(-c3nc(-c4ccccc4)nc(-n4c5ccccc5c5ccc6c7ccccc7oc6c54)n3)cc2)cc1 ; CC1(C)c2ccccc2-c2ccc(-c3nc(-c4ccccc4)nc(-n4c5ccccc5c5ccc6c7ccccc7oc6c54)n3)cc21 ; c1ccc(-c2nc(-c3ccc4oc5ccccc5c4c3)nc(-n3c4ccccc4c4ccc5c6ccccc6oc5c43)n2)cc1 ; c1ccc(-c2nc(-c3ccc4sc5ccccc5c4c3)nc(-n3c4ccccc4c4ccc5c6ccccc6oc5c43)n2)cc1]

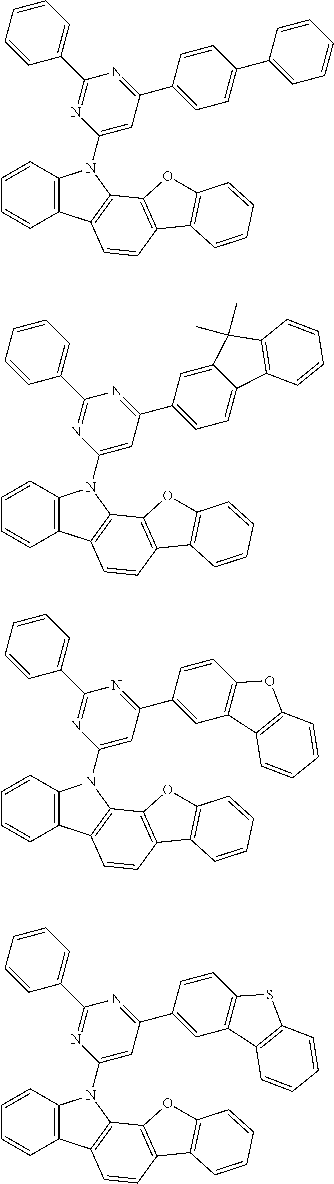 [SMILES: c1ccc(-c2ccc(-c3cc(-n4c5ccccc5c5ccc6c7ccccc7oc6c54)nc(-c4ccccc4)n3)cc2)cc1 ; CC1(C)c2ccccc2-c2ccc(-c3cc(-n4c5ccccc5c5ccc6c7ccccc7oc6c54)nc(-c4ccccc4)n3)cc21 ; c1ccc(-c2nc(-c3ccc4oc5ccccc5c4c3)cc(-n3c4ccccc4c4ccc5c6ccccc6oc5c43)n2)cc1 ; c1ccc(-c2nc(-c3ccc4sc5ccccc5c4c3)cc(-n3c4ccccc4c4ccc5c6ccccc6oc5c43)n2)cc1]

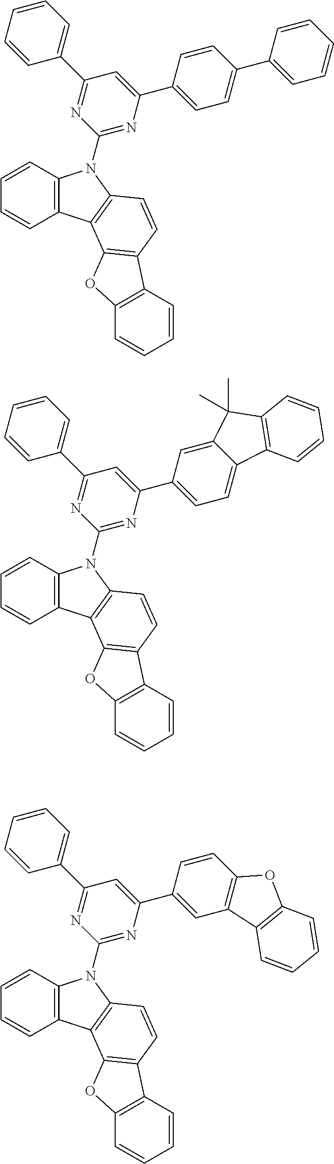 [SMILES: c1ccc(-c2ccc(-c3cc(-c4ccccc4)nc(-n4c5ccccc5c5c6oc7ccccc7c6ccc54)n3)cc2)cc1 ; CC1(C)c2ccccc2-c2ccc(-c3cc(-c4ccccc4)nc(-n4c5ccccc5c5c6oc7ccccc7c6ccc54)n3)cc21 ; c1ccc(-c2cc(-c3ccc4oc5ccccc5c4c3)nc(-n3c4ccccc4c4c5oc6ccccc6c5ccc43)n2)cc1]

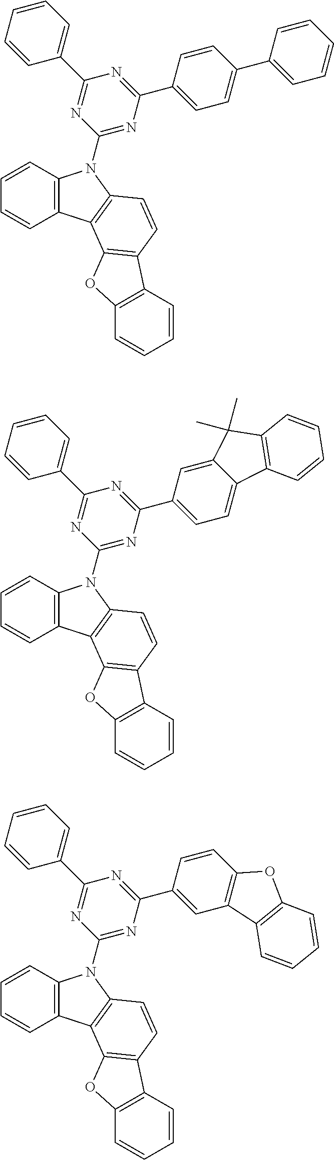 [SMILES: c1ccc(-c2ccc(-c3nc(-c4ccccc4)nc(-n4c5ccccc5c5c6oc7ccccc7c6ccc54)n3)cc2)cc1 ; CC1(C)c2ccccc2-c2ccc(-c3nc(-c4ccccc4)nc(-n4c5ccccc5c5c6oc7ccccc7c6ccc54)n3)cc21 ; c1ccc(-c2nc(-c3ccc4oc5ccccc5c4c3)nc(-n3c4ccccc4c4c5oc6ccccc6c5ccc43)n2)cc1]

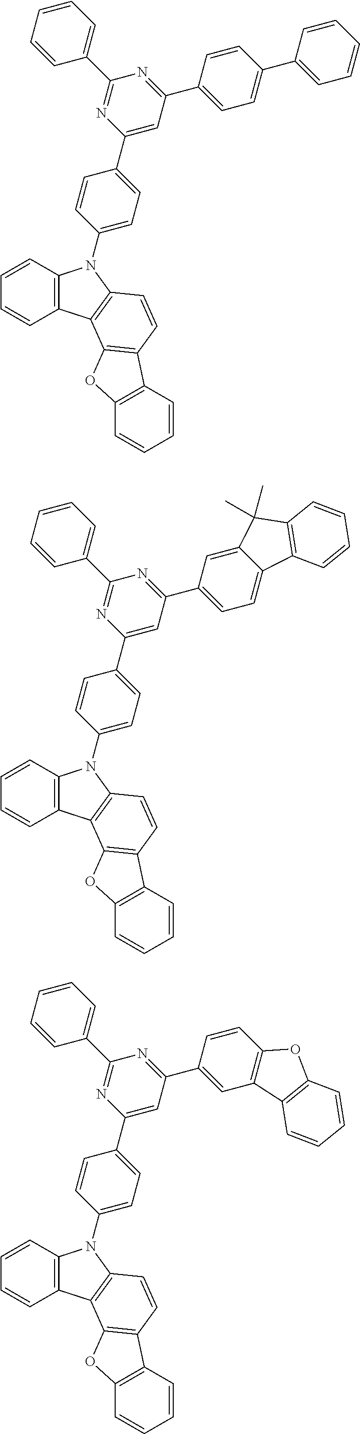 [SMILES: c1ccc(-c2ccc(-c3cc(-c4ccc(-n5c6ccccc6c6c7oc8ccccc8c7ccc65)cc4)nc(-c4ccccc4)n3)cc2)cc1 ; CC1(C)c2ccccc2-c2ccc(-c3cc(-c4ccc(-n5c6ccccc6c6c7oc8ccccc8c7ccc65)cc4)nc(-c4ccccc4)n3)cc21 ; c1ccc(-c2nc(-c3ccc(-n4c5ccccc5c5c6oc7ccccc7c6ccc54)cc3)cc(-c3ccc4oc5ccccc5c4c3)n2)cc1]

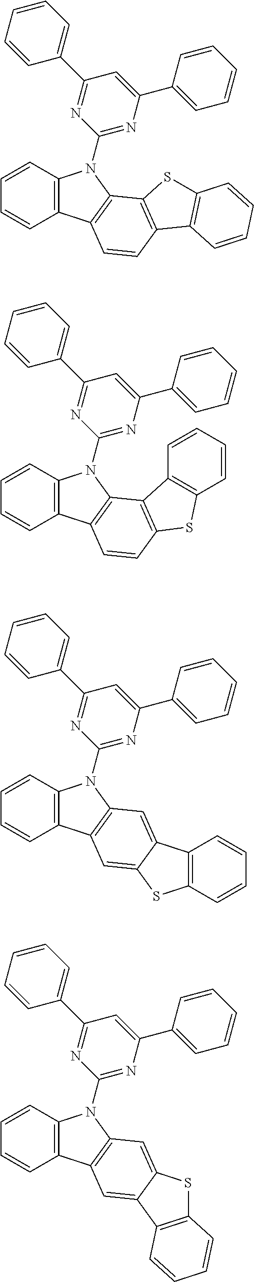 [SMILES: c1ccc(-c2cc(-c3ccccc3)nc(-n3c4ccccc4c4ccc5c6ccccc6sc5c43)n2)cc1 ; c1ccc(-c2cc(-c3ccccc3)nc(-n3c4ccccc4c4ccc5sc6ccccc6c5c43)n2)cc1 ; c1ccc(-c2cc(-c3ccccc3)nc(-n3c4ccccc4c4cc5sc6ccccc6c5cc43)n2)cc1 ; c1ccc(-c2cc(-c3ccccc3)nc(-n3c4ccccc4c4cc5c(cc43)sc3ccccc35)n2)cc1]

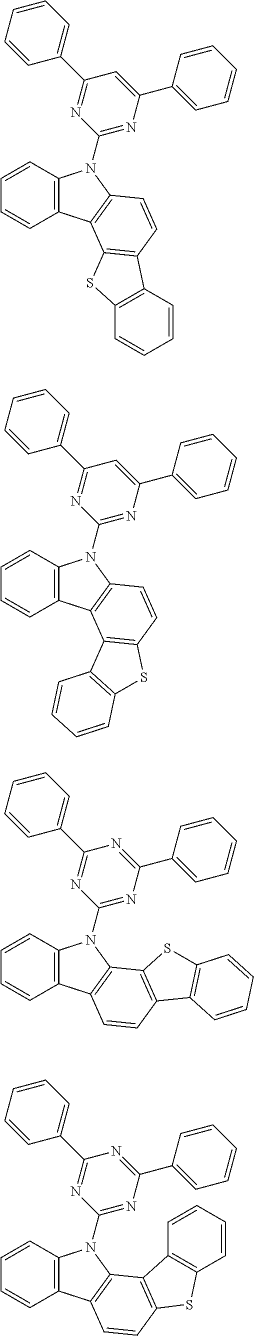 [SMILES: c1ccc(-c2cc(-c3ccccc3)nc(-n3c4ccccc4c4c5sc6ccccc6c5ccc43)n2)cc1 ; c1ccc(-c2cc(-c3ccccc3)nc(-n3c4ccccc4c4c5c(ccc43)sc3ccccc35)n2)cc1 ; c1ccc(-c2nc(-c3ccccc3)nc(-n3c4ccccc4c4ccc5c6ccccc6sc5c43)n2)cc1 ; c1ccc(-c2nc(-c3ccccc3)nc(-n3c4ccccc4c4ccc5sc6ccccc6c5c43)n2)cc1]

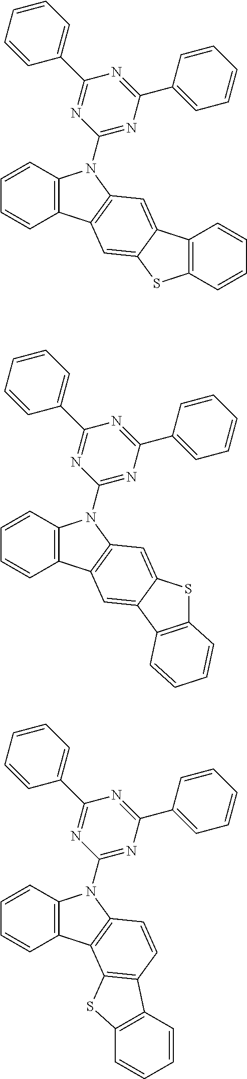 [SMILES: c1ccc(-c2nc(-c3ccccc3)nc(-n3c4ccccc4c4cc5sc6ccccc6c5cc43)n2)cc1 ; c1ccc(-c2nc(-c3ccccc3)nc(-n3c4ccccc4c4cc5c(cc43)sc3ccccc35)n2)cc1 ; c1ccc(-c2nc(-c3ccccc3)nc(-n3c4ccccc4c4c5sc6ccccc6c5ccc43)n2)cc1]

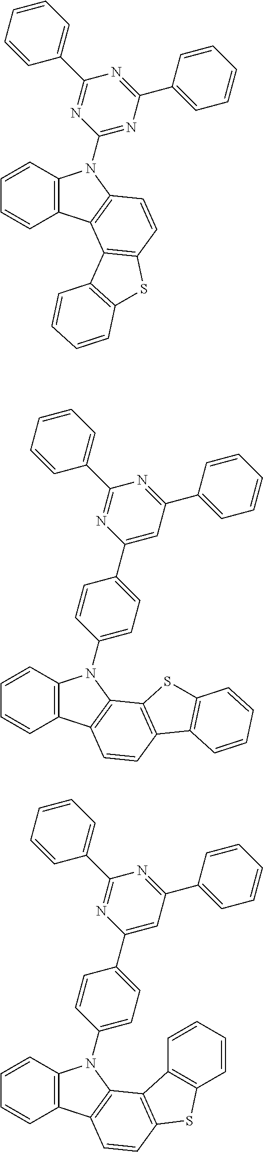 [SMILES: c1ccc(-c2nc(-c3ccccc3)nc(-n3c4ccccc4c4c5c(ccc43)sc3ccccc35)n2)cc1 ; c1ccc(-c2cc(-c3ccc(-n4c5ccccc5c5ccc6c7ccccc7sc6c54)cc3)nc(-c3ccccc3)n2)cc1 ; c1ccc(-c2cc(-c3ccc(-n4c5ccccc5c5ccc6sc7ccccc7c6c54)cc3)nc(-c3ccccc3)n2)cc1]

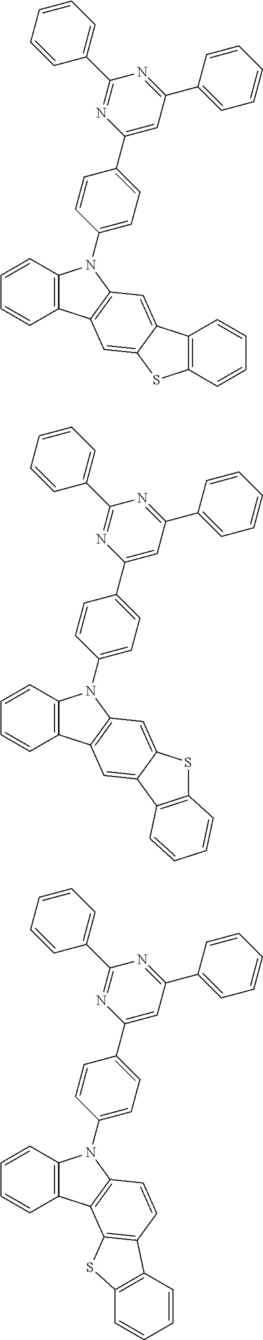 [SMILES: c1ccc(-c2cc(-c3ccc(-n4c5ccccc5c5cc6sc7ccccc7c6cc54)cc3)nc(-c3ccccc3)n2)cc1 ; c1ccc(-c2cc(-c3ccc(-n4c5ccccc5c5cc6c(cc54)sc4ccccc46)cc3)nc(-c3ccccc3)n2)cc1 ; c1ccc(-c2cc(-c3ccc(-n4c5ccccc5c5c6sc7ccccc7c6ccc54)cc3)nc(-c3ccccc3)n2)cc1]

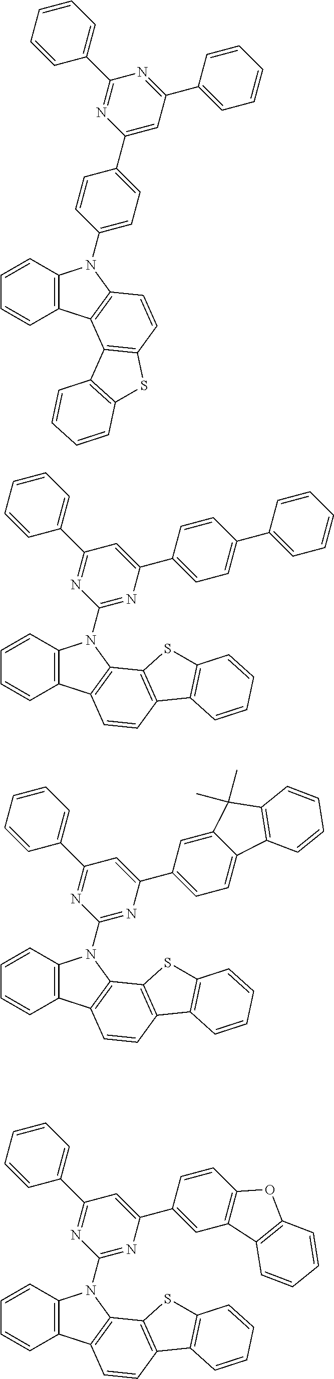

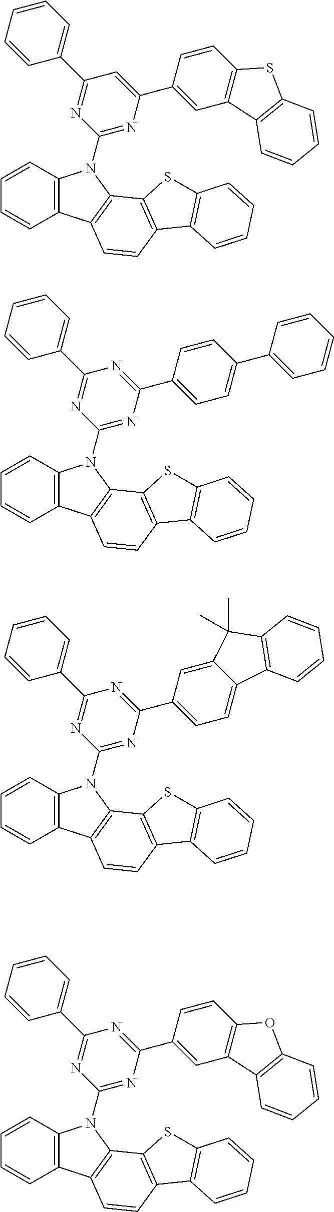 [SMILES: c1ccc(-c2cc(-c3ccc4sc5ccccc5c4c3)nc(-n3c4ccccc4c4ccc5c6ccccc6sc5c43)n2)cc1 ; c1ccc(-c2ccc(-c3nc(-c4ccccc4)nc(-n4c5ccccc5c5ccc6c7ccccc7sc6c54)n3)cc2)cc1 ; CC1(C)c2ccccc2-c2ccc(-c3nc(-c4ccccc4)nc(-n4c5ccccc5c5ccc6c7ccccc7sc6c54)n3)cc21 ; c1ccc(-c2nc(-c3ccc4oc5ccccc5c4c3)nc(-n3c4ccccc4c4ccc5c6ccccc6sc5c43)n2)cc1]

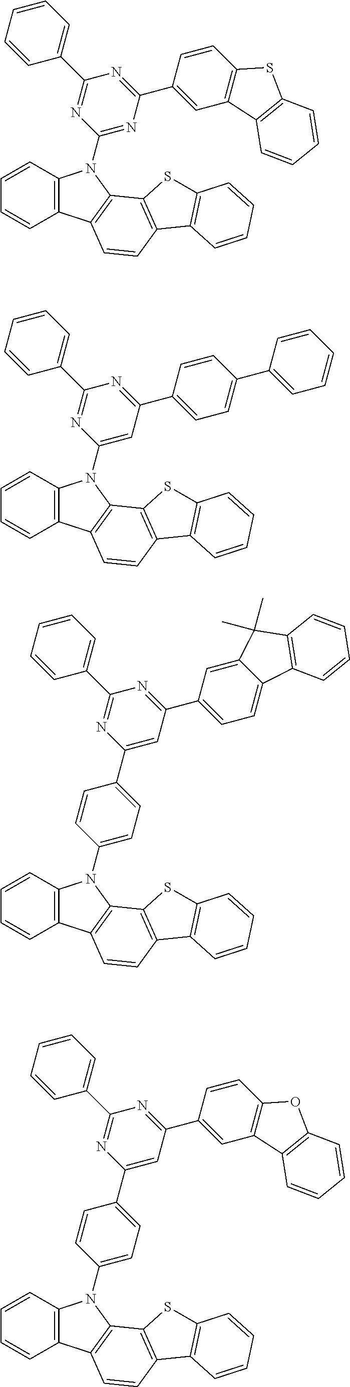 [SMILES: c1ccc(-c2nc(-c3ccc4sc5ccccc5c4c3)nc(-n3c4ccccc4c4ccc5c6ccccc6sc5c43)n2)cc1 ; c1ccc(-c2ccc(-c3cc(-n4c5ccccc5c5ccc6c7ccccc7sc6c54)nc(-c4ccccc4)n3)cc2)cc1 ; CC1(C)c2ccccc2-c2ccc(-c3cc(-c4ccc(-n5c6ccccc6c6ccc7c8ccccc8sc7c65)cc4)nc(-c4ccccc4)n3)cc21 ; c1ccc(-c2nc(-c3ccc(-n4c5ccccc5c5ccc6c7ccccc7sc6c54)cc3)cc(-c3ccc4oc5ccccc5c4c3)n2)cc1]

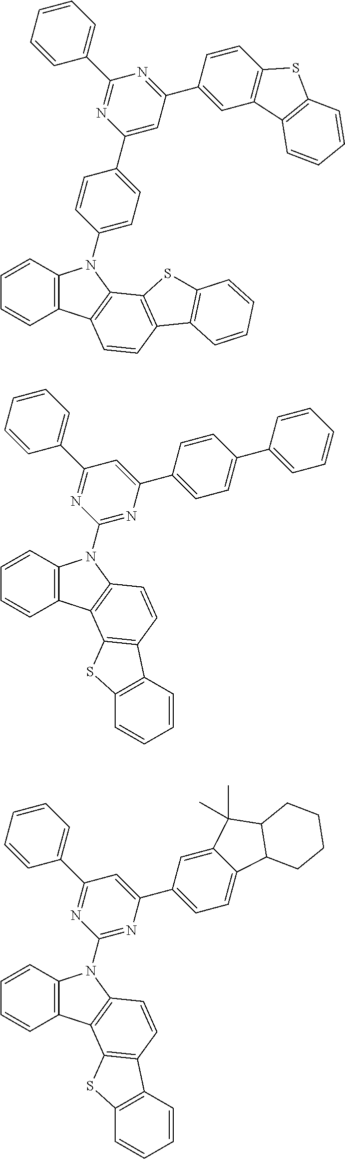 [SMILES: c1ccc(-c2nc(-c3ccc(-n4c5ccccc5c5ccc6c7ccccc7sc6c54)cc3)cc(-c3ccc4sc5ccccc5c4c3)n2)cc1 ; c1ccc(-c2ccc(-c3cc(-c4ccccc4)nc(-n4c5ccccc5c5c6sc7ccccc7c6ccc54)n3)cc2)cc1 ; CC1(C)c2cc(-c3cc(-c4ccccc4)nc(-n4c5ccccc5c5c6sc7ccccc7c6ccc54)n3)ccc2C2CCCCC21]

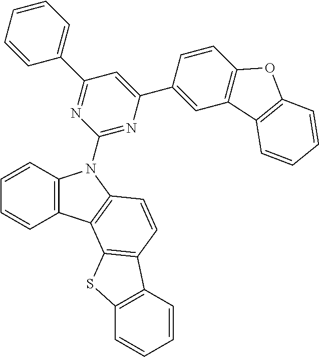 [SMILES: c1ccc(-c2cc(-c3ccc4oc5ccccc5c4c3)nc(-n3c4ccccc4c4c5sc6ccccc6c5ccc43)n2)cc1]

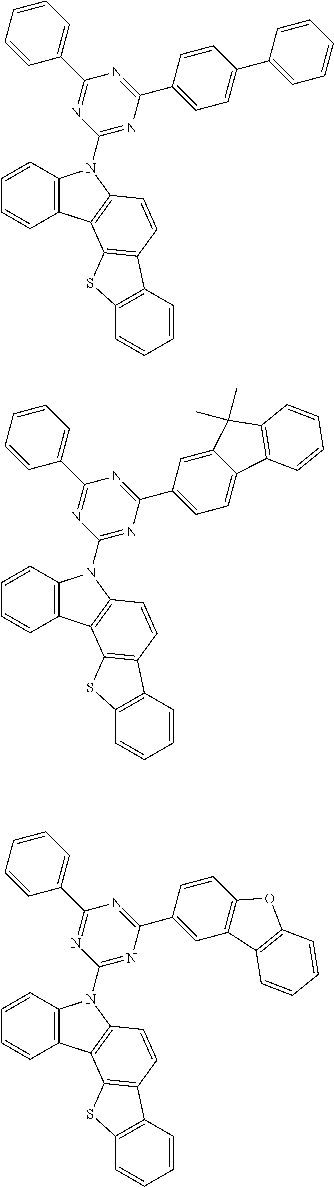 [SMILES: c1ccc(-c2ccc(-c3nc(-c4ccccc4)nc(-n4c5ccccc5c5c6sc7ccccc7c6ccc54)n3)cc2)cc1 ; CC1(C)c2ccccc2-c2ccc(-c3nc(-c4ccccc4)nc(-n4c5ccccc5c5c6sc7ccccc7c6ccc54)n3)cc21 ; c1ccc(-c2nc(-c3ccc4oc5ccccc5c4c3)nc(-n3c4ccccc4c4c5sc6ccccc6c5ccc43)n2)cc1]

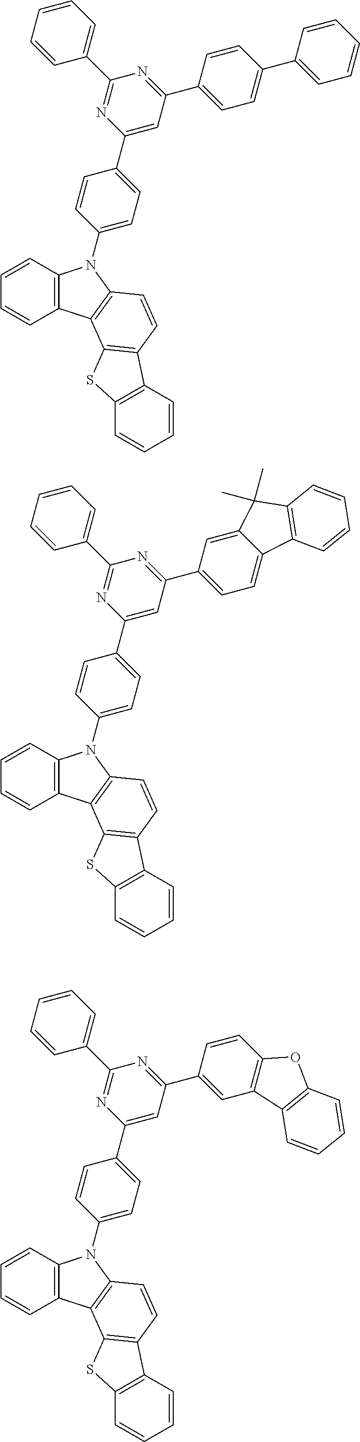 [SMILES: c1ccc(-c2ccc(-c3cc(-c4ccc(-n5c6ccccc6c6c7sc8ccccc8c7ccc65)cc4)nc(-c4ccccc4)n3)cc2)cc1 ; CC1(C)c2ccccc2-c2ccc(-c3cc(-c4ccc(-n5c6ccccc6c6c7sc8ccccc8c7ccc65)cc4)nc(-c4ccccc4)n3)cc21 ; c1ccc(-c2nc(-c3ccc(-n4c5ccccc5c5c6sc7ccccc7c6ccc54)cc3)cc(-c3ccc4oc5ccccc5c4c3)n2)cc1]

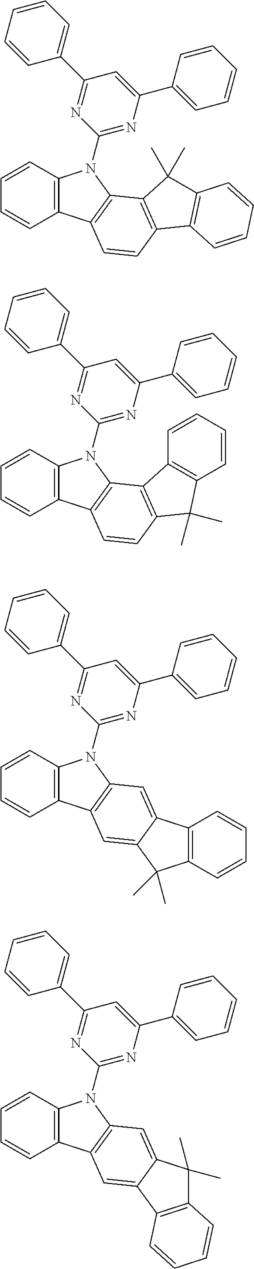 [SMILES: CC1(C)c2ccccc2-c2ccc3c4ccccc4n(-c4nc(-c5ccccc5)cc(-c5ccccc5)n4)c3c21 ; CC1(C)c2ccccc2-c2c1ccc1c3ccccc3n(-c3nc(-c4ccccc4)cc(-c4ccccc4)n3)c21 ; CC1(C)c2ccccc2-c2cc3c(cc21)c1ccccc1n3-c1nc(-c2ccccc2)cc(-c2ccccc2)n1 ; CC1(C)c2ccccc2-c2cc3c4ccccc4n(-c4nc(-c5ccccc5)cc(-c5ccccc5)n4)c3cc21]

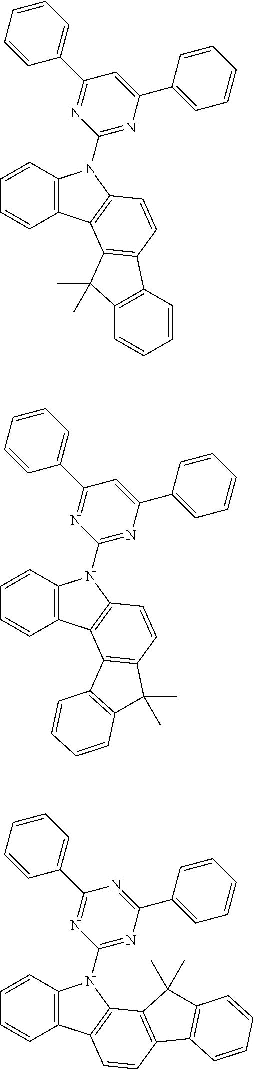 [SMILES: CC1(C)c2ccccc2-c2ccc3c(c21)c1ccccc1n3-c1nc(-c2ccccc2)cc(-c2ccccc2)n1 ; CC1(C)c2ccccc2-c2c1ccc1c2c2ccccc2n1-c1nc(-c2ccccc2)cc(-c2ccccc2)n1 ; CC1(C)c2ccccc2-c2ccc3c4ccccc4n(-c4nc(-c5ccccc5)nc(-c5ccccc5)n4)c3c21]

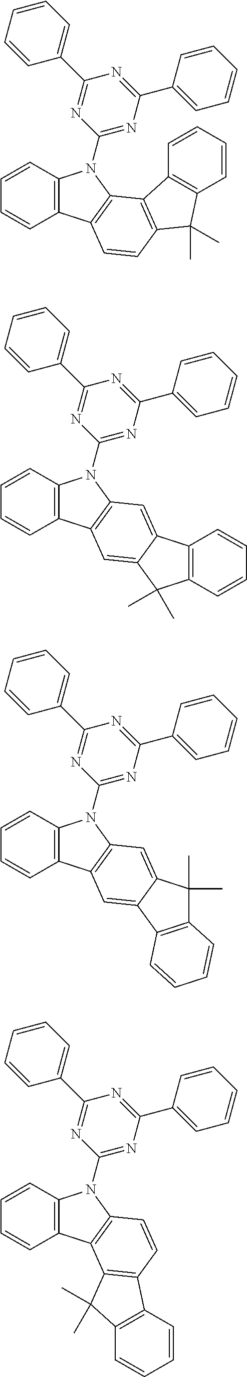 [SMILES: CC1(C)c2ccccc2-c2c1ccc1c3ccccc3n(-c3nc(-c4ccccc4)nc(-c4ccccc4)n3)c21 ; CC1(C)c2ccccc2-c2cc3c(cc21)c1ccccc1n3-c1nc(-c2ccccc2)nc(-c2ccccc2)n1 ; CC1(C)c2ccccc2-c2cc3c4ccccc4n(-c4nc(-c5ccccc5)nc(-c5ccccc5)n4)c3cc21 ; CC1(C)c2ccccc2-c2ccc3c(c21)c1ccccc1n3-c1nc(-c2ccccc2)nc(-c2ccccc2)n1]

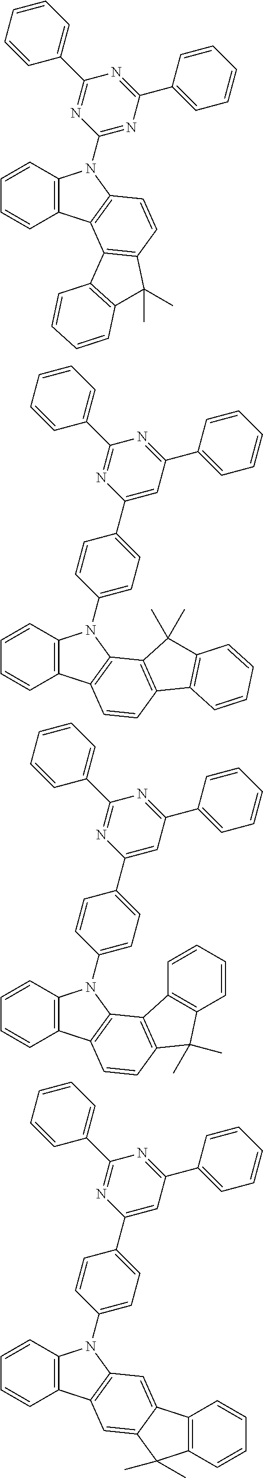

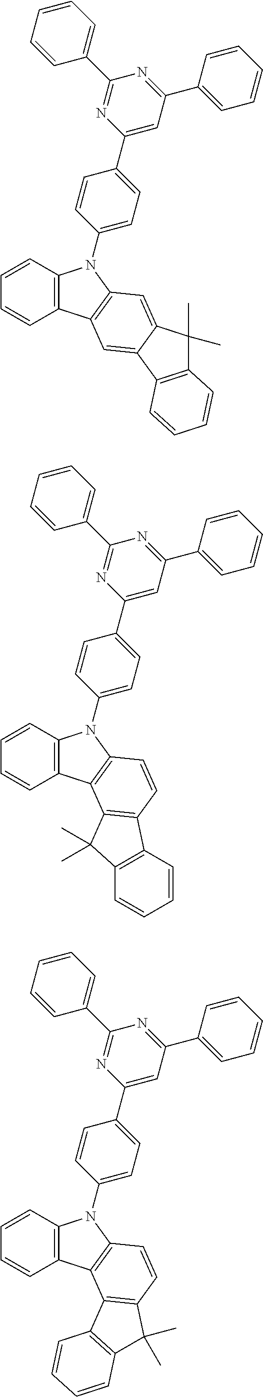 [SMILES: CC1(C)c2ccccc2-c2cc3c4ccccc4n(-c4ccc(-c5cc(-c6ccccc6)nc(-c6ccccc6)n5)cc4)c3cc21 ; CC1(C)c2ccccc2-c2ccc3c(c21)c1ccccc1n3-c1ccc(-c2cc(-c3ccccc3)nc(-c3ccccc3)n2)cc1 ; CC1(C)c2ccccc2-c2c1ccc1c2c2ccccc2n1-c1ccc(-c2cc(-c3ccccc3)nc(-c3ccccc3)n2)cc1]

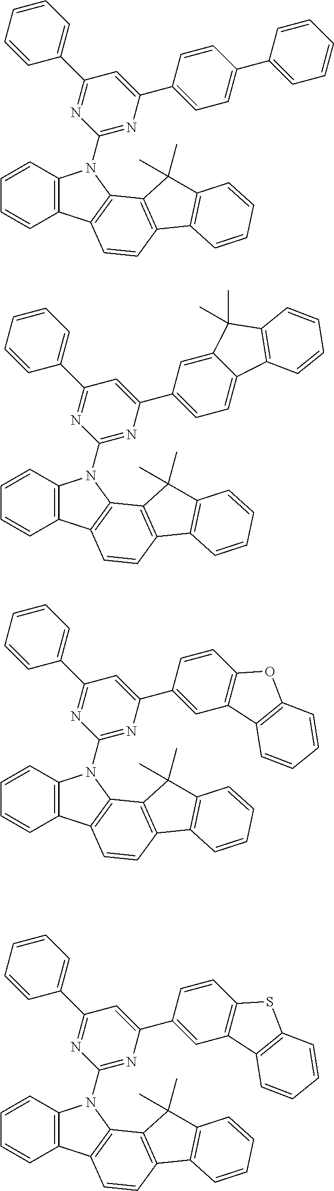

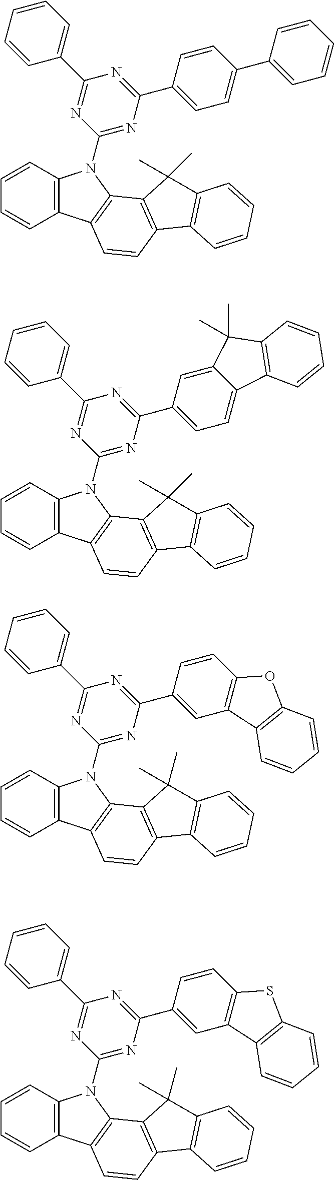 [SMILES: CC1(C)c2ccccc2-c2ccc3c4ccccc4n(-c4nc(-c5ccccc5)nc(-c5ccc(-c6ccccc6)cc5)n4)c3c21 ; CC1(C)c2ccccc2-c2ccc(-c3nc(-c4ccccc4)nc(-n4c5ccccc5c5ccc6c(c54)C(C)(C)c4ccccc4-6)n3)cc21 ; CC1(C)c2ccccc2-c2ccc3c4ccccc4n(-c4nc(-c5ccccc5)nc(-c5ccc6oc7ccccc7c6c5)n4)c3c21 ; CC1(C)c2ccccc2-c2ccc3c4ccccc4n(-c4nc(-c5ccccc5)nc(-c5ccc6sc7ccccc7c6c5)n4)c3c21]

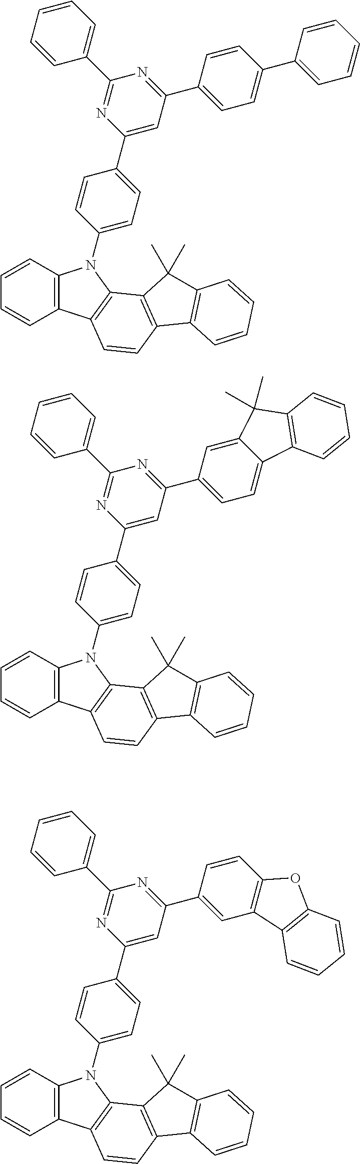

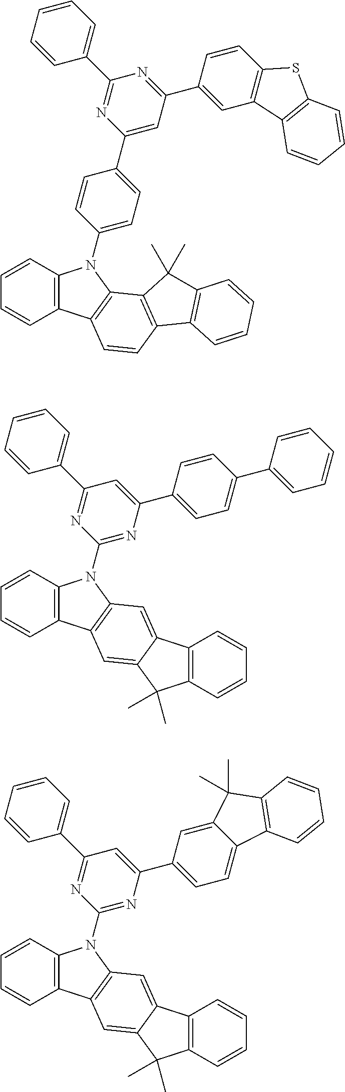 [SMILES: CC1(C)c2ccccc2-c2ccc3c4ccccc4n(-c4ccc(-c5cc(-c6ccc7sc8ccccc8c7c6)nc(-c6ccccc6)n5)cc4)c3c21 ; CC1(C)c2ccccc2-c2cc3c(cc21)c1ccccc1n3-c1nc(-c2ccccc2)cc(-c2ccc(-c3ccccc3)cc2)n1 ; CC1(C)c2ccccc2-c2ccc(-c3cc(-c4ccccc4)nc(-n4c5ccccc5c5cc6c(cc54)-c4ccccc4C6(C)C)n3)cc21]

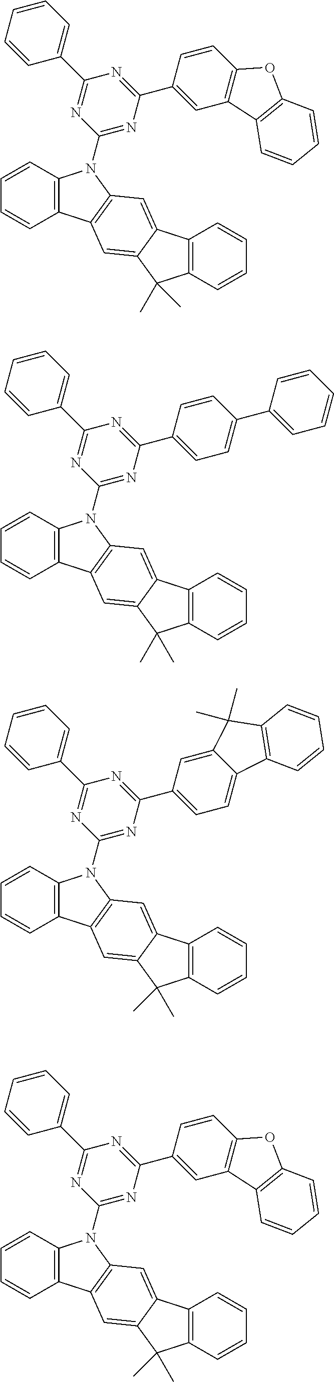 [SMILES: CC1(C)c2ccccc2-c2cc3c(cc21)c1ccccc1n3-c1nc(-c2ccccc2)nc(-c2ccc3oc4ccccc4c3c2)n1 ; CC1(C)c2ccccc2-c2cc3c(cc21)c1ccccc1n3-c1nc(-c2ccccc2)nc(-c2ccc(-c3ccccc3)cc2)n1 ; CC1(C)c2ccccc2-c2ccc(-c3nc(-c4ccccc4)nc(-n4c5ccccc5c5cc6c(cc54)-c4ccccc4C6(C)C)n3)cc21 ; CC1(C)c2ccccc2-c2cc3c(cc21)c1ccccc1n3-c1nc(-c2ccccc2)nc(-c2ccc3oc4ccccc4c3c2)n1]

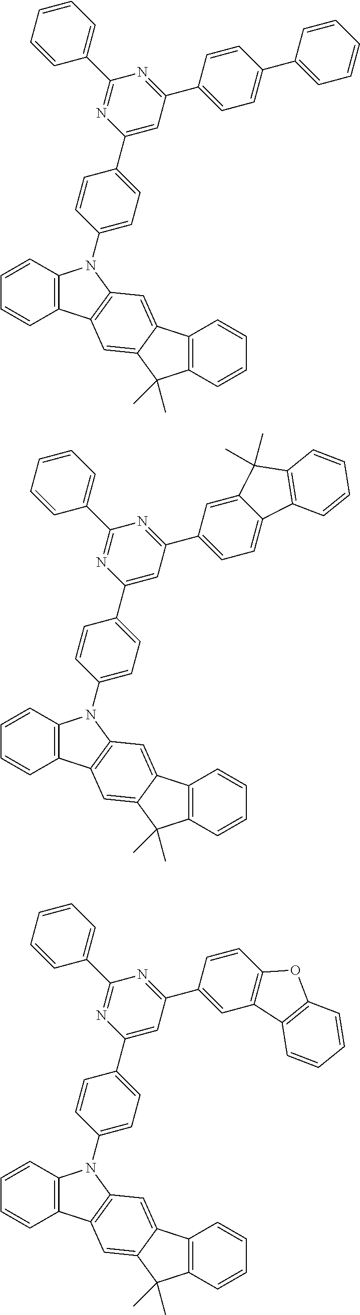 [SMILES: CC1(C)c2ccccc2-c2cc3c(cc21)c1ccccc1n3-c1ccc(-c2cc(-c3ccc(-c4ccccc4)cc3)nc(-c3ccccc3)n2)cc1 ; CC1(C)c2ccccc2-c2ccc(-c3cc(-c4ccc(-n5c6ccccc6c6cc7c(cc65)-c5ccccc5C7(C)C)cc4)nc(-c4ccccc4)n3)cc21 ; CC1(C)c2ccccc2-c2cc3c(cc21)c1ccccc1n3-c1ccc(-c2cc(-c3ccc4oc5ccccc5c4c3)nc(-c3ccccc3)n2)cc1]

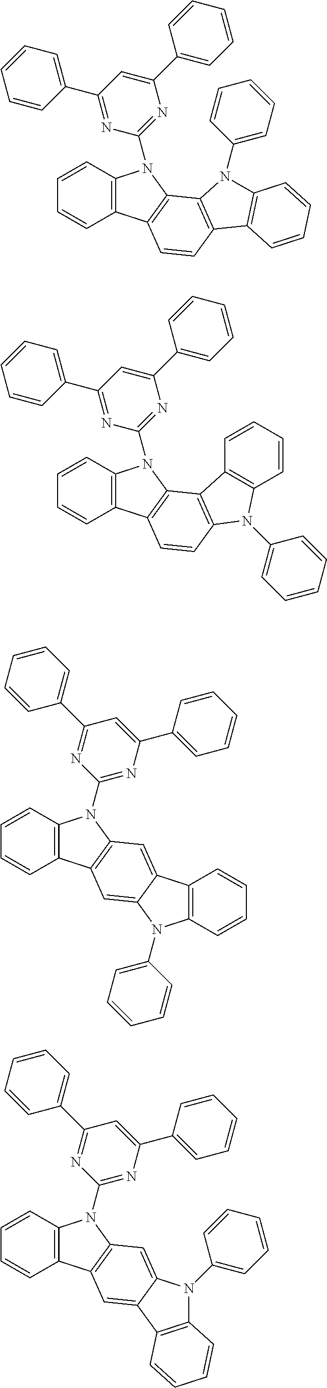

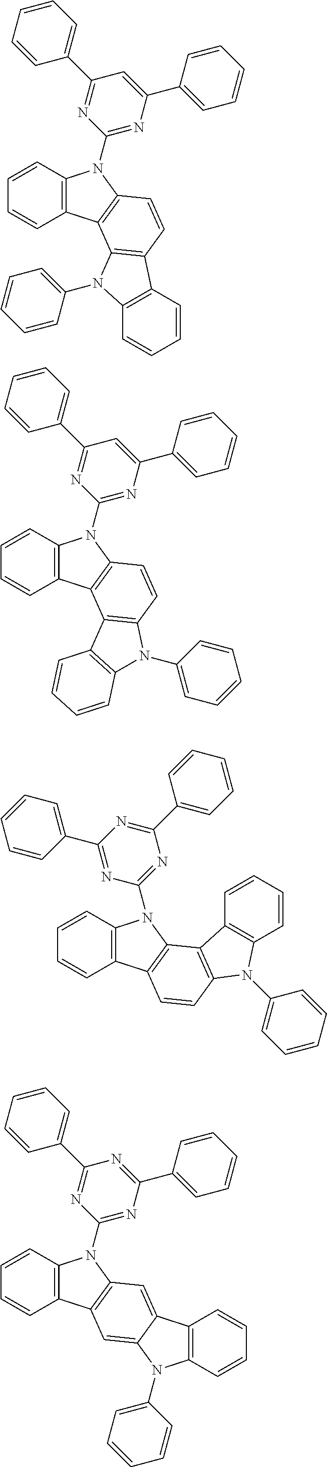

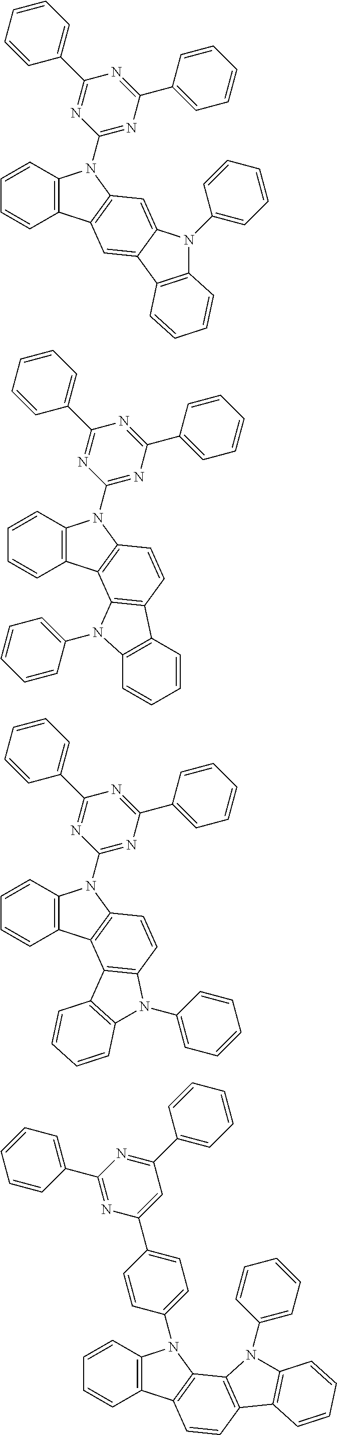

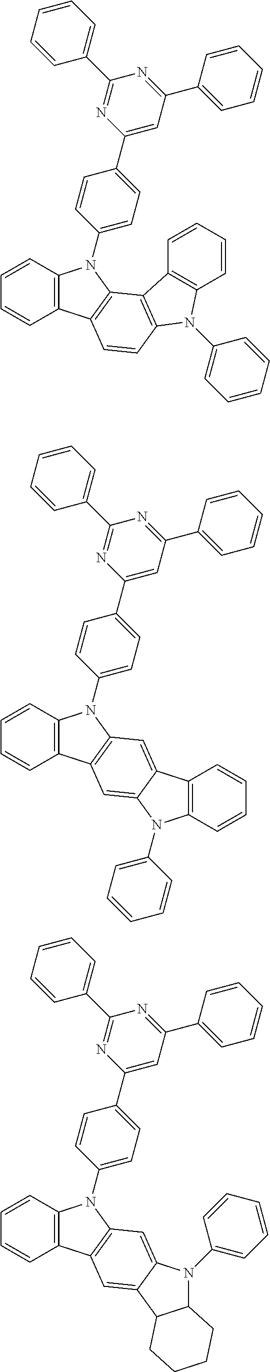 [SMILES: c1ccc(-c2cc(-c3ccc(-n4c5ccccc5c5ccc6c(c7ccccc7n6-c6ccccc6)c54)cc3)nc(-c3ccccc3)n2)cc1 ; c1ccc(-c2cc(-c3ccc(-n4c5ccccc5c5cc6c(cc54)c4ccccc4n6-c4ccccc4)cc3)nc(-c3ccccc3)n2)cc1 ; c1ccc(-c2cc(-c3ccc(-n4c5ccccc5c5cc6c(cc54)N(c4ccccc4)C4CCCCC64)cc3)nc(-c3ccccc3)n2)cc1]

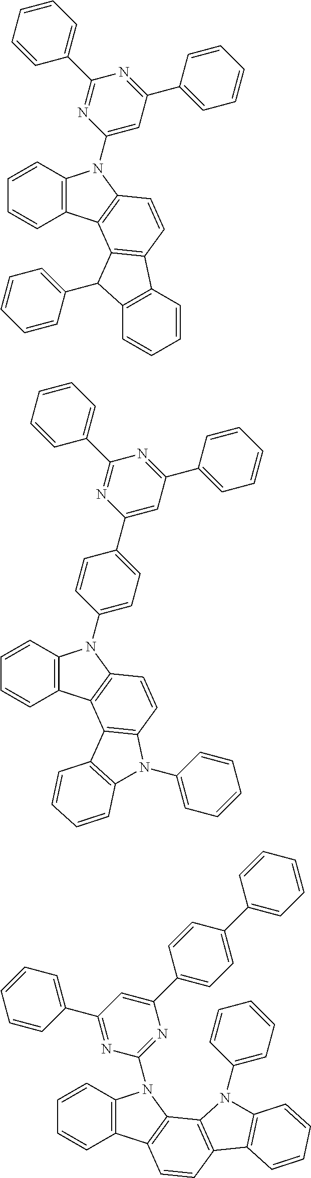 [SMILES: c1ccc(-c2cc(-n3c4ccccc4c4c5c(ccc43)-c3ccccc3C5c3ccccc3)nc(-c3ccccc3)n2)cc1 ; c1ccc(-c2cc(-c3ccc(-n4c5ccccc5c5c6c7ccccc7n(-c7ccccc7)c6ccc54)cc3)nc(-c3ccccc3)n2)cc1 ; c1ccc(-c2ccc(-c3cc(-c4ccccc4)nc(-n4c5ccccc5c5ccc6c7ccccc7n(-c7ccccc7)c6c54)n3)cc2)cc1]

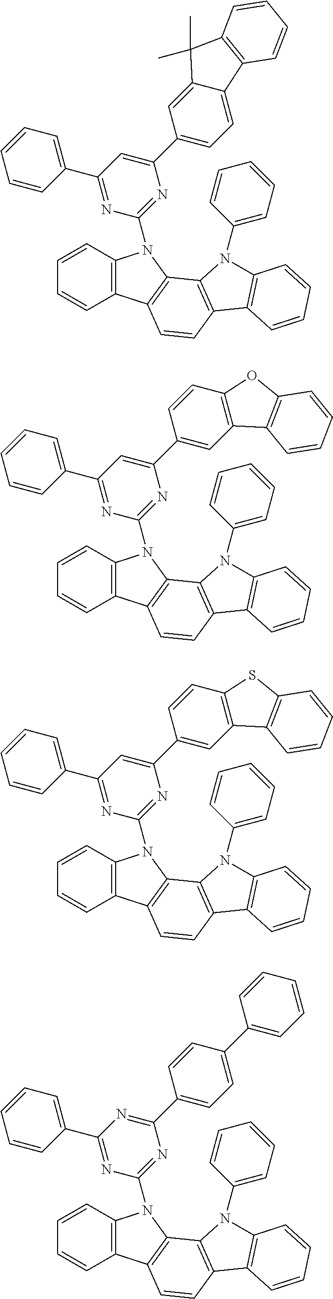

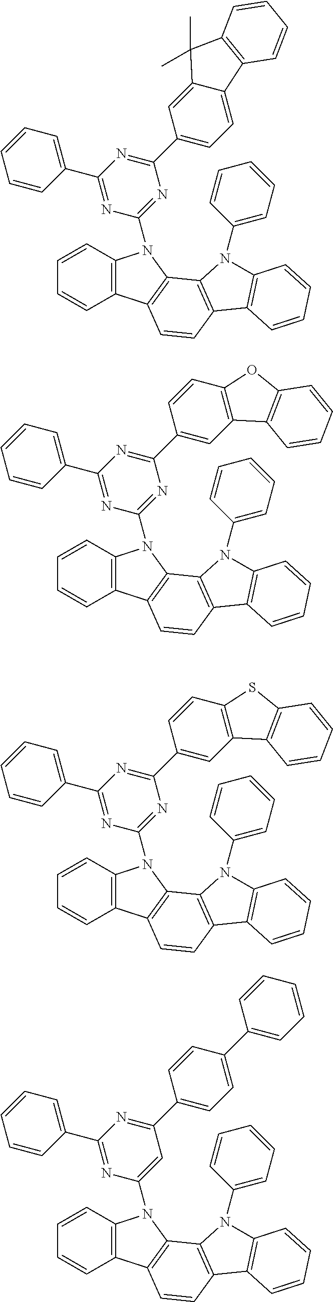

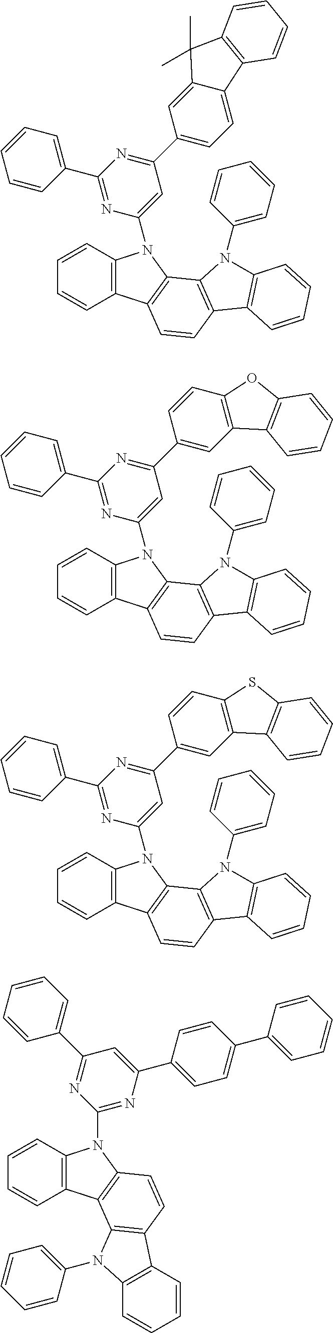 [SMILES: CC1(C)c2ccccc2-c2ccc(-c3cc(-n4c5ccccc5c5ccc6c7ccccc7n(-c7ccccc7)c6c54)nc(-c4ccccc4)n3)cc21 ; c1ccc(-c2nc(-c3ccc4oc5ccccc5c4c3)cc(-n3c4ccccc4c4ccc5c6ccccc6n(-c6ccccc6)c5c43)n2)cc1 ; c1ccc(-c2nc(-c3ccc4sc5ccccc5c4c3)cc(-n3c4ccccc4c4ccc5c6ccccc6n(-c6ccccc6)c5c43)n2)cc1 ; c1ccc(-c2ccc(-c3cc(-c4ccccc4)nc(-n4c5ccccc5c5c4ccc4c6ccccc6n(-c6ccccc6)c45)n3)cc2)cc1]

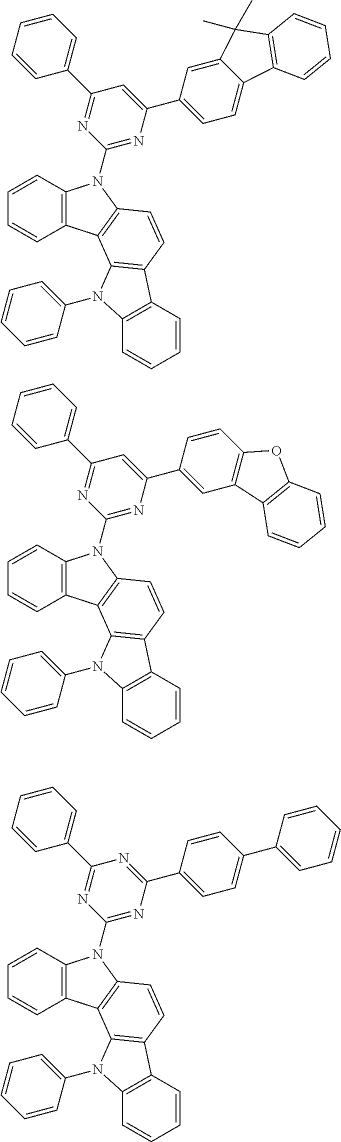 [SMILES: CC1(C)c2ccccc2-c2ccc(-c3cc(-c4ccccc4)nc(-n4c5ccccc5c5c4ccc4c6ccccc6n(-c6ccccc6)c45)n3)cc21 ; c1ccc(-c2cc(-c3ccc4oc5ccccc5c4c3)nc(-n3c4ccccc4c4c3ccc3c5ccccc5n(-c5ccccc5)c34)n2)cc1 ; c1ccc(-c2ccc(-c3nc(-c4ccccc4)nc(-n4c5ccccc5c5c4ccc4c6ccccc6n(-c6ccccc6)c45)n3)cc2)cc1]

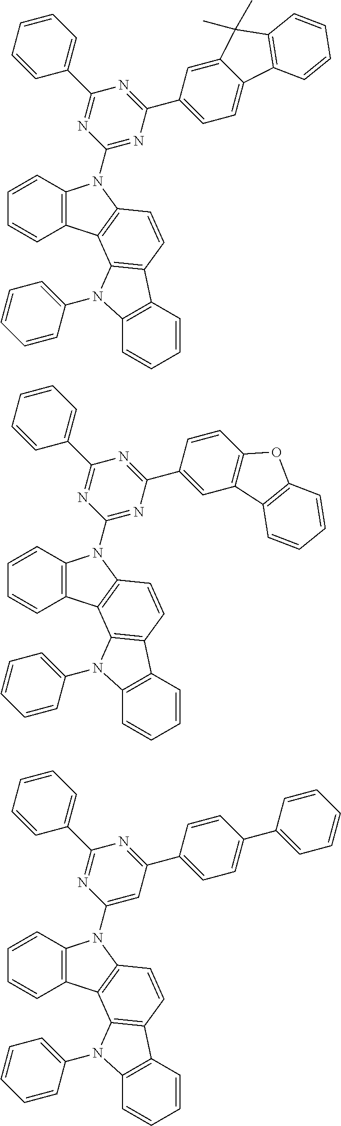 [SMILES: CC1(C)c2ccccc2-c2ccc(-c3nc(-c4ccccc4)nc(-n4c5ccccc5c5c4ccc4c6ccccc6n(-c6ccccc6)c45)n3)cc21 ; c1ccc(-c2nc(-c3ccc4oc5ccccc5c4c3)nc(-n3c4ccccc4c4c3ccc3c5ccccc5n(-c5ccccc5)c34)n2)cc1 ; c1ccc(-c2ccc(-c3cc(-n4c5ccccc5c5c4ccc4c6ccccc6n(-c6ccccc6)c45)nc(-c4ccccc4)n3)cc2)cc1]

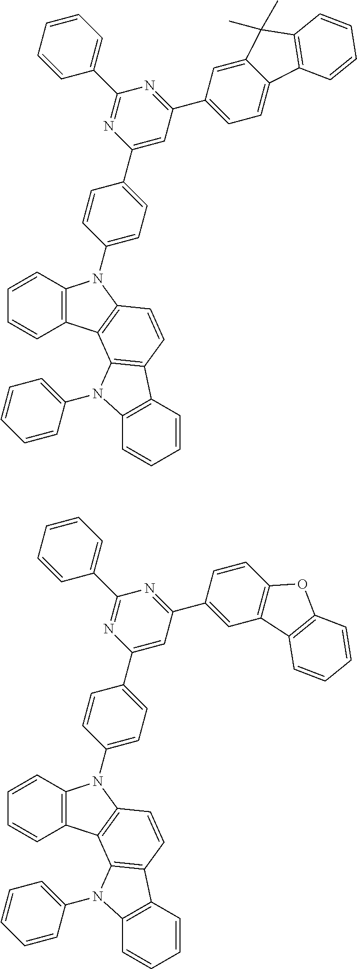 [SMILES: CC1(C)c2ccccc2-c2ccc(-c3cc(-c4ccc(-n5c6ccccc6c6c5ccc5c7ccccc7n(-c7ccccc7)c56)cc4)nc(-c4ccccc4)n3)cc21 ; c1ccc(-c2nc(-c3ccc(-n4c5ccccc5c5c4ccc4c6ccccc6n(-c6ccccc6)c45)cc3)cc(-c3ccc4oc5ccccc5c4c3)n2)cc1]

A content ratio of the first material (first host material) and the second material (second host material) in the emitting layer is not particularly limited but adjustable as needed. The ratio by mass is preferably the host material:the second host material in a range of 1:99 to 99:1, more preferably of 10:90 to 90:10.

### Luminescent Material

Examples of a luminescent material contained in the emitting layer are a fluorescent material and a phosphorescent material, among which the phosphorescent material is preferable.

The fluorescent material used as the dopant material (hereinafter, referred to as a fluorescent dopant material) is selected from a fluoranthene derivative, pyrene derivative, arylacetylene derivative, fluorene derivative, boron complex, perylene derivative, oxadiazole derivative, anthracene derivative and chrysene derivative. The fluoranthene derivative, pyrene derivative and boron complex are preferable.

The dopant material of the organic EL device according to the exemplary embodiment is preferably the phosphorescent material emittable in a triplet state. The phosphorescent material used as the dopant material (hereinafter, referred to as a phosphorescent dopant material) preferably contains a metal complex. The metal complex preferably contains: a metal atom selected from iridium (Ir), platinum (Pt), osmium (Os), gold (Au), rhenium (Re) and ruthenium (Ru); and a ligand. Particularly, an ortho-metalated complex in which the ligand and the metal atom form an ortho-metal bond is preferable. As the phosphorescent dopant material, an ortho-metalated complex containing a metal selected from the group consisting of iridium (Ir), osmium (Os) and platinum (Pt) is preferable since a phosphorescent quantum yield is high and an external quantum efficiency of an emitting device is improvable. In terms of the luminous efficiency, a metal complex including the ligand selected from phenyl quinoline, phenyl isoquinoline, phenyl pyridine, phenyl pyrimidine, phenyl pyrazine and phenyl imidazole is preferable.

A content of the dopant material in the emitting layer is not particularly limited. Although the content thereof can be selected according to the need, for instance, the content thereof is preferably in a range of 0.1 mass % to 70 mass %, more preferably of 1 mass % to 30 mass %. When the content of the dopant material is 0.1 mass % or more, a sufficient emission is obtained. When the content of the dopant material is 70 mass % or less, concentration quenching is avoidable.

It should be noted that a host material combined with a fluorescent dopant material is herein referred to as a fluorescent host material while a host material combined with a phosphorescent dopant material is herein referred to as a phosphorescent host material. The fluorescent host material and the phosphorescent host material are not differentiated only from molecular structures thereof. In other words, the phosphorescent host material herein means a material for forming a phosphorescent-emitting layer containing a phosphorescent dopant material, and does not mean to be inapplicable to a material for forming a fluorescent-emitting layer. The same applies to a fluorescent host material.

Examples of the phosphorescent dopant material are shown below.

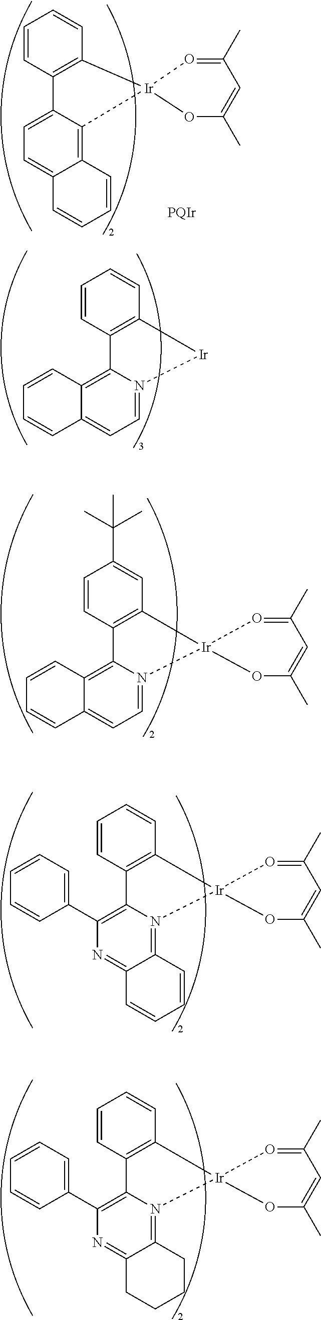

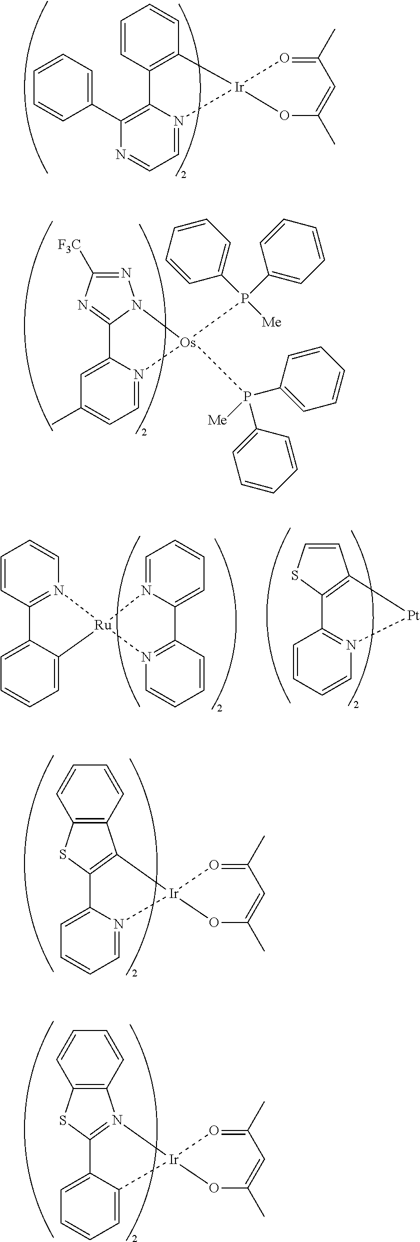

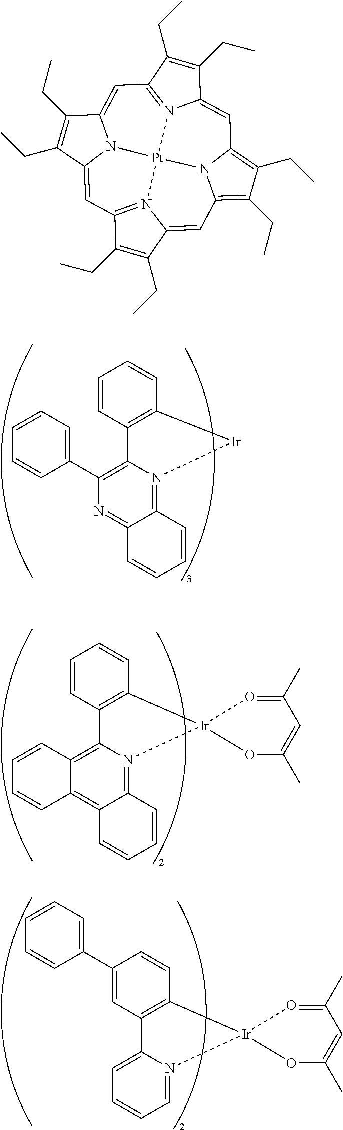

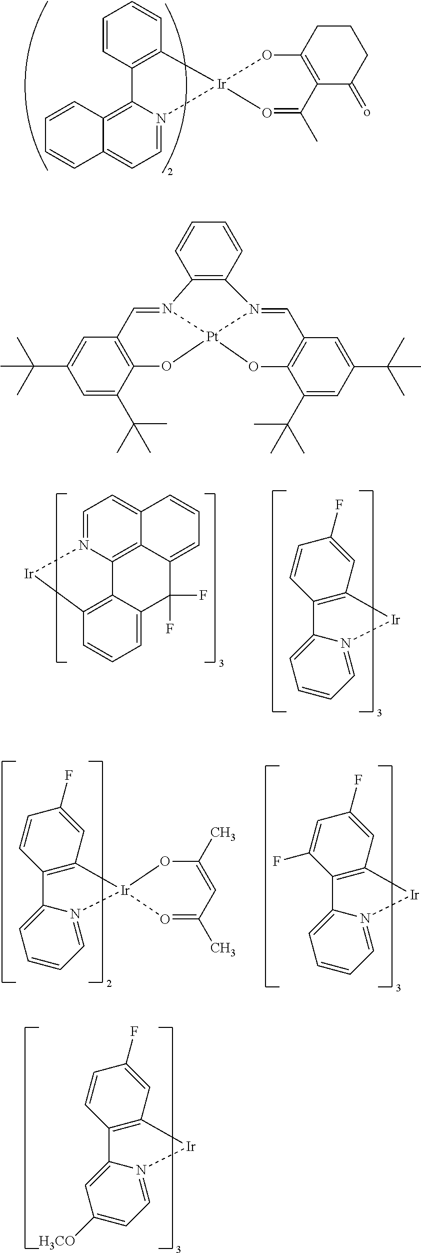

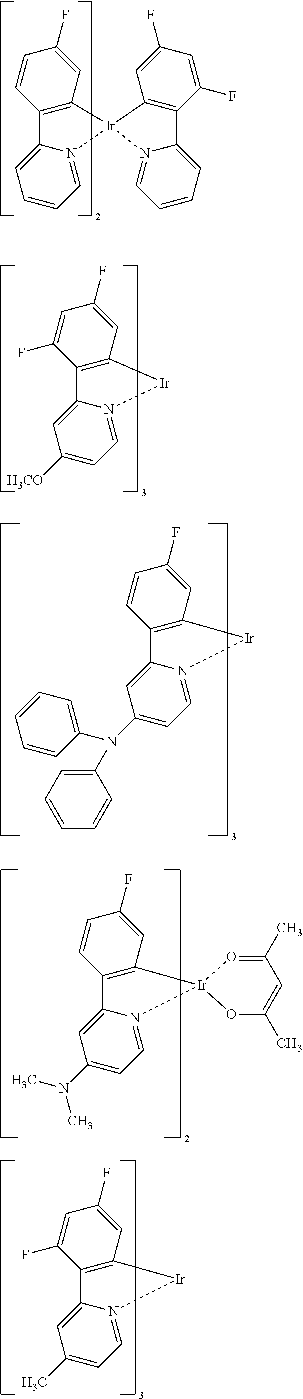

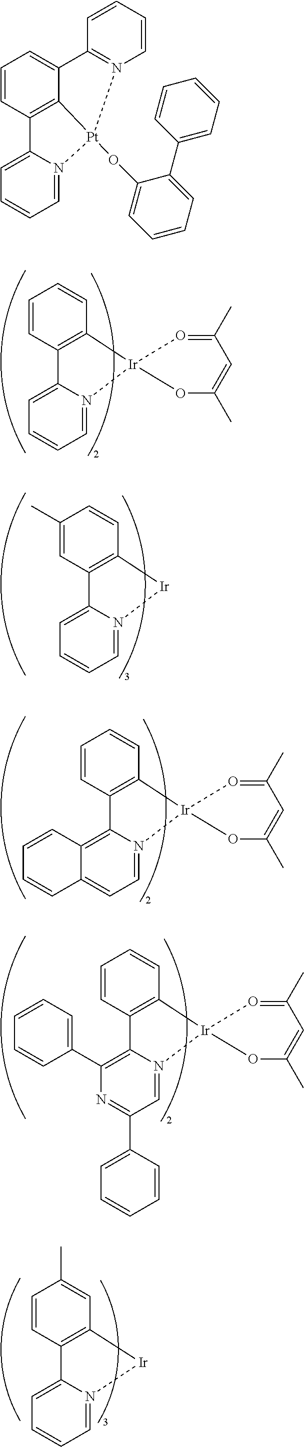

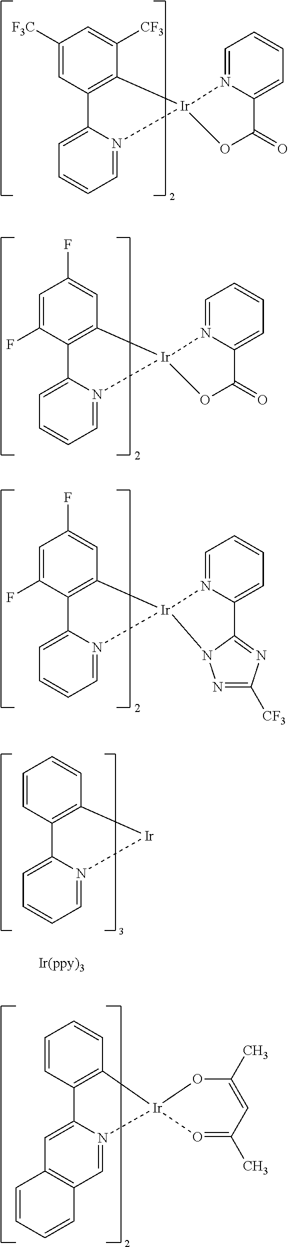

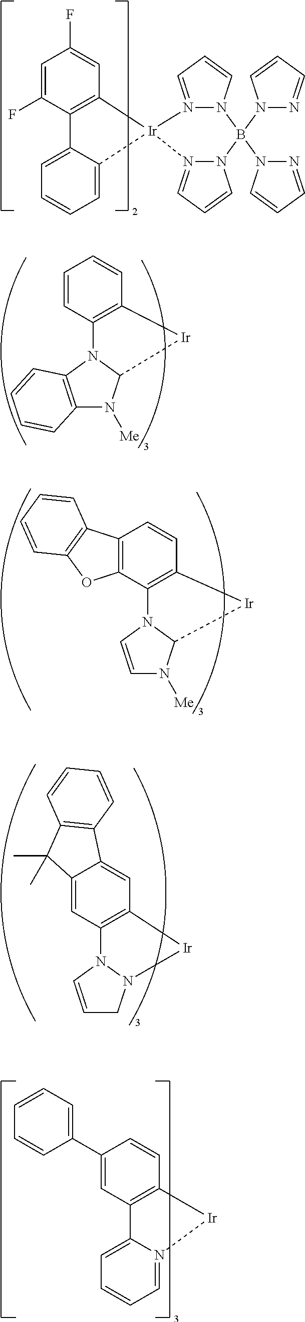

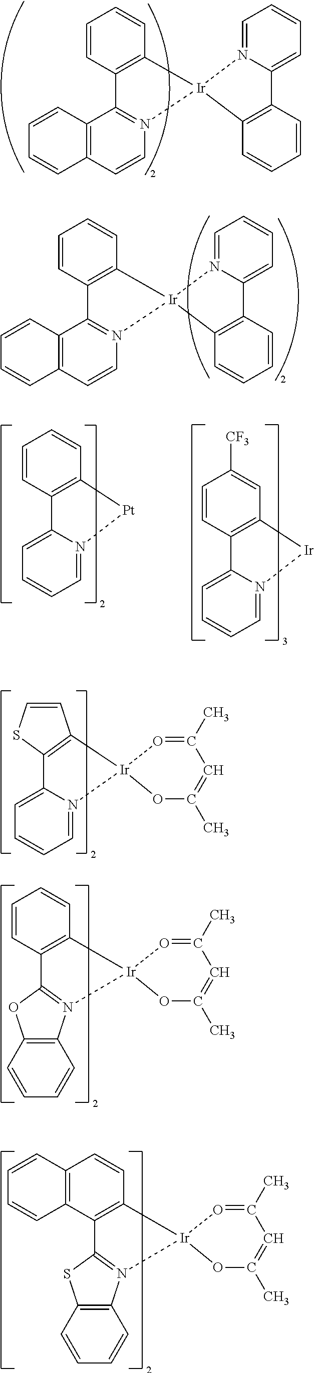

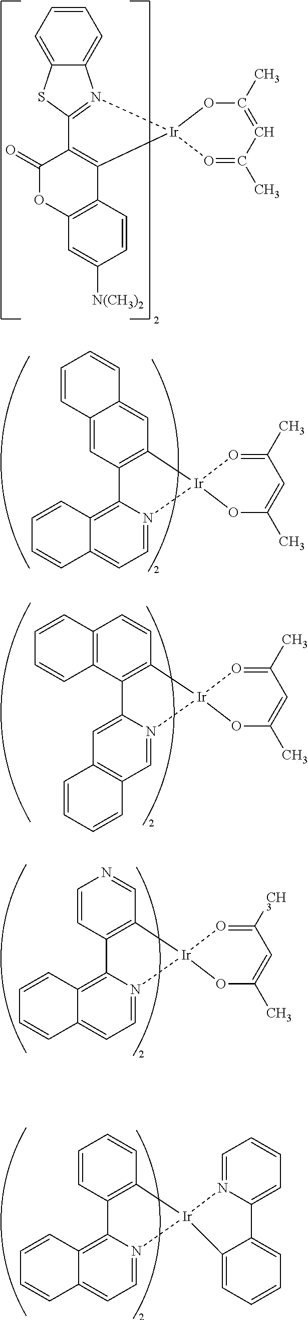

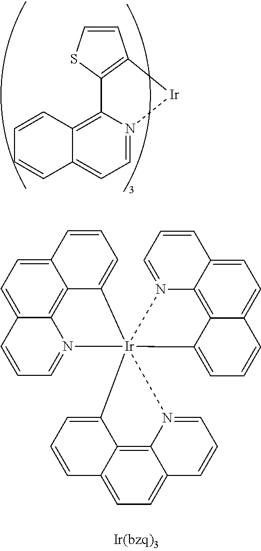

One of the phosphorescent dopant materials may be singularly used, or two or more kinds thereof may be used in combination.

An emission wavelength of the phosphorescent dopant material contained in the emitting layer is not particularly limited, but at least one of the phosphorescent dopant material contained in the emitting layer preferably has a peak of the emission wavelength in a range of 490 nm to 700 nm, more preferably in a range of 490 nm to 650 nm. Preferable emission colors of the emitting layer are, for instance, red, yellow and green. Using the first and second host materials and doping the phosphorescent dopant material having such an emission wavelength, the organic EL device can exhibit a high efficiency and a long lifetime.

The phosphorescent host material is a compound having a function to enable the phosphorescent dopant material to emit efficiently by efficiently trapping triplet energy of the phosphorescent dopant material in the emitting layer. The organic EL device according to the exemplary embodiment may select a compound other than the compounds of the first and second host materials as the phosphorescent host material according to the object of the invention.

The first and second host materials and the other compound may be used together in the same emitting layer. When a plurality of emitting layers are present, the first and second host materials may be used as a phosphorescent host material in one of the emitting layers while the compound other than the first and second host materials may be used as a phosphorescent host material in another one of the emitting layers. The first and second host materials may be used in the organic layer other than the emitting layer(s).

Specific examples of a preferable compound for the phosphorescent host except for the compound for the first and second host materials include a carbazole derivative, triazoles derivative, oxazole derivative, oxadiazole derivative, imidazoles derivative, polyarylalkane derivative, pyrazoline derivative, pyrazolone derivative, phenylenediamine derivative, arylamine derivative, amino-substituted chalcone derivative, styryl anthracene derivative, fluorenone derivative, hydrazone derivative, stilbene derivative, silazane derivative, aromatic tertiary amine compound, styrylamine compound, aromatic dimethylidene compound, porphyrin compound, anthraquinodimethane derivative, anthrone derivative, diphenylquinone derivative, thiopyrandioxide derivative, carbodiimide derivative, fluorenylidenemethan derivative, distyryl pyrazine derivative, heterocyclic tetracarboxylic acid anhydride such as naphthaleneperylene, phthalocyanine derivative, various metal complex polysilane compounds typified by a metal complex of 8-quinolinol derivative, and a metal complex having metal phthalocyanine, benzoxazole or benzothiazole as the ligand, poly(N-vinylcarbazole) derivative, aniline copolymer, conductive high molecular weight oligomers such as thiophene oligomer and polythiophene, polymer compounds such as polythiophene derivative, polyphenylene derivative, polyphenylene vinylene derivative and polyfluorene derivative. One kind of the phosphorescent host material other than the first and second host materials may be singularly used, or two or more kinds thereof may be used in combination. In addition, one kind or two or more kinds of the compounds may be used as the second host material.

### Hole Injecting/Transporting Layer

The hole injecting/transporting layer helps injection of holes to the emitting layer and transports the holes to an emitting region. The hole injecting/transporting layer exhibits a large hole mobility and a small ionization energy.

The hole injecting/transporting layer in the exemplary embodiment includes the hole injecting layer 5, the first hole transporting layer 61, and the second hole transporting layer 62 in this sequence from the anode, as shown in FIG. 1.

### Second Hole Transporting Layer

The second hole transporting layer in the exemplary embodiment is adjacent to the side near the anode of the emitting layer and contains a compound represented by the following formula (4).

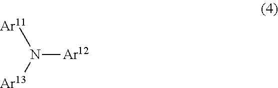

In the formula (4), Ar¹¹ to Ar¹³ represent a group represented by the following formula (4-2) or a substituted or unsubstituted aromatic hydrocarbon group having 6 to 40 carbon atoms. At least one of Ar¹¹ to Ar¹³ is a group represented by the following formula (4-2).

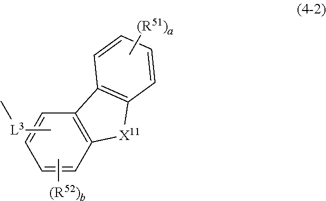

In the formula (4-2), X¹¹ represents CR⁵³R⁵⁴, an oxygen atom, or a sulfur atom.

In the formula (4-2), L³ each independently represents a single bond or a substituted or unsubstituted arylene group having 6 to 50 ring carbon atoms. When L³ is a substituted or unsubstituted arylene group having 6 to 50 ring carbon atoms, the substituent is a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms.

In the formula (4-2), R⁵¹ and R⁵² each independently represent a halogen atom, a cyano group, a substituted or unsubstituted amino group, a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms.

In adjacent ones of R⁵¹ and adjacent ones of R⁵², a saturated or unsaturated divalent group to be bonded form a ring is formed or not formed.

In the formula (4-2), R⁵³ and R⁵⁴ each independently represent a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms.

In adjacent ones of R⁵³ and adjacent ones of R⁵⁴, a saturated or unsaturated divalent group to be bonded form a ring is formed or not formed.

In the formula (4-2), a represents an integer of 0 to 4 and b represents an integer of 0 to 3. In the formula (4-2), a and b are preferably 0 or 1, more preferably 0.

In the formula (4-2), examples of the arylene group represented by L³ are a phenylene group, naphthylene group, biphenylene group, anthrylene group, acenaphthylenyl group, anthranylene group, phenanthrenylene group, phenalenyl group, quinolylene group, isoquinolylene group, s-indacenylene group, as-indacenylene group and chrysenylene group. Among these groups, an arylene group having 6 to 30 ring carbon atoms is preferable, an arylene group having 6 to 20 ring carbon atoms is more preferable, an arylene group having 6 to 12 ring carbon atoms is further preferable, and a phenylene group is particularly preferable.

Each of the other groups will be described below. However, the same group will be described in the same way.

Examples of the amino group in the formula (4-2) include an alkylamino group, an arylamino group, and an aralkylamino group. The amino group is represented by —NQ¹Q². Examples for each of Q¹ and Q² are the same as the examples described in relation to the alkyl group, the aromatic hydrocarbon group and the aralkyl group (i.e., a group obtained by substituting a hydrogen atom of the alkyl group with the aromatic hydrocarbon group) described in relation to the formula (1-1), and preferable examples for each of Q¹ and Q² are also the same as those described in relation to the alkyl group, the aromatic hydrocarbon group and the aralkyl group. One of Q¹ and Q² may be a hydrogen atom.

In the formula (4-2), examples of the halogen atom include a fluorine atom, chlorine atom and iodine atom.

In the formula (4-2), examples of the aromatic hydrocarbon group having 6 to 50 ring carbon atoms include a phenyl group, naphthyl group, biphenylyl group, anthryl group, phenanthryl group and terphenylyl group. Among these groups, an aromatic hydrocarbon group having 6 to 30 ring carbon atoms is preferable, an aromatic hydrocarbon group having 6 to 20 ring carbon atoms is more preferable, an aromatic hydrocarbon group having 6 to 12 ring carbon atoms is further preferable.

In the formula (4-2), the alkyl group is preferably an alkyl group having 1 to 5 carbon atoms, more preferably an alkyl group having 1 to 3 carbon atoms. Examples of the alkyl group include a methyl group, ethyl group, n-propyl group, isopropyl group, n-butyl group, isobutyl group, t-butyl group and n-hexyl group.

In the formula (4-2), examples of the alkyl group in the trialkylsilyl group are the same as the above, among which preferable examples are the same as the above. Examples of the aromatic hydrocarbon group in the triarylsilyl group are a phenyl group, naphthyl group and biphenyl group.

In the formula (4-2), the alkylaryl group in the alkylarylsilyl group is exemplified by a dialkyl monoarylsilyl group. The alkyl group has 1 to 5 carbon atoms, more preferably 1 to 3 carbon atoms. The aryl group has 6 to 14 ring carbon atoms, more preferably 6 to 10 ring carbon atoms.

In the compound contained in the second hole transporting layer of the organic EL device according to the exemplary embodiment, the compound represented by the formula (4-2) is preferably represented by the following formula (4-2-1) or (4-2-2).

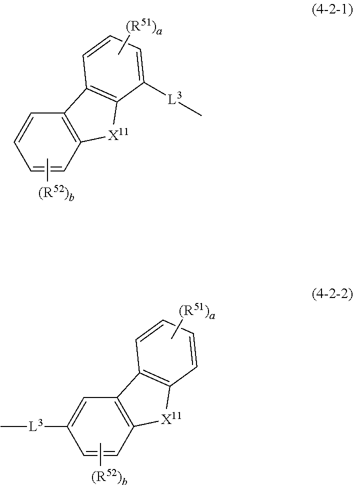

In the formulae (4-2-1) and (4-2-2), R⁵¹, R⁵², L³, X¹¹, a and b respectively represent the same as R⁵¹, R⁵², L³, X¹¹, a and b in the formula (4-2).

In the compound contained in the second hole transporting layer in the exemplary embodiment, a in the formula (4-2) is preferably an integer of 1 to 4, and at least one of R⁵¹ in the formula (4-2) is preferably a substituted or unsubstituted carbazolyl group to be bonded at N position. Specifically, the N position of the carbazolyl group is preferably bonded to a carbon atom of a six-membered ring.

In the formulae (4-2), (4-2-1) and (4-2-2), X¹¹ is preferably an oxygen atom.

In the compound contained in the second hole transporting layer according to the exemplary embodiment, two or three of Ar¹¹ to Ar¹³ in the formula (4) are preferably a group represented by the formula (4-2). In this arrangement, the groups represented by the formula (4-2) in each of Ar¹¹ to Ar¹³ are mutually the same or different.

In the formula (4-2), when X¹¹ is an oxygen atom, a dibenzofuran ring is formed to improve stability of the compound, thereby prolonging a lifetime of the organic EL device. In this arrangement, the dibenzofuran ring is preferably bonded via a substituted or unsubstituted arylene group having 6 to 50 ring carbon atoms rather than to be directly bonded to a nitrogen atom of an amino group with a single bond, thereby improving resistance to oxidation.

In the formula (4-2), when X¹¹ is CR⁵³R⁵⁴, a fluorene ring is formed to tend to decrease the ionization potential of the compound, thereby improving hole injectability to the emitting layer.

In the formula (4-2), when X¹¹ is a sulfur atom, a dibenzothiophene ring is formed to improve the lifetime of the compound.

Thus, the properties of the compound contained in the second hole transporting layer can be adjusted as needed by the structures of Ar¹¹ to Ar¹³, so that the compound contained in the second hole transporting layer can exhibit suitable performance in combination with the host material of the emitting layer.

The compound contained in the second hole transporting layer according to the exemplary embodiment preferably has a single amino group. When the compound has a single amino group, the lifetime of the organic EL device can be prolonged. In this arrangement, the luminescent material contained in the emitting layer is preferably a luminescent material emitting light in a wavelength range from green emission to red emission, particularly preferably a phosphorescent material emitting light in a wavelength range from green emission to red emission.

When L³ in the formulae (4-2), (4-2-1) and (4-2-2) is an arylene group, an electron density is prevented from being increased, the ionization potential Ip is increased, and hole injection to the emitting layer is promoted in the compound represented by the formula (4). Accordingly, the drive voltage of the organic EL device is advantageously easily decreased. Further, when the dibenzofuran structure and the carbazole structure are bonded to a nitrogen atom via the arylene group, amine becomes less likely to be oxidized, so that the compound is often stabilized to easily prolong the lifetime of the device. The arylene group is particularly preferably a phenylene group.

In the compound contained in the second hole transporting layer of the organic EL device according to the exemplary embodiment, when the group for Ar¹¹ to Ar¹³ in the formula (4) is not the group represented by the formula (4-2), a substituted or unsubstituted aromatic hydrocarbon group having 6 to 40 carbon atoms is preferably represented by any one of the following formulae (4-3) to (4-5).

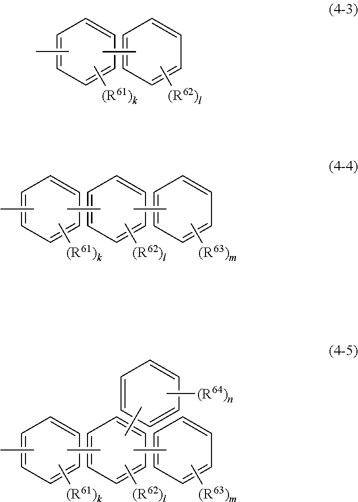

In the formulae (4-3) to (4-5), R⁶¹ to R⁶⁴ each independently represent a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms in which an aryl moiety has 6 to 14 ring carbon atoms. In at least one of adjacent ones of R⁶¹, adjacent ones of R⁶², adjacent ones of R⁶³, and adjacent ones of R⁶⁴, the adjacent ones are bonded to each other to form a cyclic structure, or are not bonded.

In the formulae (4-3) to (4-5), k, l, m and n are each independently an integer of 0 to 4.

Further, the groups of the formulae (4-3) to (4-5) are preferably represented by the following formulae (4-3′) to (4-5′) in which the definition of each of the groups is the same as the above.

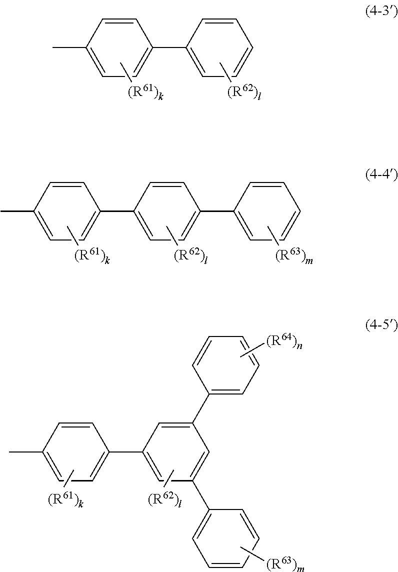

The group of the formula (4-3′) includes a group represented by the following formulae (4-3′-1) to (4-3′-4).

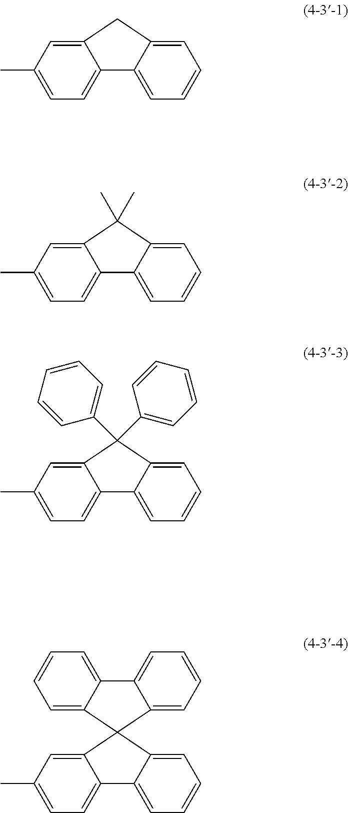

It is preferable that a substituted or unsubstituted aromatic hydrocarbon group having 6 to 40 carbon atoms is used for each of Ar¹¹ to Ar¹³ in the formula (4), since a terphenyl group in the formula (4-4′) can prolong the lifetime of the device.

Moreover, it is preferable that a substituted or unsubstituted aromatic hydrocarbon group having 6 to 40 carbon atoms is used for each of Ar¹¹ to Ar¹³ in the formula (4), since a biphenyl group in the formula (4-3′) can improve the efficiency of the device.

The compound used in the second hole transporting layer is also preferably a compound represented by the following formulae (5) to (7).

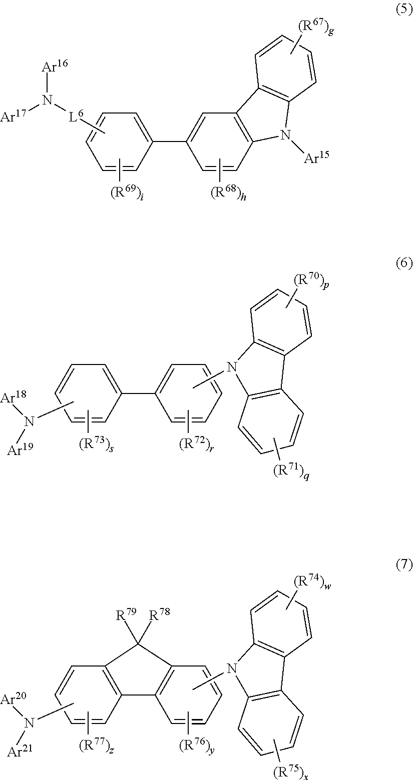

In the formulae (5) to (7), Ar¹⁵ to Ar²¹ each independently represent a substituted or unsubstituted aryl group having 6 to 50 ring carbon atoms, a substituted or unsubstituted aromatic heterocyclic group having 5 to 50 ring carbon atoms, a substituted or unsubstituted aryl group having 8 to 50 carbon atoms to which an aromatic amino group is bonded, or a substituted or unsubstituted aryl group having 8 to 50 carbon atoms to which an aromatic heterocyclic group is bonded.

Ar¹⁶ and Ar¹⁷, Ar¹⁸ and Ar¹⁹, and Ar²° and Ar²¹ may be bonded to each other to form a ring.

In the formulae (5) to (7), L⁶ represents a single bond or a substituted or unsubstituted arylene group having 6 to 50 ring carbon atoms.

Examples of a substituent usable for L⁶ are a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, an alkylarylsilyl group having 8 to 15 carbon atoms in which an aryl moiety has 6 to 14 ring carbon atoms, an aryl group having 6 to 50 ring carbon atoms, a halogen atom, or a cyano group.

Specific examples of the group for Ar¹⁵ to Ar² and L⁶ in the formulae (5) to (7) are the same as the examples described in relation to the formula (1-1).

In the formulae (5) to (7), R⁶⁷ to R⁷⁷ each independently represent a halogen atom, a substituted or unsubstituted alkyl group having 1 to 40 carbon atoms, a substituted or unsubstituted heterocyclic group having 3 to 20 carbon atoms, a substituted or unsubstituted aromatic hydrocarbon group having 6 to 40 carbon atoms, a substituted or unsubstituted aralkyl group having 7 to 20 carbon atoms, a substituted or unsubstituted alkenyl group having 2 to 40 carbon atoms, a substituted or unsubstituted alkylamino group having 1 to 40 carbon atoms, a substituted or unsubstituted aralkylamino group having 7 to 60 carbon atoms, a substituted or unsubstituted alkylsilyl group having 3 to 20 carbon atoms, a substituted or unsubstituted arylsilyl group having 8 to 40 carbon atoms, a substituted or unsubstituted aralkylsilyl group having 8 to 40 carbon atoms, a substituted or unsubstituted haloalkyl group having 1 to 40 carbon atoms.

Specific examples of the groups for R⁶⁷ to R⁷⁷ in the formulae (5) to (7) are the same as the examples described in relation to the formula (1-1).

In the formula (7), R⁷⁸ and R⁷⁹ each independently represent a substituted or unsubstituted alkyl group having 1 to 40 carbon atoms, a substituted or unsubstituted heterocyclic group having 3 to 20 carbon atoms, a substituted or unsubstituted aromatic hydrocarbon group having 6 to 40 carbon atoms, or a substituted or unsubstituted aralkyl group having 7 to 20 carbon atoms.

Specific examples of the groups for R⁷⁸ and R⁷⁹ in the formula (7) are the same as the examples described in relation to the formula (1-1).

In the formulae (5) to (7), g, i, p, q, r, s, w and x are each independently an integer of 0 to 4.

In the formulae (5) to (7), h, y and z are each independently an integer of 0 to 3.

The lifetime and the efficiency of the organic EL device are improved in good balance by a carbazolyl group being bonded to a fluorene ring bonded to a nitrogen atom of an amino group as shown in the formula (7).

Examples of specific structures of the compounds usable as the second hole transporting layer are compounds below. However, the invention is not limited to the compounds having these structures. It should be noted that a bond at an end of the following structural formulae, of which chemical formula (e.g., CN or a benzene ring) is not described, represents a methyl group.

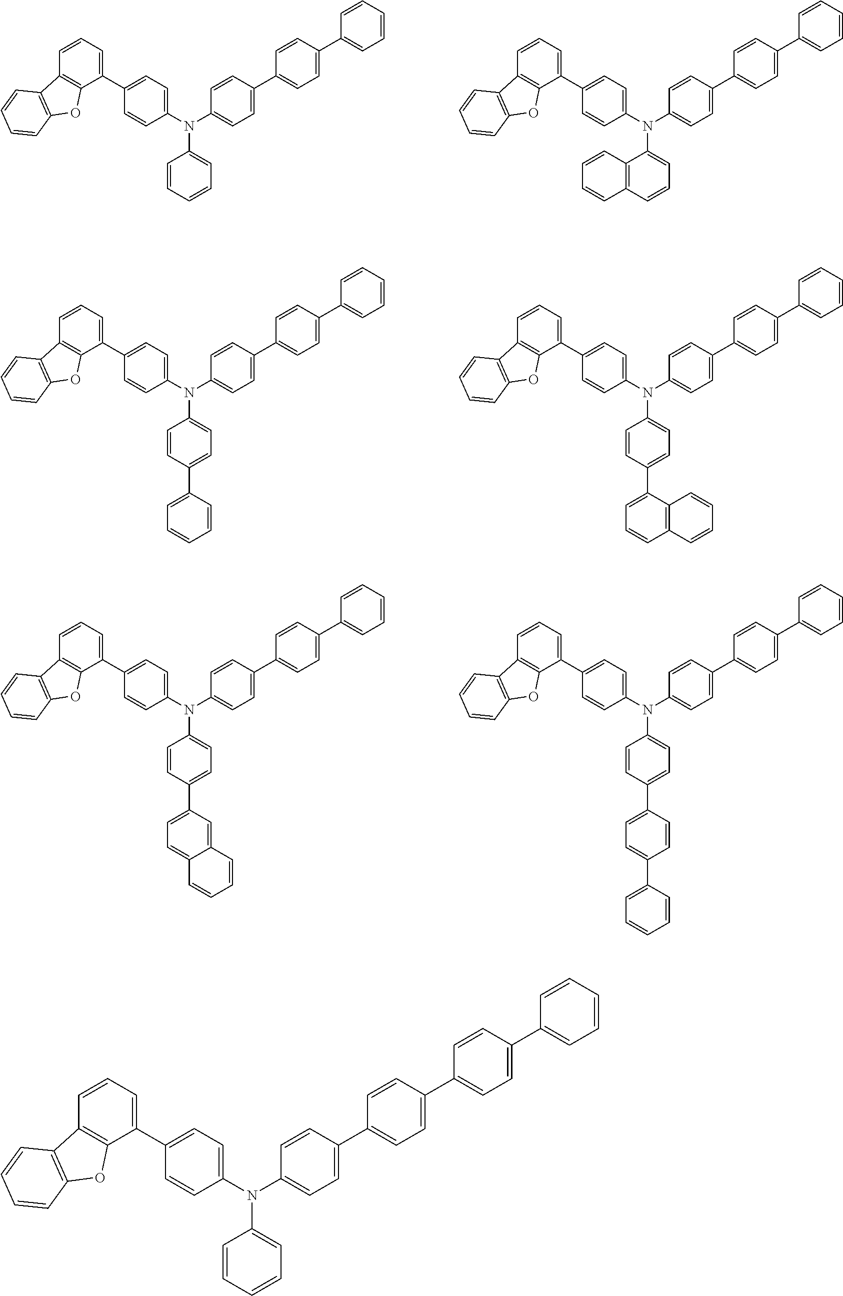

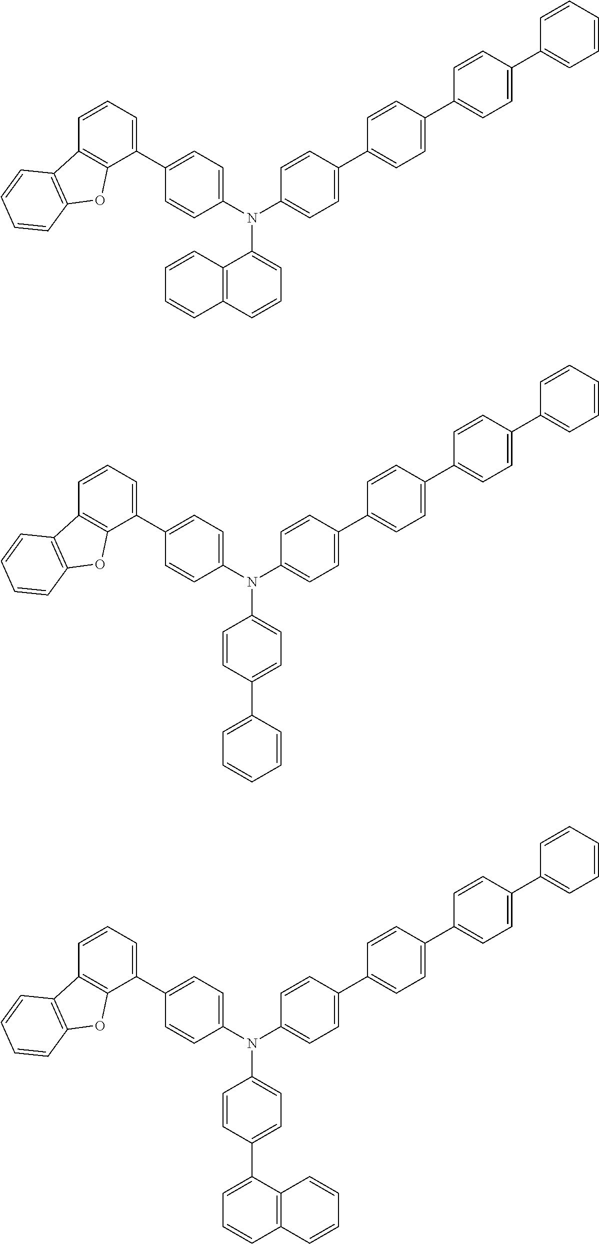 [SMILES: c1ccc(-c2ccc(-c3ccc(-c4ccc(N(c5ccc(-c6cccc7c6oc6ccccc67)cc5)c5cccc6ccccc56)cc4)cc3)cc2)cc1 ; c1ccc(-c2ccc(-c3ccc(-c4ccc(N(c5ccc(-c6ccccc6)cc5)c5ccc(-c6cccc7c6oc6ccccc67)cc5)cc4)cc3)cc2)cc1 ; c1ccc(-c2ccc(-c3ccc(-c4ccc(N(c5ccc(-c6cccc7ccccc67)cc5)c5ccc(-c6cccc7c6oc6ccccc67)cc5)cc4)cc3)cc2)cc1]

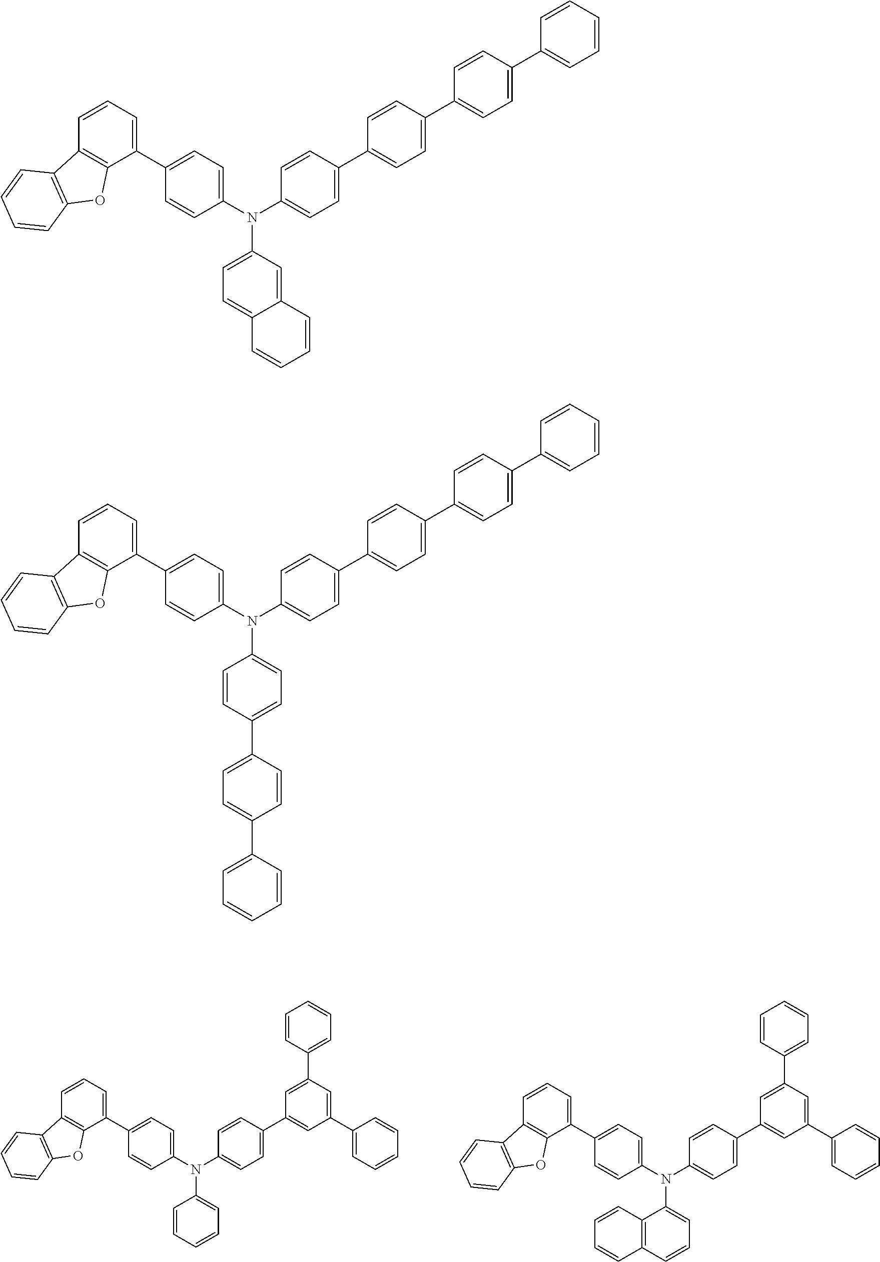 [SMILES: c1ccc(-c2ccc(-c3ccc(-c4ccc(N(c5ccc(-c6cccc7c6oc6ccccc67)cc5)c5ccc6ccccc6c5)cc4)cc3)cc2)cc1 ; c1ccc(-c2ccc(-c3ccc(-c4ccc(N(c5ccc(-c6ccc(-c7ccccc7)cc6)cc5)c5ccc(-c6cccc7c6oc6ccccc67)cc5)cc4)cc3)cc2)cc1 ; c1ccc(-c2cc(-c3ccccc3)cc(-c3ccc(N(c4ccccc4)c4ccc(-c5cccc6c5oc5ccccc56)cc4)cc3)c2)cc1 ; c1ccc(-c2cc(-c3ccccc3)cc(-c3ccc(N(c4ccc(-c5cccc6c5oc5ccccc56)cc4)c4cccc5ccccc45)cc3)c2)cc1]

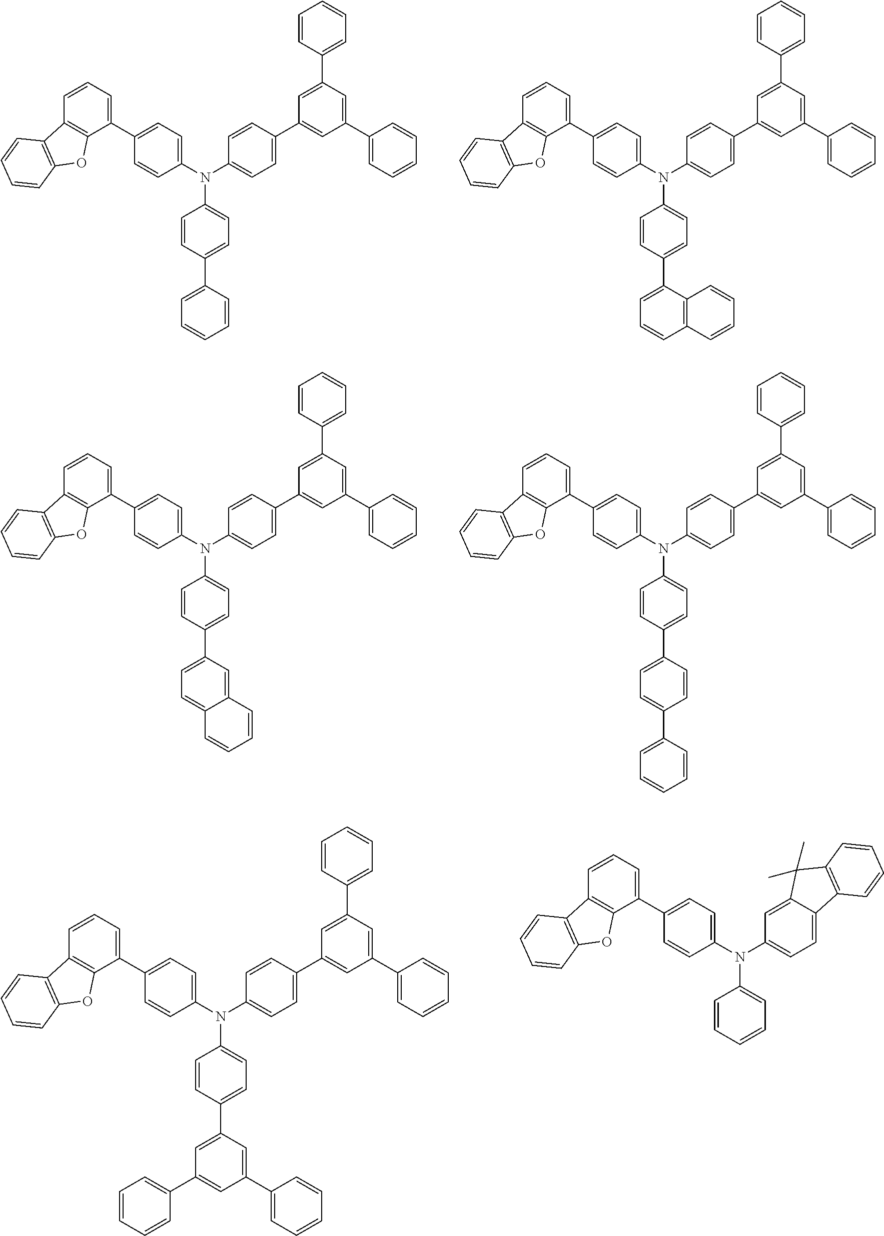

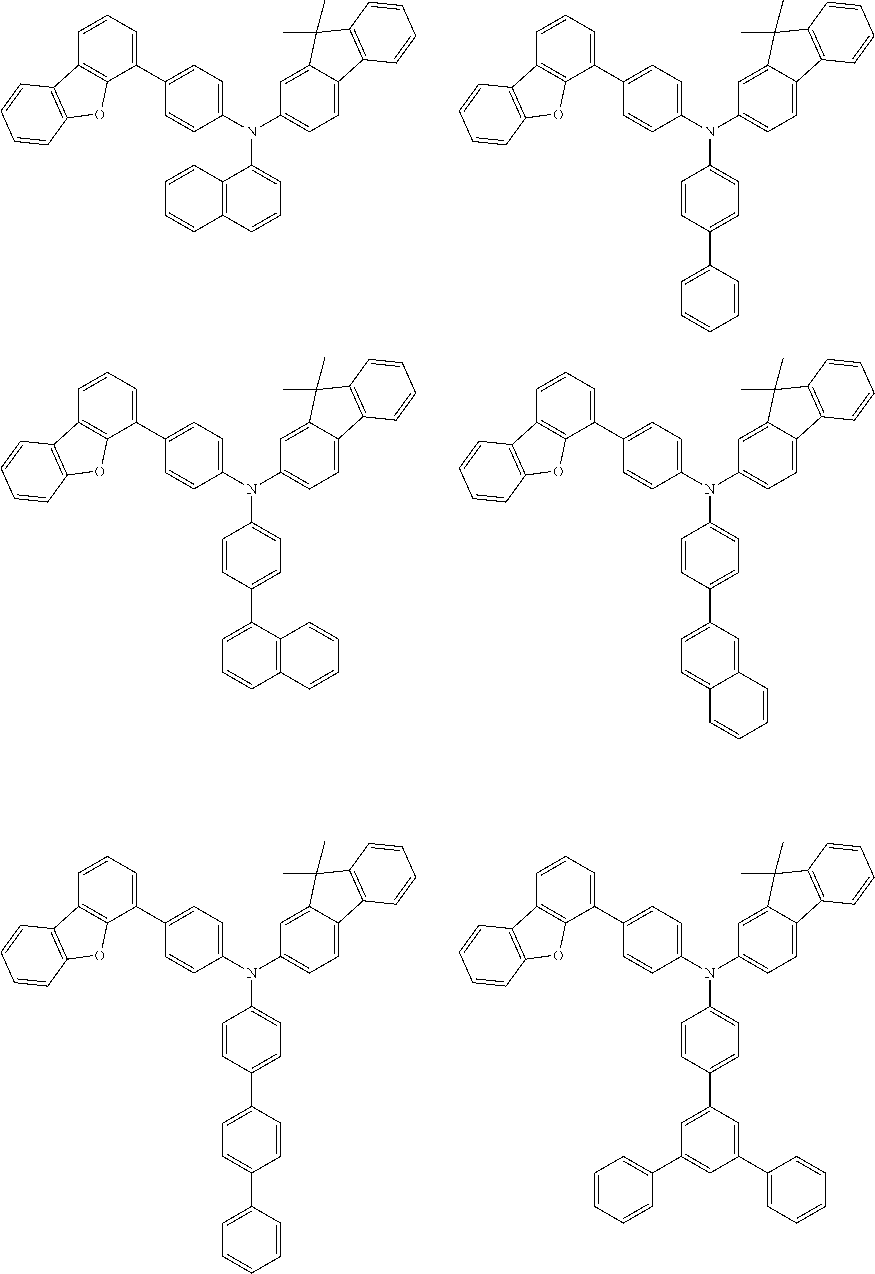

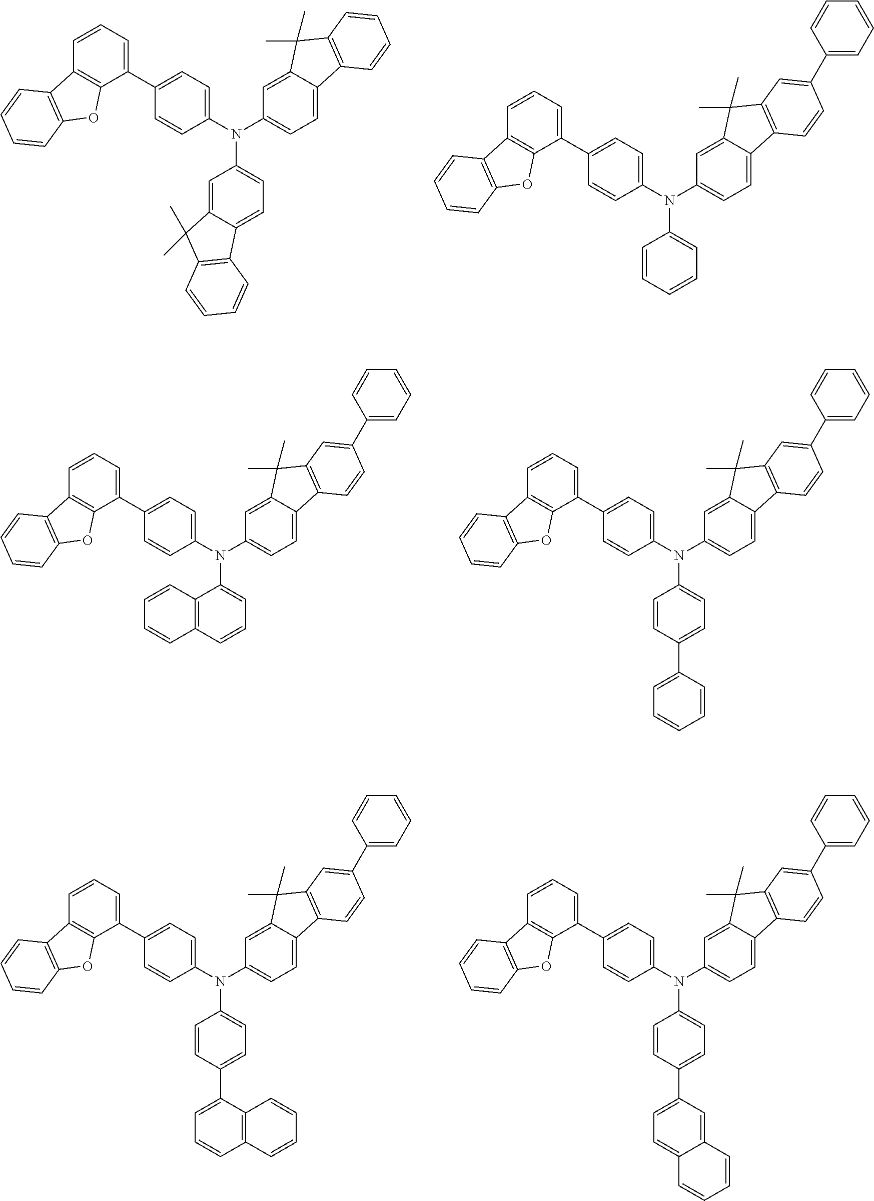

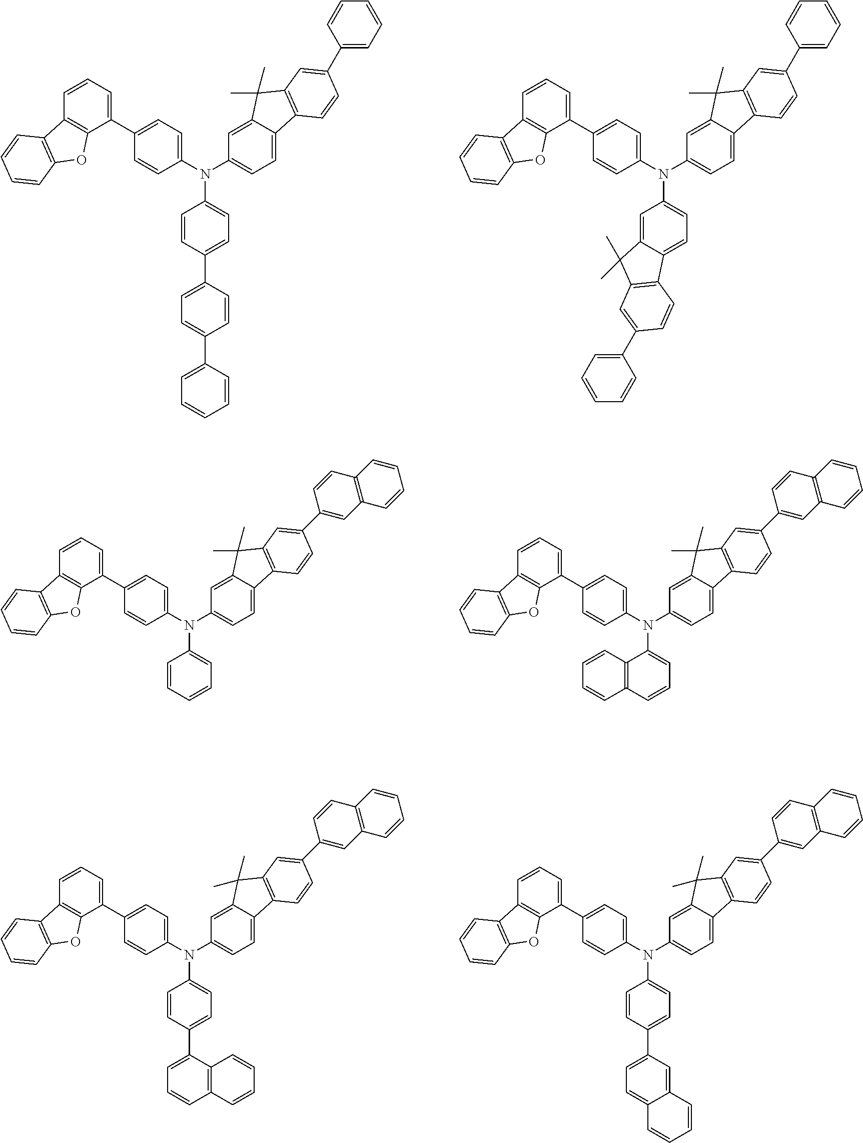

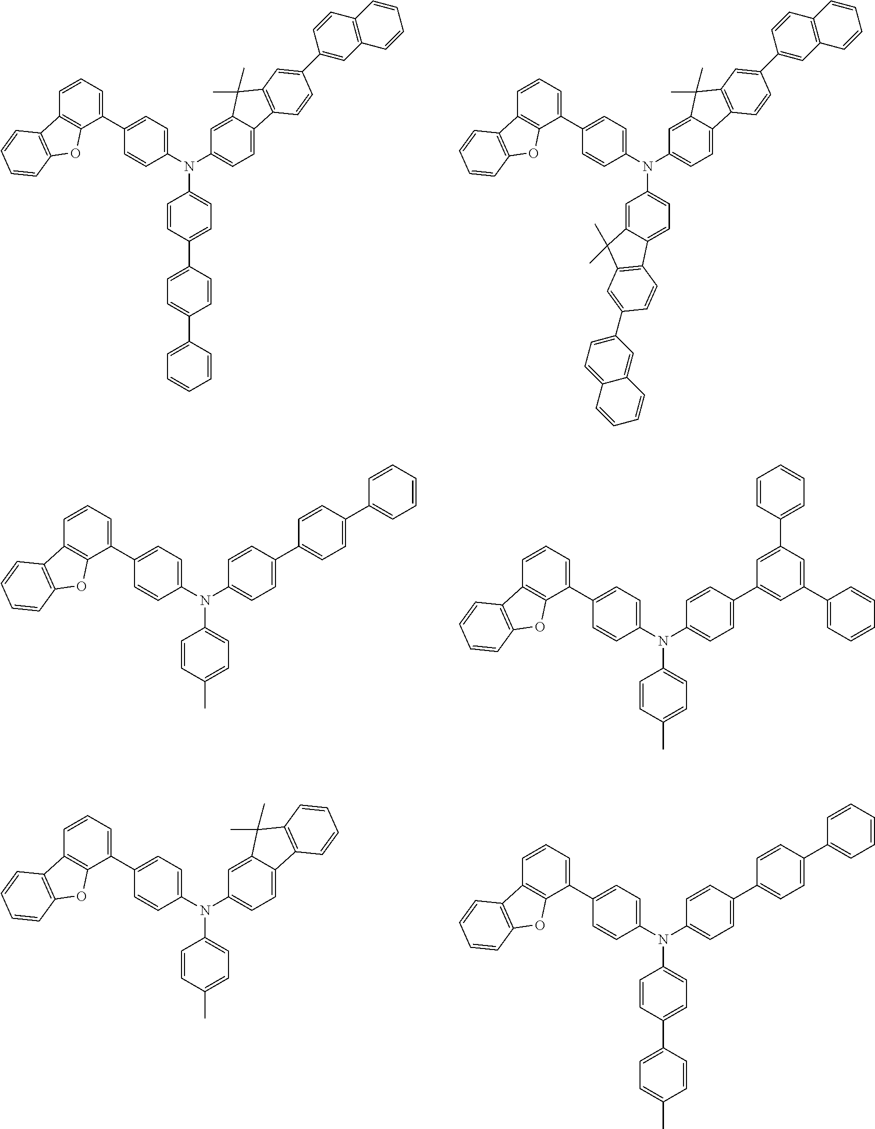

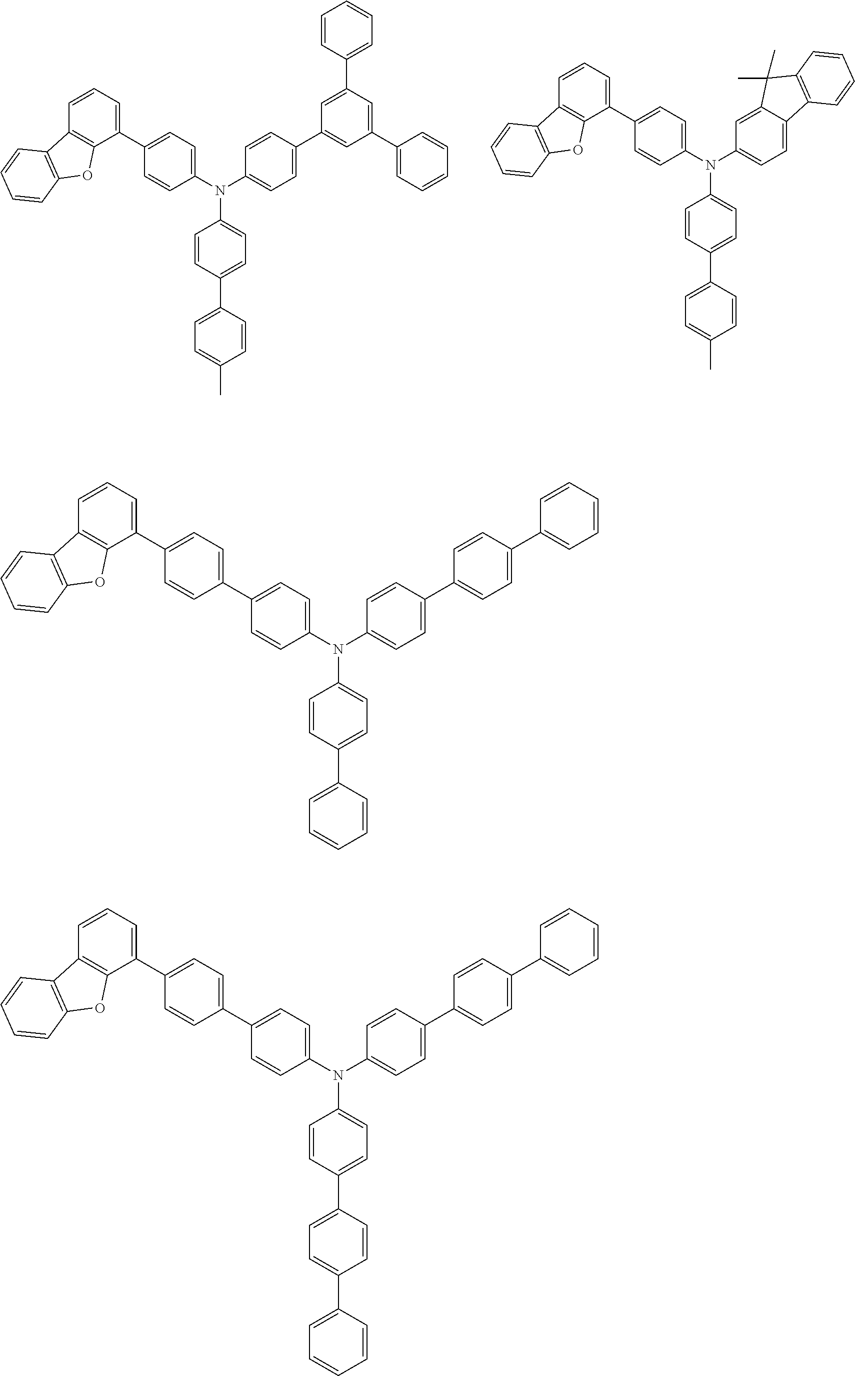

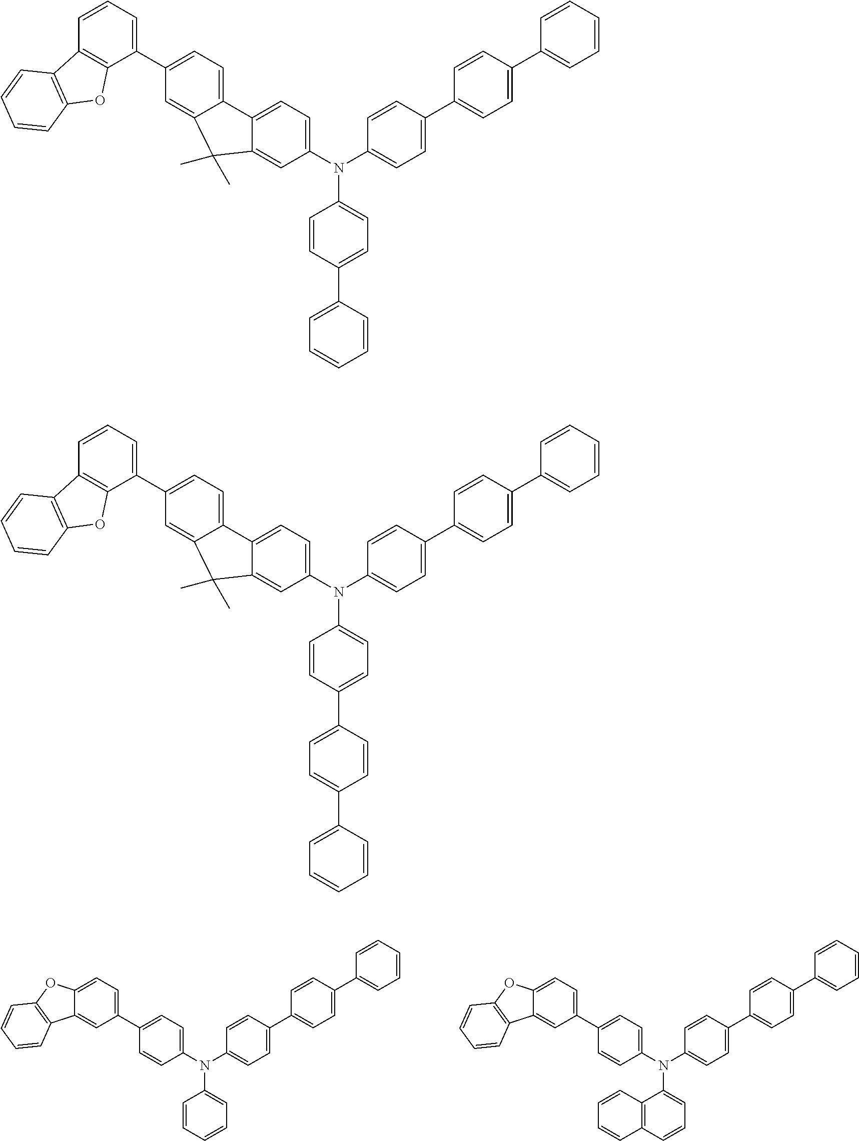 [SMILES: CC1(C)c2cc(-c3cccc4c3oc3ccccc34)ccc2-c2ccc(N(c3ccc(-c4ccccc4)cc3)c3ccc(-c4ccc(-c5ccccc5)cc4)cc3)cc21 ; CC1(C)c2cc(-c3cccc4c3oc3ccccc34)ccc2-c2ccc(N(c3ccc(-c4ccc(-c5ccccc5)cc4)cc3)c3ccc(-c4ccc(-c5ccccc5)cc4)cc3)cc21 ; c1ccc(-c2ccc(-c3ccc(N(c4ccccc4)c4ccc(-c5ccc6oc7ccccc7c6c5)cc4)cc3)cc2)cc1 ; c1ccc(-c2ccc(-c3ccc(N(c4ccc(-c5ccc6oc7ccccc7c6c5)cc4)c4cccc5ccccc45)cc3)cc2)cc1]

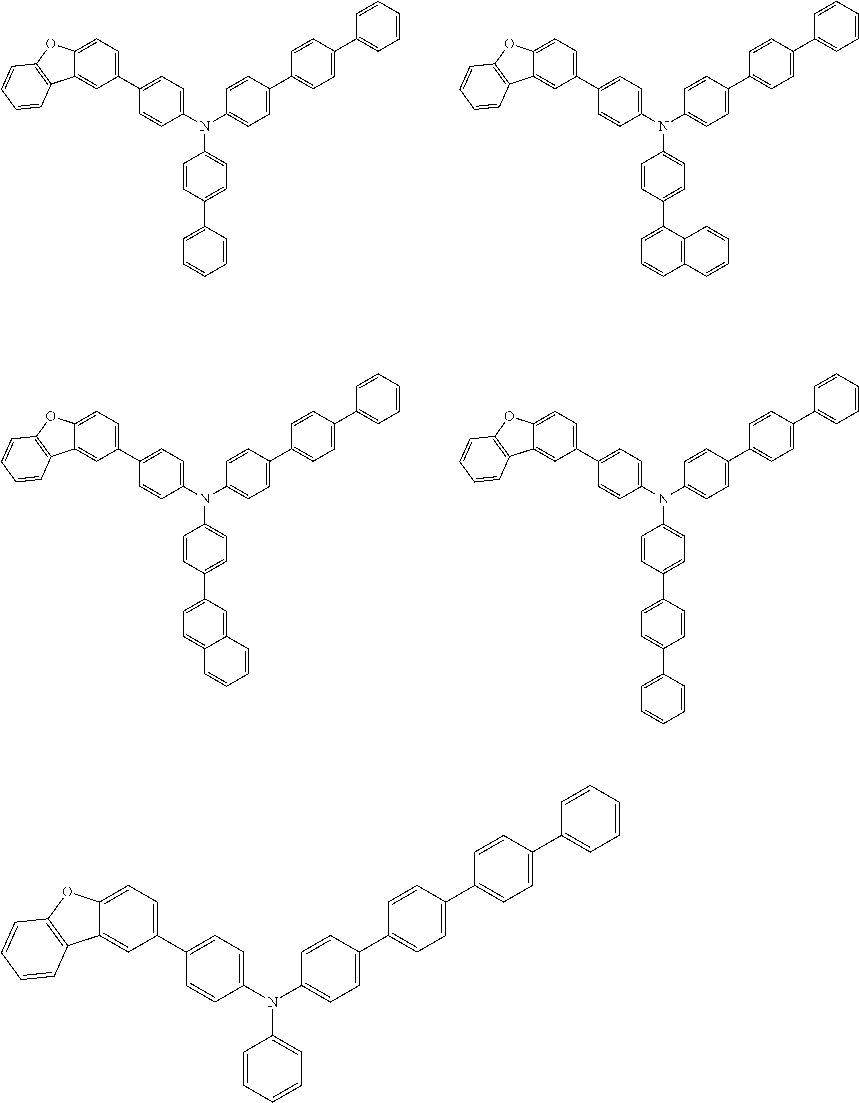 [SMILES: c1ccc(-c2ccc(-c3ccc(N(c4ccc(-c5ccccc5)cc4)c4ccc(-c5ccc6oc7ccccc7c6c5)cc4)cc3)cc2)cc1 ; c1ccc(-c2ccc(-c3ccc(N(c4ccc(-c5ccc6oc7ccccc7c6c5)cc4)c4ccc(-c5cccc6ccccc56)cc4)cc3)cc2)cc1 ; c1ccc(-c2ccc(-c3ccc(N(c4ccc(-c5ccc6ccccc6c5)cc4)c4ccc(-c5ccc6oc7ccccc7c6c5)cc4)cc3)cc2)cc1 ; c1ccc(-c2ccc(-c3ccc(N(c4ccc(-c5ccc(-c6ccccc6)cc5)cc4)c4ccc(-c5ccc6oc7ccccc7c6c5)cc4)cc3)cc2)cc1 ; c1ccc(-c2ccc(-c3ccc(-c4ccc(N(c5ccccc5)c5ccc(-c6ccc7oc8ccccc8c7c6)cc5)cc4)cc3)cc2)cc1]

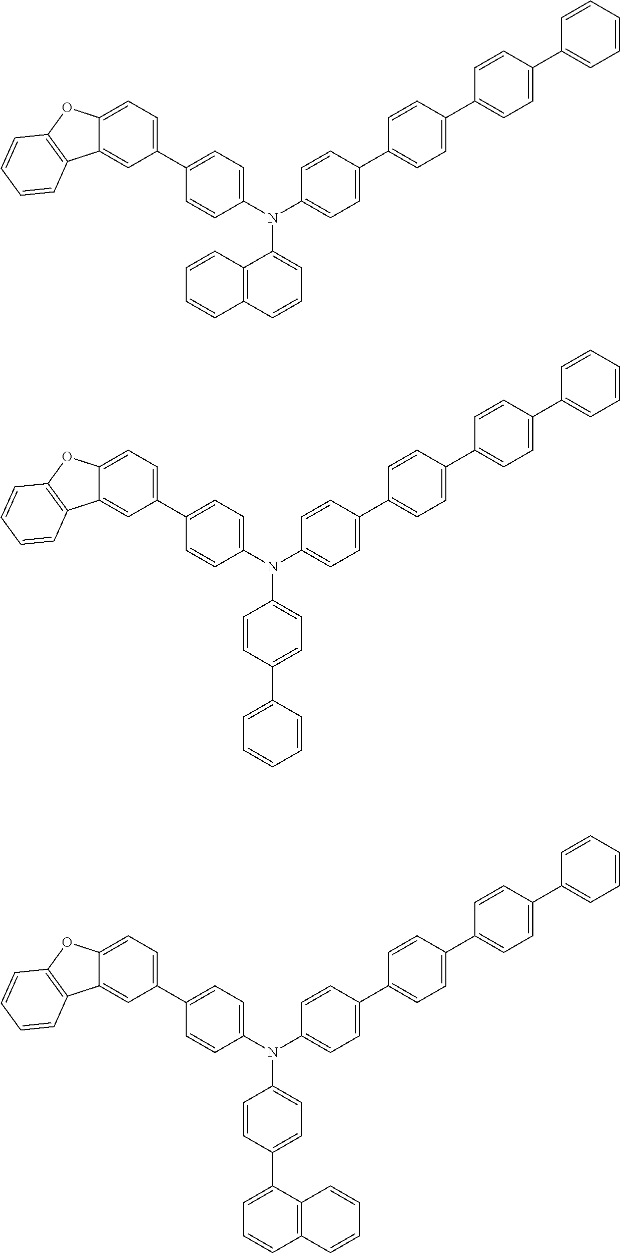 [SMILES: c1ccc(-c2ccc(-c3ccc(-c4ccc(N(c5ccc(-c6ccc7oc8ccccc8c7c6)cc5)c5cccc6ccccc56)cc4)cc3)cc2)cc1 ; c1ccc(-c2ccc(-c3ccc(-c4ccc(N(c5ccc(-c6ccccc6)cc5)c5ccc(-c6ccc7oc8ccccc8c7c6)cc5)cc4)cc3)cc2)cc1 ; c1ccc(-c2ccc(-c3ccc(-c4ccc(N(c5ccc(-c6ccc7oc8ccccc8c7c6)cc5)c5ccc(-c6cccc7ccccc67)cc5)cc4)cc3)cc2)cc1]

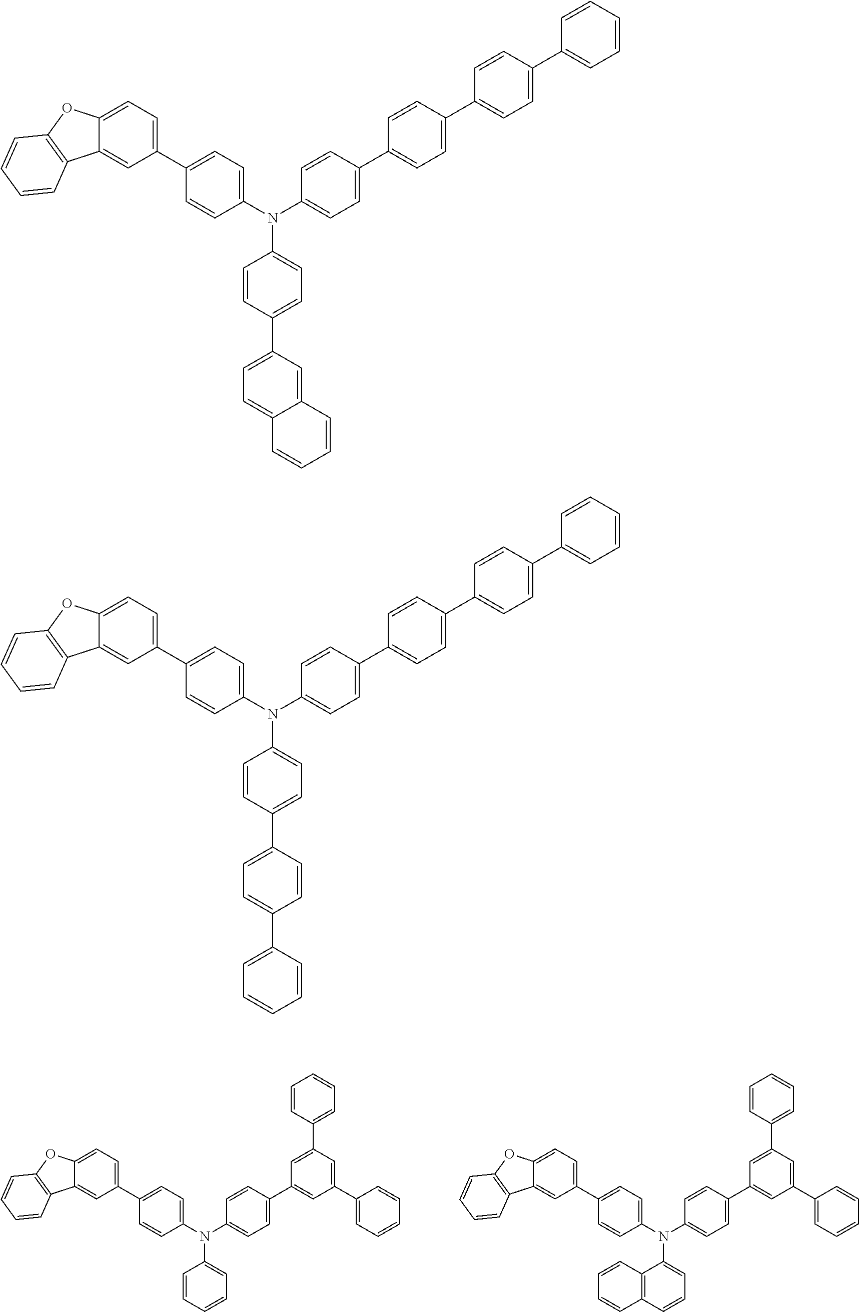 [SMILES: c1ccc(-c2ccc(-c3ccc(-c4ccc(N(c5ccc(-c6ccc7ccccc7c6)cc5)c5ccc(-c6ccc7oc8ccccc8c7c6)cc5)cc4)cc3)cc2)cc1 ; c1ccc(-c2ccc(-c3ccc(-c4ccc(N(c5ccc(-c6ccc(-c7ccccc7)cc6)cc5)c5ccc(-c6ccc7oc8ccccc8c7c6)cc5)cc4)cc3)cc2)cc1 ; c1ccc(-c2cc(-c3ccccc3)cc(-c3ccc(N(c4ccccc4)c4ccc(-c5ccc6oc7ccccc7c6c5)cc4)cc3)c2)cc1 ; c1ccc(-c2cc(-c3ccccc3)cc(-c3ccc(N(c4ccc(-c5ccc6oc7ccccc7c6c5)cc4)c4cccc5ccccc45)cc3)c2)cc1]

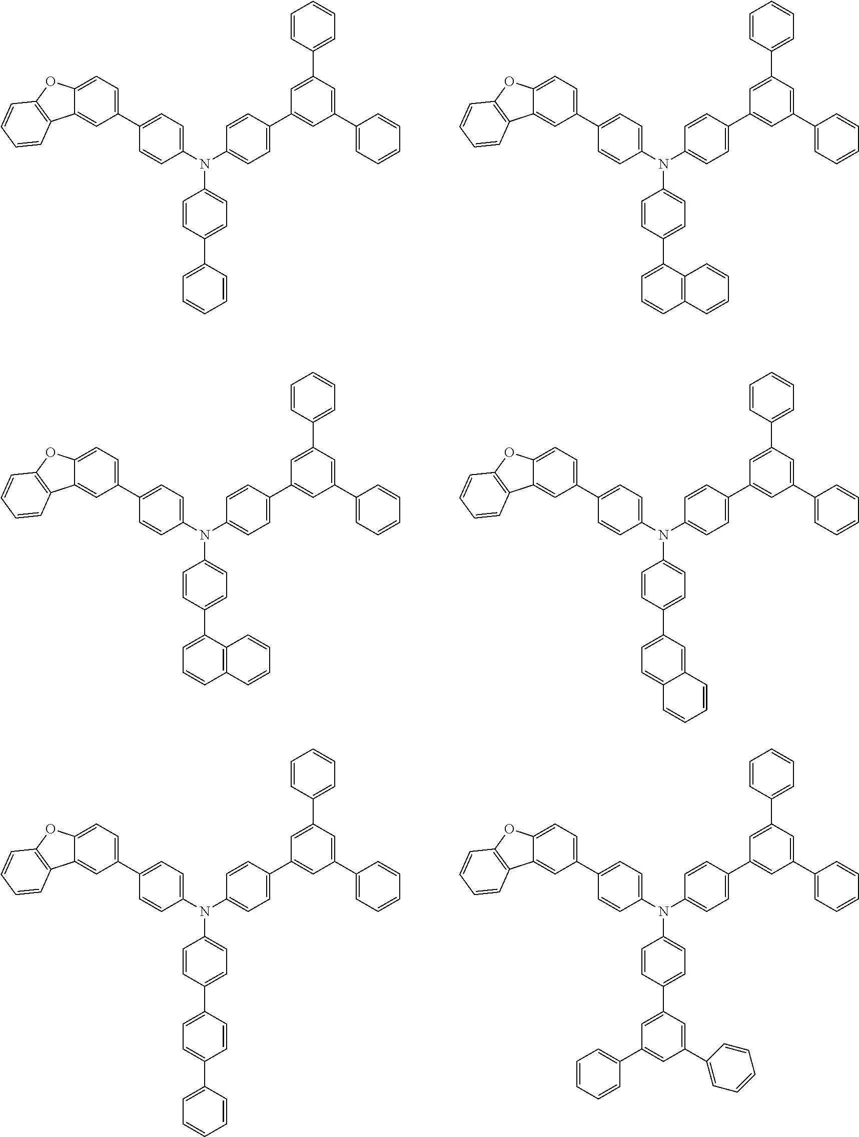

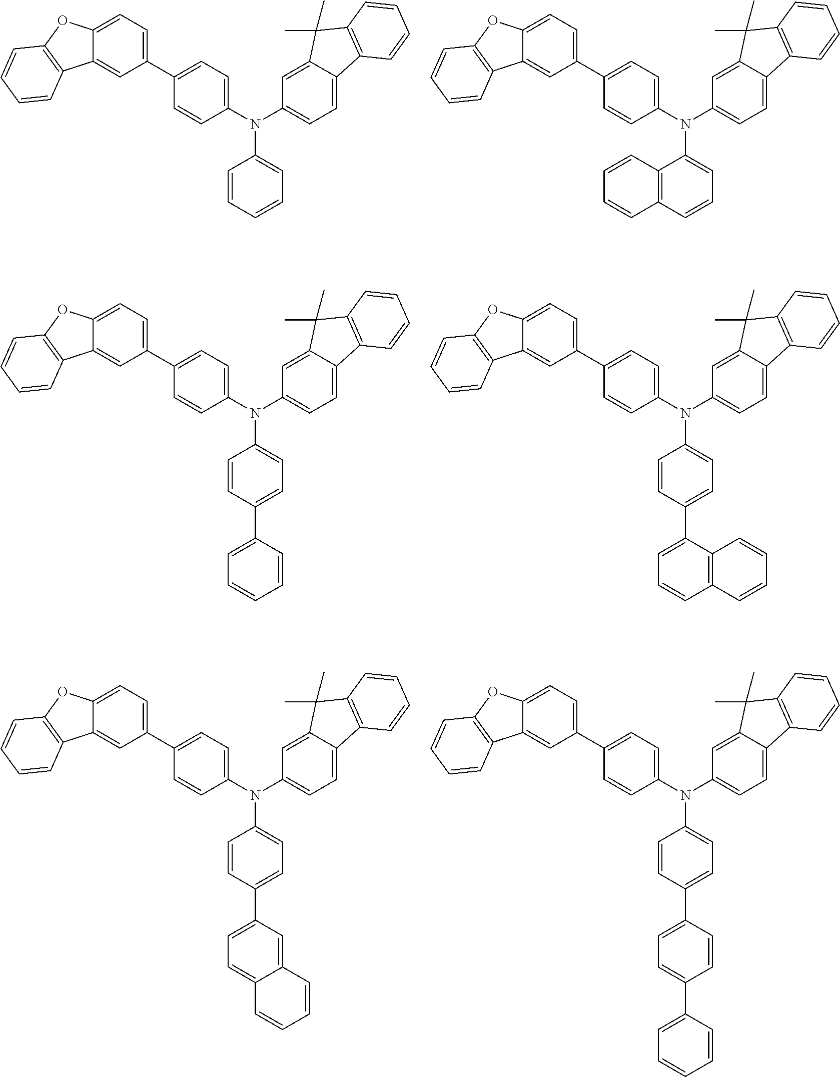

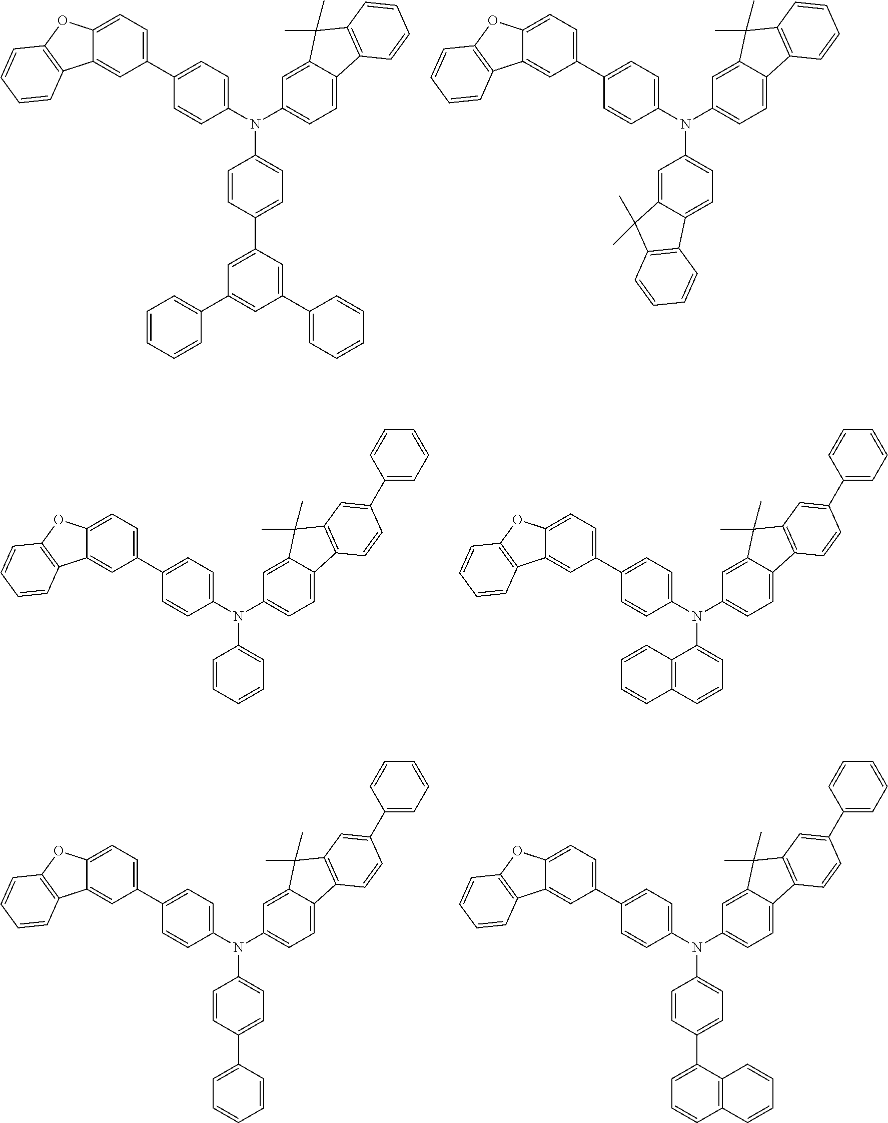

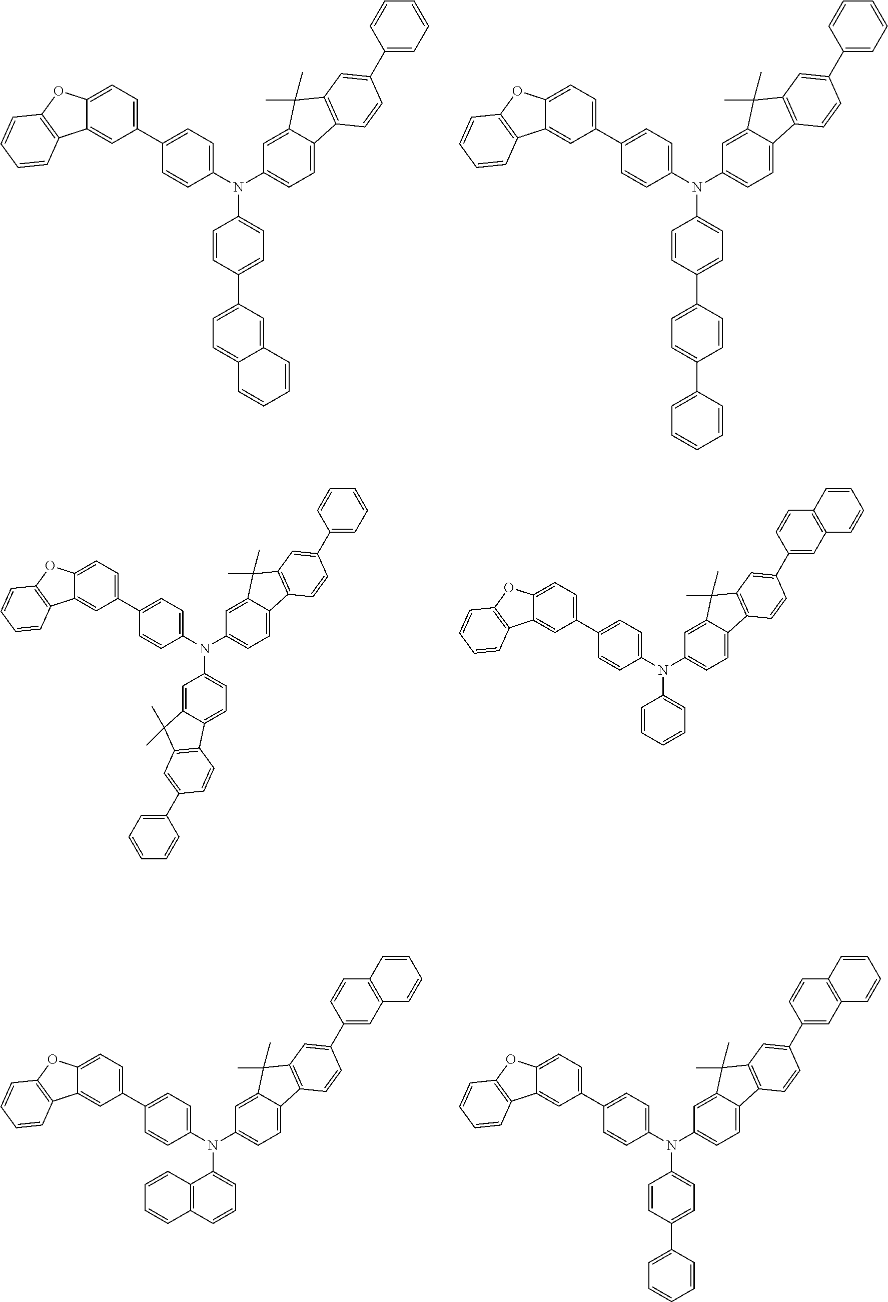

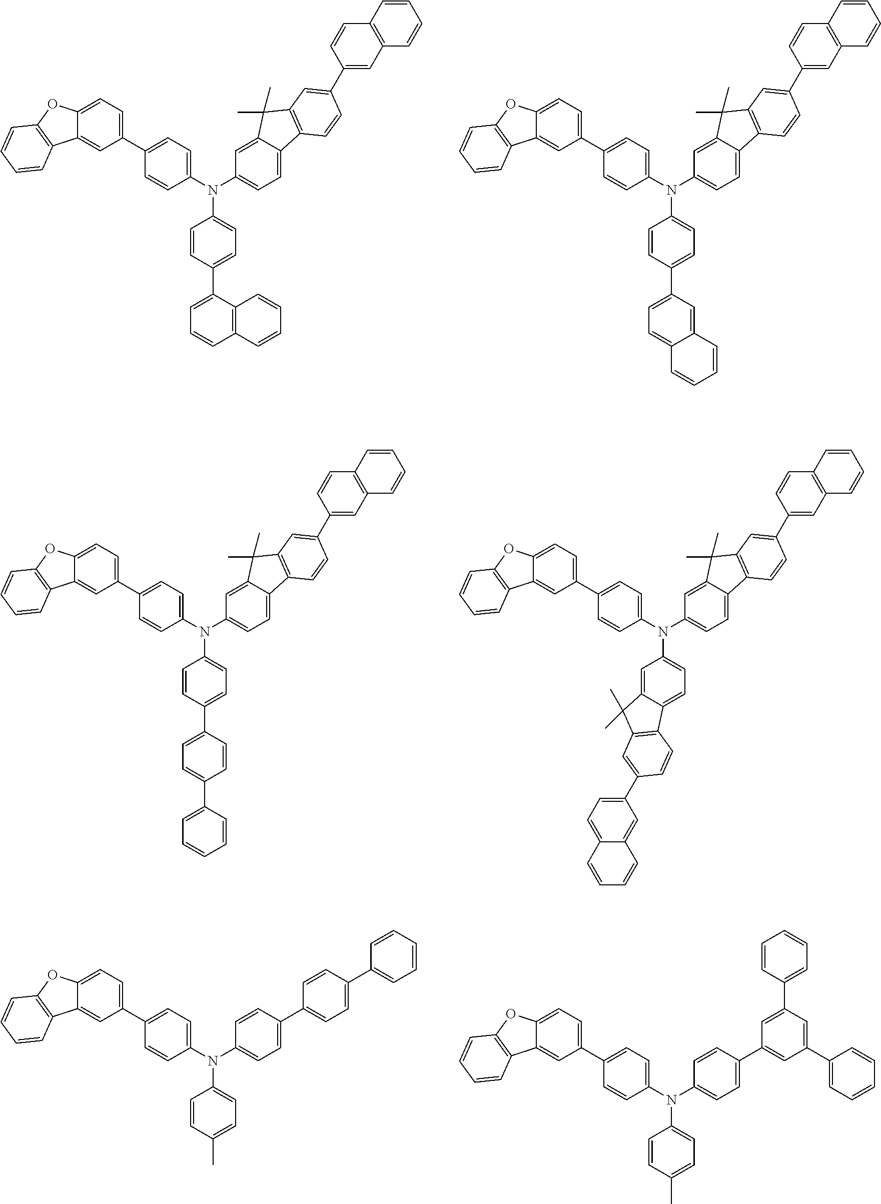

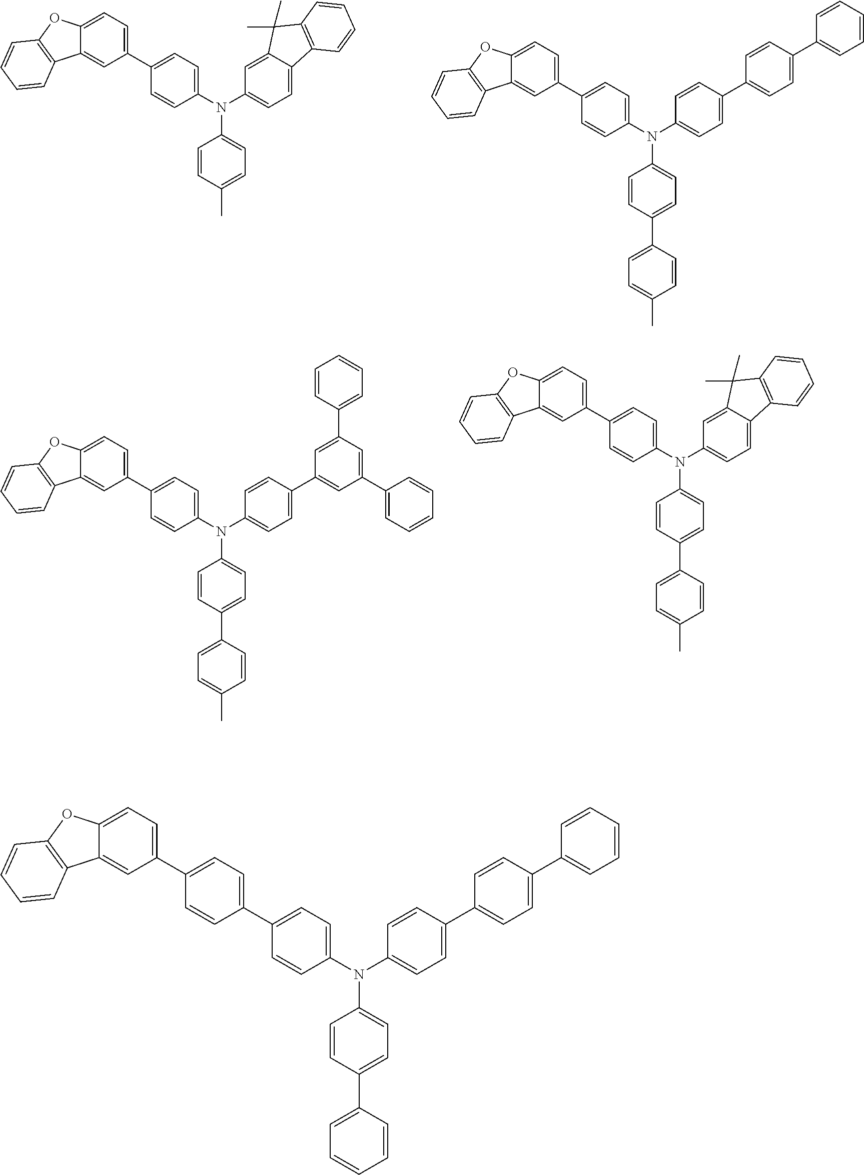 [SMILES: Cc1ccc(N(c2ccc(-c3ccc4oc5ccccc5c4c3)cc2)c2ccc3c(c2)C(C)(C)c2ccccc2-3)cc1 ; Cc1ccc(-c2ccc(N(c3ccc(-c4ccc(-c5ccccc5)cc4)cc3)c3ccc(-c4ccc5oc6ccccc6c5c4)cc3)cc2)cc1 ; Cc1ccc(-c2ccc(N(c3ccc(-c4cc(-c5ccccc5)cc(-c5ccccc5)c4)cc3)c3ccc(-c4ccc5oc6ccccc6c5c4)cc3)cc2)cc1 ; Cc1ccc(-c2ccc(N(c3ccc(-c4ccc5oc6ccccc6c5c4)cc3)c3ccc4c(c3)C(C)(C)c3ccccc3-4)cc2)cc1 ; c1ccc(-c2ccc(-c3ccc(N(c4ccc(-c5ccccc5)cc4)c4ccc(-c5ccc(-c6ccc7oc8ccccc8c7c6)cc5)cc4)cc3)cc2)cc1]

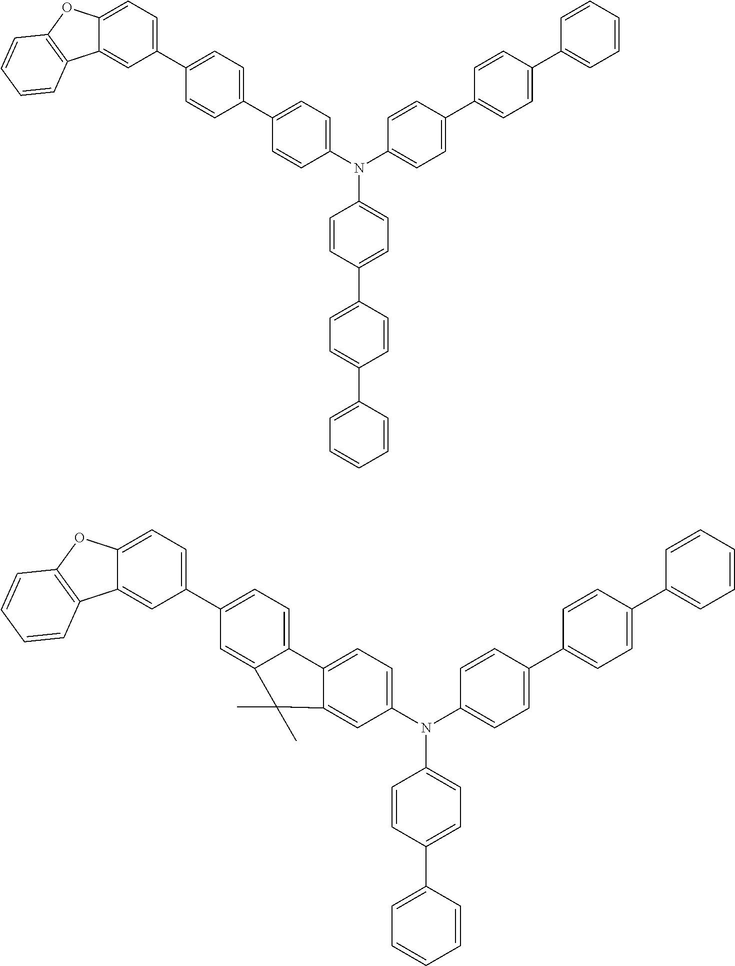 [SMILES: c1ccc(-c2ccc(-c3ccc(N(c4ccc(-c5ccc(-c6ccccc6)cc5)cc4)c4ccc(-c5ccc(-c6ccc7oc8ccccc8c7c6)cc5)cc4)cc3)cc2)cc1 ; CC1(C)c2cc(-c3ccc4oc5ccccc5c4c3)ccc2-c2ccc(N(c3ccc(-c4ccccc4)cc3)c3ccc(-c4ccc(-c5ccccc5)cc4)cc3)cc21]

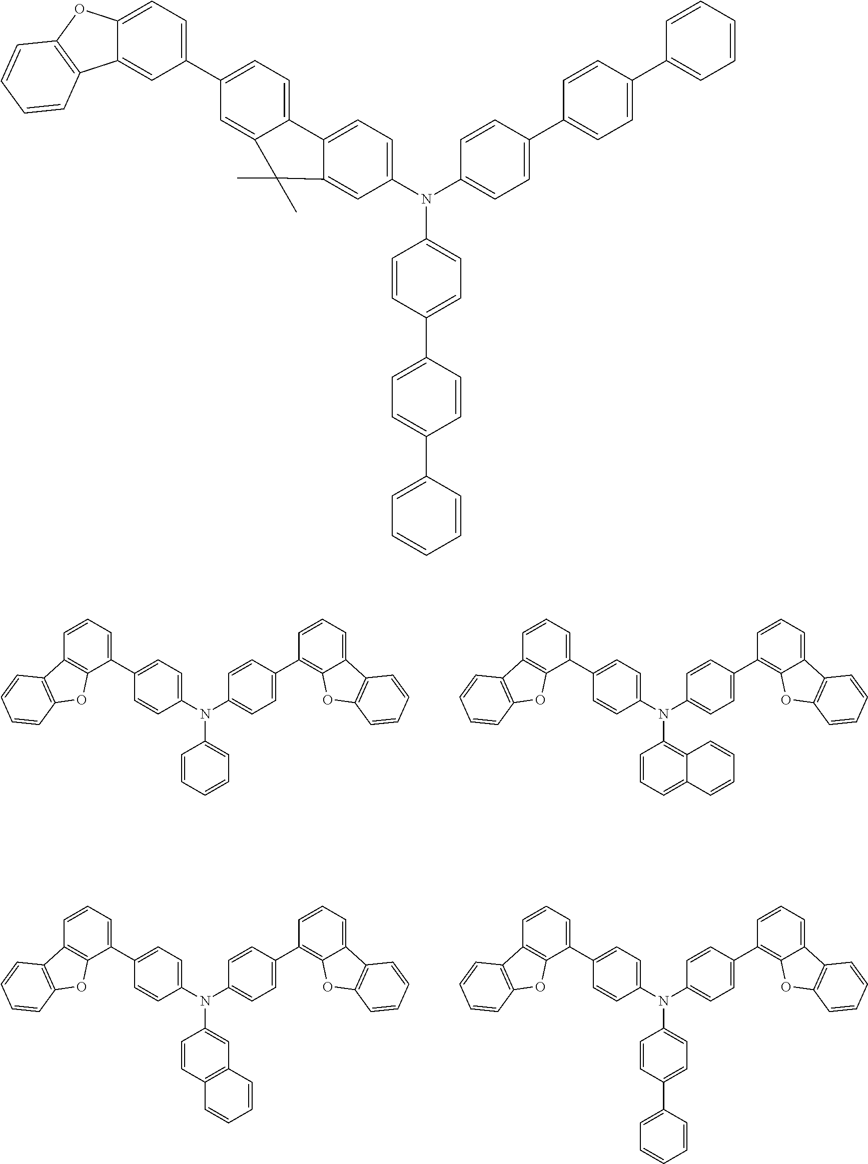 [SMILES: CC1(C)c2cc(-c3ccc4oc5ccccc5c4c3)ccc2-c2ccc(N(c3ccc(-c4ccc(-c5ccccc5)cc4)cc3)c3ccc(-c4ccc(-c5ccccc5)cc4)cc3)cc21 ; c1ccc(N(c2ccc(-c3cccc4c3oc3ccccc34)cc2)c2ccc(-c3cccc4c3oc3ccccc34)cc2)cc1 ; c1ccc2c(N(c3ccc(-c4cccc5c4oc4ccccc45)cc3)c3ccc(-c4cccc5c4oc4ccccc45)cc3)cccc2c1 ; c1ccc2cc(N(c3ccc(-c4cccc5c4oc4ccccc45)cc3)c3ccc(-c4cccc5c4oc4ccccc45)cc3)ccc2c1 ; c1ccc(-c2ccc(N(c3ccc(-c4cccc5c4oc4ccccc45)cc3)c3ccc(-c4cccc5c4oc4ccccc45)cc3)cc2)cc1]

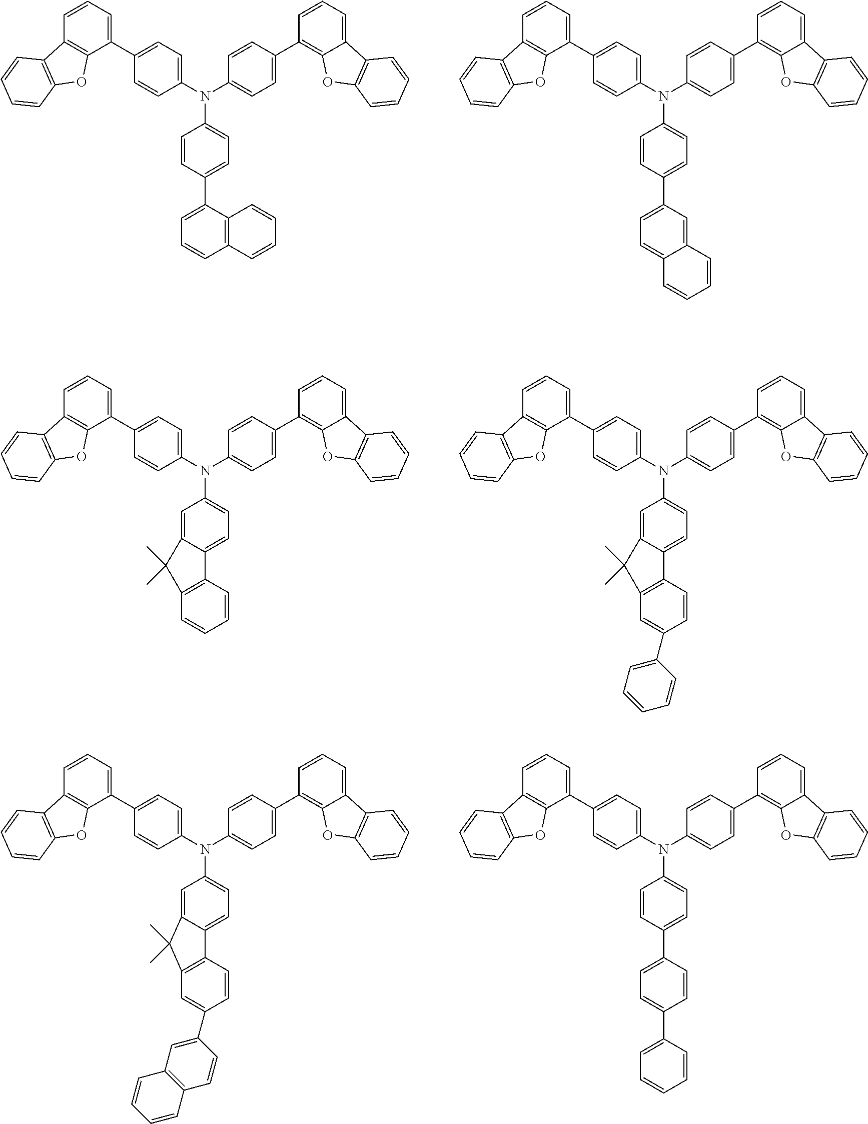

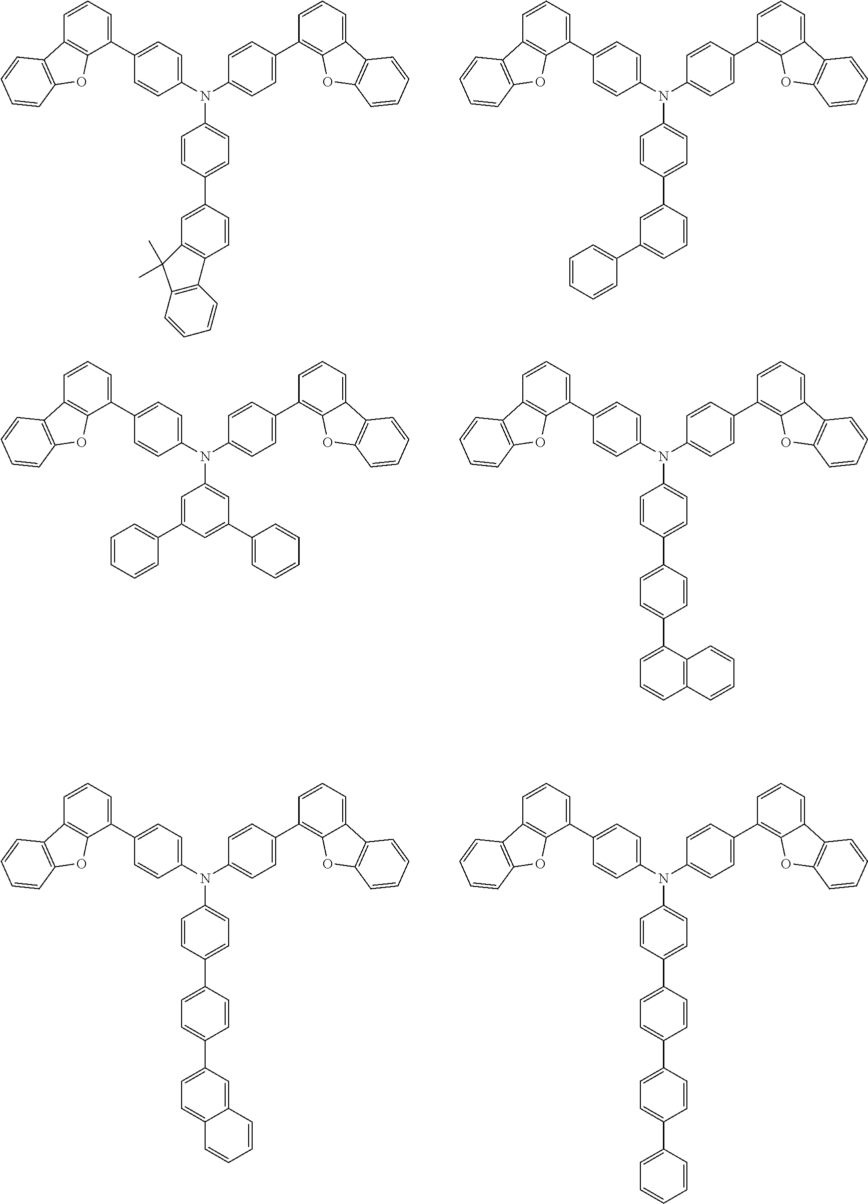

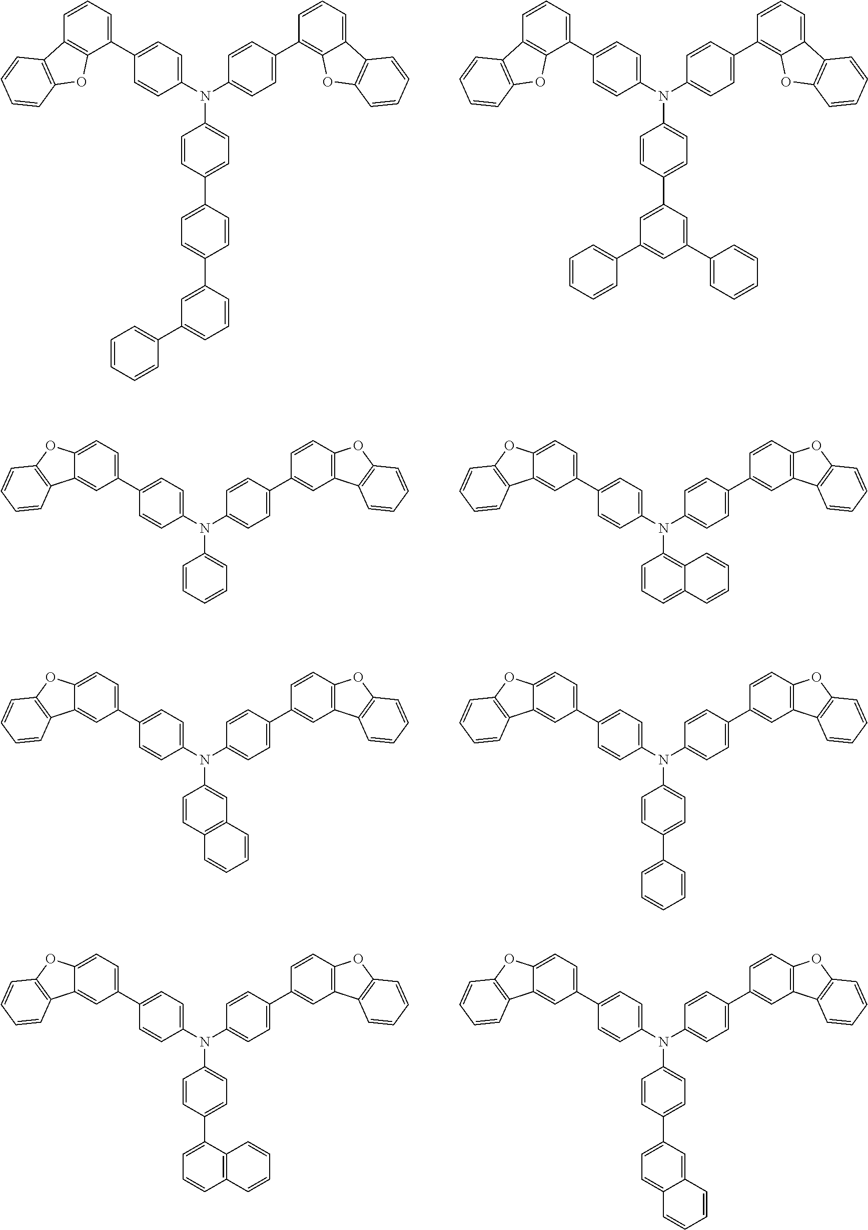

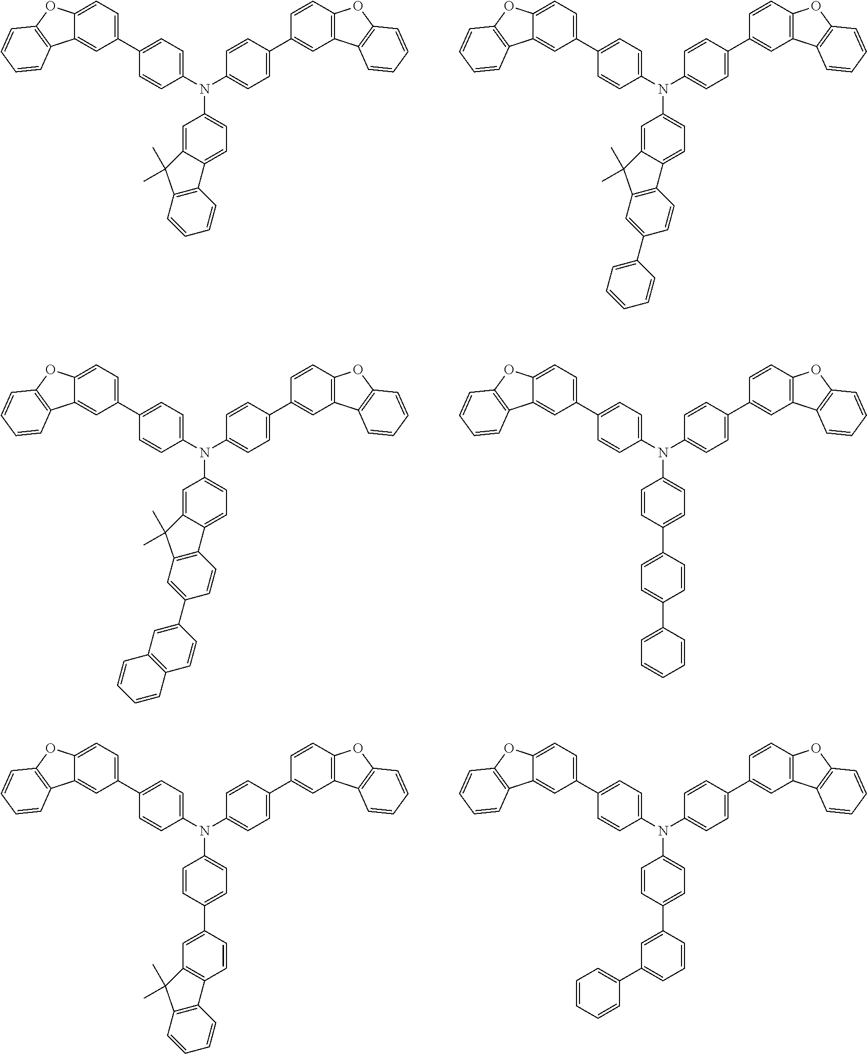

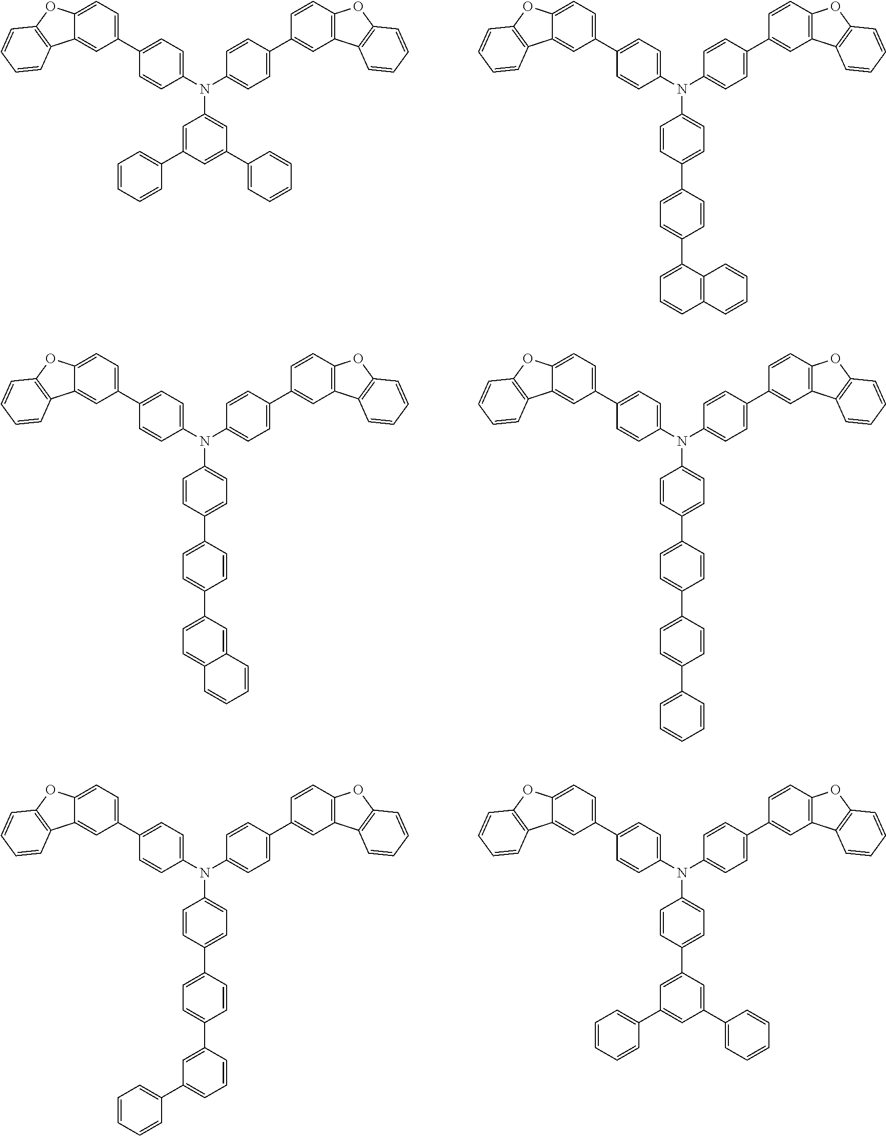

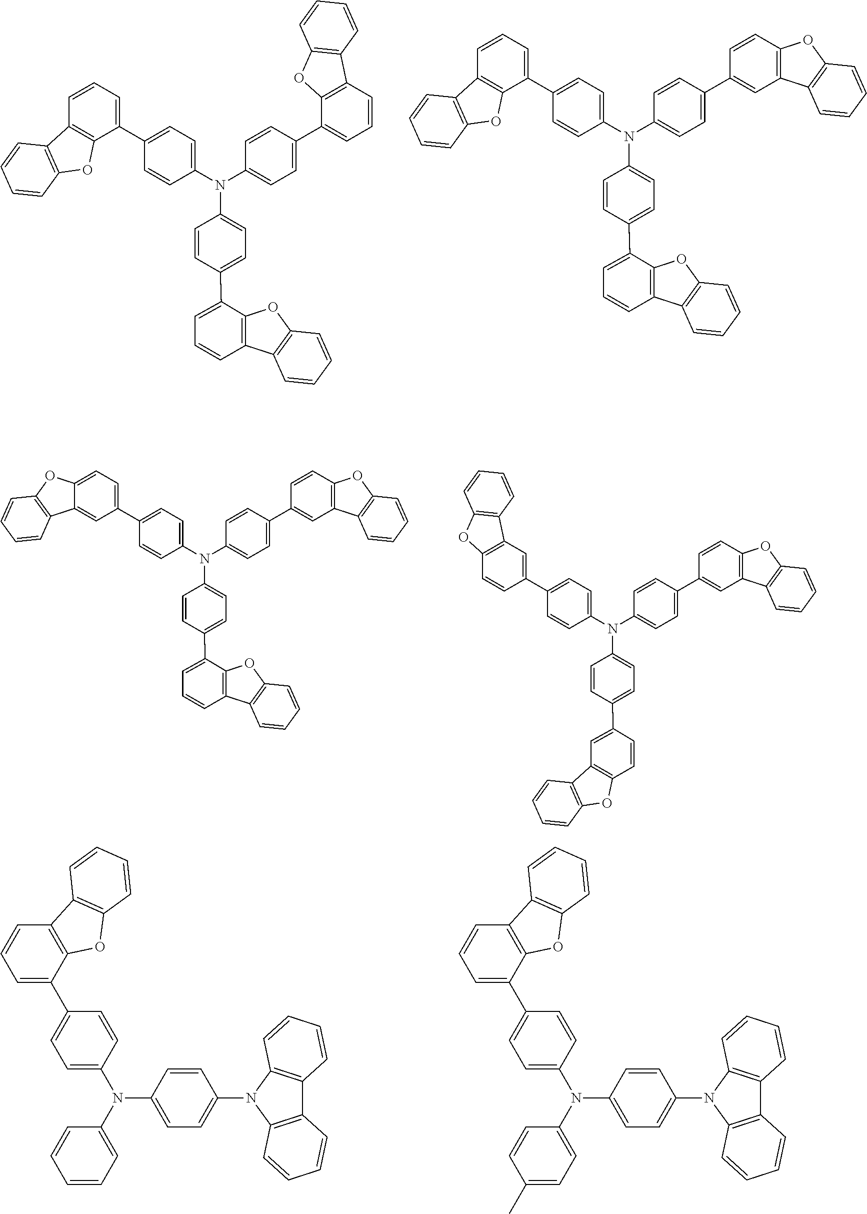

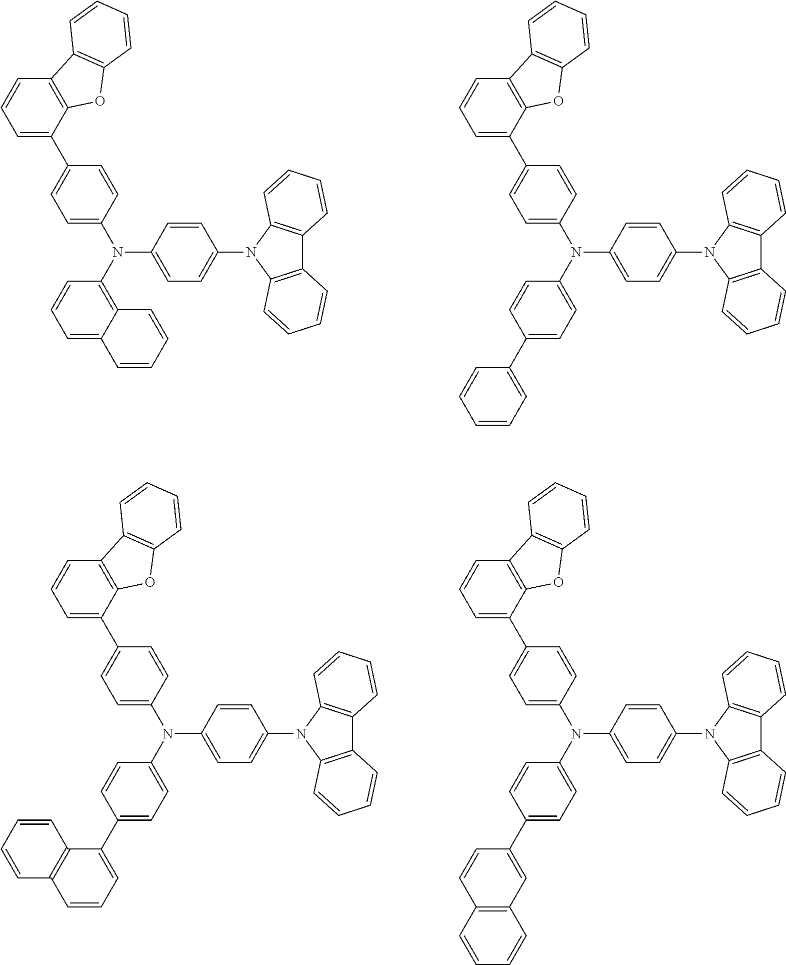 [SMILES: c1ccc2c(N(c3ccc(-c4cccc5c4oc4ccccc45)cc3)c3ccc(-n4c5ccccc5c5ccccc54)cc3)cccc2c1 ; c1ccc(-c2ccc(N(c3ccc(-c4cccc5c4oc4ccccc45)cc3)c3ccc(-n4c5ccccc5c5ccccc54)cc3)cc2)cc1 ; c1ccc2c(-c3ccc(N(c4ccc(-c5cccc6c5oc5ccccc56)cc4)c4ccc(-n5c6ccccc6c6ccccc65)cc4)cc3)cccc2c1 ; c1ccc2cc(-c3ccc(N(c4ccc(-c5cccc6c5oc5ccccc56)cc4)c4ccc(-n5c6ccccc6c6ccccc65)cc4)cc3)ccc2c1]

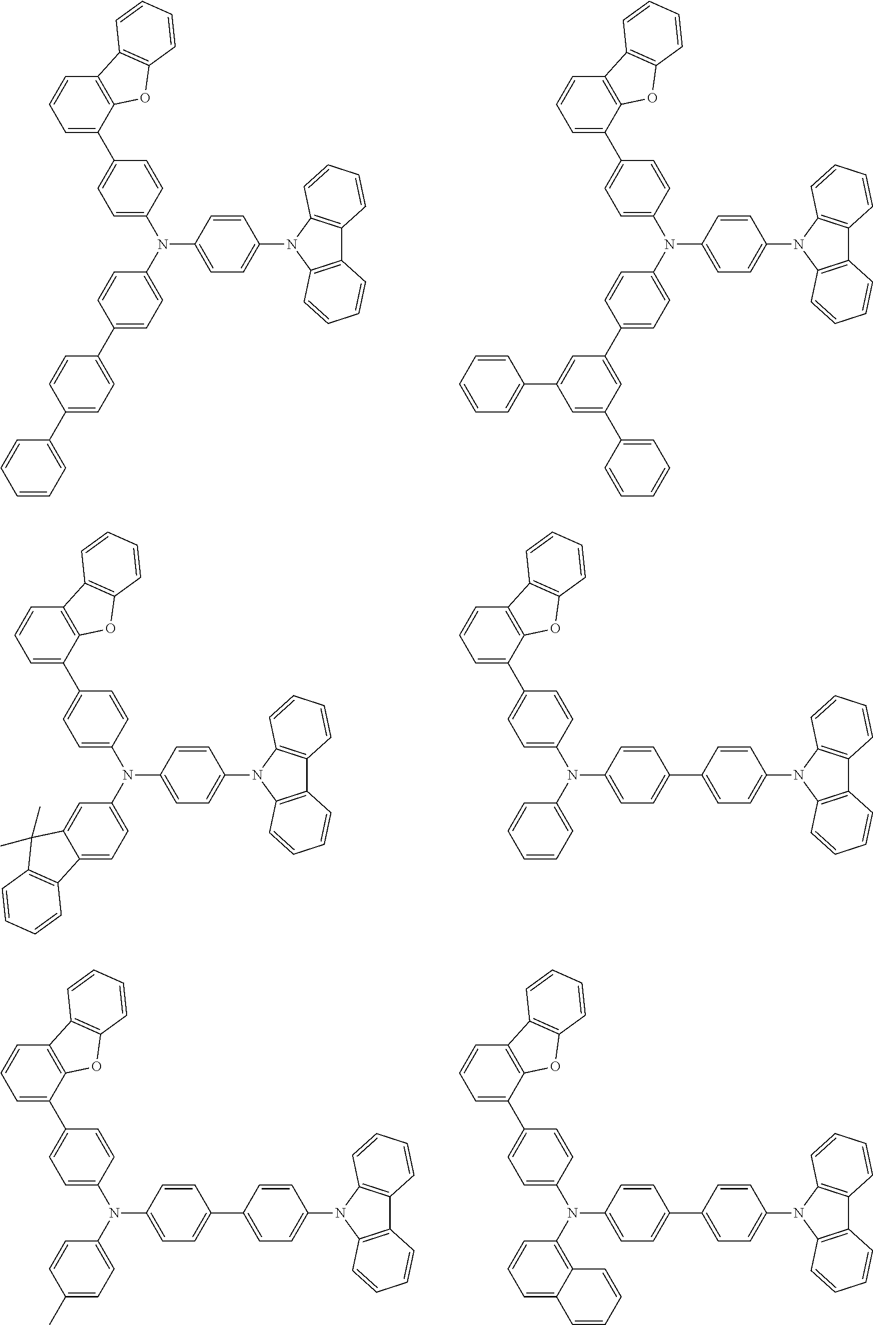

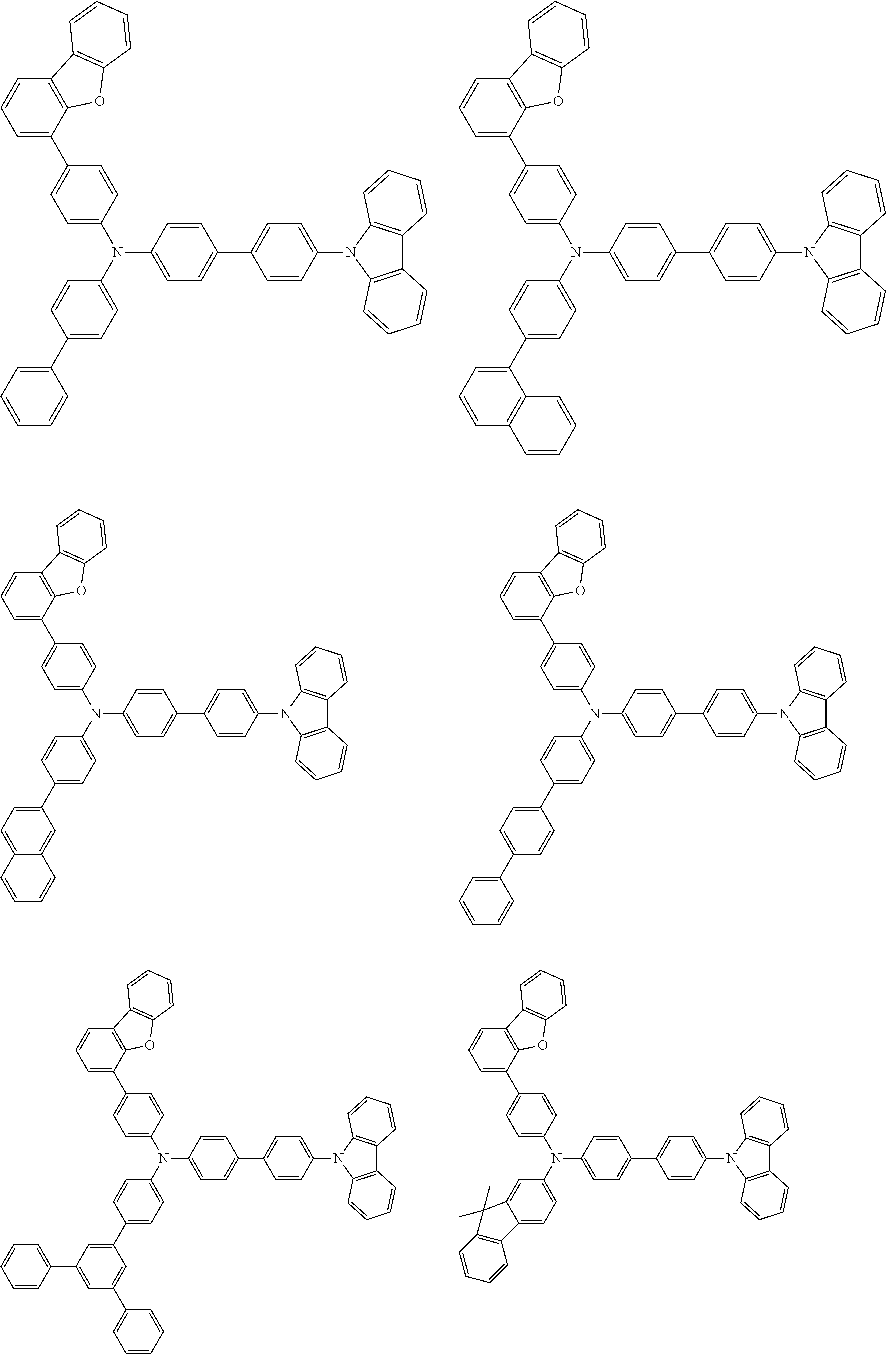

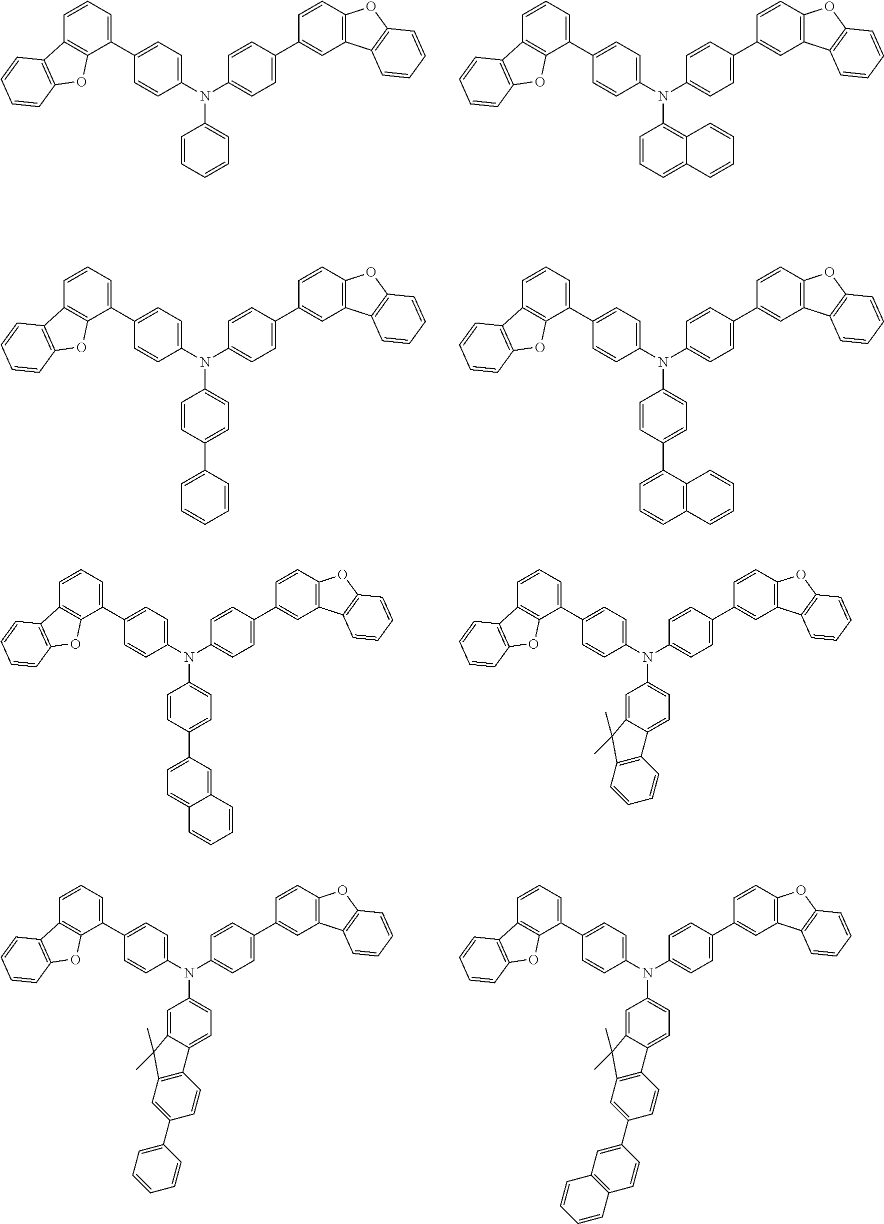

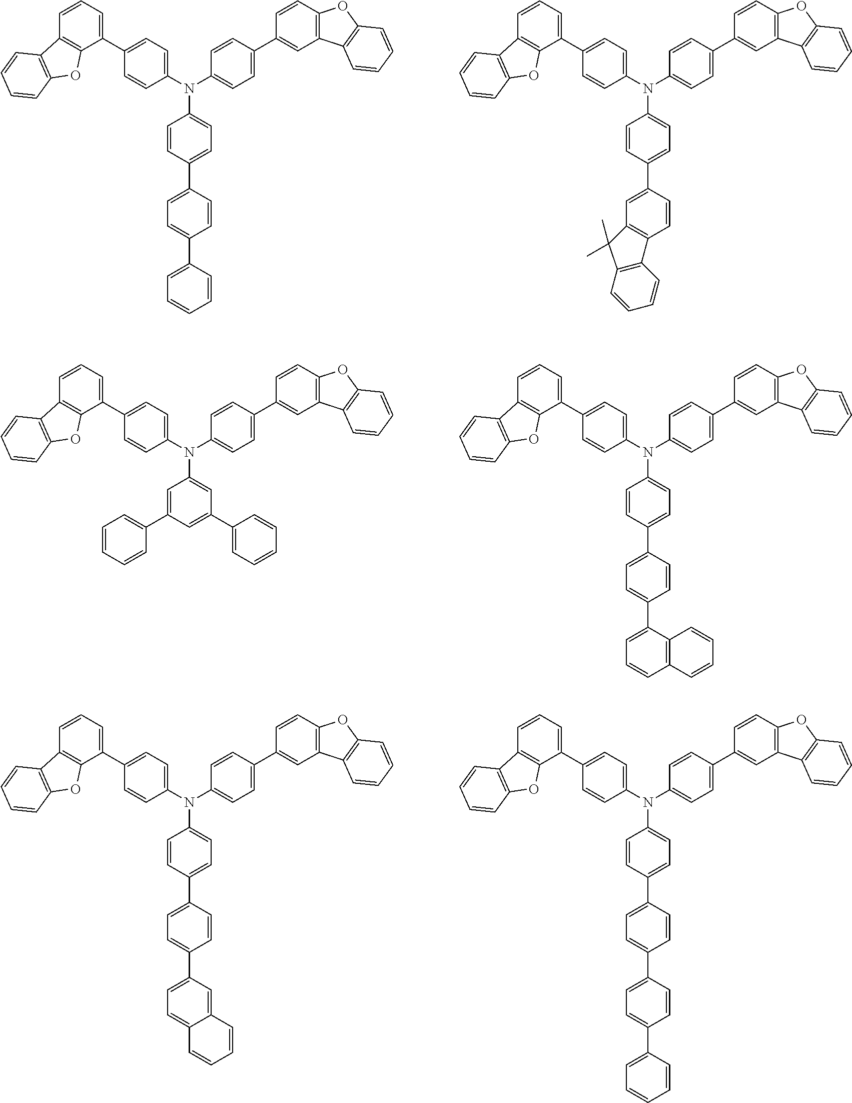

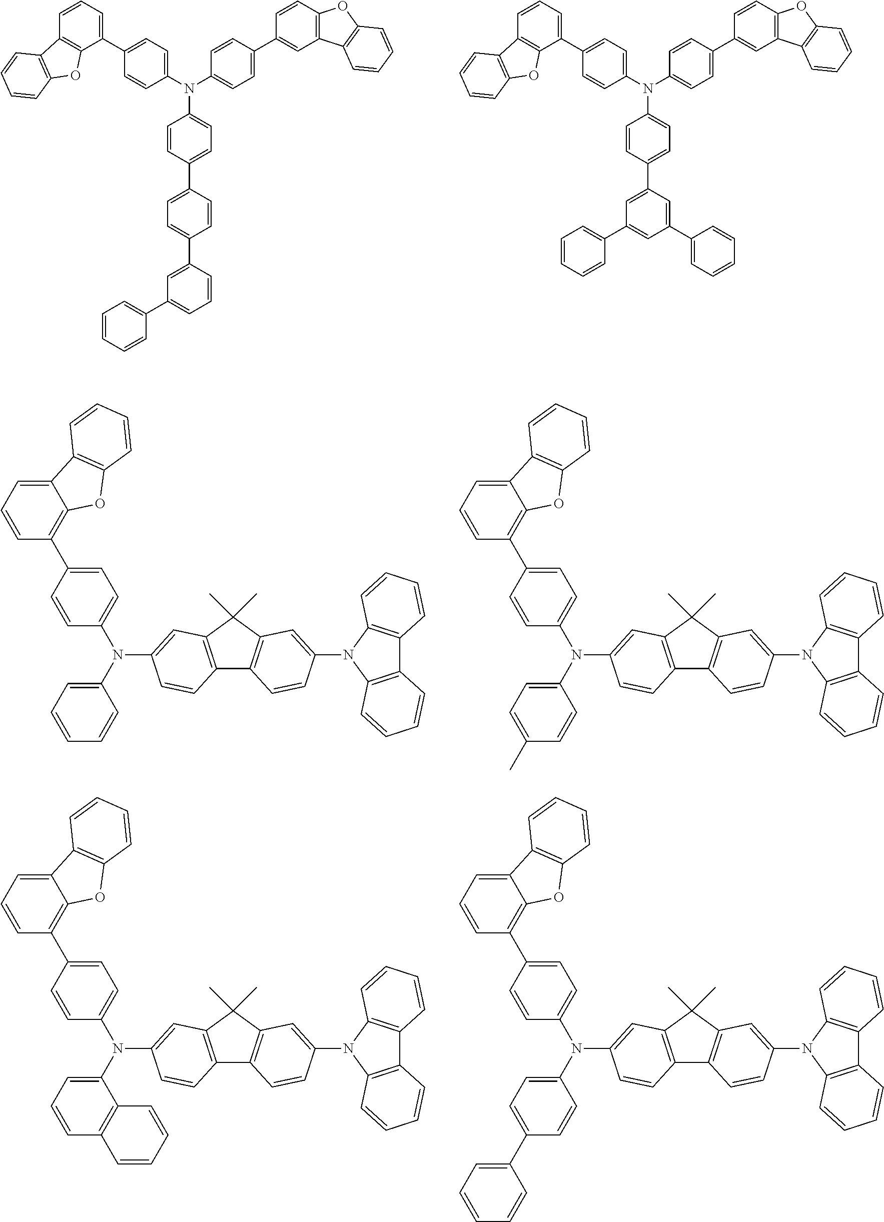

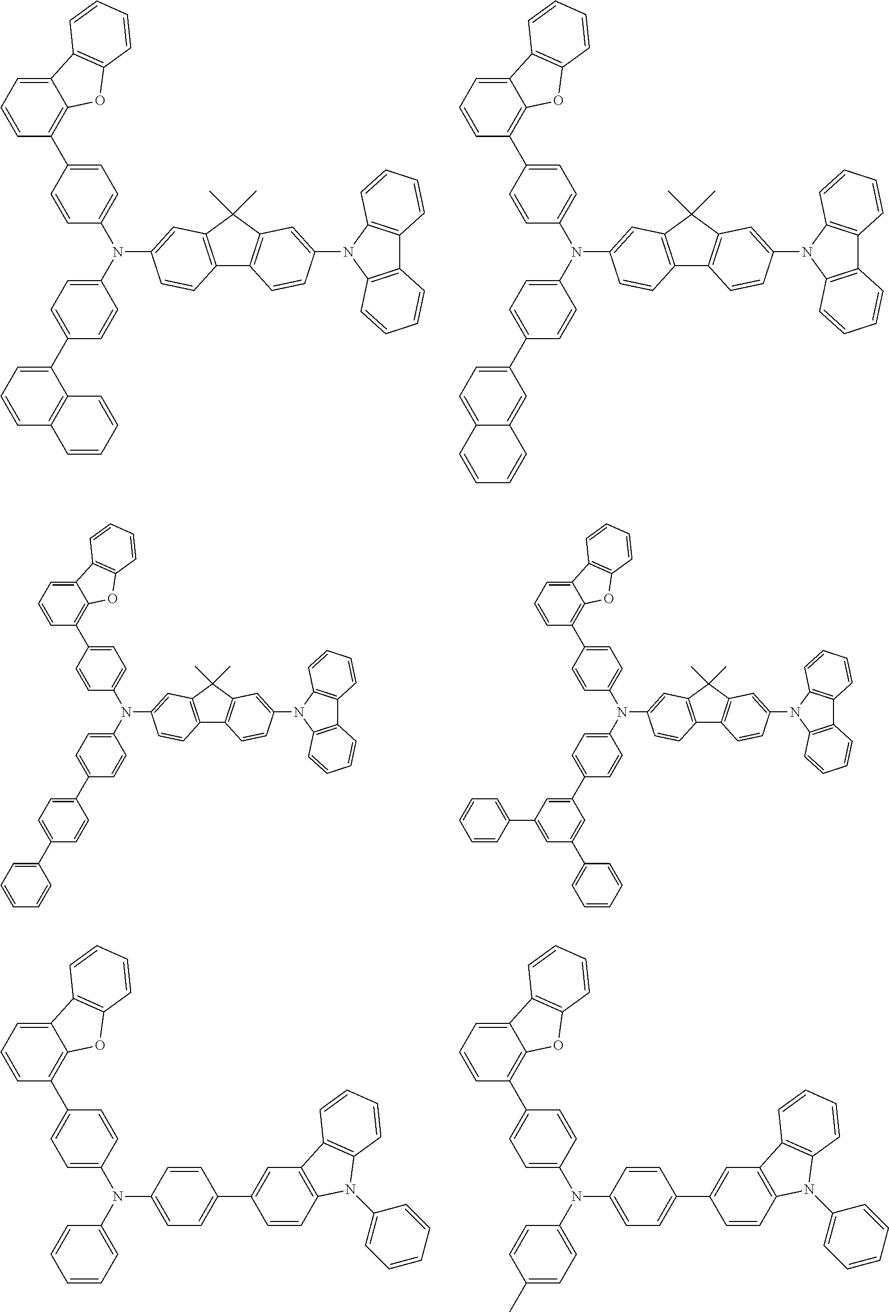

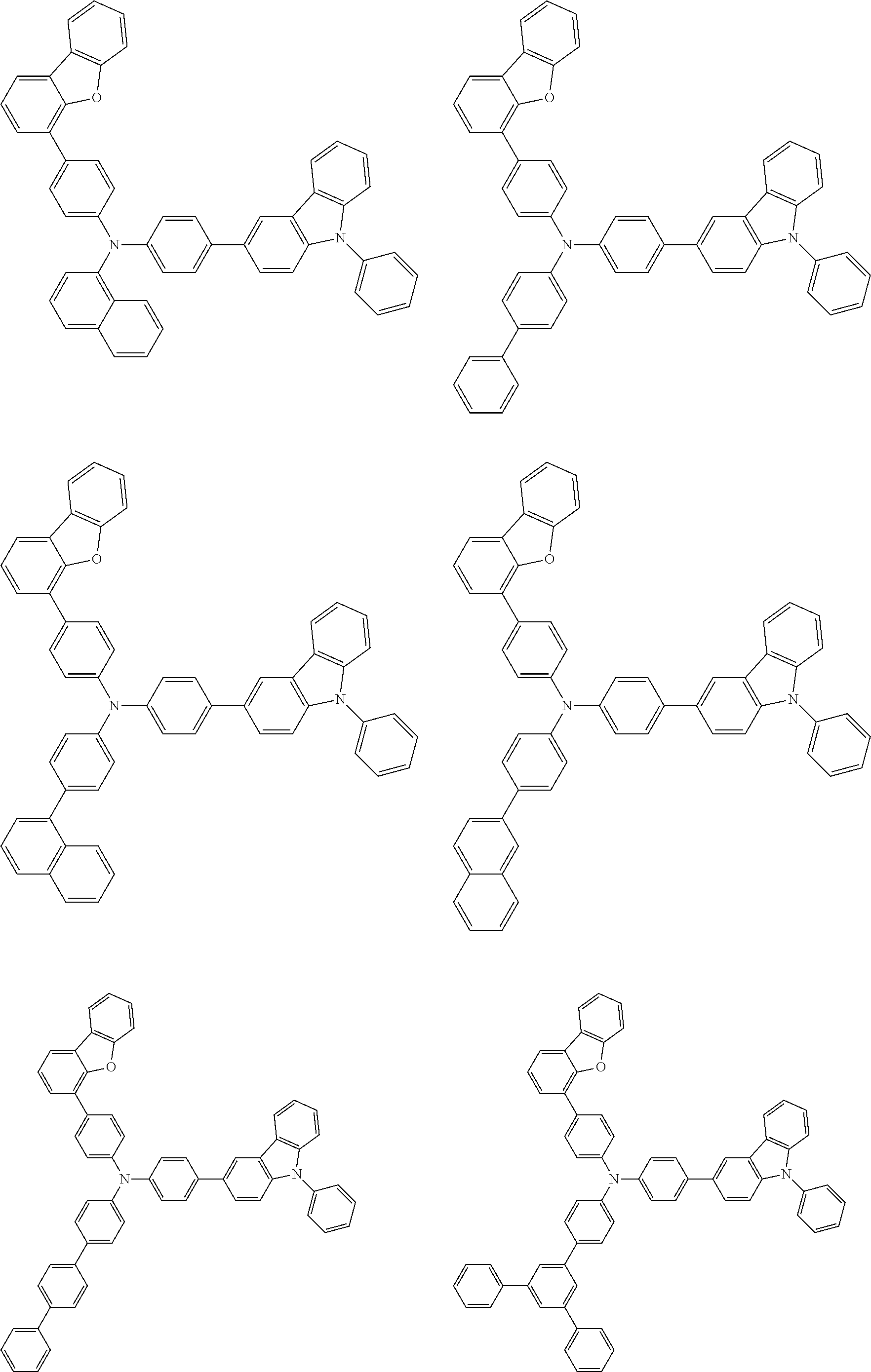

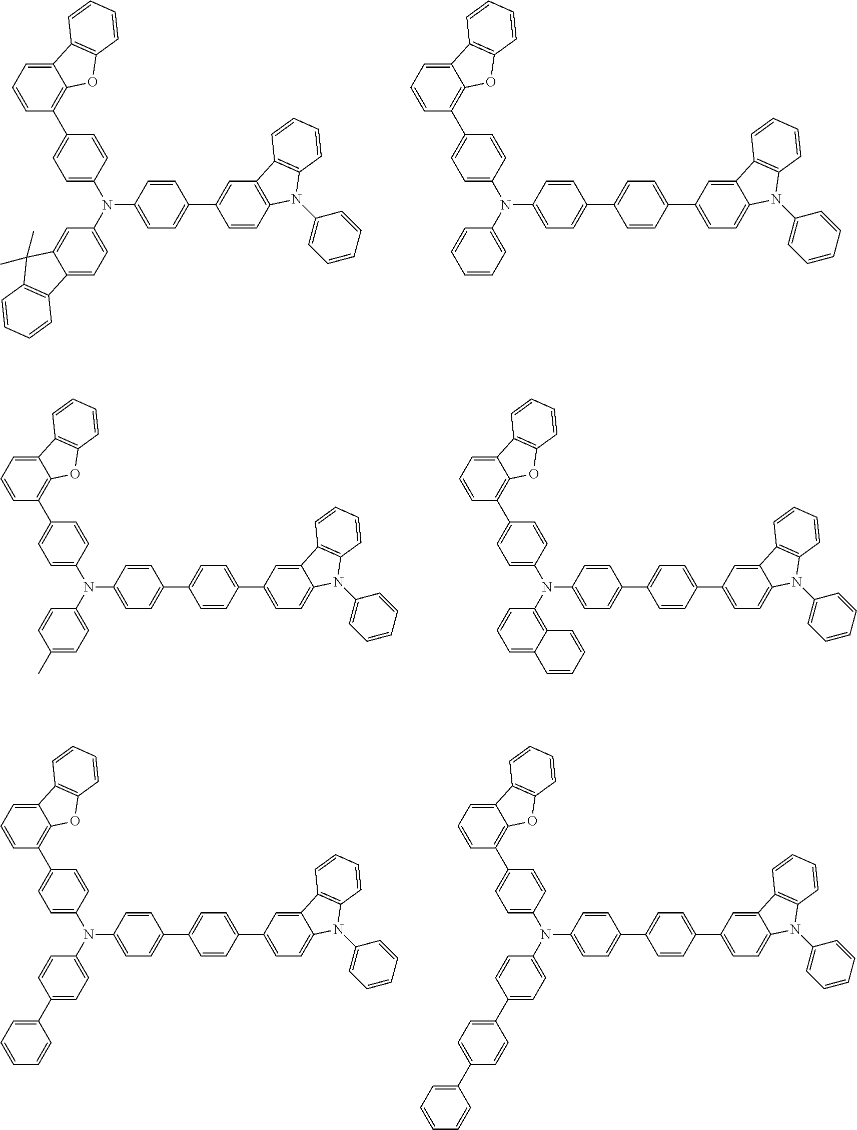

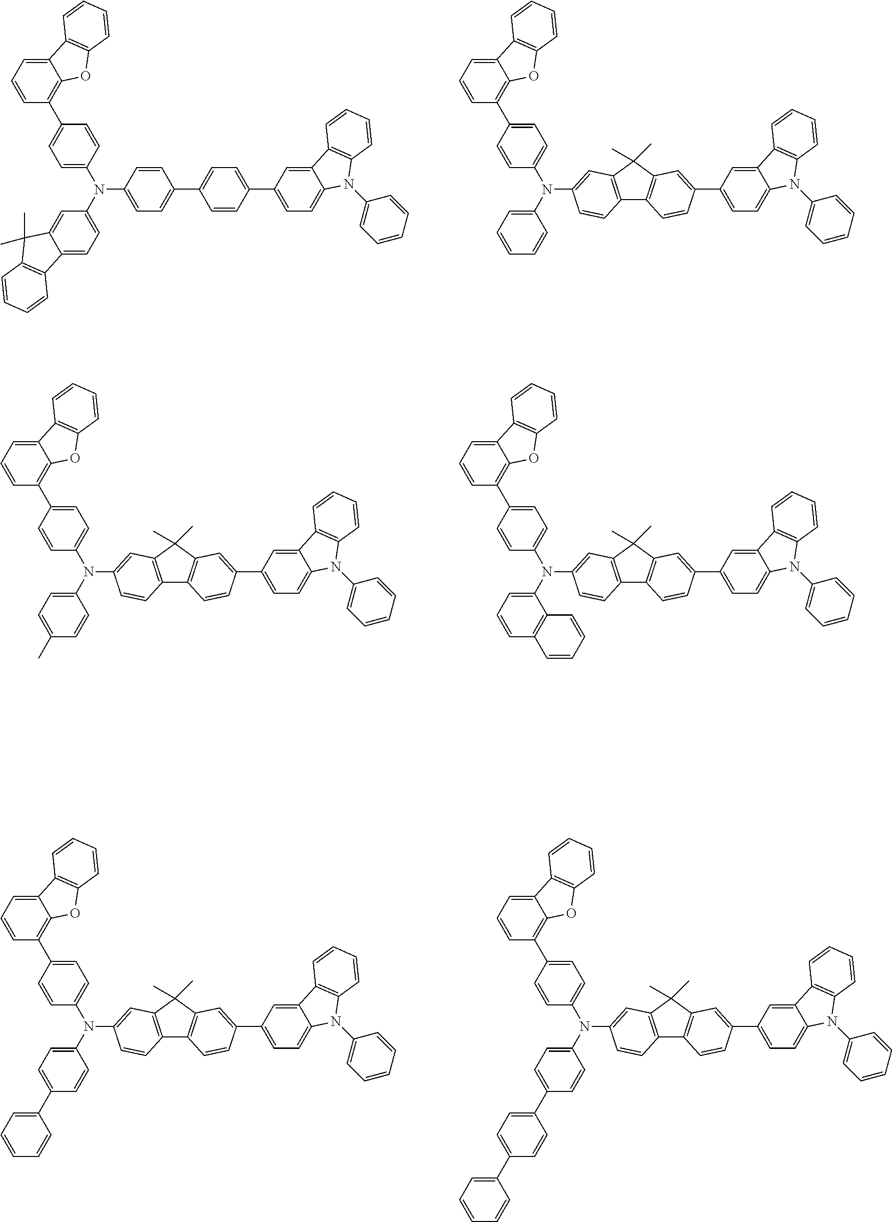

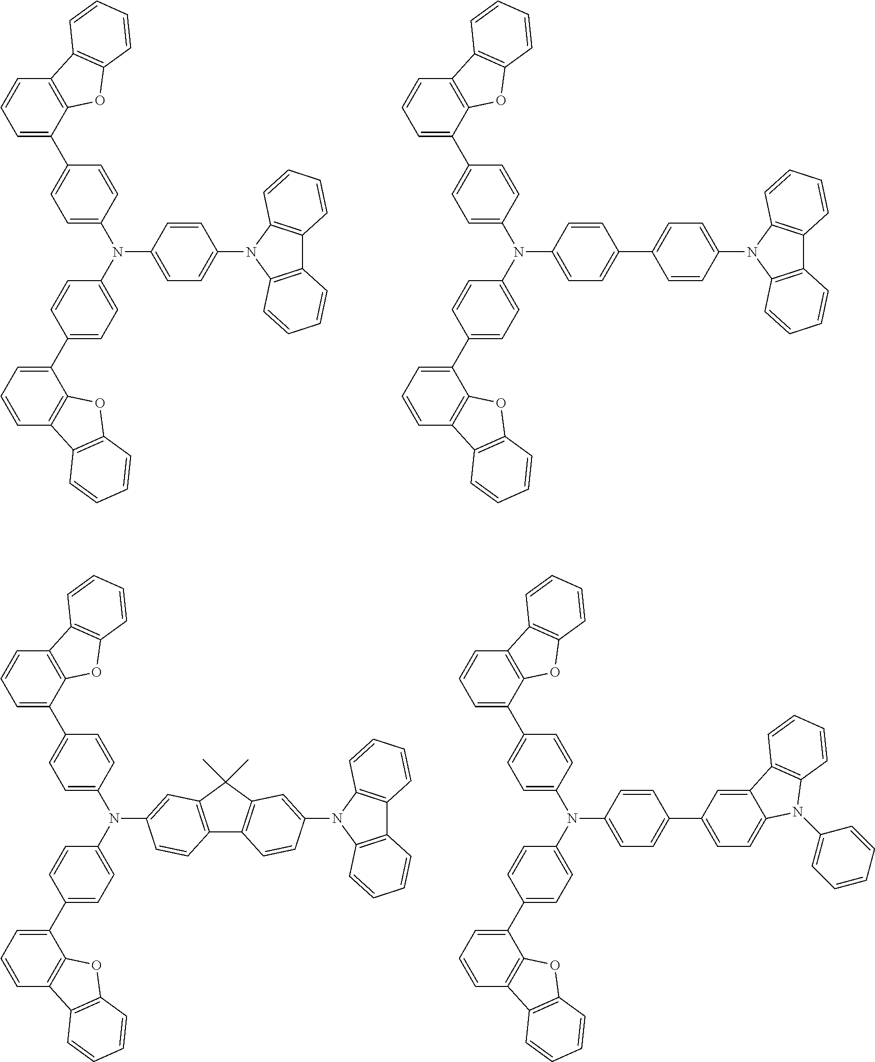 [SMILES: c1ccc2c(c1)oc1c(-c3ccc(N(c4ccc(-c5cccc6c5oc5ccccc56)cc4)c4ccc(-n5c6ccccc6c6ccccc65)cc4)cc3)cccc12 ; c1ccc2c(c1)oc1c(-c3ccc(N(c4ccc(-c5ccc(-n6c7ccccc7c7ccccc76)cc5)cc4)c4ccc(-c5cccc6c5oc5ccccc56)cc4)cc3)cccc12 ; CC1(C)c2cc(N(c3ccc(-c4cccc5c4oc4ccccc45)cc3)c3ccc(-c4cccc5c4oc4ccccc45)cc3)ccc2-c2ccc(-n3c4ccccc4c4ccccc43)cc21 ; c1ccc(-n2c3ccccc3c3cc(-c4ccc(N(c5ccc(-c6cccc7c6oc6ccccc67)cc5)c5ccc(-c6cccc7c6oc6ccccc67)cc5)cc4)ccc32)cc1]

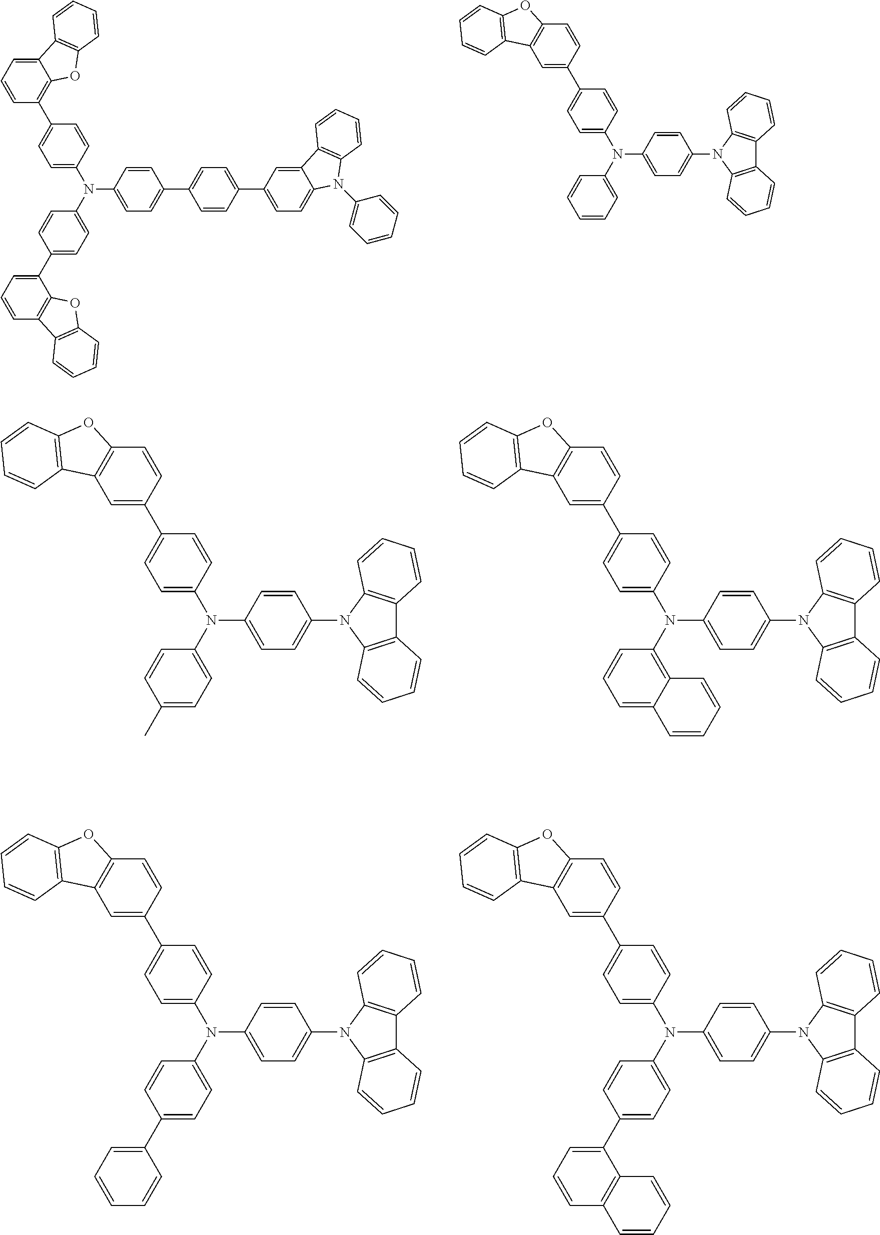

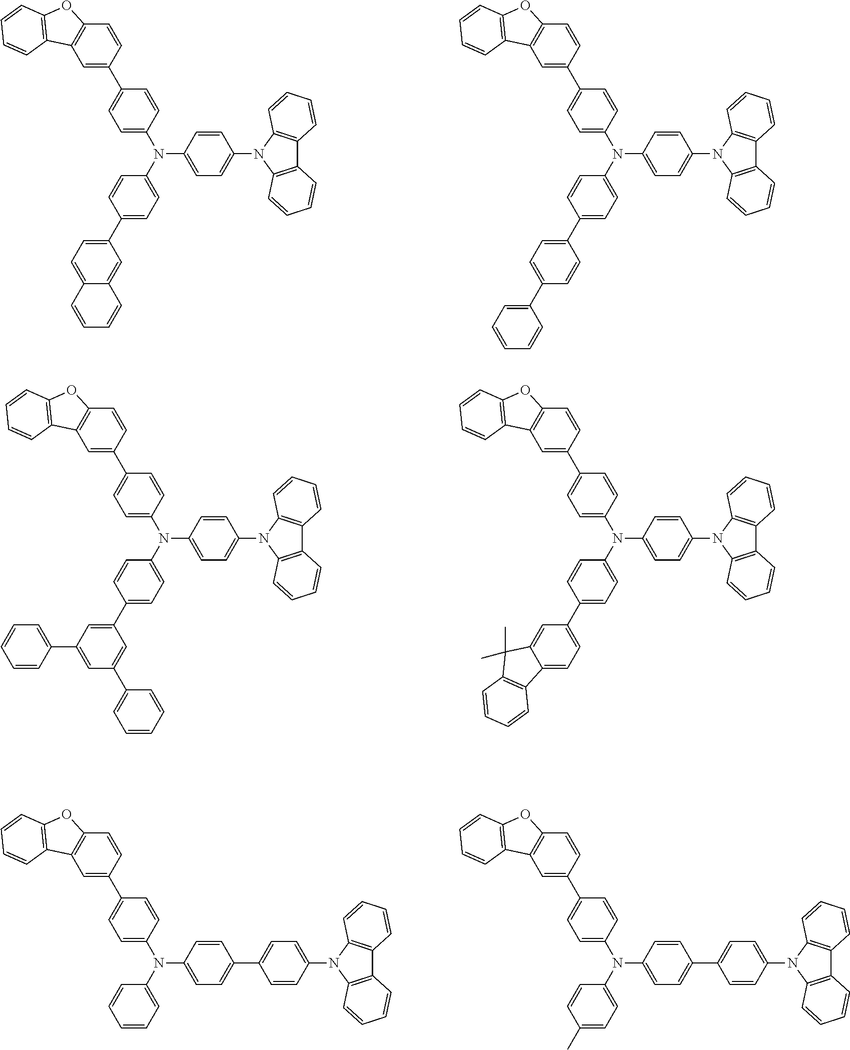

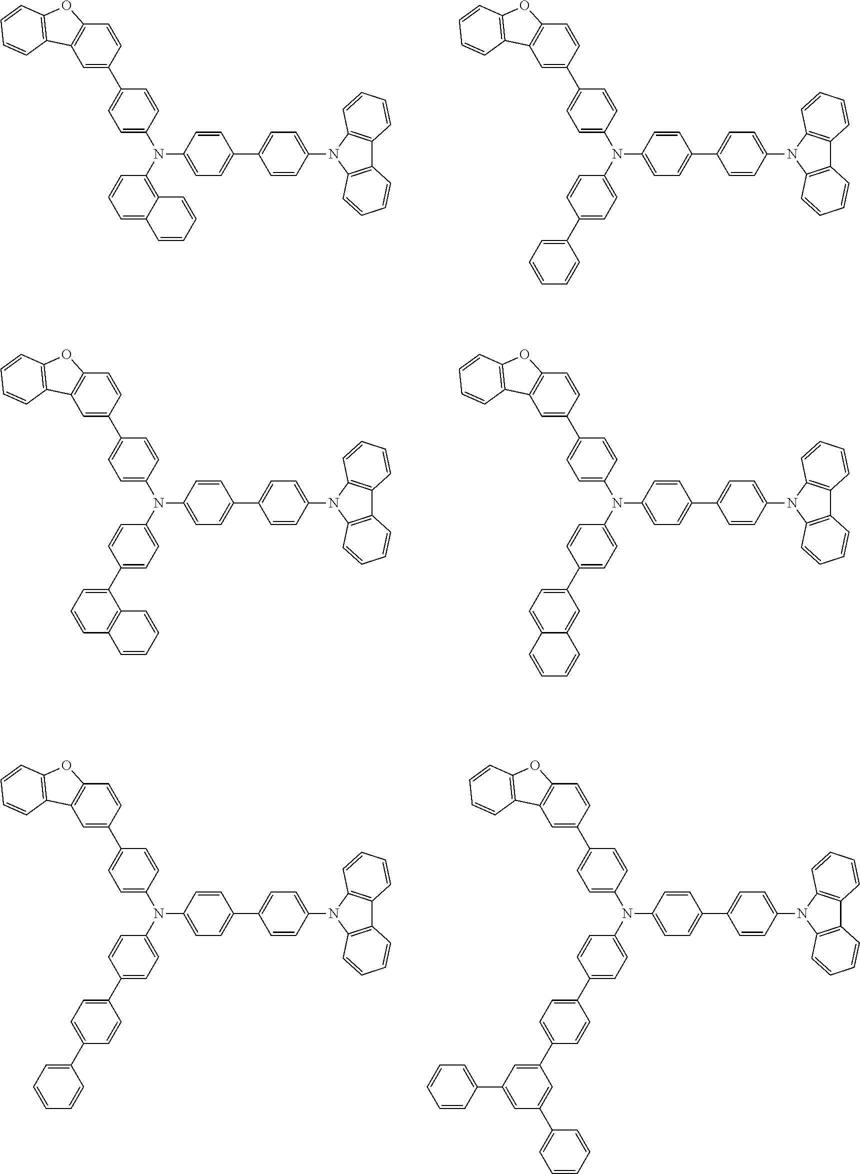

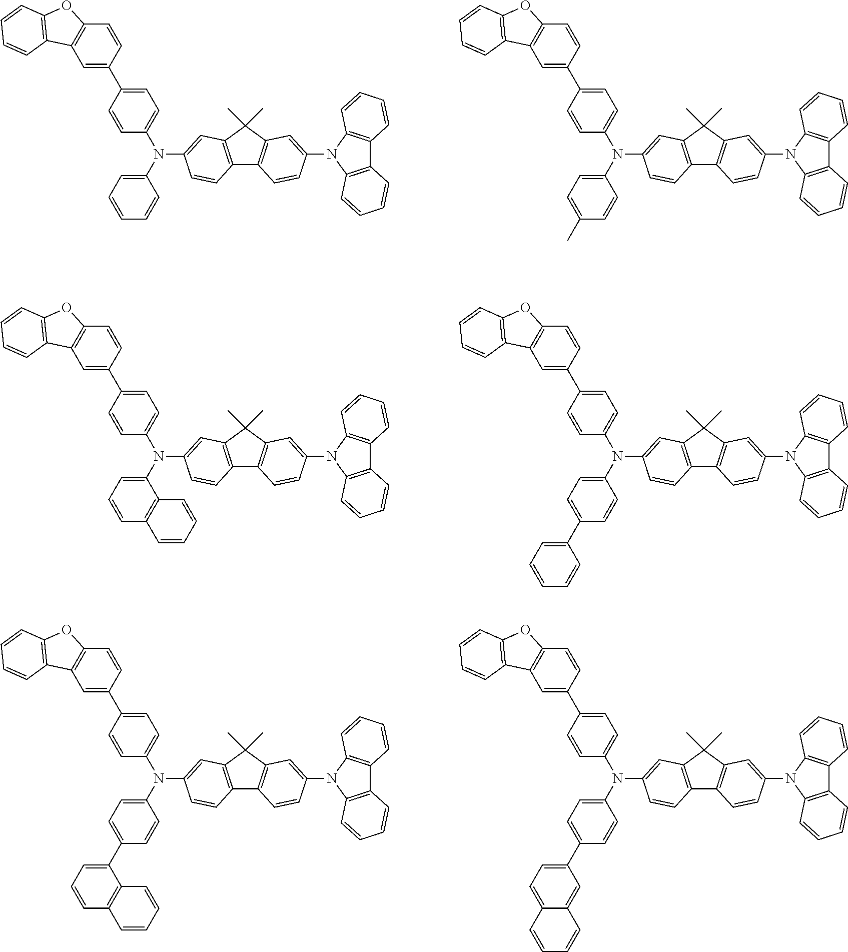

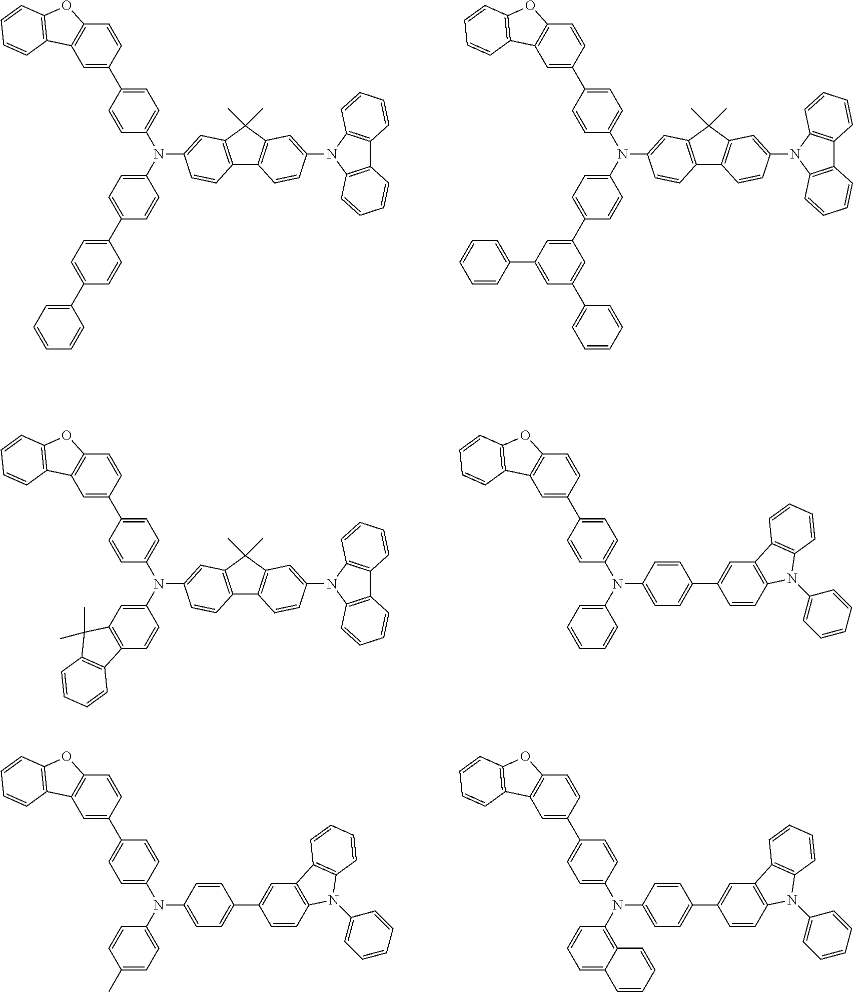

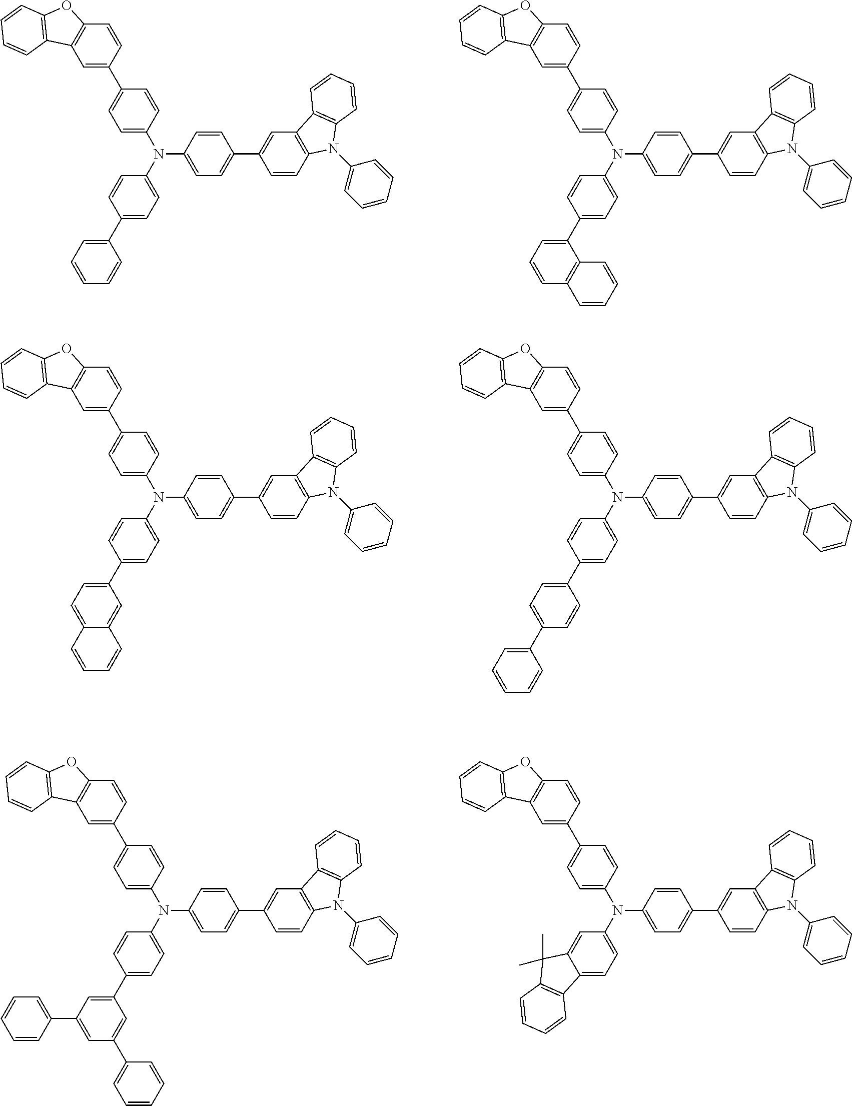

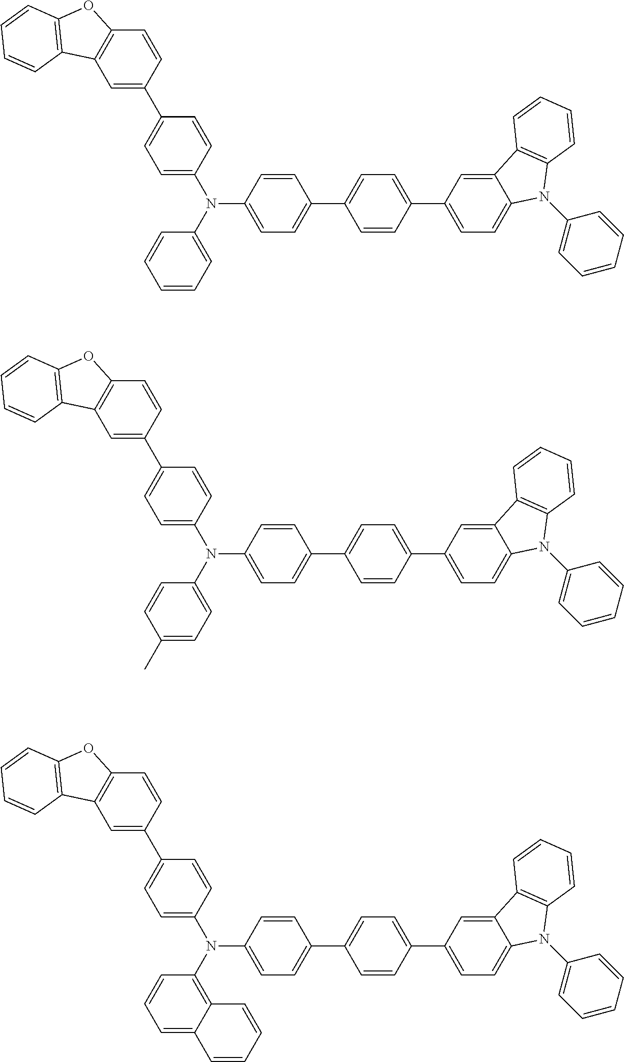 [SMILES: c1ccc(N(c2ccc(-c3ccc(-c4ccc5c(c4)c4ccccc4n5-c4ccccc4)cc3)cc2)c2ccc(-c3ccc4oc5ccccc5c4c3)cc2)cc1 ; Cc1ccc(N(c2ccc(-c3ccc(-c4ccc5c(c4)c4ccccc4n5-c4ccccc4)cc3)cc2)c2ccc(-c3ccc4oc5ccccc5c4c3)cc2)cc1 ; c1ccc(-n2c3ccccc3c3cc(-c4ccc(-c5ccc(N(c6ccc(-c7ccc8oc9ccccc9c8c7)cc6)c6cccc7ccccc67)cc5)cc4)ccc32)cc1]

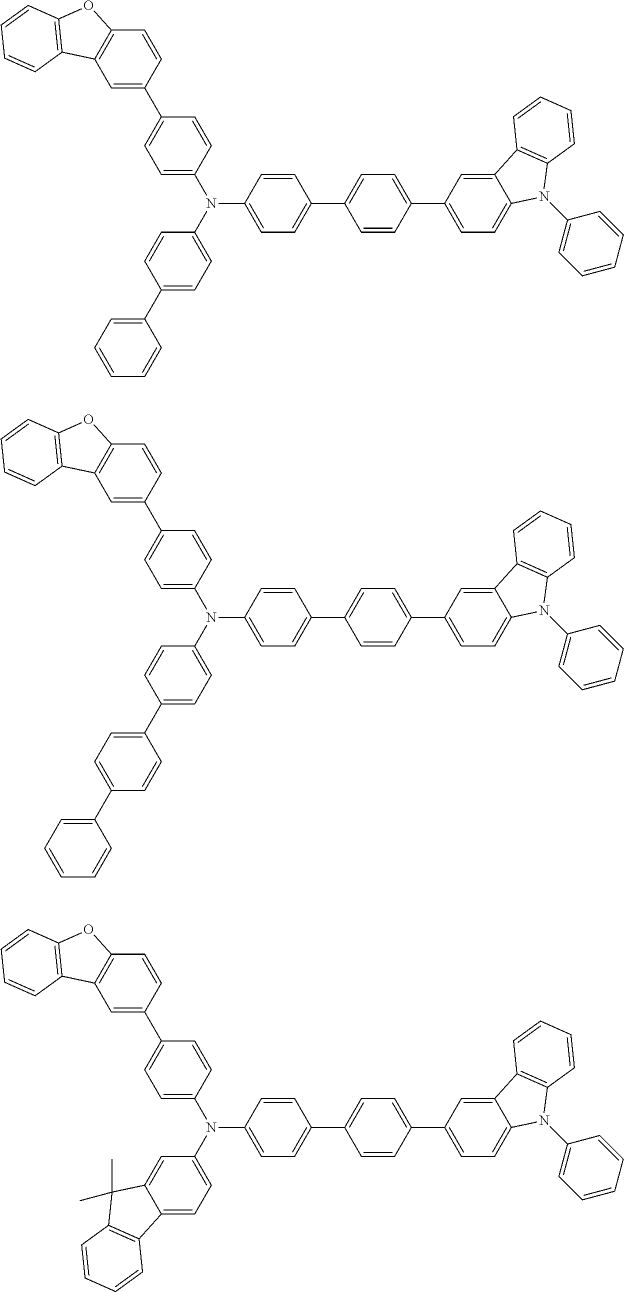 [SMILES: c1ccc(-c2ccc(N(c3ccc(-c4ccc(-c5ccc6c(c5)c5ccccc5n6-c5ccccc5)cc4)cc3)c3ccc(-c4ccc5oc6ccccc6c5c4)cc3)cc2)cc1 ; c1ccc(-c2ccc(-c3ccc(N(c4ccc(-c5ccc(-c6ccc7c(c6)c6ccccc6n7-c6ccccc6)cc5)cc4)c4ccc(-c5ccc6oc7ccccc7c6c5)cc4)cc3)cc2)cc1 ; CC1(C)c2ccccc2-c2ccc(N(c3ccc(-c4ccc(-c5ccc6c(c5)c5ccccc5n6-c5ccccc5)cc4)cc3)c3ccc(-c4ccc5oc6ccccc6c5c4)cc3)cc21]

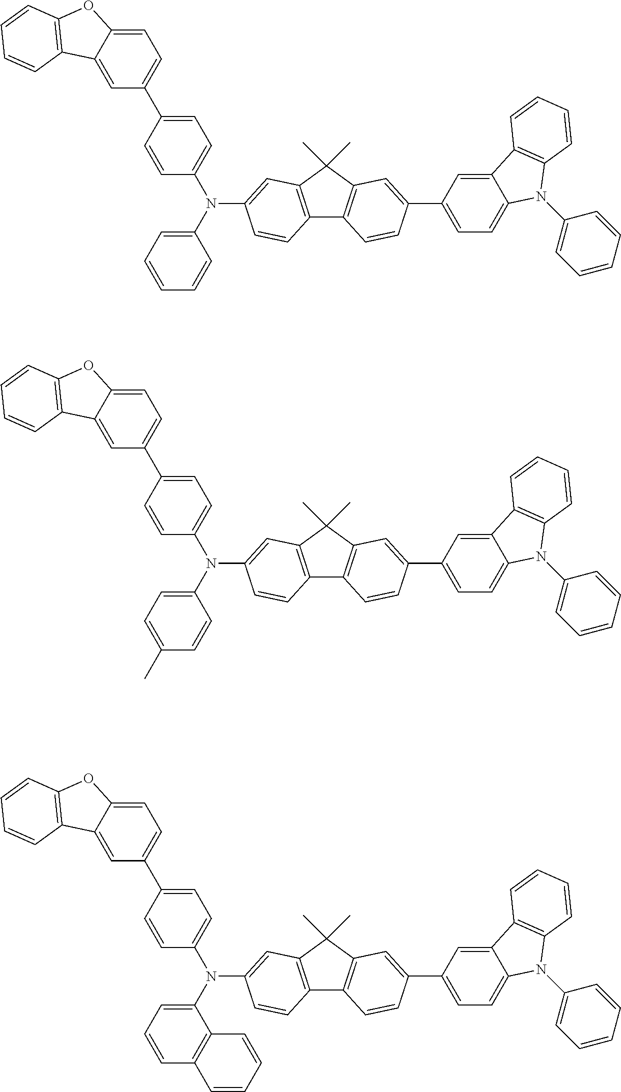 [SMILES: CC1(C)c2cc(-c3ccc4c(c3)c3ccccc3n4-c3ccccc3)ccc2-c2ccc(N(c3ccccc3)c3ccc(-c4ccc5oc6ccccc6c5c4)cc3)cc21 ; Cc1ccc(N(c2ccc(-c3ccc4oc5ccccc5c4c3)cc2)c2ccc3c(c2)C(C)(C)c2cc(-c4ccc5c(c4)c4ccccc4n5-c4ccccc4)ccc2-3)cc1 ; CC1(C)c2cc(-c3ccc4c(c3)c3ccccc3n4-c3ccccc3)ccc2-c2ccc(N(c3ccc(-c4ccc5oc6ccccc6c5c4)cc3)c3cccc4ccccc34)cc21]

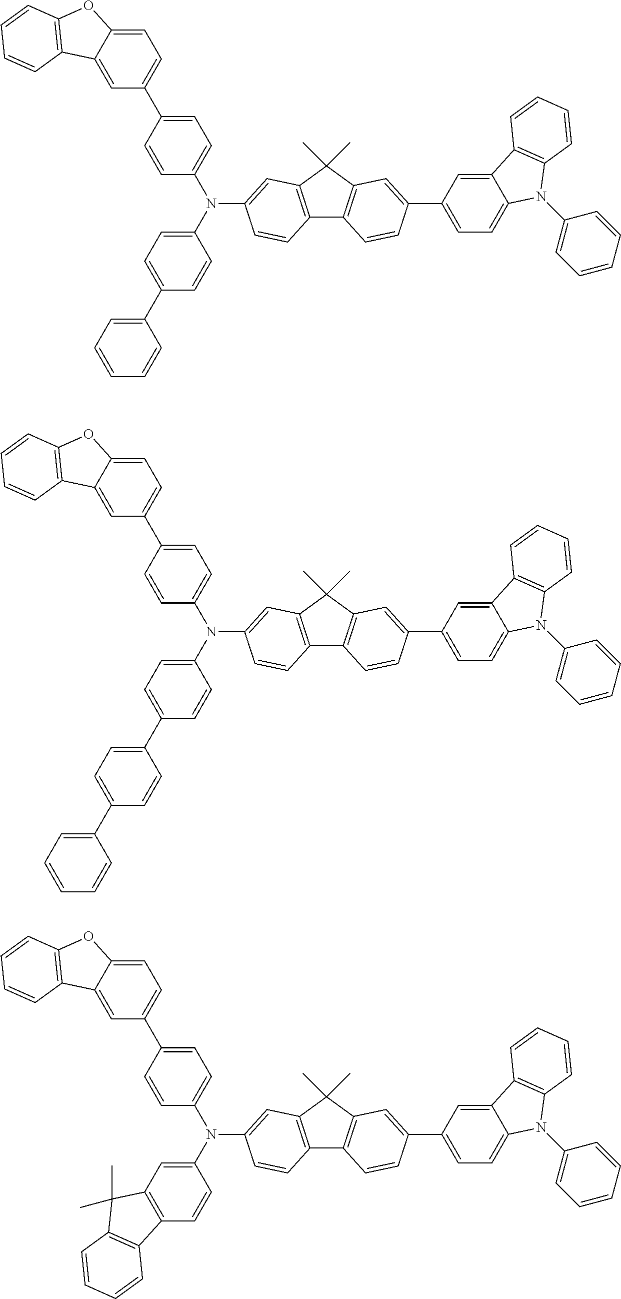

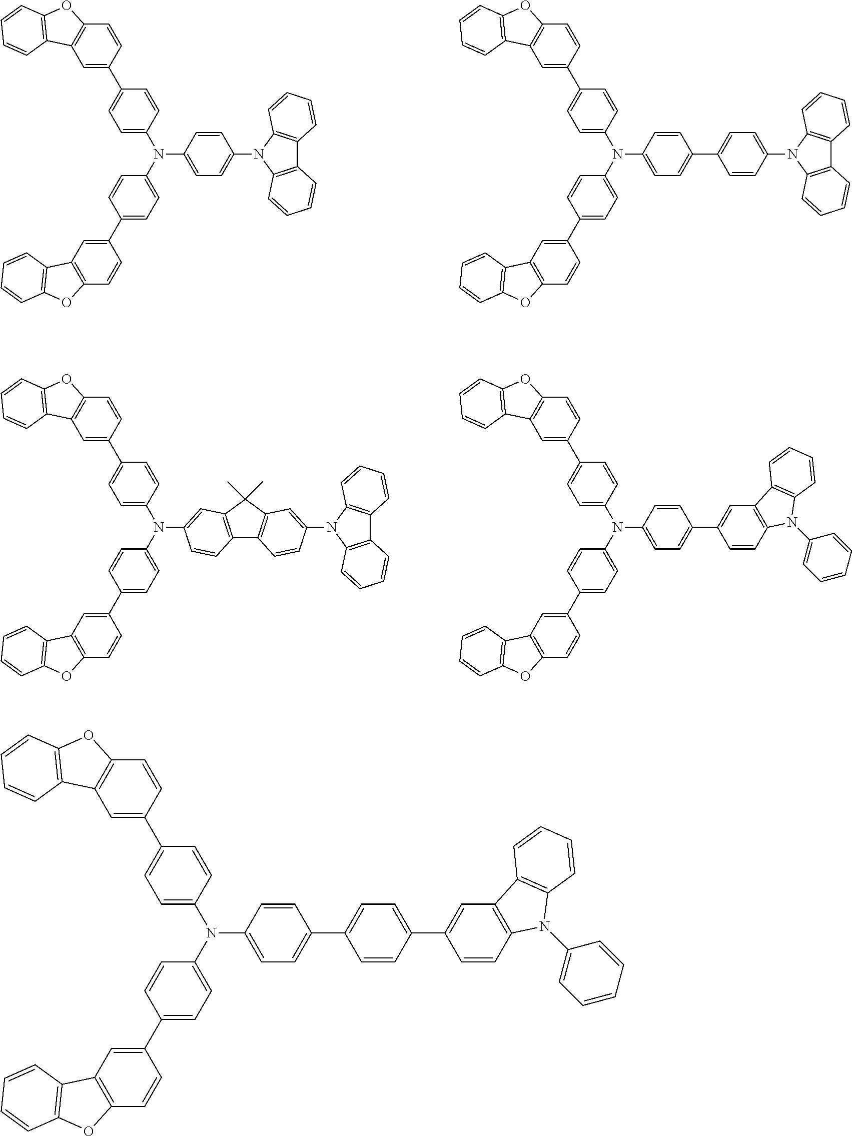

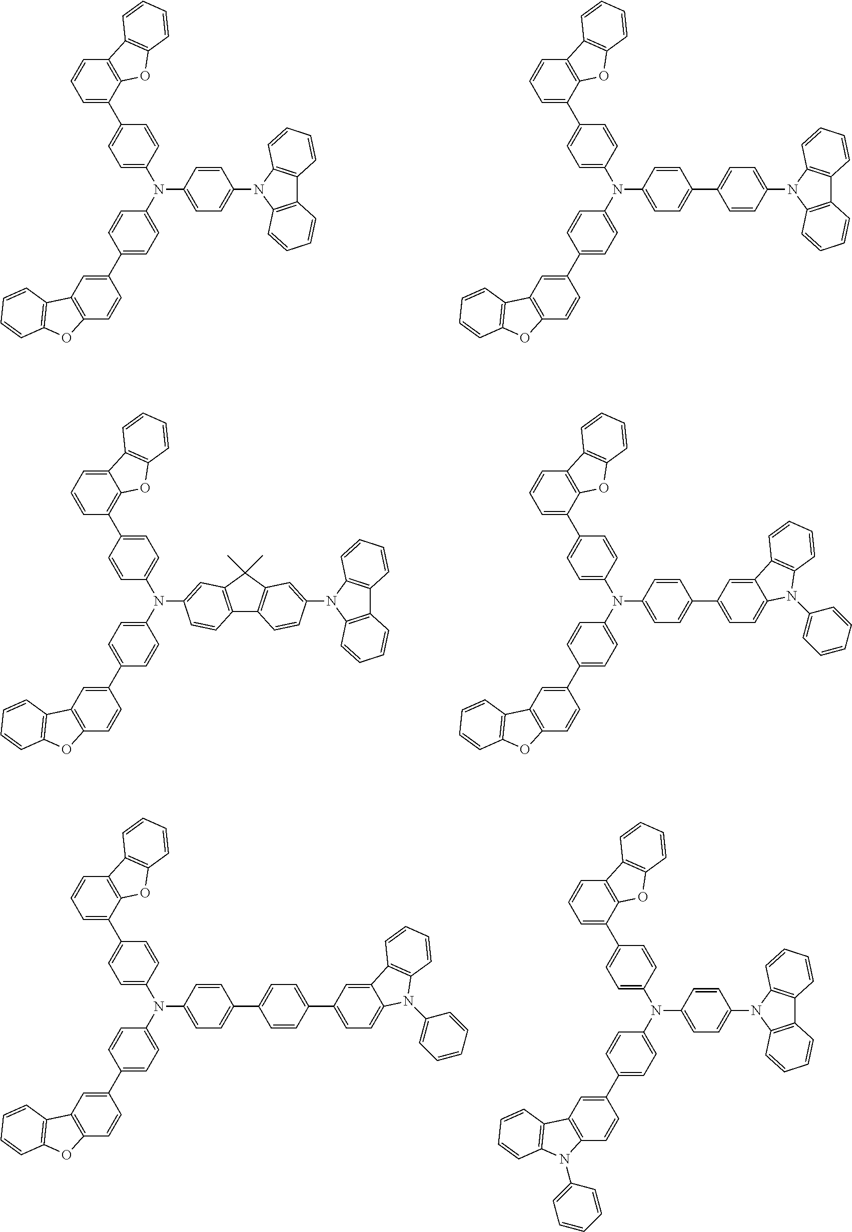

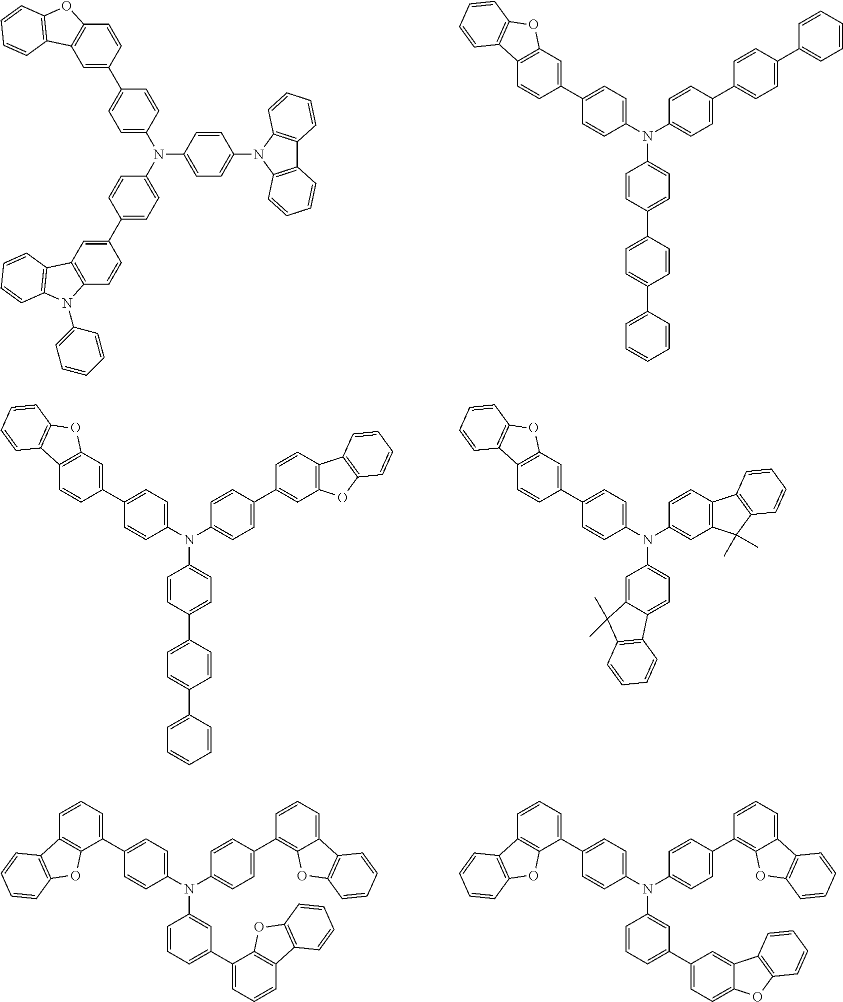

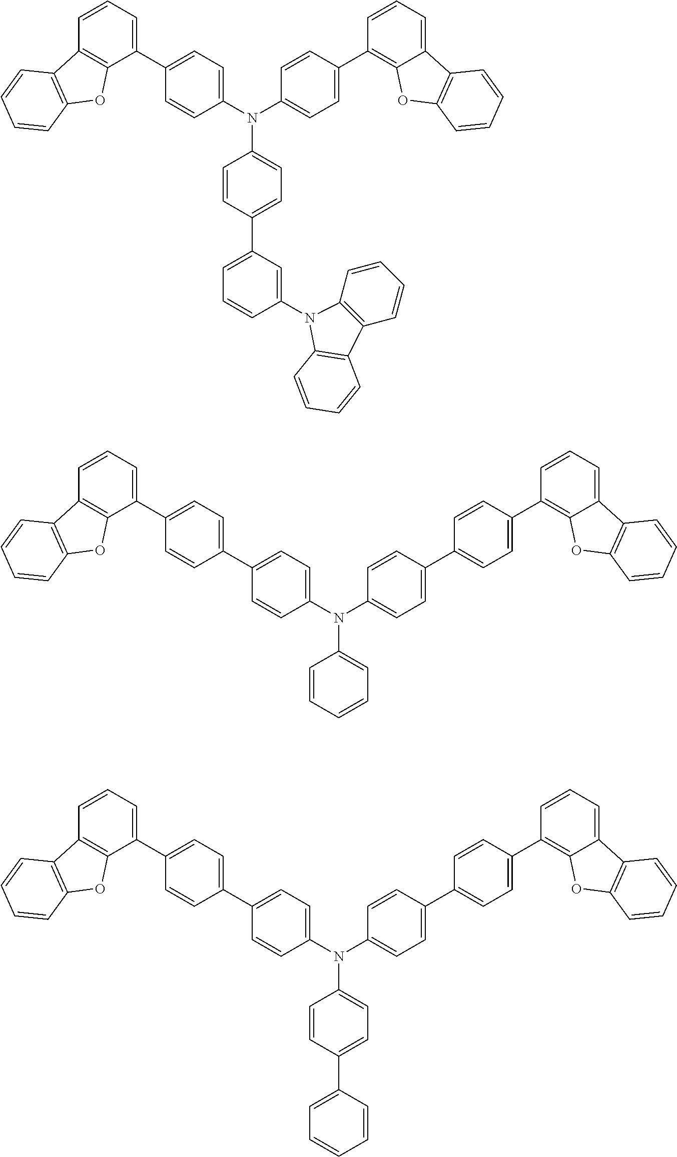 [SMILES: c1cc(-c2ccc(N(c3ccc(-c4cccc5c4oc4ccccc45)cc3)c3ccc(-c4cccc5c4oc4ccccc45)cc3)cc2)cc(-n2c3ccccc3c3ccccc32)c1 ; c1ccc(N(c2ccc(-c3ccc(-c4cccc5c4oc4ccccc45)cc3)cc2)c2ccc(-c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

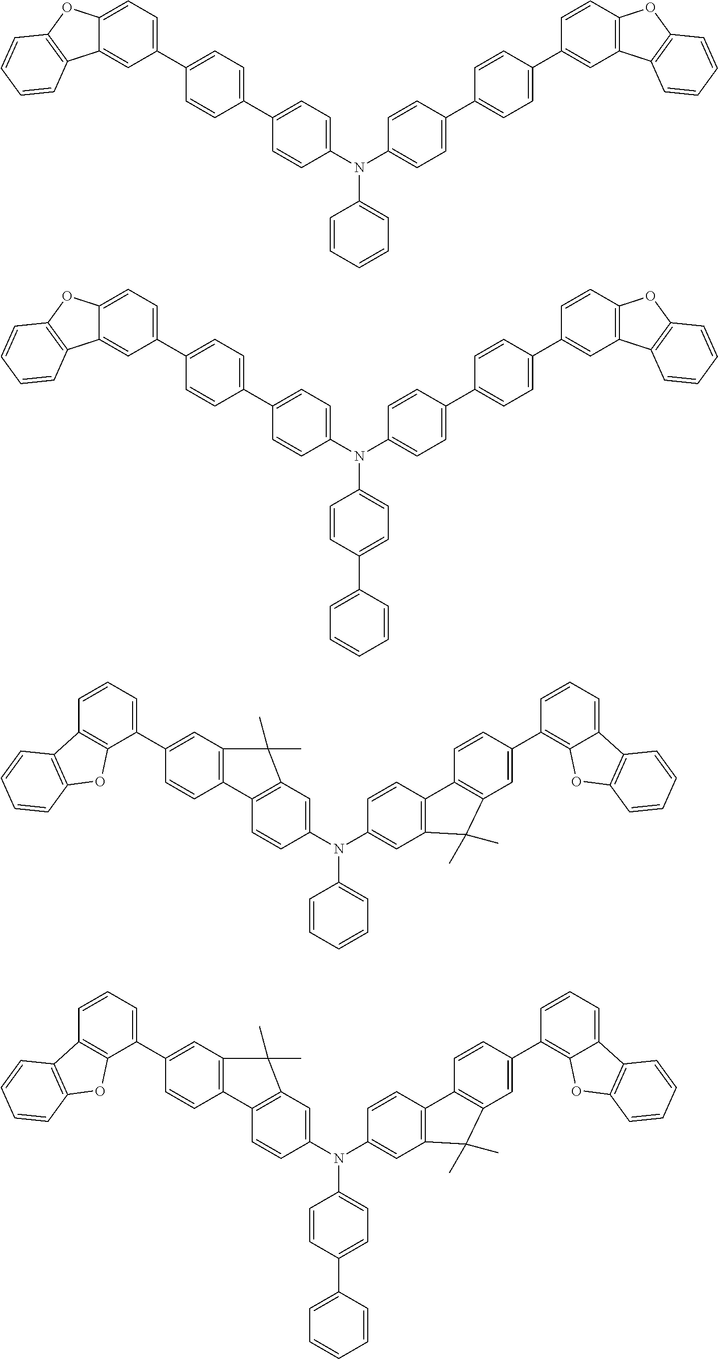 [SMILES: c1ccc(N(c2ccc(-c3ccc(-c4ccc5oc6ccccc6c5c4)cc3)cc2)c2ccc(-c3ccc(-c4ccc5oc6ccccc6c5c4)cc3)cc2)cc1 ; c1ccc(-c2ccc(N(c3ccc(-c4ccc(-c5ccc6oc7ccccc7c6c5)cc4)cc3)c3ccc(-c4ccc(-c5ccc6oc7ccccc7c6c5)cc4)cc3)cc2)cc1 ; CC1(C)c2cc(-c3cccc4c3oc3ccccc34)ccc2-c2ccc(N(c3ccccc3)c3ccc4c(c3)C(C)(C)c3cc(-c5cccc6c5oc5ccccc56)ccc3-4)cc21 ; CC1(C)c2cc(-c3cccc4c3oc3ccccc34)ccc2-c2ccc(N(c3ccc(-c4ccccc4)cc3)c3ccc4c(c3)C(C)(C)c3cc(-c5cccc6c5oc5ccccc56)ccc3-4)cc21]

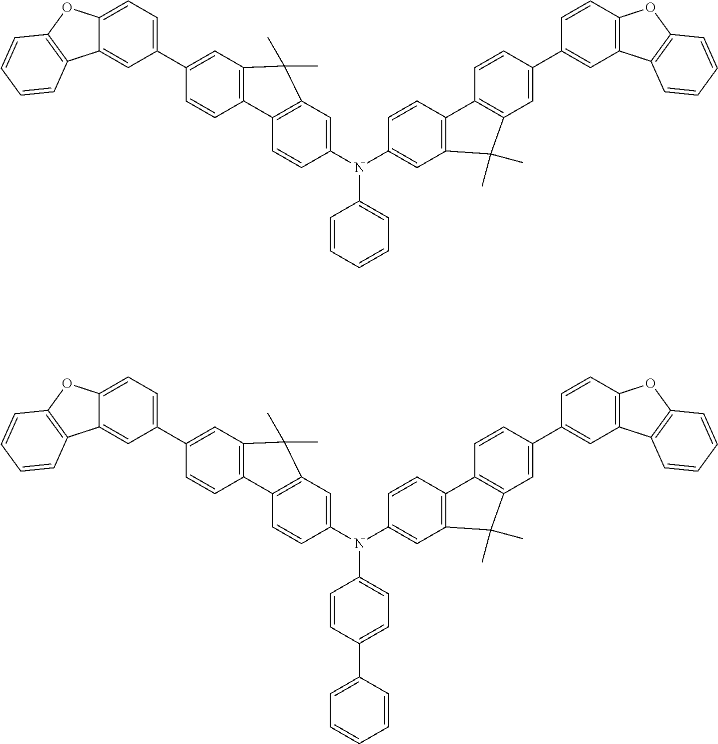 [SMILES: CC1(C)c2cc(-c3ccc4oc5ccccc5c4c3)ccc2-c2ccc(N(c3ccccc3)c3ccc4c(c3)C(C)(C)c3cc(-c5ccc6oc7ccccc7c6c5)ccc3-4)cc21 ; CC1(C)c2cc(-c3ccc4oc5ccccc5c4c3)ccc2-c2ccc(N(c3ccc(-c4ccccc4)cc3)c3ccc4c(c3)C(C)(C)c3cc(-c5ccc6oc7ccccc7c6c5)ccc3-4)cc21]

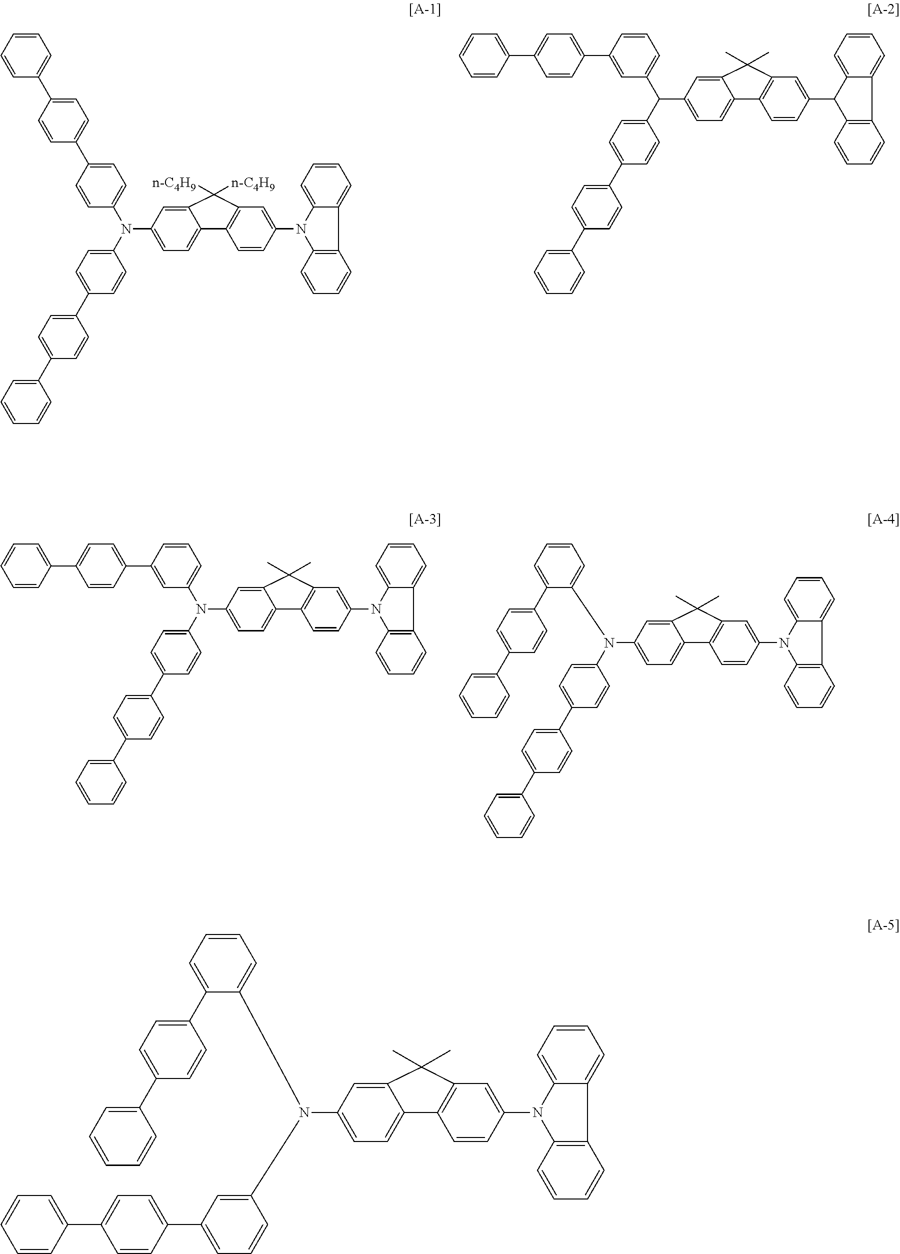

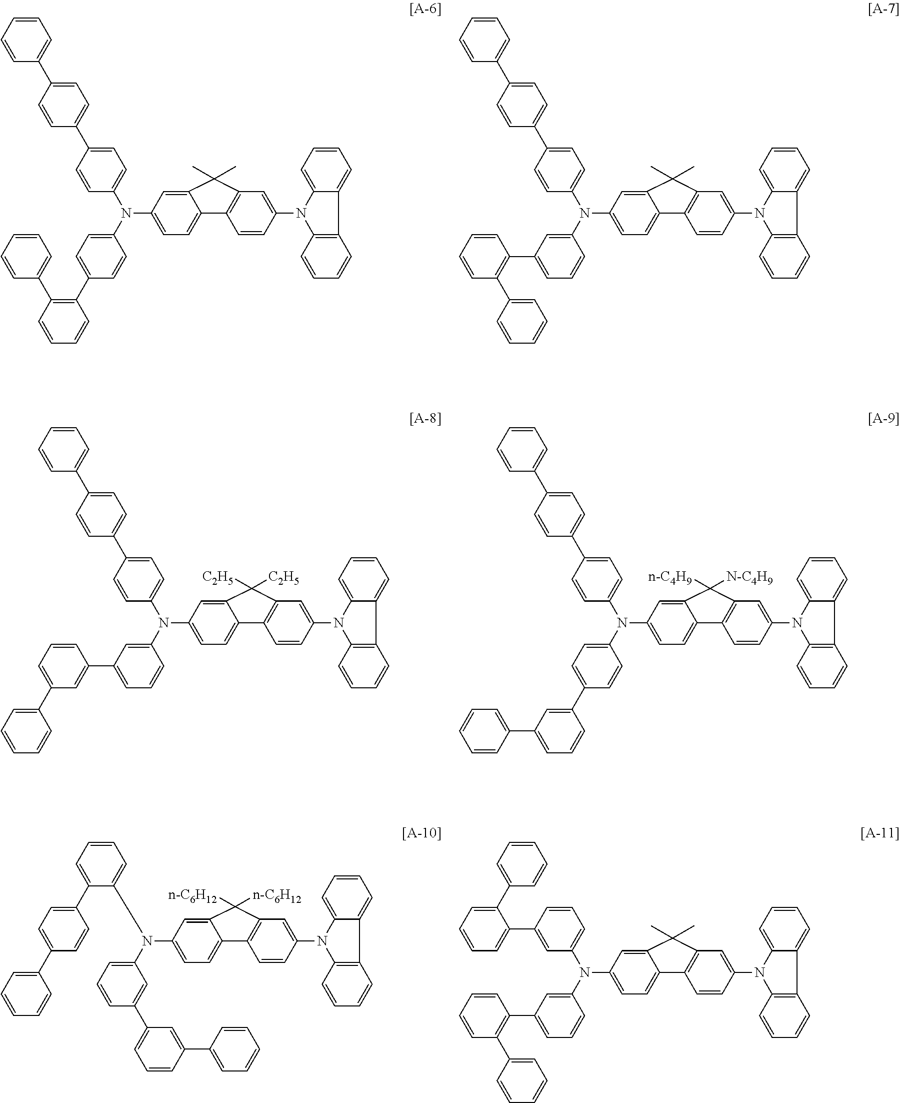

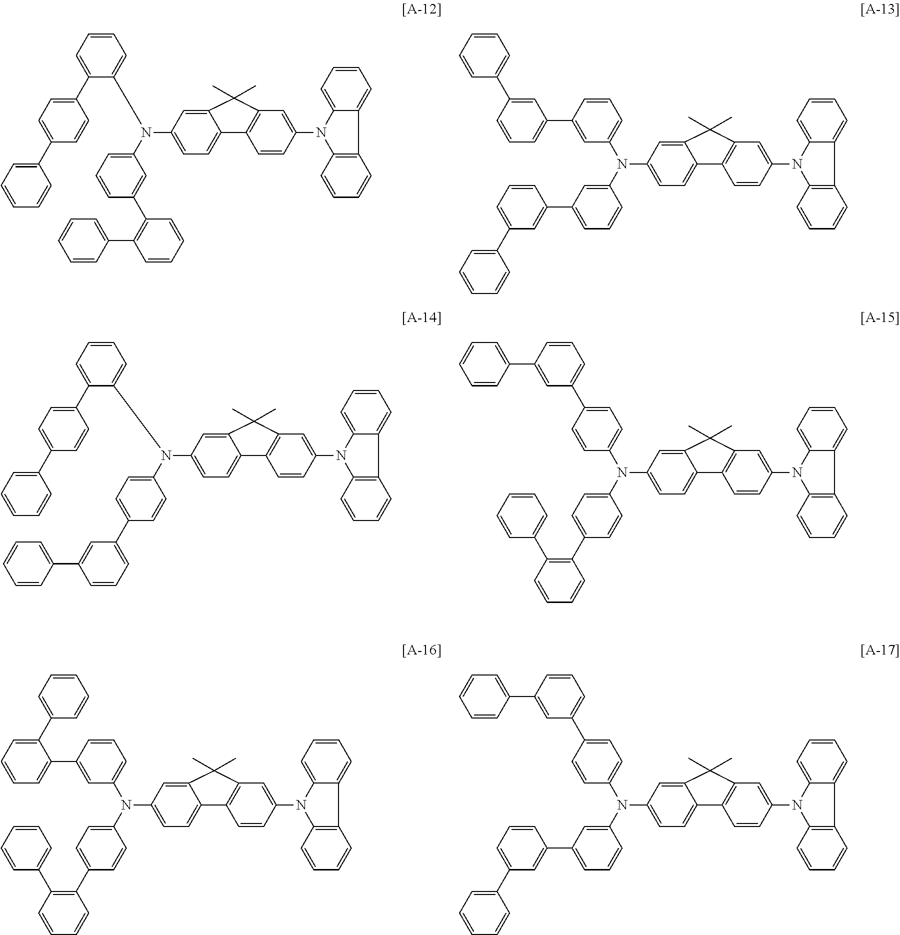

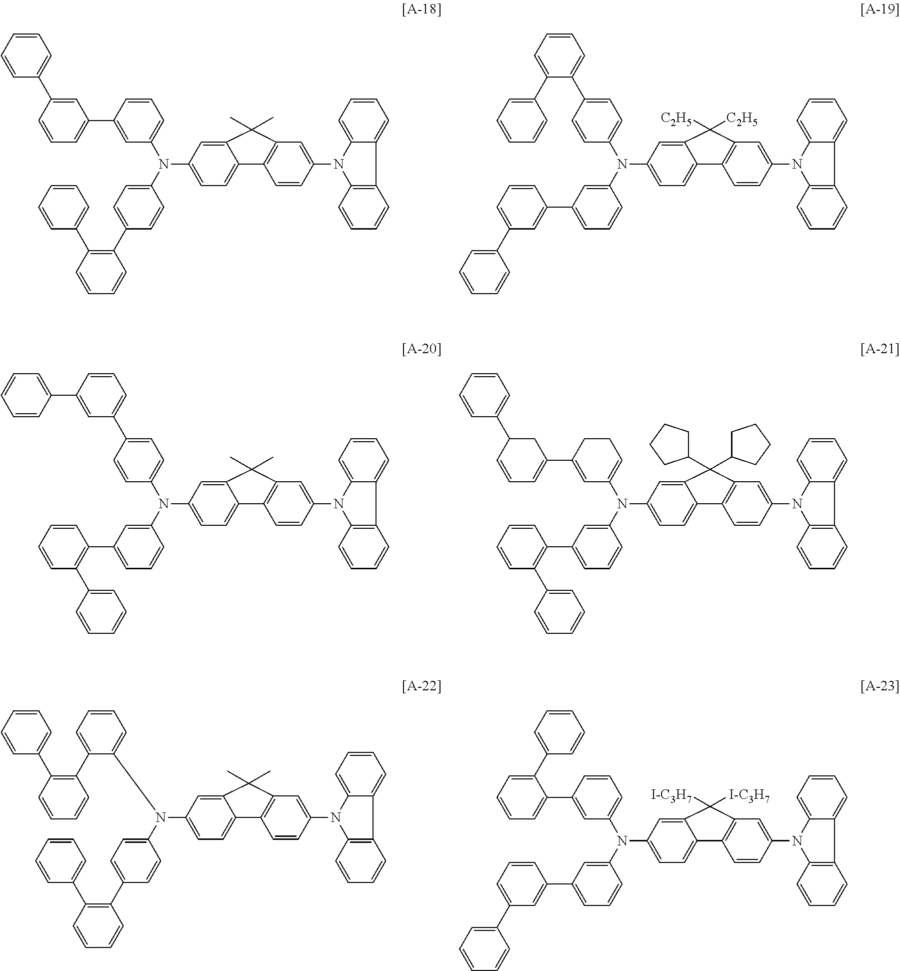

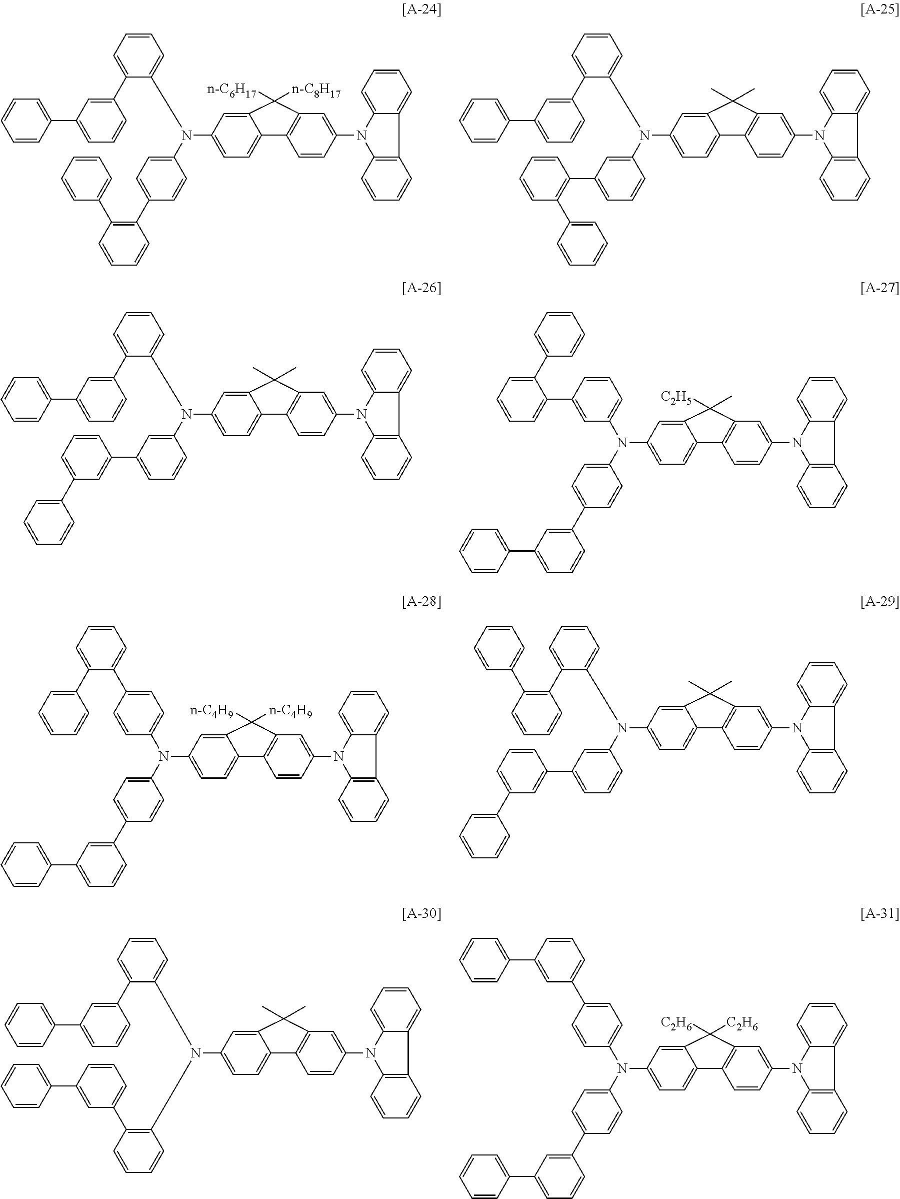

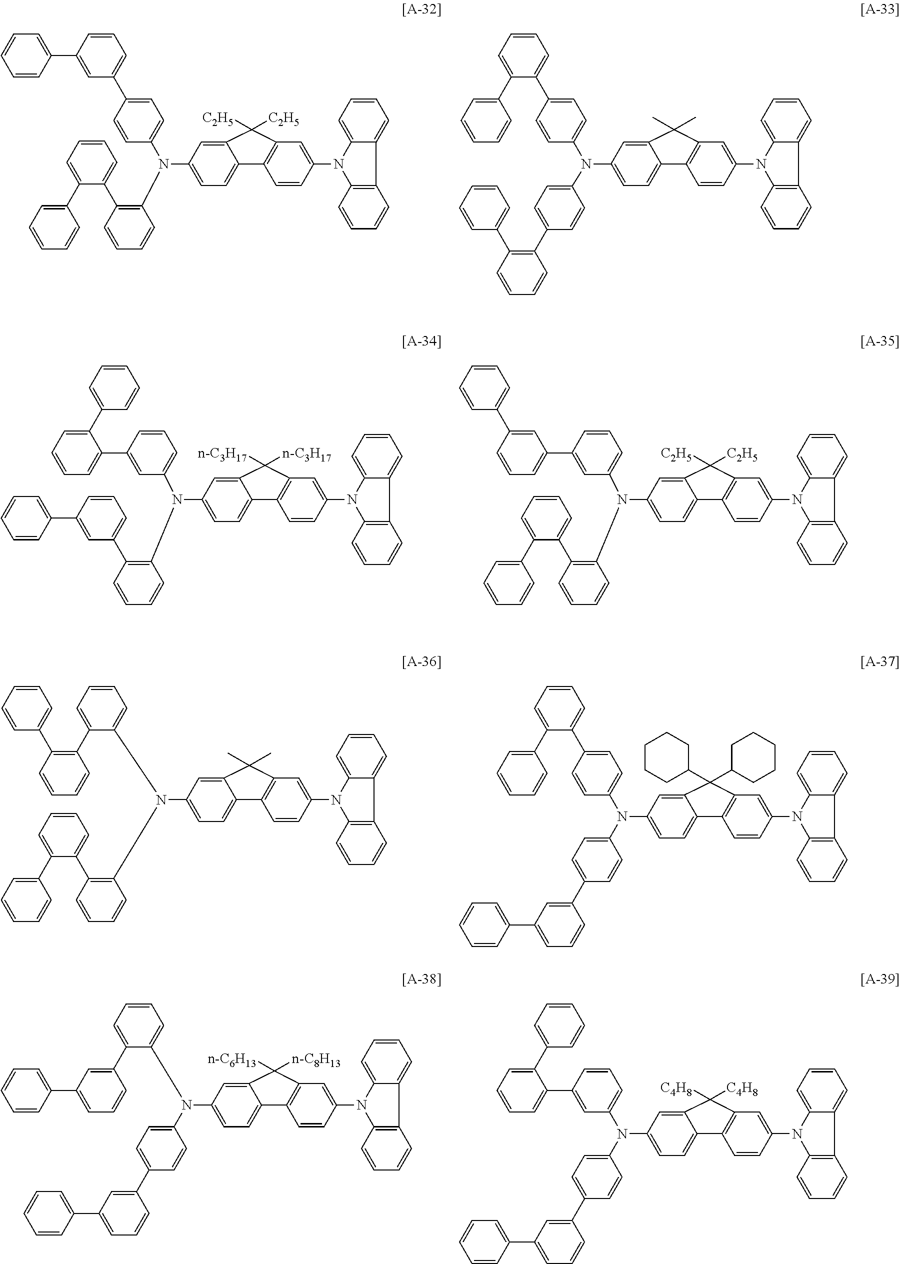

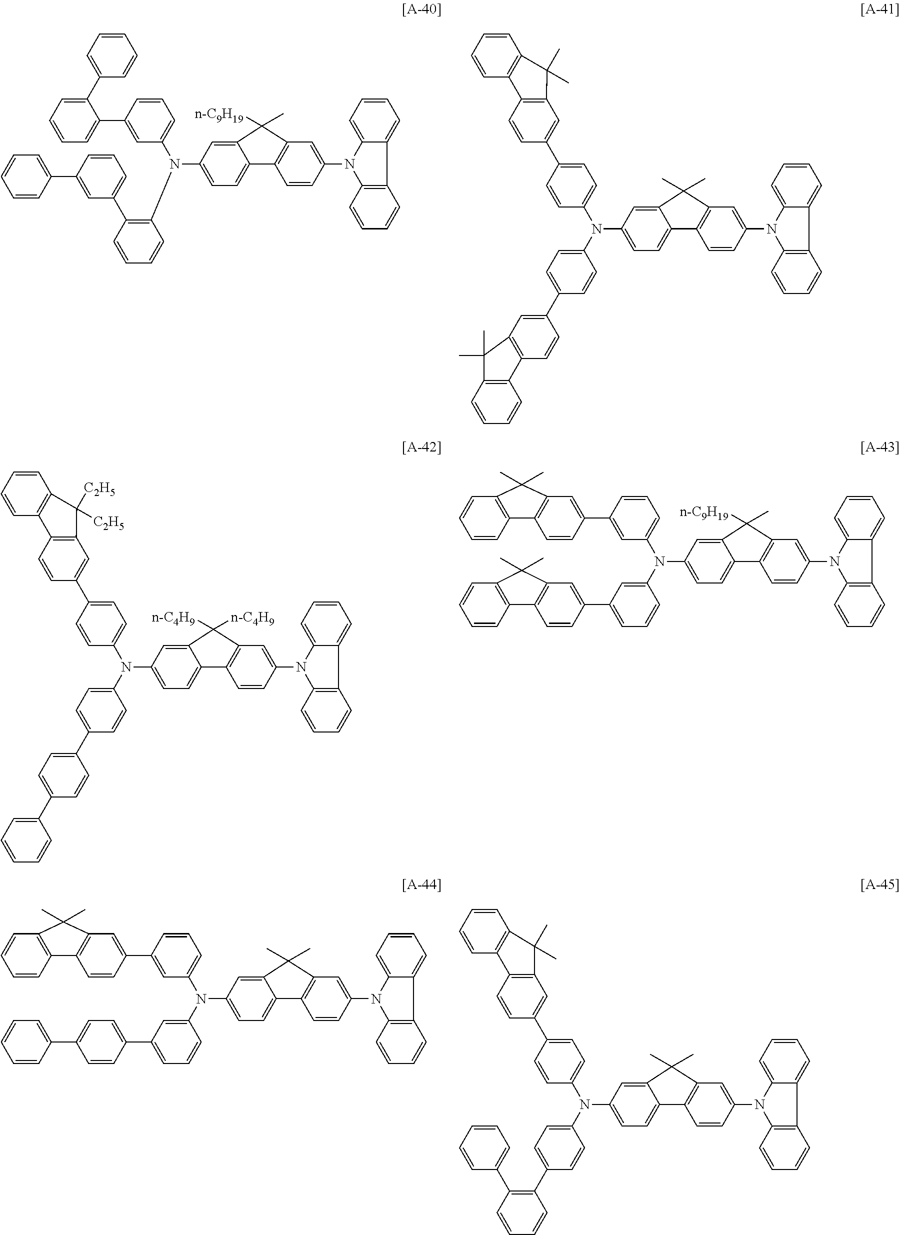

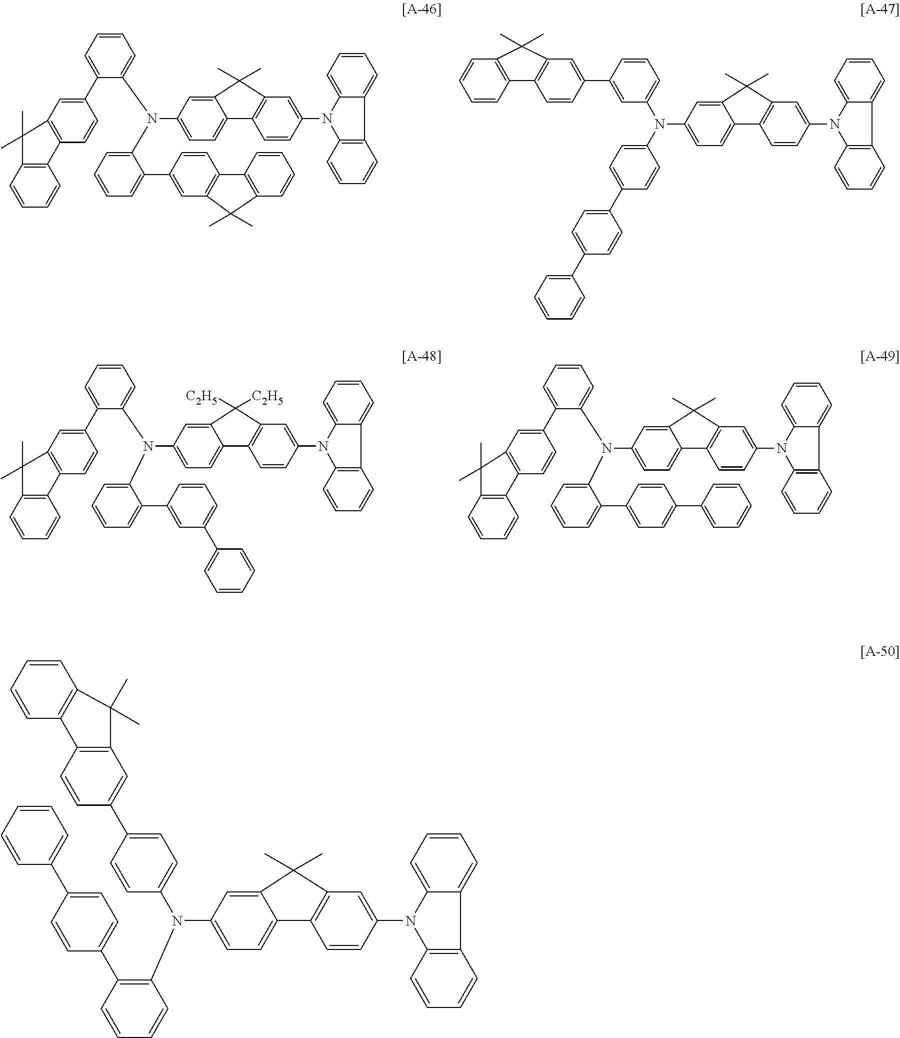

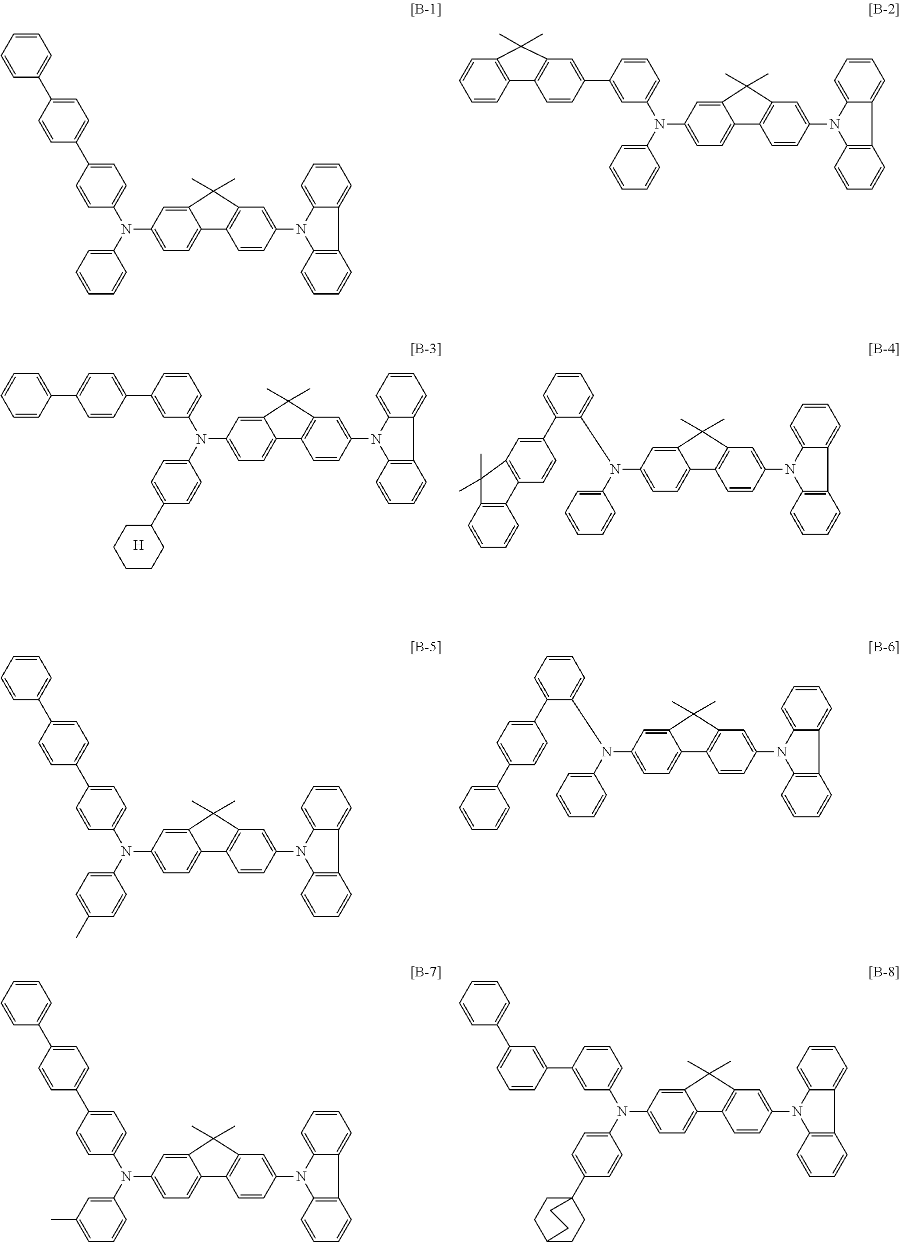

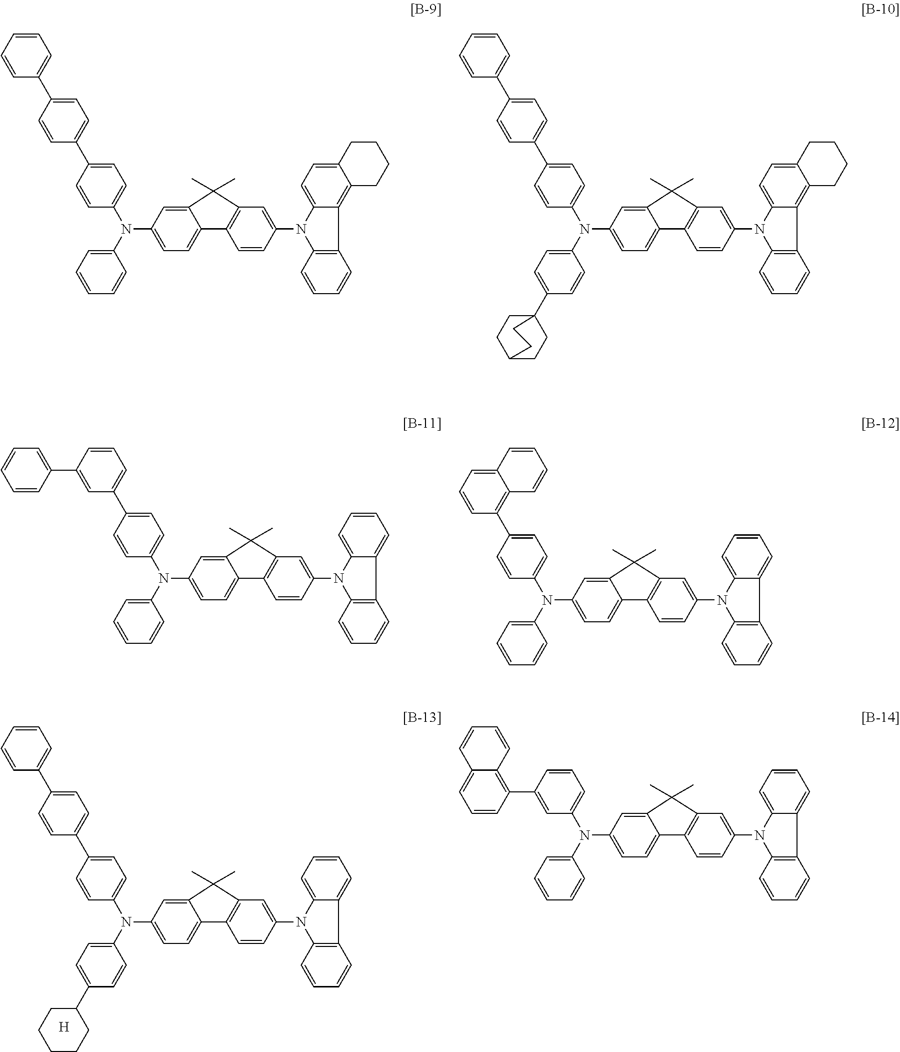

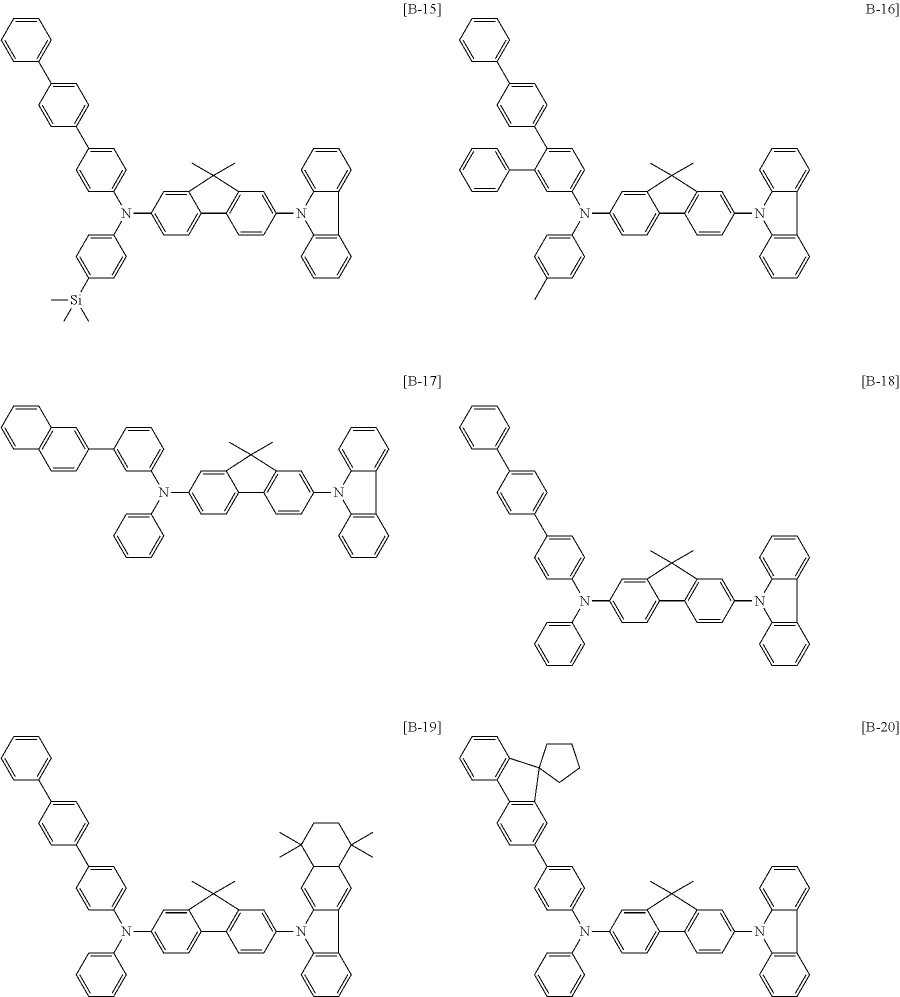

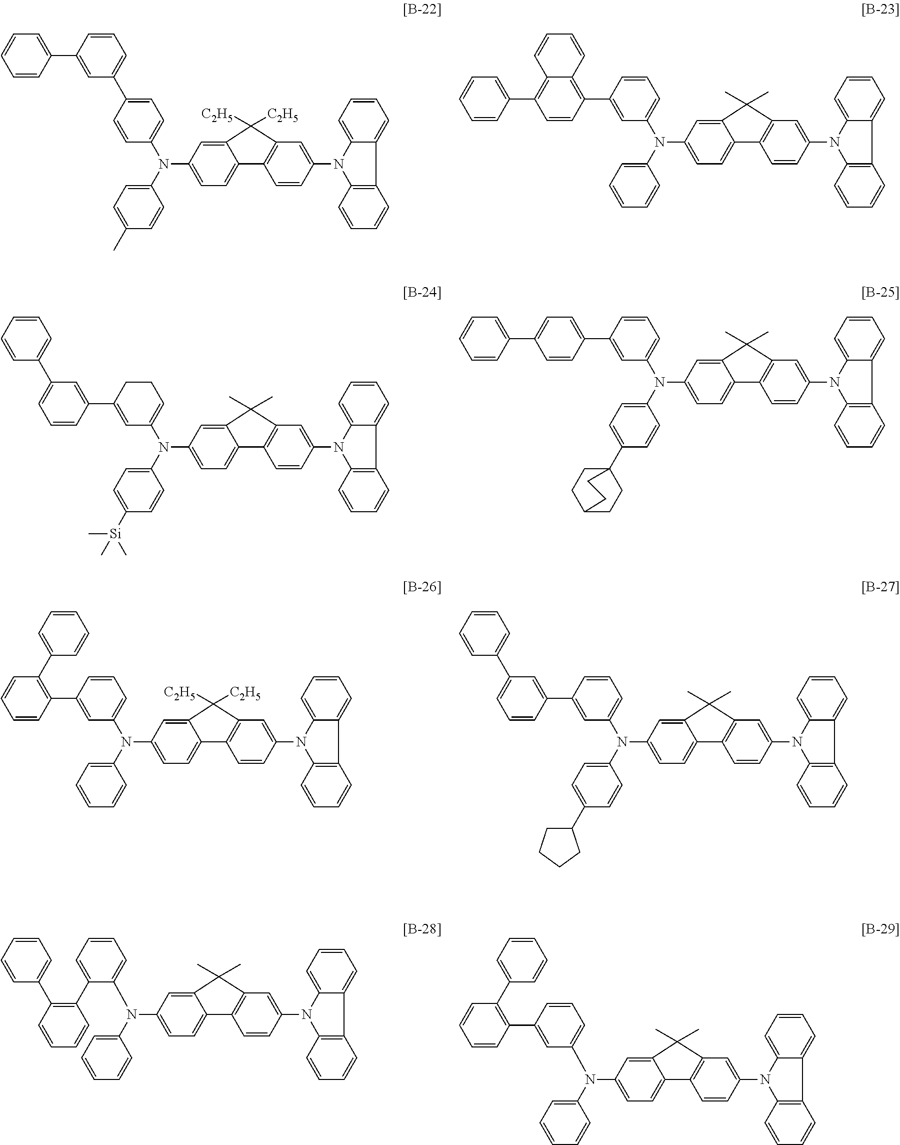

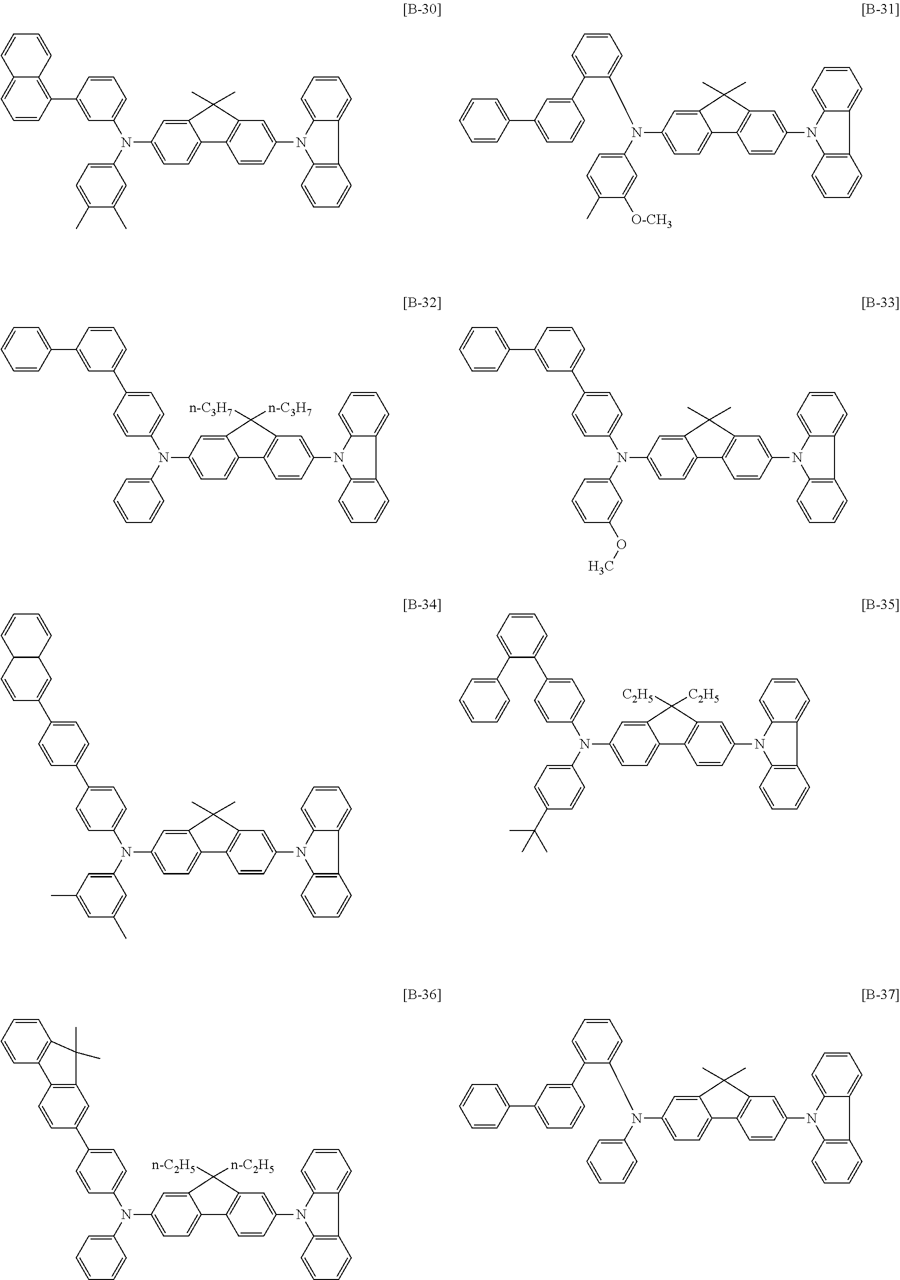

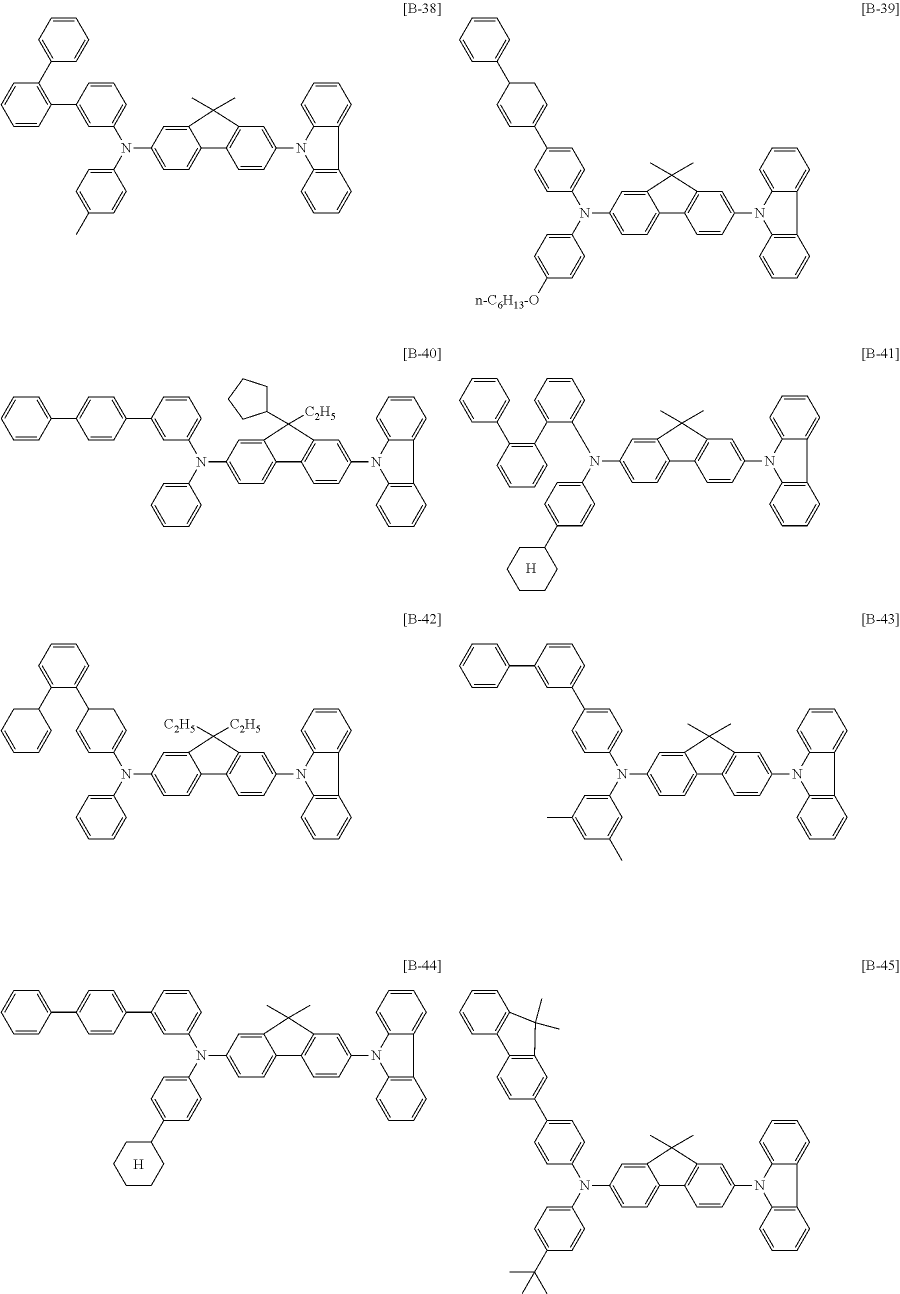

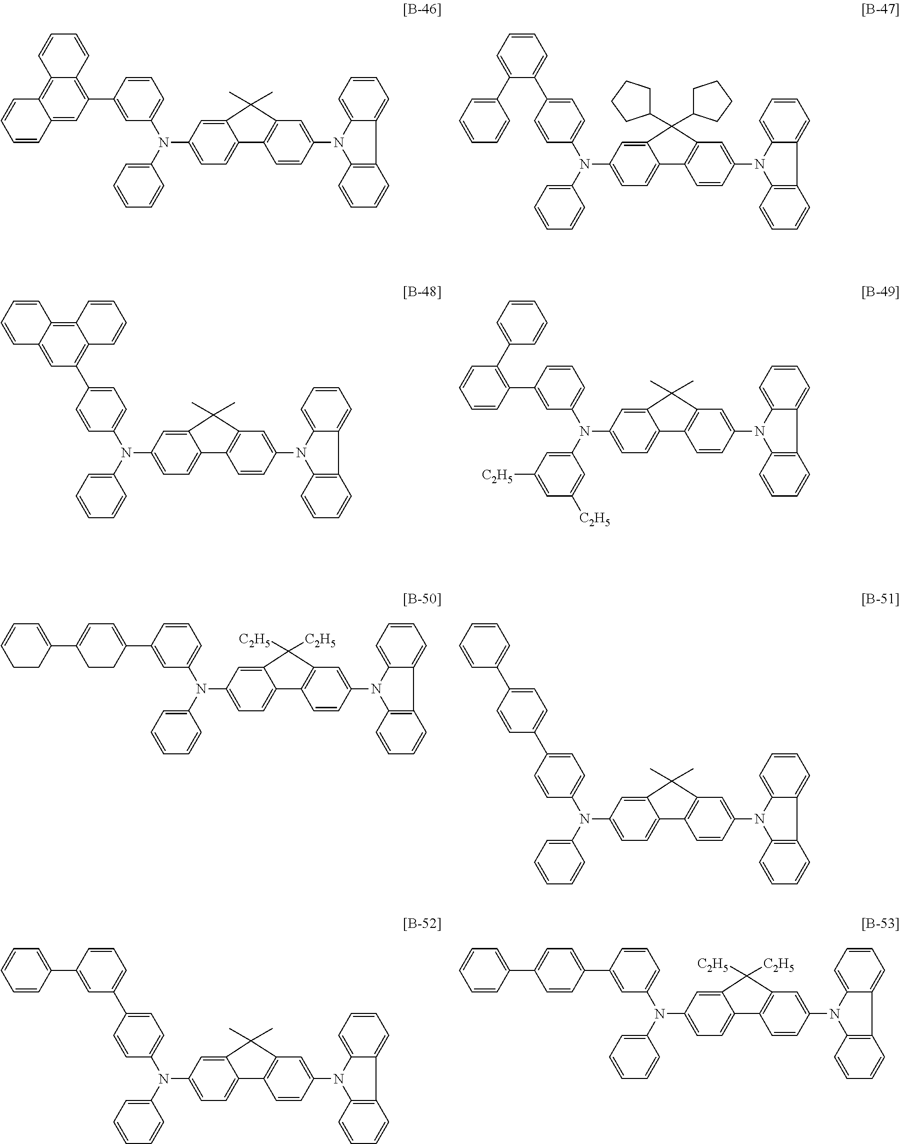

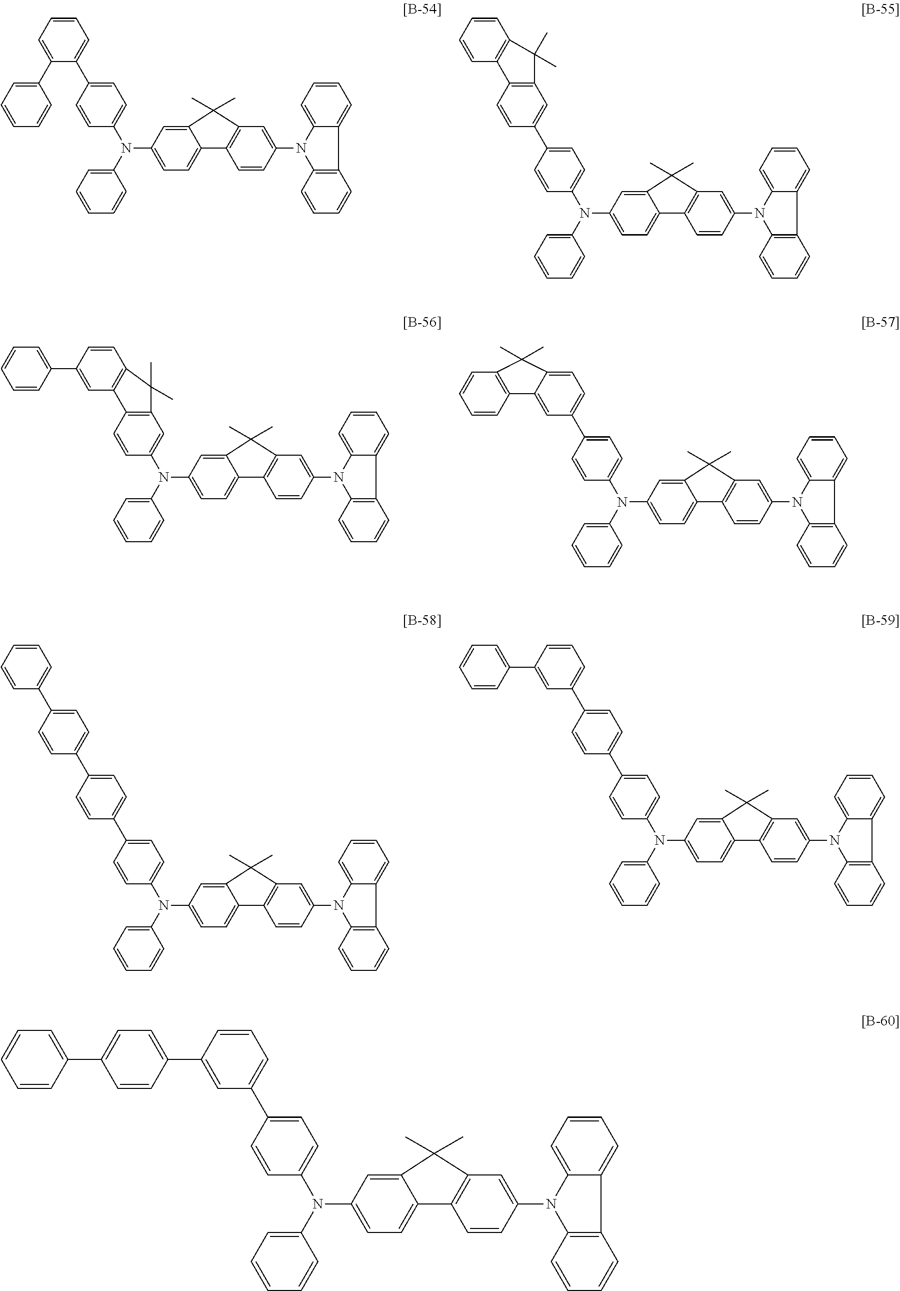

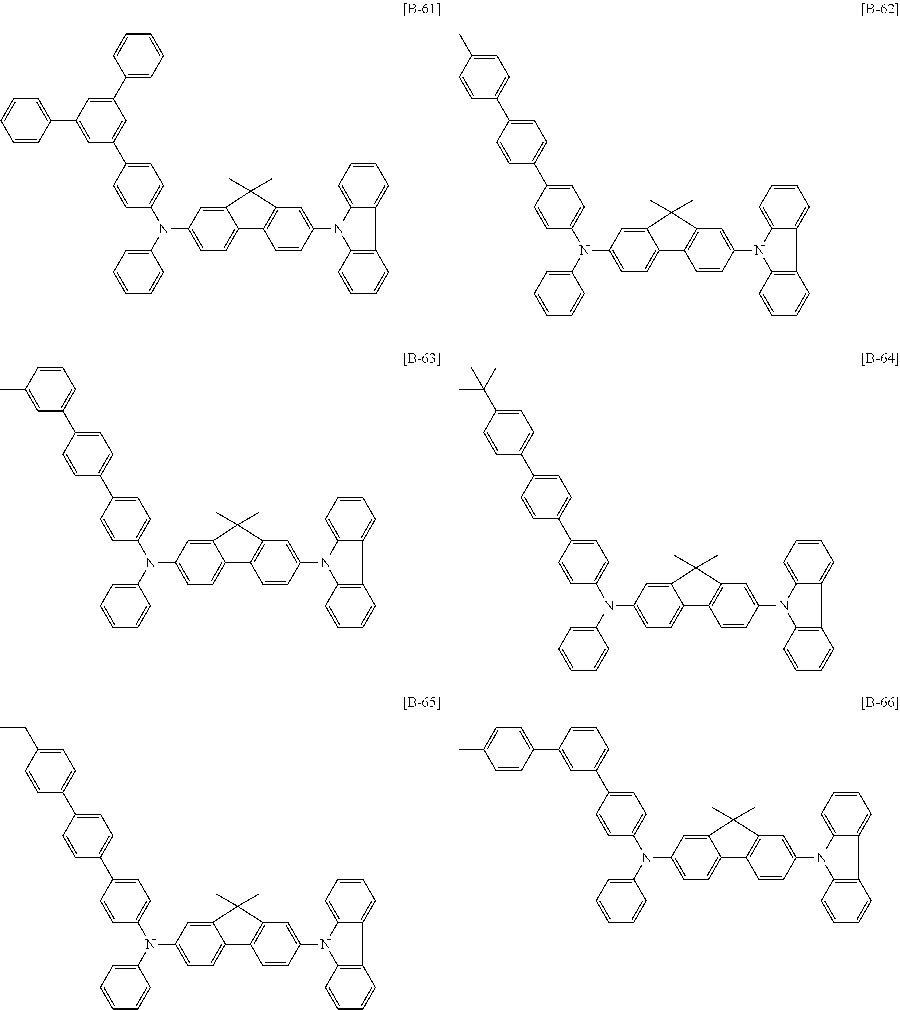

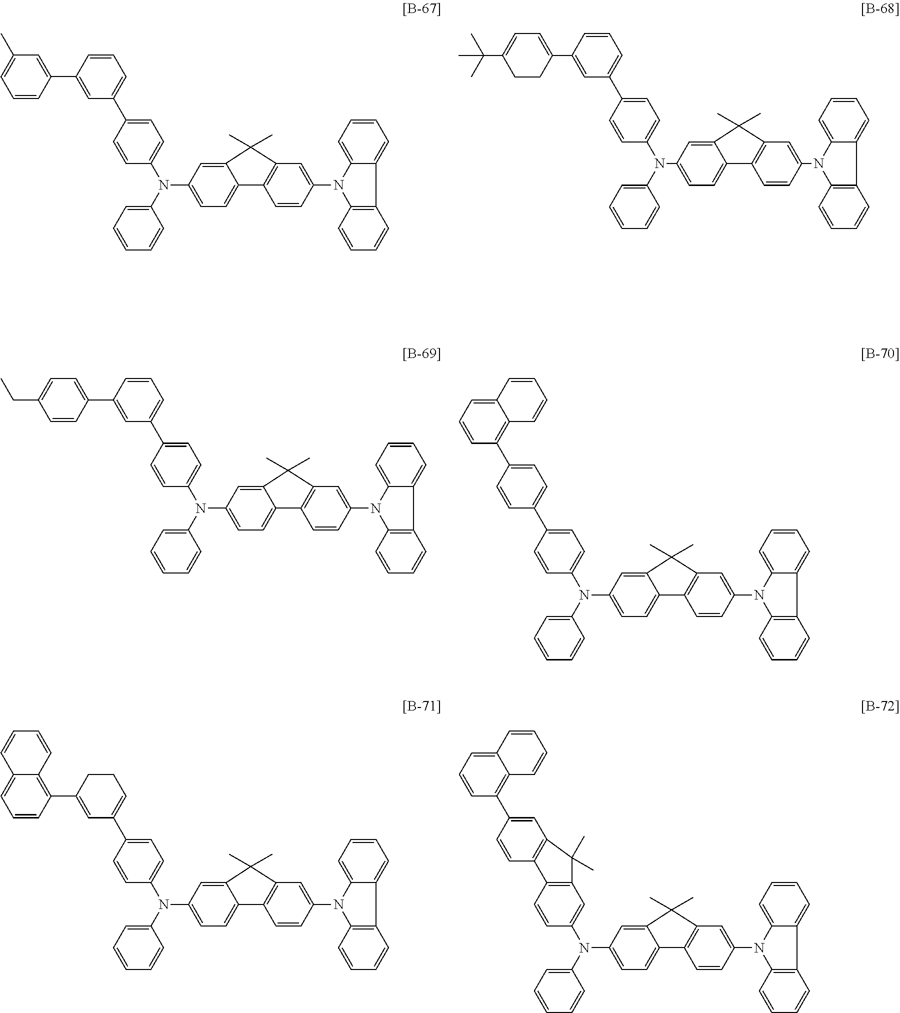

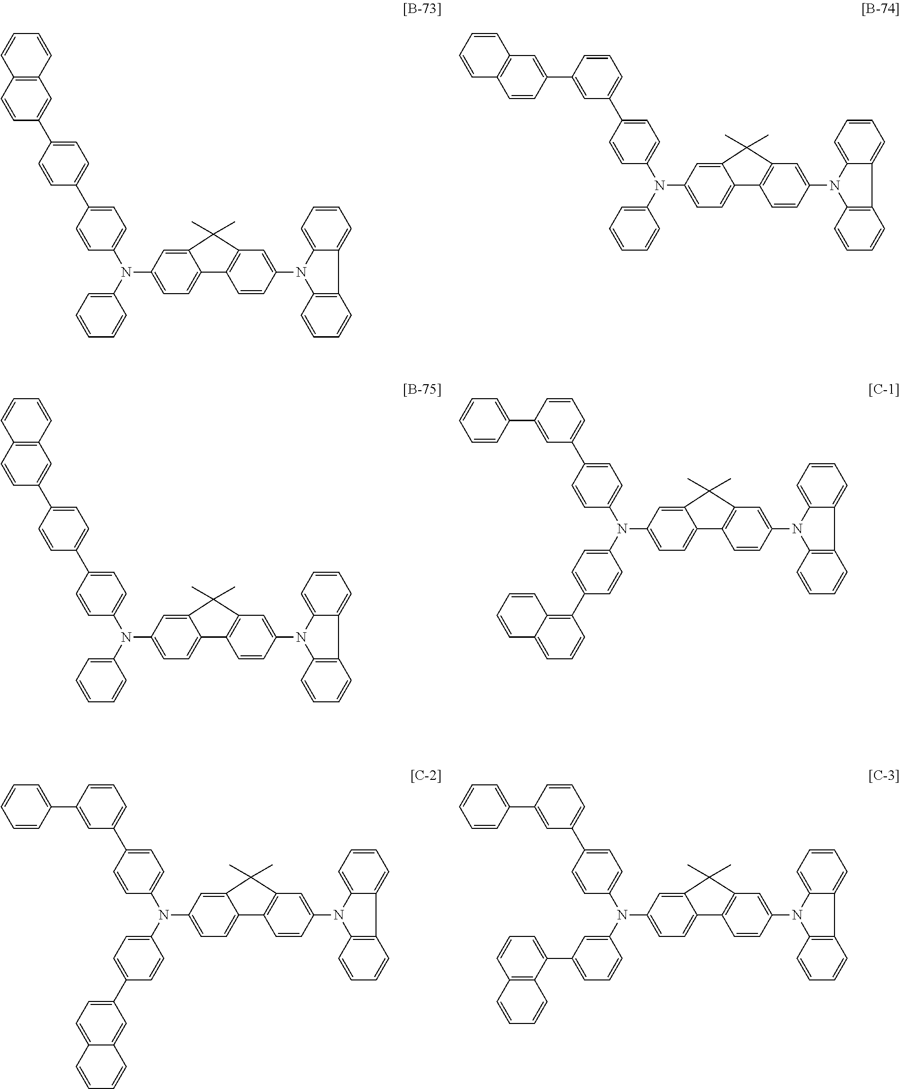

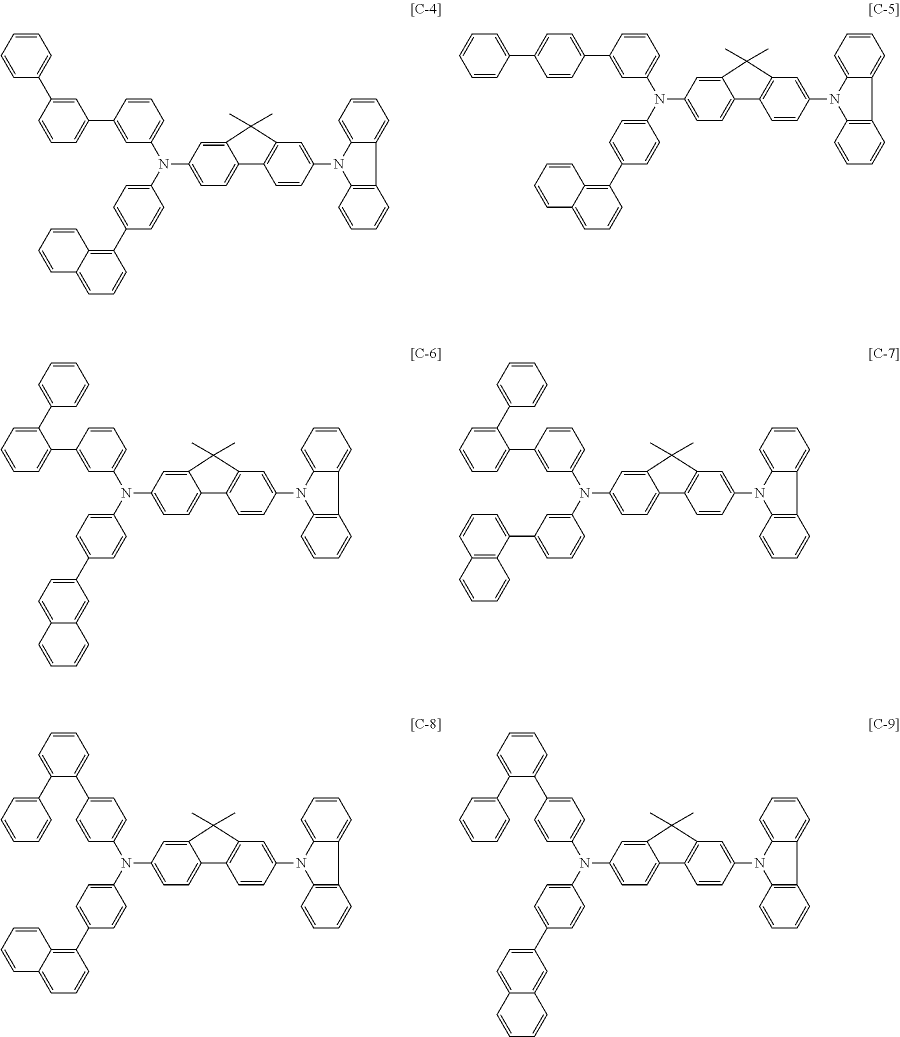

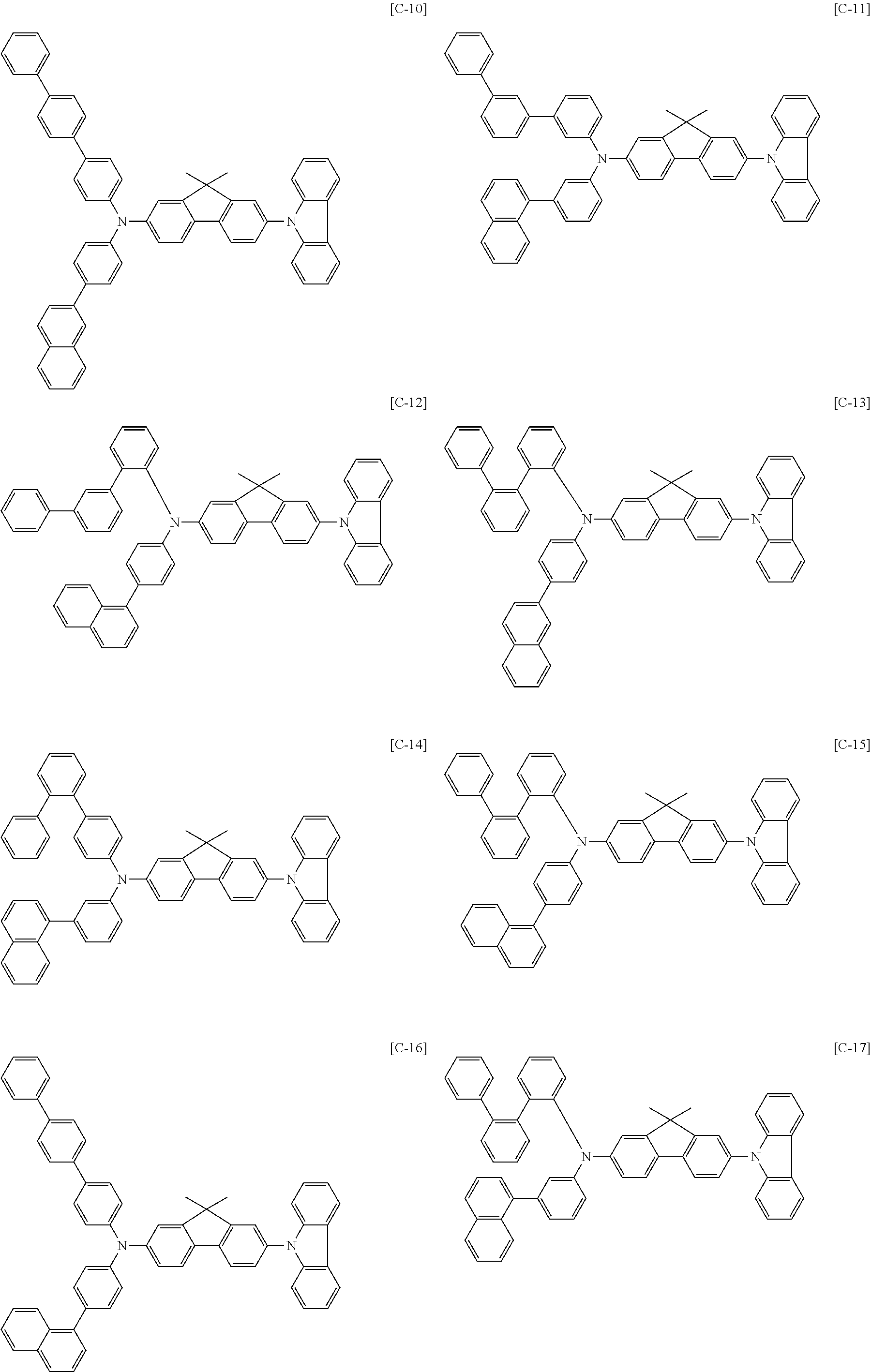

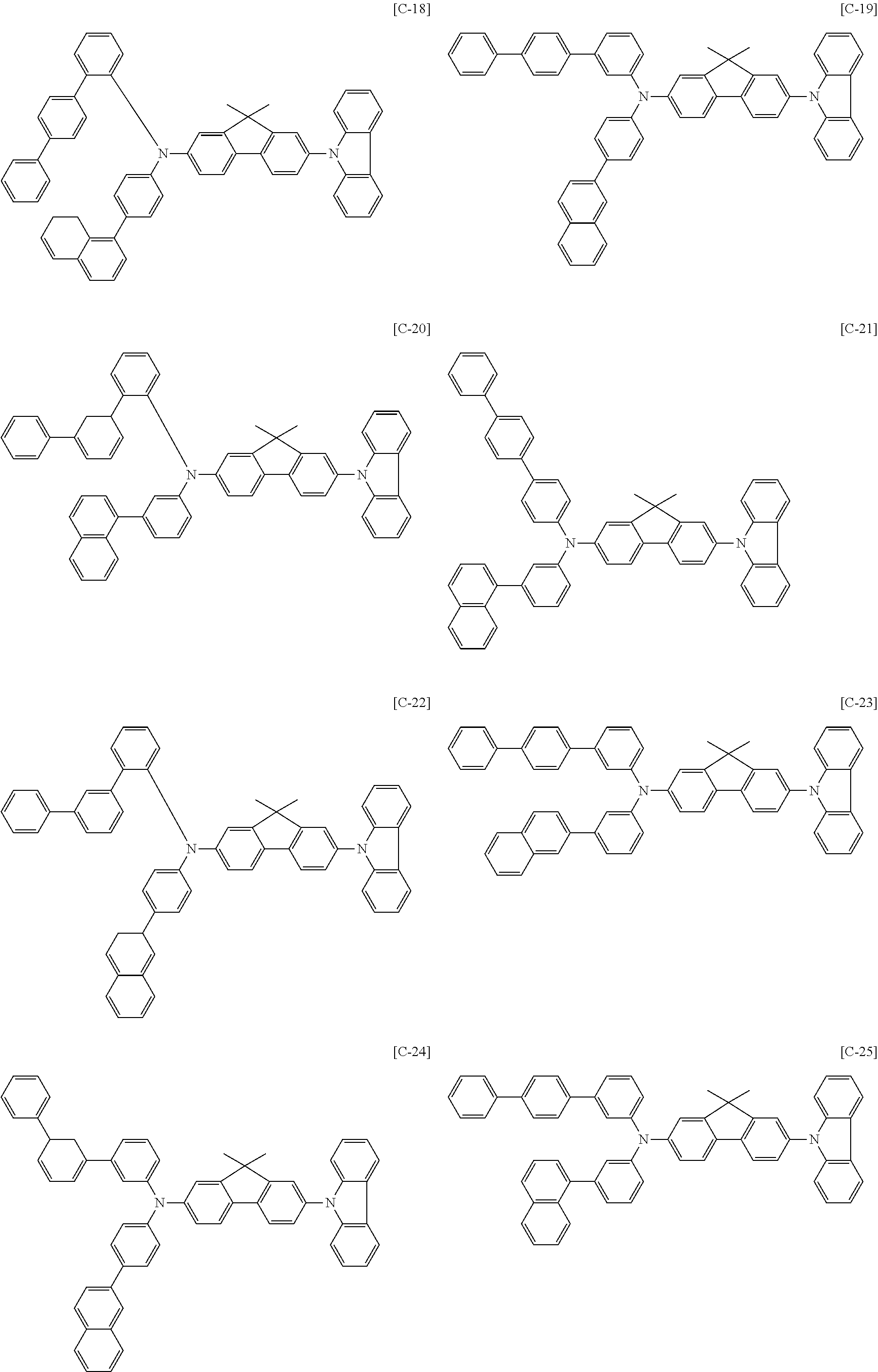

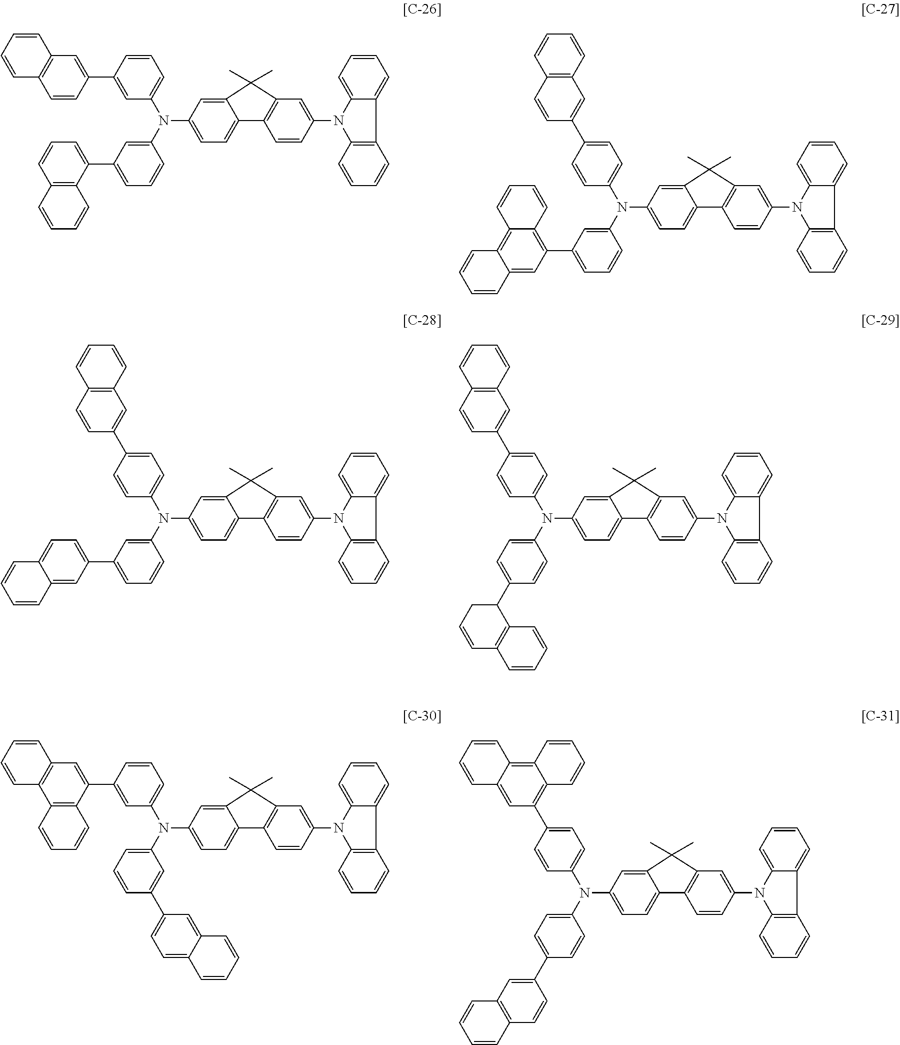

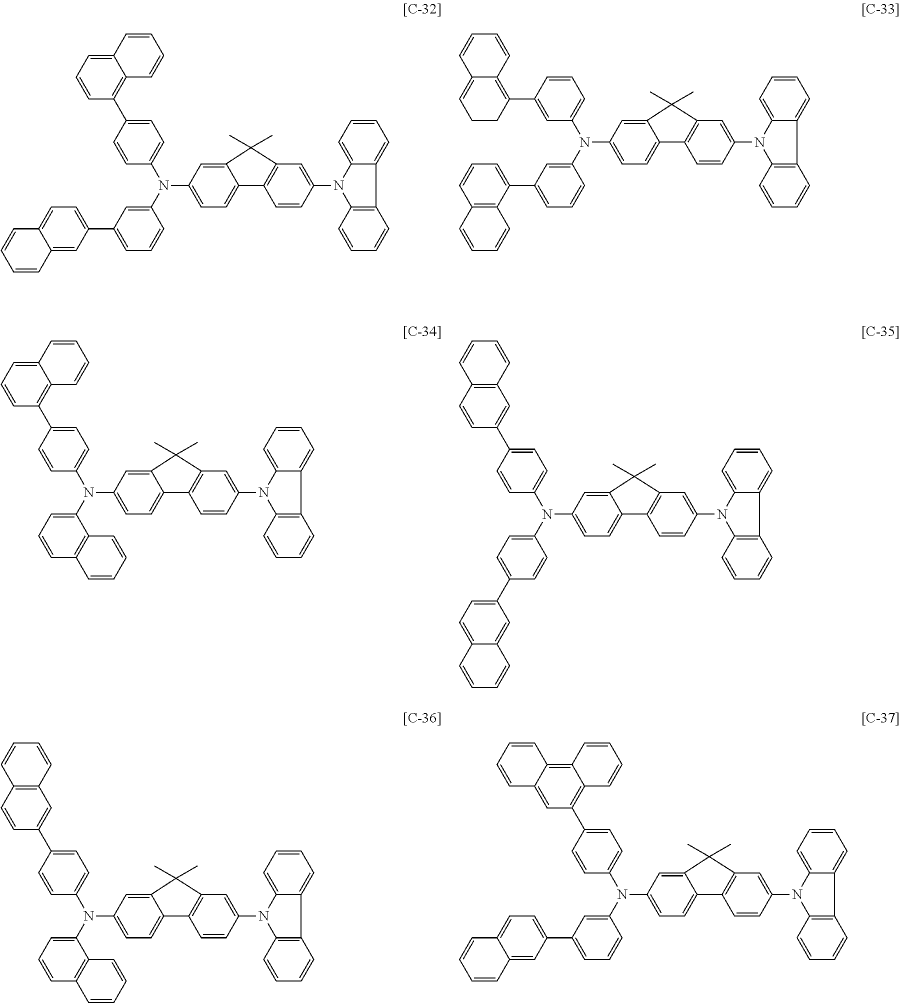

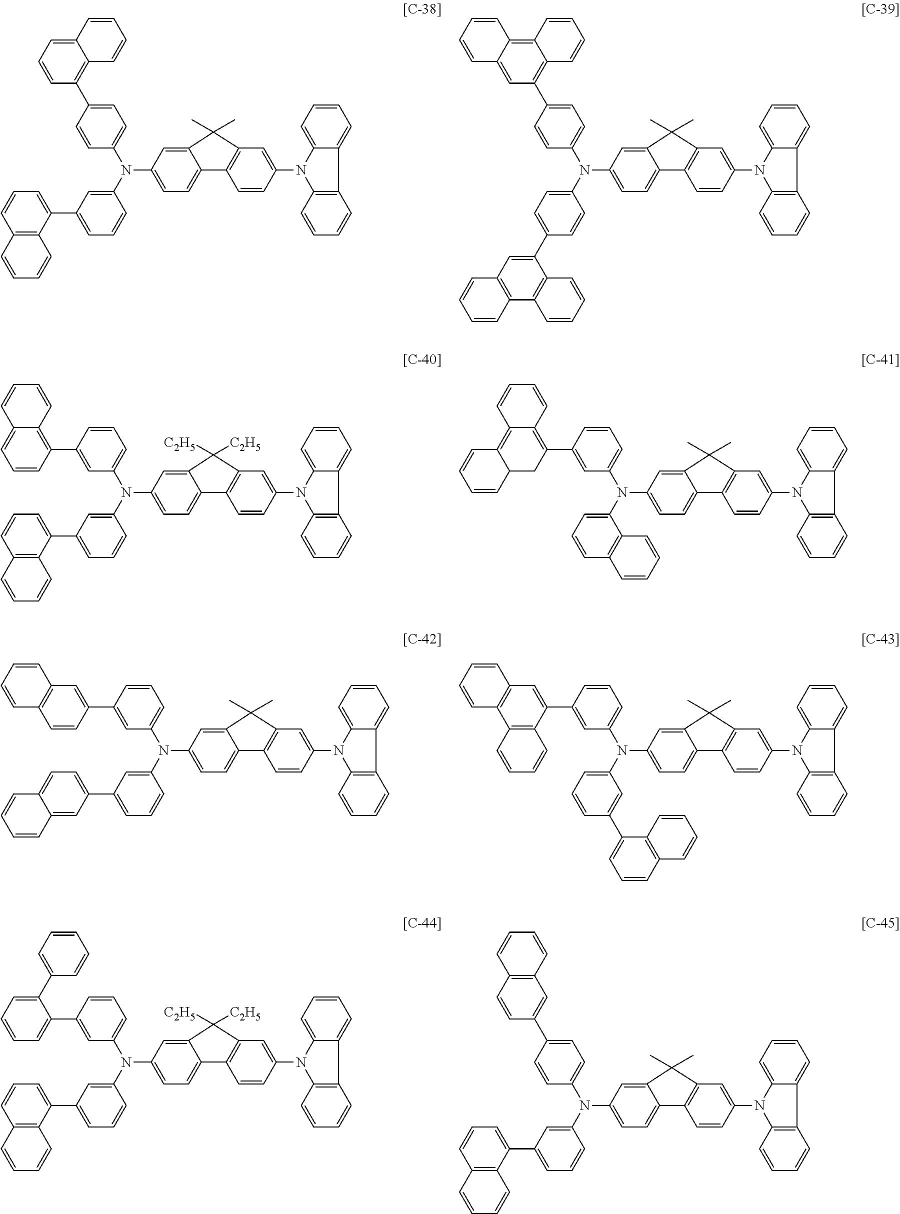

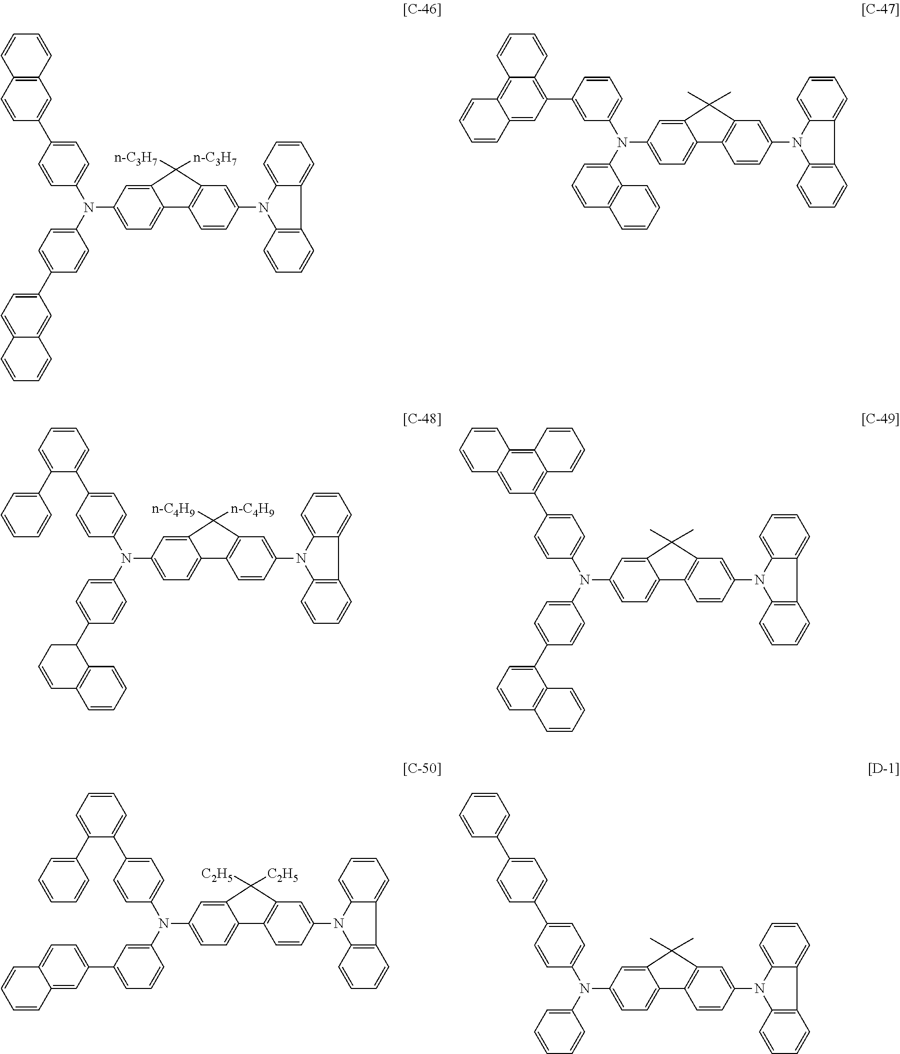

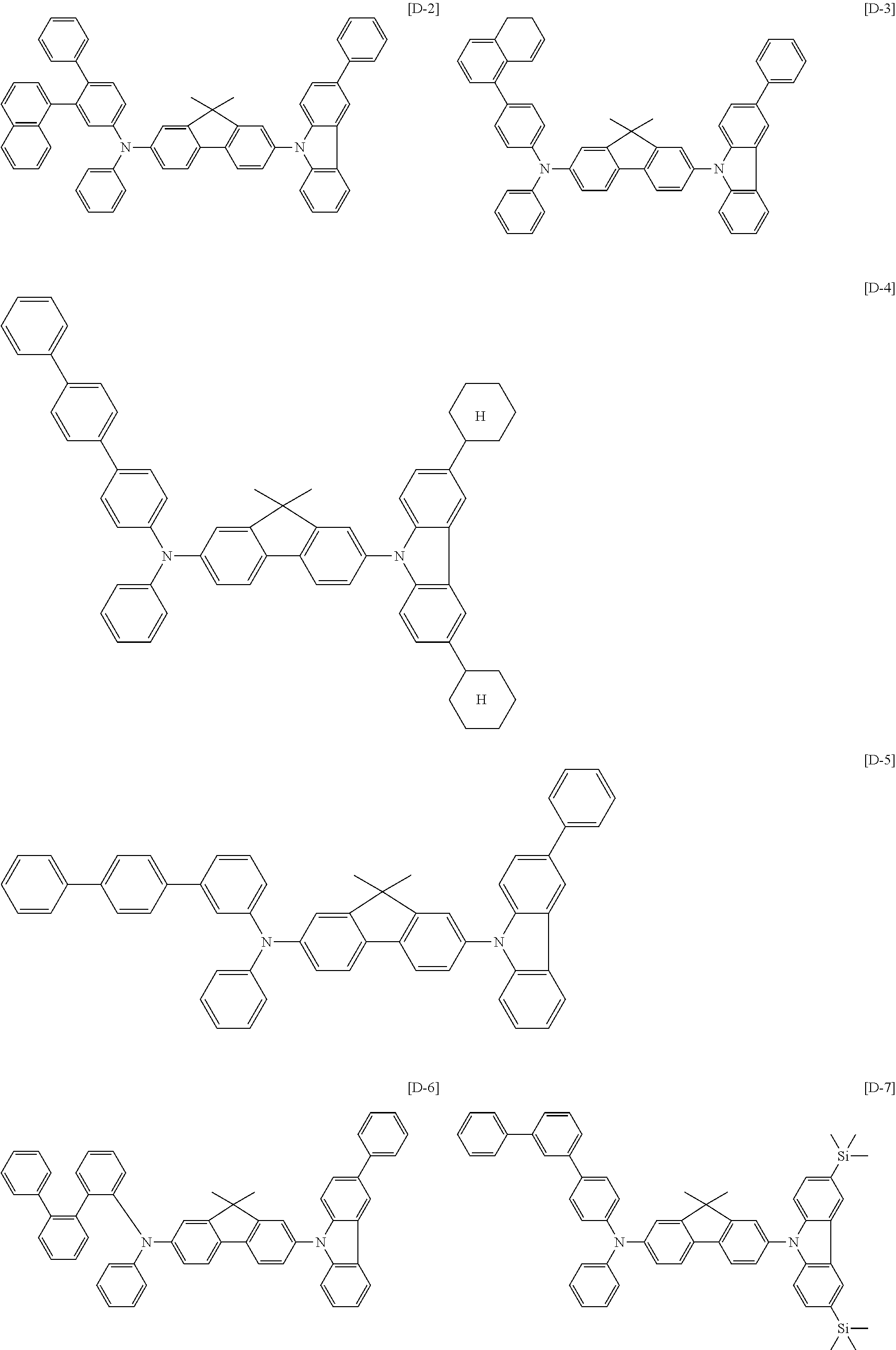

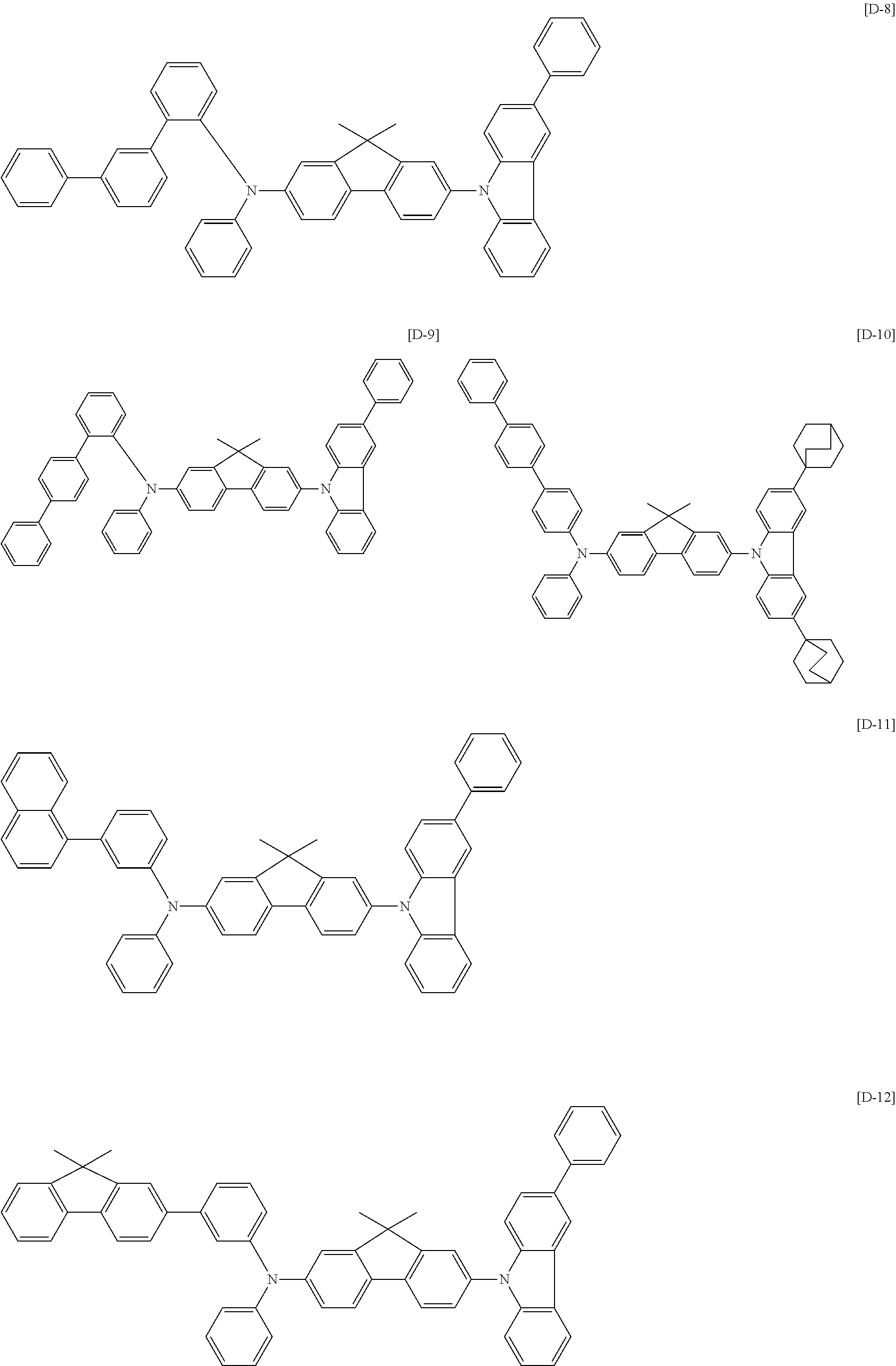

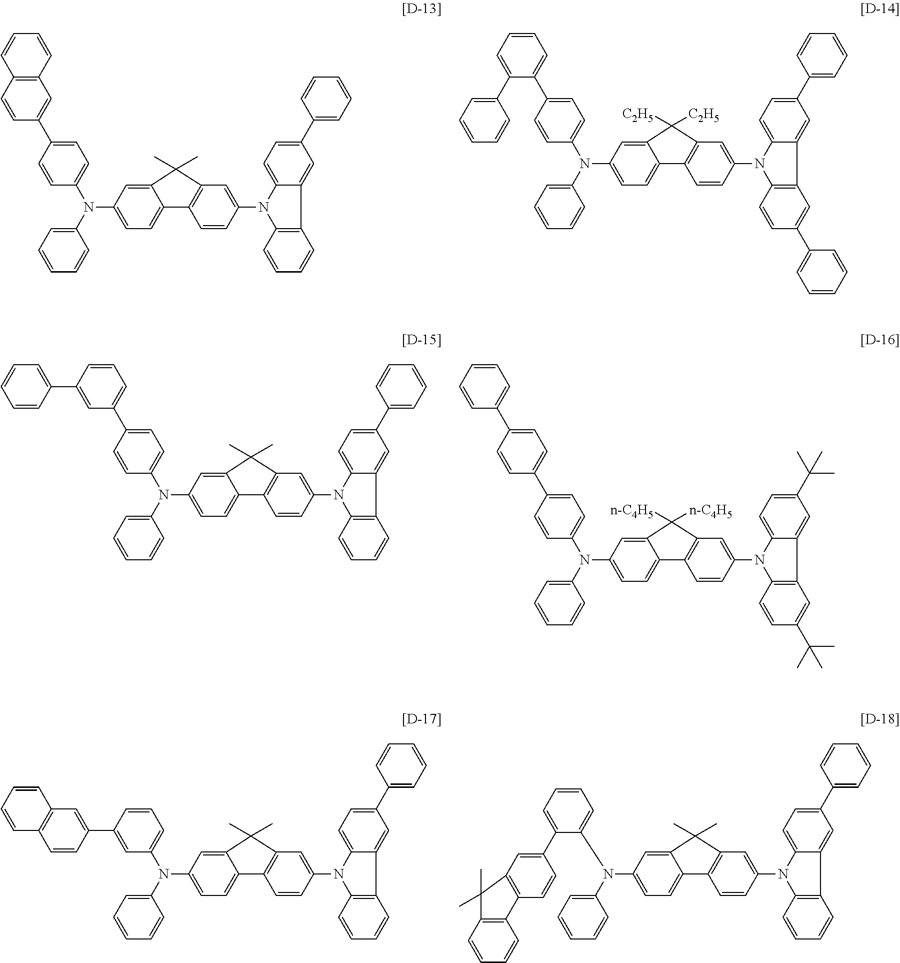

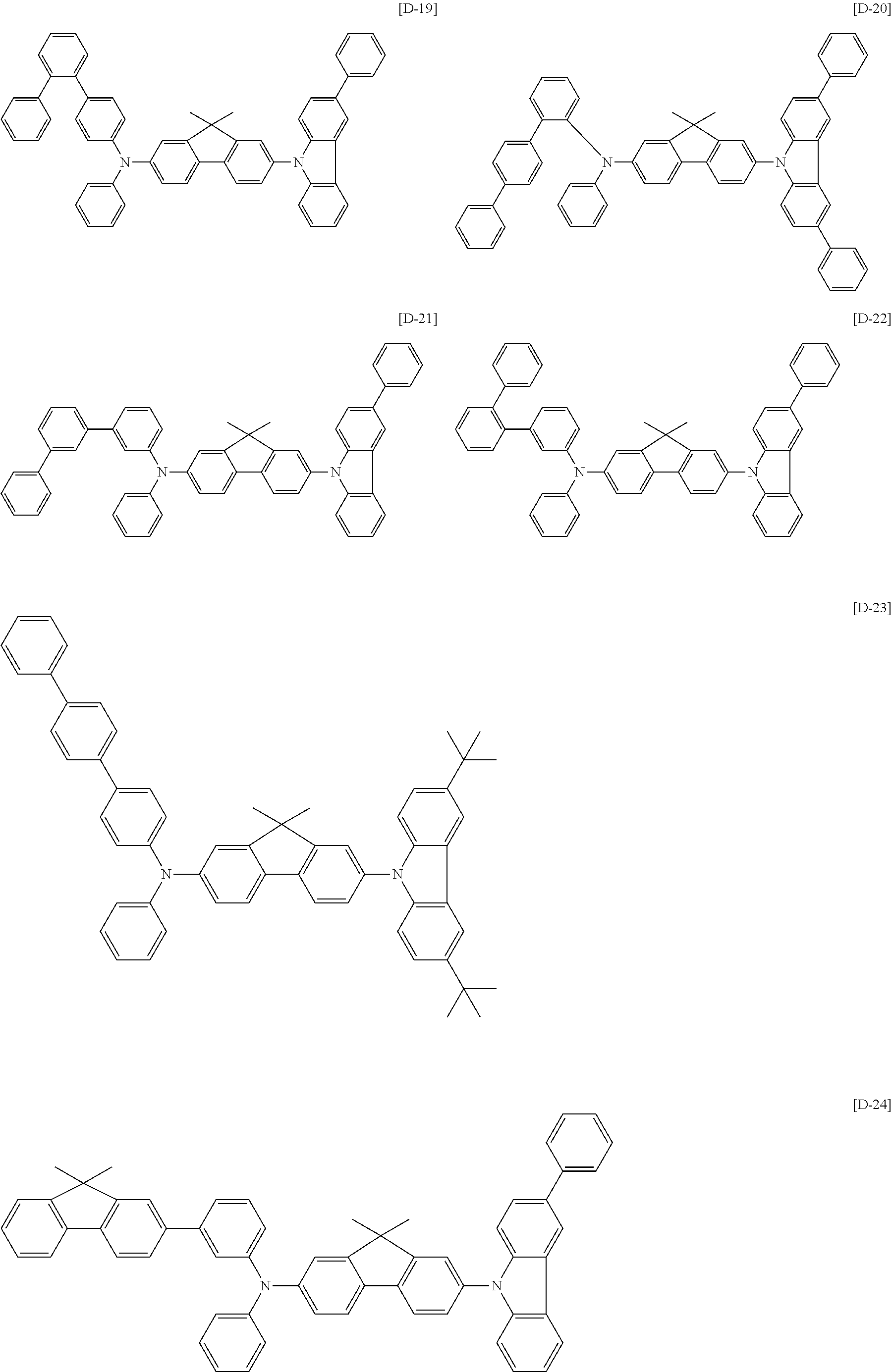

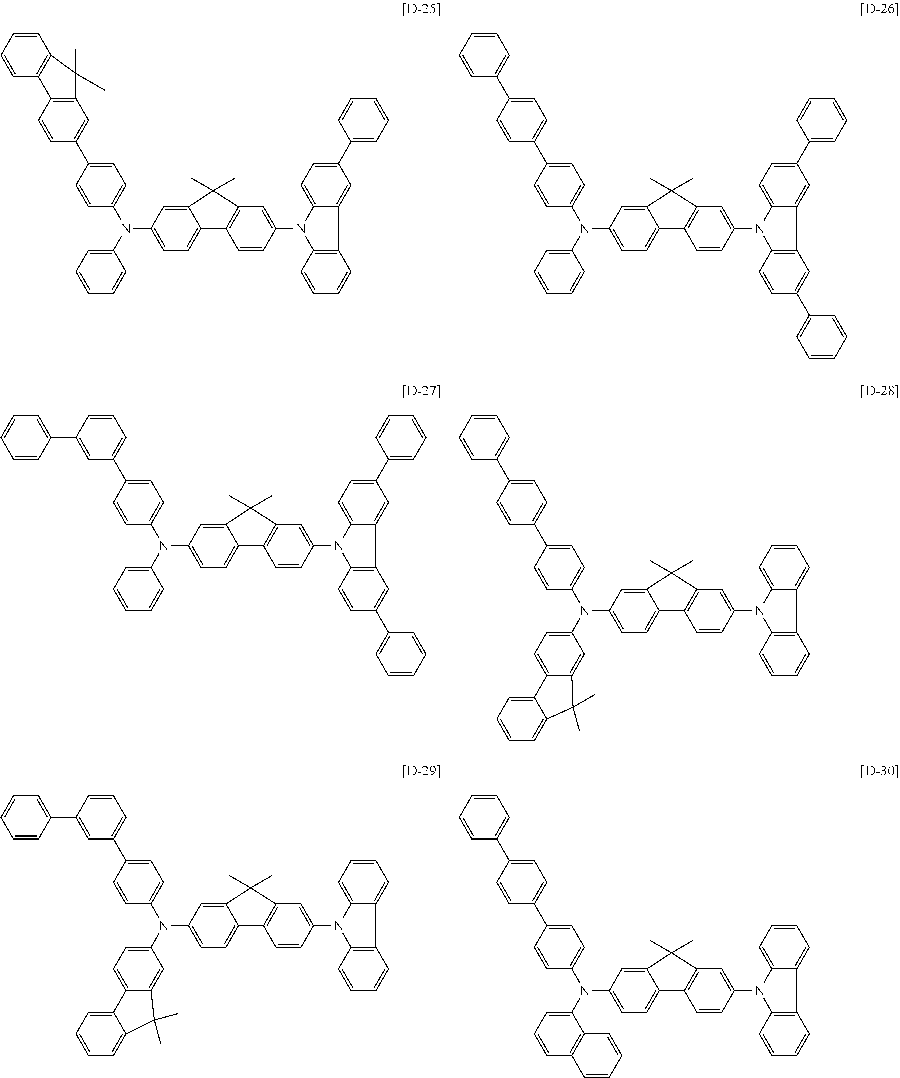

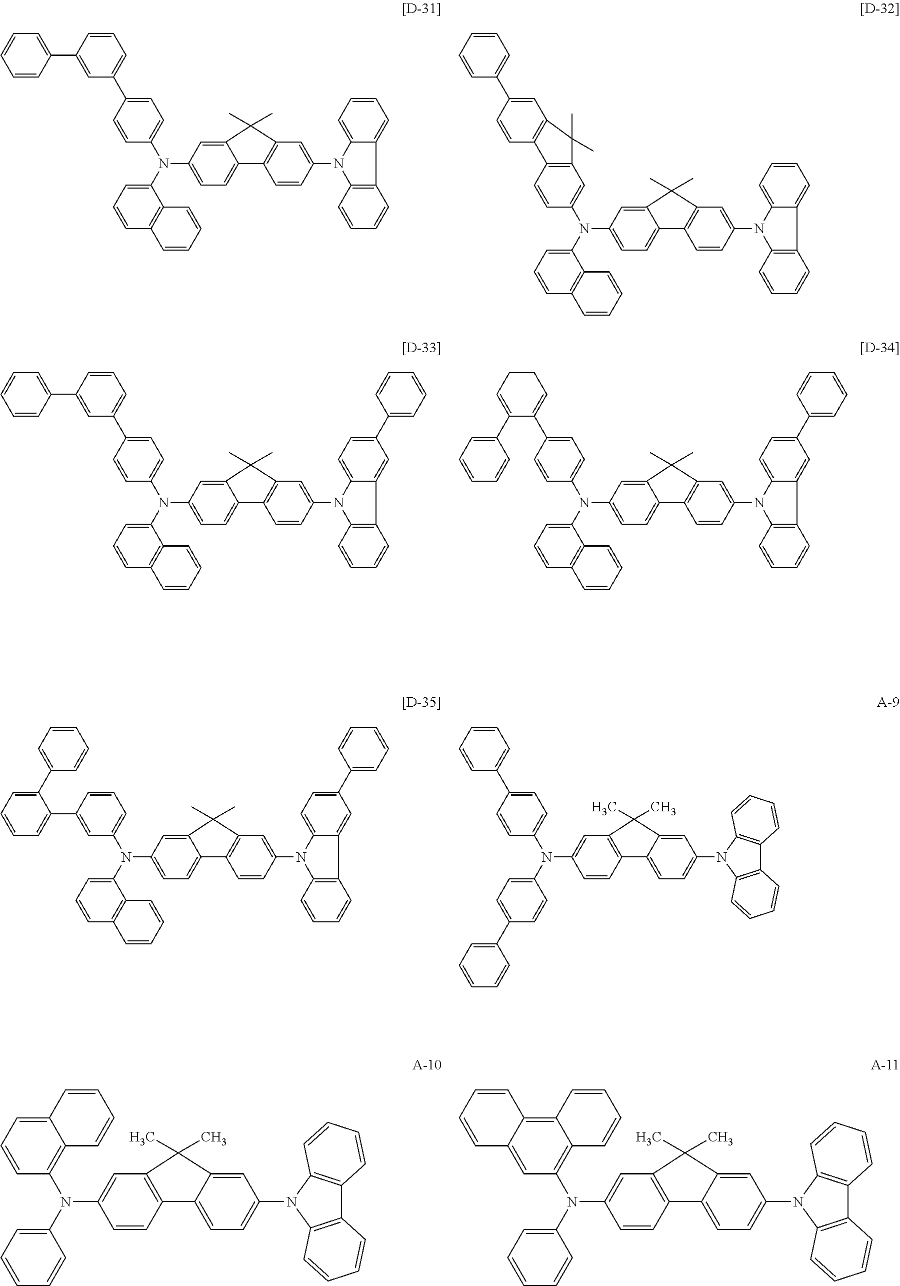

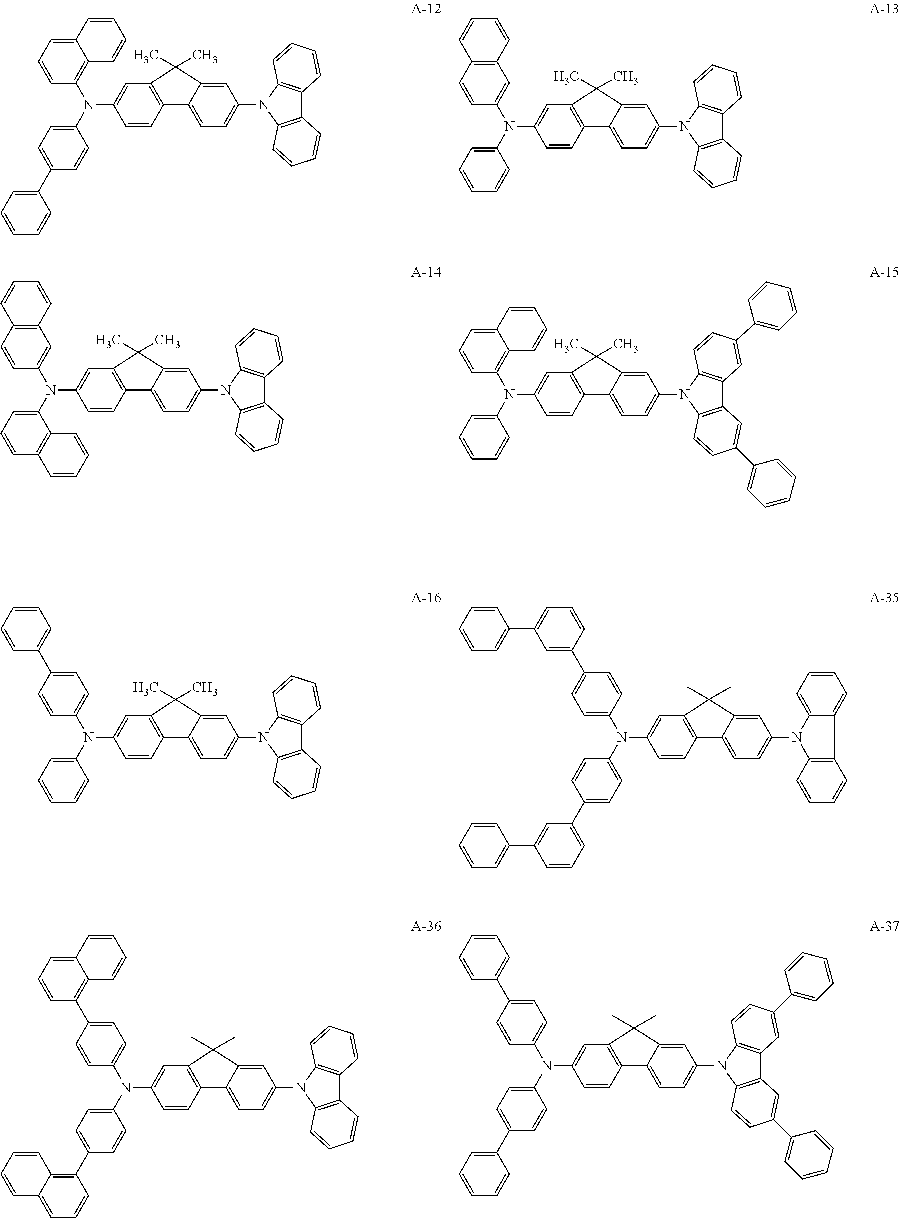

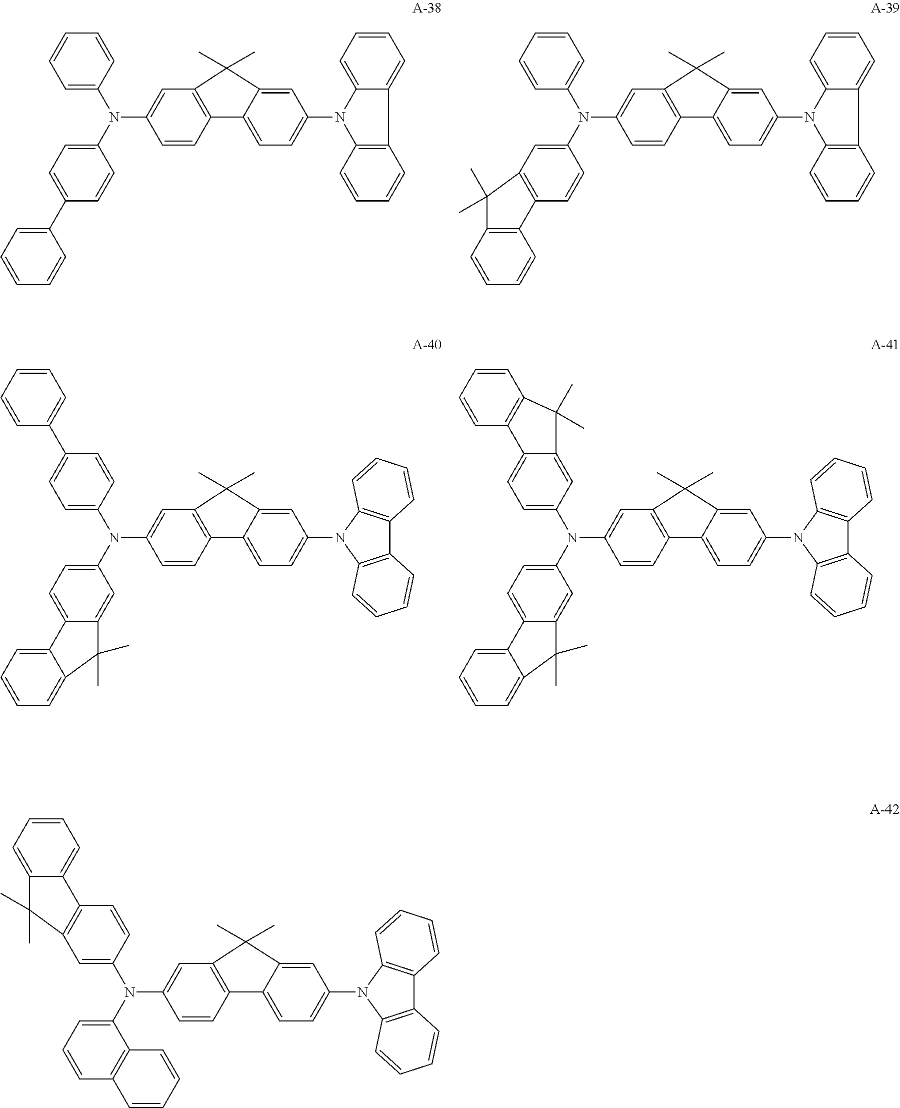 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(N(c3ccccc3)c3ccc4c(c3)C(C)(C)c3cc(-n5c6ccccc6c6ccccc65)ccc3-4)cc21 ; CC1(C)c2ccccc2-c2ccc(N(c3ccc(-c4ccccc4)cc3)c3ccc4c(c3)C(C)(C)c3cc(-n5c6ccccc6c6ccccc65)ccc3-4)cc21 ; CC1(C)c2ccccc2-c2ccc(N(c3ccc4c(c3)C(C)(C)c3ccccc3-4)c3ccc4c(c3)C(C)(C)c3cc(-n5c6ccccc6c6ccccc65)ccc3-4)cc21 ; CC1(C)c2ccccc2-c2ccc(N(c3ccc4c(c3)C(C)(C)c3cc(-n5c6ccccc6c6ccccc65)ccc3-4)c3cccc4ccccc34)cc21]

In addition, compounds having the following names are also specific examples of the compounds used in the second hole transporting layer.
1. N-(9′H-fluorene-2′-yl)-N-phenyl-9H-fluorene-2-amine
2. N-(9′H-fluorene-2′-yl)-N-(4″-methylphenyl-9H-fluorene-2-amine
3. N-(9′-methyl-9′H-fluorene-2′-yl)-N-(4″-methoxylphenyl)-9-methyl-9H-fluorene-2-amine
4. N-(9′,9′-dimethyl-9′H-fluorene-2′-yl)-N-phenyl-9,9-dimethyl-9H-fluorene-2-amine
5. N-(9′,9′-dimethyl-9′H-fluorene-2′-yl)-N-(3″-methylphenyl)-9,9-dimethyl-9H-fluorene-2-amine
6. N-(9′,9′-dimethyl-9′H-fluorene-2′-yl)-N-(4″-methylphenyl)-9,9-dimethyl-9H-fluorene-2-amine
7. N-(9′,9′-dimethyl-9′H-fluorene-2′-yl)-N-(4″-ethylphenyl)-9,9-dimethyl-9H-fluorene-2-amine
8. N-(9′,9′-dimethyl-9′H-fluorene-2′-yl)-N-(4″-tert-butylphenyl)-9,9-dimethyl-9H-fluorene-2-amine
9. N-(9′,9′-dimethyl-9′H-fluorene-2′-yl)-N-(3″0.4″-dimethylphenyl)-9,9-dimethyl-9H-fluorene-2-amine
10. N-(9′,9′-dimethyl-9H-fluorene-2′-yl)-N-(3″0.5″-dimethylphenyl)-9,9-dimethyl-9H-fluorene-2-amine
11. N-(9′,9′-dimethyl-9′H-fluorene-2′-yl)-N-(3″-methoxyphenyl)-9,9-dimethyl-9H-fluorene-2-amine
12. N-(9′,9′-dimethyl-9′H-fluorene-2′-yl)-N-(4″-methoxyphenyl)-9,9-dimethyl-9H-fluorene-2-amine
13. N-(9′,9′-dimethyl-9′H-fluorene-2′-yl)-N-(4″-ethoxyphenyl)-9,9-dimethyl-9H-fluorene-2-amine
14. N-(9′,9′-dimethyl-9′H-fluorene-2′-yl)-N-(4″-n-butoxyphenyl)-9,9-dimethyl-9H-fluorene-2-amine
15. N-(9′,9′-dimethyl-9′H-fluorene-2′-yl)-N-(3″-fluorophenyl)-9,9-dimethyl-9H-fluorene-2-amine
16. N-(9′,9′-dimethyl-9′H-fluorene-2′-yl)-N-(4″-chlorophenyl)-9,9-dimethyl-9H-fluorene-2-amine
17. N-(9′,9′-dimethyl-9′H-fluorene-2′-yl)-N-(4″-phenylphenyl)-9,9-dimethyl-9H-fluorene-2-amine
18. N-(9′,9′-dimethyl-9′H-fluorene-2′-yl)-N-(2″-naphthyl)-9,9-dimethyl-9H-fluorene-2-amine
19. N-(9′,9′-dimethyl-9′H-fluorene-2′-yl)-N-(2″-furyl)-9,9-dimethyl-9H-fluorene-2-amine
20. N-(9′,9′-dimethyl-9′H-fluorene-2′-yl)-N-(2″-thienyl)-9,9-dimethyl-9H-fluorene-2-amine
21. N-(9′,9′-dimethyl-9′H-fluorene-2′-yl)-N-(2″-pyridyl)-9,9-dimethyl-9H-fluorene-2-amine
22. N-(4′-fluoro-9′,9′-dimethyl-9′H-fluorene-2′-yl)-N-(4″-methylphenyl)-4-fluoro-9,9-dimethyl-9H-fluorene-2-amine
23. N-(7′-n-butyl-9′,9′-dimethyl-9′-fluorene-2′-yl)-N-(4″-methylphenyl)-7-n-butyl-9,9-dimethyl-9H-fluorene-2-amine
24. N-(7′-methoxy-9′,9′-dimethyl-9′H-fluorene-2′-yl)-N-phenyl-7-methoxy-9,9-dimethyl-9H-fluorene-2-amine
25. N-(7′-phenyl-9′,9′-dimethyl-9′H-fluorene-2′-yl)-N-phenyl-7-phenyl-9,9-dimethyl-9H-fluorene-2-amine
26. N-(9′,9′-diethyl-9′H-fluorene-2′-yl)-N-(4″-methylphenyl)-9,9-diethyl-9H-fluorene-2-amine
27. N-(9′,9′-diethyl-9′H-fluorene-2′-yl)-N-(4″-methoxyphenyl)-9,9-diethyl-9H-fluorene-2-amine
28. N-(4′-methyl-9′,9′-diethyl-9′H-fluorene-2′-yl)-N-(4″-methylphenyl)-4-methyl-9,9-diethyl-9H-fluorene-2-amine
29. N-(9′-isopropyl-9′H-fluorene-2′-yl)-N-(4″-methoxylphenyl)-9-isopropyl-9H-fluorene-2-amine
30. N-(9′,9′-di-n-propyl-9′H-fluorene-2′-yl)-N-phenyl-9,9-di-n-propyl-9H-fluorene-2-amine
31. N-(9′,9′-di-n-propyl-9′H-fluorene-2′-yl)-N-(4″-methylphenyl)-9,9-di-n-propyl-9H-fluorene-2-amine
32. N-(9′,9′-di-n-propyl-9′H-fluorene-2′-yl)-N-(4″-methoxyphenyl)-9,9-di-n-propyl-9H-fluorene-2-amine
33. N-(9′,9′-di-n-butyl-9′H-fluorene-2′-yl)-N-phenyl-9,9-di-n-butyl-9H-fluorene-2-amine
34. N-(9′,9′-di-n-butyl-9′H-fluorene-2′-yl)-N-(4″-methylphenyl)-9,9-di-n-butyl-9H-fluorene-2-amine
35. N-(9′,9′-di-n-pentyl-9′H-fluorene-2′-yl)-N-(4″-methylphenyl)-9,9-di-n-pentyl-9H-fluorene-2-amine
36. N-(9′,9′-di-n-hexyl-9′H-fluorene-2′-yl)-N-(4″-methoxyphenyl)-9,9-di-n-hexyl-9H-fluorene-2-amine
37. N-(9′,9′-di-n-hexyl-9′H-fluorene-2′-yl)-N-(4″-phenylphenyl)-9,9-di-n-hexyl-9H-fluorene-2-amine
38. N-(9′,9′-di-n-hexyl-9′H-fluorene-2′-yl)-N-(2″-naphthyl)-9,9-di-n-hexyl-9H-fluorene-2-amine
39. N-(9′-cyclohexyl-9′H-fluorene-2′-yl)-N-(4″-methylphenyl)-9-cyclohexyl-9H-fluorene-2-amine
40. N-(7′-phenyl-9′9′-di-n-octyl-9′H-fluorene-2′-yl)-N-(2″-naphthyl)-7-phenyl-9,9-di-n-octyl-9H-fluorene-2-amine
41. N-(9′-methyl-9′-ethyl-9′H-fluorene-2′-yl)-N-(4″-methoxylphenyl)-9-methyl-9-ethyl-9H-fluorene-2-amine
42. N-(9′-methyl-9′-n-propyl-9′H-fluorene-2′-yl)-N-(4″-methylphenyl)-9-methyl-9-n-propyl-9H-fluorene-2-amine
43. N-(9′-ethyl-9′-n-hexyl-9′H-fluorene-2′-yl)-N-(4″-ethylphenyl)-9-methyl-9-n-hexyl-9H-fluorene-2-amine
44. N-(9′-ethyl-9′-cyclohexyl-9′H-fluorene-2′-yl)-N-(4″-ethylphenyl)-9-ethyl-9-cyclohexyl-9H-fluorene-2-amine
45. N-(9′,9′-dimethyl-9′H-fluorene-2′-yl)-N-(4″-methylphenyl)-9H-fluorene-2-amine
46. N-(9′,9′-dimethyl-9′H-fluorene-2′-yl)-N-(4″-ethylphenyl)-9,9-diethyl-9H-fluorene-2-amine
47. N-(9′-benzyl-9′H-fluorene-2′-yl)-N-(4″-ethylphenyl)-9-benzyl-9H-fluorene-2-amine
48. N-(9′,9′-dibenzyl-9′H-fluorene-2′-yl)-N-phenyl-9,9-dibenzyl-9H-fluorene-2-amine
49. N-(9′,9′-dibenzyl-9′H-fluorene-2′-yl)-N-(4″-methoxyphenyl)-9,9-dibenzyl-9H-fluorene-2-amine
50. N-(9′,9′-dibenzyl-9′H-fluorene-2′-yl)-N-(4″-phenylphenyl)-9,9-dibenzyl-9H-fluorene-2-amine
51. N-(9′,9′-dibenzyl-9′H-fluorene-2′-yl)-N-(2″-naphthyl)-9,9-dibenzyl-9H-fluorene-2-amine
52. N-(9′-methyl-9′-benzyl-9′H-fluorene-2′-yl)-N-(4″-methylphenyl)-9-methyl-9-benzyl-9H-fluorene-2-amine
53. N-(9′,9′-dibenzyl-9′H-fluorene-2′-yl)-N-(4″-ethylphenyl)-9,9-dimethyl-9H-fluorene-2-amine
54. N-[9′-(4″-methylphenyl)-9′H-fluorene-2′-yl]-N-phenyl-9-(4″-methylphenyl)-9H-fluorene-2-amine
55. N-(9′,9′-diphenyl-9′H-fluorene-2′-yl)-N-phenyl-9,9-diphenyl-9H-fluorene-2-amine
56. N-(9′,9′-diphenyl-9′H-fluorene-2′-yl)-N-(3″-methylphenyl)-9,9-diphenyl-9H-fluorene-2-amine
57. N-[9′,9′-di(4″-methylphenyl)-9′H-fluorene-2′-yl]-N-phenyl-9,9-di(4′″-methylphenyl)-9H-fluorene-2-amine
58. N-[9′,9′-di(4″-methoxyphenyl)-9H-fluorene-2′-yl]-N-phenyl-9,9-di(4′″-methoxyphenyl)-9H-fluorene-2-amine
59. N-(9′-methyl-9′-phenyl-9′H-fluorene-2′-yl)-N-(4″-methylphenyl)-9-methyl-9-phenyl-9H-fluorene-2-amine
60. N-(9′-ethyl-9′-phenyl-9′H-fluorene-2′-yl)-N-(4″-methylphenyl)-9-ethyl-9-phenyl-9H-fluorene-2-amine
61. N-(9′,9′-diphenyl-9′H-fluorene-2′-yl)-N-phenyl-9,9-dimethyl-9H-fluorene-2-amine

### First Hole Transporting Layer

The organic EL device according to the exemplary embodiment has the first hole transporting layer adjacent to a side near the anode of the second hole transporting layer. The first hole transporting layer contains a compound represented by the following formula (5) and is not adjacent to the emitting layer.

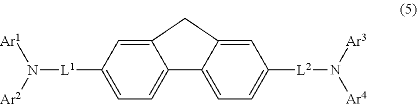

In the formula (5), R¹ and R² each independently represent a hydrogen atom or an alkyl group having 1 to 10 carbon atoms.

In the formula (5), L¹ and L² each independently represent a single bond or a substituted or unsubstituted arylene group having 6 to 30 ring carbon atoms.

In the formula (5), Ar¹ to Ar⁴ each independently represent a substituted or unsubstituted aryl group having 6 to 30 ring carbon atoms.

The compound represented by the formula (5) is preferably a compound represented by the following formula (5-1) or (5-2). In the formulae (5-1) and (5-2), R¹, R², L², and Ar¹ to Ar⁴ respectively represent the same as those in the formula (5).

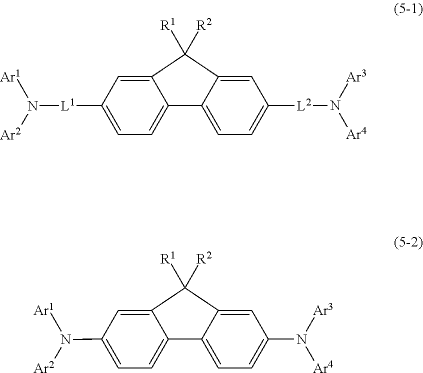

Examples of the alkyl group having 1 to 10 carbon atoms for R¹ and R² in the formulae (5), (5-1) and (5-2) include a methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, and neo-pentyl group, among which a methyl group, ethyl group, n-propyl group, isopropyl group, n-butyl group, s-butyl group, isobutyl group, t-butyl group are preferable.

Examples of the aryl group having 6 to 30 ring carbon atoms for Ar¹ to Ar⁴ in the formulae (5), (5-1) and (5-2) include a phenyl group, naphthyl group, anthryl group, phenanthryl group, naphthacenyl group, chrysenyl group, pyrenyl group, biphenyl group, terphenyl group, tolyl group, fluoranthenyl group and fluorenyl group, among which a phenyl group, naphthyl group, biphenyl group and terphenyl group are preferable.

Examples of the arylene group having 6 to 30 ring carbon atoms for L¹ and L² in the formulae (5), (5-1) and (5-2) are a divalent group derived from the aryl group represented by Ar¹ to Ar⁴, among which a phenylene group is preferable.

The compounds represented by the formulae (5), (5-1) and (5-2) and used for the first hole transporting layer are specifically exemplified below, but is not limited to the examples.

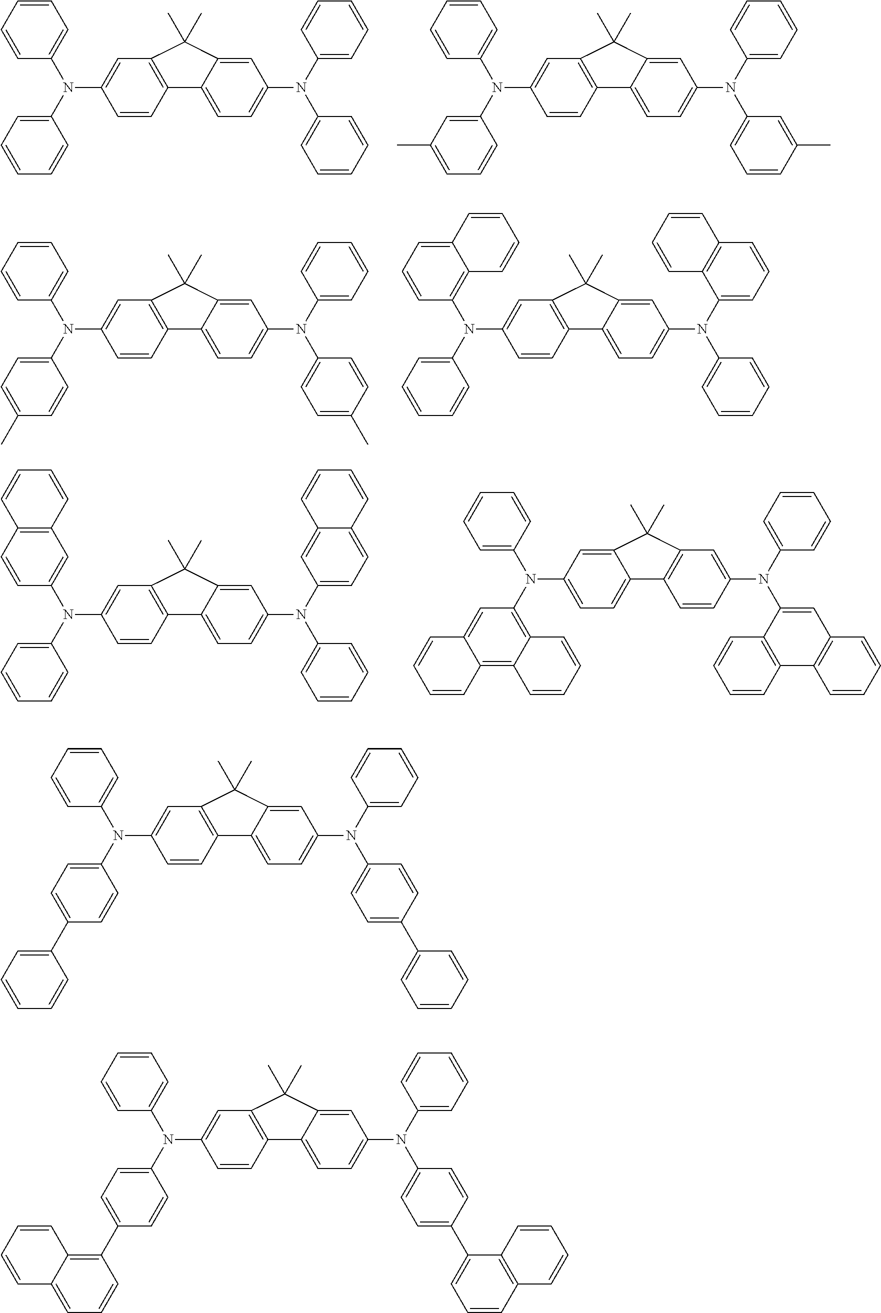

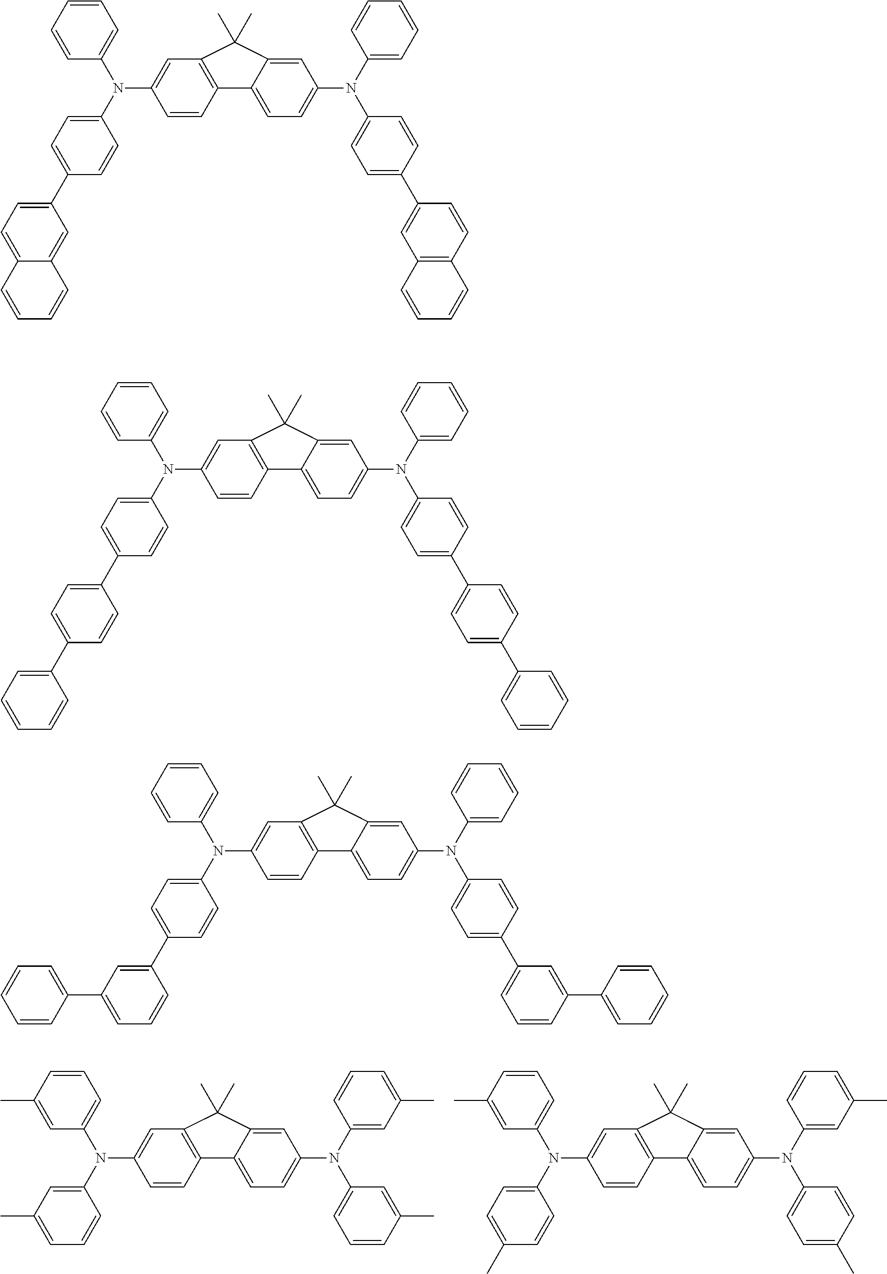

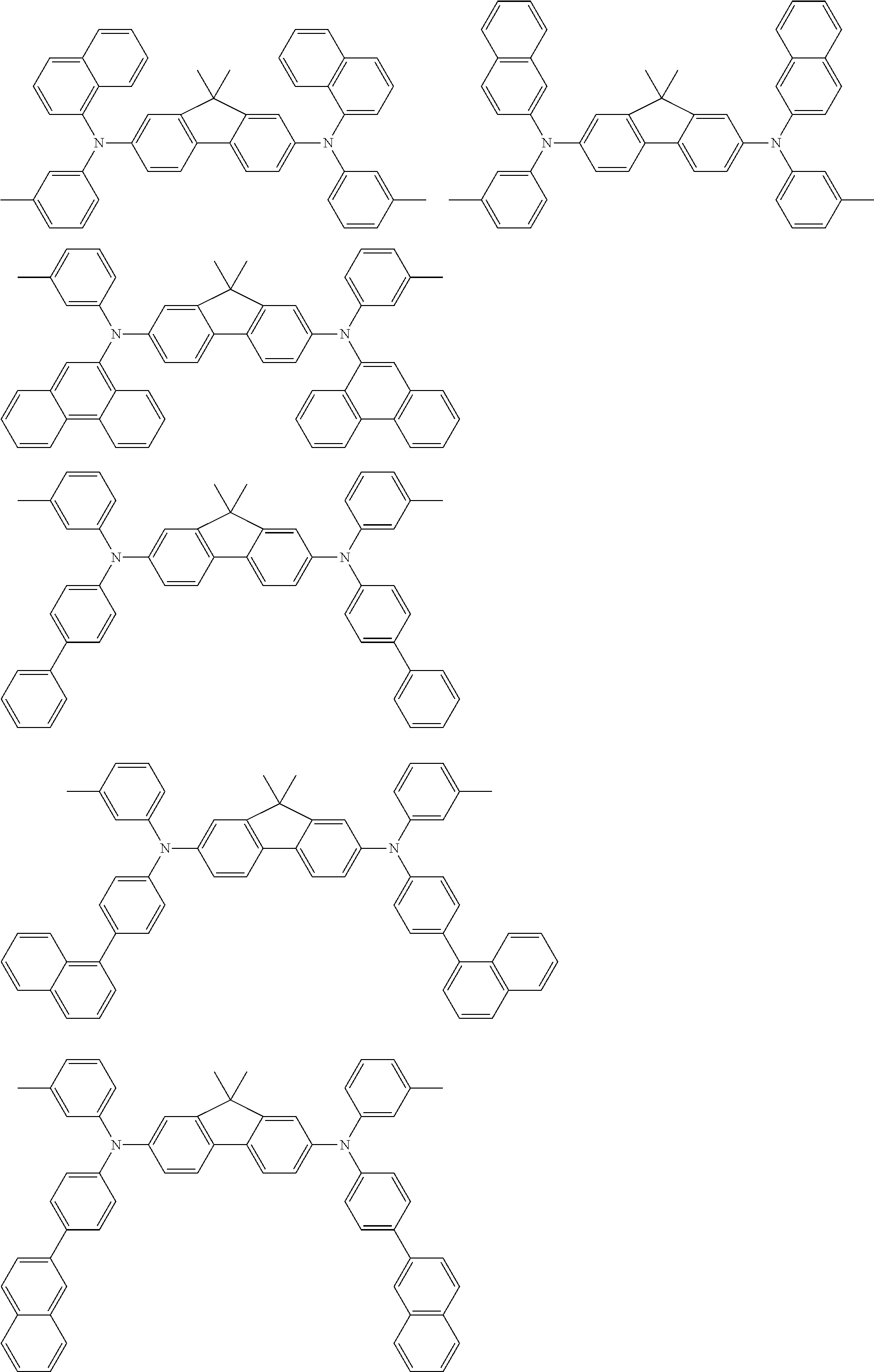

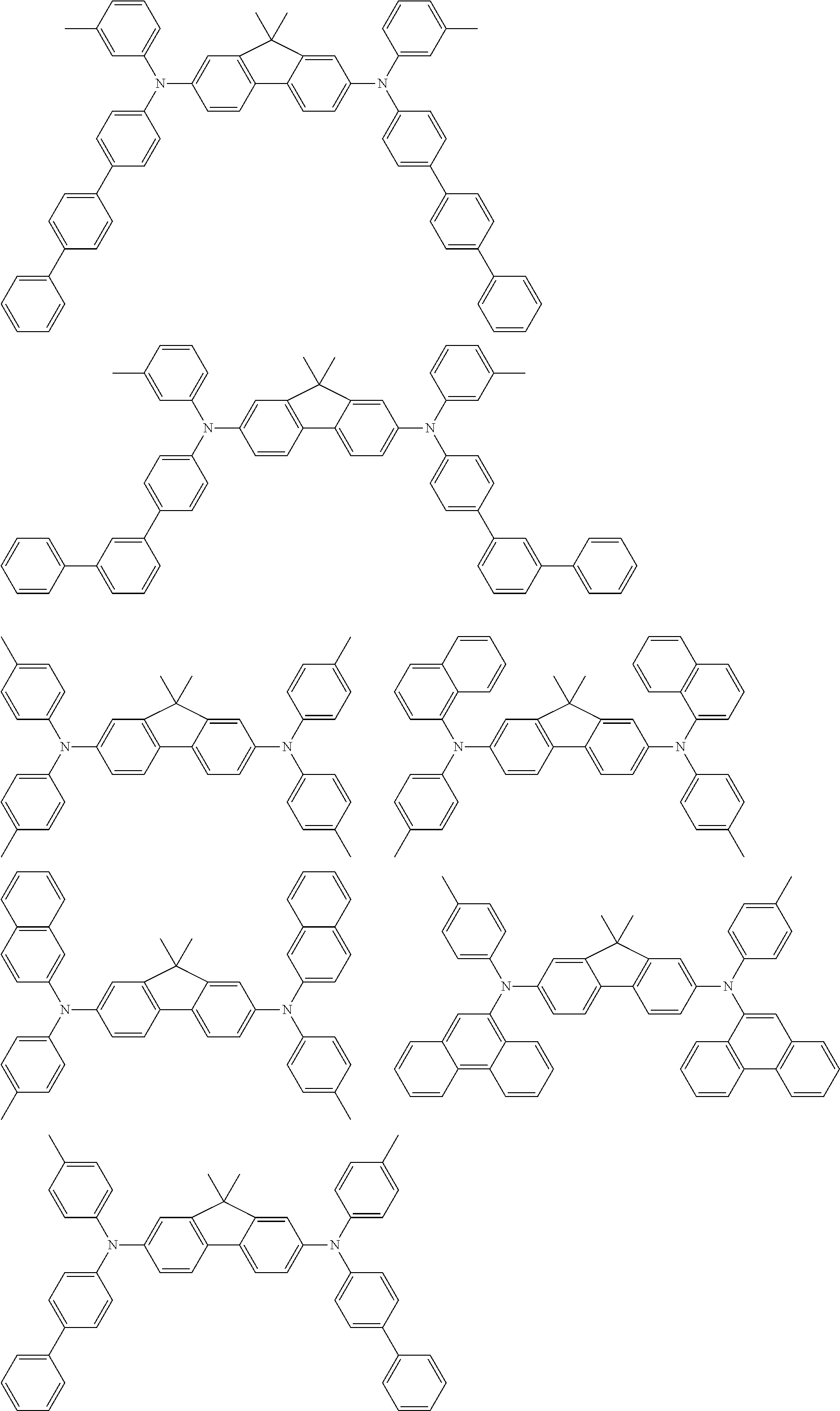

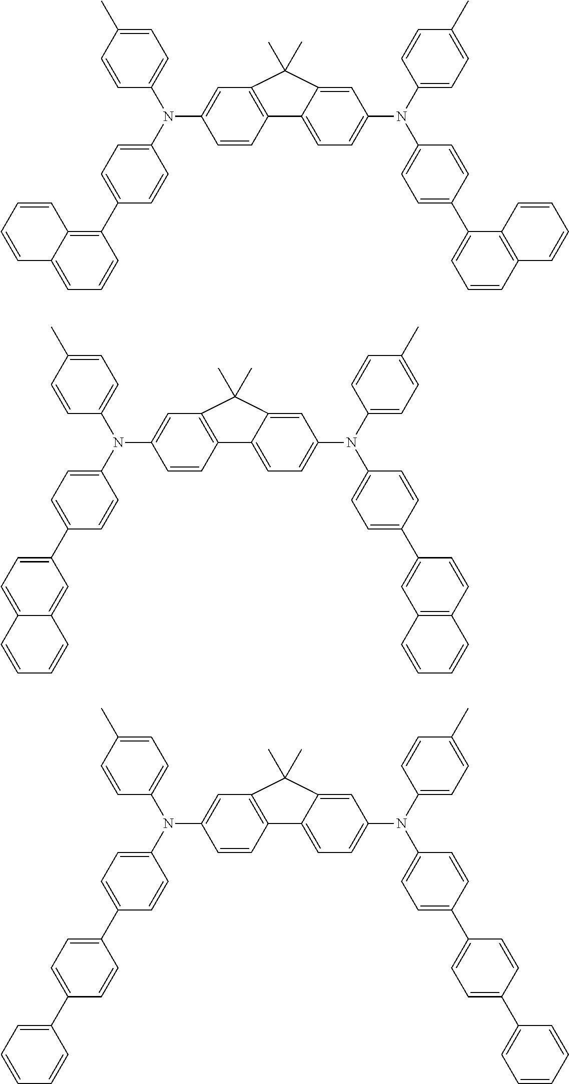

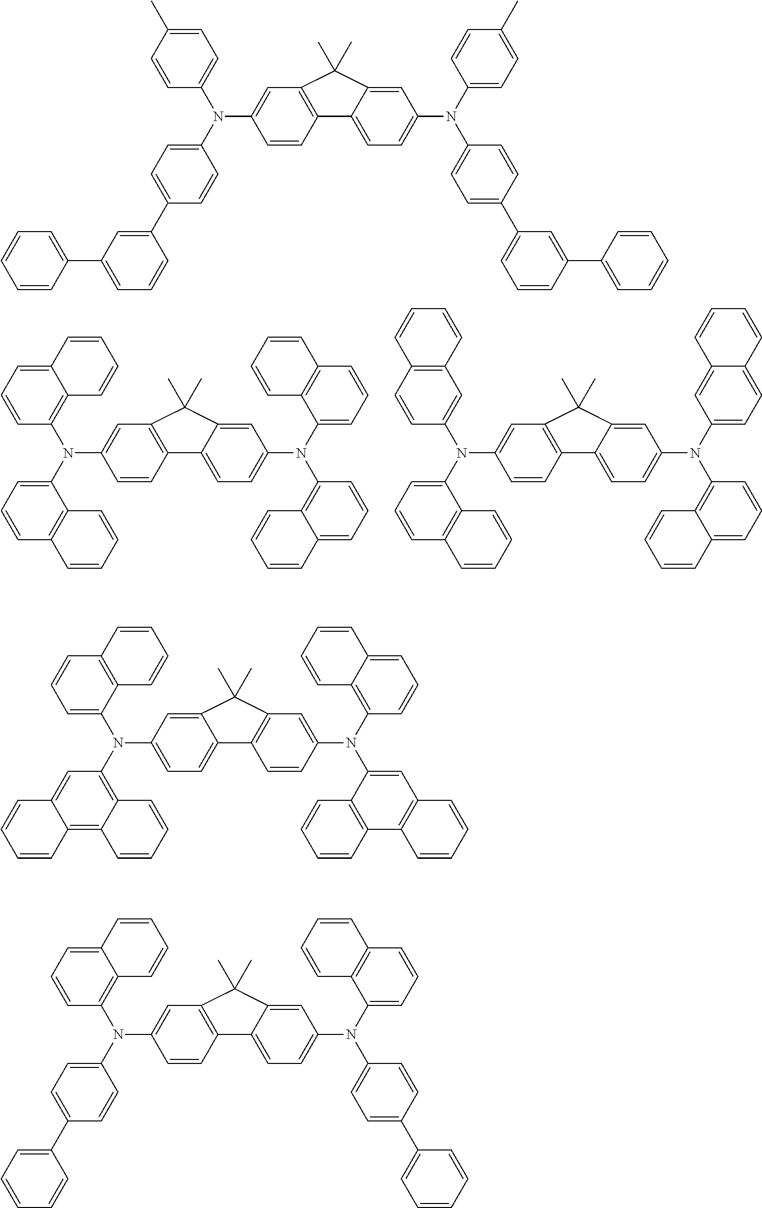

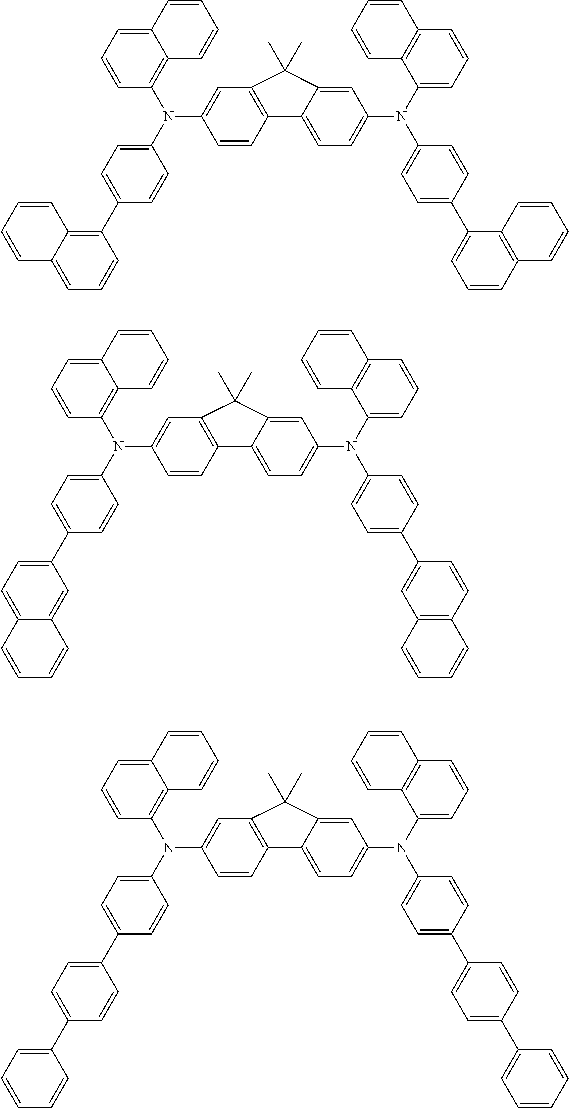

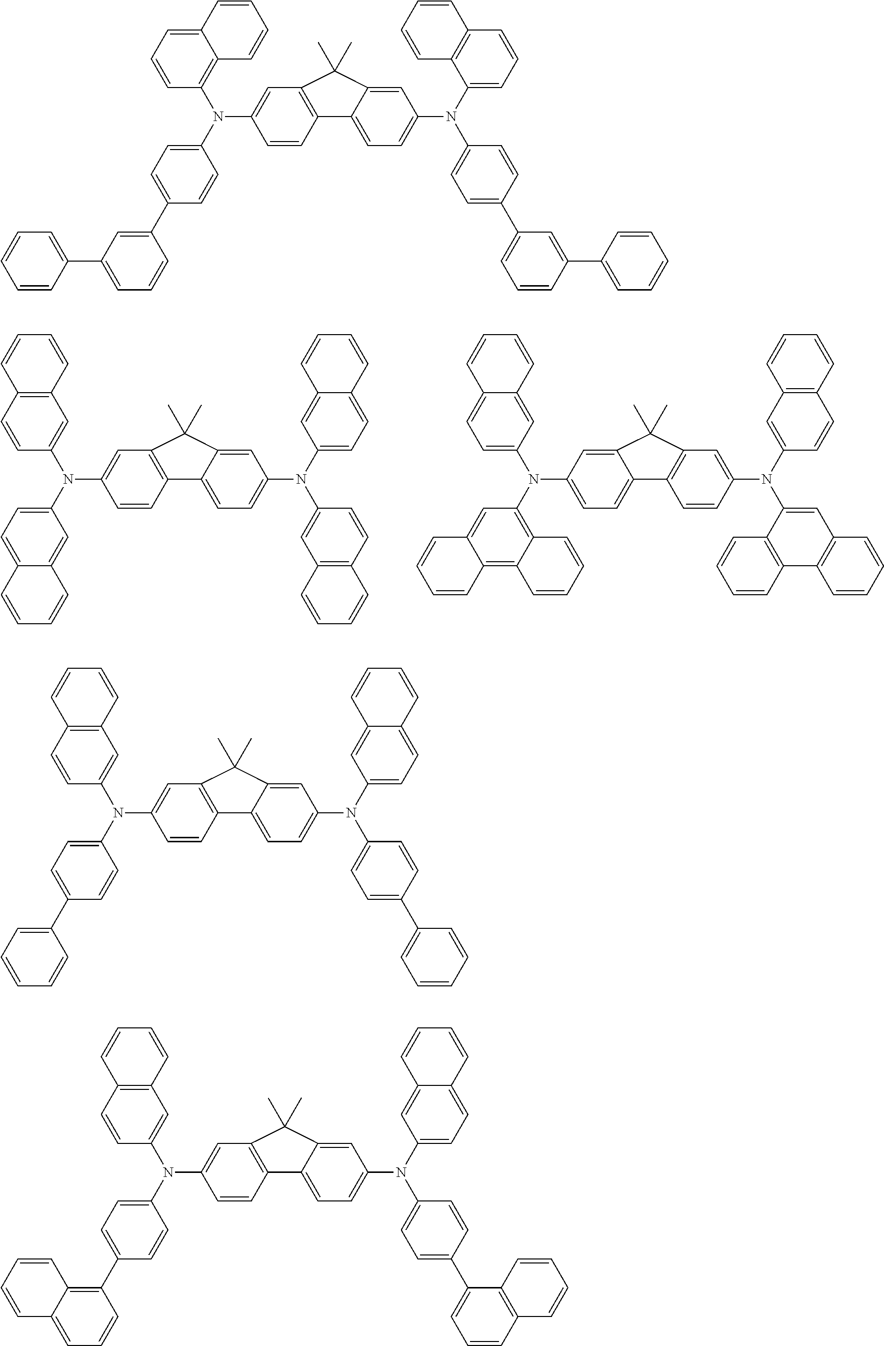

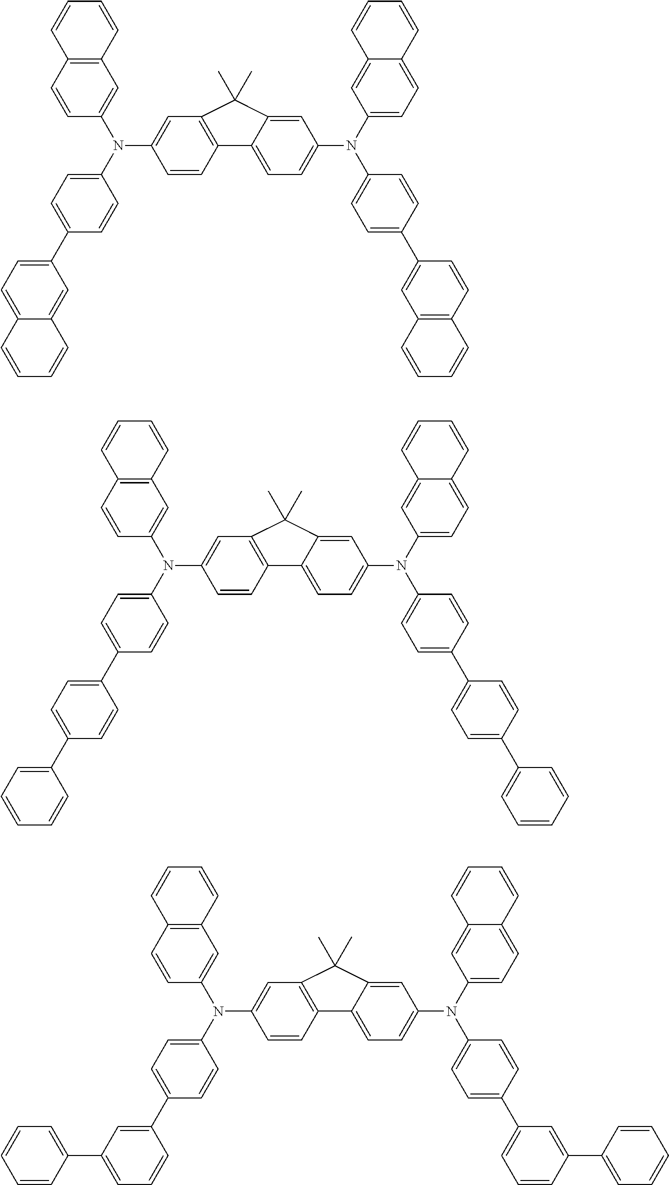

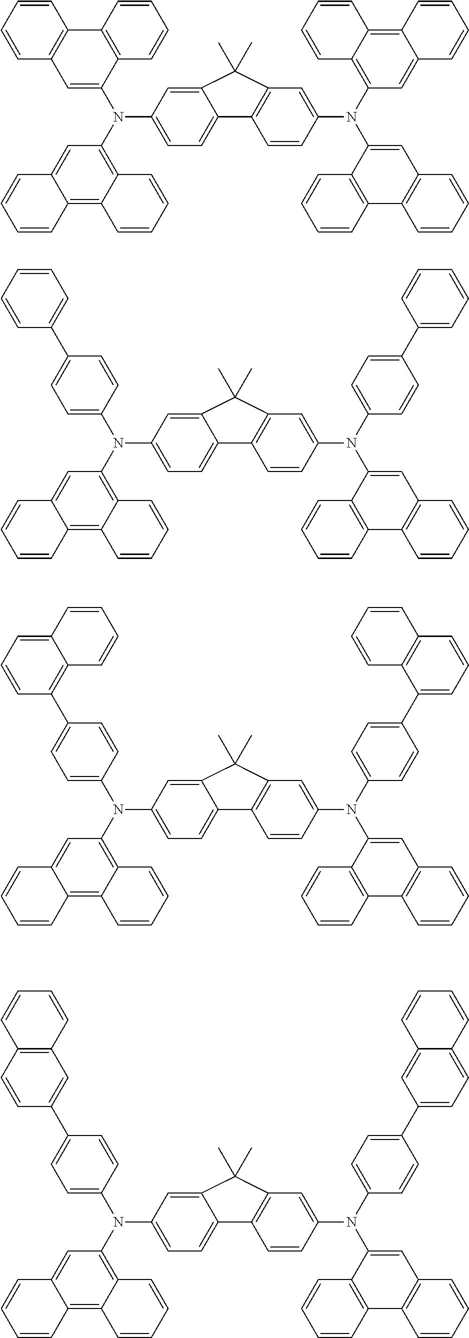

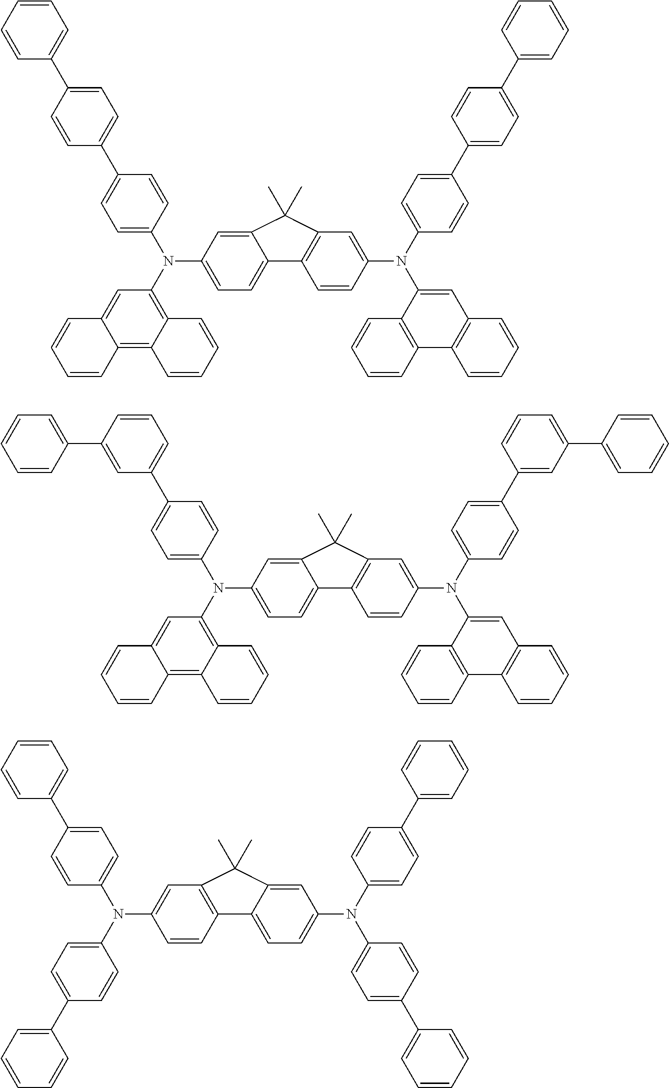

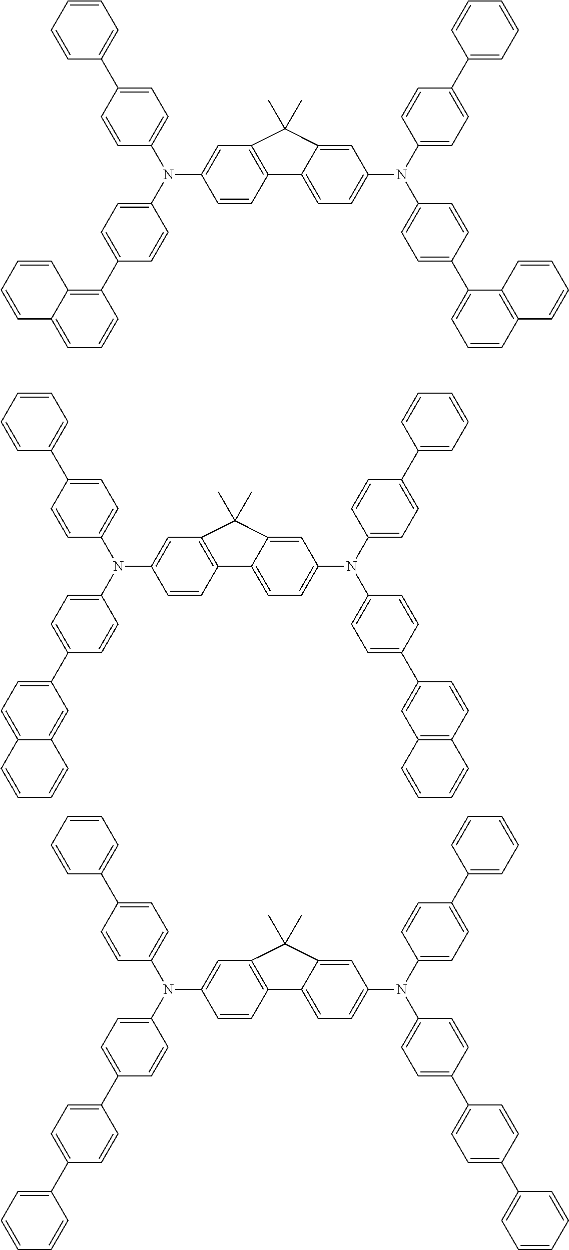

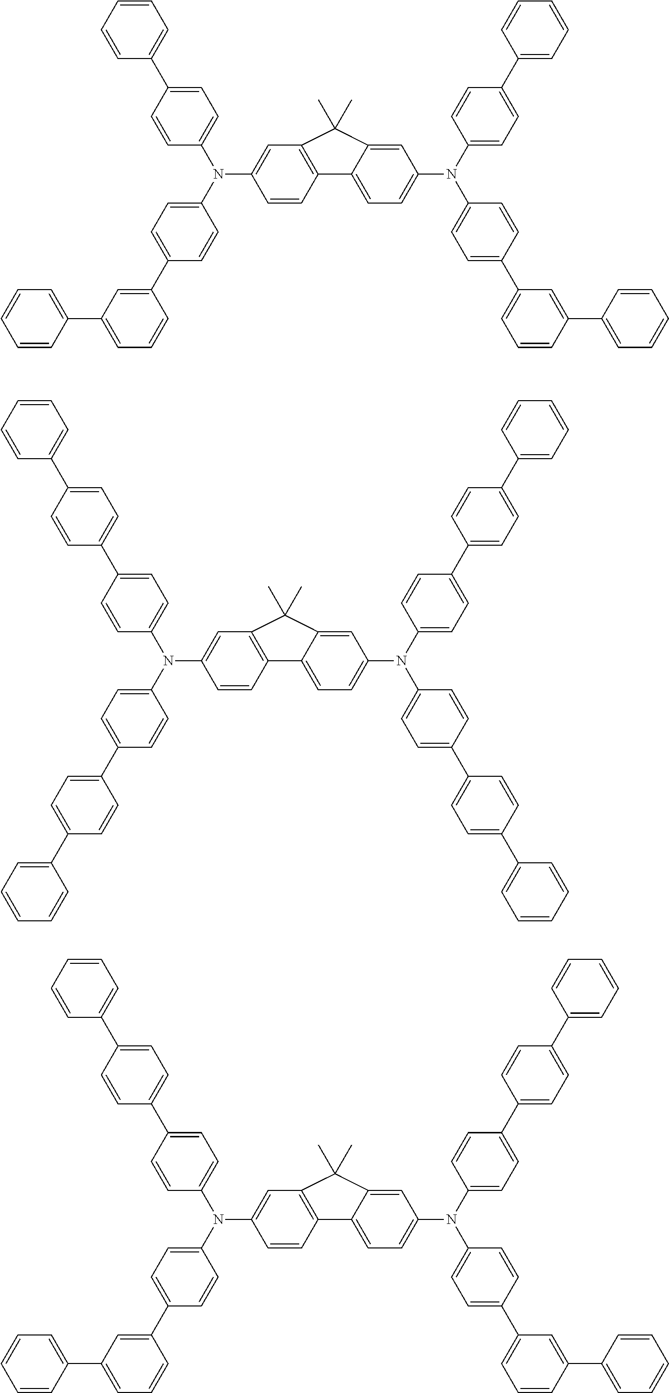

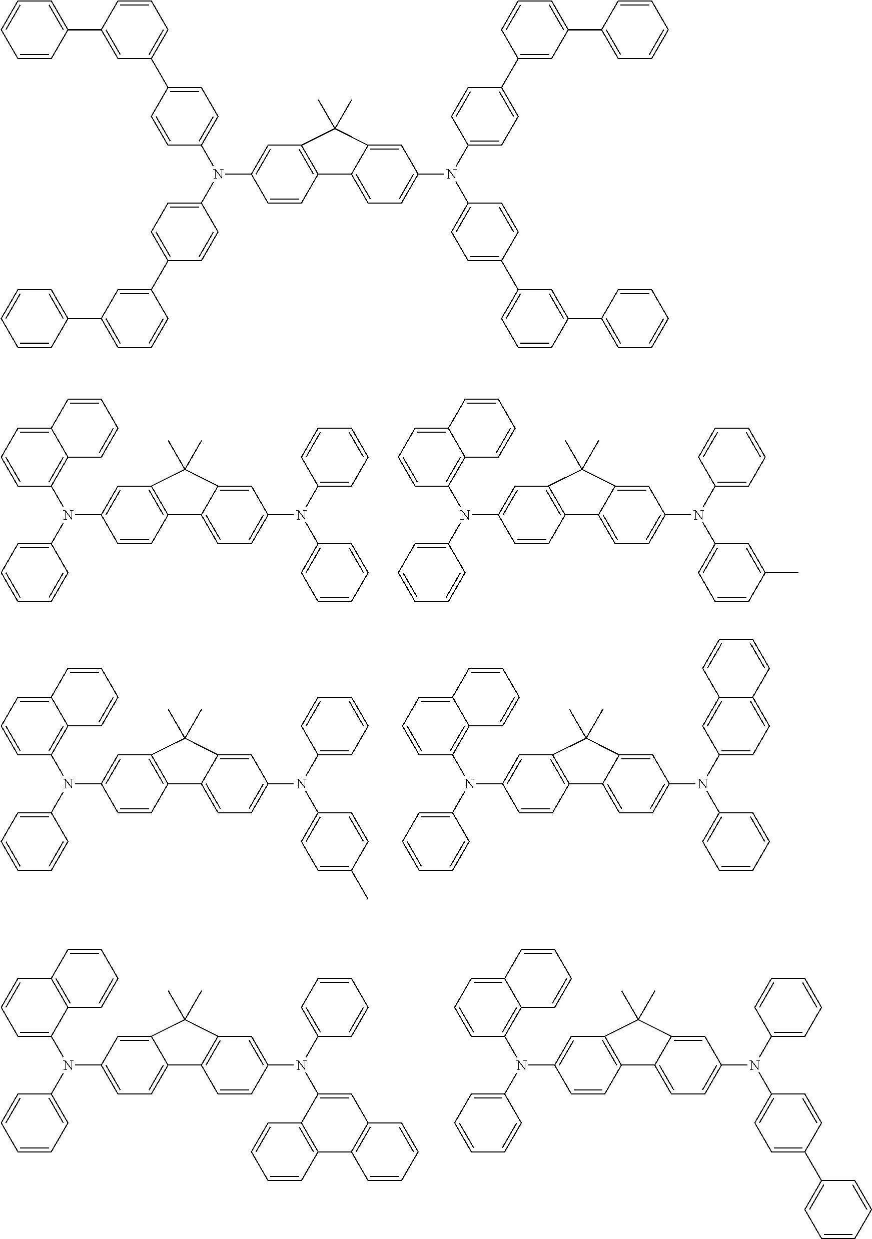

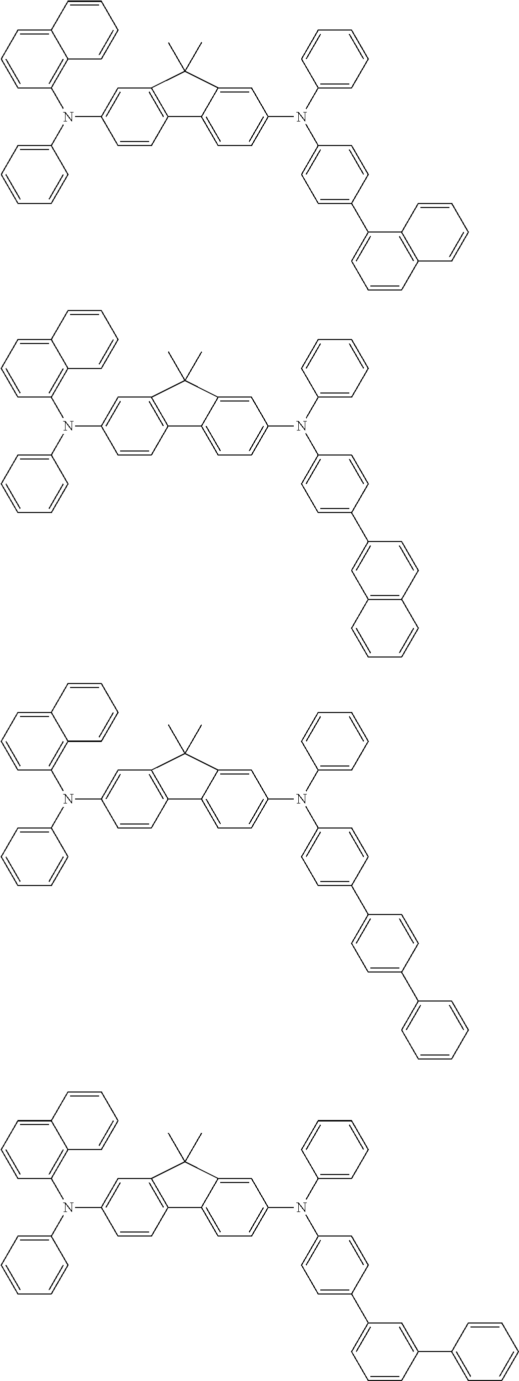 [SMILES: CC1(C)c2cc(N(c3ccccc3)c3ccc(-c4cccc5ccccc45)cc3)ccc2-c2ccc(N(c3ccccc3)c3cccc4ccccc34)cc21 ; CC1(C)c2cc(N(c3ccccc3)c3ccc(-c4ccc5ccccc5c4)cc3)ccc2-c2ccc(N(c3ccccc3)c3cccc4ccccc34)cc21 ; CC1(C)c2cc(N(c3ccccc3)c3ccc(-c4ccc(-c5ccccc5)cc4)cc3)ccc2-c2ccc(N(c3ccccc3)c3cccc4ccccc34)cc21 ; CC1(C)c2cc(N(c3ccccc3)c3ccc(-c4cccc(-c5ccccc5)c4)cc3)ccc2-c2ccc(N(c3ccccc3)c3cccc4ccccc34)cc21]

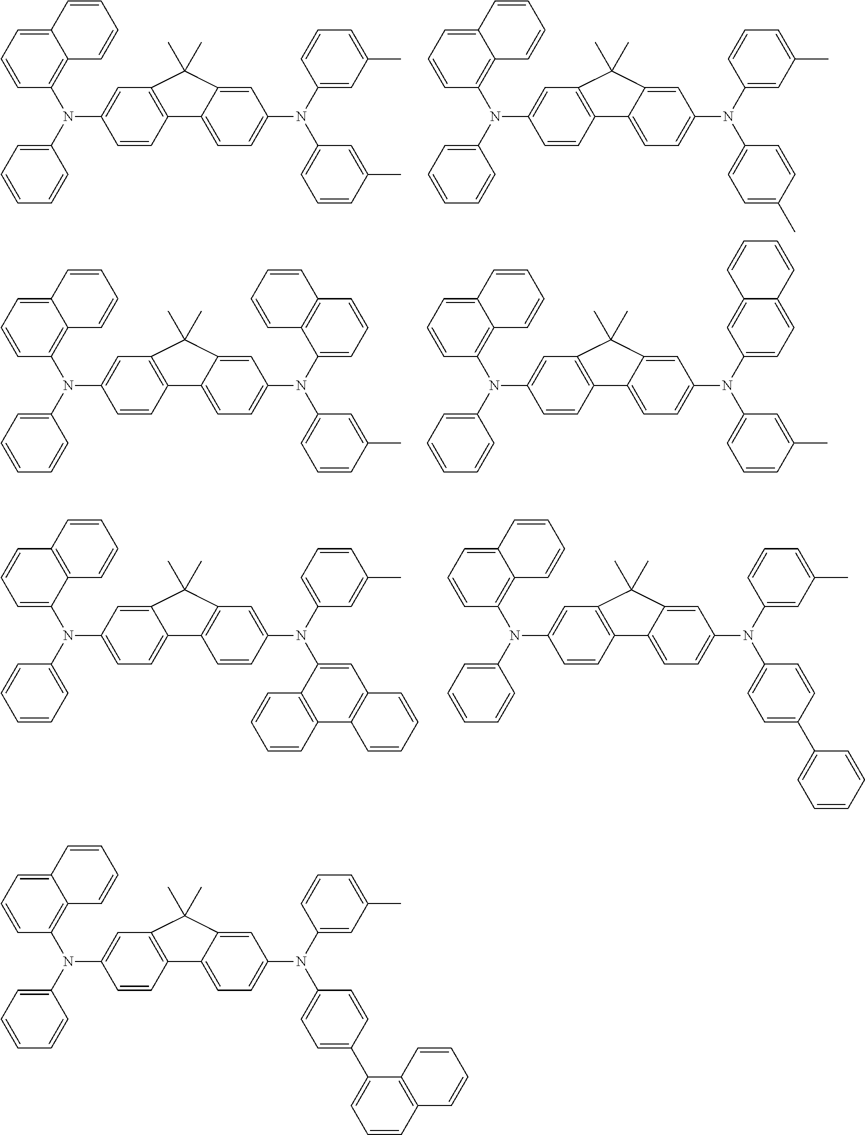

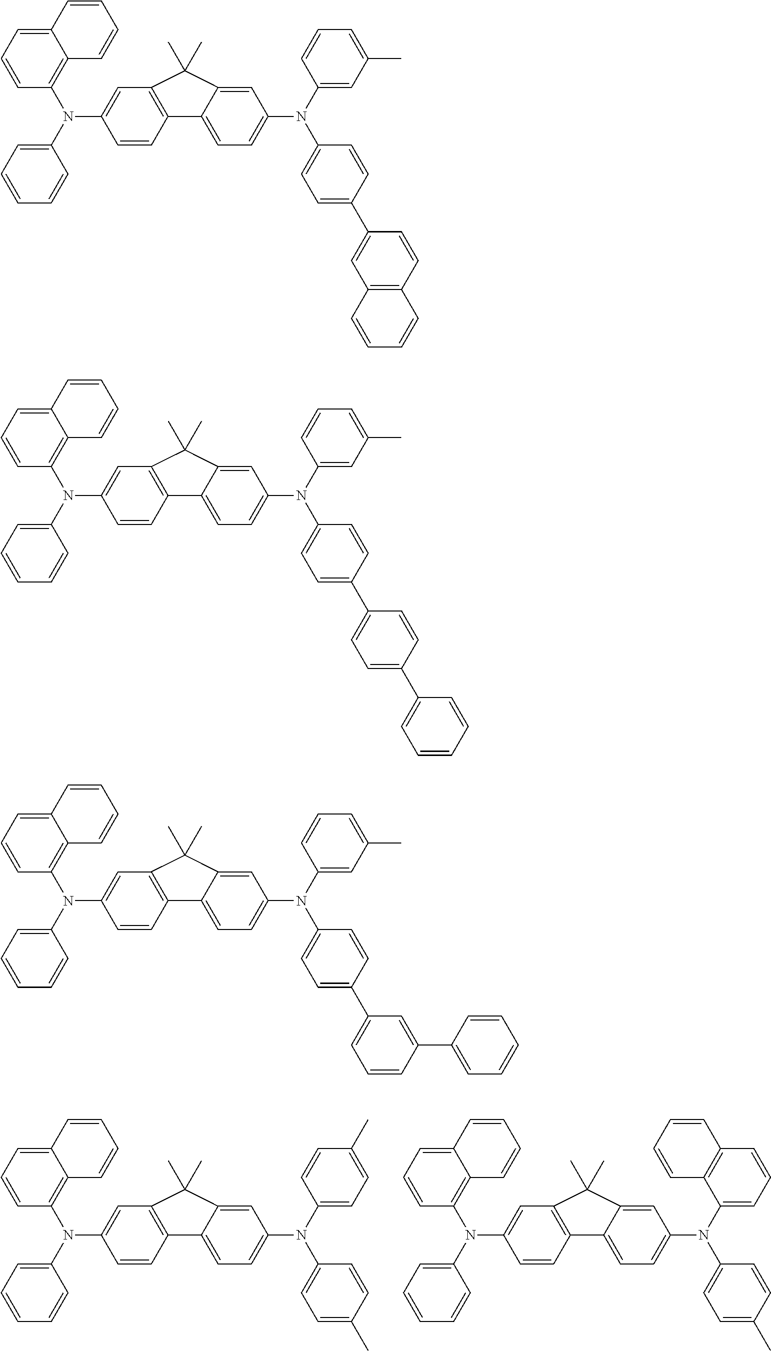

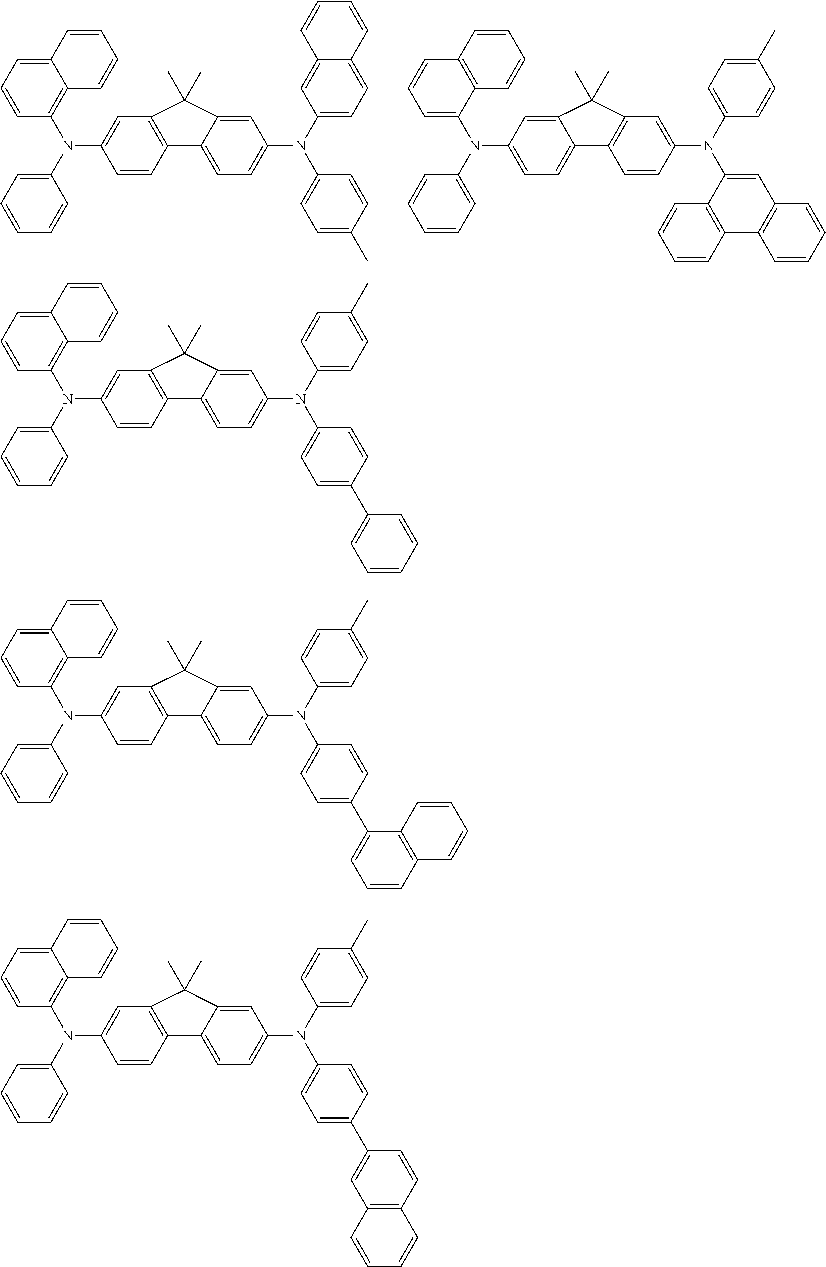

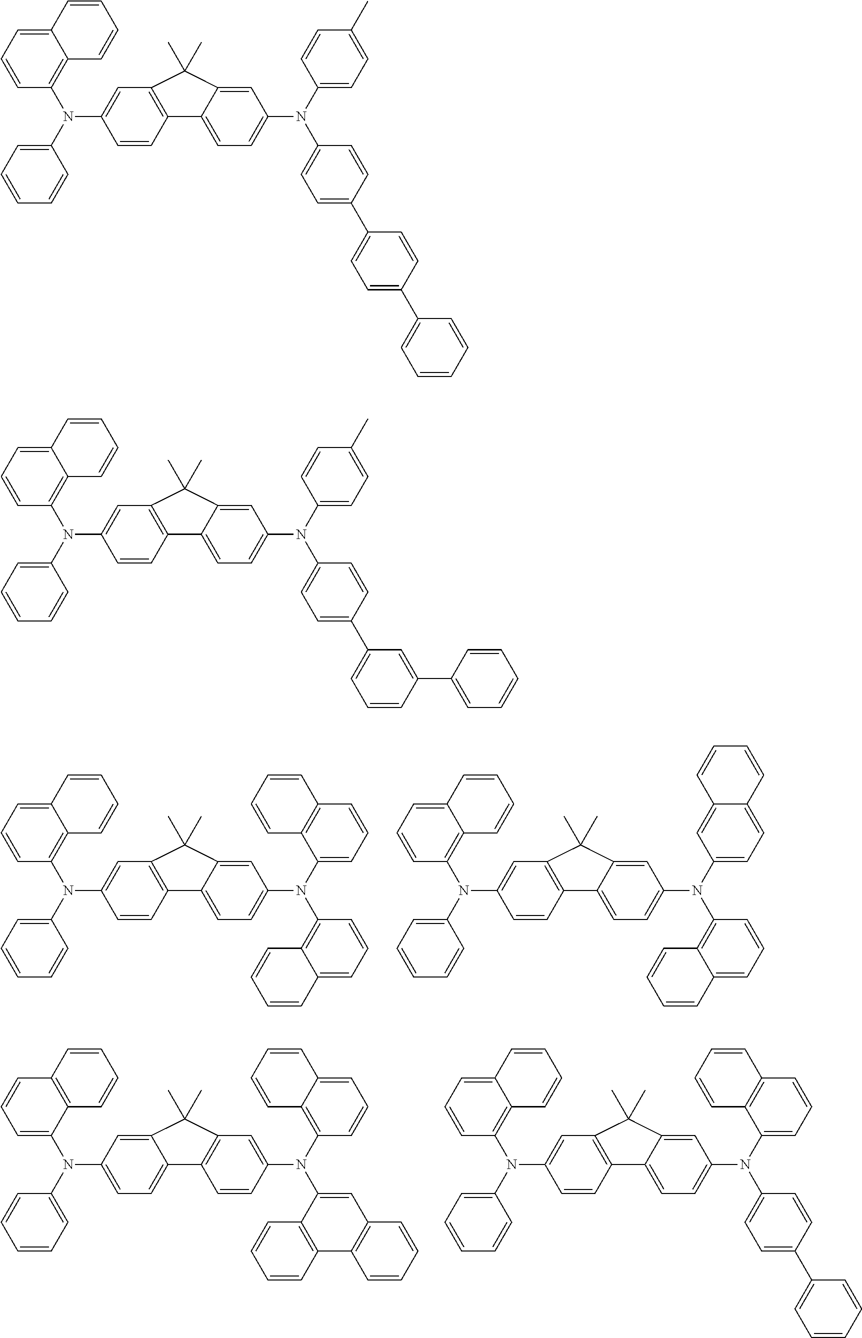

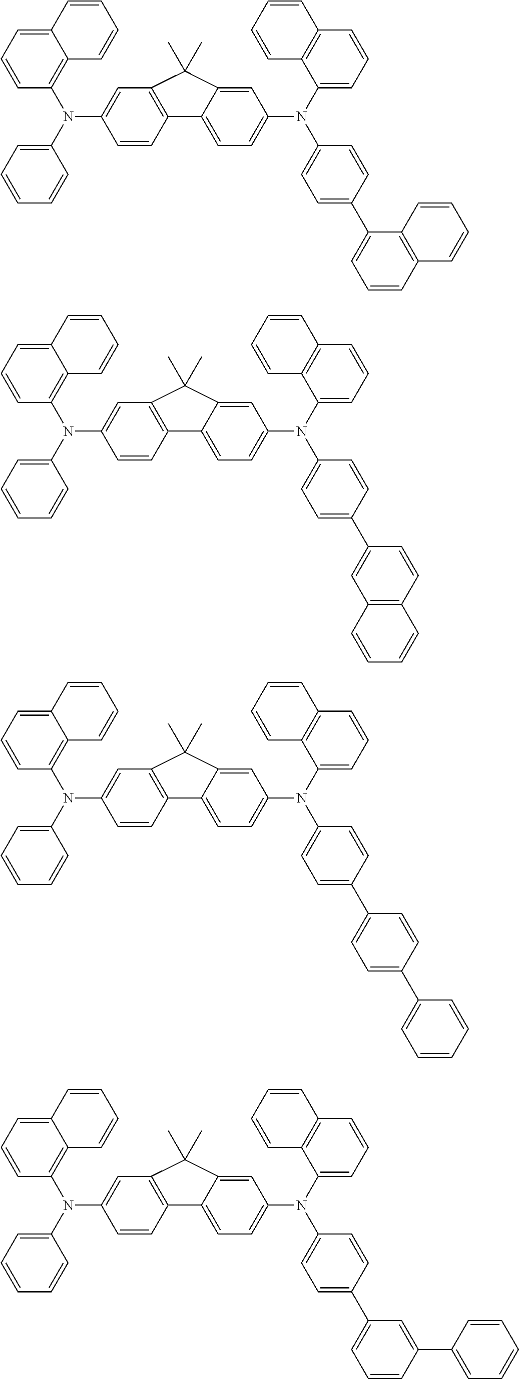 [SMILES: CC1(C)c2cc(N(c3ccccc3)c3cccc4ccccc34)ccc2-c2ccc(N(c3ccc(-c4cccc5ccccc45)cc3)c3cccc4ccccc34)cc21 ; CC1(C)c2cc(N(c3ccccc3)c3cccc4ccccc34)ccc2-c2ccc(N(c3ccc(-c4ccc5ccccc5c4)cc3)c3cccc4ccccc34)cc21 ; CC1(C)c2cc(N(c3ccccc3)c3cccc4ccccc34)ccc2-c2ccc(N(c3ccc(-c4ccc(-c5ccccc5)cc4)cc3)c3cccc4ccccc34)cc21 ; CC1(C)c2cc(N(c3ccccc3)c3cccc4ccccc34)ccc2-c2ccc(N(c3ccc(-c4cccc(-c5ccccc5)c4)cc3)c3cccc4ccccc34)cc21]

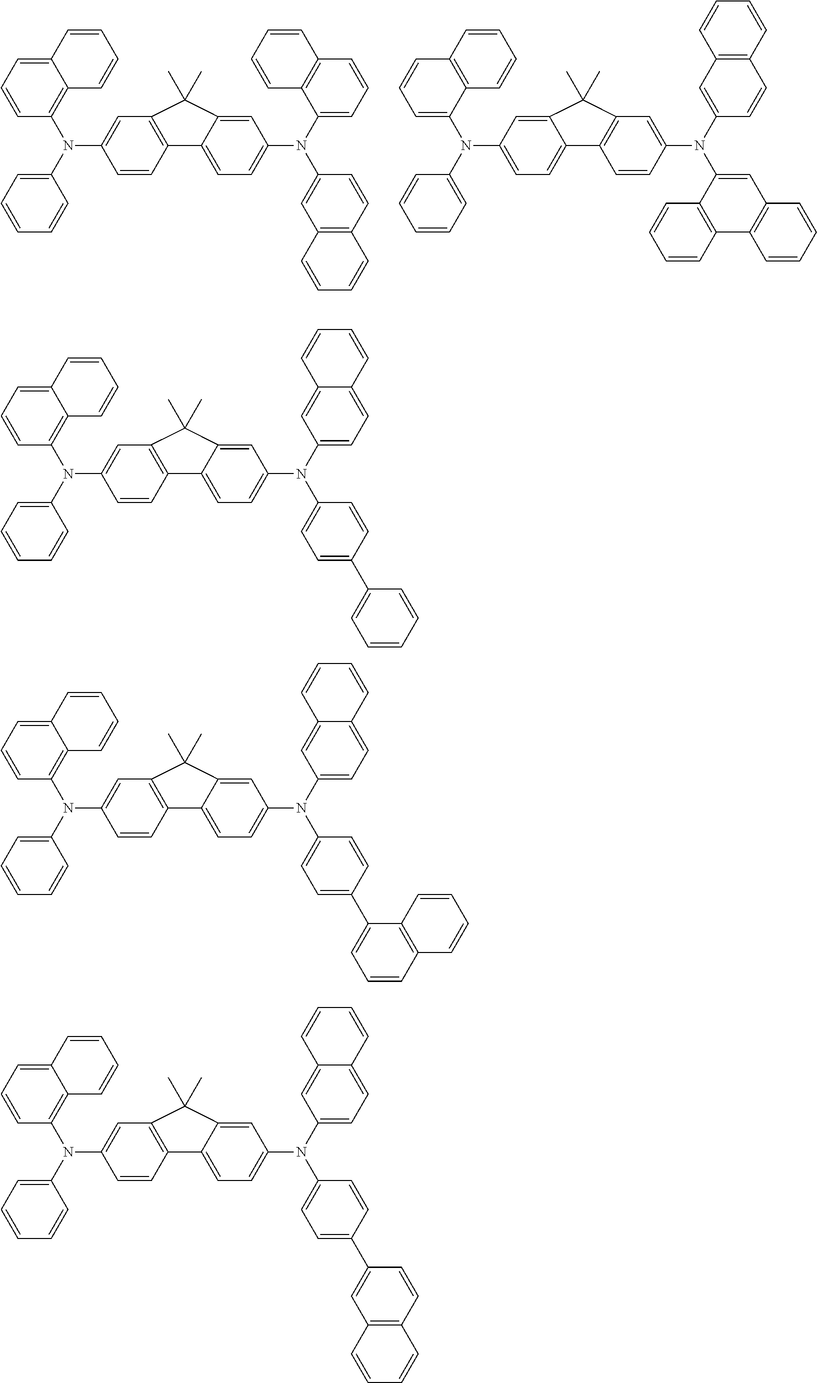

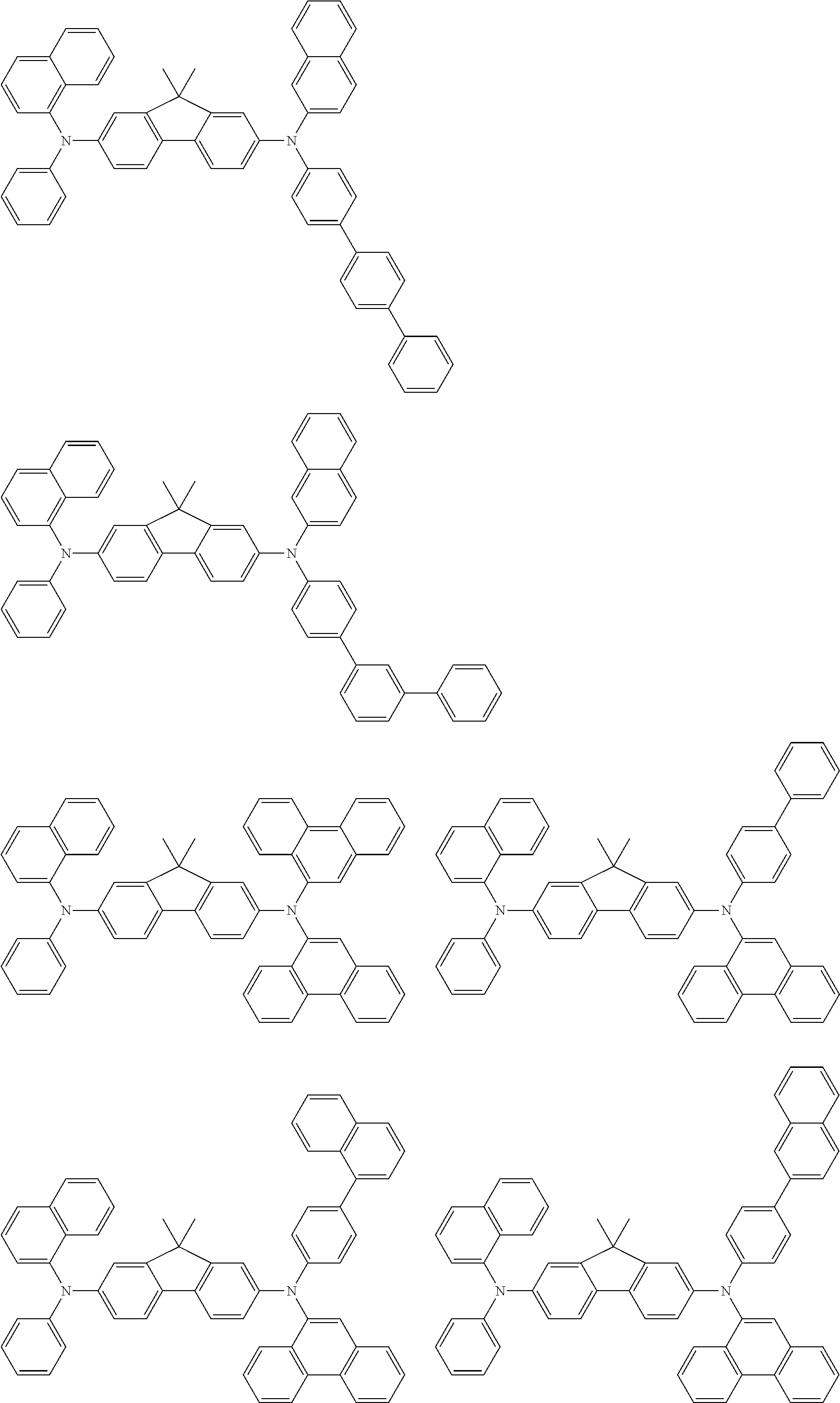

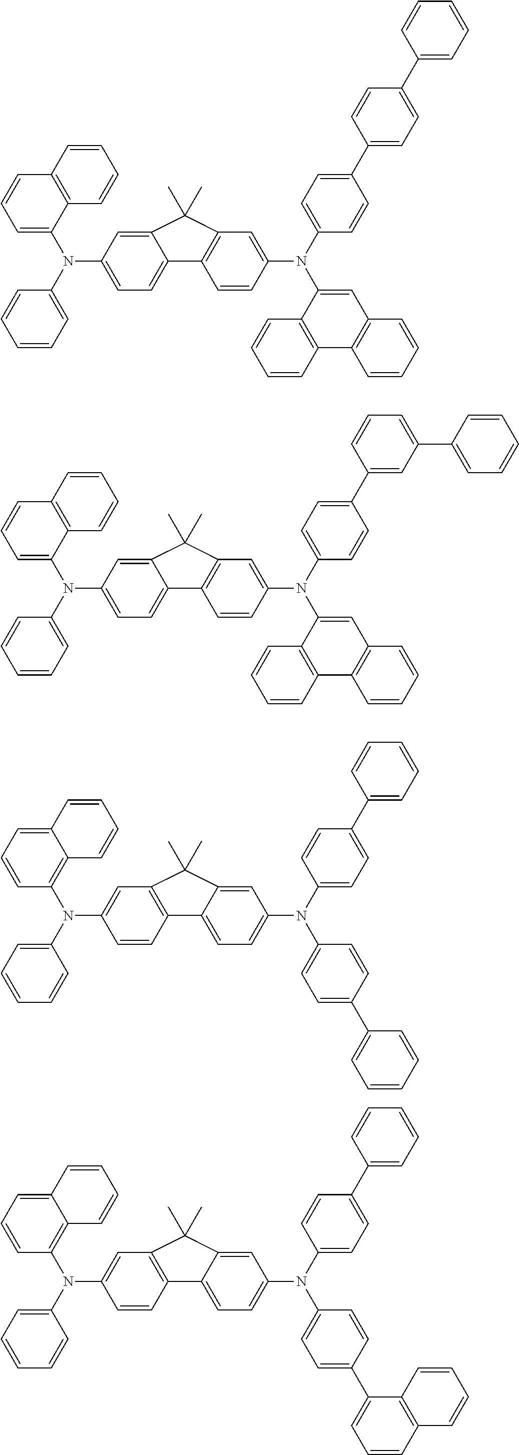

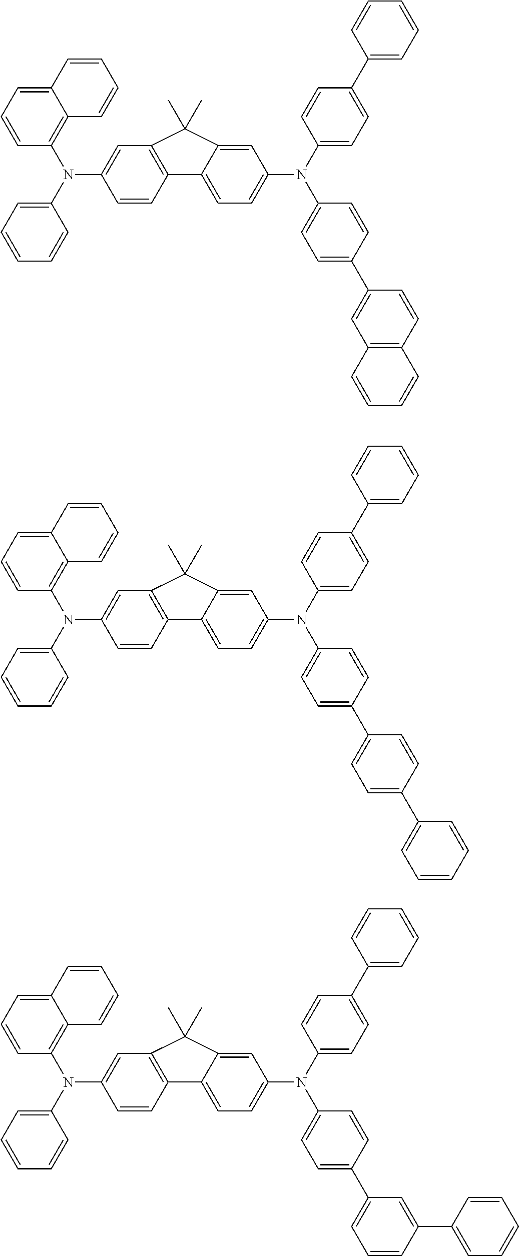

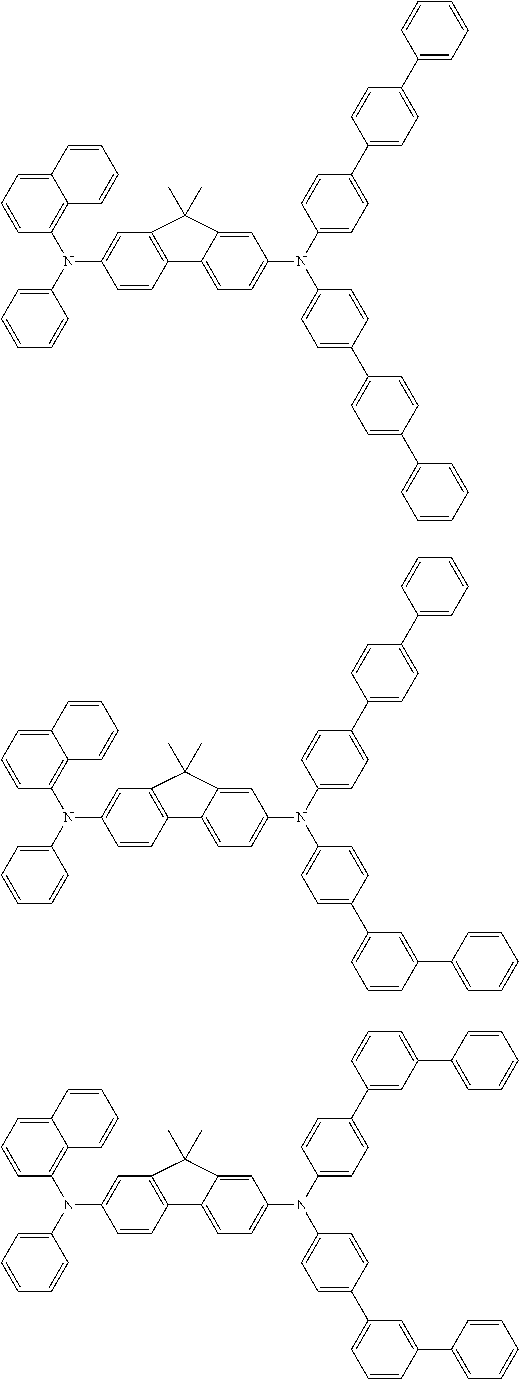

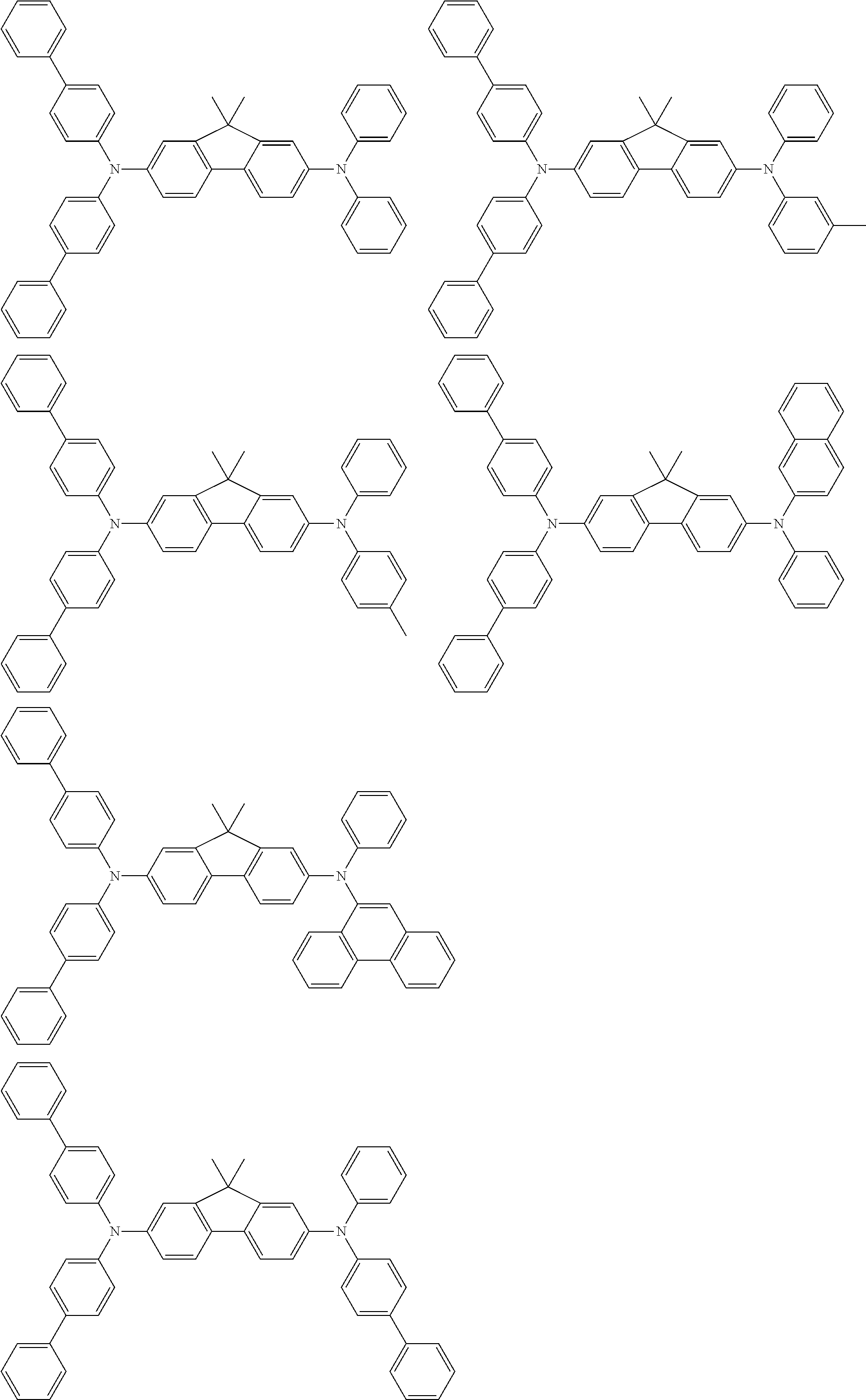

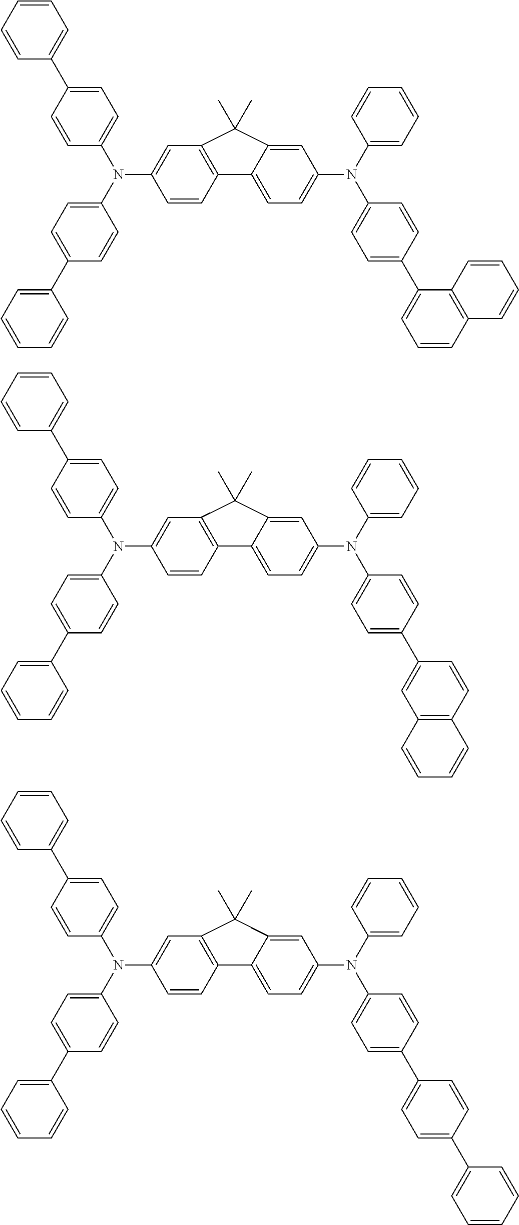

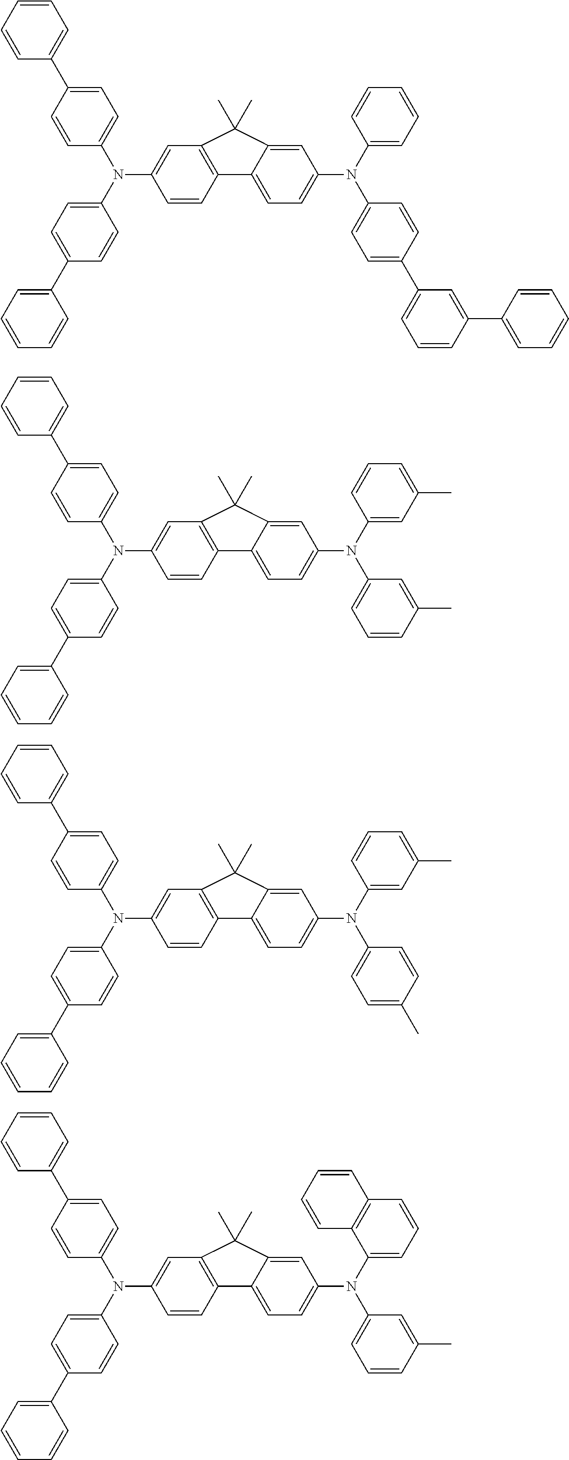

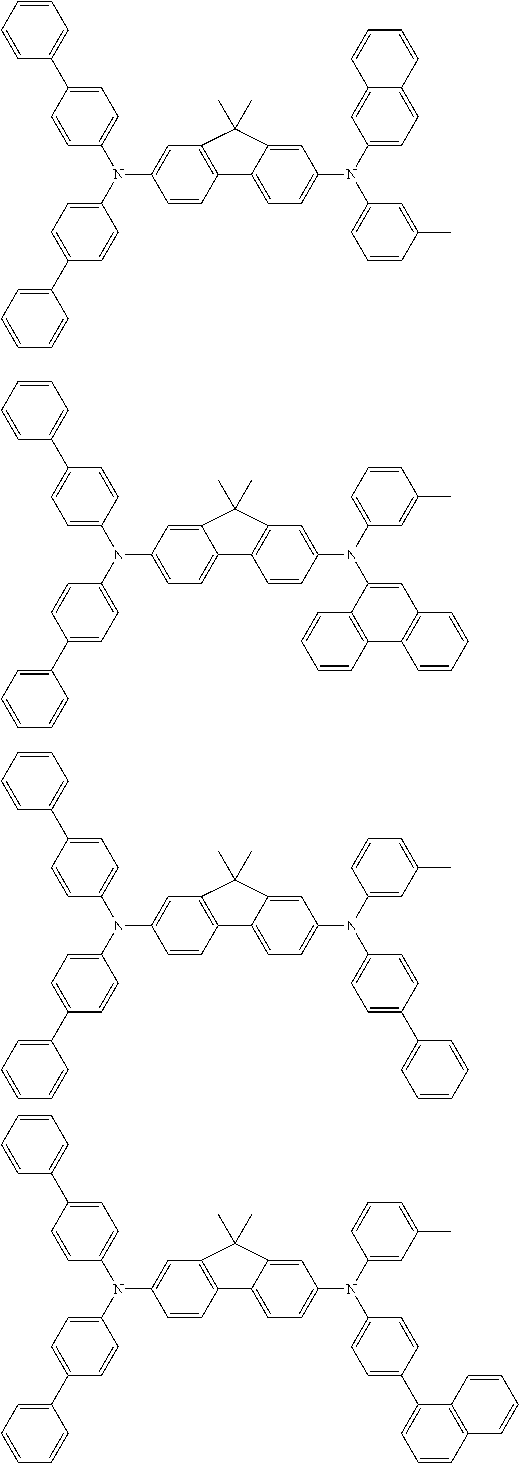

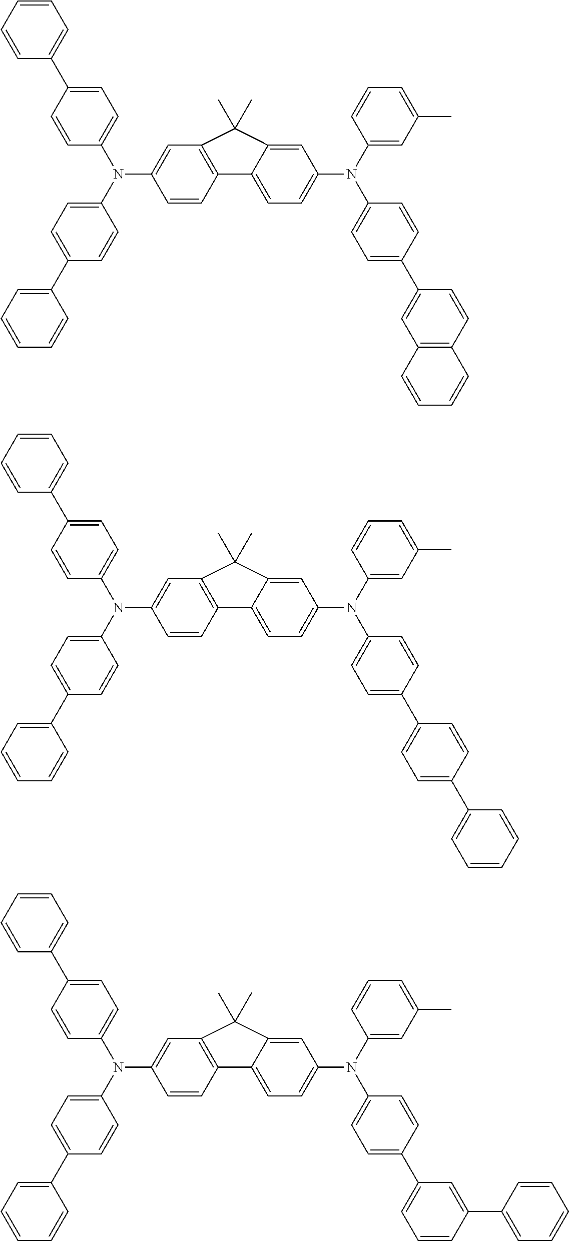 [SMILES: Cc1cccc(N(c2ccc(-c3ccc4ccccc4c3)cc2)c2ccc3c(c2)C(C)(C)c2cc(N(c4ccc(-c5ccccc5)cc4)c4ccc(-c5ccccc5)cc4)ccc2-3)c1 ; Cc1cccc(N(c2ccc(-c3ccc(-c4ccccc4)cc3)cc2)c2ccc3c(c2)C(C)(C)c2cc(N(c4ccc(-c5ccccc5)cc4)c4ccc(-c5ccccc5)cc4)ccc2-3)c1 ; Cc1cccc(N(c2ccc(-c3cccc(-c4ccccc4)c3)cc2)c2ccc3c(c2)C(C)(C)c2cc(N(c4ccc(-c5ccccc5)cc4)c4ccc(-c5ccccc5)cc4)ccc2-3)c1]

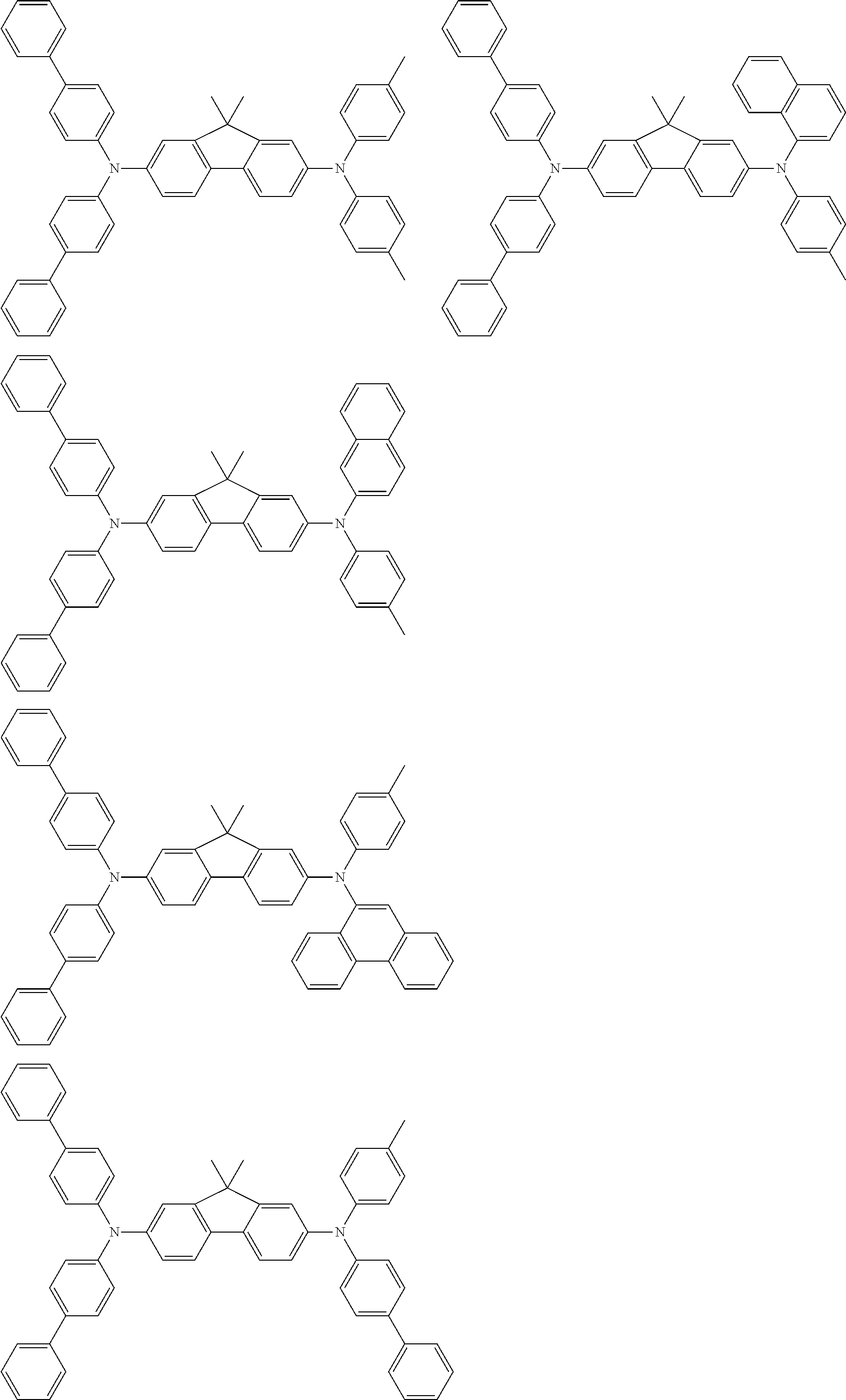

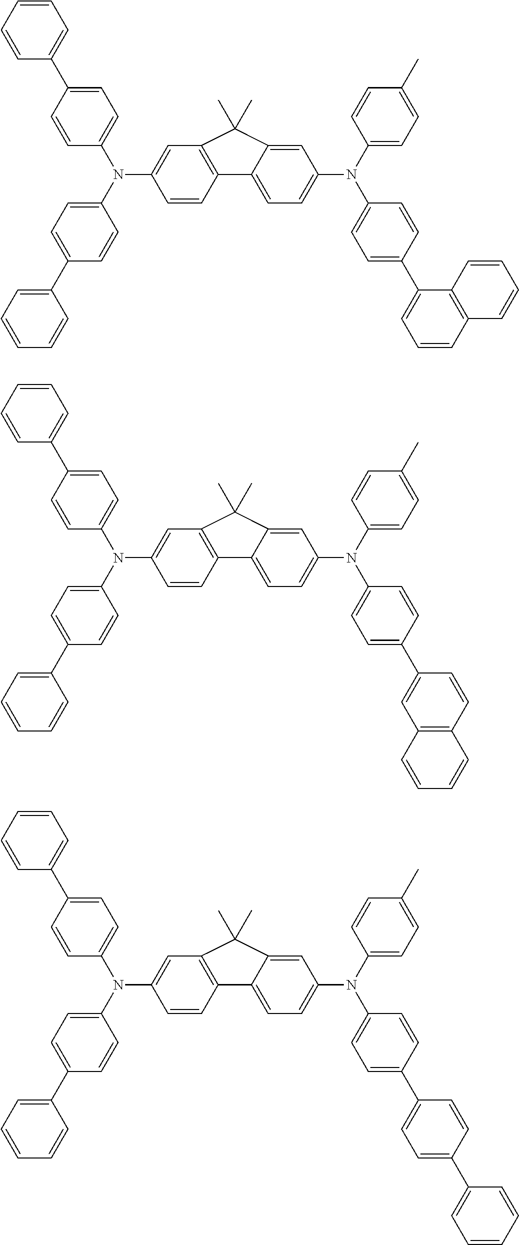

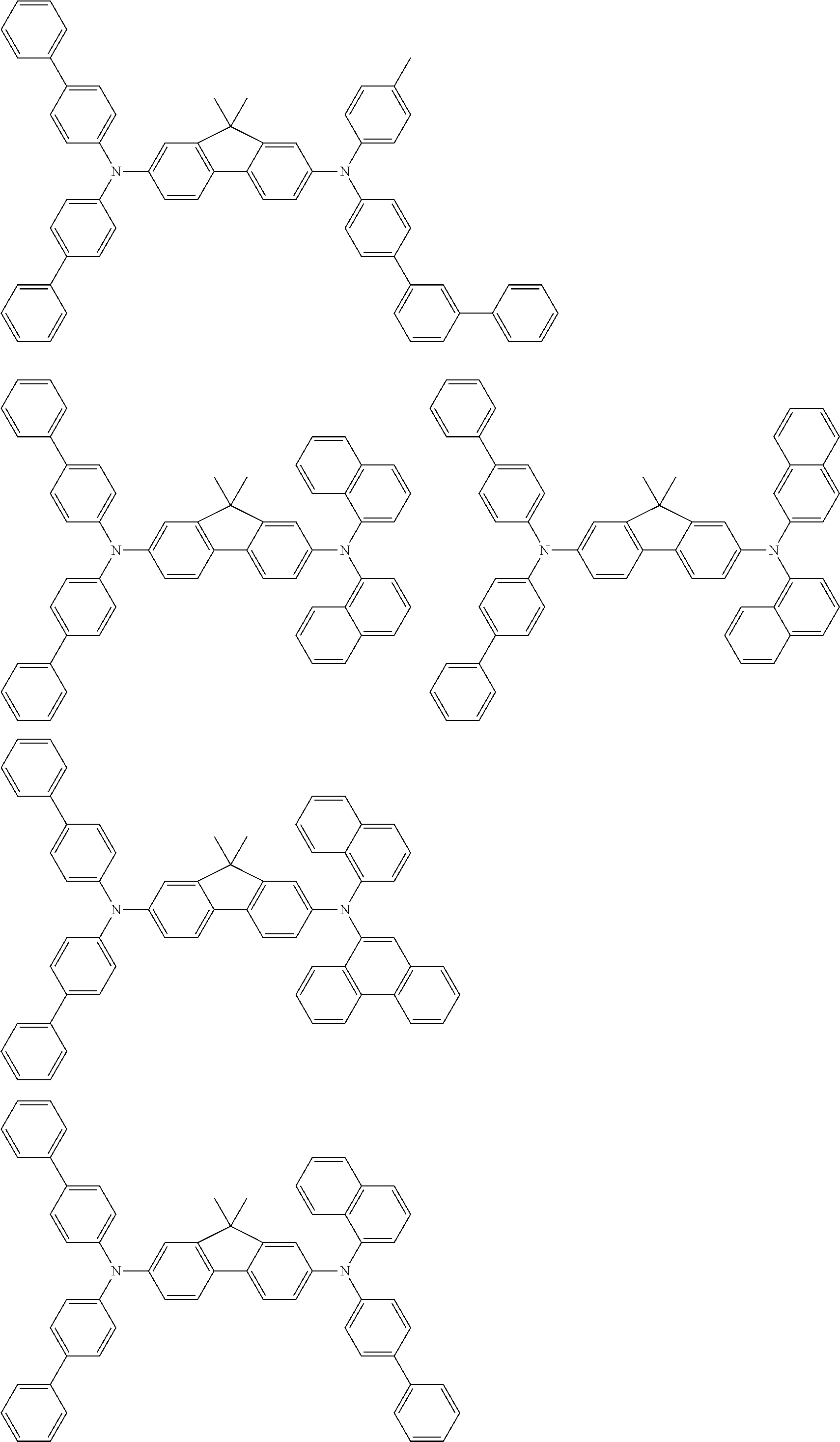

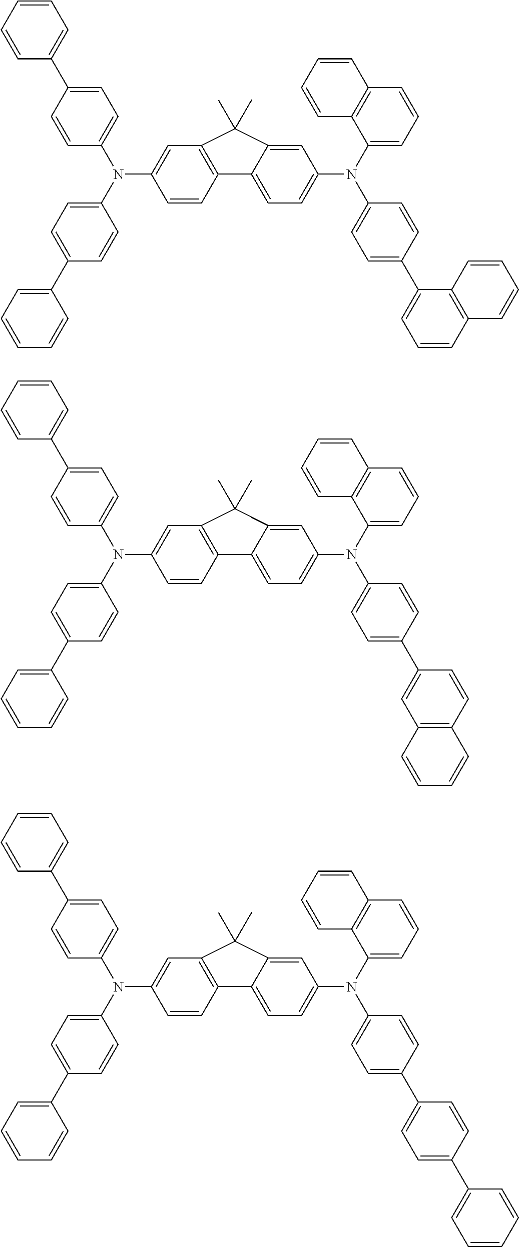

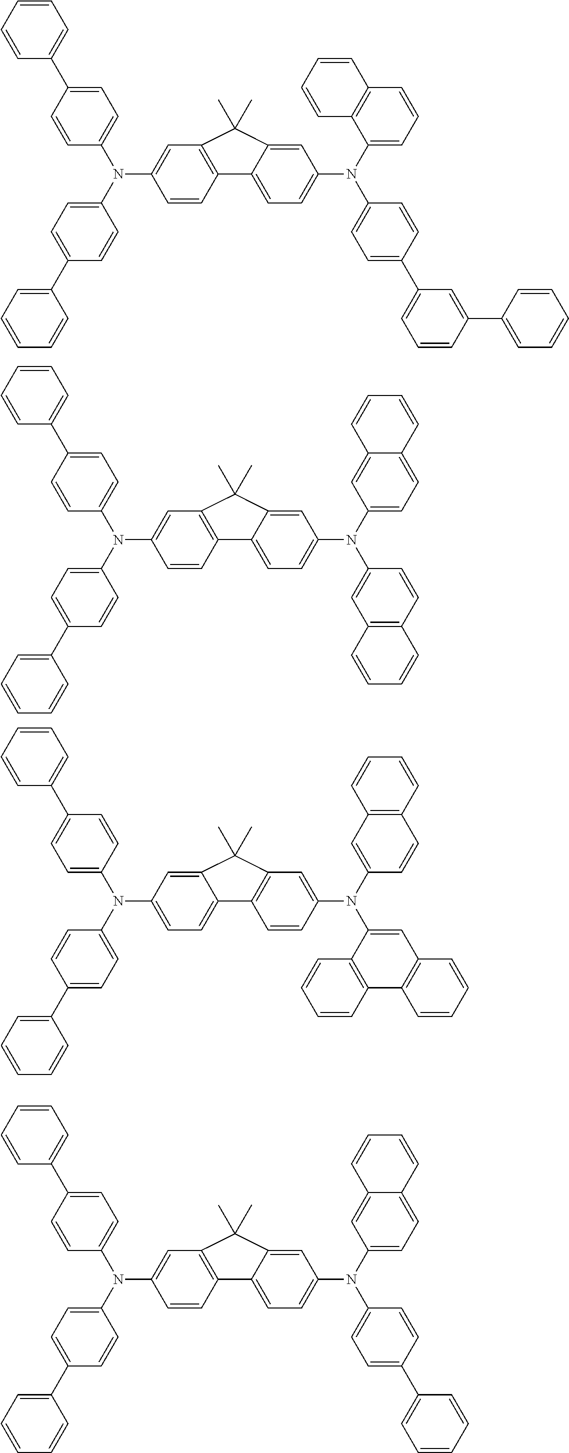

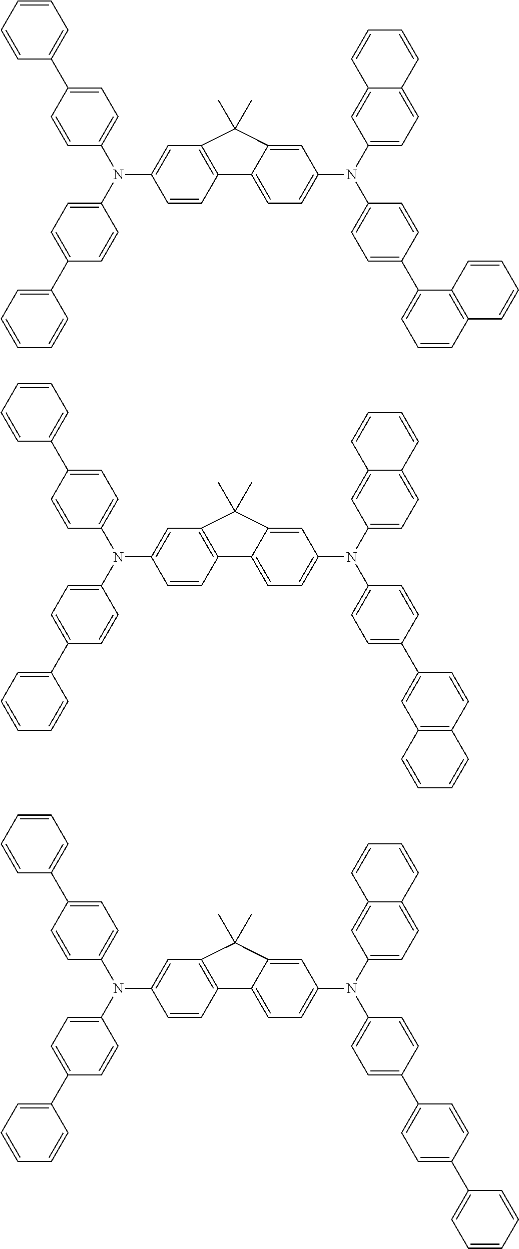

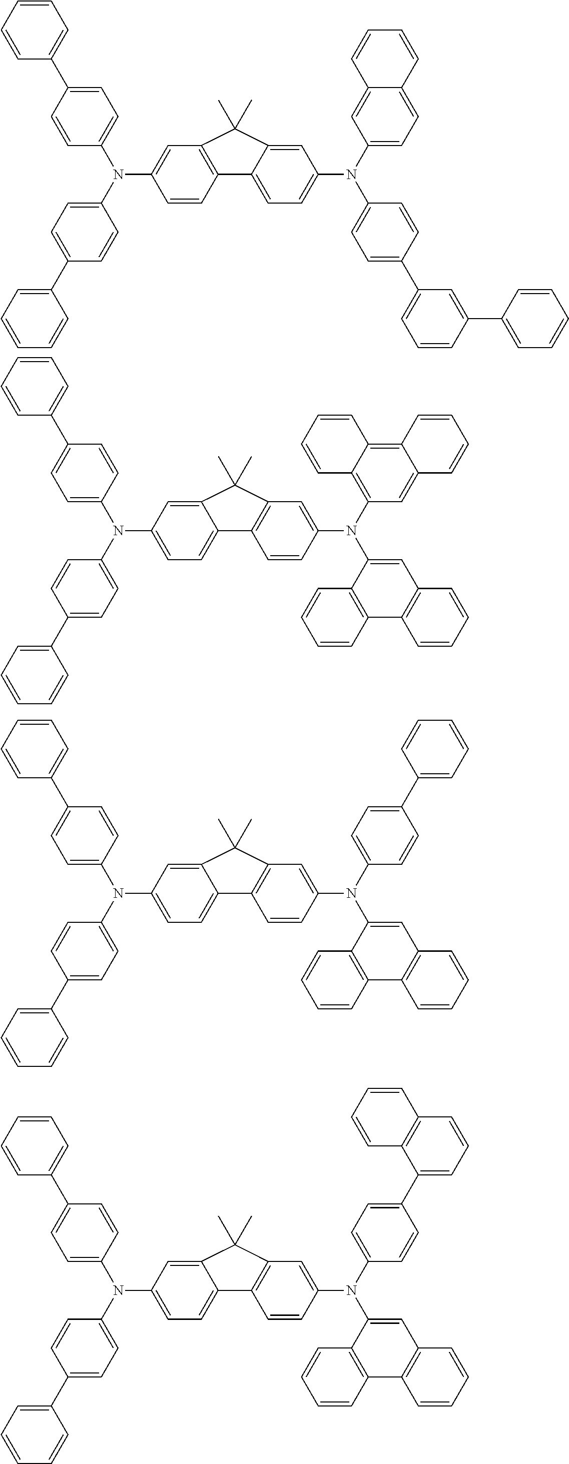

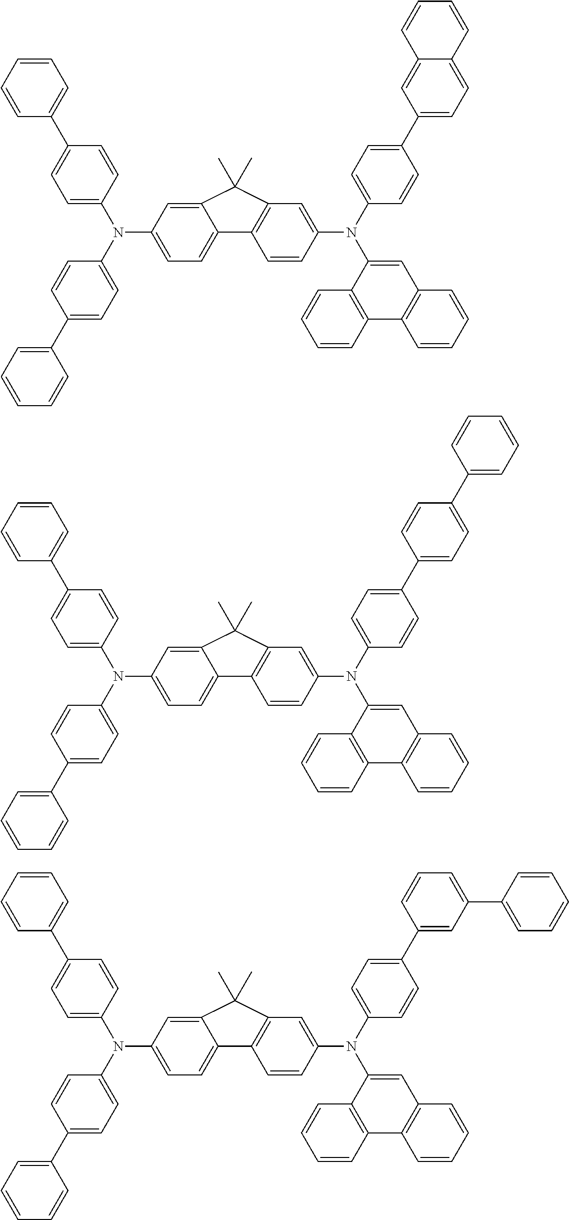

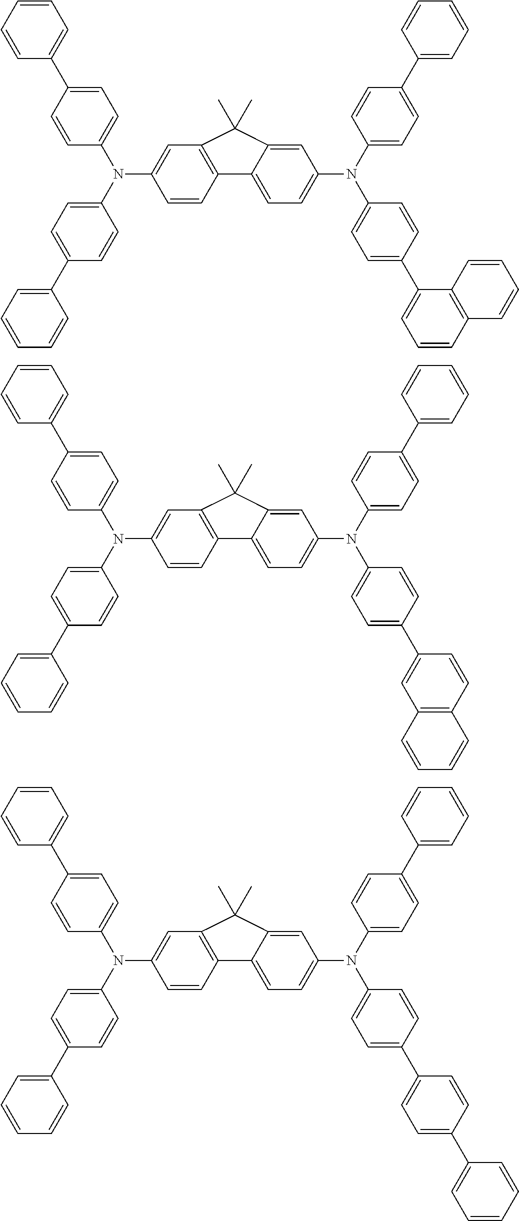

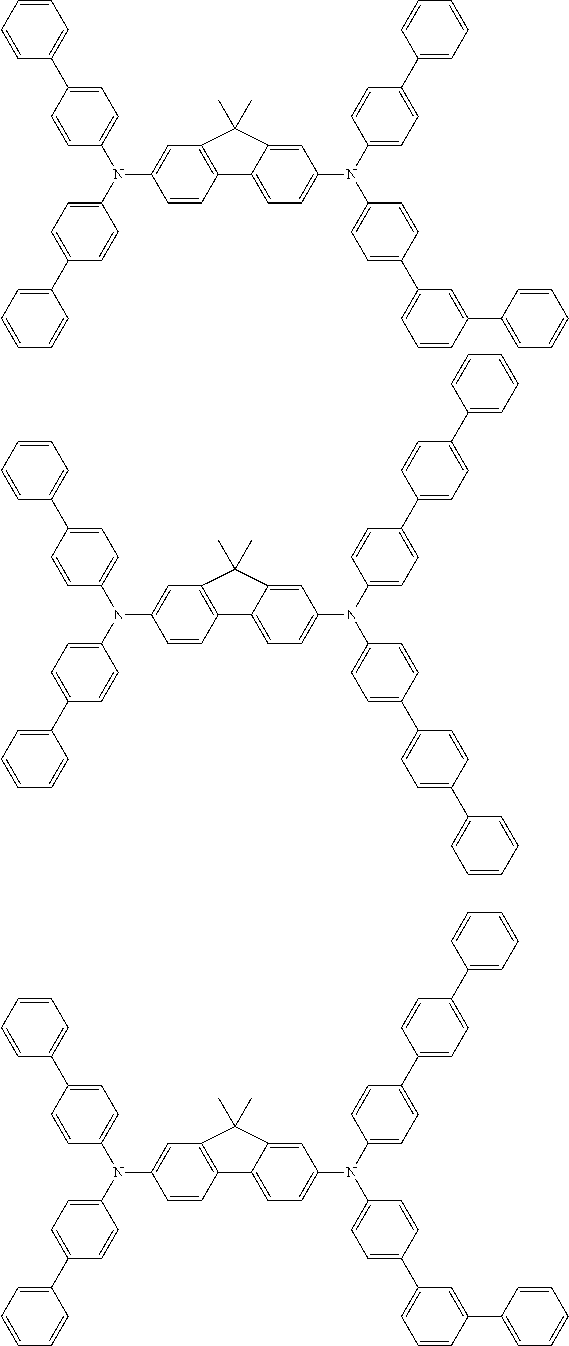

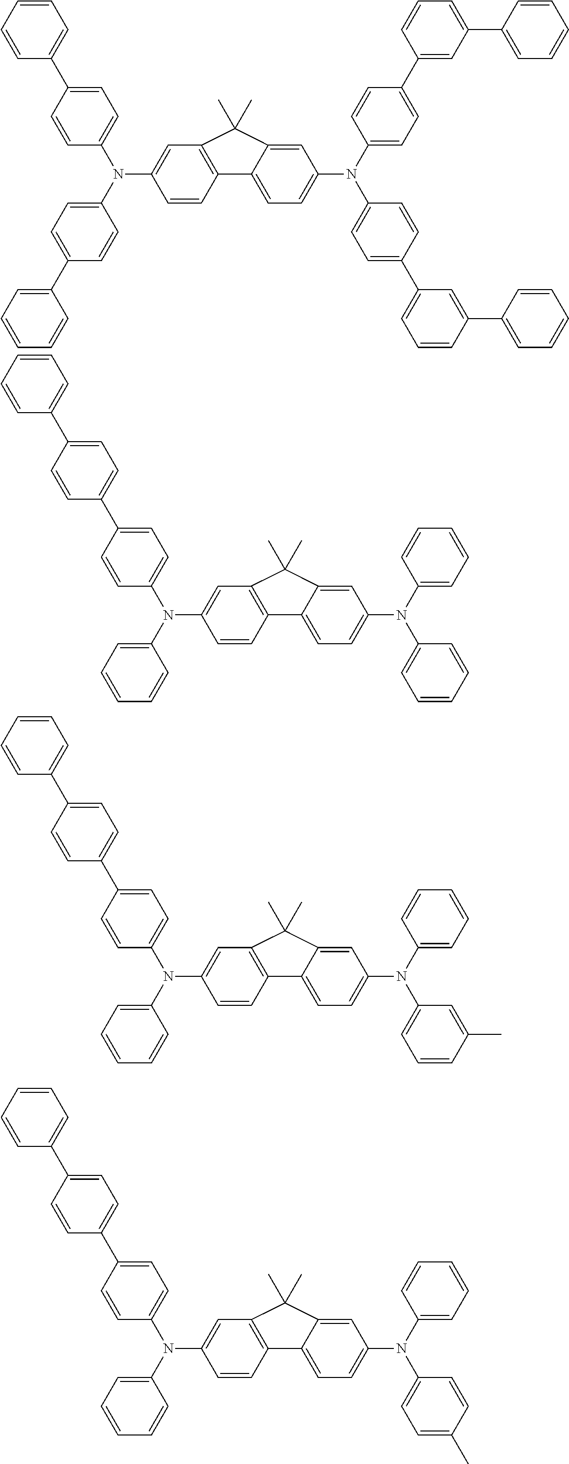

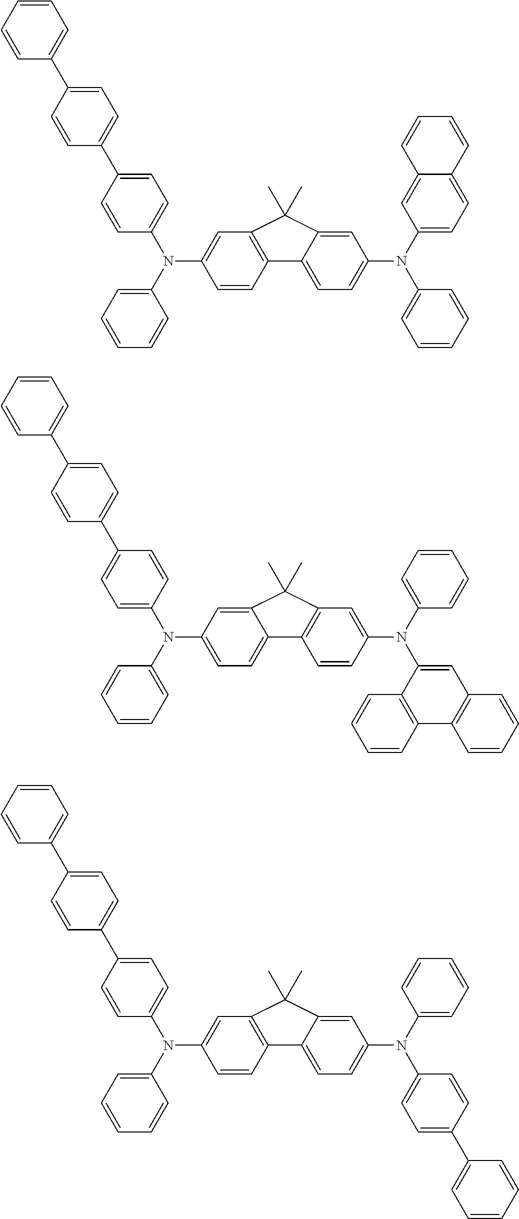 [SMILES: CC1(C)c2cc(N(c3ccccc3)c3ccc(-c4ccc(-c5ccccc5)cc4)cc3)ccc2-c2ccc(N(c3ccccc3)c3ccc4ccccc4c3)cc21 ; CC1(C)c2cc(N(c3ccccc3)c3ccc(-c4ccc(-c5ccccc5)cc4)cc3)ccc2-c2ccc(N(c3ccccc3)c3cc4ccccc4c4ccccc34)cc21 ; CC1(C)c2cc(N(c3ccccc3)c3ccc(-c4ccccc4)cc3)ccc2-c2ccc(N(c3ccccc3)c3ccc(-c4ccc(-c5ccccc5)cc4)cc3)cc21]

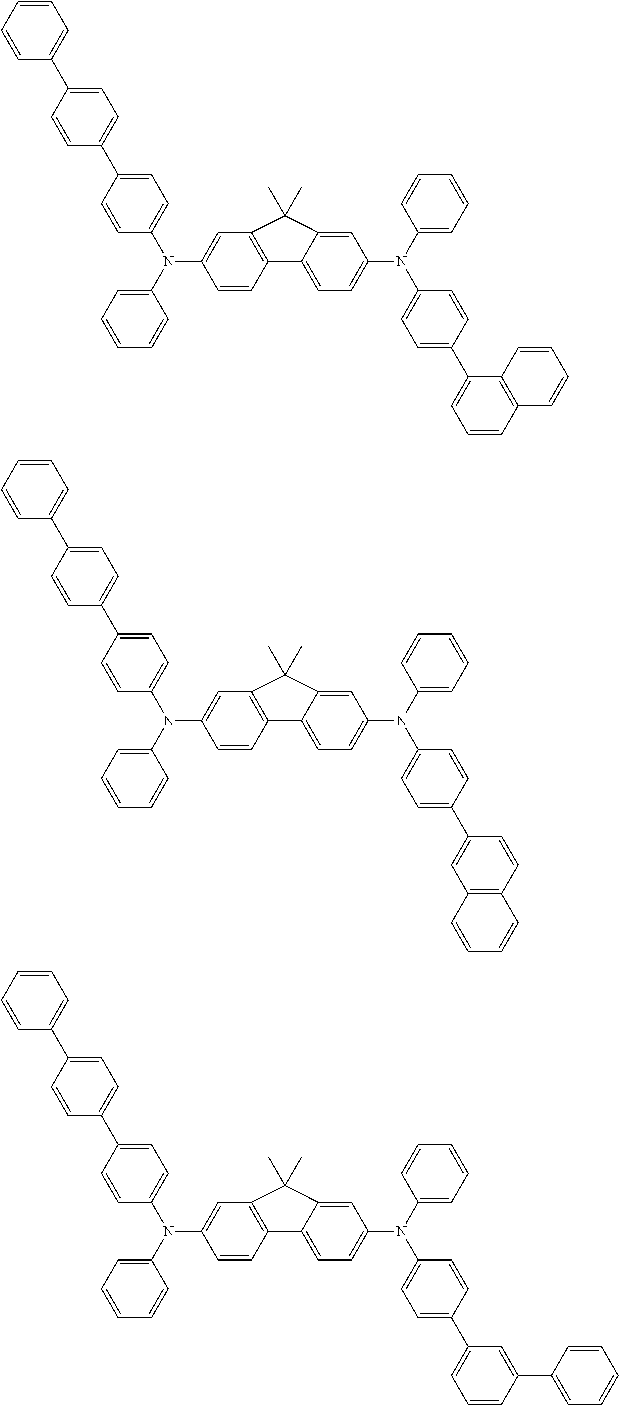 [SMILES: CC1(C)c2cc(N(c3ccccc3)c3ccc(-c4ccc(-c5ccccc5)cc4)cc3)ccc2-c2ccc(N(c3ccccc3)c3ccc(-c4cccc5ccccc45)cc3)cc21 ; CC1(C)c2cc(N(c3ccccc3)c3ccc(-c4ccc(-c5ccccc5)cc4)cc3)ccc2-c2ccc(N(c3ccccc3)c3ccc(-c4ccc5ccccc5c4)cc3)cc21 ; CC1(C)c2cc(N(c3ccccc3)c3ccc(-c4ccc(-c5ccccc5)cc4)cc3)ccc2-c2ccc(N(c3ccccc3)c3ccc(-c4cccc(-c5ccccc5)c4)cc3)cc21]

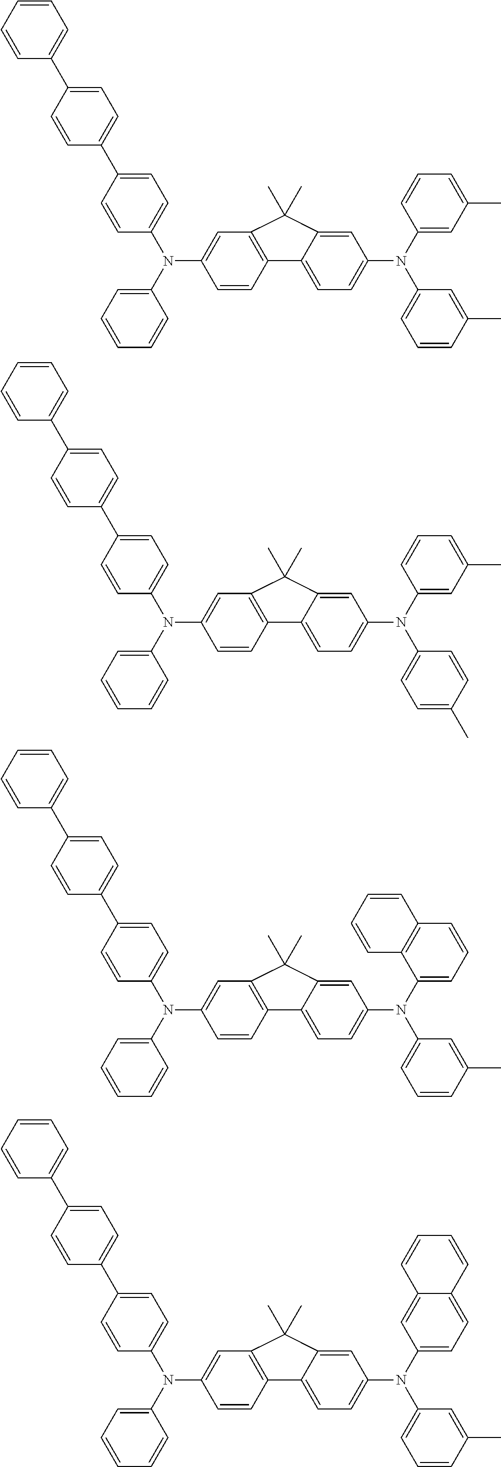 [SMILES: Cc1cccc(N(c2cccc(C)c2)c2ccc3c(c2)C(C)(C)c2cc(N(c4ccccc4)c4ccc(-c5ccc(-c6ccccc6)cc5)cc4)ccc2-3)c1 ; Cc1ccc(N(c2cccc(C)c2)c2ccc3c(c2)C(C)(C)c2cc(N(c4ccccc4)c4ccc(-c5ccc(-c6ccccc6)cc5)cc4)ccc2-3)cc1 ; Cc1cccc(N(c2ccc3c(c2)C(C)(C)c2cc(N(c4ccccc4)c4ccc(-c5ccc(-c6ccccc6)cc5)cc4)ccc2-3)c2cccc3ccccc23)c1 ; Cc1cccc(N(c2ccc3c(c2)C(C)(C)c2cc(N(c4ccccc4)c4ccc(-c5ccc(-c6ccccc6)cc5)cc4)ccc2-3)c2ccc3ccccc3c2)c1]

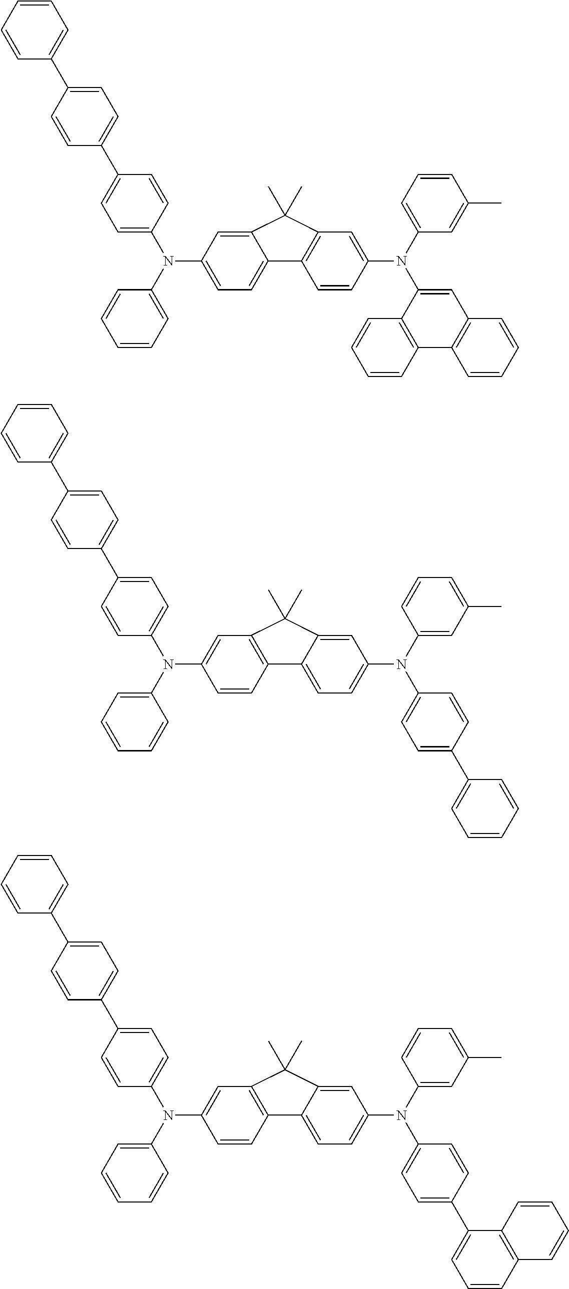 [SMILES: Cc1cccc(N(c2ccc3c(c2)C(C)(C)c2cc(N(c4ccccc4)c4ccc(-c5ccc(-c6ccccc6)cc5)cc4)ccc2-3)c2cc3ccccc3c3ccccc23)c1 ; Cc1cccc(N(c2ccc(-c3ccccc3)cc2)c2ccc3c(c2)C(C)(C)c2cc(N(c4ccccc4)c4ccc(-c5ccc(-c6ccccc6)cc5)cc4)ccc2-3)c1 ; Cc1cccc(N(c2ccc(-c3cccc4ccccc34)cc2)c2ccc3c(c2)C(C)(C)c2cc(N(c4ccccc4)c4ccc(-c5ccc(-c6ccccc6)cc5)cc4)ccc2-3)c1]

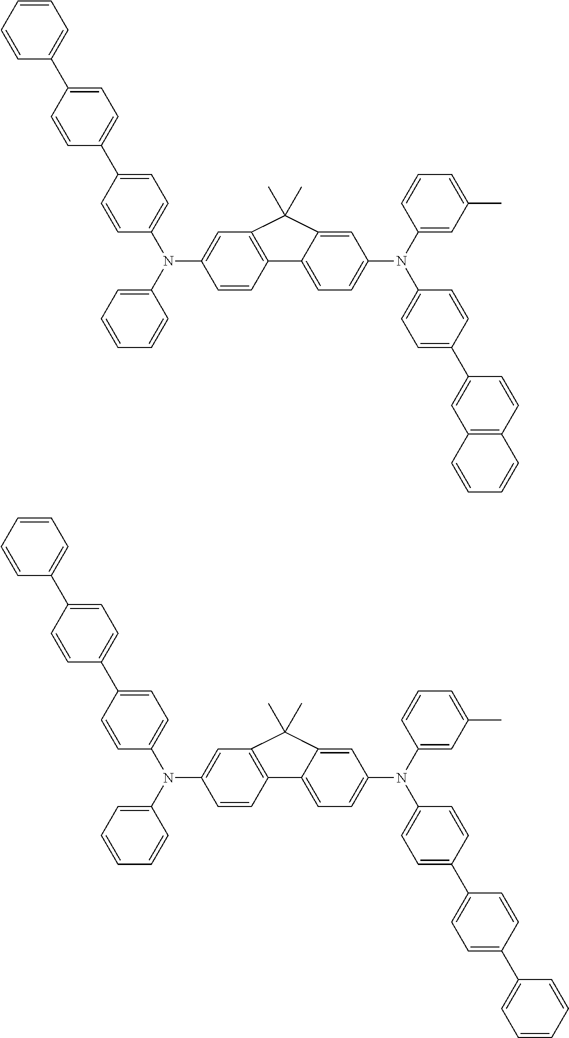 [SMILES: Cc1cccc(N(c2ccc(-c3ccc4ccccc4c3)cc2)c2ccc3c(c2)C(C)(C)c2cc(N(c4ccccc4)c4ccc(-c5ccc(-c6ccccc6)cc5)cc4)ccc2-3)c1 ; Cc1cccc(N(c2ccc(-c3ccc(-c4ccccc4)cc3)cc2)c2ccc3c(c2)C(C)(C)c2cc(N(c4ccccc4)c4ccc(-c5ccc(-c6ccccc6)cc5)cc4)ccc2-3)c1]

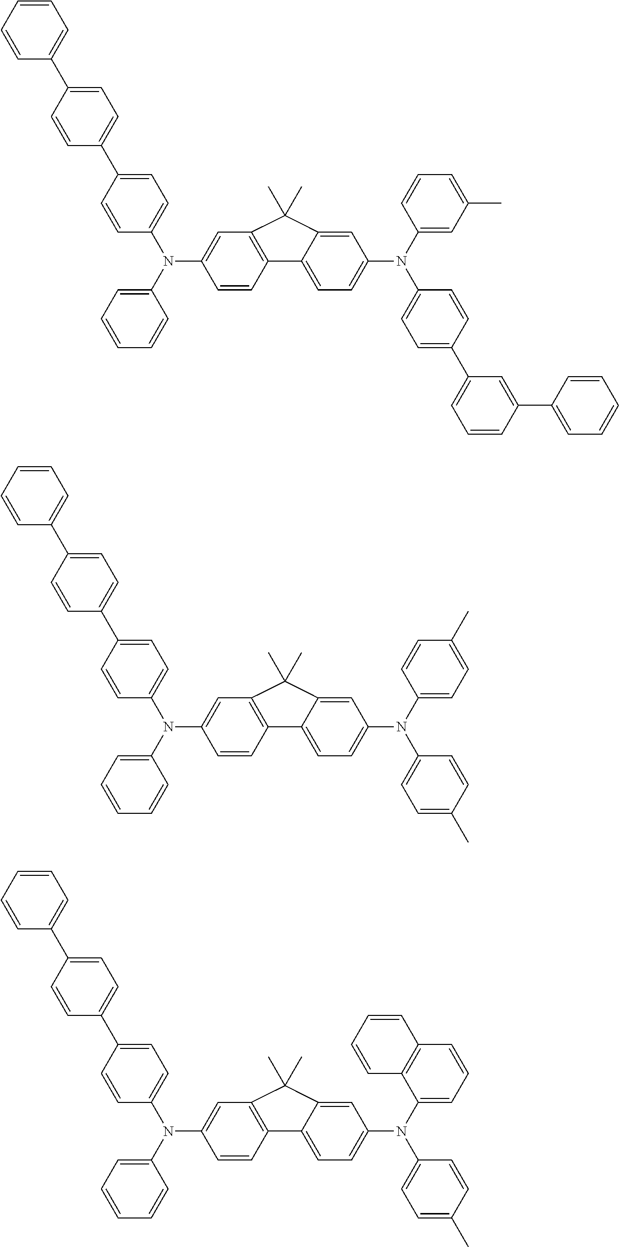 [SMILES: Cc1cccc(N(c2ccc(-c3cccc(-c4ccccc4)c3)cc2)c2ccc3c(c2)C(C)(C)c2cc(N(c4ccccc4)c4ccc(-c5ccc(-c6ccccc6)cc5)cc4)ccc2-3)c1 ; Cc1ccc(N(c2ccc(C)cc2)c2ccc3c(c2)C(C)(C)c2cc(N(c4ccccc4)c4ccc(-c5ccc(-c6ccccc6)cc5)cc4)ccc2-3)cc1 ; Cc1ccc(N(c2ccc3c(c2)C(C)(C)c2cc(N(c4ccccc4)c4ccc(-c5ccc(-c6ccccc6)cc5)cc4)ccc2-3)c2cccc3ccccc23)cc1]

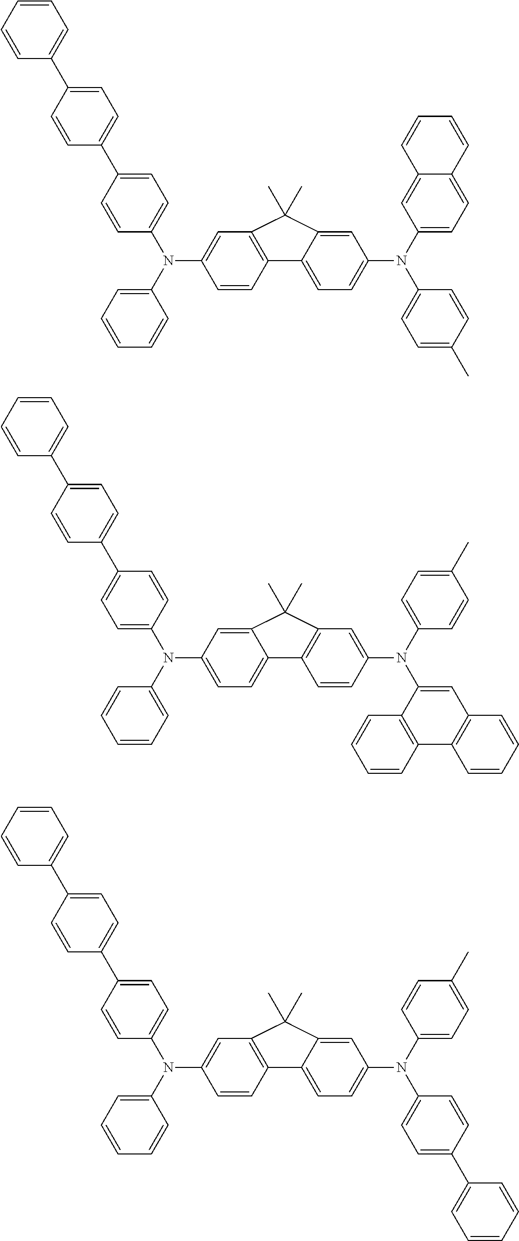 [SMILES: Cc1ccc(N(c2ccc3c(c2)C(C)(C)c2cc(N(c4ccccc4)c4ccc(-c5ccc(-c6ccccc6)cc5)cc4)ccc2-3)c2ccc3ccccc3c2)cc1 ; Cc1ccc(N(c2ccc3c(c2)C(C)(C)c2cc(N(c4ccccc4)c4ccc(-c5ccc(-c6ccccc6)cc5)cc4)ccc2-3)c2cc3ccccc3c3ccccc23)cc1 ; Cc1ccc(N(c2ccc(-c3ccccc3)cc2)c2ccc3c(c2)C(C)(C)c2cc(N(c4ccccc4)c4ccc(-c5ccc(-c6ccccc6)cc5)cc4)ccc2-3)cc1]

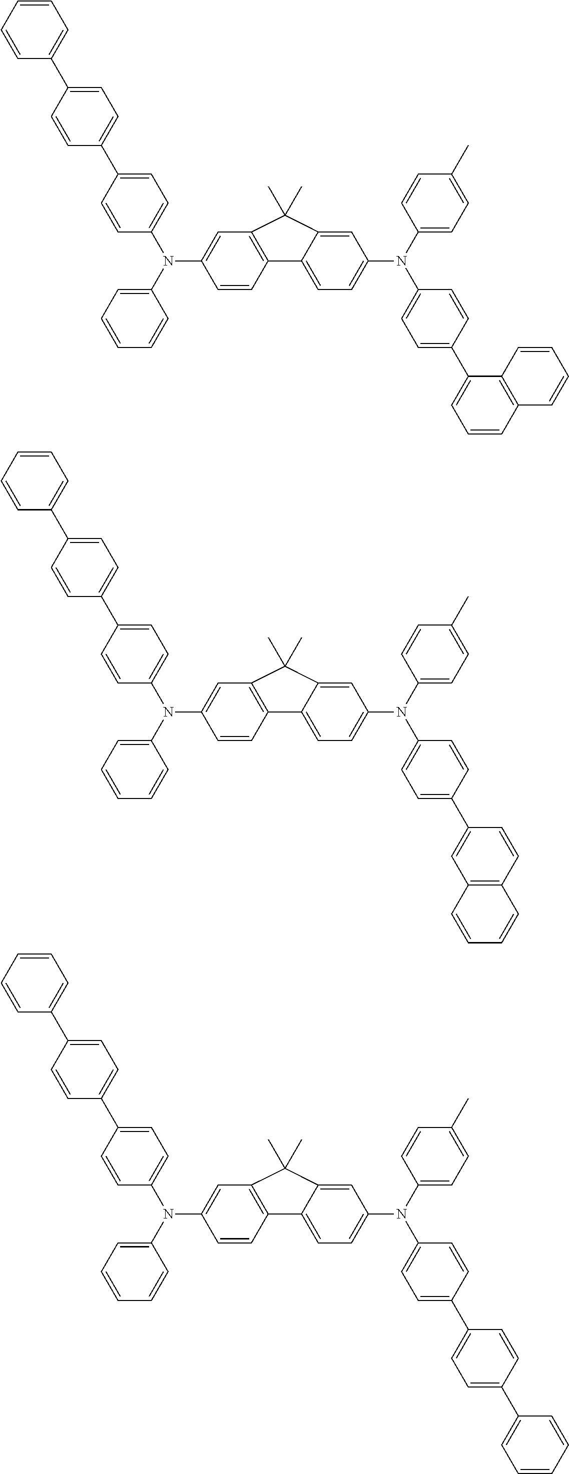 [SMILES: Cc1ccc(N(c2ccc(-c3cccc4ccccc34)cc2)c2ccc3c(c2)C(C)(C)c2cc(N(c4ccccc4)c4ccc(-c5ccc(-c6ccccc6)cc5)cc4)ccc2-3)cc1 ; Cc1ccc(N(c2ccc(-c3ccc4ccccc4c3)cc2)c2ccc3c(c2)C(C)(C)c2cc(N(c4ccccc4)c4ccc(-c5ccc(-c6ccccc6)cc5)cc4)ccc2-3)cc1 ; Cc1ccc(N(c2ccc(-c3ccc(-c4ccccc4)cc3)cc2)c2ccc3c(c2)C(C)(C)c2cc(N(c4ccccc4)c4ccc(-c5ccc(-c6ccccc6)cc5)cc4)ccc2-3)cc1]

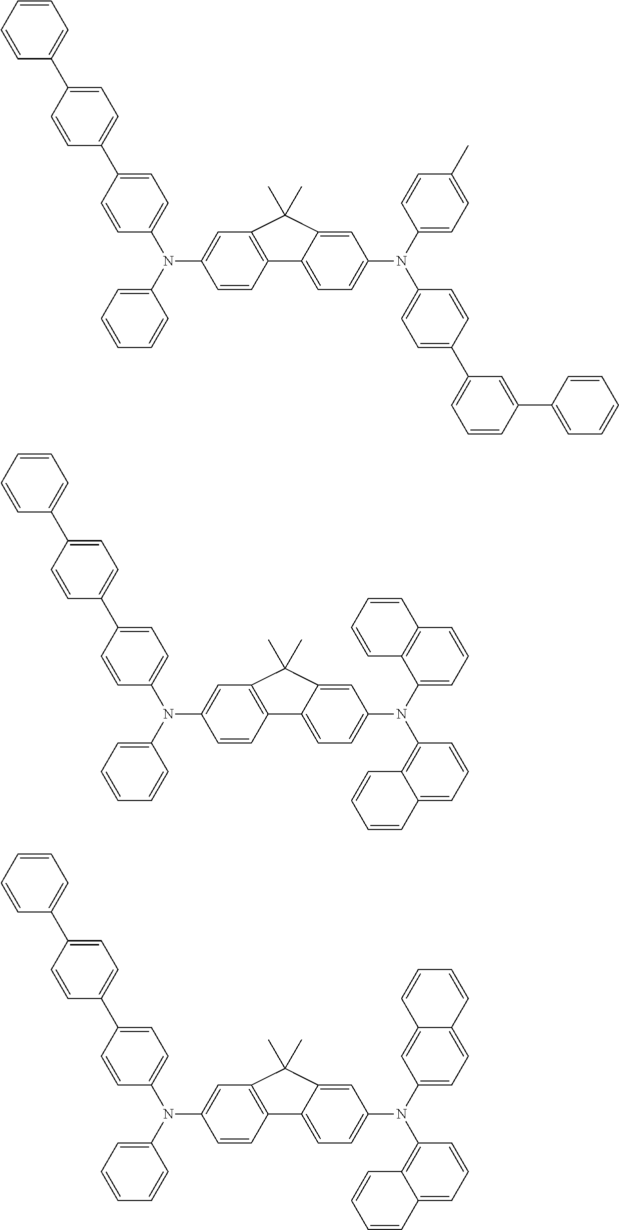 [SMILES: Cc1ccc(N(c2ccc(-c3cccc(-c4ccccc4)c3)cc2)c2ccc3c(c2)C(C)(C)c2cc(N(c4ccccc4)c4ccc(-c5ccc(-c6ccccc6)cc5)cc4)ccc2-3)cc1 ; CC1(C)c2cc(N(c3ccccc3)c3ccc(-c4ccc(-c5ccccc5)cc4)cc3)ccc2-c2ccc(N(c3cccc4ccccc34)c3cccc4ccccc34)cc21 ; CC1(C)c2cc(N(c3ccccc3)c3ccc(-c4ccc(-c5ccccc5)cc4)cc3)ccc2-c2ccc(N(c3ccc4ccccc4c3)c3cccc4ccccc34)cc21]

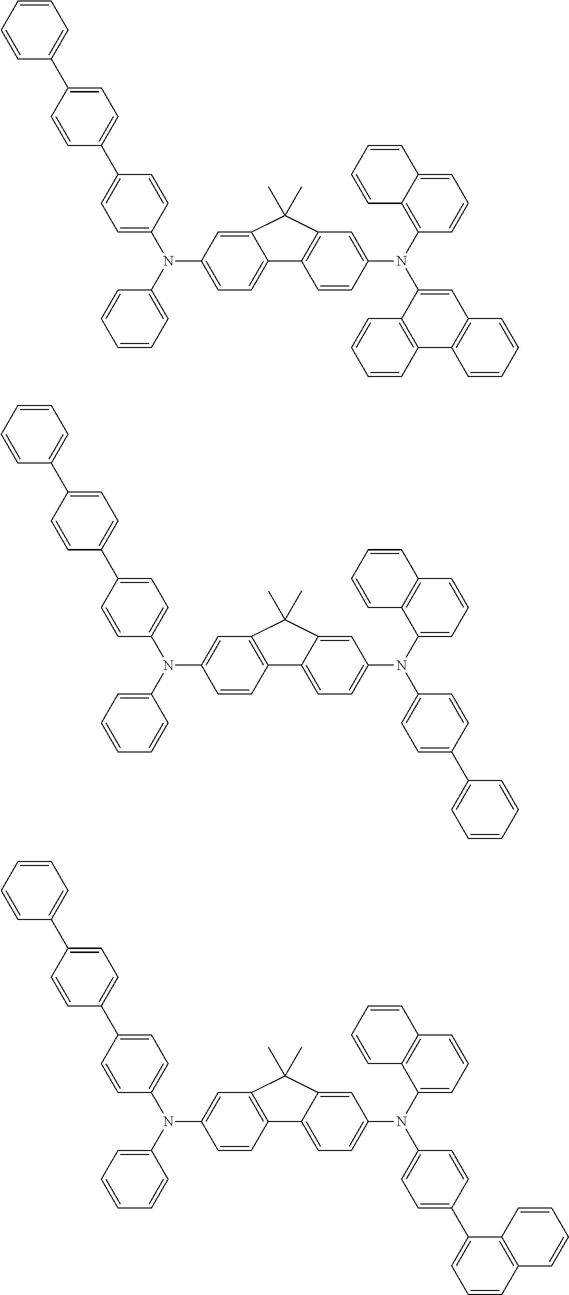 [SMILES: CC1(C)c2cc(N(c3ccccc3)c3ccc(-c4ccc(-c5ccccc5)cc4)cc3)ccc2-c2ccc(N(c3cccc4ccccc34)c3cc4ccccc4c4ccccc34)cc21 ; CC1(C)c2cc(N(c3ccccc3)c3ccc(-c4ccc(-c5ccccc5)cc4)cc3)ccc2-c2ccc(N(c3ccc(-c4ccccc4)cc3)c3cccc4ccccc34)cc21 ; CC1(C)c2cc(N(c3ccccc3)c3ccc(-c4ccc(-c5ccccc5)cc4)cc3)ccc2-c2ccc(N(c3ccc(-c4cccc5ccccc45)cc3)c3cccc4ccccc34)cc21]

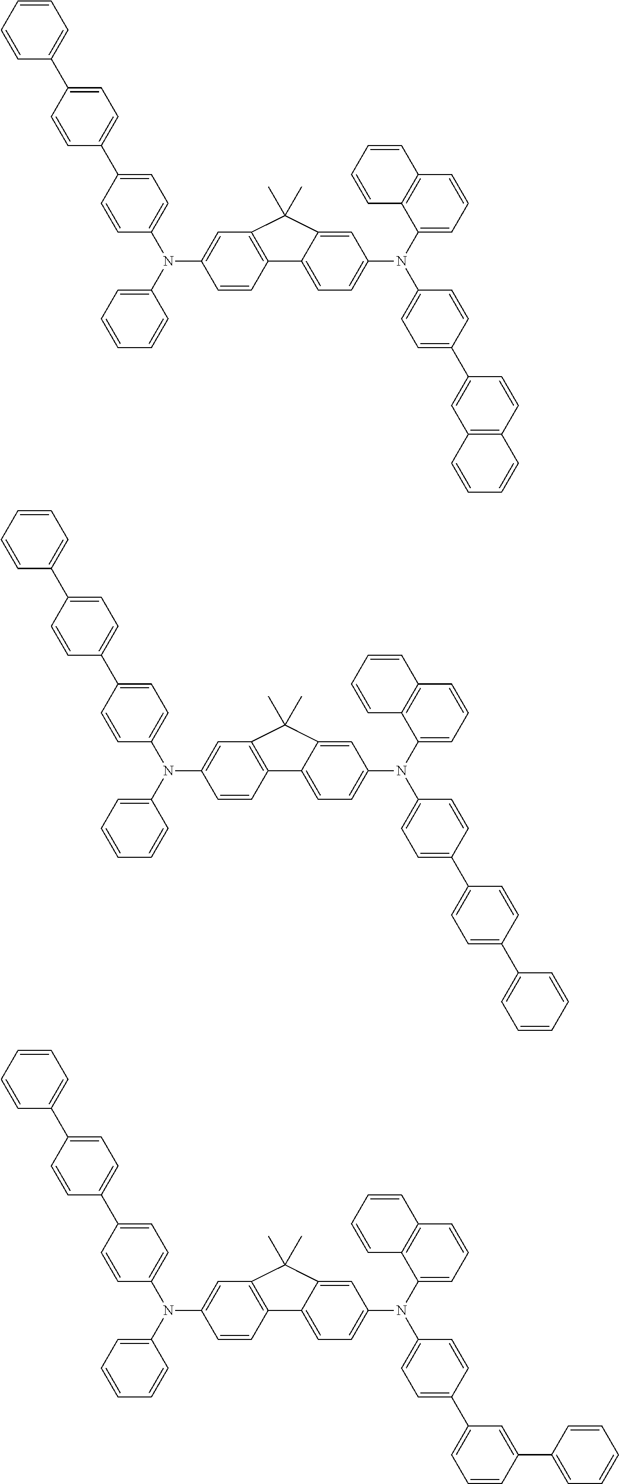 [SMILES: CC1(C)c2cc(N(c3ccccc3)c3ccc(-c4ccc(-c5ccccc5)cc4)cc3)ccc2-c2ccc(N(c3ccc(-c4ccc5ccccc5c4)cc3)c3cccc4ccccc34)cc21 ; CC1(C)c2cc(N(c3ccccc3)c3ccc(-c4ccc(-c5ccccc5)cc4)cc3)ccc2-c2ccc(N(c3ccc(-c4ccc(-c5ccccc5)cc4)cc3)c3cccc4ccccc34)cc21 ; CC1(C)c2cc(N(c3ccccc3)c3ccc(-c4ccc(-c5ccccc5)cc4)cc3)ccc2-c2ccc(N(c3ccc(-c4cccc(-c5ccccc5)c4)cc3)c3cccc4ccccc34)cc21]

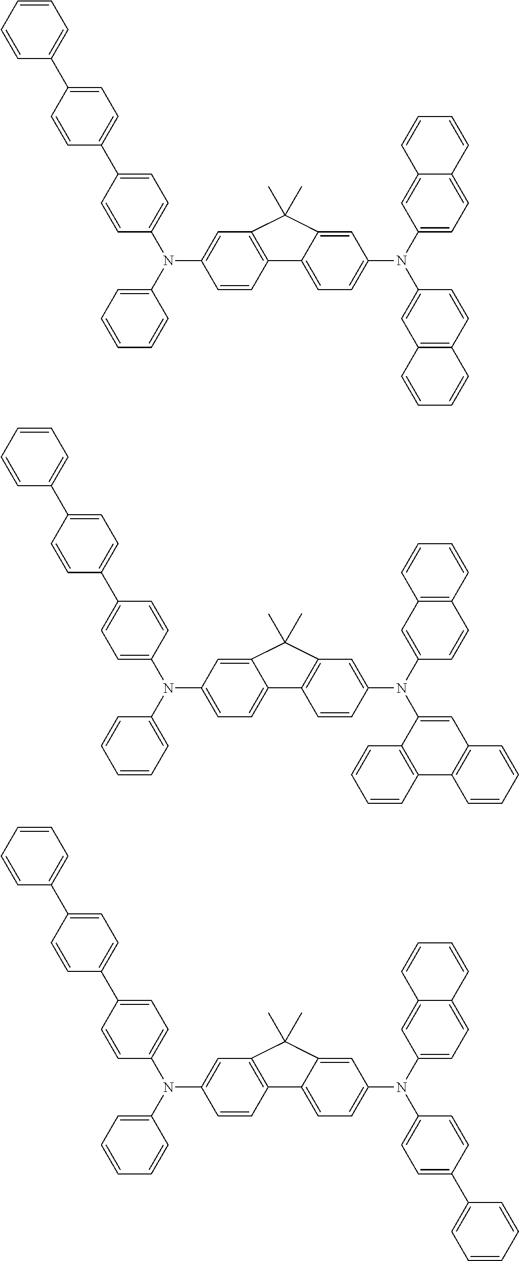 [SMILES: CC1(C)c2cc(N(c3ccccc3)c3ccc(-c4ccc(-c5ccccc5)cc4)cc3)ccc2-c2ccc(N(c3ccc4ccccc4c3)c3ccc4ccccc4c3)cc21 ; CC1(C)c2cc(N(c3ccccc3)c3ccc(-c4ccc(-c5ccccc5)cc4)cc3)ccc2-c2ccc(N(c3ccc4ccccc4c3)c3cc4ccccc4c4ccccc34)cc21 ; CC1(C)c2cc(N(c3ccccc3)c3ccc(-c4ccc(-c5ccccc5)cc4)cc3)ccc2-c2ccc(N(c3ccc(-c4ccccc4)cc3)c3ccc4ccccc4c3)cc21]

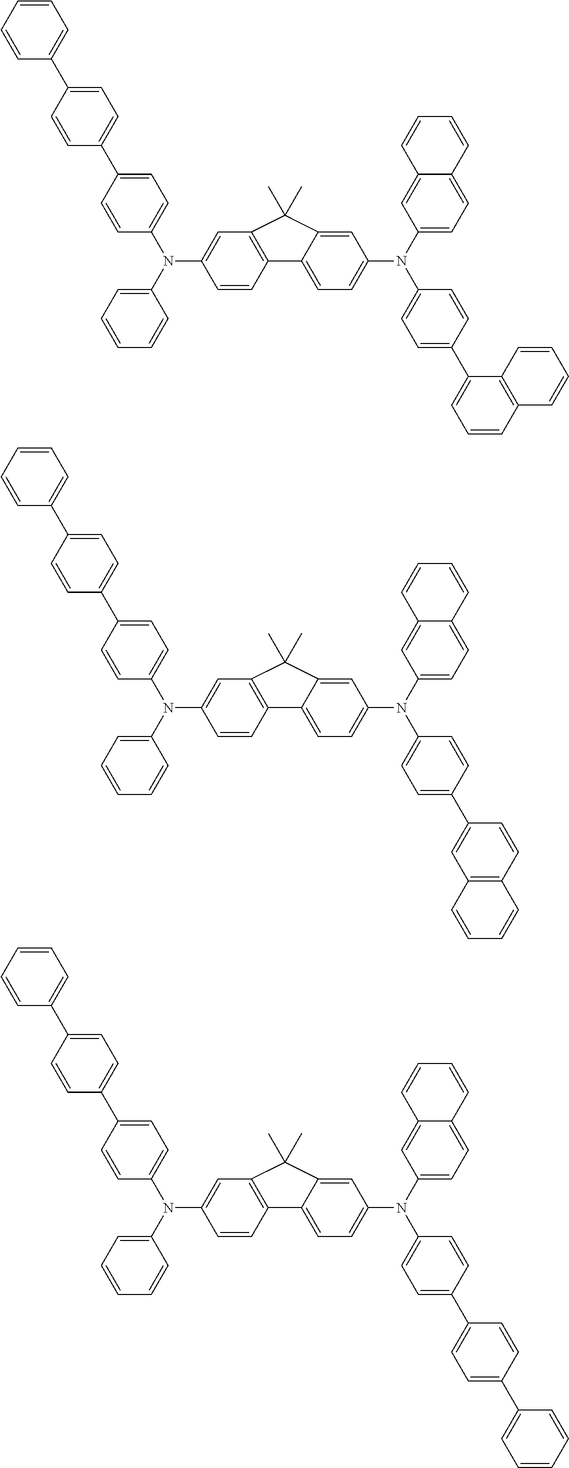 [SMILES: CC1(C)c2cc(N(c3ccccc3)c3ccc(-c4ccc(-c5ccccc5)cc4)cc3)ccc2-c2ccc(N(c3ccc(-c4cccc5ccccc45)cc3)c3ccc4ccccc4c3)cc21 ; CC1(C)c2cc(N(c3ccccc3)c3ccc(-c4ccc(-c5ccccc5)cc4)cc3)ccc2-c2ccc(N(c3ccc(-c4ccc5ccccc5c4)cc3)c3ccc4ccccc4c3)cc21 ; CC1(C)c2cc(N(c3ccccc3)c3ccc(-c4ccc(-c5ccccc5)cc4)cc3)ccc2-c2ccc(N(c3ccc(-c4ccc(-c5ccccc5)cc4)cc3)c3ccc4ccccc4c3)cc21]

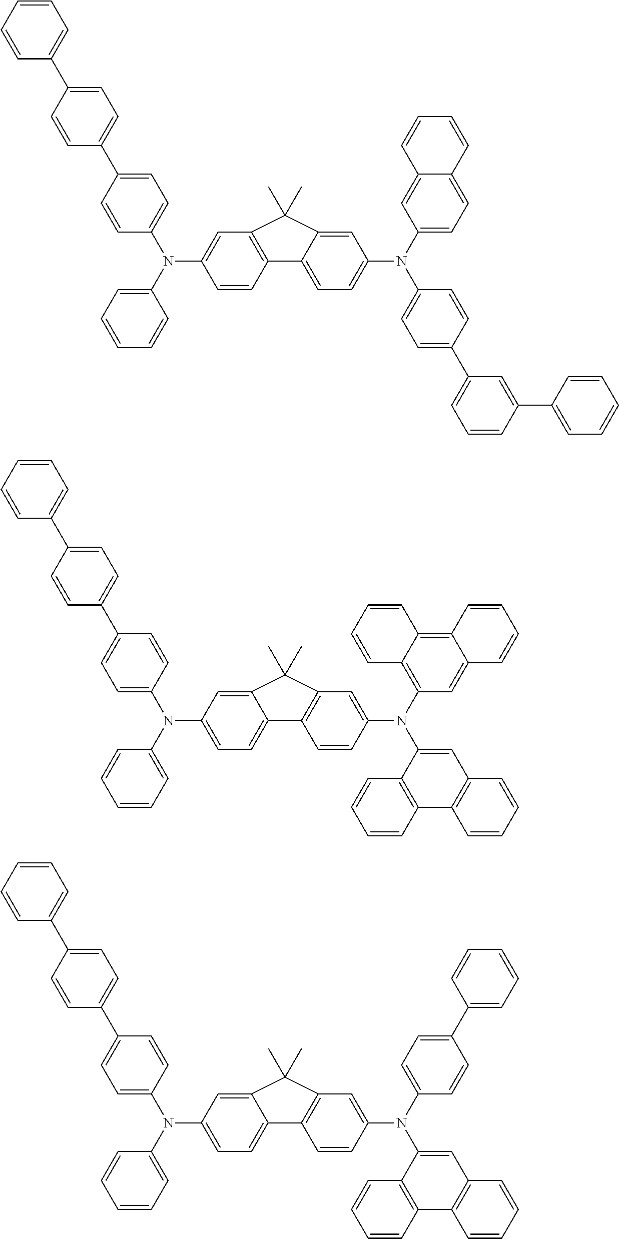 [SMILES: CC1(C)c2cc(N(c3ccccc3)c3ccc(-c4ccc(-c5ccccc5)cc4)cc3)ccc2-c2ccc(N(c3ccc(-c4cccc(-c5ccccc5)c4)cc3)c3ccc4ccccc4c3)cc21 ; CC1(C)c2cc(N(c3ccccc3)c3ccc(-c4ccc(-c5ccccc5)cc4)cc3)ccc2-c2ccc(N(c3cc4ccccc4c4ccccc34)c3cc4ccccc4c4ccccc34)cc21 ; CC1(C)c2cc(N(c3ccccc3)c3ccc(-c4ccc(-c5ccccc5)cc4)cc3)ccc2-c2ccc(N(c3ccc(-c4ccccc4)cc3)c3cc4ccccc4c4ccccc34)cc21]

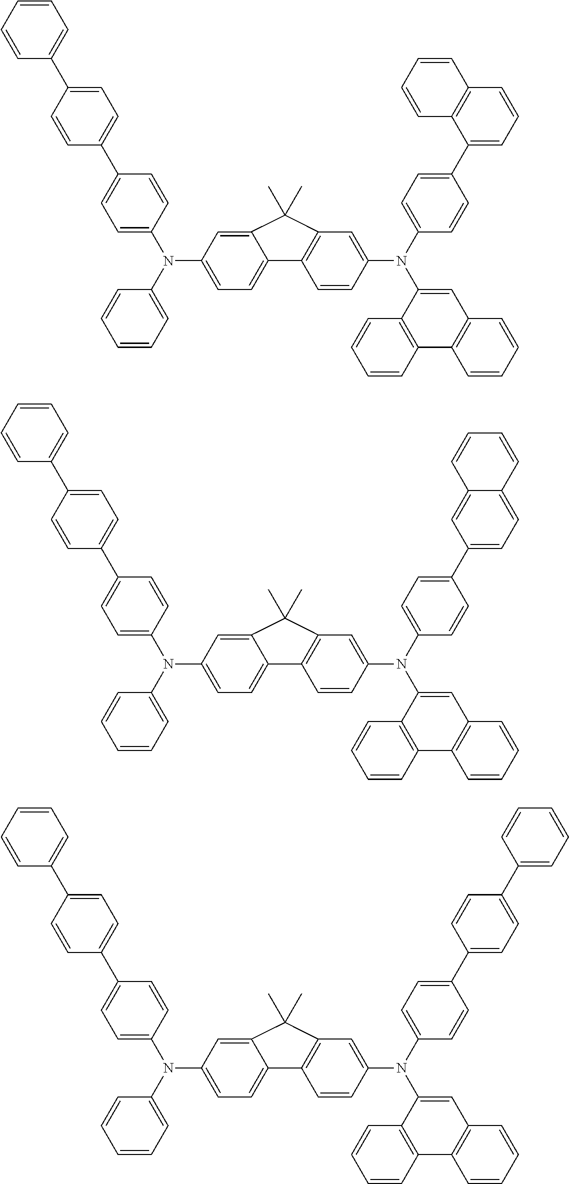

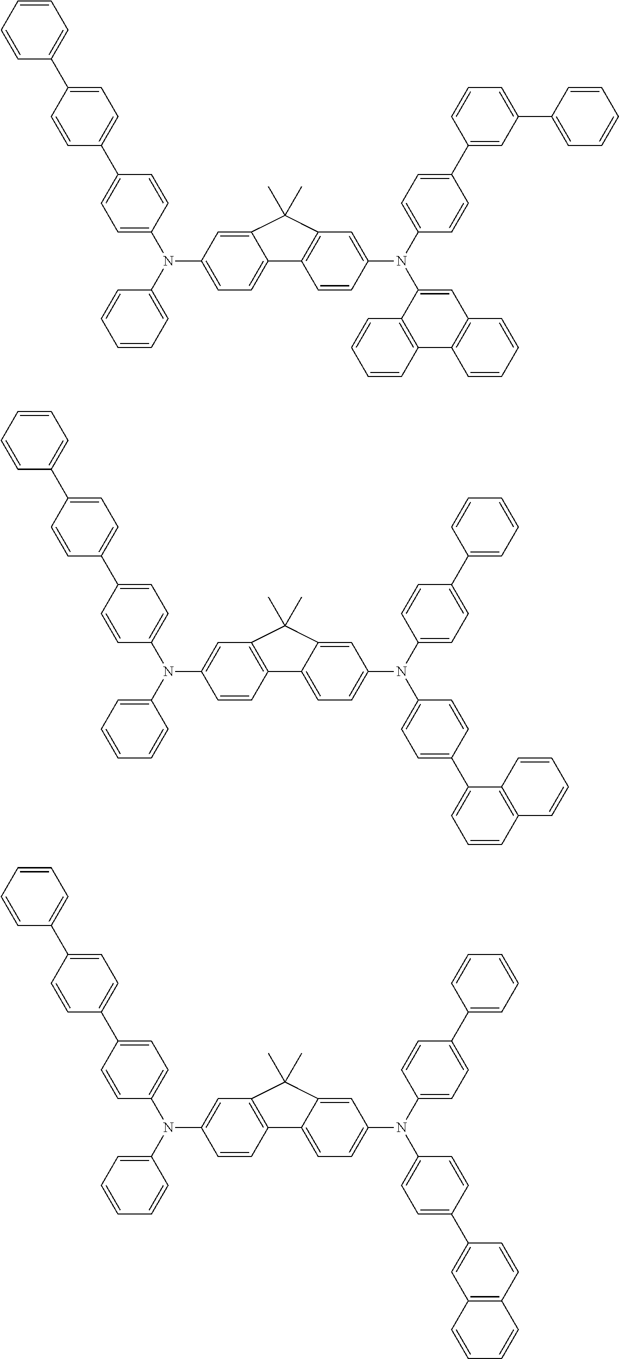 [SMILES: CC1(C)c2cc(N(c3ccccc3)c3ccc(-c4ccc(-c5ccccc5)cc4)cc3)ccc2-c2ccc(N(c3ccc(-c4cccc(-c5ccccc5)c4)cc3)c3cc4ccccc4c4ccccc34)cc21 ; CC1(C)c2cc(N(c3ccccc3)c3ccc(-c4ccc(-c5ccccc5)cc4)cc3)ccc2-c2ccc(N(c3ccc(-c4ccccc4)cc3)c3ccc(-c4cccc5ccccc45)cc3)cc21 ; CC1(C)c2cc(N(c3ccccc3)c3ccc(-c4ccc(-c5ccccc5)cc4)cc3)ccc2-c2ccc(N(c3ccc(-c4ccccc4)cc3)c3ccc(-c4ccc5ccccc5c4)cc3)cc21]

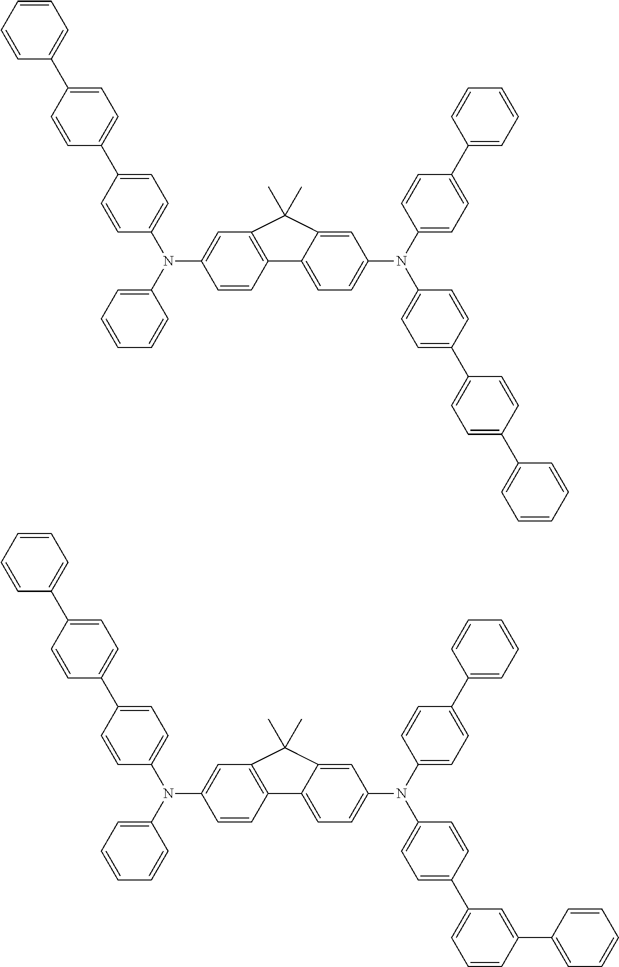 [SMILES: CC1(C)c2cc(N(c3ccccc3)c3ccc(-c4ccc(-c5ccccc5)cc4)cc3)ccc2-c2ccc(N(c3ccc(-c4ccccc4)cc3)c3ccc(-c4ccc(-c5ccccc5)cc4)cc3)cc21 ; CC1(C)c2cc(N(c3ccccc3)c3ccc(-c4ccc(-c5ccccc5)cc4)cc3)ccc2-c2ccc(N(c3ccc(-c4ccccc4)cc3)c3ccc(-c4cccc(-c5ccccc5)c4)cc3)cc21]

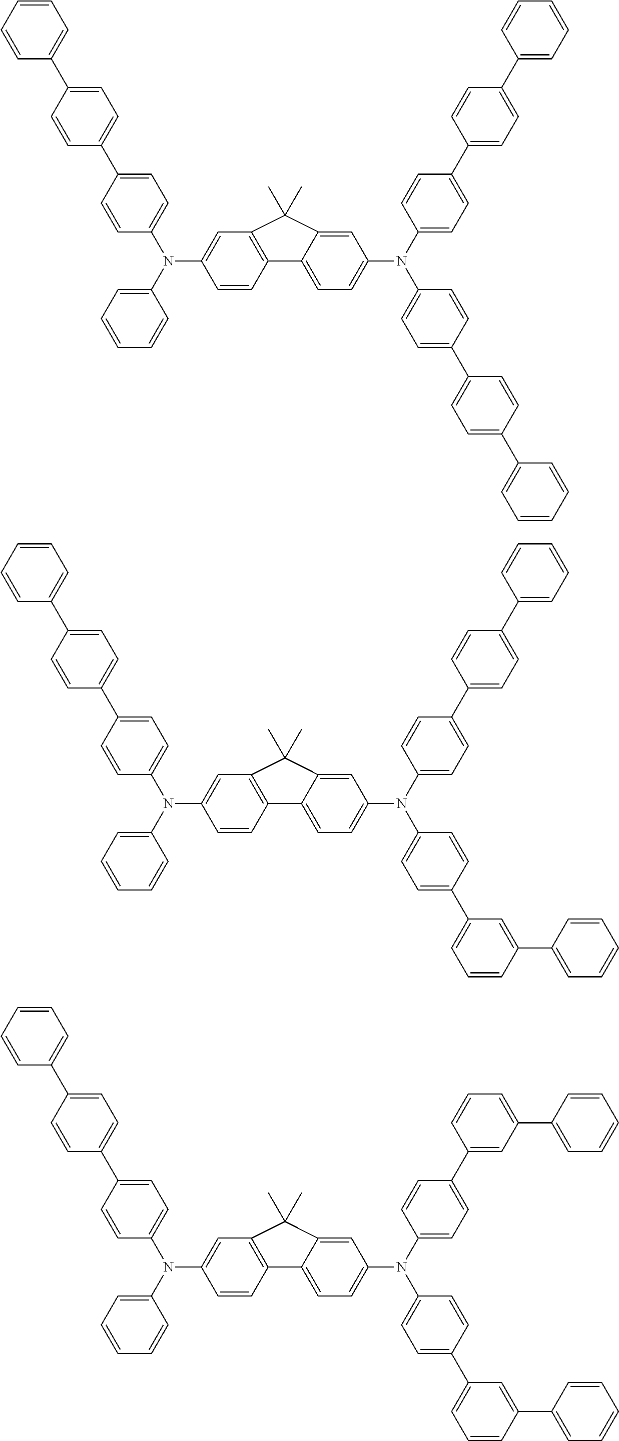

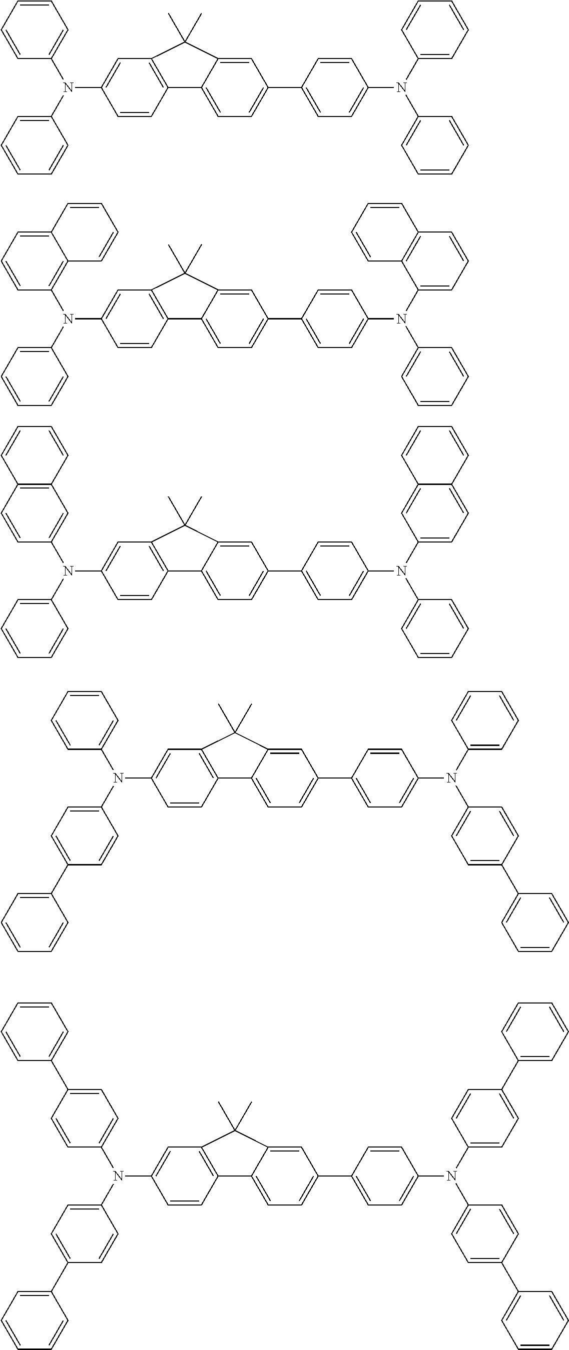

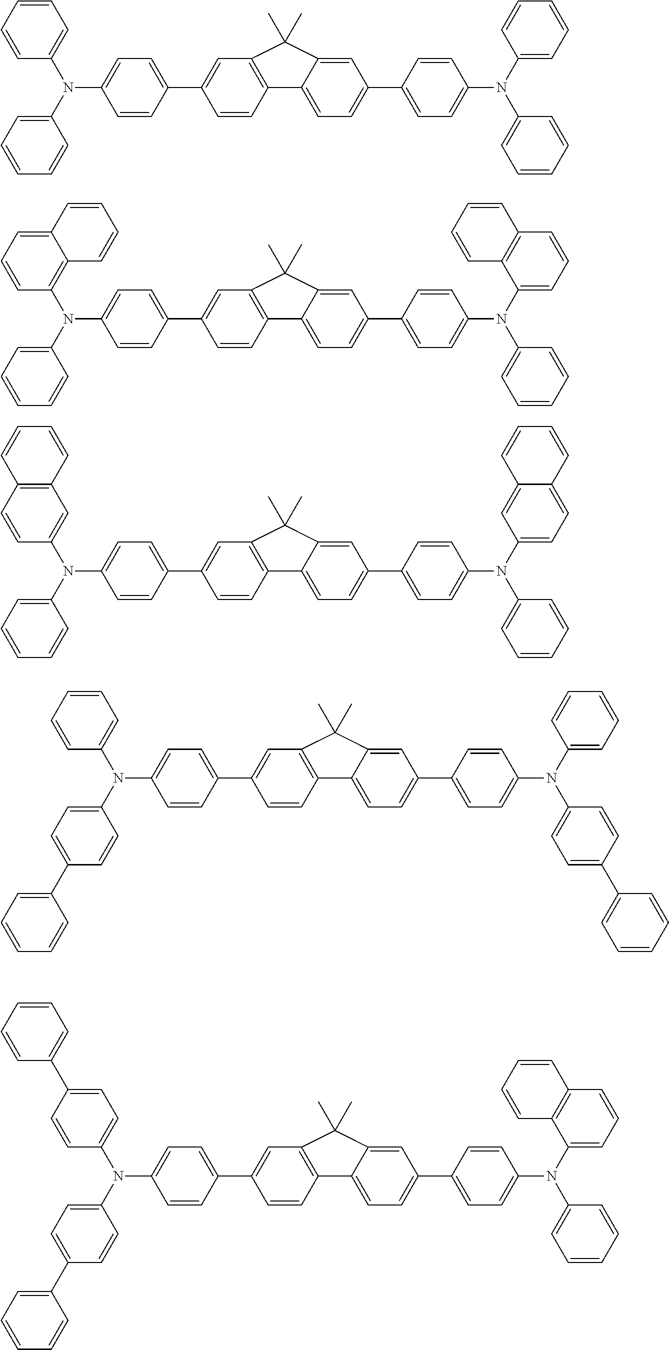

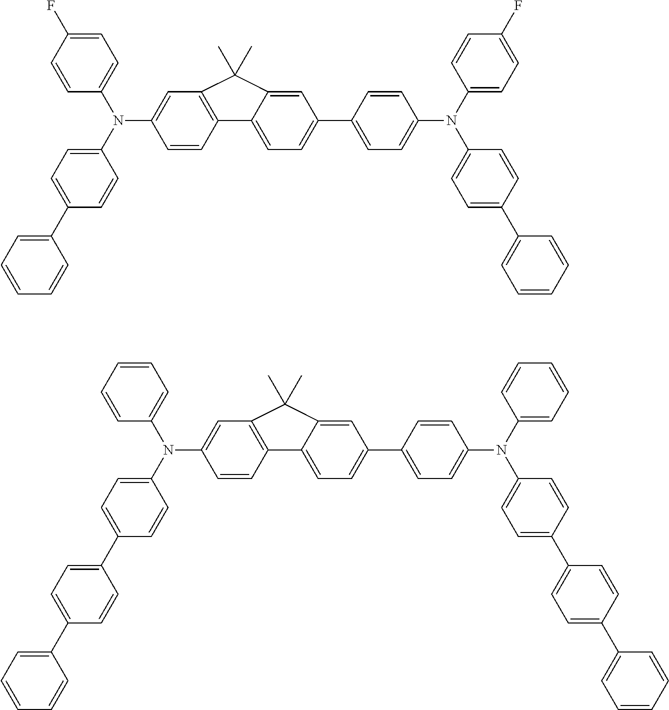 [SMILES: CC1(C)c2cc(-c3ccc(N(c4ccc(F)cc4)c4ccc(-c5ccccc5)cc4)cc3)ccc2-c2ccc(N(c3ccc(F)cc3)c3ccc(-c4ccccc4)cc3)cc21 ; CC1(C)c2cc(-c3ccc(N(c4ccccc4)c4ccc(-c5ccc(-c6ccccc6)cc5)cc4)cc3)ccc2-c2ccc(N(c3ccccc3)c3ccc(-c4ccc(-c5ccccc5)cc4)cc3)cc21]

It should be noted that the hole injecting/transporting layer only needs to have a hole transporting layer (corresponding to the second hole transporting layer according to the exemplary embodiment) containing the compound represented by the formula (4). Accordingly, the hole injecting/transporting layer may be provided by only the hole transporting layer, by the hole transporting layer and a hole injecting layer provided to a side near the anode of the hole transporting layer, or by the hole injecting layer, the first hole transporting layer and the second hole transporting layer which are laminated in this sequence from the anode.

A material for forming the hole injecting layer and the first hole transporting layer is preferably a material for transporting holes to the emitting layer at a lower electric field intensity. For instance, an aromatic amine compound is preferably used. A material for the hole injecting layer is preferably a porphyrin compound, an aromatic tertiary amine compound or a styryl amine compound, particularly preferably the aromatic tertiary amine compound such as hexacyanohexaazatriphenylene (HAT).

A material for forming the hole injection/transport layer is preferably a material for transporting the holes to the emitting layer at a lower electric field intensity. For instance, an aromatic amine compound represented by the following formula (A1) is preferably used.

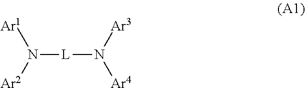

In the formula (A1), Ar¹ to Ar⁴ each independently represent an aromatic hydrocarbon group having 6 to 50 ring carbon atoms, aromatic heterocyclic group having 2 to 40 ring carbon atoms, or a group formed by combining the aromatic hydrocarbon group with the aromatic heterocyclic group, or a group formed by combining the aromatic hydrocarbon group with the aromatic heterocyclic group. Note that the aromatic hydrocarbon group and the aromatic heterocyclic group described herein may have a substituent.

In the formula (A1), L is a linking group and represents a divalent aromatic hydrocarbon group having 6 to 50 ring carbon atoms, a divalent aromatic heterocyclic group having 5 to 50 ring carbon atoms, and a divalent group formed by two or more aromatic hydrocarbon groups or aromatic heterocyclic groups which are bonded through a single bond, ether bond, thioether bond, or through an alkylene group having 1 to 20 carbon atoms, an alkenylene group having 2 to 20 carbon atoms or an amino group. Note that the divalent aromatic hydrocarbon group and the divalent aromatic heterocyclic group described herein may have a substituent.

Examples of the compound represented by the formula (A1) are shown below. However, the compound represented by the formula (A1) is not limited thereto.

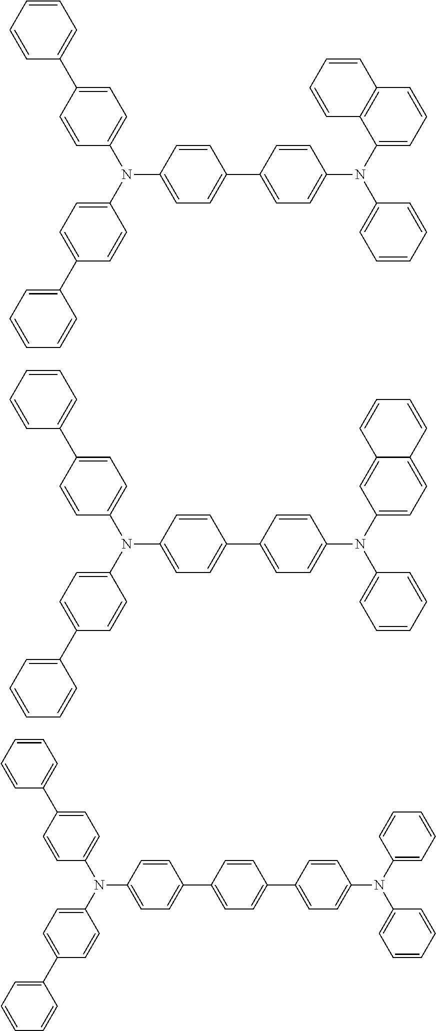

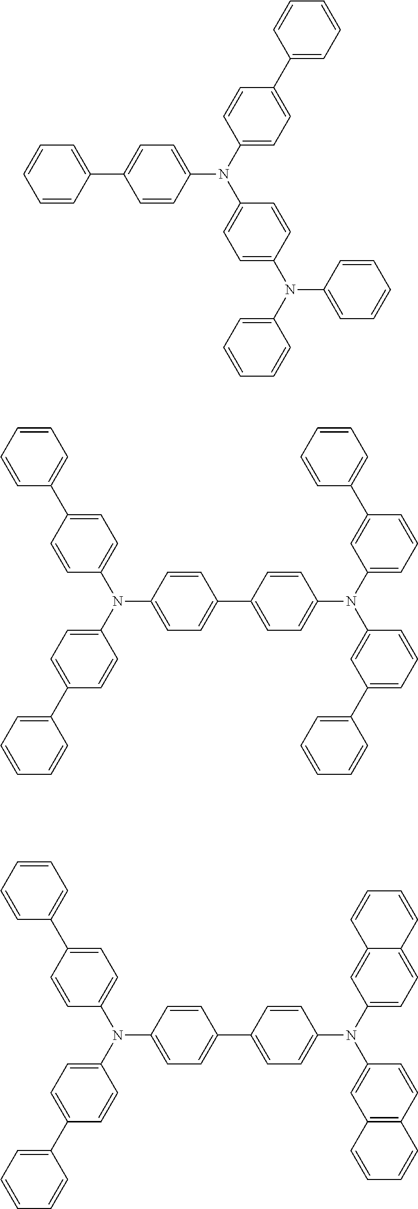 [SMILES: c1ccc(-c2ccc(N(c3ccc(-c4ccccc4)cc3)c3ccc(N(c4ccccc4)c4ccccc4)cc3)cc2)cc1 ; c1ccc(-c2ccc(N(c3ccc(-c4ccccc4)cc3)c3ccc(-c4ccc(N(c5cccc(-c6ccccc6)c5)c5cccc(-c6ccccc6)c5)cc4)cc3)cc2)cc1 ; c1ccc(-c2ccc(N(c3ccc(-c4ccccc4)cc3)c3ccc(-c4ccc(N(c5ccc6ccccc6c5)c5ccc6ccccc6c5)cc4)cc3)cc2)cc1]

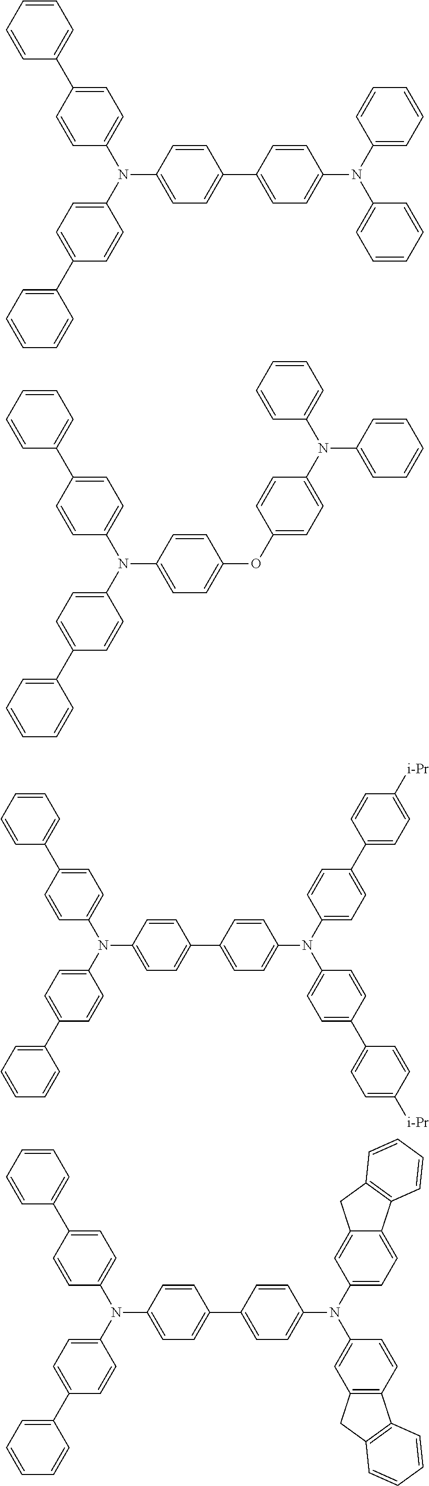

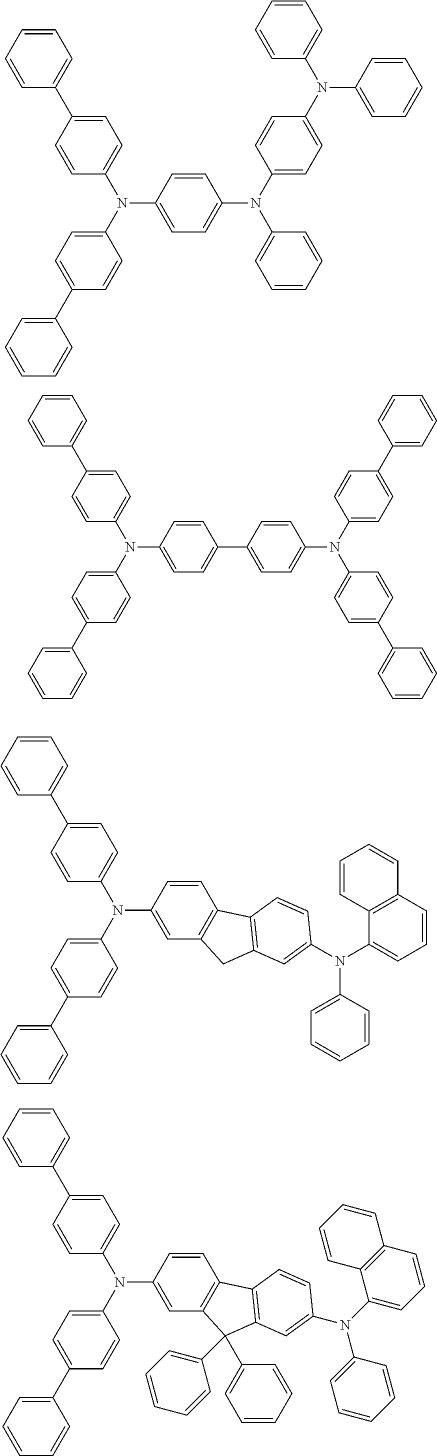

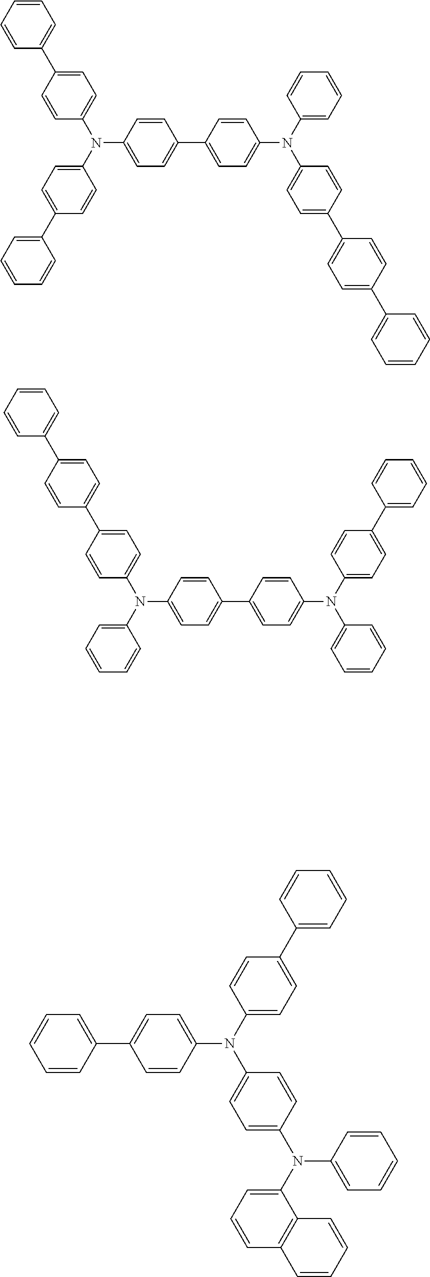 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccccc4)c4ccc(-c5ccc(N(c6ccccc6)c6ccc(-c7ccccc7)cc6)cc5)cc4)cc3)cc2)cc1 ; c1ccc(-c2ccc(N(c3ccc(-c4ccccc4)cc3)c3ccc(N(c4ccccc4)c4cccc5ccccc45)cc3)cc2)cc1]

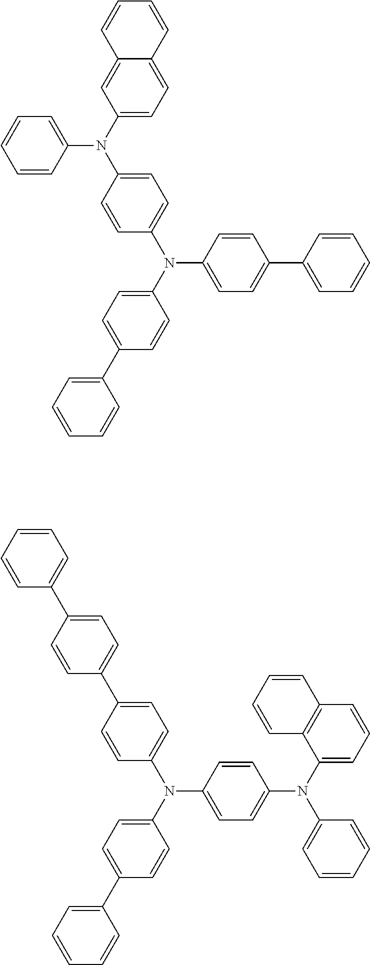 [SMILES: c1ccc(-c2ccc(N(c3ccc(-c4ccccc4)cc3)c3ccc(N(c4ccccc4)c4ccc5ccccc5c4)cc3)cc2)cc1 ; c1ccc(-c2ccc(-c3ccc(N(c4ccc(-c5ccccc5)cc4)c4ccc(N(c5ccccc5)c5cccc6ccccc56)cc4)cc3)cc2)cc1]

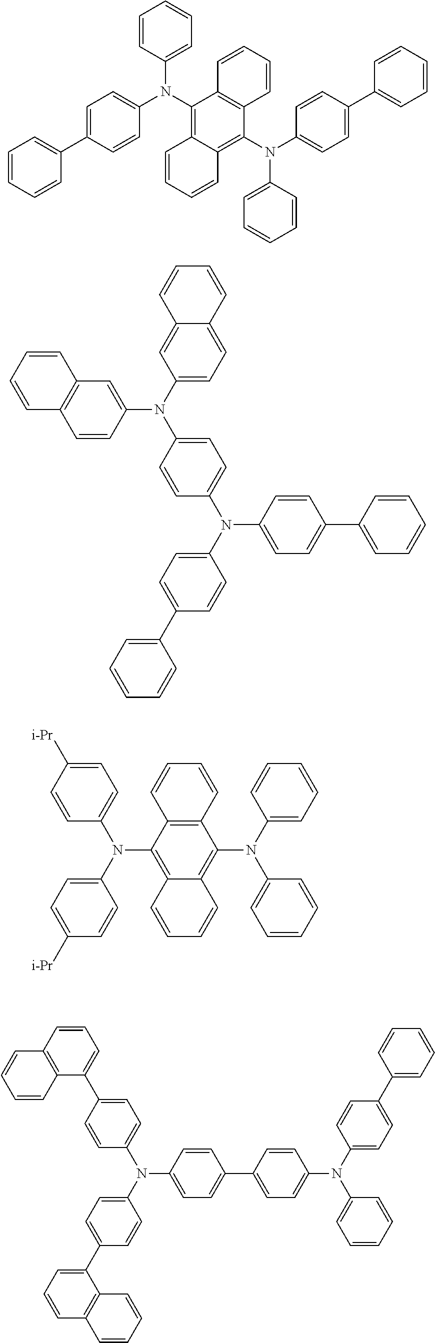 [SMILES: c1ccc(-c2ccc(N(c3ccccc3)c3c4ccccc4c(N(c4ccccc4)c4ccc(-c5ccccc5)cc4)c4ccccc34)cc2)cc1 ; c1ccc(-c2ccc(N(c3ccc(-c4ccccc4)cc3)c3ccc(N(c4ccc5ccccc5c4)c4ccc5ccccc5c4)cc3)cc2)cc1 ; CC(C)c1ccc(N(c2ccc(C(C)C)cc2)c2c3ccccc3c(N(c3ccccc3)c3ccccc3)c3ccccc23)cc1 ; c1ccc(-c2ccc(N(c3ccccc3)c3ccc(-c4ccc(N(c5ccc(-c6cccc7ccccc67)cc5)c5ccc(-c6cccc7ccccc67)cc5)cc4)cc3)cc2)cc1]

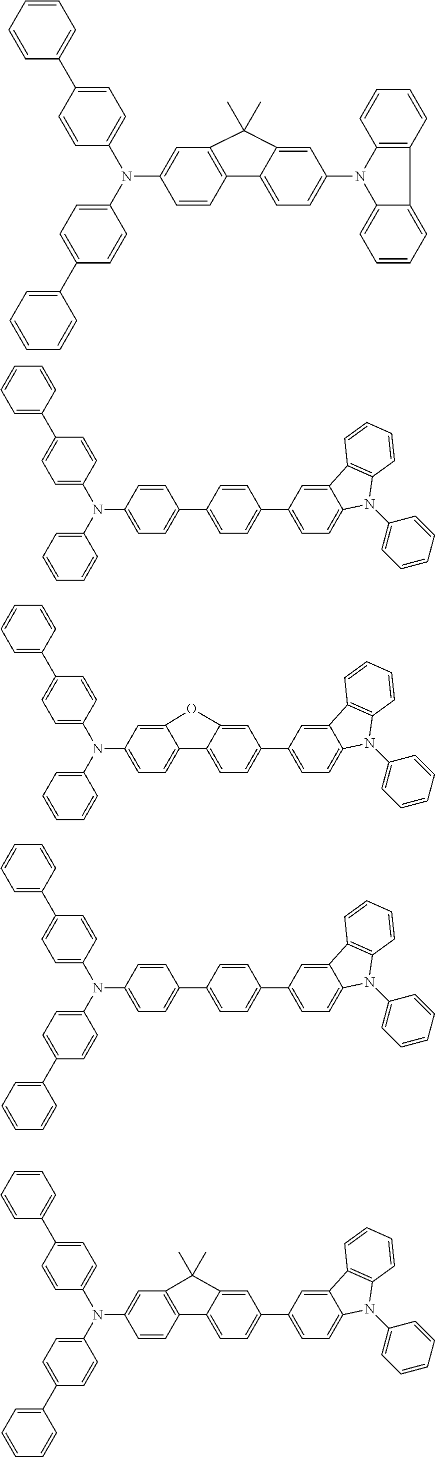

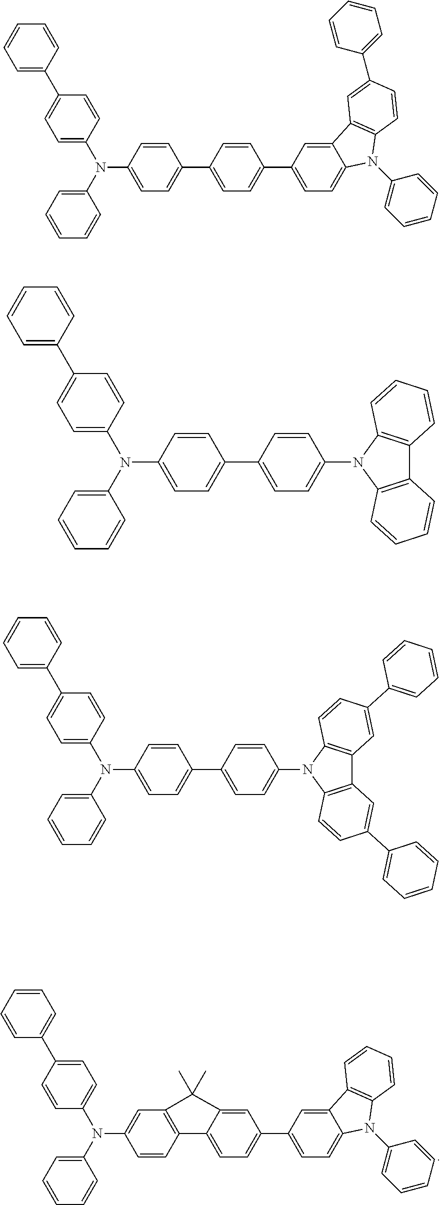 [SMILES: c1ccc(-c2ccc(N(c3ccccc3)c3ccc(-c4ccc(-c5ccc6c(c5)c5cc(-c7ccccc7)ccc5n6-c5ccccc5)cc4)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccccc3)c3ccc(-c4ccc(-n5c6ccc(-c7ccccc7)cc6c6cc(-c7ccccc7)ccc65)cc4)cc3)cc2)cc1 ; CC1(C)c2cc(-c3ccc4c(c3)c3ccccc3n4-c3ccccc3)ccc2-c2ccc(N(c3ccccc3)c3ccc(-c4ccccc4)cc3)cc21]

Aromatic amine represented by the following formula (A2) can also be preferably used for forming the hole injecting/transporting layer.

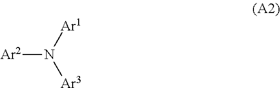

In the above formula (A2), Ar¹ to Ar³ each represent the same as Ar¹ to Ar⁴ of the above formula (A1). Examples of the compound represented by the formula (A2) are shown below. However, the compound represented by the formula (A2) is not limited thereto.

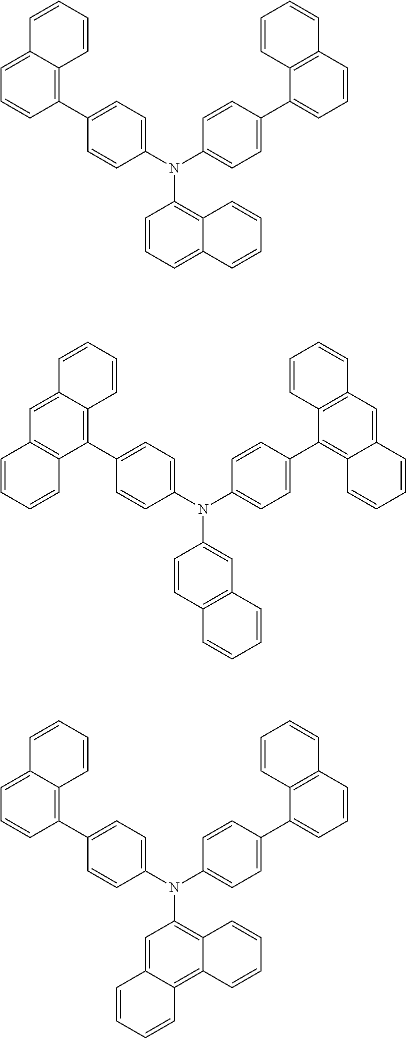 [SMILES: c1ccc2c(-c3ccc(N(c4ccc(-c5cccc6ccccc56)cc4)c4cccc5ccccc45)cc3)cccc2c1 ; c1ccc2cc(N(c3ccc(-c4c5ccccc5cc5ccccc45)cc3)c3ccc(-c4c5ccccc5cc5ccccc45)cc3)ccc2c1 ; c1ccc2c(-c3ccc(N(c4ccc(-c5cccc6ccccc56)cc4)c4cc5ccccc5c5ccccc45)cc3)cccc2c1]

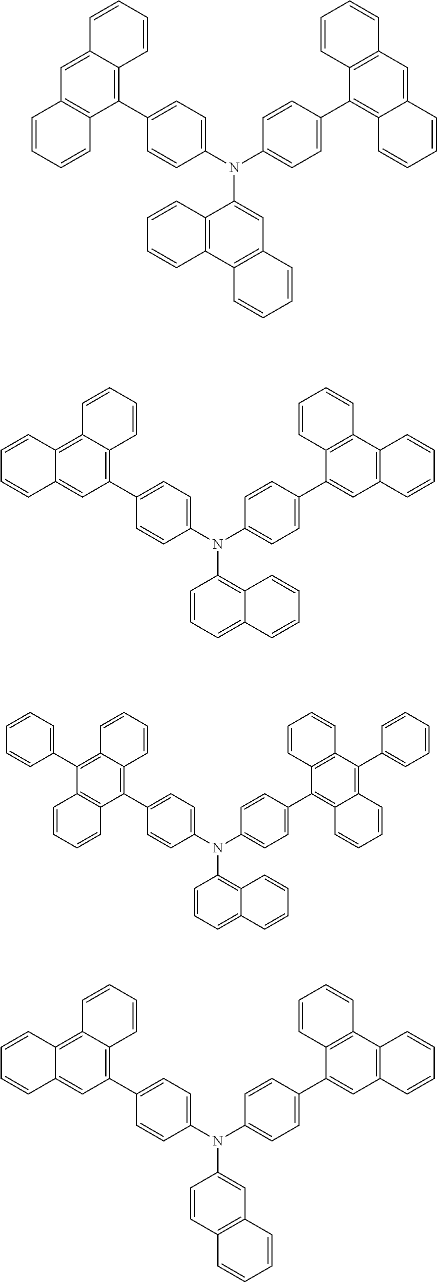 [SMILES: c1ccc2c(-c3ccc(N(c4ccc(-c5c6ccccc6cc6ccccc56)cc4)c4cc5ccccc5c5ccccc45)cc3)c3ccccc3cc2c1 ; c1ccc2c(N(c3ccc(-c4cc5ccccc5c5ccccc45)cc3)c3ccc(-c4cc5ccccc5c5ccccc45)cc3)cccc2c1 ; c1ccc(-c2c3ccccc3c(-c3ccc(N(c4ccc(-c5c6ccccc6c(-c6ccccc6)c6ccccc56)cc4)c4cccc5ccccc45)cc3)c3ccccc23)cc1 ; c1ccc2cc(N(c3ccc(-c4cc5ccccc5c5ccccc45)cc3)c3ccc(-c4cc5ccccc5c5ccccc45)cc3)ccc2c1]

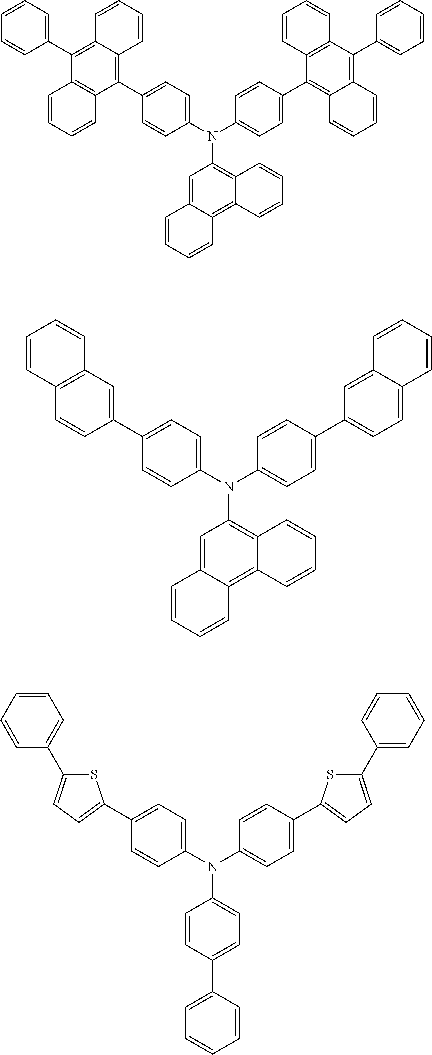 [SMILES: c1ccc(-c2c3ccccc3c(-c3ccc(N(c4ccc(-c5c6ccccc6c(-c6ccccc6)c6ccccc56)cc4)c4cc5ccccc5c5ccccc45)cc3)c3ccccc23)cc1 ; c1ccc2cc(-c3ccc(N(c4ccc(-c5ccc6ccccc6c5)cc4)c4cc5ccccc5c5ccccc45)cc3)ccc2c1 ; c1ccc(-c2ccc(N(c3ccc(-c4ccc(-c5ccccc5)s4)cc3)c3ccc(-c4ccc(-c5ccccc5)s4)cc3)cc2)cc1]

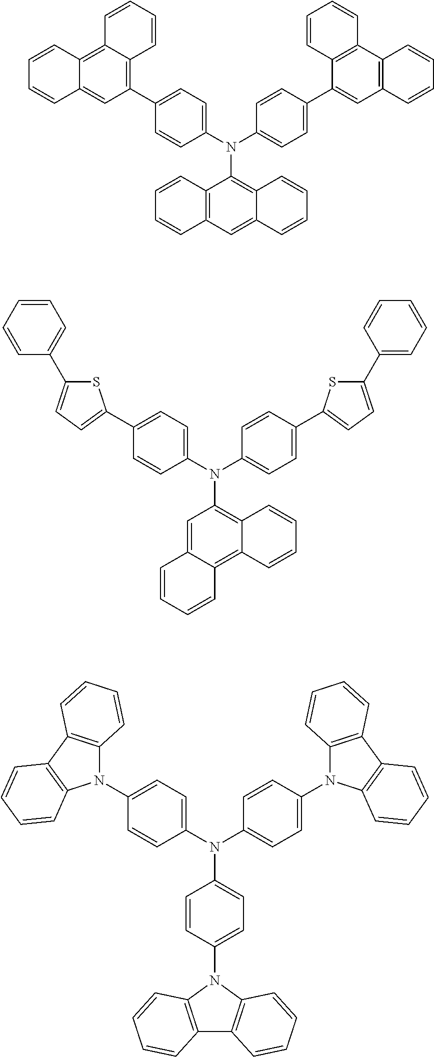 [SMILES: c1ccc2c(N(c3ccc(-c4cc5ccccc5c5ccccc45)cc3)c3ccc(-c4cc5ccccc5c5ccccc45)cc3)c3ccccc3cc2c1 ; c1ccc(-c2ccc(-c3ccc(N(c4ccc(-c5ccc(-c6ccccc6)s5)cc4)c4cc5ccccc5c5ccccc45)cc3)s2)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

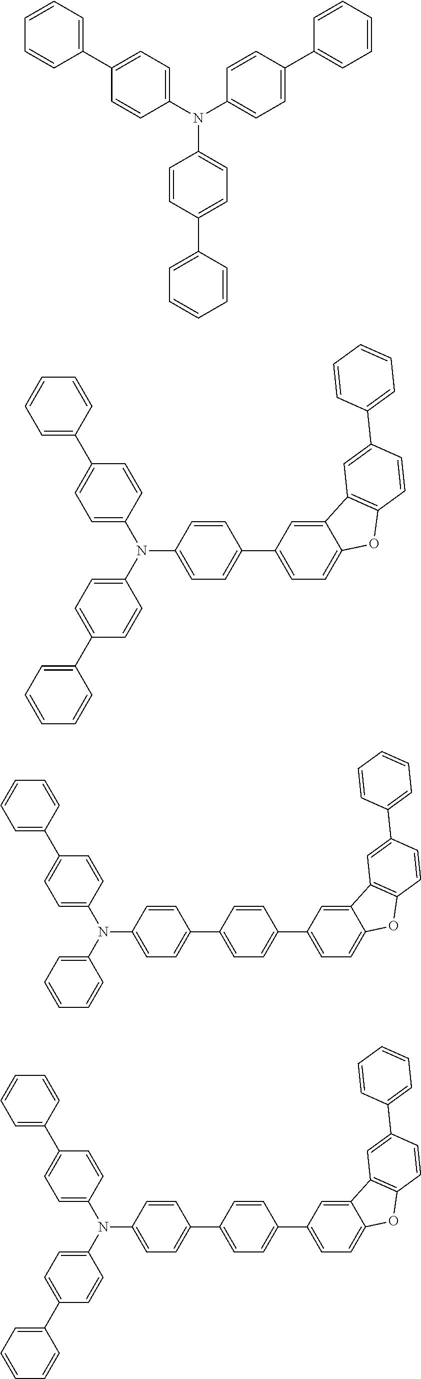 [SMILES: c1ccc(-c2ccc(N(c3ccc(-c4ccccc4)cc3)c3ccc(-c4ccccc4)cc3)cc2)cc1 ; c1ccc(-c2ccc(N(c3ccc(-c4ccccc4)cc3)c3ccc(-c4ccc5oc6ccc(-c7ccccc7)cc6c5c4)cc3)cc2)cc1 ; c1ccc(-c2ccc(N(c3ccccc3)c3ccc(-c4ccc(-c5ccc6oc7ccc(-c8ccccc8)cc7c6c5)cc4)cc3)cc2)cc1 ; c1ccc(-c2ccc(N(c3ccc(-c4ccccc4)cc3)c3ccc(-c4ccc(-c5ccc6oc7ccc(-c8ccccc8)cc7c6c5)cc4)cc3)cc2)cc1]

Although a film thickness of the hole transporting layer is not particularly limited, the film thickness is preferably 10 nm to 200 nm.

In the organic EL device according to the exemplary embodiment, a layer containing an acceptor material may be bonded to the side near the anode of the hole transporting layer or the first hole transporting layer. With this arrangement, reduction in the drive voltage and manufacturing costs is expected.

The acceptor material is preferably a compound represented by the following formula (K).

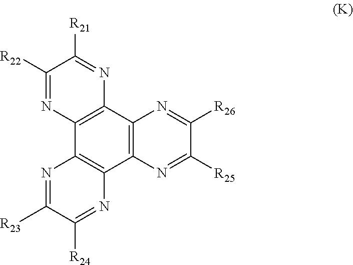

In the formula (K), R₂₁ to R₂₆ may be mutually the same or different and each independently represent a cyano group, —CONH₂, a carboxyl group or —COOR₂₇ in which R₂₇ represents an alkyl group having 1 to 20 carbon atoms or a cycloalkyl, group having 3 to 30 carbon atoms. Among a pair of R₂₁ and R₂₂, a pair of R₂₃ and R₂₄ and a pair of R₂₅ and R₂₆, one or more of the pairs may be combined to form a group represented by —CO—O—CO—.

Examples of R₂₇ include a methyl group, ethyl group, n-propyl group, isopropyl group, n-butyl group, isobutyl group, t-butyl group, cyclopentyl group and cyclohexyl group.

Although a film thickness of the acceptor material is not particularly limited, the film thickness is preferably 5 nm to 20 nm.

### Electron Injecting/Transporting Layer

The electron injection/transport layer helps injection of the electron to the luminescent layer and has a high electron mobility. The electron injecting layer is provided for adjusting energy level, by which, for instance, sudden changes of the energy level can be reduced. The electron injection/transport layer includes at least one of the electron injecting layer and the electron transporting layer.

The organic EL device according to this exemplary embodiment preferably includes the electron injecting layer between the emitting layer and the cathode, and the electron injecting layer preferably contains a nitrogen-containing cyclic derivative as a main component. The electron injecting layer may serve as the electron transporting layer.

Noted that “as a main component” means that the nitrogen-containing cyclic derivative is contained in the electron injecting layer at a content of 50 mass % or more.

The electron transporting material for forming the electron injecting layer is preferably exemplified by an aromatic heterocyclic compound having at least one heteroatom in a molecule, among which a nitrogen-containing cyclic derivative is particularly preferable. The nitrogen-containing cyclic derivative is preferably an aromatic cyclic compound having a nitrogen-containing six-membered or five-membered skeleton or a fused aromatic cyclic compound having a nitrogen-containing six-membered or five-membered skeleton.

The nitrogen-containing cyclic derivative is preferably exemplified by a nitrogen-containing cyclic metal chelate complex represented by the following formula (B1).

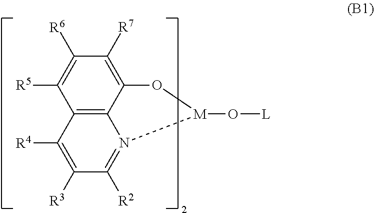

R² to R⁷ in the formula (B1) each independently represent a hydrogen atom, halogen atom, oxy group, amino group, hydrocarbon group having 1 to 40 carbon atoms, alkoxy group having 1 to 40 carbon atoms, aryloxy group having 1 to 40 carbon atoms, alkoxycarbonyl group having 1 to 40 carbon atoms, or aromatic heterocyclic group having 1 to 40 carbon atoms. These groups may have a substituent.

Examples of the halogen atom are fluorine, chlorine, bromine and iodine. Examples of a substituted or unsubstituted amino group are an alkylamino group, an arylamino group and an aralkylamino group.

The alkoxycarbonyl group is represented by —COOY′. Examples of Y′ are the same as the examples of the alkyl group. The alkylamino group and the aralkylamino group are represented by —NQ¹Q². Examples for each of Q¹ and Q² are the same as the examples described in relation to the alkyl group and the aralkyl group, and preferable examples for each of Q¹ and Q² are also the same as those described in relation to the alkyl group and the aralkyl group. One of Q¹ and Q² may be a hydrogen atom. Note that the aralkyl group is a group obtained by substituting the hydrogen atom of the alkyl group with the aryl group.

The arylamino group is represented by —NAr¹Ar². Examples for each of Ar¹ and Ar² are the same as the examples described in relation to the non-fused aromatic hydrocarbon group and the fused aromatic hydrocarbon group. One of Ar¹ and Ar² may be a hydrogen atom.

M represents aluminum (Al), gallium (Ga) or indium (In), among which In is preferable.

L in the formula (B1) represents a group represented by a formula (B2) or (B3) below.

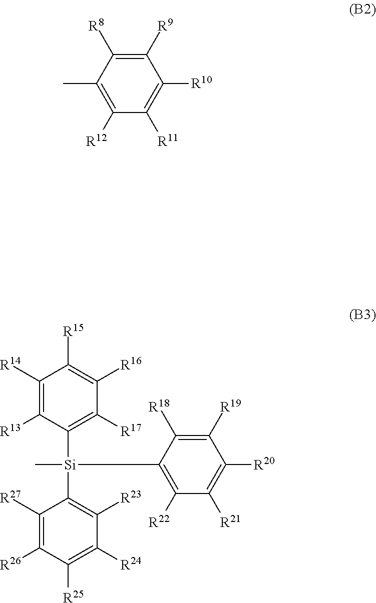

In the formula (B2), R⁸ to R¹² each independently represent a hydrogen atom or a hydrocarbon group having 1 to 40 carbon atoms. Adjacent groups may form a cyclic structure. The hydrocarbon group may have a substituent.

In the formula (B3), R¹³ to R²⁷ each independently represent a hydrogen atom or a hydrocarbon group having 1 to 40 carbon atoms. Adjacent groups may form a cyclic structure. The hydrocarbon group may have a substituent.

Examples of the hydrocarbon group having 1 to 40 carbon atoms represented by each of R⁸ to R¹² and R¹³ to R²⁷ in the formulae (B2) and (B3) are the same as those of R² to R⁷ in the formula (B1).

Examples of a divalent group formed when adjacent groups of R⁸ to R¹² and adjacent groups of R¹³ to R²⁷ form a cyclic structure are a tetramethylene group, pentamethylene group, hexamethylene group, diphenylmethane-2,2′-diyl group, diphenylethane-3,3′-diyl group and diphenylpropane-4,4′-diyl group.

The electron transporting layer preferably contains at least one of nitrogen-containing heterocyclic derivatives respectively represented by the following formulae (B4) to (B6).

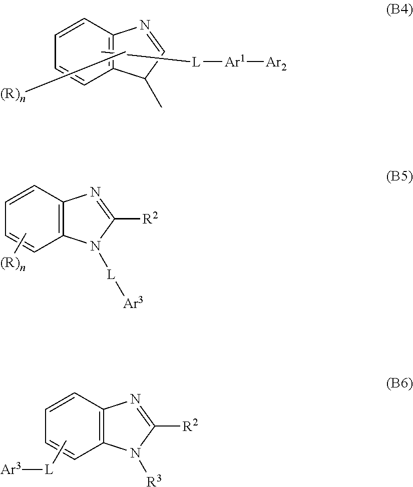

In the formulae (B4) to (B6), R represents a hydrogen atom, an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

n is an integer in a range of 0 to 4.

In the formulae (B4) to (B6), R¹ represents an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

In the formulae (B4) to (B6), R² and R³ independently represent a hydrogen atom, an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

In the formulae (B4) to (B6), L represents an aromatic hydrocarbon group having 6 to 60 ring carbon atoms, a fused aromatic hydrocarbon group having 6 to 60 ring carbon atoms, a pyridinylene group, a quinolinylene group, or a fluorenylene group.

In the formulae (B4) to (B6), Ar¹ represents an aromatic hydrocarbon group having 6 to 60 ring carbon atoms, a fused aromatic hydrocarbon group having 6 to 60 ring carbon atoms, a pyridinylene group, a quinolinylene group,

In the formulae (B4) to (B6), Ar² represents an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

In the formulae (B4) to (B6), Ar³ represents an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, an alkoxy group having 1 to 20 carbon atoms, or a group represented by —Ar¹-Ar² in which Ar¹ and Ar² represent the same as the above.

The fused aromatic hydrocarbon group, pyridyl group, quinolyl group, alkyl group, alkoxy group, pyridinylene group, quinolinylene group and fluorenylene group which are described in relation to R, R¹, R², R³, L, Ar¹, Ar² and Ar³ in the formulae (B4) to (B6) may have a substituent.

As an electron transporting compound for the electron injecting layer or the electron transporting layer, 8-hydroxyquinoline or a metal complex of its derivative, an oxadiazole derivative and a nitrogen-containing heterocyclic derivative are preferable. An example of the 8-hydroxyquinoline or the metal complex of its derivative is a metal chelate oxinoid compound containing a chelate of oxine (typically 8-quinolinol or 8-hydroxyquinoline). For instance, tris(8-quinolinol) aluminum can be used. Examples of the oxadiazole derivative are as follows.

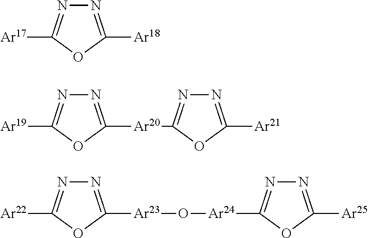

In each of the formulae of the oxadiazole derivatives, Ar¹⁷, Ar¹⁸, Ar¹⁹, Ar²¹, Ar²² and Ar²⁵ represent an aromatic hydrocarbon group having 6 to 40 ring carbon atoms or a fused aromatic hydrocarbon group having 6 to 40 ring carbon atoms.

It should be noted that the aromatic hydrocarbon group and the fused aromatic hydrocarbon group described herein may have a substituent. Ar¹⁷ and Ar¹⁸, Ar¹⁹ and Ar²¹, and Ar²² and Ar²⁵ may be the same or different.

Examples of the aromatic hydrocarbon group and the fused aromatic hydrocarbon group described herein are a phenyl group, naphthyl group, biphenyl group, anthranyl group, perylenyl group and pyrenyl group. Examples of the substituent therefor are an alkyl group having 1 to 10 carbon atoms, alkoxy group having 1 to 10 carbon atoms and cyano group.

In each of the formulae of the oxadiazole derivatives, Ar²⁰, Ar²³ and Ar²⁴ represent a divalent aromatic hydrocarbon group having 6 to 40 ring carbon atoms or a divalent fused aromatic hydrocarbon group having 6 to 40 ring carbon atoms.

It should be noted that the aromatic hydrocarbon group and the fused aromatic hydrocarbon group described herein may have a substituent.

Ar²³ and Ar²⁴ may be mutually the same or different.

Examples of the divalent aromatic hydrocarbon group or the divalent fused aromatic hydrocarbon group described herein are a phenylene group, naphthylene group, biphenylene group, anthranylene group, perylenylene group and pyrenylene group. Examples of the substituent therefor are an alkyl group having 1 to 10 carbon atoms, alkoxy group having 1 to 10 carbon atoms and cyano group.

Such an electron transport compound is preferably an electron transport compound that can be favorably formed into a thin film(s). Examples of the electron transport compounds are as follows.

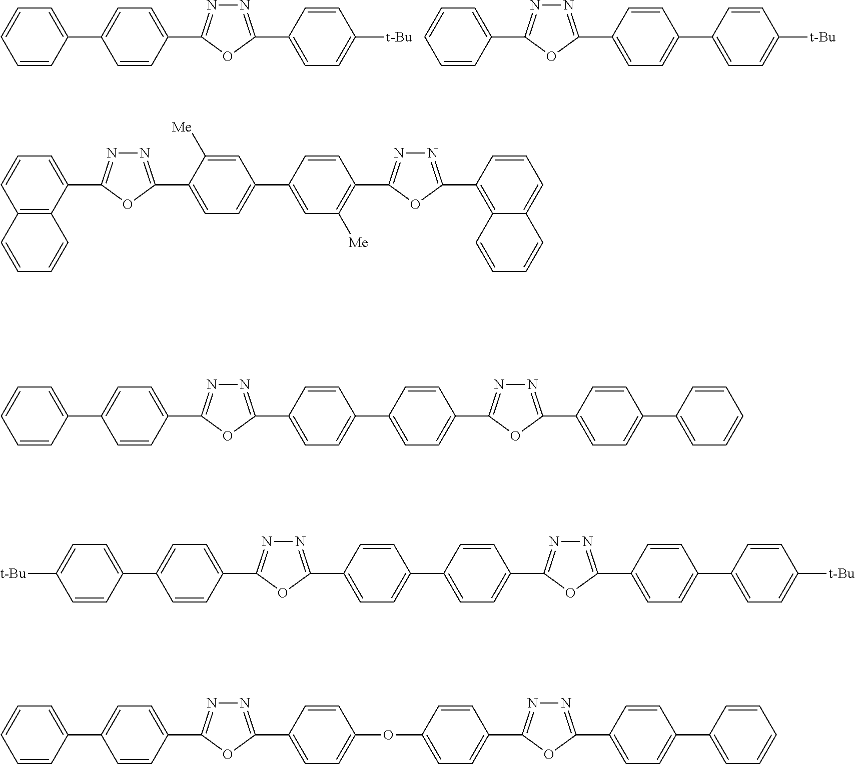

An example of the nitrogen-containing heterocyclic derivative as the electron transporting compound is a nitrogen-containing compound that is not a metal complex, the derivative being formed of an organic compound represented by one of the following general formulae. Examples of the nitrogen-containing compound are a nitrogen-containing compound having five-membered ring or six-membered ring with a skeleton represented by the following formula (B7) and a nitrogen-containing compound having a structure represented by the following formula (B8).

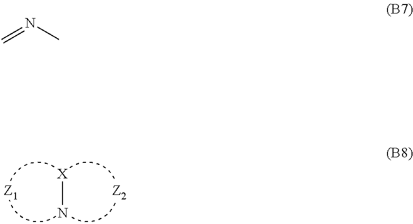

In the formula (B8), X represents a carbon atom or a nitrogen atom. Z₁ and Z₂ each independently represent an atom group from which a nitrogen-containing heterocycle can be formed.

Preferably, the nitrogen-containing heterocyclic derivative is an organic compound having a nitrogen-containing aromatic polycyclic group having a five-membered ring or six-membered ring. Further, in the organic compound having the nitrogen-containing aromatic polycyclic group having plural nitrogen atoms, a nitrogen-containing aromatic polycyclic organic compound having a skeleton formed by a combination of the skeletons respectively represented by the formulae (B7) and (B8), or by a combination of the skeletons respectively represented by the formula (B7) and the following formula (B9) is preferable.

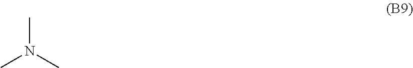

A nitrogen-containing group of the nitrogen-containing aromatic polycyclic organic compound is selected from nitrogen-containing heterocyclic groups respectively represented by the following formulae.

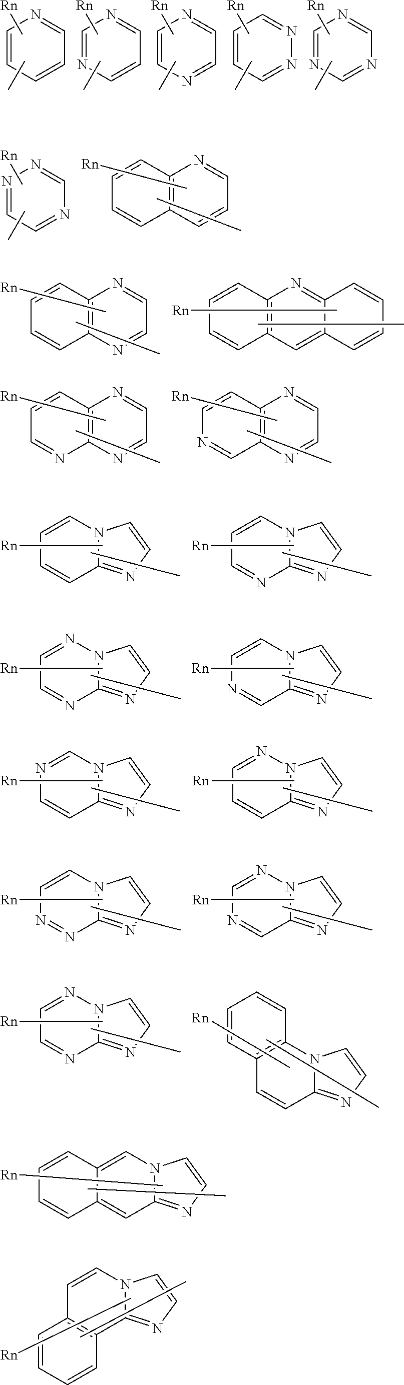

In each of the formulae of the nitrogen-containing heterocyclic groups, R represents an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, a fused aromatic heterocyclic group having 2 to 40 ring carbon atoms, an alkyl group having 1 to 20 carbon atoms, or an alkoxy group having 1 to 20 carbon atoms.

In each of the formulae of the nitrogen-containing heterocyclic groups, n is an integer of 0 to 5. When n is 2 or more, a plurality of R may be mutually the same or different.

A preferable specific compound is a nitrogen-containing heterocyclic derivative represented by the following formula (B10).

HAr-L′-Ar¹-Ar² (B10)

In the above formula (B 10), HAr is a nitrogen-containing heterocyclic group having 1 to 40 ring carbon atoms.

In the formula (B10), L¹ is a single bond, an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, or a fused aromatic heterocyclic group having 2 to 40 ring carbon atoms.

In the formula (B10), Ar¹ is a divalent aromatic hydrocarbon group having 6 to 40 ring carbon atoms.

In the formula (B10), Ar² is an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, or a fused aromatic heterocyclic group having 2 to 40 ring carbon atoms.

The nitrogen-containing heterocyclic group, aromatic hydrocarbon group, fused aromatic hydrocarbon group, aromatic heterocyclic group and fused aromatic heterocyclic group described in relation to HAr, L¹, Ar¹ and Ar² in the formula (B 10) may have a substituent.

HAr in the formula (B10) is exemplarily selected from the following group.

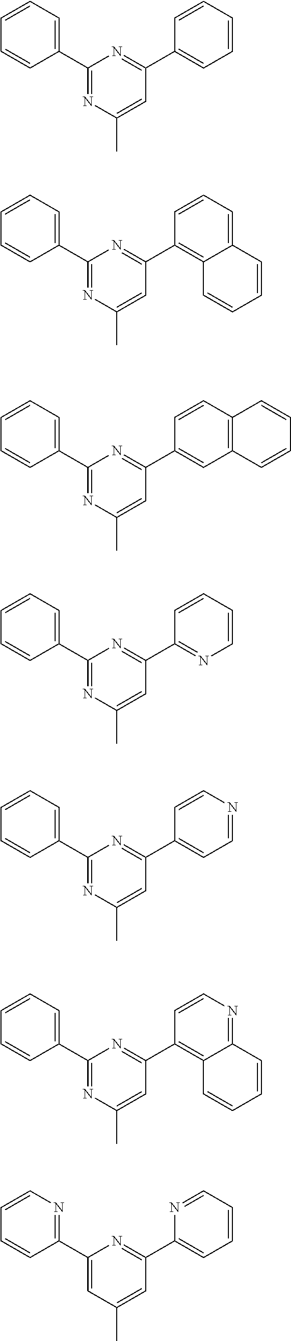

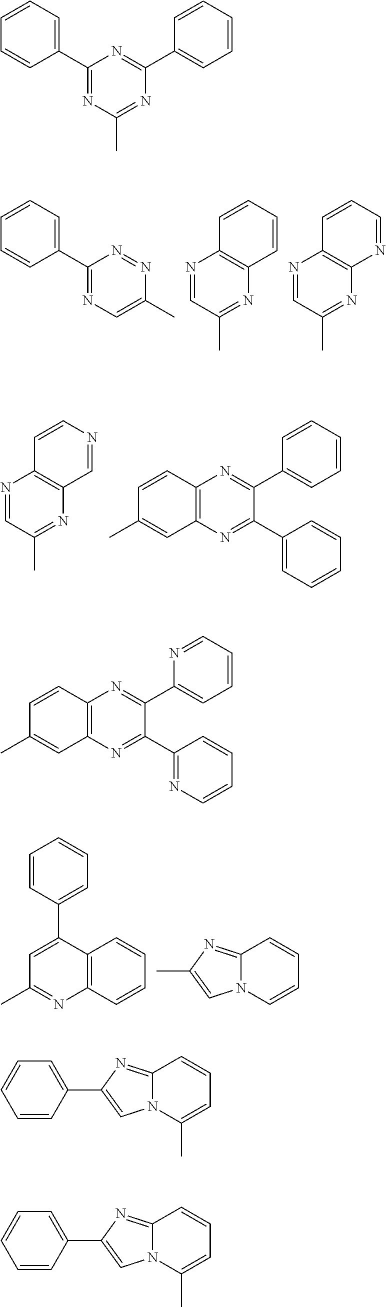

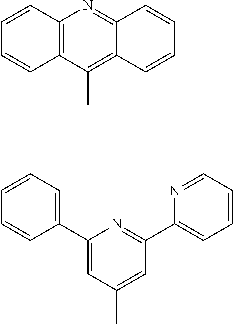 [SMILES: Cc1c2ccccc2nc2ccccc12 ; Cc1cc(-c2ccccc2)nc(-c2ccccn2)c1]

L¹ in the formula (B10) is exemplarily selected from the following group.

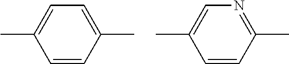

Ar¹ in the formula (B10) is exemplarily selected from the following arylanthranyl group.

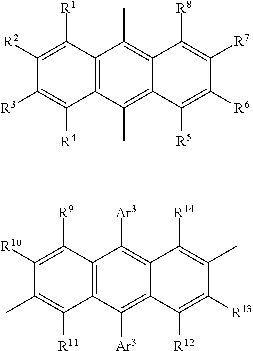

In the formula of the arylanthranyl group, R¹ to R¹⁴ each independently represent a hydrogen atom, halogen atom, alkyl group having 1 to 20 carbon atoms, alkoxy group having 1 to 20 carbon atoms, aryloxy group having 6 to 40 ring carbon atoms, aromatic hydrocarbon group having 6 to 40 ring carbon atoms, fused aromatic hydrocarbon group having 6 to 40 ring carbon atoms, aromatic heterocyclic group having 2 to 40 ring carbon atoms or fused aromatic heterocyclic group having 2 to 40 ring carbon atoms.

In the formula of the arylanthranyl group, Ar³ is an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, or a fused aromatic heterocyclic group having 2 to 40 ring carbon atoms.

The aromatic hydrocarbon group, fused aromatic hydrocarbon group, aromatic heterocyclic group and fused aromatic heterocyclic group described in relation to R¹ to R¹⁴ and Ar³ in the formula of the arylanthranyl may have a substituent.

All of R¹ to R⁸ of a nitrogen-containing heterocyclic derivative may be hydrogen atoms.

In the formula of the arylanthranyl group, Ar² is exemplarily selected from the following group.

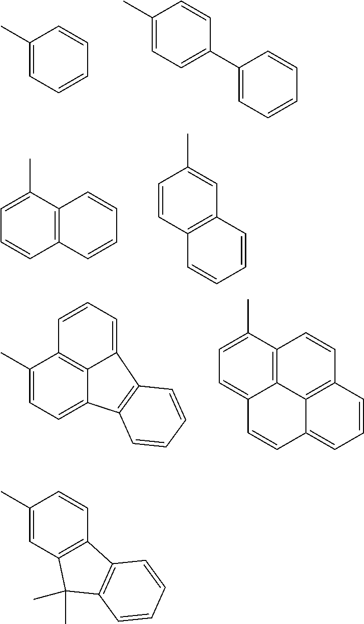

Other than the above, the following compound (see JP-A-9-3448) can be favorably used for the nitrogen-containing aromatic polycyclic organic compound as the electron transporting compound.

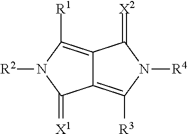

In the formula of the nitrogen-containing aromatic polycyclic organic compound, R¹ to R⁴ independently represent a hydrogen atom, aliphatic group, alicyclic group, carbocyclic aromatic cyclic group or heterocyclic group. Note that the aliphatic group, alicyclic group, carbocyclic aromatic cyclic group and heterocyclic group described herein may have a substituent.

In the formula of the nitrogen-containing aromatic polycyclic organic compound, X¹ and X² independently represent an oxygen atom, sulfur atom or dicyanomethylene group.

The following compound (see JP-A-2000-173774) can also be favorably used for the electron transporting compound.

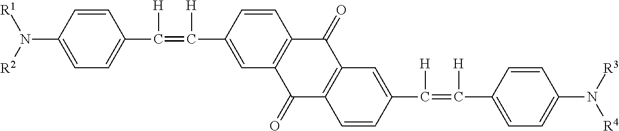

In the formula, R′, R², R³ and R⁴, which may be mutually the same or different, each represent an aromatic hydrocarbon group or fused aromatic hydrocarbon group represented by the following formula.

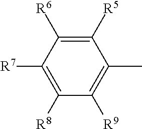

In the formula, R⁵, R⁶, R⁷, R⁸ and R⁹, which may be mutually the same or different, each represent a hydrogen atom, a saturated or unsaturated alkoxyl group, alkyl group, amino group or alkylamino group. At least one of R⁵, R⁶, R⁷, R⁸ and R⁹ represents a saturated or unsaturated alkoxyl group, alkyl group, amino group or alkylamino group.

A polymer compound containing the nitrogen-containing heterocyclic group or a nitrogen-containing heterocyclic derivative may be used for the electron transporting compound.

Although a thickness of the electron injecting layer or the electron transporting layer is not specifically limited, the thickness is preferably in a range of 1 nm to 100 nm.

The electron injecting layer preferably contains an inorganic compound such as an insulator or a semiconductor in addition to the nitrogen-containing cyclic derivative. Such an insulator or a semiconductor, when contained in the electron injecting layer, can effectively prevent a current leak, thereby enhancing electron injectability of the electron injecting layer.

For such an insulator, at least one metal compound selected from a group of alkali metal chalcogenide, alkaline-earth metal chalcogenide, halogenide of alkali metal, and halogenide of alkaline-earth metal may preferably be utilized. A configuration in which the electron injecting layer is formed by these alkali metal chalcogenide and the like is advantageous in that the electron injecting property is further improved. Specifically, preferable examples of the alkali metal chalcogenide are lithium oxide (Li₂O), potassium oxide (K₂O), sodium sulfide (Na₂S), sodium selenide (Na₂Se) and sodium oxide (Na₂O). Preferable examples of the alkaline-earth metal chalcogenide are calcium oxide (CaO), barium oxide (BaO), strontium oxide (SrO), beryllium oxide (BeO), barium sulfide (BaS) and calcium selenide (CaSe). Preferable examples of the halogenide of the alkali metal are lithium fluoride (LiF), sodium fluoride (NaF), potassium fluoride (KF), lithium chloride (LiCl), potassium chloride (KCl) and sodium chloride (NaCl). Preferable examples of the halogenide of the alkaline-earth metal are fluorides such as calcium fluoride (CaF₂), barium fluoride (BaF₂), strontium fluoride (SrF₂), magnesium fluoride (MgF₂) and beryllium fluoride (BeF₂), and halogenides other than the fluorides.

Examples of the semiconductor are one of or a combination of two or more of an oxide, a nitride or an oxidized nitride containing at least one element selected from barium (Ba), calcium (Ca), strontium (Sr), ytterbium (Yb), aluminum (Al), gallium (Ga), indium (In), lithium (Li), sodium (Na), cadmium (Cd), magnesium (Mg), silicon (Si), tantalum (Ta), antimony (Sb) and zinc (Zn). An inorganic compound for forming the electron injecting layer is preferably a microcrystalline or amorphous insulative thin-film. When the electron injecting layer is formed of such an insulative thin-film, more uniform thin-film can be formed, thereby reducing pixel defects such as a dark spot. Examples of such an inorganic compound are the above-described alkali metal chalcogenide, alkaline-earth metal chalcogenide, halogenide of the alkali metal and halogenide of the alkaline-earth metal.

When the electron injecting layer contains such an insulator or a semiconductor, a thickness thereof is preferably in a range of approximately 0.1 nm to 15 nm. The electron injecting layer according to the invention may preferably contain the above-described reduction-causing dopant material.

### Electron-Donating Dopant and Organic Metal Complex

In the organic EL device according to this exemplary embodiment, at least one of an electron-donating dopant and an organic metal complex is preferably contained in an interfacial region between the cathode and the organic layer.

With this arrangement, the organic EL device can emit light with enhanced luminance intensity and have a longer lifetime.

The electron-donating dopant may be at least one selected from an alkali metal, an alkali metal compound, an alkaline-earth metal, an alkaline-earth metal compound, a rare-earth metal, a rare-earth metal compound and the like.

The organic metal complex may be at least one selected from an organic metal complex including an alkali metal, an organic metal complex including an alkaline-earth metal, an organic metal complex including a rare-earth metal and the like.

Examples of the alkali metal are lithium (Li) (work function: 2.93 eV), sodium (Na) (work function: 2.36 eV), potassium (K) (work function: 2.28 eV), rubidium (Rb) (work function: 2.16 eV) and cesium (Cs) (work function: 1.95 eV), which particularly preferably has a work function of 2.9 eV or less. Among the above, the reductive dopant is preferably K, Rb or Cs, more preferably Rb or Cs, the most preferably Cs.

Examples of the alkaline-earth metal are calcium (Ca) (work function: 2.9 eV), strontium (Sr) (work function: 2.0 to 2.5 eV), and barium (Ba) (work function: 2.52 eV), among which a substance having a work function of 2.9 eV or less is particularly preferable.

Examples of the rare-earth metal are scandium (Sc), yttrium (Y), cerium (Ce), terbium (Tb), and ytterbium (Yb), among which a substance having a work function of 2.9 eV or less is particularly preferable.

Since the above preferable metals have particularly high reducibility, addition of a relatively small amount of the metals to an electron injecting zone can enhance luminance intensity and lifetime of the organic EL device.

Examples of the alkali metal compound are an alkali oxide such as lithium oxide (Li₂O), cesium oxide (Cs₂O) and potassium oxide (K₂O), and an alkali halogenide such as sodium fluoride (NaF), cesium fluoride (CsF) and potassium fluoride (KF), among which lithium fluoride (LiF), lithium oxide (Li₂O) and sodium fluoride (NaF) are preferable.

Examples of the alkaline-earth metal compound are barium oxide (BaO), strontium oxide (SrO), calcium oxide (CaO) and a mixture thereof, i.e., barium strontium oxide (BaₓSr₁₋ₓ) (0<x<1), barium calcium oxide (BaₓCa₁₋ₓ) (0<x<1), among which BaO, SrO and CaO are preferable.

Examples of the rare earth metal compound are ytterbium fluoride (YbF₃), scandium fluoride (ScF₃), scandium oxide (ScO₃), yttrium oxide (Y₂O₃), cerium oxide (Ce₂O₃), gadolinium fluoride (GdF₃) and terbium fluoride (TbF₃), among which YbF₃, ScF₃, and TbF₃ are preferable.

The organic metal complex is not specifically limited as long as containing at least one metal ion of an alkali metal ion, an alkaline-earth metal ion and a rare earth metal ion. A ligand for each of the complexes is preferably quinolinol, benzoquinolinol, acridinol, phenanthridinol, hydroxyphenyl oxazole, hydroxyphenyl thiazole, hydroxydiaryl oxadiazole, hydroxydiaryl thiadiazole, hydroxyphenyl pyridine, hydroxyphenyl benzoimidazole, hydroxybenzo triazole, hydroxy fluborane, bipyridyl, phenanthroline, phthalocyanine, porphyrin, cyclopentadiene, β-diketones, azomethines, or a derivative thereof, but the ligand is not limited thereto.

The electron-donating dopant and the organic metal complex are added to preferably form a layer or an island pattern in the interfacial region. The layer of the electron-donating dopant or the island pattern of the organic metal complex is preferably formed by evaporating at least one of the electron-donating dopant and the organic metal complex by resistance heating evaporation while an emitting material for forming the interfacial region or an organic substance as an electron-injecting material are simultaneously evaporated, so that at least one of the electron-donating dopant and an organic metal complex reduction-causing dopant is dispersed in the organic substance. Dispersion concentration at which the electron-donating dopant is dispersed in the organic substance is a mole ratio (the organic substance to the electron-donating dopant or the organic metal complex) of 100:1 to 1:100, preferably 5:1 to 1:5.

When at least one of the electron-donating dopant and the organic metal complex forms a layer, the emitting material or the electron injecting material for forming the organic layer of the interfacial region is initially layered, and then, at least one of the electron-donating dopant and the organic metal complex is singularly evaporated thereon by resistance heating evaporation to preferably form a 0.1 nm- to 15 nm-thick layer.

When at least one of the electron-donating dopant and the organic metal complex forms an island pattern, the emitting material or the electron injecting material for forming the organic layer of the interfacial region is initially layered, and then, at least one of the electron-donating dopant is singularly evaporated thereon by resistance heating evaporation to preferably form a 0.05 nm- to 1 nm-thick island pattern.

A ratio of the main component to at least one of the electron-donating dopant and the organic metal complex in the organic EL device according to the exemplary embodiment is preferably a mole ratio (the main component to the electron-donating dopant or the organic metal complex) of 5:1 to 1:5, more preferably 2:1 to 1:2.

### Substrate

The organic EL device in the exemplary embodiment is prepared on a light-transmissive substrate. The light-transmissive plate, which supports the organic EL device, is preferably a flat and smooth substrate that transmits 50% or more of light in a visible region of 400 nm to 700 nm.

Specifically, the light-transmissive substrate is provided by a glass plate, a polymer plate and the like.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate, acryl, polyethylene terephthalate, polyether sulfide and polysulfone can be used.

### Anode and Cathode

The anode of the organic EL device is used for injecting holes into the hole injecting layer, the hole transporting layer or the emitting layer. It is effective that the anode has a work function of 4.5 eV or more.

Exemplary materials for the anode are alloys of indium-tin oxide (ITO), tin oxide (NESA), indium zinc oxide, gold, silver, platinum and copper.

The anode may be made by forming a thin film from these electrode materials through a method such as vapor deposition or sputtering.

When light emission from the emitting layer is to be extracted through the cathode as in the exemplary embodiment, the anode preferably transmits more than 10% of the light in the visible region. Sheet resistance of the anode is preferably several hundreds Ω/square or lower. Although depending on the material of the anode, thickness of the anode is typically in a range of 10 nm to 1 μm, and preferably in a range of 10 to 200 nm.

The cathode is preferably formed of a material with smaller work function in order to inject electrons into the electron injecting layer, the electron transporting layer and the emitting layer.

Although a material for the cathode is subject to no specific limitation, examples of the material are indium, aluminum, magnesium, alloy of magnesium and indium, alloy of magnesium and aluminum, alloy of aluminum and lithium, alloy of aluminum, scandium and lithium, alloy of magnesium and silver and the like.

Like the anode, the cathode may be made by forming a thin film from the above materials through a method such as vapor deposition or sputtering. In addition, the light may be emitted through the cathode. In addition, the light emission from the emitting layer may be extracted through the cathode. When light emission from the emitting layer is to be extracted through the cathode, the cathode preferably transmits more than 10% of the light in the visible region.

Sheet resistance of the cathode is preferably several hundreds Ω/square or lower.

Although depending on the material of the cathode, a thickness of the cathode is typically in a range of 10 nm to 1 μm, and preferably in a range of 50 nm to 200 nm.

### Formation Method of Each Layer of Organic EL Device

A method of forming each of the layers in the organic EL device according to the exemplary embodiment is not particularly limited. Conventionally-known methods such as vacuum deposition and spin coating may be employed for forming the layers. The organic layer containing the compound used in the organic EL device according to this exemplary embodiment can be formed by a conventional coating method such as vacuum deposition, molecular beam epitaxy (MBE method) and coating methods using a solution such as a dipping, spin coating, casting, bar coating, and roll coating.

### Thickness of Each Layer of Organic EL Device

A thickness of the emitting layer is preferably in the range of 5 nm to 50 nm, more preferably in the range of 7 nm to 50 nm and most preferably in the range of 10 nm to 50 nm. By forming the emitting layer at the film thickness of 5 nm or more, the emitting layer is easily formable and chromaticity is easily adjustable. By forming the emitting layer at the thickness of 50 nm or less, increase in the drive voltage is suppressible.

A thickness of the organic layer other than the emitting layer is not particularly limited, but is preferably in a typical range of several nm to 1 μm. When the thickness is provided in the above range, defects such as pin holes caused by an excessively thinned film can be avoided while increase in the drive voltage caused by an excessively thickened film can be suppressed to prevent deterioration of the efficiency.

### Second Exemplary Embodiment

An organic EL device according to a second exemplary embodiment is different from the organic EL device according to the first exemplary embodiment in the arrangement of the emitting layer. Specifically, the emitting layer of the organic EL device according to the second exemplary embodiment is arranged to include the first material (first host material) and the luminescent material (dopant material). However, unlike the organic EL device according to the first exemplary embodiment, the organic EL device according to the second exemplary embodiment does not necessarily require the second material.

The first host material contained in the emitting layer of the organic EL device according to the second exemplary embodiment is represented by the following formula (1-3X).

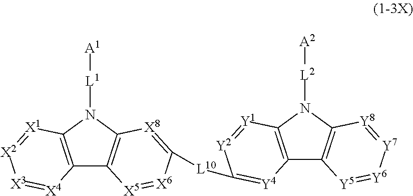

The formula (1-3X) represents the same as the formula (1-3).

The first organic layer is provided on the side near the anode of the emitting layer of the organic EL device according to the second exemplary embodiment. The first organic layer includes the second hole transporting layer adjacent to the side near the anode of the emitting layer and contains a compound represented by the following formula (4X). The formula (4X) represents the same as the formula (4).

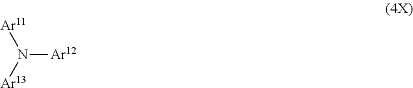

In the organic EL device according to the second exemplary embodiment, other layers can be provided in the same arrangement as in the first exemplary embodiment. In the second exemplary embodiment, the same materials and compounds as described in the first exemplary embodiment are usable.

The organic EL device according to the second exemplary embodiment can also improve the luminous efficiency.

### Modifications of Embodiment(s)

It should be noted that the invention is not limited to the above exemplary embodiment but may include any modification and improvement as long as such modification and improvement are compatible with the invention.

The emitting layer is not limited to a single layer, but may be provided as laminate by a plurality of emitting layers. When the organic EL device includes a plurality of emitting layers, it is only required that at least one of the emitting layers contains the luminescent material and the compound represented by the formula (1-1), and the hole transporting layer adjacent to the side near the anode of the at least one emitting layer contains the compound represented by the formula (4). The other emitting layers may be a fluorescent emitting layer or a phosphorescent emitting layer.

Moreover, when the organic EL device includes the plurality of emitting layers, the plurality of emitting layers may be adjacent to each other, or may be laminated through an intermediate layer to provide a so-called tandem-type organic EL device.

The organic EL device of the invention is suitably usable as a display device of TV, a mobile phone, a personal computer or the like, or an electronic device of an illuminator, an emission device of a vehicle light or the like.

### EXAMPLES

Next, the invention will be described in further detail by exemplifying Example(s) and Comparative(s). However, the invention is not limited by the description of Example(s).

Compounds used in Examples and Comparatives will be shown below.

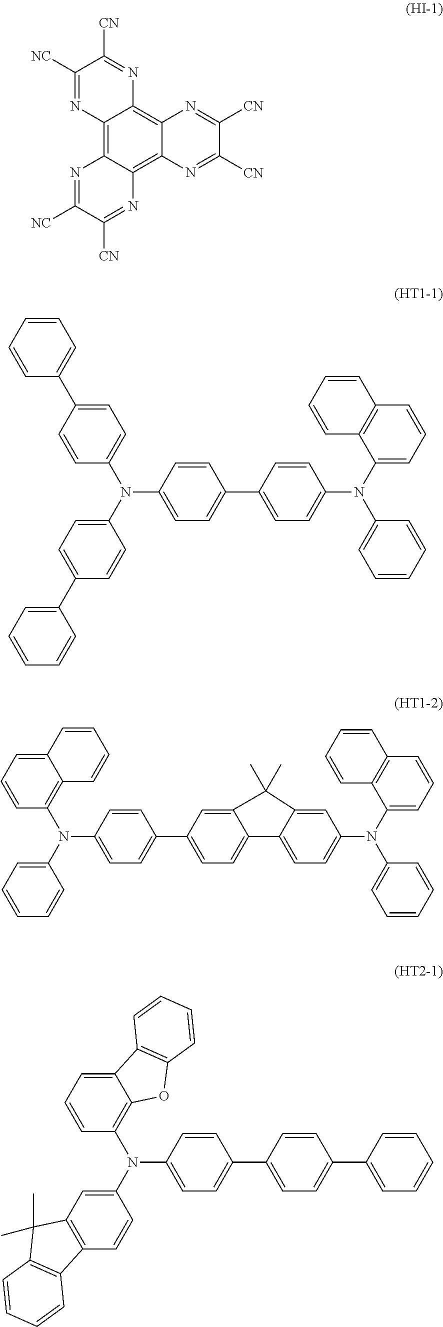 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccccc5)c5cccc6ccccc56)cc4)cc3)cc2)cc1 ; CC1(C)c2cc(-c3ccc(N(c4ccccc4)c4cccc5ccccc45)cc3)ccc2-c2ccc(N(c3ccccc3)c3cccc4ccccc34)cc21 ; CC1(C)c2ccccc2-c2ccc(N(c3ccc(-c4ccc(-c5ccccc5)cc4)cc3)c3cccc4c3oc3ccccc34)cc21]

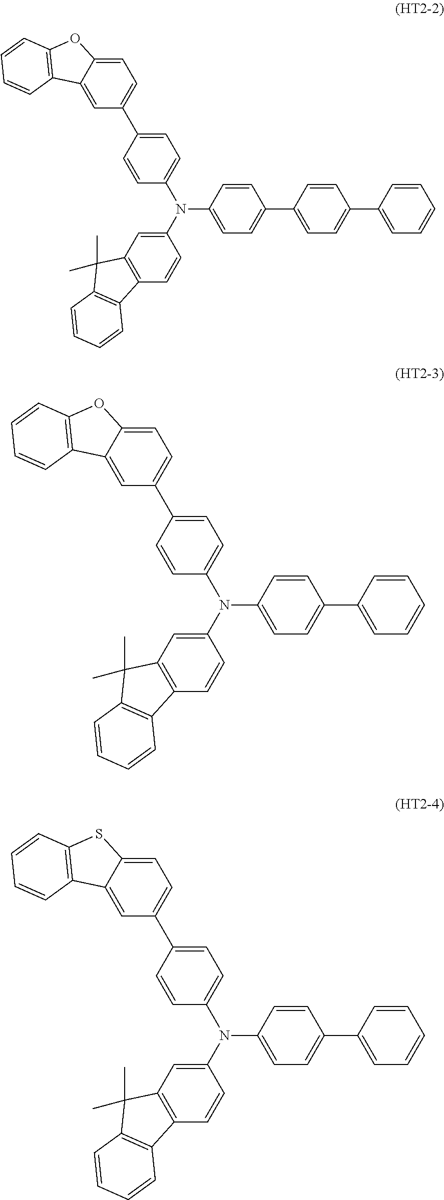 [SMILES: CC1(C)c2ccccc2-c2ccc(N(c3ccc(-c4ccc(-c5ccccc5)cc4)cc3)c3ccc(-c4ccc5oc6ccccc6c5c4)cc3)cc21 ; CC1(C)c2ccccc2-c2ccc(N(c3ccc(-c4ccccc4)cc3)c3ccc(-c4ccc5oc6ccccc6c5c4)cc3)cc21 ; CC1(C)c2ccccc2-c2ccc(N(c3ccc(-c4ccccc4)cc3)c3ccc(-c4ccc5sc6ccccc6c5c4)cc3)cc21]

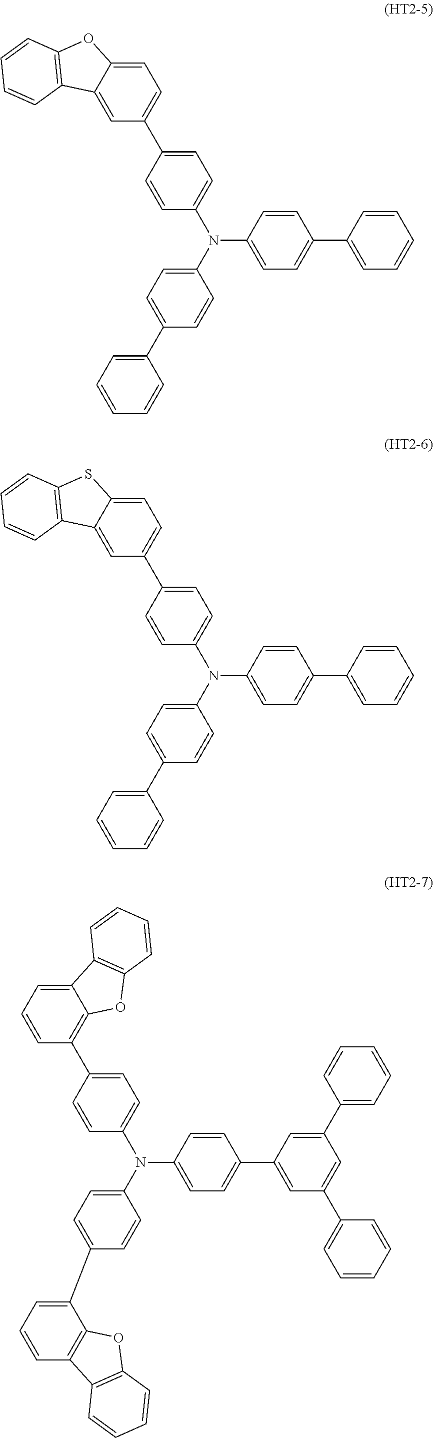 [SMILES: c1ccc(-c2ccc(N(c3ccc(-c4ccccc4)cc3)c3ccc(-c4ccc5oc6ccccc6c5c4)cc3)cc2)cc1 ; c1ccc(-c2ccc(N(c3ccc(-c4ccccc4)cc3)c3ccc(-c4ccc5sc6ccccc6c5c4)cc3)cc2)cc1 ; c1ccc(-c2cc(-c3ccccc3)cc(-c3ccc(N(c4ccc(-c5cccc6c5oc5ccccc56)cc4)c4ccc(-c5cccc6c5oc5ccccc56)cc4)cc3)c2)cc1]

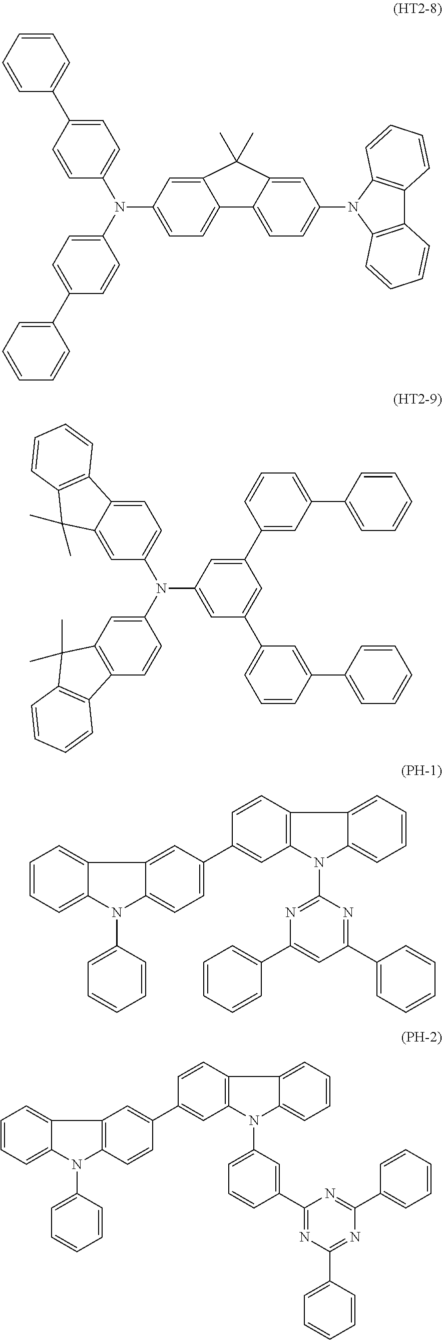

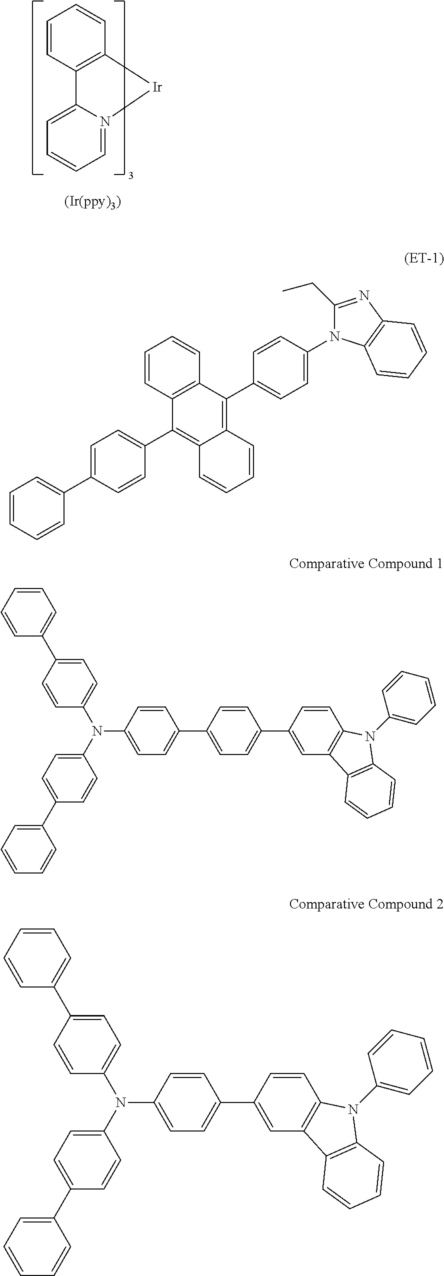

### Manufacture and Evaluation on Luminescent Performance of Organic EL Device

### Example 1

A glass substrate (size: 25 mm×75 mm×1.1 mm thick) having an ITO transparent electrode (manufactured by GEOMATEC Co., Ltd.) was ultrasonic-cleaned in isopropyl alcohol for five minutes, and then UV (Ultraviolet)/ozone-cleaned for 30 minutes.

After the glass substrate having the transparent electrode line was cleaned, the glass substrate was mounted on a substrate holder of a vacuum deposition apparatus. The following electron accepting (acceptor) compound (HI-1) was deposited to form a 5-nm thick film of the compound HI-1 on a surface of the glass substrate where the transparent electrode line was provided so as to cover the transparent electrode.

On the film of the compound HI-1, the aromatic amine derivative (compound HT1-1) was deposited as a first hole transporting material to form a 65-nm thick first hole transporting layer.

After film formation of the first hole transporting layer, the aromatic amine derivative (compound HT2-1) was deposited as a second hole transporting material to form a 10-nm thick second hole transporting layer.

Further, on the second hole transporting layer, the compound PH-1 as the first host material, the compound PH-2 as the second host material and the compound 1r(ppy)₃ as the phosphorescent dopant material were co-deposited to form a 25-nm thick emitting layer. In the emitting layer, concentrations of the compound 1r(ppy)₃, the first host material PH-1 and the second host material PH-2 were respectively 10.0 mass %, 45.0 mass % and 45.0 mass %. This co-deposited film serves as the emitting layer.

After the film formation of the emitting layer, a 35-nm thick film of the compound ET-1 was formed. The film of the compound ET-1 serves as the electron transporting layer.

Next, a 1-nm thick film of LiF was formed as an electron-injecting electrode (cathode) at a film-forming speed of 0.1 Å/min. A metal Al was deposited on the LiF film to form an 80-nm thick metal cathode.

Thus, an organic EL device of Example 1 was manufactured.

### Examples 2 to 10 and Comparatives 1 to 2

Organic EL devices of Examples 2 to 10 and Comparatives 1 to 2 were manufactured in the same manner as in the Example 1 except that the materials used for the first and second hole transporting layers were replaced as shown in Table 1.

TABLE 1

| | | First Hole | Second Hole |
|---|---|---|---|
| | | Transporting Layer | Transporting Layer |
| Example | 1 | HT1-1 | HT2-1 |
| | 2 | HT1-1 | HT2-2 |
| | 3 | HT1-1 | HT2-3 |
| | 4 | HT1-1 | HT2-4 |
| | 5 | HT1-1 | HT2-5 |
| | 6 | HT1-1 | HT2-6 |
| | 7 | HT1-1 | HT2-7 |
| | 8 | HT1-1 | HT2-8 |
| | 9 | HT1-1 | HT2-9 |
| | 10 | HT1-2 | HT2-1 |
| Comparative | 1 | HT1-1 | Comparative compound 1 |
| | 2 | HT1-1 | Comparative compound 2 |

### Evaluation of Organic EL Device

Light was emitted from the manufactured organic EL device by direct-current driving and a luminance intensity (L) and a current density were measured. An external quantum efficiency) EQE at the current density of 10 mA/cm² and a drive voltage were obtained. Further, a lifetime LT80 of the device at a current density of 50 mA/cm² was evaluated. The results are shown in Table 2.

### Drive Voltage

Electrical current was applied between the ITO transparent electrode and the metal cathode such that a current density was 10 mA/cm², where voltage (unit: V) was measured.

### External Quantum Efficiency EQE

Voltage was applied on each of the organic EL devices such that a current density was 10 mA/cm², where spectral radiance spectrum was measured by a spectroradiometer (CS-1000 manufactured by Konica Minolta Holdings, Inc.). The external quantum efficiency EQE (unit: %) was calculated based on the obtained spectral radiance spectrum, assuming that the spectra was provided under a Lambertian radiation.

### Lifetime LT80

A voltage was applied to the devices so that a current density became 50 mA/cm², where an elapsed time until a luminance intensity was reduced to 80% of an initial luminance intensity when each of the organic devices was driven at a constant current was obtained as a device lifetime LT80 (unit: hour).

TABLE 2

| | | Measurement Results | | |
|---|---|---|---|---|
| | | external quantum | | |
| | | efficiency EQE (%) | Drive Voltage (V) | |
| | | @10 mA/cm² | @10 mA/cm² | LT80 (hour) |
| Example | 1 | 17.5 | 3.2 | 150 |
| | 2 | 17.3 | 3.2 | 120 |
| | 3 | 17.6 | 3.3 | 90 |
| | 4 | 17.6 | 3.3 | 60 |
| | 5 | 18.7 | 3.3 | 90 |
| | 6 | 20.1 | 3.3 | 80 |
| | 7 | 18.5 | 3.5 | 100 |
| | 8 | 19.0 | 3.3 | 110 |
| | 9 | 17.7 | 3.3 | 70 |
| | 10 | 18.1 | 3.3 | 150 |
| Comparative | 1 | 16.1 | 3.3 | 120 |
| | 2 | 16.2 | 3.2 | 120 |

The organic EL devices of Examples 1 to 10 exhibited a higher luminous efficiency as compared with the organic EL devices of Comparatives 1 and 2.

### Examples 11 to 20 and Comparatives 3 to 4

Organic EL devices in Examples 11 to 20 and Comparatives 3 to 4 were manufactured in the same manner as those in Examples 1 to 10 and Comparatives 1 to 2 except that the first host material was replaced by the compound PH-2 and the second host material was replaced by the following compound PH-3 in the organic EL device in Examples 1 to 10 and Comparatives 1 to 2. Schematic arrangements of the hole transporting layer and the emitting layer are shown in Table 3.

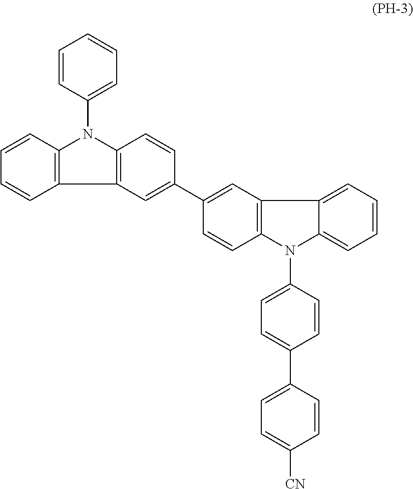 [SMILES: N#Cc1ccc(-c2ccc(-n3c4ccccc4c4cc(-c5ccc6c(c5)c5ccccc5n6-c5ccccc5)ccc43)cc2)cc1]

TABLE 3

| | | First Hole | Second Hole | Emitting Layer | |
|---|---|---|---|---|---|
| | | Transporting | Transporting | First Host | Second Host |
| | | Layer | Layer | Material | Material |
| Example | 11 | HT1-1 | HT2-1 | PH-2 | PH-3 |
| | 12 | HT1-1 | HT2-2 | PH-2 | PH-3 |
| | 13 | HT1-1 | HT2-3 | PH-2 | PH-3 |
| | 14 | HT1-1 | HT2-4 | PH-2 | PH-3 |
| | 15 | HT1-1 | HT2-5 | PH-2 | PH-3 |
| | 16 | HT1-1 | HT2-6 | PH-2 | PH-3 |
| | 17 | HT1-1 | HT2-7 | PH-2 | PH-3 |
| | 18 | HT1-1 | HT2-8 | PH-2 | PH-3 |
| | 19 | HT1-1 | HT2-9 | PH-2 | PH-3 |
| | 20 | HT1-2 | HT2-1 | PH-2 | PH-3 |
| Comparative | 3 | HT1-1 | Comparative | PH-2 | PH-3 |
| | | | compound 1 | | |
| | 4 | HT1-1 | Comparative | PH-2 | PH-3 |
| | | | compound 2 | | |

### Synthesis Example 1-1

### Synthesis of Compound PH-3

### Synthesis Example 1-1-1

### Synthesis of Intermediate 2-1

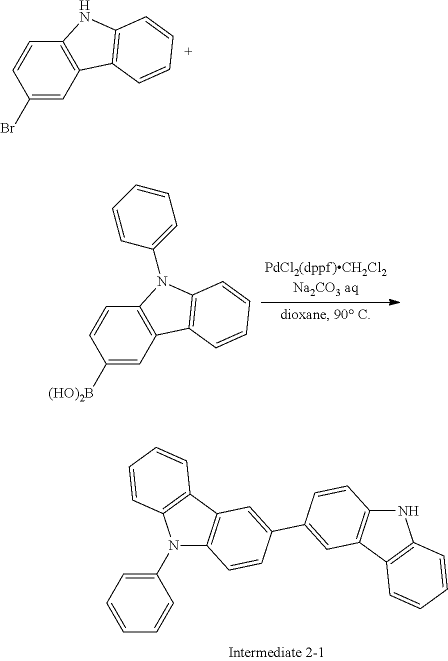 [SMILES: Brc1ccc2[nH]c3ccccc3c2c1 ; OB(O)c1ccc2c(c1)c1ccccc1n2-c1ccccc1 ; c1ccc(-n2c3ccccc3c3cc(-c4ccc5[nH]c6ccccc6c5c4)ccc32)cc1]

Under an argon gas stream, to a 2000-mL eggplant flask, 3-bromocarbazole (43 g, 174 mmol), 9-phenylcarbazole-3-ylboronic acid (50 g, 174 mmol), [1,1′-bix(diphenylphosphino)ferrocene]palladium(II) dichloride dichloromethane adduct (1.4 g, 1.7 mmol), dioxane (610 mL) and 2M sodium carbonate aqueous solution (260 mL) were sequentially added and heated to reflux for eight hours.

After the reaction solution was cooled down to the room temperature, an organic layer was removed and an organic solvent was evaporated under reduced pressure. The obtained residue was purified by silica-gel column chromatography, so that an intermediate 4 (43 g, a yield of 60%) was obtained. As a result of FD-MS (Field Desorption Mass Spectrometry) analysis, the product was identified as an intermediate 2-1.

### Synthesis Example 1-1-2

### Synthesis of Compound PH-3

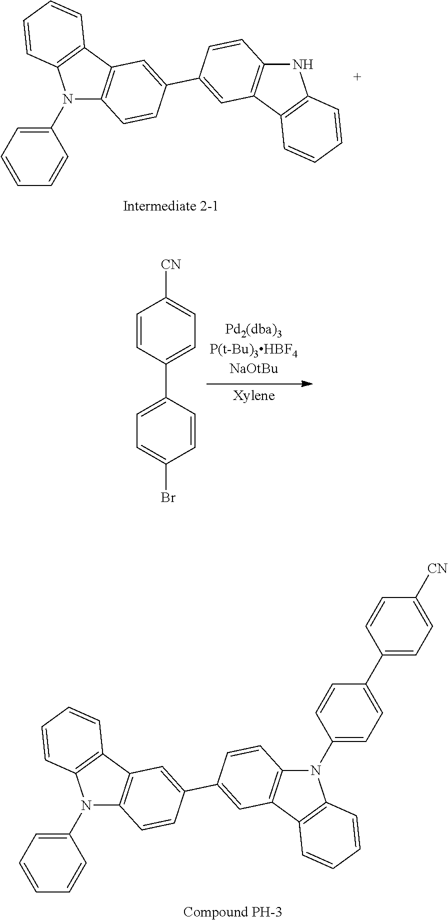 [SMILES: c1ccc(-n2c3ccccc3c3cc(-c4ccc5[nH]c6ccccc6c5c4)ccc32)cc1 ; N#Cc1ccc(-c2ccc(Br)cc2)cc1 ; N#Cc1ccc(-c2ccc(-n3c4ccccc4c4cc(-c5ccc6c(c5)c5ccccc5n6-c5ccccc5)ccc43)cc2)cc1]

Under an argon gas stream, to a 300-mL eggplant flask, the intermediate 2-1 (5.14 g, 12.6 mmol), 4′-bromobiphenyl-4-carbonitrile (3.90 g, 15.1 mmol), tris(dibenzylideneacetone)dipalladium (0.462 g, 0.505 mmol), tri-t-butylphosphonium tetrafluoroborate (0.470 g, 1.62 mmol), sodium t-butoxide (2.42 g, 25.2 mmol), and anhydrous xylene (25 mL) were sequentially added and heated to reflux for eight hours.

After the reaction solution was cooled down to the room temperature, an organic layer was removed and an organic solvent was evaporated under reduced pressure. The obtained residue was purified by silica-gel column chromatography, whereby 4.5 g of a white solid (PH-3) was obtained.

A result of FD-MS (Field Desorption Mass Spectrometry) of the obtained compound and a maximum ultraviolet absorption wavelength thereof in a toluene solution UV(PhMe; λmax) and a maximum fluorescent wavelength thereof in a toluene solution FL(PhMe, λex=310 nm; λmax) are shown below:

FDMS, calcd for C43H27N3=585, found m/z=585 (M+)

UV(PhMe); λmax, 340 nm

FL(PhMe, λex=310 nm); λmax, 424 nm

### Evaluation of Organic EL Device

The organic EL devices manufactured in Examples 11 to 20 and Comparatives 3 to 4 were measured in the same manner as the above in terms of the drive voltage, external quantum efficiency and lifetime. Measurement results are shown in Table 4.

TABLE 4

| | | Measurement Results | | |
|---|---|---|---|---|
| | | External Quantum | | |
| | | Efficiency EQE (%) | Drive Voltage (V) | |
| | | @10 mA/cm² | @10 mA/cm² | LT80 (hour) |
| Example | 11 | 17.8 | 3.4 | 170 |
| | 12 | 17.5 | 3.4 | 150 |
| | 13 | 17.9 | 3.5 | 120 |
| | 14 | 17.9 | 3.5 | 100 |
| | 15 | 19.0 | 3.5 | 120 |
| | 16 | 20.5 | 3.5 | 100 |
| | 17 | 19.0 | 3.5 | 130 |
| | 18 | 19.3 | 3.5 | 120 |
| | 19 | 18.0 | 3.5 | 90 |
| | 20 | 18.1 | 3.5 | 170 |
| Comparative | 3 | 16.5 | 3.5 | 140 |
| | 4 | 16.6 | 3.5 | 140 |

The organic EL devices of Examples 11 to 20 exhibited a higher luminous efficiency as compared with the organic EL devices of Comparatives 3 and 4.

### Example 21

An organic EL device in Example 21 was manufactured in the same manner as in Example 1 except that the compound HT2-1 in the second hole transporting layer was replaced by a compound HT2-7 and the compound PH-2 in the emitting layer was replaced by the following compound PH-4 in the organic EL device of Example 1.

A schematic device arrangement of the organic EL device in Example 21 is shown below.

ITO/HI-1(5)/HT-1(65)/HT2-7(10)/PH-4:PH-1:Ir(ppy)₃ (25, 45%:45%:10%)/ET-1(35)/LiF(1)/Al(80)

Note that numerals in parentheses represent a film thickness (unit: nm). Numerals expressed by percent in the same parentheses show a ratio (mass %) of an added component (e.g., the dopant material in the emitting layer). The same applies for the following schematic device arrangements of the organic EL devices.

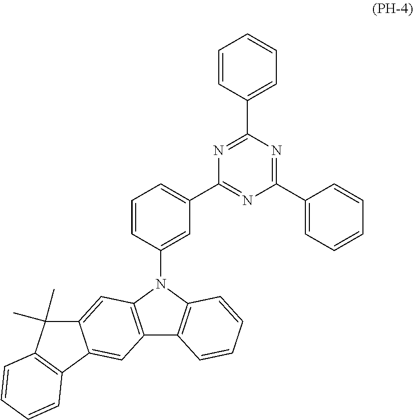 [SMILES: CC1(C)c2ccccc2-c2cc3c4ccccc4n(-c4cccc(-c5nc(-c6ccccc6)nc(-c6ccccc6)n5)c4)c3cc21]

### Comparative 5

An organic EL device in Comparative 5 was manufactured in the same manner as in Example 21 except that the compound HT2-7 in the second hole transporting layer was replaced by a comparative compound 2 in the organic EL device of Example 21.

A schematic device arrangement of the organic EL device in Comparative 5 is shown below.

ITO/HI-1(5)/HT-1(65)/Comparative Compound 2(10)/PH-4:PH-1:Ir(ppy)₃ (25, 45%:45%:10%)/ET-1(35)/LiF(1)/Al(80)

### Evaluation of Organic EL Device

The organic EL devices manufactured in Example 21 and Comparative 5 were measured in the same manner as the above in terms of the drive voltage, external quantum efficiency and lifetime. Measurement results are shown in Table 5.

TABLE 5

| | | Measurement Results | | |
|---|---|---|---|---|
| | | External Quantum | | LT80 (hour) |
| | | Efficiency EQE (%) | Drive Voltage (V) | Current |
| | | Current Density: | Current Density: | Density: |
| | | @10 mA/cm² | @10 mA/cm² | @50 mA/cm² |
| Example | 21 | 16.0 | 3.1 | 150 |
| Compara- | 5 | 14.0 | 3.0 | 120 |
| tive | | | | |

### Example 22

An organic EL device in Example 22 was manufactured in the same manner as in Example 1 except that the compound HT2-1 in the second hole transporting layer was replaced by a compound HT2-8 and the materials for the emitting layer were replaced in the organic EL device of Example 1. Specifically, the emitting layer of the organic EL device in Example 22 was formed by co-depositing the compound PH-2 and the compound 1r(ppy)₃. A film thickness of the emitting layer was 25 nm. In the emitting layer, a concentration of the compound 1r(ppy)₃ was 10.0 mass % and a concentration of the compound PH-2 was 90.0 mass %.

A schematic device arrangement of the organic EL device in Example 22 is shown below.

ITO/HI-1(5)/HT-1(65)/HT2-8(10)/PH-2:Ir(ppy)₃ (25, 90%:10%)/ET-1(35)/LiF(1)/Al(80)

### Example 23

An organic EL device in Example 23 was manufactured in the same manner as in Example 22 except that the compound HT2-8 in the second hole transporting layer was replaced by the following compound HT2-10 in the organic EL device of Example 22.

A schematic device arrangement of the organic EL device in Example 23 is shown below.

ITO/HI-1(5)/HT-1(65)/HT2-10(10)/PH-2:Ir(ppy)₃ (25, 90%:10%)/ET-1(35)/LiF(1)/Al(80)

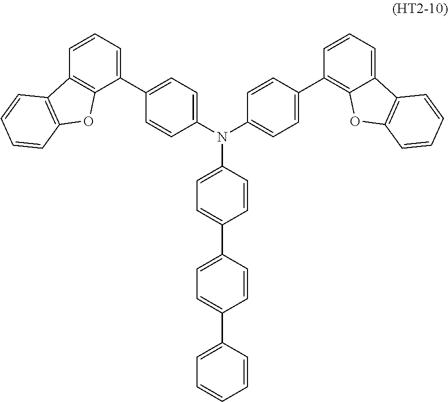 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

### Comparative 6

An organic EL device in Comparative 6 was manufactured in the same manner as in Example 22 except that the compound HT2-8 in the second hole transporting layer was replaced by the comparative compound 2 in the organic EL device of Example 22.

A schematic device arrangement of the organic EL device in Comparative 6 is shown below.

ITO/HI-1(5)/HT-1(65)/Comparative Compound 2(10)/PH-2:Ir(ppy)₃ (25, 90%:10%)/ET-1(35)/LiF(1)/Al(80)

### Evaluation of Organic EL Device

The organic EL devices manufactured in Examples 22, 23 and Comparative 6 were measured in the same manner as the above in terms of the drive voltage, external quantum efficiency and lifetime. Measurement results are shown in Table 6.

TABLE 6

| | | Measurement Results | | |
|---|---|---|---|---|
| | | External Quantum | | LT80 (hour) |
| | | Efficiency EQE (%) | Drive Voltage (V) | Current |
| | | Current Density: | Current Density: | Density: |
| | | @10 mA/cm² | @10 mA/cm² | @50 mA/cm² |
| Example | 22 | 17.0 | 3.1 | 150 |
| | 23 | 18.0 | 3.3 | 160 |
| Compara- | 6 | 16.0 | 3.2 | 120 |
| tive | | | | |

What is claimed is:

1. An organic electroluminescence device comprising:
an anode;
a cathode;
a first organic layer interposed between the anode and the cathode and comprising a compound represented by the following formula (4); and
an emitting layer interposed between the first organic layer and the cathode and comprising a first material represented by the following formula (1-1), a second material and a luminescent material, 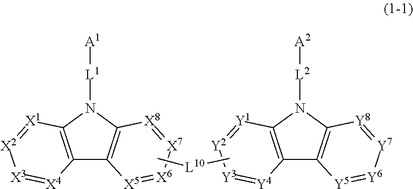
where:
A¹ and A² each independently represent a substituted or unsubstituted aromatic hydrocarbon group having 6 to 30 ring carbon atoms or a substituted or unsubstituted heterocyclic group having 5 to 30 ring atoms;
L¹, L² and L¹⁰ each independently represent a single bond, a substituted or unsubstituted divalent aromatic hydrocarbon group having 6 to 30 ring carbon atoms, or a substituted or unsubstituted divalent heterocyclic group having 5 to 30 ring atoms;
X¹ to X⁸ and Y¹ to Y⁸ each independently represent a nitrogen atom, CR^{a}, or a carbon atom to be bonded to L¹⁰, wherein
R^{a} each independently represents a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms;
when a plurality of R^{a} are present, the plurality of R^{a} are the same or different; and
one of X⁵ to X⁸ is bonded to one of Y¹ to Y⁴ through L¹⁰, 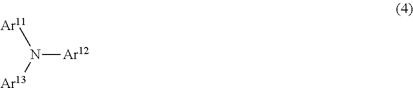
where:
Ar¹¹ to Ar¹³ represent a group represented by the following formula (4-2) or a substituted or unsubstituted aromatic hydrocarbon group having 6 to 40 carbon atoms; and at least one of Ar¹¹ to Ar¹³ is a group represented by the following formula (4-2), 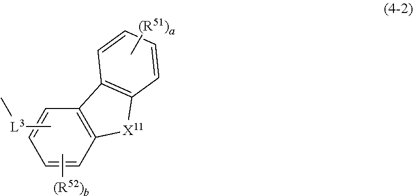
where:
X¹¹ represents CR⁵³R⁵⁴, an oxygen atom, or a sulfur atom;
L³ each independently represents a single bond, or a substituted or unsubstituted arylene group having 6 to 50 ring carbon atoms;
when L³ is a substituted arylene group having 6 to 50 ring carbon atoms, the substituent is a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms;
R⁵¹ and R⁵² each independently represent a halogen atom, a cyano group, a substituted or unsubstituted amino group, a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms;
in adjacent ones of R⁵¹ and adjacent ones of R⁵², a saturated or unsaturated divalent group to be bonded form a ring is formed or not formed;
R⁵³ and R⁵⁴ each independently represent a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, a substituted or unsubstituted alkylarylsilyl group having 8 to 15 carbon atoms, or a substituted or unsubstituted aromatic hydrocarbon group having 6 to 50 ring carbon atoms; in adjacent ones of R⁵³ and adjacent ones of R⁵⁴, a saturated or unsaturated divalent group to be bonded form a ring is formed or not formed;
a represents an integer of 0 to 4; and b represents an integer of 0 to 3.

2. The organic electroluminescence device according to claim 1, wherein
at least one of A¹ and A² is represented by the following formula (1-1a), 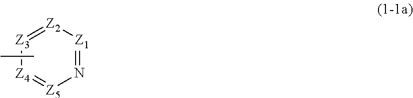
where:
Z₁ to Z₅ each independently represent CR₇ or a nitrogen atom; wherein
R₇ each independently represents a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms; and
adjacent ones of R₇ are bonded to each other to form a cyclic structure, or are not bonded.

3. The organic electroluminescence device according to claim 1, wherein
the substituted or unsubstituted aromatic hydrocarbon group having 6 to 40 carbon atoms for Ar¹¹ to Ar¹³ in the formula (4) is represented by any one of the following formulae (4-3) to (4-5), 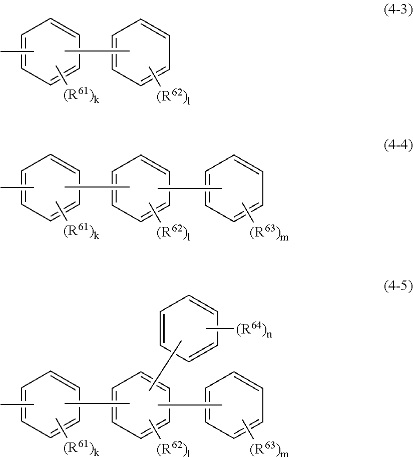
where:
R⁶¹ to R⁶⁴ each independently represent a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms in which an aryl moiety has 6 to 14 ring carbon atoms;
in at least one of adjacent ones of R⁶¹, adjacent ones of R⁶², adjacent ones of R⁶³, and adjacent ones of R⁶⁴, the adjacent ones are bonded to each other to form a cyclic structure, or are not bonded; and
k, l, m and n are each independently an integer of 0 to 4.

4. The organic electroluminescence device according to claim 2, wherein
the substituted or unsubstituted aromatic hydrocarbon group having 6 to 40 carbon atoms for Ar¹¹ to Ar¹³ in the formula (4) is represented by any one of the following formulae (4-3) to (4-5), 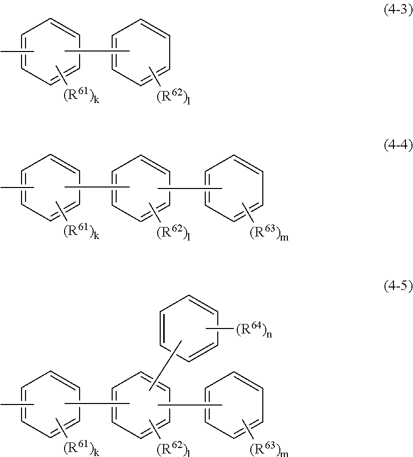
where:
R⁶¹ to R⁶⁴ each independently represent a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms in which an aryl moiety has 6 to 14 ring carbon atoms;
in at least one of adjacent ones of R⁶¹, adjacent ones of R⁶², adjacent ones of R⁶³, and adjacent ones of R⁶⁴, the adjacent ones are bonded to each other to form a cyclic structure, or are not bonded; and
k, l, m and n are each independently an integer of 0 to 4.

5. The organic electroluminescence device according to claim 1, wherein
the first material is represented by any one of the following formulae (1-2) to (1-4), 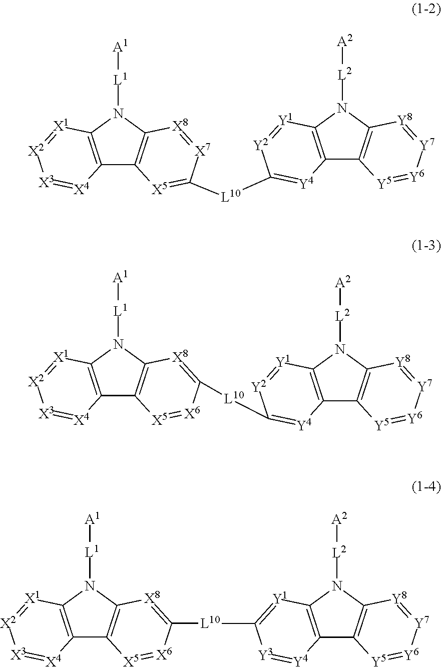
where:
A¹, A², L¹, L², L¹⁰, X¹ to X⁸ and Y¹ to Y⁸ respectively represent the same as A¹, A², L¹, L², L¹⁰, X¹ to X⁸ and Y¹ to Y⁸ in the formula (1-1).

6. The organic electroluminescence device according to claim 2, wherein
the first material is represented by any one of the following formulae (1-2) to (1-4), 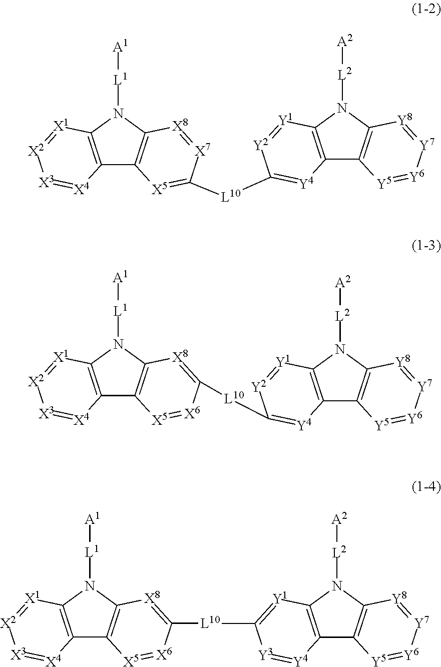
where:
A¹, A², L¹, L², L¹⁰, X¹ to X⁸ and Y¹ to Y⁸ respectively represent the same as A¹, A², L¹, L², L¹⁰, X¹ to X⁸ and Y¹ to Y⁸ in the formula (1-1).

7. The organic electroluminescence device according to claim 3, wherein
the first material is represented by any one of the following formulae (1-2) to (1-4), 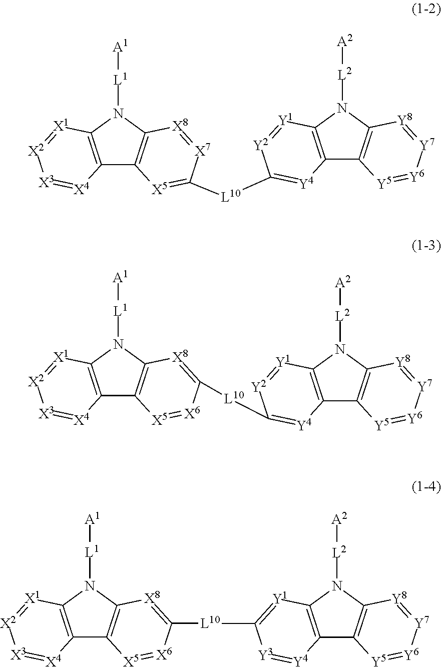
where:
A¹, A², L¹, L², L¹⁰, X¹ to X⁸ and Y¹ to Y⁸ respectively represent the same as A¹, A², L¹, L², L¹⁰, X¹ to X⁸ and Y¹ to Y⁸ in the formula (1-1).

8. The organic electroluminescence device according to claim 4, wherein
the first material is represented by any one of the following formulae (1-2) to (1-4), 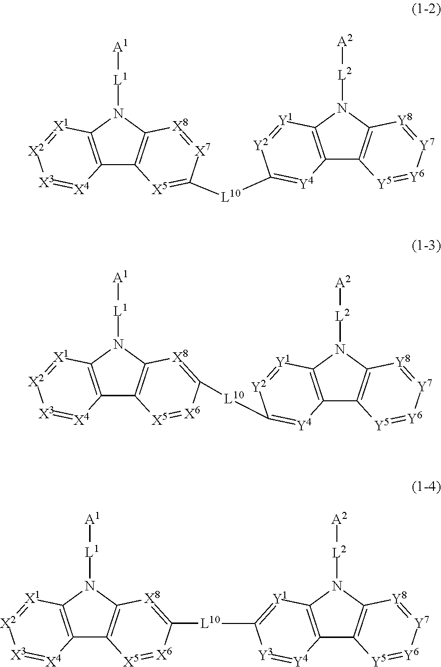
where:
A¹, A², L¹, L², L¹⁰, X¹ to X⁸ and Y¹ to Y⁸ respectively represent the same as A¹, A², L¹, L², L¹⁰, X¹ to X⁸ and Y¹ to Y⁸ in the formula (1-1).

9. The organic electroluminescence device according to claim 1, wherein
the group represented by the formula (4-2) is represented by the following formula (4-2-1) or (4-2-2), 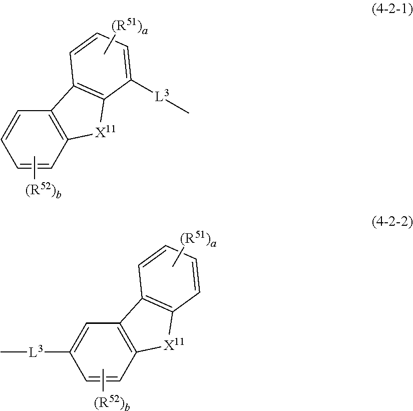
where:
R⁵¹, R⁵², L³, X¹¹, a and b respectively represent the same as R⁵¹, R⁵², L³, X¹¹, a and b in the formula (4-2).

10. The organic electroluminescence device according to claim 2, wherein
the group represented by the formula (4-2) is represented by the following formula (4-2-1) or (4-2-2), 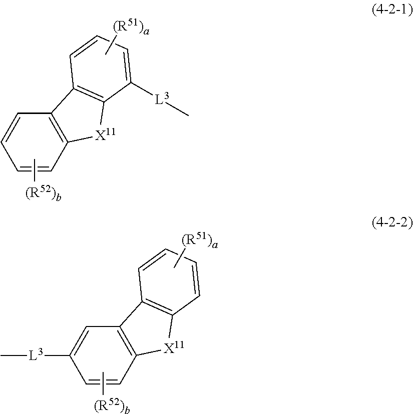
where:
R⁵¹, R⁵², L³, X¹¹, a and b respectively represent the same as R⁵¹, R⁵², L³, X¹¹, a and b in the formula (4-2).

11. The organic electroluminescence device according to claim 3, wherein
the group represented by the formula (4-2) is represented by the following formula (4-2-1) or (4-2-2), 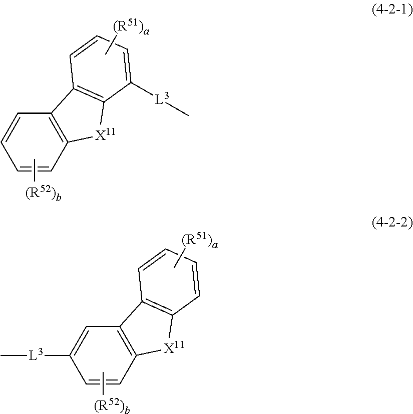
where:
R⁵¹, R⁵², L³, X¹¹, a and b respectively represent the same as R⁵¹, R⁵², L³, X¹¹, a and b in the formula (4-2).

12. The organic electroluminescence device according to claim 4, wherein
the group represented by the formula (4-2) is represented by the following formula (4-2-1) or (4-2-2), 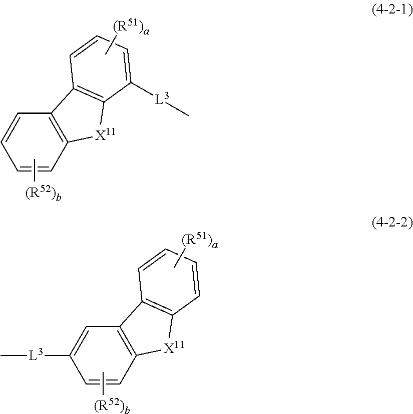
where:
R⁵¹R⁵², L³, X¹¹, a and b respectively represent the same as R⁵¹, R⁵², L³, X¹¹, a and b in the formula (4-2).

13. The organic electroluminescence device according to claim 1, wherein
a in the formula (4-2) is an integer of 1 to 4, and
at least one of R⁵¹ in the formula (4-2) is a substituted or unsubstituted carbazolyl group to be bonded at N position.

14. The organic electroluminescence device according to claim 1, wherein
two of Ar¹¹ to Ar¹³ in the formula (4) are the group represented by the formula (4-2).

15. The organic electroluminescence device according to claim 1, wherein
three of Ar¹¹ to Ar¹³ in the formula (4) are the group represented by the formula (4-2).

16. The organic electroluminescence device according to claim 1, wherein
the second material is represented by the following formula (2), 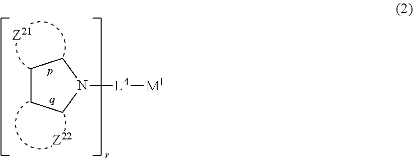
where:
Z²¹ to be fused at p represents a cyclic structure represented by the following formula (2-1) or (2-2);
Z²² to be fused at q represents a cyclic structure represented by the following formula (2-1) or (2-2), provided that at least one of Z²¹ and Z²² is represented by the formula (2-1);
M¹ represents a substituted or unsubstituted aromatic hydrocarbon group having 6 to 30 ring carbon atoms, or substituted or unsubstituted heterocyclic group having 5 to 30 ring atoms;
L⁴ represents a single bond, a substituted or unsubstituted divalent aromatic hydrocarbon group having 6 to 30 ring carbon atoms, a substituted or unsubstituted divalent heterocyclic group having 5 to 30 ring atoms, a substituted or unsubstituted cycloalkylene group having 5 to 30 ring carbon atoms, or a group provided by linking the divalent aromatic hydrocarbon group, the divalent heterocyclic group and the cycloalkylene group; and
r is 1 or 2, 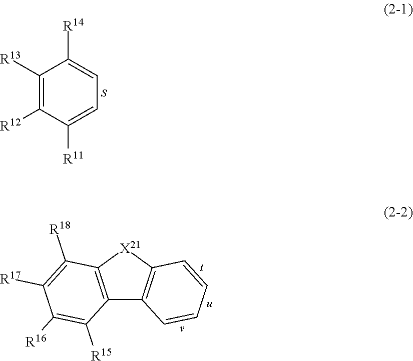
where:
s in the formula (2-1) is fused to p or q in the formula (2);
one of t, u and v in the formula (2-2) is fused to p or q in the formula (2);
X²¹ in the formula (2-2) represents a sulfur atom, an oxygen atom, N—R¹⁹, or C(R²⁰)(R²¹);
R¹¹ and R²¹ each independently represent a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms; and
adjacent ones of R¹¹ to R¹⁸ are bonded to each other to form a ring, or are not bonded.

17. The organic electroluminescence device according to claim 16, wherein
the second material is represented by the following formula (2-3), 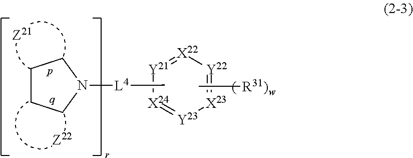
where:
Z²¹ to be fused at p represents a cyclic structure represented by the formula (2-1) or (2-2);
Z²² to be fused at q represents a cyclic structure represented by the formula (2-1) or (2-2), provided that at least one of Z²¹ and Z²² is represented by the formula (2-1);
L⁴ represents the same as L⁴ in the formula (2);
X²² to X²⁴ each independently represent a nitrogen atom, CH, or a carbon atom to be bonded to R³¹ or L⁴;
Y²¹ to Y²³ each independently represent CH or a carbon atom to be bonded to R³¹ or L⁴;
R³¹ each independently represents a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms;
when a plurality of R³¹ are present, the plurality of R³¹ are optionally mutually the same or different and adjacent ones of R³¹ are optionally bonded to each other to form a ring;
r is 1 or 2 and w is an integer of 0 to 4;
s in the formula (2-1) is fused to p or q in the formula (2); and
one of t, u and v in the formula (2-2) is fused to p or q in the formula (2).

18. The organic electroluminescence device according to claim 16, wherein
the second material is represented by the following formula (2-4), 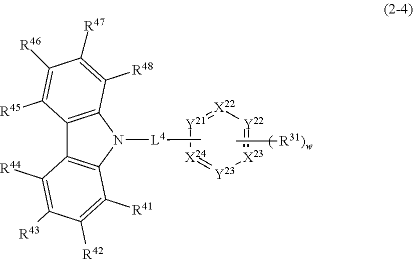
where:
L⁴ represents the same as L⁴ in the formula (2);
X²² to X²⁴ each independently represent a nitrogen atom, CH, or a carbon atom to be bonded to R³¹ or L⁴;
Y²¹ to Y²³ each independently represent CH or a carbon atom to be bonded to R³¹ or L⁴;
R³¹ each independently represents a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms;
when a plurality of R³¹ are present, the plurality of R³¹ are optionally mutually the same or different and adjacent ones of R³¹ are optionally bonded to each other to form a ring;
w is an integer of 0 to 4;
R⁴¹ to R⁴⁸ each independently represent the same as R¹¹ to R²¹ in the formula (2); and adjacent ones of R⁴¹ to R⁴⁸ are bonded to each other to form a ring, or are not bonded.

19. The organic electroluminescence device according to claim 16, wherein
the second material is represented by the following formula (2-5), 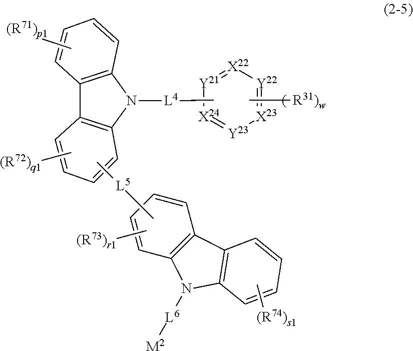
where:
L⁴ represents the same as L⁴ in the formula (2);
X²² to X²⁴ each independently represent a nitrogen atom, CH or a carbon atom to be bonded to R³¹ or L⁴, provided that at least one of X²² to X²⁴ is a nitrogen atom;
Y²¹ to Y²³ each independently represent CH or a carbon atom to be bonded to R³¹ or L⁴;
R³¹ each independently represents a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms;
when a plurality of R³¹ are present, the plurality of R³¹ are optionally mutually the same or different and adjacent ones of R³¹ are optionally bonded to each other to form a ring;
w is an integer of 0 to 4;
L⁵ and L⁶ each independently represent a single bond, a substituted or unsubstituted divalent aromatic hydrocarbon group having 6 to 30 ring carbon atoms, a substituted or unsubstituted divalent heterocyclic group having 5 to 30 ring atoms, a substituted or unsubstituted cycloalkylene group having 5 to 30 ring carbon atoms, or a group provided by linking the divalent aromatic hydrocarbon group, the divalent heterocyclic group and the cycloalkylene group;
R⁷¹ to R⁷⁴ each independently represent the same as R¹¹ to R²¹ in the formula (2); in at least one of adjacent ones of R⁷¹, adjacent ones of R⁷², adjacent ones of R⁷³, and adjacent ones of R⁷⁴, the adjacent ones are bonded to each other to form a ring, or are not bonded;
M² represents a substituted or unsubstituted aromatic hydrocarbon group having 6 to 30 ring carbon atoms, or substituted or unsubstituted heterocyclic group having 5 to 30 ring atoms;
p1 and s1 each independently represent an integer of 0 to 4; and
q1 and r1 each independently represent an integer of 0 to 3.

20. An organic electroluminescence device comprising:
an anode;
a cathode;
a first organic layer interposed between the anode and the cathode and comprising a compound represented by the following formula (4X); and
an emitting layer interposed between the first organic layer and the cathode and comprising a first material represented by the following formula (1-3X), and a luminescent material, 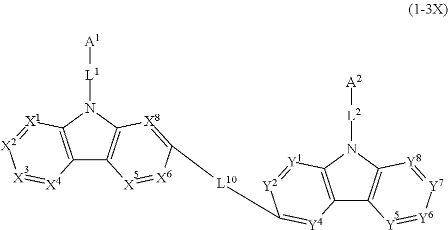
where:
A¹ and A² each independently represent a substituted or unsubstituted aromatic hydrocarbon group having 6 to 30 ring carbon atoms or a substituted or unsubstituted heterocyclic group having 5 to 30 ring atoms;
L¹, L² and L¹⁰ each independently represent a single bond, a substituted or unsubstituted divalent aromatic hydrocarbon group having 6 to 30 ring carbon atoms, or a substituted or unsubstituted divalent heterocyclic group having 5 to 30 ring atoms;
X¹ to X⁸ and Y¹ to Y⁸ each independently represent a nitrogen atom or CR^{a}, wherein
R^{a} each independently represents a hydrogen atom, a halogen atom, a cyano group, a substituted or unsubstituted aromatic hydrocarbon group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aryloxy group having 6 to 30 ring carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 30 carbon atoms, a substituted or unsubstituted arylsilyl group having 6 to 30 carbon atoms, a substituted or unsubstituted aralkyl group having 7 to 30 carbon atoms, a substituted or unsubstituted alkenyl group having 2 to 30 carbon atoms, or a substituted or unsubstituted alkynyl group having 2 to 30 carbon atoms; and
when a plurality of R^{a} are present, the plurality of R^{a} are the same or different, 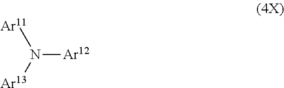
where:
at least one of Ar¹¹ to Ar¹³ is a group represented by the following formula (4-2X); and the rest of Ar¹¹ to Ar¹³ except for the group represented by the following formula (4-2X) is a substituted or unsubstituted aromatic hydrocarbon group having 6 to 40 carbon atoms, 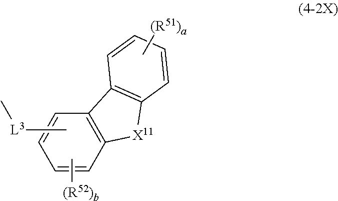
where:
X¹¹ represents CR⁵³R⁵⁴, an oxygen atom, or a sulfur atom;
L³ each independently represents a single bond or a substituted or unsubstituted arylene group having 6 to 50 ring carbon atoms;
when L³ is a substituted arylene group having 6 to 50 ring carbon atoms, the substituent is a halogen atom, a cyano group, an aromatic hydrocarbon group having 6 to 50 ring carbon atoms, a linear or branched alkyl group having 1 to 10 carbon atoms, a cycloalkyl group having 3 to 10 ring carbon atoms, a trialkylsilyl group having 3 to 10 carbon atoms, a triarylsilyl group having 18 to 30 ring carbon atoms, or an alkylarylsilyl group having 8 to 15 carbon atoms;
R⁵¹ and R⁵² each independently represent a halogen atom, a cyano group, a substituted or unsubstituted amino group, a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms;
in adjacent ones of R⁵¹ and adjacent ones of R⁵², a saturated or unsaturated divalent group to be bonded form a ring is formed or not formed;
R⁵³ and R⁵⁴ each independently represent a substituted or unsubstituted aromatic hydrocarbon group having 6 to 50 ring carbon atoms, a substituted or unsubstituted and linear or branched alkyl group having 1 to 10 carbon atoms, a substituted or unsubstituted cycloalkyl group having 3 to 10 ring carbon atoms, a substituted or unsubstituted trialkylsilyl group having 3 to 10 carbon atoms, a substituted or unsubstituted triarylsilyl group having 18 to 30 ring carbon atoms, or a substituted or unsubstituted alkylarylsilyl group having 8 to 15 carbon atoms;
in adjacent ones of R⁵³ and adjacent ones of R⁵⁴, a saturated or unsaturated divalent group to be bonded form a ring is formed or not formed;
a represents an integer of 0 to 4; and
b represents an integer of 0 to 3.
